(19) United States
(12) Patent Application Publication
(10) Pub. No.: US 2024/0268230 A1
(43) Pub. Date: Aug. 8, 2024

(54) LIGHT EMITTING ELEMENT AND FUSED POLYCYCLIC COMPOUND FOR THE LIGHT EMITTING ELEMENT

(71) Applicant: Samsung Display Co., Ltd., Yongin-si (KR)

(72) Inventors: Yuma AOKI, Yokohama (JP); Yuji SUZAKI, Yokohama (JP); Tetsuji HAYANO, Yokohama (JP)

(21) Appl. No.: 18/496,801

(22) Filed: Oct. 27, 2023

(30) Foreign Application Priority Data
Jan. 4, 2023 (KR) 10-2023-0001405

(51) Int. Cl. H10K 85/60; C07F 5/02; C09K 11/06

(52) U.S. Cl. CPC H10K 85/658; C07F 5/027; C09K 11/06; H10K 50/11

(57) ABSTRACT

A light emitting element of one or more embodiments includes a first electrode, a second electrode provided on the first electrode, and at least one functional layer provided between the first electrode and the second electrode, and including a fused polycyclic compound having at least one sterically bulky substituent.

### CROSS-REFERENCE TO RELATED APPLICATION

This application claims priority to and the benefit of Korean Patent Application No. 10-2023-0001405, filed on Jan. 4, 2023, the entire content of which is hereby incorporated by reference.

### BACKGROUND

### 1. Field

The present disclosure herein relates to a light emitting element and a fused polycyclic compound utilized in the light emitting element.

### 2. Description of the Related Art

Recently, the development of an organic electroluminescence display to be utilized in an image display is being actively conducted. The organic electroluminescence display and/or the like is different from a liquid crystal display and is so-called a “self-luminescent display” in which holes and electrons injected from a first electrode and a second electrode recombine in an emission layer. Subsequently, a light emitting material including an organic compound located in the emission layer emits light to achieve display.

Implementation of the organic electroluminescence display (e.g., organic electroluminescence display device) to an image display, requires (or there is a desire for) the decrease of a driving voltage, the increase of the emission efficiency, and/or the increase in lifetime of the organic electroluminescence device. Therefore, the need exists for the development of materials for an organic electroluminescence display (e.g., organic electroluminescence display device) and a light emitting element which is capable of stably achieving the requirements (or desires).

For example, in an effort to implement an organic electroluminescence display (e.g., organic electroluminescence display device) with high efficiency, the development of materials for phosphorescence emission which use energy in a triplet state or fluorescence emission which use the generating phenomenon of singlet excitons by the collision of triplet excitons (triplet-triplet annihilation, TTA) are being developed. Also, the development of materials for thermally activated delayed fluorescence (TADF) utilizing delayed fluorescence phenomenon is being pursued.

### SUMMARY

One or more aspects of embodiments of the present disclosure are directed toward a light emitting element having improved emission efficiency and element lifetime.

One or more aspects of embodiments of the present disclosure are directed toward a fused polycyclic compound which is capable of improving the emission efficiency and element lifetime of a light emitting element.

One or more embodiments of the present disclosure provide a light emitting element including a first electrode, a second electrode provided at (or with) the first electrode, and at least one functional layer provided between the first electrode and the second electrode, and including a fused polycyclic compound represented by Formula 1.

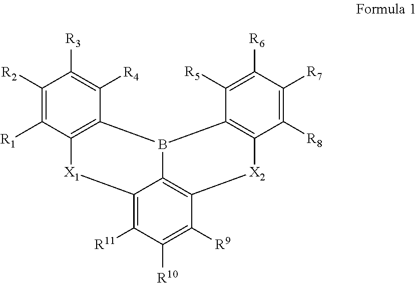

1 In Formula 1, X₁ and X₂ may each independently be O, S, Se, NR₁₂, CR₁₃R₁₄, or SiR₁₅R₁₆, R₁ to R₁₆ may each independently be a hydrogen atom, a deuterium atom, a halogen atom, a cyano group, a hydroxyl group, a substituted or unsubstituted oxy group, a substituted or unsubstituted thio group, a substituted or unsubstituted silyl group, a substituted or unsubstituted amine group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, a substituted or unsubstituted heteroaryl group of 2 to 30 ring-forming carbon atoms, or a substituent represented by Formula 2, and/or combined with an adjacent group to form a ring. In one or more embodiments, in case where each of R₁ to R₁₆ is combined with the adjacent group to form the ring, a case including a heterocycle including Si in the ring as a ring-forming atom or a substituted or unsubstituted benzothiophene moiety, is excluded. In one or more embodiments, at least one selected from among R₁ to R₁₁ is represented by Formula 2.

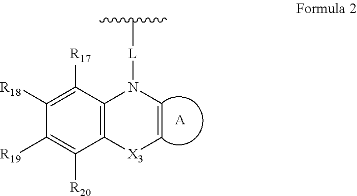

In Formula 2, L is a direct linkage, or a substituted or unsubstituted arylene group of 6 to 30 ring-forming carbon atoms, X₃ is a direct linkage, O, S, Se, NR₂₁, CR₂₂R₂₃, or SiR₂₄R₂₅, R₁₇ to R₂₅ may each independently be a hydrogen atom, a deuterium atom, a halogen atom, a cyano group, a hydroxyl group, a substituted or unsubstituted oxy group, a substituted or unsubstituted thio group, a substituted or unsubstituted silyl group, a substituted or unsubstituted amine group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, and/or a substituted or unsubstituted heteroaryl group of 2 to 30 ring-forming carbon atoms, or combined with an adjacent group to form a ring,

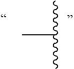

is a position connected with Formula 1, and A is represented by Formula 3.

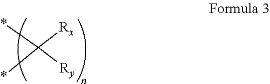

In Formula 3, Rₓ and R_{y} may each independently be a hydrogen atom, a deuterium atom, a halogen atom, a cyano group, a hydroxyl group, a substituted or unsubstituted oxy group, a substituted or unsubstituted thio group, a substituted or unsubstituted silyl group, a substituted or unsubstituted amine group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, and/or combined with an adjacent group to form a ring, “n” is an integer of 3 to 6, and “—*” is a position connected with Formula 2.

In one or more embodiments, the at least one functional layer may include an emission layer, a hole transport region provided between the first electrode and the emission layer, and an electron transport region provided between the emission layer and the second electrode, and the emission layer may include the fused polycyclic compound.

In one or more embodiments, the emission layer may be to (e.g., configured) emit delayed fluorescence.

In one or more embodiments, the emission layer may be to (e.g., configured) emit light having a light center wavelength of about 430 nanometer (nm) to about 490 nm.

In one or more embodiments, the substituent represented by Formula 2 may be represented by any one selected from among Formula 2-1-1 to Formula 2-1-4.

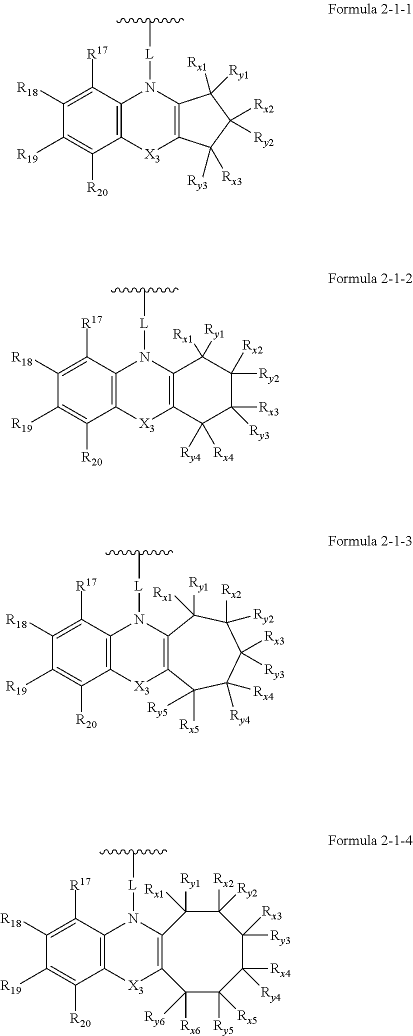

In Formula 2-1-1 to Formula 2-1-4, Rₓ₁ to Rₓ₆, and R_{y1} to R_{y6} may each independently be a hydrogen atom, a deuterium atom, a halogen atom, a cyano group, a hydroxyl group, a substituted or unsubstituted oxy group, a substituted or unsubstituted thio group, a substituted or unsubstituted silyl group, a substituted or unsubstituted amine group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, and/or combined with an adjacent group to form a ring.

In Formula 2-1-1 to Formula 2-1-4, the contents as those defined in Formula 2 may be applied for L, X₃, and R₁₇ to R₂₀.

In one or more embodiments, the substituent represented by Formula 2 may be represented by any one selected from among Formula 2-2-1 to Formula 2-2-7.

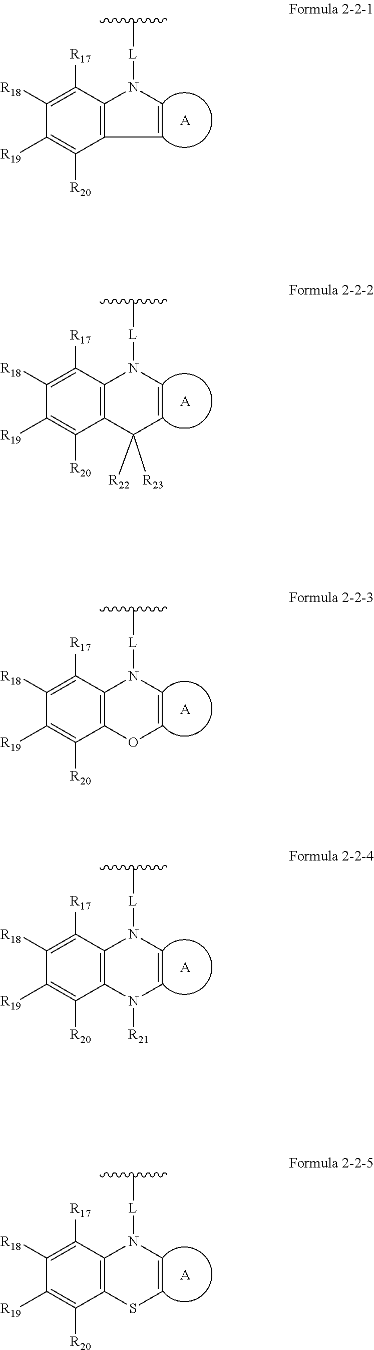

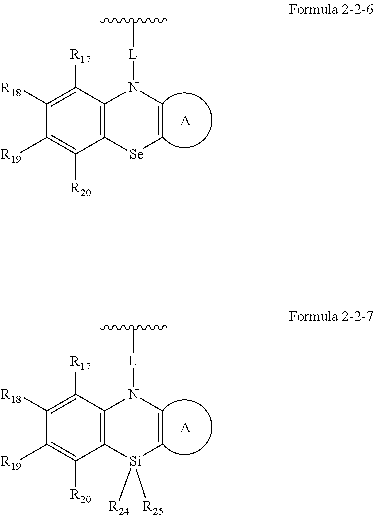

In Formula 2-2-1 to Formula 2-2-7, the contents as those defined in Formula 2 may be applied for L, R₁₇ to R₂₅, and A.

In one or more embodiments, the fused polycyclic compound represented by Formula 1 may be represented by any one selected from among Formula 1-1-1 to Formula 1-1-3.

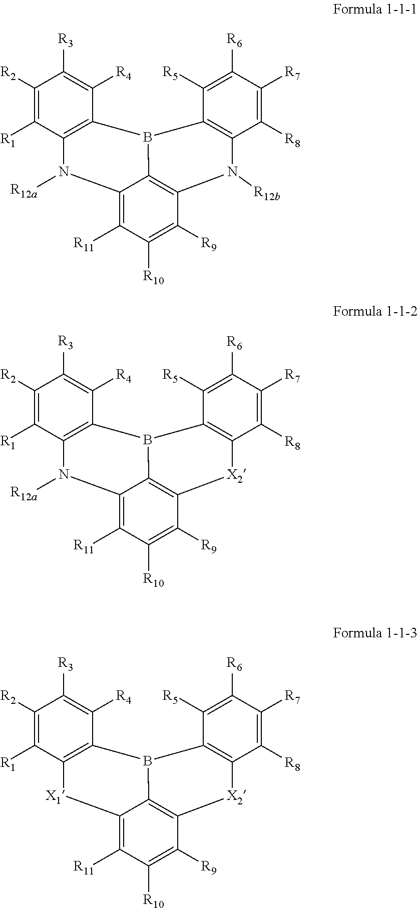

In Formula 1-1-1 to Formula 1-1-3, X₁′ and X₂′ may each independently be O, S, Se, CR₂₆R₂₇, or SiR₂₈R₂₉, R₂₆ to R₂₉ may each independently be a hydrogen atom, a deuterium atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, or combined with an adjacent group to form a ring, R₁₂ₐ and R_{12b} may each independently be a substituted or unsubstituted aryl group of 6 to 30 ring-forming carbon atoms, or a substituted or unsubstituted heteroaryl group of 2 to 30 ring-forming carbon atoms, and/or combined with an adjacent group to form a ring.

In Formula 1-1-1 to Formula 1-1-3, the contents as those defined in Formula 1 may be applied for R₁ to R₁₁.

In one or more embodiments, the fused polycyclic compound represented by Formula 1 may be represented by Formula 1-2-1 or Formula 1-2-2.

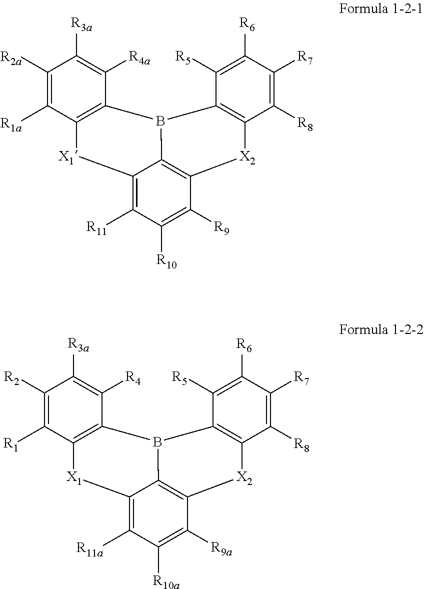

In Formula 1-2-1 and Formula 1-2-2, R₁ₐ to R₄ₐ, and R₉ₐ to R₁₁ₐ may each independently be a hydrogen atom, a deuterium atom, a halogen atom, a cyano group, a hydroxyl group, a substituted or unsubstituted oxy group, a substituted or unsubstituted thio group, a substituted or unsubstituted silyl group, a substituted or unsubstituted amine group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, a substituted or unsubstituted heteroaryl group of 2 to 30 ring-forming carbon atoms, or the substituent represented by Formula 2, and/or combined with an adjacent group to form a ring. In one or more embodiments, in Formula 1-2-1, at least one selected from among R₁ₐ to R₄ₐ is represented by Formula 2, and in Formula 1-2-2, at least one selected from among R₉ₐ to R₁₁ₐ is represented by Formula 2.

In Formula 1-2-1 and Formula 1-2-2, the contents as those defined in Formula 1 may be applied for X₁, X₂, and R₁ to R₁₁.

In one or more embodiments, the fused polycyclic compound represented by Formula 1 may be represented by any one selected from among Formula 1-3-1 to Formula 1-3-3.

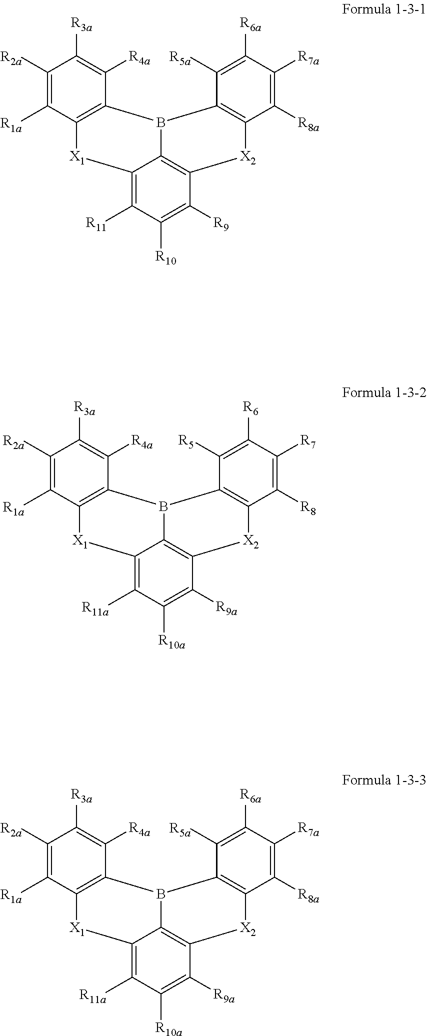

In Formula 1-3-1 to Formula 1-3-3, R₁ₐ to R₁₁ₐ may each independently be a hydrogen atom, a deuterium atom, a halogen atom, a cyano group, a hydroxyl group, a substituted or unsubstituted oxy group, a substituted or unsubstituted thio group, a substituted or unsubstituted silyl group, a substituted or unsubstituted amine group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, a substituted or unsubstituted heteroaryl group of 2 to 30 ring-forming carbon atoms, or the substituent represented by Formula 2, and/or combined with an adjacent group to form a ring. In one or more embodiments, in Formula 1-3-1, at least one selected from among R₁ₐ to R₄ₐ, and at least one selected from among R₅ₐ to R₈ₐ are represented by Formula 2, in Formula 1-3-2, at least one selected from among R₁ₐ to R₄ₐ, and at least one selected from among R₉ₐ to R₁₁ₐ are represented by Formula 2, in Formula 1-3-3, at least one selected from among R₁ₐ to R₄ₐ, at least one selected from among R₅ₐ to R₈ₐ, and at least one selected from among R₉ₐ to R₁₁ₐ are represented by Formula 2.

In Formula 1-3-1 to Formula 1-3-3, the contents as those defined in Formula 1 may be applied for X₁, X₂, and R₅ to R₁₁.

In one or more embodiments, the fused polycyclic compound represented by Formula 1 may be represented by Formula 1-4-1 or Formula 1-4-2.

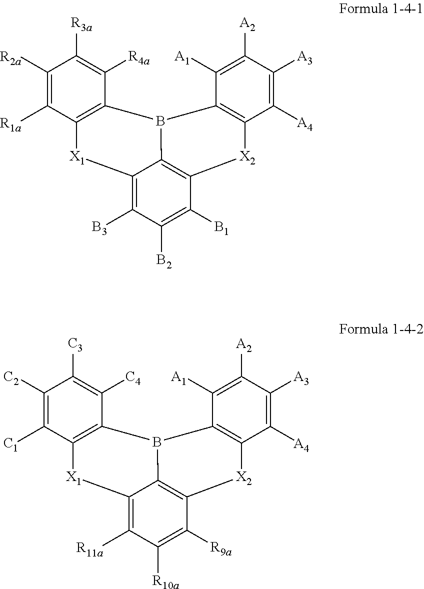

In Formula 1-4-1 and Formula 1-4-2, A₁ to A₄, B₁ to B₃, and C₁ to C₄ may each independently be a hydrogen atom, a deuterium atom, a substituted or unsubstituted alkyl group of 1 to 10 carbon atoms, or the substituent represented by Formula 2, or a substituent represented by Formula C1. In one or more embodiments, R₁ₐ to R₄ₐ, and Rea to R₁₁ₐ may each independently be a hydrogen atom, a deuterium atom, a halogen atom, a cyano group, a hydroxyl group, a substituted or unsubstituted oxy group, a substituted or unsubstituted thio group, a substituted or unsubstituted silyl group, a substituted or unsubstituted amine group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, a substituted or unsubstituted heteroaryl group of 2 to 30 ring-forming carbon atoms, or the substituent represented by Formula 2, and/or combined with an adjacent group to form a ring. In one or more embodiments, in Formula 1-4-1, at least one selected from among R₁ₐ to R₄ₐ is represented by Formula 2, in Formula 1-4-2, at least one selected from among R₉ₐ to R₁₁ₐ is represented by Formula 2.

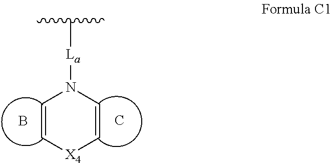

In Formula C1, Lₐ is a direct linkage, or a substituted or unsubstituted arylene group of 6 to 30 ring-forming carbon atoms, X₄ is a direct linkage, O, S, Se, NR₃₁, CR₃₂R₃₃, or SiR₃₄R₃₅, R₃₁ to R₃₅ may each independently be a hydrogen atom, a deuterium atom, a halogen atom, a cyano group, a hydroxyl group, a substituted or unsubstituted oxy group, a substituted or unsubstituted thio group, a substituted or unsubstituted silyl group, a substituted or unsubstituted amine group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, and/or combined with an adjacent group to form a ring. In one or more embodiments, B and C may each independently be represented by Formula C2.

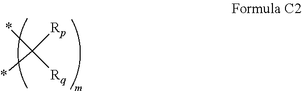

In Formula C2, Rₚ and R_{q} may each independently be a hydrogen atom, a deuterium atom, a halogen atom, a cyano group, a hydroxyl group, a substituted or unsubstituted oxy group, a substituted or unsubstituted thio group, a substituted or unsubstituted silyl group, a substituted or unsubstituted amine group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, and/or combined with an adjacent group to form a ring, and “m” is an integer of 3 to 6.

In Formula 1-4-1 and Formula 1-4-2, the contents as those defined in Formula 1 may be applied for X₁ and X₂.

In one or more embodiments, the fused polycyclic compound represented by Formula 1 may be represented by any one selected from among Formula 1-5-1 to Formula 1-5-3.

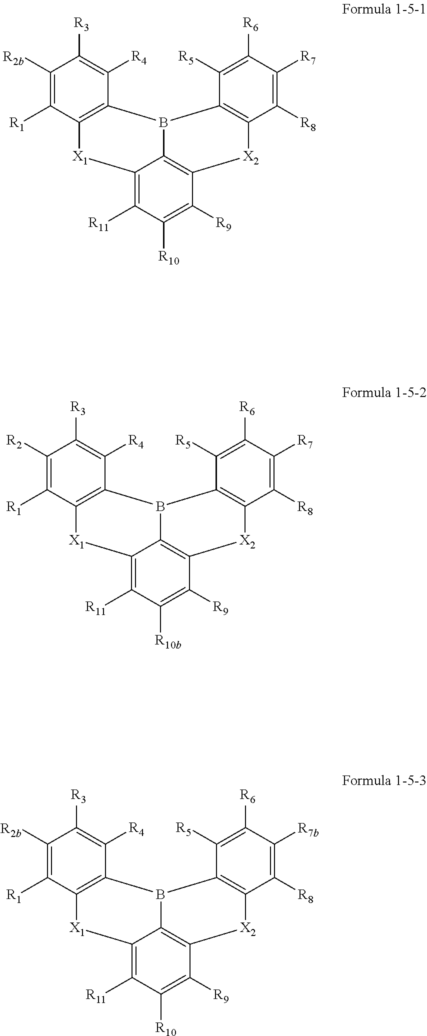

In Formula 1-5-1 to Formula 1-5-3, R_{2b} and R_{10b} may each independently be represented by Formula 2, and R_{7b} is represented by Formula 2 Formula C1.

In one or more embodiments, the fused polycyclic compound represented by Formula 1 may be represented by any one selected from among Formula 1-6-1 to Formula 1-6-3.

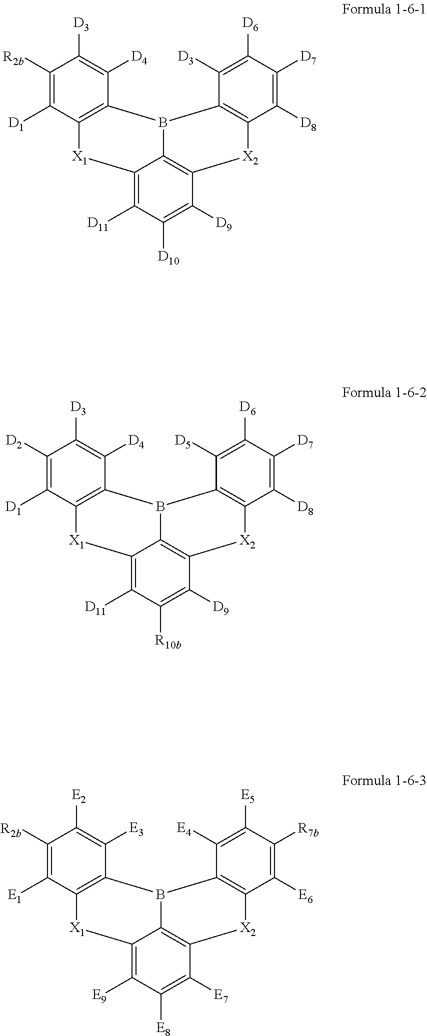

In Formula 1-6-1 to Formula 1-6-3, D₁ to D₁₁ may each independently be a hydrogen atom or a deuterium atom, E₁ to E₉ may each independently be a hydrogen atom, a deuterium atom, or a substituted or unsubstituted alkyl group of 1 to 10 carbon atoms, R_{2b} and R_{10b} may each independently be represented by Formula 2, and R_{7b} is represented by Formula 2 or Formula C1.

A fused polycyclic compound according to one or more embodiments of the present disclosure is represented by Formula 1.

### BRIEF DESCRIPTION OF THE DRAWINGS

The accompanying drawings are included to provide a further understanding of the present disclosure, and are incorporated in and constitute a part of this specification. The drawings illustrate example embodiments of the present disclosure and, together with the description, serve to explain principles of the present disclosure. In the drawings:

FIG. 1 is a plan view of a display device according to one or more embodiments of the present disclosure;

FIG. 2 is a cross-sectional view of a display device according to one or more embodiments of the present disclosure;

FIG. 3 is a cross-sectional view schematically showing a light emitting element according to one or more embodiments of the present disclosure;

FIG. 4 is a cross-sectional view schematically showing a light emitting element according to one or more embodiments of the present disclosure;

FIG. 5 is a cross-sectional view schematically showing a light emitting element according to one or more embodiments of the present disclosure;

FIG. 6 is a cross-sectional view schematically showing a light emitting element according to one or more embodiments of the present disclosure;

FIG. 7 and is a cross-sectional view of a display device according to one or more embodiment of the present disclosure;

FIG. 8 is a cross-sectional view of a display device according to one or more embodiments of the present disclosure;

FIG. 9 is a cross-sectional view showing a display device according to one or more embodiments of the present disclosure;

FIG. 10 is a cross-sectional view showing a display device according to one or more embodiments of the present disclosure; and

FIG. 11 is a perspective view of a vehicle including a display device according to one or more embodiments of the present disclosure.

### DETAILED DESCRIPTION

The present disclosure may be modified in one or more suitable manners and have many forms, and thus specific embodiments will be exemplified in the drawings and described in more detail in the detailed description of the present disclosure. It should be understood, however, that it is not intended to limit the present disclosure to the particular forms disclosed, but rather, is intended to cover all modifications, equivalents, and alternatives falling within the spirit and scope of the present disclosure. Unless otherwise defined, all chemical names, technical and scientific terms, and terms defined in common dictionaries should be interpreted as having meanings consistent with the context of the related art, and should not be interpreted in an ideal or overly formal sense.

When explaining each of drawings, like reference numbers are utilized for referring to like elements. In the accompanying drawings, the dimensions of each structure are exaggeratingly illustrated for clarity of the present disclosure. It will be understood that, although the terms “first,” “second,” etc., may be utilized herein to describe one or more suitable components, these components should not be limited by these terms. These terms are only utilized to distinguish one component from another. For example, a first component could be termed a second component, and, similarly, a second component could be termed a first component, without departing from the scope of example embodiments of the present disclosure. As utilized herein, the singular forms, “a,” “an,” and “the” are intended to include the plural forms as well, unless the context clearly indicates otherwise.

In the present application, it will be understood that the terms “comprise,” “comprises,” “comprising,” “include,” “includes,” “including,” “have,” “has,” “having,” and/or the like specify the presence of features, numbers, steps, operations, component, parts, or combinations thereof disclosed in the specification, but do not exclude the possibility of presence or addition of one or more other features, numbers, steps, operations, component, parts, or combinations thereof.

In the present application, when a layer, a film, a region, or a plate is referred to as being “on,” “connected to,” “coupled to,” or “in an upper portion of” another layer, film, region, or plate, it may be not only “directly on” the layer, film, region, or plate, but intervening layers, films, regions, or plates may also be present. On the contrary to this, when a layer, a film, a region, or a plate is referred to as being “,” “in a lower portion of” another layer, film, region, or plate, it can be not only directly under the layer, film, region, or plate, but intervening layers, films, regions, or plates may also be present. In some embodiments, it will be understood that when a part is referred to as being “on” another part, it can be provided above the other part, or provided under the other part as well. When an element is referred to as being “directly on,” “directly connected to,” or “directly coupled to” another element, there are no intervening elements present. As used herein, the terms “use,” “using,” and “used” may be considered synonymous with the terms “utilize,” “utilizing,” and “utilized,” respectively.

As used herein, expressions such as “at least one of,” “one of,” and “selected from,” when preceding a list of elements, modify the entire list of elements and do not modify the individual elements of the list. For example, the expressions “at least one of a to c,” “at least one of a, b or c,” and “at least one of a, b and/or c” may indicate only a, only b, only c, both (e.g., simultaneously) a and b, both (e.g., simultaneously) a and c, both (e.g., simultaneously) b and c, all of a, b, and c, or variations thereof.

As used herein, the term “and/or” includes any and all combinations of one or more of the associated listed items.

The term “may” will be understood to refer to “one or more embodiments of the present disclosure,” some of which include the described element and some of which exclude that element and/or include an alternate element. Similarly, alternative language such as “or” refers to “one or more embodiments of the present disclosure,” each including a corresponding listed item.

Spatially relative terms, such as “beneath,” “below,” “lower,” “above,” “upper,” “bottom,” “top,” and the like, may be used herein for ease of description to describe one element or feature's relationship to another element(s) or feature(s) as illustrated in the drawings. It will be understood that the spatially relative terms are intended to encompass different orientations of the device in use or operation in addition to the orientation depicted in the drawings. For example, if the device in the drawings is turned over, elements described as “below” or “beneath” other elements or features would then be oriented “above” or “over” the other elements or features. Thus, the term “below” may encompass both an orientation of above and below. The device may be otherwise oriented (rotated 90 degrees or at other orientations), and the spatially relative descriptors used herein should be interpreted accordingly.

Unless otherwise defined, all terms (including technical and scientific terms) used herein have the same meaning as commonly understood by those of ordinary skill in the art to which the present disclosure pertains. It is also to be understood that terms defined in commonly used dictionaries should be interpreted as having meanings consistent with meanings in the context of the related art, unless expressly defined herein, and should not be interpreted in an ideal or overly formal sense.

In this context, “consisting essentially of” means that any additional components will not materially affect the chemical, physical, optical, or electrical properties of the semiconductor film.

Further, in this specification, the phrase “on a plane,” or “plan view,” means viewing a target portion from the top, and the phrase “on a cross-section” means viewing a cross-section formed by vertically cutting a target portion from the side.

### Definitions

In the specification, the term “substituted or unsubstituted” may refer to substituted or unsubstituted with at least one substituent selected from the group consisting of a deuterium atom, a halogen atom, a cyano group, a nitro group, an amino group, a silyl group, an oxy group, a thio group, a sulfinyl group, a sulfonyl group, a carbonyl group, a boron group, a phosphine oxide group, a phosphine sulfide group, an alkyl group, an alkenyl group, an alkynyl group, a hydrocarbon ring group, an aryl group, and a heterocyclic group. In some embodiments, each of the substituents exemplified above may be substituted or unsubstituted. For example, a biphenyl group may be interpreted as an aryl group or a phenyl group substituted with a phenyl group.

In the specification, the phrase “bonded to an adjacent group to form a ring” may refer to that a group is bonded to an adjacent group to form a substituted or unsubstituted hydrocarbon ring, or a substituted or unsubstituted heterocycle. The hydrocarbon ring includes an aliphatic hydrocarbon ring and an aromatic hydrocarbon ring. The heterocycle includes an aliphatic heterocycle and an aromatic heterocycle. The hydrocarbon ring and the heterocycle may be monocyclic or polycyclic. In some embodiments, the rings formed by being bonded to each other may be connected to another ring to form a spiro structure.

In the specification, the term “adjacent group” may refer to a substituent substituted for an atom which is directly linked to an atom substituted with a corresponding substituent, another substituent substituted for an atom which is substituted with a corresponding substituent, or a substituent sterically positioned at the nearest position to a corresponding substituent. For example, two methyl groups in 1,2-dimethylbenzene may be interpreted as “adjacent groups” to each other and two ethyl groups in 1,1-diethylcyclopentane may be interpreted as “adjacent groups” to each other. In some embodiments, two methyl groups in 4,5-dimethylphenanthrene may be interpreted as “adjacent groups” to each other.

In the specification, examples of the halogen atom may include a fluorine atom, a chlorine atom, a bromine atom, or an iodine atom.

In the specification, the alkyl group may be linear or branched. The number of carbons in the alkyl group is 1 to 50, 1 to 30, 1 to 20, 1 to 10, or 1 to 6. Examples of the alkyl group may include a methyl group, an ethyl group, an n-propyl group, an isopropyl group, an n-butyl group, an s-butyl group, a t-butyl group, an i-butyl group, a 2-ethylbutyl group, a 3,3-dimethylbutyl group, an n-pentyl group, an i-pentyl group, a neopentyl group, a t-pentyl group, a 1-methylpentyl group, a 3-methylpentyl group, a 2-ethylpentyl group, a 4-methyl-2-pentyl group, an n-hexyl group, a 1-methylhexyl group, a 2-ethylhexyl group, a 2-butylhexyl group, an n-heptyl group, a 1-methylheptyl group, a 2,2-dimethylheptyl group, a 2-ethylheptyl group, a 2-butylheptyl group, an n-octyl group, a t-octyl group, a 2-ethyloctyl group, a 2-butyloctyl group, a 2-hexyloctyl group, a 3,7-dimethyloctyl group, an n-nonyl group, an n-decyl group, an adamantyl group, a 2-ethyldecyl group, a 2-butyldecyl group, a 2-hexyldecyl group, a 2-octyldecyl group, an n-undecyl group, an n-dodecyl group, a 2-ethyldodecyl group, a 2-butyldodecyl group, a 2-hexyldocecyl group, a 2-octyldodecyl group, an n-tridecyl group, an n-tetradecyl group, an n-pentadecyl group, an n-hexadecyl group, a 2-ethylhexadecyl group, a 2-butylhexadecyl group, a 2-hexylhexadecyl group, a 2-octylhexadecyl group, an n-heptadecyl group, an n-octadecyl group, an n-nonadecyl group, an n-eicosyl group, a 2-ethyleicosyl group, a 2-butyleicosyl group, a 2-hexyleicosyl group, a 2-octyleicosyl group, an n-henicosyl group, an n-docosyl group, an n-tricosyl group, an n-tetracosyl group, an n-pentacosyl group, an n-hexacosyl group, an n-heptacosyl group, an n-octacosyl group, an n-nonacosyl group, an n-triacontyl group, etc., but the embodiment of the present disclosure is not limited thereto.

In the specification, a cycloalkyl group may refer to a cyclic alkyl group. The number of carbons in the cycloalkyl group is 3 to 50, 3 to 30, 3 to 20, or 3 to 10. Examples of the cycloalkyl group may include a cyclopropyl group, a cyclobutyl group, a cyclopentyl group, a cyclohexyl group, a 4-methylcyclohexyl group, a 4-t-butylcyclohexyl group, a cycloheptyl group, a cyclooctyl group, a cyclononyl group, a cyclodecyl group, a norbornyl group, a 1-adamantyl group, a 2-adamantyl group, an isobornyl group, a bicycloheptyl group, etc., but the embodiment of the present disclosure is not limited thereto.

In the specification, an alkenyl group refers to a hydrocarbon group including at least one carbon double bond in the middle or terminal of an alkyl group having 2 or more carbon atoms. The alkenyl group may be linear or branched. The number of carbon atoms in the alkenyl group is not specifically limited, but is 2 to 30, 2 to 20, or 2 to 10. Examples of the alkenyl group include a vinyl group, a 1-butenyl group, a 1-pentenyl group, a 1,3-butadienyl aryl group, a styrenyl group, a styryl vinyl group, etc., but the embodiment of the present disclosure is not limited thereto.

In the specification, an alkynyl group refers to a hydrocarbon group including at least one carbon triple bond in the middle or terminal of an alkyl group having 2 or more carbon atoms. The alkynyl group may be linear or branched. Although the number of carbon atoms is not specifically limited, it is 2 to 30, 2 to 20, or 2 to 10. Specific examples of the alkynyl group may include an ethynyl group, a propynyl group, etc., but are not limited thereto.

In the specification, the hydrocarbon ring group refers to any functional group or substituent derived from an aliphatic hydrocarbon ring. The hydrocarbon ring group may be a saturated hydrocarbon ring group having 5 to 20 ring-forming carbon atoms.

In the specification, an aryl group refers to any functional group or substituent derived from an aromatic hydrocarbon ring. The aryl group may be a monocyclic aryl group or a polycyclic aryl group. The number of ring-forming carbon atoms in the aryl group may be 6 to 30, 6 to 20, or 6 to 15. Examples of the aryl group may include a phenyl group, a naphthyl group, a fluorenyl group, an anthracenyl group, a phenanthryl group, a biphenyl group, a terphenyl group, a quaterphenyl group, a quinquephenyl group, a sexiphenyl group, a triphenylenyl group, a pyrenyl group, a benzofluoranthenyl group, a chrysenyl group, etc., but the embodiment of the present disclosure is not limited thereto.

In the specification, the fluorenyl group may be substituted, and two substituents may be bonded to each other to form a spiro structure. Examples of the substituted fluorenyl group are as shown. However, the embodiment of the present disclosure is not limited thereto.

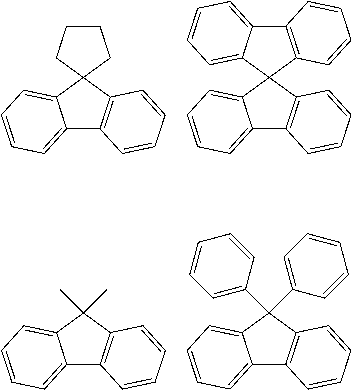

The heterocyclic group herein refers to any functional group or substituent derived from a ring containing at least one of B, O, N, P, Si, or Se as a heteroatom. The heterocyclic group includes an aliphatic heterocyclic group and an aromatic heterocyclic group. The aromatic heterocyclic group may be a heteroaryl group. The aliphatic heterocycle and the aromatic heterocycle may be monocyclic or polycyclic.

In the specification, the heterocyclic group may contain at least one of B, O, N, P, Si or S as a heteroatom. When the heterocyclic group contains two or more heteroatoms, the two or more heteroatoms may be the same as or different from each other. The heterocyclic group may be a monocyclic heterocyclic group or a polycyclic heterocyclic group, and includes a heteroaryl group. The number of ring-forming carbon atoms in the heterocyclic group may be 2 to 30, 2 to 20, or 2 to 10.

In the specification, the aliphatic heterocyclic group may include at least one of B, O, N, P, Si, or S as a heteroatom. The number of ring-forming carbon atoms in the aliphatic heterocyclic group may be 2 to 30, 2 to 20, or 2 to 10. Examples of the aliphatic heterocyclic group may include an oxirane group, a thiirane group, a pyrrolidine group, a piperidine group, a tetrahydrofuran group, a tetrahydrothiophene group, a thiane group, a tetrahydropyran group, a 1,4-dioxane group, etc., but the embodiment of the present disclosure is not limited thereto.

In the specification, the heteroaryl group may contain at least one of B, O, N, P, Si, or S as a heteroatom. When the heteroaryl group contains two or more heteroatoms, the two or more heteroatoms may be the same as or different from each other. The heteroaryl group may be a monocyclic heterocyclic group or a polycyclic heterocyclic group. The number of ring-forming carbon atoms in the heteroaryl group may be 2 to 30, 2 to 20, or 2 to 10. Examples of the heteroaryl group may include a thiophene group, a furan group, a pyrrole group, an imidazole group, a pyridine group, a bipyridine group, a pyrimidine group, a triazine group, a triazole group, an acridyl group, a pyridazine group, a pyrazinyl group, a quinoline group, a quinazoline group, a quinoxaline group, a phenoxazine group, a phthalazine group, a pyrido pyrimidine group, a pyrido pyrazine group, a pyrazino pyrazine group, an isoquinoline group, an indole group, a carbazole group, an N-arylcarbazole group, an N-heteroarylcarbazole group, an N-alkylcarbazole group, a benzoxazole group, a benzimidazole group, a benzothiazole group, a benzocarbazole group, a benzothiophene group, a dibenzothiophene group, a thienothiophene group, a benzofuran group, a phenanthroline group, a thiazole group, an isoxazole group, an oxazole group, an oxadiazole group, a thiadiazole group, a phenothiazine group, a dibenzosilole group, a dibenzofuran group, etc., but the embodiment of the present disclosure is not limited thereto.

In the specification, the above description of the aryl group may be applied to an arylene group except that the arylene group is a divalent group. The above description of the heteroaryl group may be applied to a heteroarylene group except that the heteroarylene group is a divalent group.

In the specification, the silyl group includes an alkylsilyl group and an arylsilyl group. Examples of the silyl group may include a trimethylsilyl group, a triethylsilyl group, a t-butyldimethylsilyl group, a vinyldimethylsilyl group, a propyldimethylsilyl group, a triphenylsilyl group, a diphenylsilyl group, a phenylsilyl group, etc., but the embodiment of the present disclosure is not limited thereto.

In the specification, the number of ring-forming carbon atoms in the carbonyl group is not specifically limited, but may be 1 to 40, 1 to 30, or 1 to 20. For example, the carbonyl group may have the following structures, but the embodiment of the present disclosure is not limited thereto.

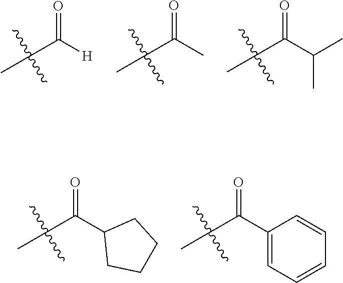

In the specification, the number of carbon atoms in the sulfinyl group and the sulfonyl group is not particularly limited, but may be 1 to 30. The sulfinyl group may include an alkyl sulfinyl group and an aryl sulfinyl group. The sulfonyl group may include an alkyl sulfonyl group and an aryl sulfonyl group.

In the specification, the thio group may include an alkylthio group and an arylthio group. The thio group may refer to that a sulfur atom is bonded to the alkyl group or the aryl group as defined above. Examples of the thio group may include a methylthio group, an ethylthio group, a propylthio group, a pentylthio group, a hexylthio group, an octylthio group, a dodecylthio group, a cyclopentylthio group, a cyclohexylthio group, a phenylthio group, a naphthylthio group, but the embodiment of the present disclosure is not limited thereto.

In the specification, an oxy group may refer to that an oxygen atom is bonded to the alkyl group or the aryl group as defined above. The oxy group may include an alkoxy group and an aryl oxy group. The alkoxy group may be a linear chain, a branched chain or a ring chain. The number of carbon atoms in the alkoxy group is not specifically limited, but may be, for example, 1 to 20 or 1 to 10. Examples of the oxy group may include methoxy, ethoxy, n-propoxy, isopropoxy, butoxy, pentyloxy, hexyloxy, octyloxy, nonyloxy, decyloxy, benzyloxy, etc., but the embodiment of the present disclosure is not limited thereto.

The boron group herein may refer to that a boron atom is bonded to the alkyl group or the aryl group as defined above. The boron group includes an alkyl boron group and an aryl boron group. Examples of the boron group may include a dimethylboron group, a trimethylboron group, a t-butyldimethylboron group, a diphenylboron group, a phenylboron group, etc., but the embodiment of the present disclosure is not limited thereto.

In the specification, the number of carbon atoms in an amine group is not specifically limited, but may be 1 to 30. The amine group may include an alkyl amine group and an aryl amine group. Examples of the amine group may include a methylamine group, a dimethylamine group, a phenylamine group, a diphenylamine group, a naphthylamine group, a 9-methyl-anthracenylamine group, etc., but the embodiment of the present disclosure is not limited thereto.

In the specification, the alkyl group among an alkylthio group, an alkylsulfoxy group, an alkylaryl group, an alkylamino group, an alkyl boron group, an alkyl silyl group, and an alkyl amine group is the same as the examples of the alkyl group described above.

1 In the specification, the aryl group among an aryloxy group, an arylthio group, an arylsulfoxy group, an arylamino group, an arylboron group, an arylsilyl group, an arylamine group is the same as the examples of the aryl group described above.

In the specification, a direct linkage may refer to a single bond.

In some embodiments, in the specification, “

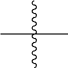

” and “—*” refer to a position to be connected.

Hereinafter, embodiments of the present disclosure will be described with reference to the accompanying drawings.

### Display Apparatus

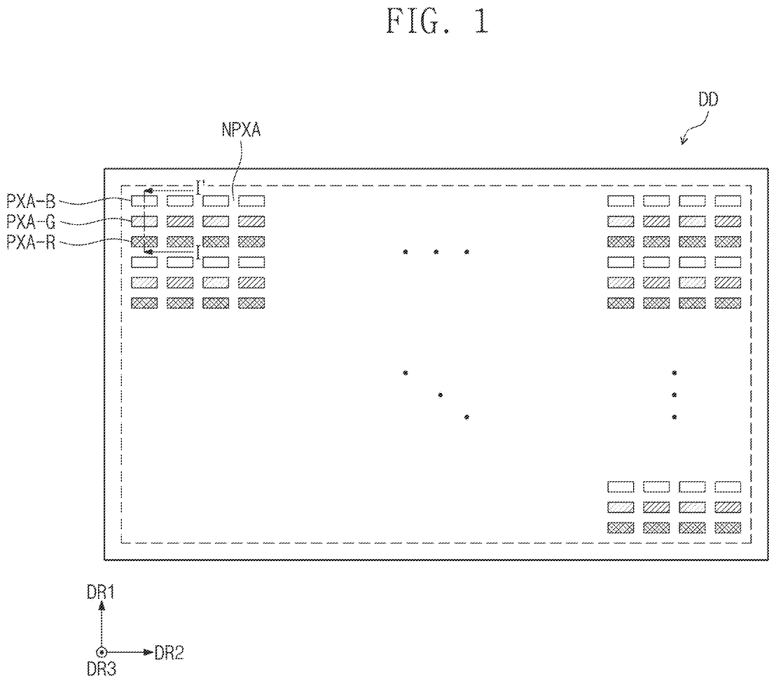

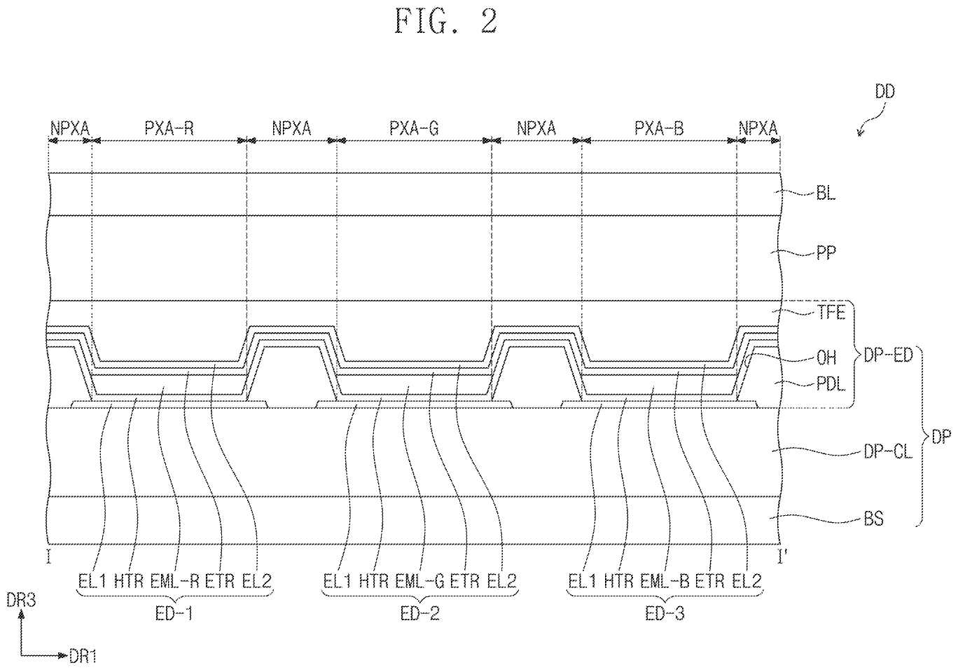

FIG. 1 is a plan view illustrating one or more embodiments of a display apparatus DD. FIG. 2 is a cross-sectional view of the display apparatus DD of one or more embodiments. FIG. 2 is a cross-sectional view illustrating a part taken along line I-I′ of FIG. 1.

The display apparatus DD may include a display panel DP and an optical layer PP provided on the display panel DP. The display panel DP includes light emitting devices ED-1, ED-2, and ED-3. The display apparatus DD may include a plurality of light emitting devices ED-1, ED-2, and ED-3. The optical layer PP may be provided on the display panel DP to control reflected light in the display panel DP due to external light. The optical layer PP may include, for example, a polarization layer or a color filter layer. In some embodiments, unlike the configuration illustrated in the drawing, the optical layer PP may not be provided from the display apparatus DD of one or more embodiments.

A base substrate BL may be provided on the optical layer PP. The base substrate BL may be a member which provides a base surface on which the optical layer PP provided. The base substrate BL may be a glass substrate, a metal substrate, a plastic substrate, etc. However, the embodiment of the present disclosure is not limited thereto, and the base substrate BL may be an inorganic layer, an organic layer, or a composite material layer. In some embodiments, unlike the configuration illustrated, in one or more embodiments, the base substrate BL may not be provided.

The display apparatus DD according to one or more embodiments may further include a filling layer. The filling layer may be provided between a display device layer DP-ED and the base substrate BL. The filling layer may be an organic material layer. The filling layer may include at least one selected from among an acrylic-based resin, a silicone-based resin, and/or an epoxy-based resin (i.e., at least one of an acrylic-based resin, a silicone-based resin, or an epoxy-based resin).

The display panel DP may include a base layer BS, a circuit layer DP-CL provided on the base layer BS, and the display device layer DP-ED. The display device layer DP-ED may include a pixel defining film PDL, the light emitting devices ED-1, ED-2, and ED-3 provided between portions of the pixel defining film PDL, and an encapsulation layer TFE provided on the light emitting devices ED-1, ED-2, and ED-3.

The base layer BS may be a member which provides a base surface on which the display device layer DP-ED is provided. The base layer BS may be a glass substrate, a metal substrate, a plastic substrate, etc. However, the embodiment is not limited thereto, and the base layer BS may be an inorganic layer, an organic layer, or a composite material layer.

In one or more embodiments, the circuit layer DP-CL is provided on the base layer BS, and the circuit layer DP-CL may include a plurality of transistors. Each of the transistors may include a control electrode, an input electrode, and an output electrode. For example, the circuit layer DP-CL may include a switching transistor and a driving transistor for driving the light emitting devices ED-1, ED-2, and ED-3 of the display device layer DP-ED.

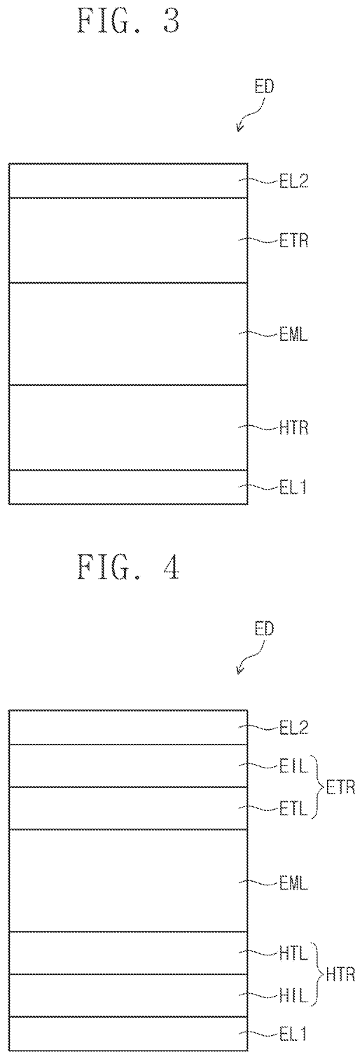

Each of the light emitting devices ED-1, ED-2, and ED-3 may have a structure of each light emitting device ED of embodiments according to FIGS. 3 to 6, as described in more detail elsewhere herein. Each of the light emitting devices ED-1, ED-2, and ED-3 may include a first electrode EL1, a hole transport region HTR, a layer selected from among emission layers EML-R, EML-G, and EML-B, an electron transport region ETR, and a second electrode EL2.

FIG. 2 illustrates one or more embodiments in which the emission layers EML-R, EML-G, and EML-B of the light emitting devices ED-1, ED-2, and ED-3 are provided in openings OH defined in the pixel defining film PDL, and the hole transport region HTR, the electron transport region ETR, and the second electrode EL2 are provided as a common layer in the entire light emitting devices ED-1, ED-2, and ED-3. However, the embodiment of the present disclosure is not limited thereto, and unlike the configuration illustrated in FIG. 2, the hole transport region HTR and the electron transport region ETR in one or more embodiments may be provided by being patterned inside the openings OH defined in the pixel defining film PDL. For example, the hole transport region HTR, the emission layers EML-R, EML-G, and EML-B, and the electron transport region ETR of the light emitting devices ED-1, ED-2, and ED-3 in one or more embodiments may be provided by being patterned in an inkjet printing method.

The encapsulation layer TFE may cover the light emitting devices ED-1, ED-2 and ED-3. The encapsulation layer TFE may seal the display device layer DP-ED. The encapsulation layer TFE may be a thin film encapsulation layer. The encapsulation layer TFE may be formed by laminating one layer or a plurality of layers.

The encapsulation layer TFE includes at least one insulation layer. The encapsulation layer TFE according to one or more embodiments may include at least one inorganic film (hereinafter, an encapsulation-inorganic film). The encapsulation layer TFE according to one or more embodiments may also include at least one organic film (hereinafter, an encapsulation-organic film) and at least one encapsulation-inorganic film.

The encapsulation-inorganic film protects the display device layer DP-ED from moisture/oxygen, and the encapsulation-organic film protects the display device layer DP-ED from foreign substances such as dust particles. The encapsulation-inorganic film may include silicon nitride, silicon oxynitride, silicon oxide, titanium oxide, aluminum oxide, and/or the like, but the embodiment of the present disclosure is not particularly limited thereto. The encapsulation-organic film may include an acrylic-based compound, an epoxy-based compound, and/or the like. The encapsulation-organic film may include a photopolymerizable organic material, but the embodiment of the present disclosure is not particularly limited thereto.

The encapsulation layer TFE may be provided on the second electrode EL2 and may be provided filling the opening OH.

Referring to FIGS. 1 and 2, the display apparatus DD may include one or more non-light emitting region(s) NPXA and light emitting regions PXA-R, PXA-G, and PXA-B. The light emitting regions PXA-R, PXA-G, and PXA-B may be regions in which light generated by the respective light emitting devices ED-1, ED-2, and ED-3 is emitted. The light emitting regions PXA-R, PXA-G, and PXA-B may be spaced from each other on a plane.

Each of the light emitting regions PXA-R, PXA-G, and PXA-B may be a region divided by the pixel defining film PDL. The non-light emitting areas NPXA may be areas between the adjacent light emitting areas PXA-R, PXA-G, and PXA-B, which correspond to the pixel defining film PDL. In some embodiments, in the specification, the light emitting regions PXA-R, PXA-G, and PXA-B may respectively correspond to pixels. The pixel defining film PDL may divide the light emitting devices ED-1, ED-2, and ED-3. The emission layers EML-R, EML-G, and EML-B of the light emitting devices ED-1, ED-2, and ED-3 may be provided in openings OH defined in the pixel defining film PDL and separated from each other.

The light emitting regions PXA-R, PXA-G, and PXA-B may be divided into a plurality of groups according to the color of light generated from the light emitting devices ED-1, ED-2, and ED-3. In the display apparatus DD of one or more embodiments illustrated in FIGS. 1 and 2, three light emitting regions PXA-R, PXA-G, and PXA-B, which emit red light, green light, and blue light, respectively, are illustrated as an example. For example, the display device DD of one or more embodiments may include the red light emitting region PXA-R, the green light emitting region PXA-G, and the blue light emitting region PXA-B that are separated from each other.

In the display apparatus DD according to one or more embodiments, the plurality of light emitting devices ED-1, ED-2 and ED-3 may be to emit (e.g., configured to emit) light beams having wavelengths different from each other. For example, in one or more embodiments, the display apparatus DD may include a first light emitting device ED-1 that emits red light, a second light emitting device ED-2 that emits green light, and a third light emitting device ED-3 that emits blue light. For example, the red light emitting region PXA-R, the green light emitting region PXA-G, and the blue light emitting region PXA-B of the display apparatus DD may correspond to the first light emitting device ED-1, the second light emitting device ED-2, and the third light emitting device ED-3, respectively.

However, the embodiment of the present disclosure is not limited thereto, and the first to third light emitting devices ED-1, ED-2, and ED-3 may be to emit (e.g., configured to emit) light beams in substantially the same wavelength range or at least one light emitting device may be to emit (e.g., configured to emit) a light beam in a wavelength range different from the others. For example, the first to third light emitting devices ED-1, ED-2, and ED-3 may all emit blue light.

The light emitting regions PXA-R, PXA-G, and PXA-B in the display apparatus DD according to one or more embodiments may be arranged in a stripe form. Referring to FIG. 1, the plurality of red light emitting regions PXA-R may be arranged with each other along a second directional axis DR2, the plurality of green light emitting regions PXA-G may be arranged with each other along the second directional axis DR2, and the plurality of blue light emitting regions PXA-B may be arranged with each other along the second directional axis DR2. In some embodiments, the red light emitting region PXA-R, the green light emitting region PXA-G, and the blue light emitting region PXA-B may be alternately arranged with each other in this order along a first directional axis DR1.

FIGS. 1 and 2 illustrate that all the light emitting regions PXA-R, PXA-G, and PXA-B have similar area, but the embodiment of the present disclosure is not limited thereto. Thus, the light emitting regions PXA-R, PXA-G, and PXA-B may have different areas from each other according to the wavelength range of the emitted light. In this case, the areas of the light emitting regions PXA-R, PXA-G, and PXA-B may refer to areas when viewed on a plane defined by the first directional axis DR1 and the second directional axis DR2.

In some embodiments, an arrangement form of the light emitting regions PXA-R, PXA-G, and PXA-B is not limited to the configuration illustrated in FIG. 1, and the order in which the red light emitting region PXA-R, the green light emitting region PXA-G, and the blue light emitting region PXA-B are arranged may be provided in one or more suitable combinations according to the characteristics of display quality required in the display apparatus DD. For example, the arrangement form of the light emitting regions PXA-R, PXA-G, and PXA-B may be a pentile (PENTILE®) arrangement form or a diamond (Diamond Pixel®) arrangement form, (PENTILE® and Diamond Pixel® are registered trademarks owned by Samsung Display Co., Ltd.).

In some embodiments, the areas of the light emitting regions PXA-R, PXA-G, and PXA-B may be different from each other. For example, in an embodiment, the area of the green light emitting region PXA-G may be smaller than that of the blue light emitting region PXA-B, but the embodiment of the present disclosure is not limited thereto.

Hereinafter, FIG. 3 to FIG. 6 are cross-sectional views schematically showing light emitting devices according to one or more embodiments. The light emitting device ED of one or more embodiments may include a first electrode EL1, a hole transport region HTR, an emission layer EML, an electron transport region ETR, and a second electrode EL2 stacked in order.

As illustrated in FIG. 3, the light emitting element ED includes the first electrode EL1, a hole transport region HTR, a light emitting layer EML, an electron transport region ETR, and the second electrode EL2 which are, e.g., sequentially laminated.

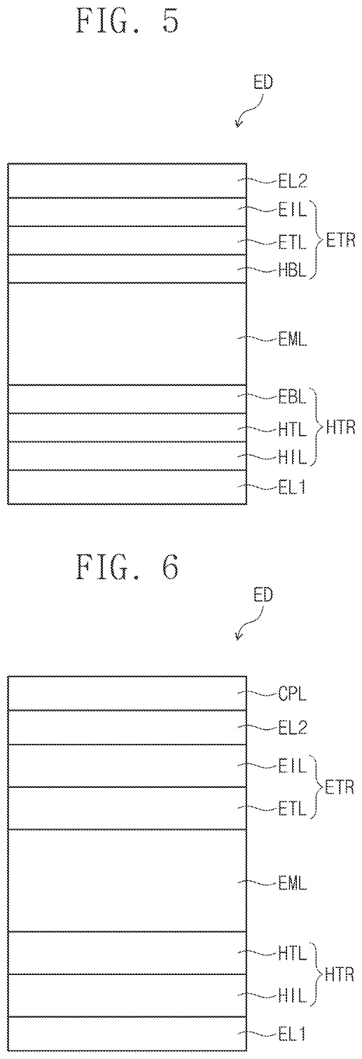

Compared with FIG. 3, FIG. 4 illustrates a cross-sectional view of a light emitting device ED of one or more embodiments, in which a hole transport region HTR includes a hole injection layer HIL and a hole transport layer HTL, and an electron transport region ETR includes an electron injection layer EIL and an electron transport layer ETL. In some embodiments, compared with FIG. 3, FIG. 5 illustrates a cross-sectional view of a light emitting device ED of one or more embodiments, in which a hole transport region HTR includes a hole injection layer HIL, a hole transport layer HTL, and an electron blocking layer EBL, and an electron transport region ETR includes an electron injection layer EIL, an electron transport layer ETL, and a hole blocking layer HBL. Compared with FIG. 4, FIG. 6 illustrates a cross-sectional view of a light emitting device ED of one or more embodiments including a capping layer CPL provided on a second electrode EL2.

The first electrode EL1 has conductivity (e.g., is a conductor). The first electrode EL1 may be formed of a metal material, a metal alloy, or a conductive compound. The first electrode EL1 may be an anode or a cathode. However, the embodiment of the present disclosure is not limited thereto. In some embodiments, the first electrode EL1 may be a pixel electrode. The first electrode EL1 may be a transmissive electrode, a transflective electrode, or a reflective electrode. The first electrode EL1 may include at least one selected from among Ag, Mg, Cu, Al, Pt, Pd, Au, Ni, Nd, Ir, Cr, Li, Ca, LiF, Mo, Ti, W, In, Sn, and Zn, a compound of two or more selected from among these, a mixture of two or more selected from among these, and/or an oxide thereof.

When the first electrode EL1 is the transmissive electrode, the first electrode EL1 may include a transparent metal oxide such as indium tin oxide (ITO), indium zinc oxide (IZO), zinc oxide (ZnO), or indium tin zinc oxide (ITZO). When the first electrode EL1 is the transflective electrode or the reflective electrode, the first electrode EL1 may include Ag, Mg, Cu, Al, Pt, Pd, Au, Ni, Nd, Ir, Cr, Li, Ca, LiF/Ca (a stacked structure of LiF and Ca), LiF/Al (a stacked structure of LiF and Al), Mo, Ti, W, and/or a compound or mixture thereof (e.g., a mixture of Ag and Mg). In some embodiments, the first electrode EL1 may have a multilayer structure including a reflective film or a transflective film formed of the above-described materials, and a transparent conductive film formed of ITO, IZO, ZnO, ITZO, etc. For example, the first electrode EL1 may have a three-layer structure of ITO/Ag/ITO, but the embodiment of the present disclosure is not limited thereto. For example, the embodiment of the present disclosure is not limited thereto, and the first electrode EL1 may include the described metal materials, combinations of at least two metal materials of the above-described metal materials, oxides of the above-described metal materials, and/or the like. The thickness of the first electrode EL1 may be from about 700 angstrom (Å) to about 10,000 Å. For example, the thickness of the first electrode EL1 may be from about 1,000 Å to about 3,000 Å.

The hole transport region HTR is provided on the first electrode EL1. The hole transport region HTR may include at least one of a hole injection layer HIL, a hole transport layer HTL, a buffer layer or an emission-auxiliary layer, or an electron blocking layer EBL. The thickness of the hole transport region HTR may be, for example, from about 50 Å to about 15,000 Å.

The hole transport region HTR may have a single layer formed of a single material, a single layer formed of a plurality of different materials, or a multilayer structure including a plurality of layers formed of a plurality of different materials.

For example, the hole transport region HTR may have a single layer structure of the hole injection layer HIL or the hole transport layer HTL, or may have a single layer structure formed of a hole injection material and a hole transport material. In some embodiments, the hole transport region HTR may have a single layer structure formed of a plurality of different materials, or a structure in which a hole injection layer HIL/hole transport layer HTL, a hole injection layer HIL/hole transport layer HTL/buffer layer, a hole injection layer HIL/buffer layer, a hole transport layer HTL/buffer layer, or a hole injection layer HIL/hole transport layer HTL/electron blocking layer EBL are stacked in order from the first electrode EL1, but the embodiment of the present disclosure is not limited thereto.

The hole transport region HTR may be formed utilizing one or more suitable methods such as a vacuum deposition method, a spin coating method, a cast method, a Langmuir-Blodgett (LB) method, an inkjet printing method, a laser printing method, and/or a laser induced thermal imaging (LITI) method.

The hole transport region HTR may include a compound represented by Formula H-1:

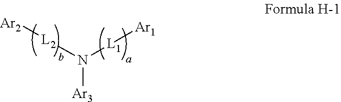

In Formula H-1, L₁ and L₂ may each independently be a direct linkage, a substituted or unsubstituted arylene group having 6 to 30 ring-forming carbon atoms, or a substituted or unsubstituted heteroarylene group having 2 to 30 ring-forming carbon atoms. a and b may each independently be an integer of 0 to 10. In some embodiments, when a or b is an integer of 2 or greater, a plurality of L₁'s and L₂'s may each independently be a substituted or unsubstituted arylene group having 6 to 30 ring-forming carbon atoms, or a substituted or unsubstituted heteroarylene group having 2 to 30 ring-forming carbon atoms.

In Formula H-1, Ar₁ and Ar₂ may each independently be a substituted or unsubstituted aryl group having 6 to 30 ring-forming carbon atoms, or a substituted or unsubstituted heteroaryl group having 2 to 30 ring-forming carbon atoms. In some embodiments, in Formula H-1, Ar₃ may be a substituted or unsubstituted aryl group having 6 to 30 ring-forming carbon atoms, or a substituted or unsubstituted heteroaryl group having 2 to 30 ring-forming carbon atoms.

The compound represented by Formula H-1 may be a monoamine compound. In some embodiments, the compound represented by Formula H-1 may be a diamine compound in which at least one among Ar₁ to Ar₃ includes the amine group as a substituent. In some embodiments, the compound represented by Formula H-1 may be a carbazole-based compound including a substituted or unsubstituted carbazole group in at least one of Ar₁ or Ar₂, or a fluorene-based compound including a substituted or unsubstituted fluorene group in at least one of Ar₁ or Ar₂.

The compound represented by Formula H-1 may be represented by any one selected from among the compounds in Compound Group H. However, the compounds listed in Compound Group H are examples, and the compounds represented by Formula H-1 are not limited to those represented by Compound Group H:

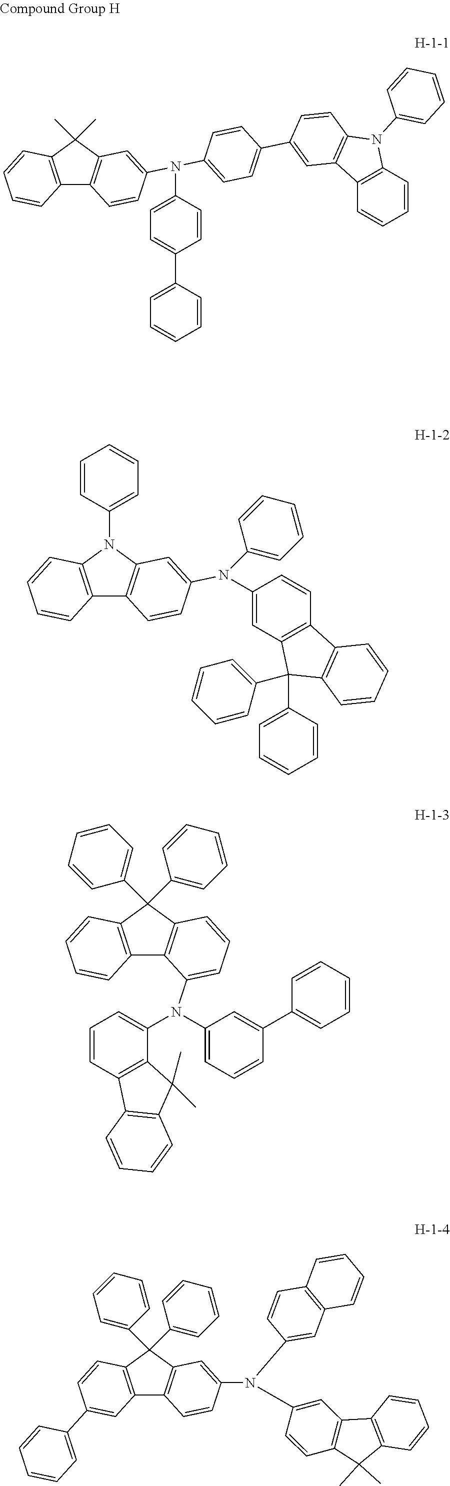 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; c1ccc(N(c2ccc3c(c2)C(c2ccccc2)(c2ccccc2)c2ccccc2-3)c2ccc3c4ccccc4n(-c4ccccc4)c3c2)cc1 ; CC1(C)c2ccccc2-c2cccc(N(c3cccc(-c4ccccc4)c3)c3cccc4c3-c3ccccc3C4(c3ccccc3)c3ccccc3)c21 ; CC1(C)c2ccccc2-c2cc(N(c3ccc4c(c3)C(c3ccccc3)(c3ccccc3)c3ccc(-c5ccccc5)cc3-4)c3ccc4ccccc4c3)ccc21]

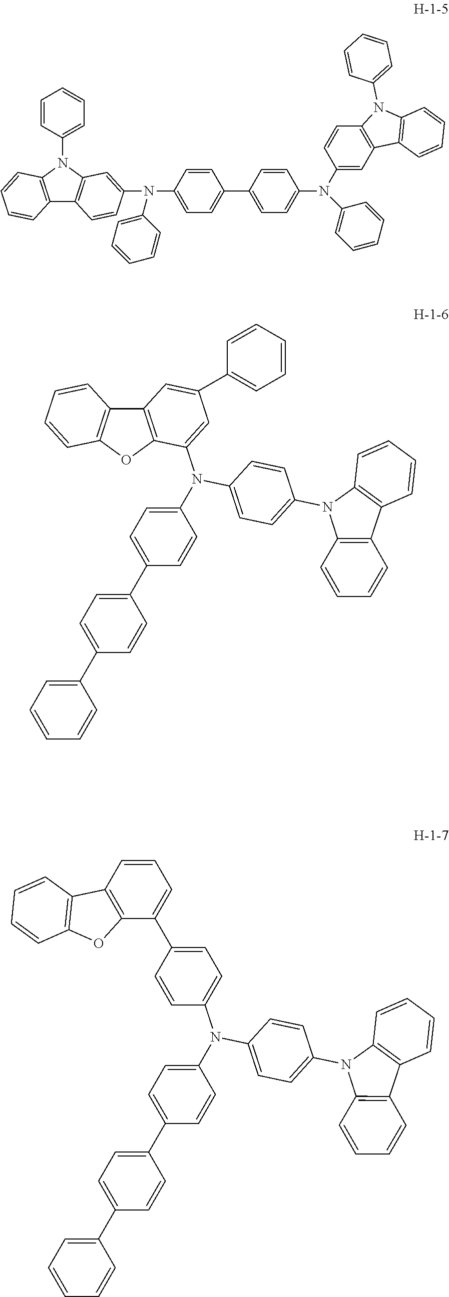 [SMILES: c1ccc(N(c2ccc(-c3ccc(N(c4ccccc4)c4ccc5c6ccccc6n(-c6ccccc6)c5c4)cc3)cc2)c2ccc3c(c2)c2ccccc2n3-c2ccccc2)cc1 ; c1ccc(-c2ccc(-c3ccc(N(c4ccc(-n5c6ccccc6c6ccccc65)cc4)c4cc(-c5ccccc5)cc5c4oc4ccccc45)cc3)cc2)cc1 ; c1ccc(-c2ccc(-c3ccc(N(c4ccc(-c5cccc6c5oc5ccccc56)cc4)c4ccc(-n5c6ccccc6c6ccccc65)cc4)cc3)cc2)cc1]

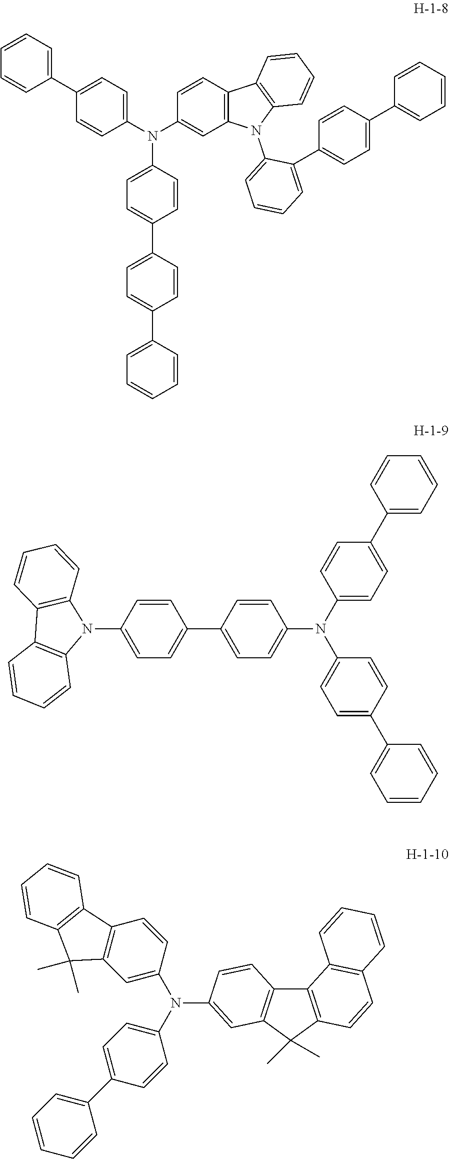 [SMILES: c1ccc(-c2ccc(-c3ccc(N(c4ccc(-c5ccccc5)cc4)c4ccc5c6ccccc6n(-c6ccccc6-c6ccc(-c7ccccc7)cc6)c5c4)cc3)cc2)cc1 ; c1ccc(-c2ccc(N(c3ccc(-c4ccccc4)cc3)c3ccc(-c4ccc(-n5c6ccccc6c6ccccc65)cc4)cc3)cc2)cc1 ; CC1(C)c2ccccc2-c2ccc(N(c3ccc(-c4ccccc4)cc3)c3ccc4c(c3)C(C)(C)c3ccc5ccccc5c3-4)cc21]

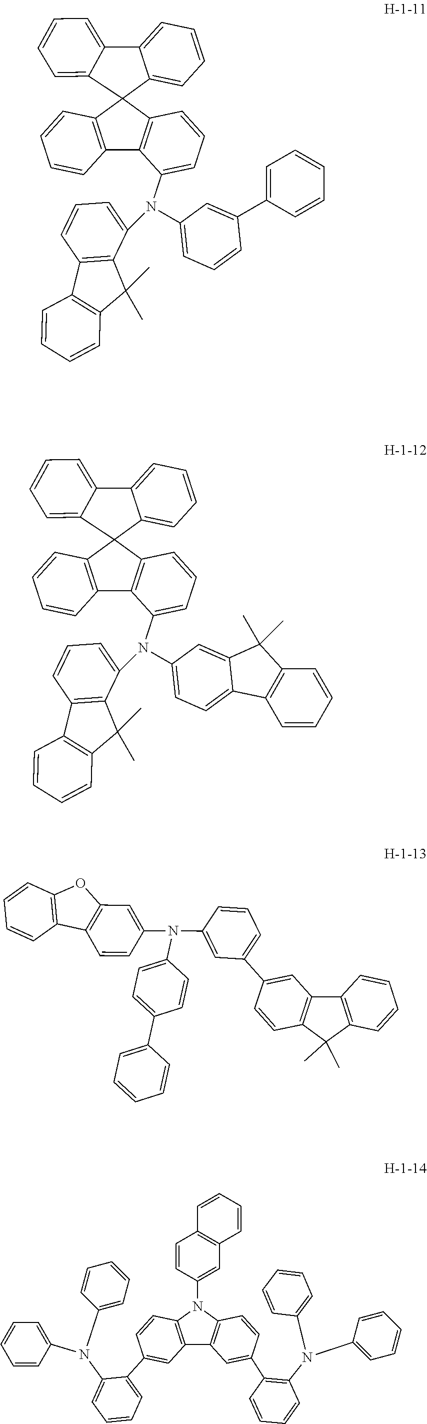 [SMILES: CC1(C)c2ccccc2-c2cccc(N(c3cccc(-c4ccccc4)c3)c3cccc4c3-c3ccccc3C43c4ccccc4-c4ccccc43)c21 ; CC1(C)c2ccccc2-c2ccc(N(c3cccc4c3-c3ccccc3C43c4ccccc4-c4ccccc43)c3cccc4c3C(C)(C)c3ccccc3-4)cc21 ; CC1(C)c2ccccc2-c2cc(-c3cccc(N(c4ccc(-c5ccccc5)cc4)c4ccc5c(c4)oc4ccccc45)c3)ccc21 ; c1ccc(N(c2ccccc2)c2ccccc2-c2ccc3c(c2)c2cc(-c4ccccc4N(c4ccccc4)c4ccccc4)ccc2n3-c2ccc3ccccc3c2)cc1]

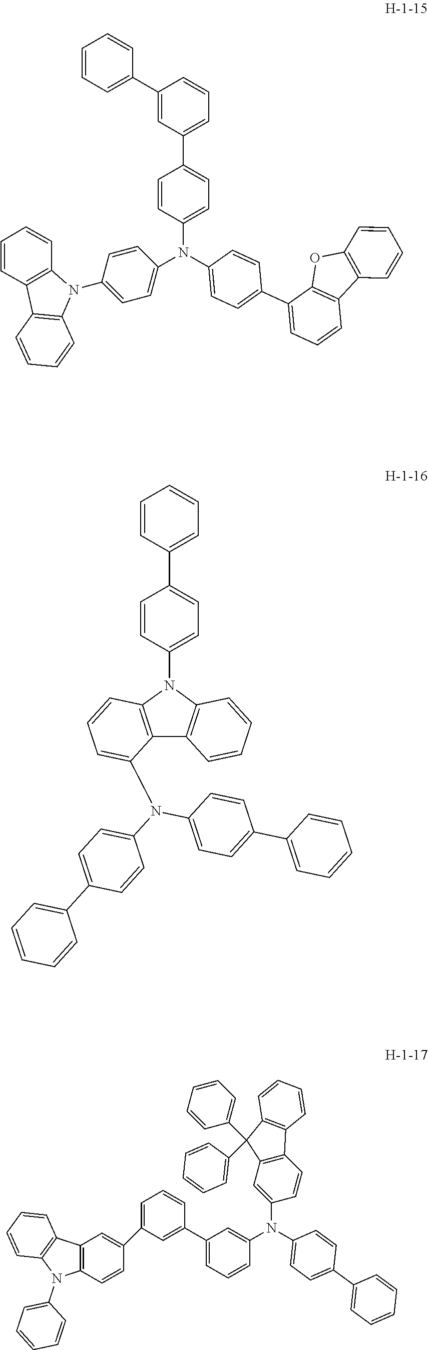 [SMILES: c1ccc(-c2cccc(-c3ccc(N(c4ccc(-c5cccc6c5oc5ccccc56)cc4)c4ccc(-n5c6ccccc6c6ccccc65)cc4)cc3)c2)cc1 ; c1ccc(-c2ccc(N(c3ccc(-c4ccccc4)cc3)c3cccc4c3c3ccccc3n4-c3ccc(-c4ccccc4)cc3)cc2)cc1 ; c1ccc(-c2ccc(N(c3cccc(-c4cccc(-c5ccc6c(c5)c5ccccc5n6-c5ccccc5)c4)c3)c3ccc4c(c3)C(c3ccccc3)(c3ccccc3)c3ccccc3-4)cc2)cc1]

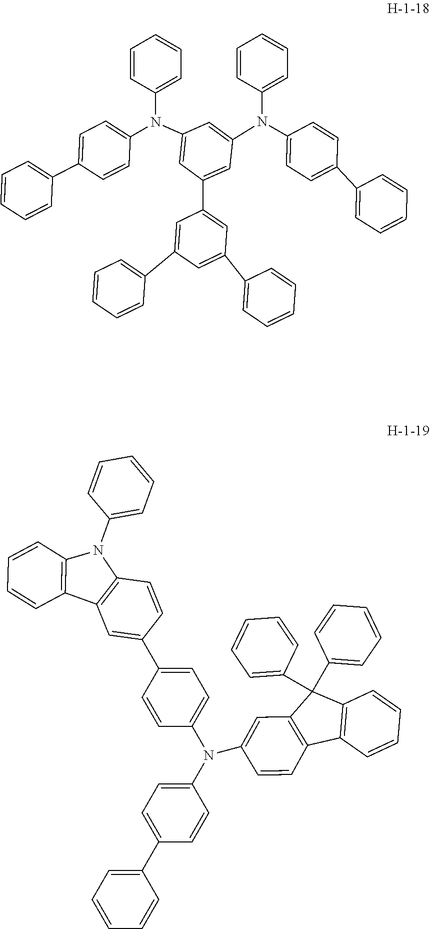 [SMILES: c1ccc(-c2ccc(N(c3ccccc3)c3cc(-c4cc(-c5ccccc5)cc(-c5ccccc5)c4)cc(N(c4ccccc4)c4ccc(-c5ccccc5)cc4)c3)cc2)cc1 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1]

The hole transport region HTR may include at least one selected from among a phthalocyanine compound such as copper phthalocyanine; N¹,N¹′-([1,1′-biphenyl]-4,4′-diyl)bis(N¹-phenyl-N⁴,N⁴-di-m-tolylbenzene-1,4-diamine) (DNTPD), 4,4′,4″-[tris(3-methylphenyl)phenylamino] triphenylamine (m-MTDATA), 4,4′,4″-tris(N,N-diphenylamino)triphenylamine (TDATA), 4,4′,4″-tris[N(2-naphthyl)-N-phenylamino]-triphenylamine (2-TNATA), poly(3,4-ethylenedioxythiophene)/poly(4-styrenesulfonate) (PEDOT/PSS), polyaniline/dodecylbenzenesulfonic acid (PANI/DBSA), polyaniline/camphor sulfonic acid (PANI/CSA), polyaniline/poly(4-styrenesulfonate) (PANI/PSS), N,N′-di(naphthalene-1-yl)-N,N′-diphenyl-benzidine (NPB), triphenylamine-containing polyetherketone (TPAPEK), 4-isopropyl-4′-methyldiphenyliodonium [tetrakis(pentafluorophenyl)borate], dipyrazino[2,3-f: 2′,3′-h]quinoxaline-2,3,6,7,10,11-hexacarbonitrile (HATCN), and/or the like.

The hole transport region HTR may include at least one selected from among a carbazole-based derivative such as N-phenyl carbazole or polyvinyl carbazole, a fluorene-based derivative, a triphenylamine-based derivative such as N,N′-bis(3-methylphenyl)-N,N′-diphenyl-[1,1-biphenyl]-4,4′-diamine (TPD) or 4,4′,4″-tris(N-carbazolyl)triphenylamine (TCTA), N, N′-di(naphthalene-1-yl)-N,N′-diphenyl-benzidine (NPB), 4,4′-cyclohexylidene bis[N, N-bis(4-methylphenyl]benzenamine] (TAPC), 4,4′-bis[N,N′-(3-tolyl)amino]-3,3′-dimethylbiphenyl (HMTPD), 1,3-bis(N-carbazolyl)benzene (mCP), and/or the like.

In some embodiments, the hole transport region HTR may include 9-(4-tert-butylphenyl)-3,6-bis(triphenylsilyl)-9H-carbazole (CzSi), 9-phenyl-9H-3,9′-bicarbazole (CCP), 1,3-bis(1,8-dimethyl-9H-carbazol-9-yl)benzene (mDCP), and/or the like.

The hole transport region HTR may include the described compounds of the hole transport region in at least one selected from among a hole injection layer HIL, a hole transport layer HTL, or an electron blocking layer EBL.

The thickness of the hole transport region HTR may be from about 100 Å to about 10,000 Å, for example, from about 100 Å to about 5,000 Å. When the hole transport region HTR includes the hole injection layer HIL, the hole injection layer HIL may have, for example, a thickness of about 30 Å to about 1,000 Å. When the hole transport region HTR includes the hole transport layer HTL, the hole transport layer HTL may have a thickness of about 250 Å to about 1,000 Å. For example, when the hole transport region HTR includes the electron blocking layer EBL, the electron blocking layer EBL may have a thickness of about 10 Å to about 1,000 Å. When the thicknesses of the hole transport region HTR, the hole injection layer HIL, the hole transport layer HTL and the electron blocking layer EBL satisfy the described ranges, satisfactory hole transport properties may be achieved without a substantial increase in driving voltage.

The hole transport region HTR may further include a charge generating material to increase conductivity in addition to the above-described materials. The charge generating material may be dispersed uniformly or non-uniformly in the hole transport region HTR. The charge generating material may be, for example, a p-dopant. The p-dopant may include at least one selected from among a halogenated metal compound, a quinone derivative, a metal oxide, and/or a cyano group-containing compound, but the embodiment of the present disclosure is not limited thereto. For example, the p-dopant may include a metal halide compound such as CuI or RbI, a quinone derivative such as tetracyanoquinodimethane (TCNQ) or 2,3,5,6-tetrafluoro-7,7′8,8-tetracyanoquinodimethane (F4-TCNQ), a metal oxide such as tungsten oxide or molybdenum oxide, a cyano group-containing compound such as dipyrazino[2,3-f: 2′,3′-h] quinoxaline-2,3,6,7,10,11-hexacarbonitrile (HATCN) or 4-[[2,3-bis[cyano-(4-cyano-2,3,5,6-tetrafluorophenyl)methylidene]cyclopropylidene]-cyanomethyl]-2,3,5,6-tetrafluorobenzonitrile (NDP9), and/or the like, but the embodiment of the present disclosure is not limited thereto.

As described above, the hole transport region HTR may further include at least one of the buffer layer or the electron blocking layer EBL in addition to the hole injection layer HIL and the hole transport layer HTL. The buffer layer may compensate for a resonance distance according to the wavelength of light emitted from the emission layer EML and may thus increase light emission efficiency. A material that may be included in the hole transport region HTR may be utilized as a material to be included in the buffer layer. The electron blocking layer EBL is a layer that serves to prevent or reduce the electron injection from the electron transport region ETR to the hole transport region HTR.

The emission layer EML is provided on the hole transport region HTR. The emission layer EML may have a thickness of, for example, about 100 Å to about 1,000 Å or about 100 Å to about 300 Å. The emission layer EML may have a single layer formed utilizing a single material, a single layer formed utilizing multiple different materials, or a multilayer structure having multiple layers formed utilizing multiple different materials.

The light emitting element ED of one or more embodiments may include the fused polycyclic compound represented by Formula 1 in at least one functional layer provided between the first electrode EL1 and the second electrode EL2. In the light emitting element ED of one or more embodiments, the emission layer EML may include the fused polycyclic compound of one or more embodiments. In one or more embodiments, the emission layer EML may include the fused polycyclic compound of one or more embodiments as a dopant. The fused polycyclic compound of one or more embodiments may be a dopant material of the emission layer EML. In some embodiments, in the description, the fused polycyclic compound of one or more embodiments, which will be explained later, may be referred to as a first compound.

### Fused Polycyclic Compound

The fused polycyclic compound of one or more embodiments may include a fused structure of multiple aromatic rings via a boron atom, and two heteroatoms. For example, the fused polycyclic compound of one or more embodiments may include a fused structure of first to third aromatic rings via a boron atom, a first heteroatom and a second heteroatom. The first to third aromatic rings may be connected with the boron atom, the first aromatic ring and the third aromatic ring may be connected via the first heteroatom, and the second aromatic ring and the third aromatic ring may be connected via the second heteroatom. In one or more embodiments, the first to third aromatic rings may be six-member aromatic hydrocarbon rings. For example, the first to third aromatic rings may be substituted or unsubstituted benzene rings. In one or more embodiments, the first heteroatom and the second heteroatom may each independently be an oxygen atom (O), a sulfur atom (S), a selenium atom (Se), a nitrogen atom (N), a carbon atom (C), or a silicon atom (Si). In some embodiments, in the description, the boron atom, the first heteroatom, and the second heteroatom, and the fused structure formed through the first to third aromatic rings fused via the boron atom, the first heteroatom, and the second heteroatom may be referred to as a “fused ring core”.

The fused polycyclic compound of one or more embodiments may include a first substituent connected with the fused ring core. The first substituent may be connected with at least one among the first to third aromatic rings. The fused polycyclic compound of one or more embodiments may include at least one first substituent. The first substituent may include a heterocycle moiety including a first nitrogen atom as a ring-forming atom. The first nitrogen atom of the first substituent may be connected with at least one among the first to third aromatic rings. The first substituent may be connected with the fused ring core via an arylene linker or directly connected with the fused ring core without a separate linker. In some embodiments, in the description, the first substituent may refer to a substituent represented by Formula 2, as described elsewhere herein.

In one or more embodiments, the first substituent may include a partially unsaturated heterocycle moiety. For example, the first substituent may include a first fused ring in which a first ring including a six-member aromatic hydrocarbon ring and a second ring including a five- or six-member heterocycle including the first nitrogen atom, are fused, and may include a structure in which a third ring including a cycloalkene moiety is fused with the first fused ring. The third ring may be fused adjacent to the second ring. Due to the third ring including the cycloalkene moiety, the first substituent may include at least three or more sp³ hybridized carbon. For example, the first substituent may include three to six sp³ hybridized carbon. For example, the third ring included in the first substituent may include a cycloalkene moiety including Structure A1 to Structure A4. Referring to Structure A1 to Structure A4, the third ring may include first connecting carbon and second connecting carbon, which are connected via a double bond. For example, the first connecting carbon and the second connecting carbon of the third ring may be positioned to be fused with the second ring. In some embodiments, for the convenience of explanation, substituents connected with the cycloalkene moiety in Structure A1 to Structure A4 are omitted. Different from the structures shown in Structure A1 to Structure A4, the cycloalkene moiety may have at least one substituent other than hydrogen.

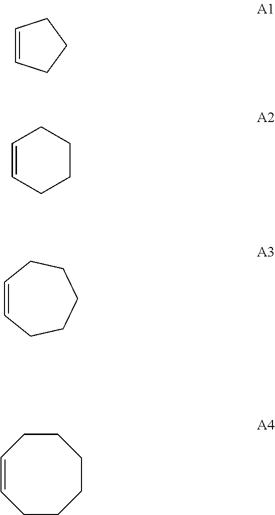 [SMILES: C1=CCCC1 ; C1=CCCCC1 ; C1=CCCCCC1 ; C1=C\CCCCCC/1]

The fused polycyclic compound of one or more embodiments may be represented by Formula 1.

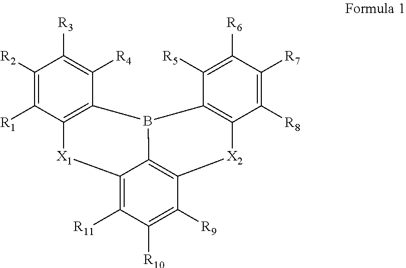

The fused polycyclic compound of one or more embodiments, represented by Formula 1 may include a fused structure of three aromatic rings via a boron atom, a first heteroatom and a second heteroatom. In some embodiments, a benzene ring substituted with substituents represented by R₁ to R₄ in Formula 1 may correspond to the described first aromatic ring, a benzene ring substituted with substituents represented by R₅ to R₈ in Formula 1 may correspond to the described second aromatic ring, and a benzene ring substituted with substituents represented by R₉ to R₁₁ in Formula 1 may correspond to the described third aromatic ring.

In Formula 1, X₁ and X₂ may each independently be O, S, Se, NR₁₂, CR₁₃R₁₄, or SiR₁₅R₁₆.

In Formula 1, R₁ to R₁₆ may each independently be a hydrogen atom, a deuterium atom, a halogen atom, a cyano group, a hydroxyl group, a substituted or unsubstituted oxy group, a substituted or unsubstituted thio group, a substituted or unsubstituted silyl group, a substituted or unsubstituted amine group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, a substituted or unsubstituted heteroaryl group of 2 to 30 ring-forming carbon atoms, or a substituent represented by Formula 2. In some embodiments, each of R₁ to R₁₆ may be combined with an adjacent group to form a ring. For example, R₁ to R₁₆ may each independently be a hydrogen atom, a deuterium atom, a halogen atom, a hydroxyl group, a substituted or unsubstituted methyl group, a substituted or unsubstituted t-butyl group, a substituted or unsubstituted propylene group, a substituted or unsubstituted phenylthio group, a substituted or unsubstituted phenyloxy group, a substituted or unsubstituted trimethylsilyl group, a substituted or unsubstituted dimethylamine group, a substituted or unsubstituted phenyl group, a substituted or unsubstituted benzofuran group, a substituted or unsubstituted benzothiophene group, a substituted or unsubstituted dibenzofuran group, a substituted or unsubstituted dibenzothiophene group, a substituted or unsubstituted pyridine group, or a substituted or unsubstituted triazine group. R₁₂ may be a substituted or unsubstituted phenyl group, a substituted or unsubstituted biphenyl group, a substituted or unsubstituted terphenyl group, a substituted or unsubstituted dibenzofuran group, or a substituted or unsubstituted dibenzothiophene group. In one or more embodiments, R₁₂ may be represented by any one among Formula X-1 to Formula X-5. R₁₃ to R₁₆ may each independently be a substituted or unsubstituted methyl group, a substituted or unsubstituted ethyl group, a substituted or unsubstituted n-propyl group, or a substituted or unsubstituted phenyl group. In the fused polycyclic compound of one or more embodiments, represented by Formula 1, when each of R₁ to R₁₆ is combined with the adjacent group to form the ring, a case including a heterocycle including Si in the ring as a ring-forming atom, or a substituted or unsubstituted benzothiophene moiety, is excluded. The heterocycle including Si in a ring as a ring-forming atom may include a dibenzoazasilane moiety. In some embodiments, in the description, the “benzothiophene moiety” may refer to a heterocycle including Structure S1.

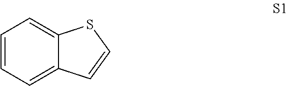

In Formula 1, at least one selected from among R₁ to R₁₁ is represented by Formula 2.

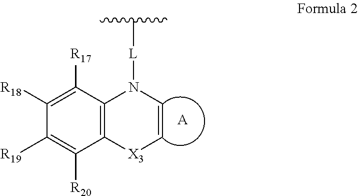

In Formula 2, a benzene ring substituted with substituents R₁₇ to R₂₀ may correspond to the first ring, a five- or six-member heterocycle including N and X₃ may correspond to the second ring, and A may correspond to the third ring.

In Formula 2, L is a direct linkage, or a substituted or unsubstituted arylene group of 6 to 30 ring-forming carbon atoms. For example, L may be a direct linkage or a substituted or unsubstituted phenylene group.

In Formula 2, X₃ is a direct linkage, O, S, Se, NR₂₁, CR₂₂R₂₃, or SiR₂₄R₂₅.

In Formula 2, R₁₇ to R₂₅ may each independently be a hydrogen atom, a deuterium atom, a halogen atom, a cyano group, a hydroxyl group, a substituted or unsubstituted oxy group, a substituted or unsubstituted thio group, a substituted or unsubstituted silyl group, a substituted or unsubstituted amine group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms. In some embodiments, each of R₁₇ to R₂₅ may be combined with an adjacent group to form a ring. For example, R₁₇ to R₂₅ may be hydrogen atoms, deuterium atoms, halogen atoms, or substituted or unsubstituted phenyl groups. R₂₁ may be a substituted or unsubstituted phenyl group. R₂₂ to R₂₅ may each independently be a substituted or unsubstituted methyl group.

In Formula 2, “

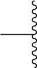

” is a position connected with Formula 1.

In Formula 2, A is represented by Formula 3.

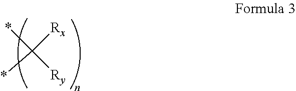

In Formula 3, Rₓ and R_{y} may each independently be a hydrogen atom, a deuterium atom, a halogen atom, a cyano group, a hydroxyl group, a substituted or unsubstituted oxy group, a substituted or unsubstituted thio group, a substituted or unsubstituted silyl group, a substituted or unsubstituted amine group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms. In some embodiments, each of Rₓ and R_{y} may be combined with an adjacent group to form a ring. For example, Rₓ and R_{y} may be hydrogen atoms.

In Formula 3, “n” is an integer of 3 to 6, and In Formula 3, “—*” is a position connected with Formula 2.

In one or more embodiments, the substituent represented by Formula 2 may be represented by any one selected from among Formula 2-1-1 to Formula 2-1-4.

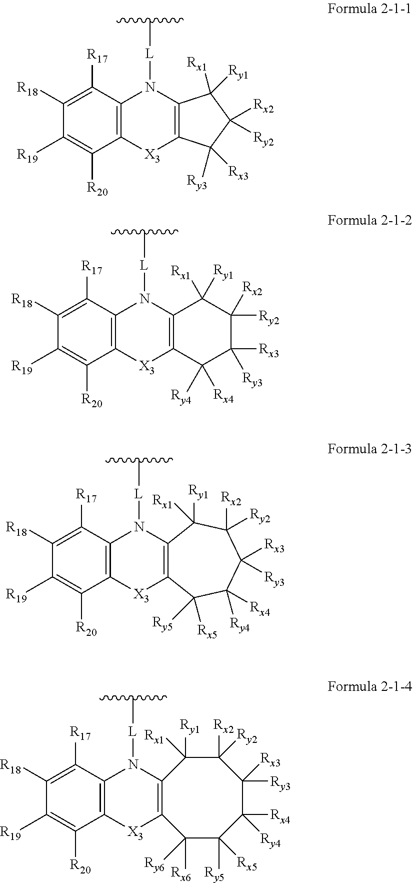

Formula 2-1-1 to Formula 2-1-4 represent cases of Formula 2 where “n” is specified. Formula 2-1-1 represents a case of Formula 2 where “n” is 3. Formula 2-1-2 represents a case of Formula 2 where “n” is 4. Formula 2-1-3 represents a case of Formula 2 where “n” is 5. Formula 2-1-4 represents a case of Formula 2 where “n” is 6.

In Formula 2-1-1 to Formula 2-1-4, Rₓ1 to Rₓ6, and R_{y1} to R_{y6} may each independently be a hydrogen atom, a deuterium atom, a halogen atom, a cyano group, a hydroxyl group, a substituted or unsubstituted oxy group, a substituted or unsubstituted thio group, a substituted or unsubstituted silyl group, a substituted or unsubstituted amine group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms. In some embodiments, each of Rₓ₁ to Rₓ₆, and R_{y1} to R_{y6} may be combined with an adjacent group to form a ring. Each of Rₓ₁ to Rₓ₆, and R_{y1} to R_{y6} may be a hydrogen atom.

In Formula 2-1-1 to Formula 2-1-4, the contents as those explained in Formula 2 may be applied for L, X₃, and R₁₇ to R₂₀.

In one or more embodiments, the substituent represented by Formula 2 may be represented by any one selected from among Formula 2-2-1 to Formula 2-2-7.

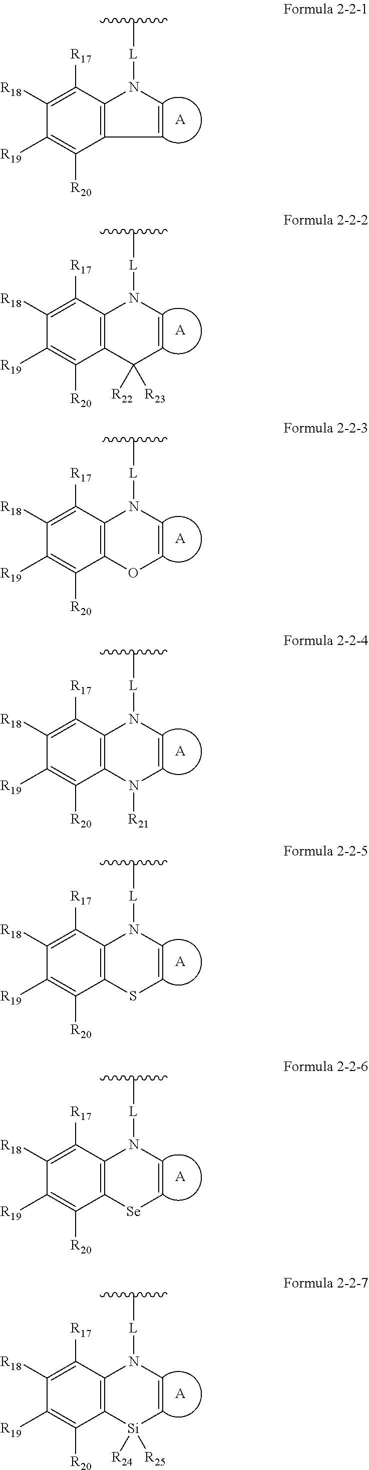

Formula 2-2-1 to Formula 2-2-7 represent cases of Formula 2 where the type or kind of X₃ is specified. Formula 2-2-1 represents a case of Formula 2 where X₃ is a direct linkage. Formula 2-2-2 represents a case of Formula 2 where X₃ is CR₂₂R₂₃. Formula 2-2-3 represents a case of Formula 2 where X₃ is O. Formula 2-2-4 represents a case of Formula 2 where X₃ is NR₂₁. Formula 2-2-5 represents a case of Formula 2 where X₃ is S. Formula 2-2-6 represents a case of Formula 2 where X₃ is Se. Formula 2-2-7 represents a case of Formula 2 where X₃ is SiR₂₄R₂₅.

In Formula 2-2-1 to Formula 2-2-7, the contents as those explained in Formula 2 may be applied for L, R₁₇ to R₂₅, and A.

In one or more embodiments, the substituent represented by Formula 2 may be represented by Formula 2-3-1 or Formula 2-3-2.

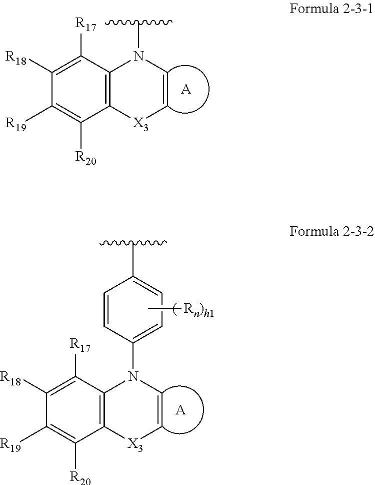

In Formula 2-3-2, Rn is a hydrogen atom, a deuterium atom, a halogen atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms. In some embodiments, Rₙ may be combined with an adjacent group to form a ring. For example, Rₙ may be a hydrogen atom or a deuterium atom.

In Formula 2-3-2, h1 is an integer of 0 to 4. In Formula 2-3-2, when h1 is 0, the fused polycyclic compound of one or more embodiments may be unsubstituted with Rₙ. In Formula 2-3-2, a case where h1 is 4, and all Rₙ are hydrogen atoms, may be the same as a case of Formula 2-3-2 where h1 is 0. When h1 is an integer of 2 or more, multiple Rₙ may be all the same, or at least one among multiple Rₙ may be different.

In Formula 2-3-1 and Formula 2-3-2, the contents as those explained in Formula 2 may be applied for A, X₃, and R₁₇ to R₂₀.

In one or more embodiments, the fused polycyclic compound represented by Formula 1 may be represented by any one selected from among Formula 1-1-1 to Formula 1-1-3.

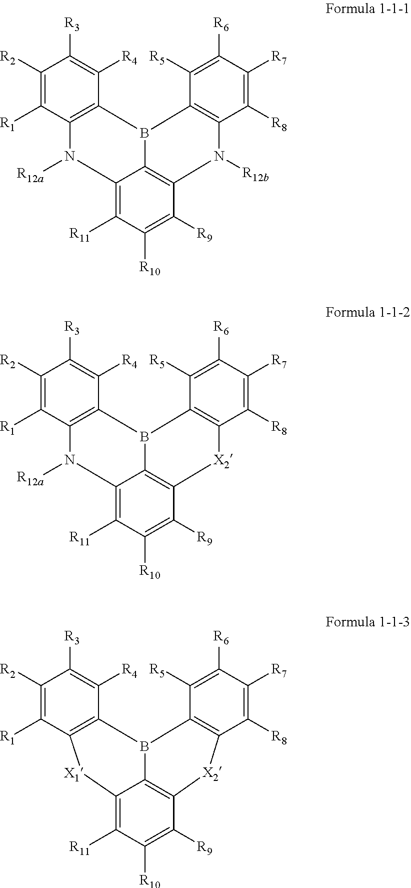

Formula 1-1-1 to Formula 1-1-3 represent cases of Formula 1 where X₁ and X₂ are specified.

In Formula 1-1-1 to Formula 1-1-3, X₁′ and X₂′ may each independently be O, S, Se, CR₂₆R₂₇, or SiR₂₈R₂₉. X₁′ and X₂′ may be the same or different from each other.

In Formula 1-1-1 to Formula 1-1-3, R₂₆ to R₂₉ may each independently be a hydrogen atom, a deuterium atom, a substituted or unsubstituted alkyl group of 1 to 20 carbon atoms, be each independently aryl group of 6 to 30 ring-forming carbon atoms, or a substituted or unsubstituted heteroaryl group of 2 to 30 ring-forming carbon atoms. In some embodiments, each of R₂₆ to R₂₉ may be combined with an adjacent group to form a ring. R₂₆ to R₂₉ may each independently be a substituted or unsubstituted methyl group, a substituted or unsubstituted ethyl group, a substituted or unsubstituted n-propyl group, or a substituted or unsubstituted phenyl group.

In Formula 1-1-1 to Formula 1-1-3, R₁₂ₐ and R_{12b} may each independently be a substituted or unsubstituted aryl group of 6 to 30 ring-forming carbon atoms, or a substituted or unsubstituted heteroaryl group of 2 to 30 ring-forming carbon atoms. In some embodiments, each of R₁₂ₐ and R_{12b} may be combined with an adjacent group to form a ring. For example, R₁₂ₐ and R_{12b} may each independently be a substituted or unsubstituted phenyl group, a substituted or unsubstituted biphenyl group, a substituted or unsubstituted terphenyl group, a substituted or unsubstituted dibenzofuran group, or a substituted or unsubstituted dibenzothiophene group.

In Formula 1-1-1 to Formula 1-1-3, the contents as those explained in Formula 1 may be applied for R₁ to R₁₁.

In one or more embodiments, R₁₂ₐ and R_{12b} may each independently be represented by any one selected from among Formula X-1 to Formula X-5.

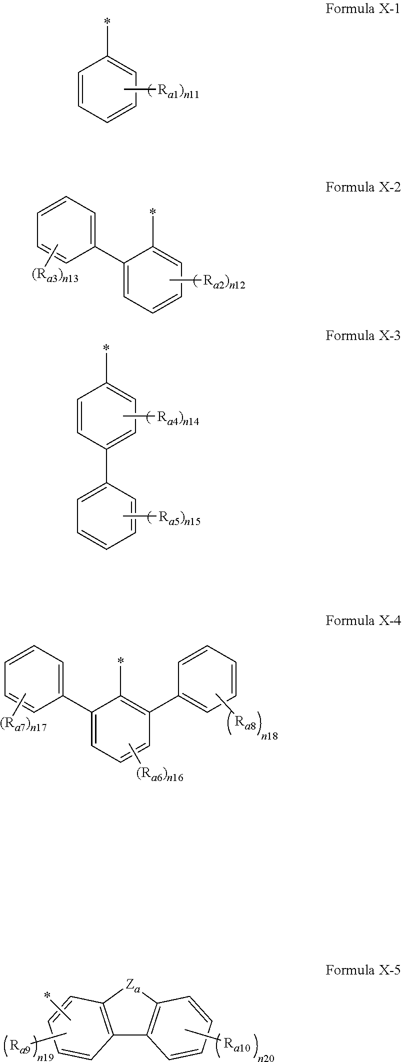

In Formula X-1 to Formula X-5, Rₐ₁ to Rₐ₁₀ may each independently be a hydrogen atom, a deuterium atom, a halogen atom, a cyano group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms. For example, Rₐ₁ may be a hydrogen atom, a deuterium atom, a halogen atom, a substituted or unsubstituted methyl group, a substituted or unsubstituted t-butyl group, a substituted or unsubstituted phenyloxy group, a substituted or unsubstituted phenylthio group, a substituted or unsubstituted benzofuran group, a substituted or unsubstituted benzothiophene group, or a substituted or unsubstituted triazine group. Rₐ₂ to Rₐ₈ may each independently be a hydrogen atom, a deuterium atom, or a substituted or unsubstituted t-butyl group. Rₐ₉ and Rₐ₁₀ may each independently be a hydrogen atom or a deuterium atom.

In Formula X-5, Zₐ may be O or S.

In Formula X-1 to Formula X-4, n11, n13, n15, n17, and n18 may each

independently be an integer of 0 to 5. In Formula X-1 to Formula X-4, when n11, n13, n15, n17, and n18 are 0, the fused polycyclic compound of one or more embodiments may be unsubstituted with Rₐ₁, Rₐ₃, Rₐ₅, Rₐ₇, and Rₐ₈, respectively. In Formula X-1 to Formula X-4, cases where n11, n13, n15, n17, and n18 are 5, and Rₐ₁, Rₐ₃, Rₐ₅, Rₐ₇, and Rₐ₈ are all hydrogen atoms, may be the same as cases of Formula X-1 to Formula X-4 where n11, n13, n15, n17, and n18 are 0, respectively. When n11, n13, n15, n17, and n18 are integers of 2 or more, each of multiple Rₐ₁, Rₐ₃, Rₐ₅, Rₐ₇, and Rₐ₈ may be all the same, or at least one among each of multiple (i.e., two or more selected from among) Rₐ₁, Rₐ₃, Rₐ₅, Rₐ₇, and Rₐ₈ may be different (i.e., from each other).

In Formula X-2, Formula X-3 and Formula X-5, n12, n14, and n20 may each independently be an integer of 0 to 4. In Formula X-2, Formula X-3 and Formula X-5, when n12, n14, and n20 are 0, the fused polycyclic compound of one or more embodiments may be unsubstituted with Rₐ₂, Rₐ₄, and Rₐ₁₀, respectively. In Formula X-2, Formula X-3 and Formula X-5, cases where n12, n14, and n20 are 4, and Rₐ₂, Rₐ₄, and Rₐ₁₀ are all hydrogen atoms, may be the same as cases of Formula X-2, Formula X-3 and Formula X-5 where n12, n14, and n20 are 0, respectively. When n12, n14, and n20 are integers of 2 or more, each of multiple Rₐ₂, Rₐ₄, and Rₐ₁₀ may be all the same, or at least one among each of multiple Rₐ₂, Rₐ₄, and Rₐ₁₀ may be different.

In Formula X-4 and Formula X-5, n16 and n19 may each independently be an integer of 0 to 3. In Formula X-4 and Formula X-5, when n16 and n19 are 0, the fused polycyclic compound of one or more embodiments may be unsubstituted with Rₐ₆, and Rₐ₉, respectively. In Formula X-4 and Formula X-5, cases where n16 and n19 are 3, and Rₐ₈ and Rag are all hydrogen atoms, may be the same as cases of Formula X-4 and Formula X-5 where n16 and n19 are 0, respectively. When n16 and n19 are integers of 2 or more, each of multiple Rₐ₈ and Rₐ₉ may be all the same, or at least one among each of multiple Rₐ₆ and Ray may be different.

In Formula X-1 to Formula X-5, “z,900 *” is a position connected with the nitrogen atom of Formula 1-1-1.

In one or more embodiments, R₁₂ₐ and R_{12b} may each independently be selected from Compound Group A.

### Compound Group A

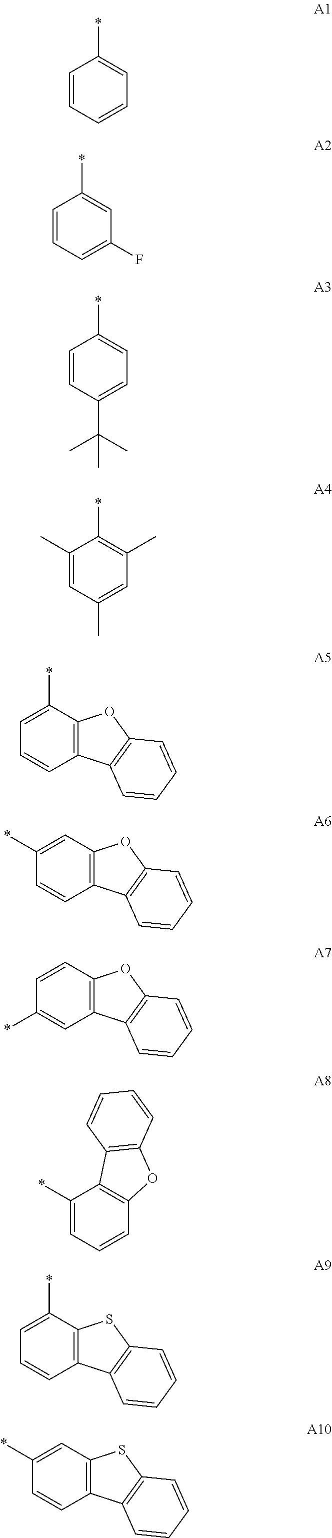

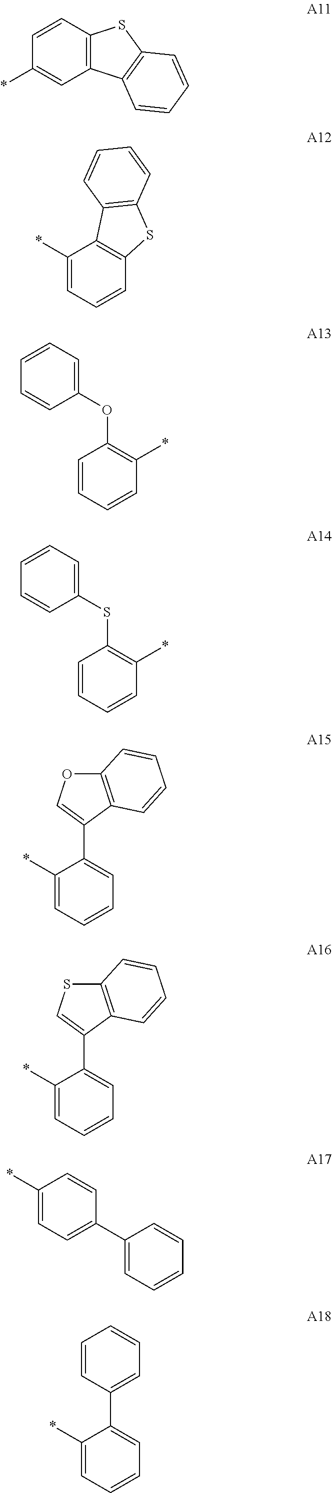

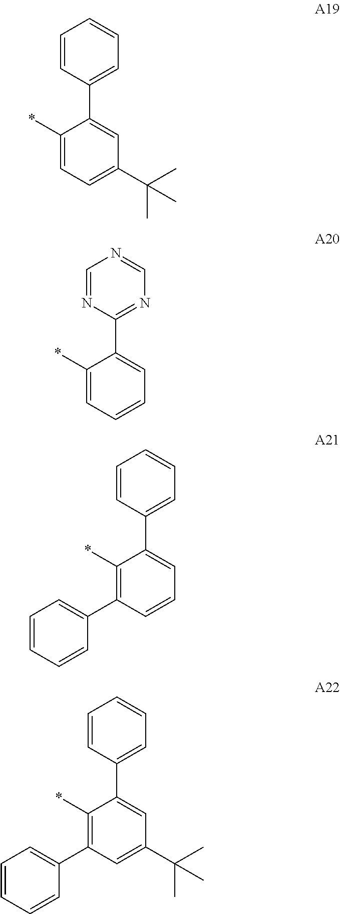

In one or more embodiments, the fused polycyclic compound represented by Formula 1 may be represented by Formula 1-2-1 or Formula 1-2-2.

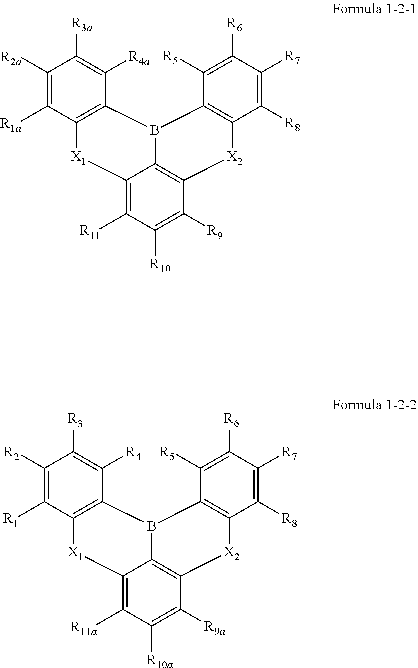

Formula 1-2-1 and Formula 1-2-2 represent cases of Formula 1 where a position connected of the substituent represented by Formula 2 is specified.

In Formula 1-2-1 and Formula 1-2-2, R₁ₐ to R₄ₐ, and R₉ₐ to R₁₁ₐ may each independently be a hydrogen atom, a deuterium atom, a halogen atom, a cyano group, a hydroxyl group, a substituted or unsubstituted oxy group, a substituted or unsubstituted thio group, a substituted or unsubstituted silyl group, a substituted or unsubstituted amine group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, a substituted or unsubstituted heteroaryl group of 2 to 30 ring-forming carbon atoms, or the substituent represented by Formula 2. In some embodiments, each of R₁ₐ to R₄ₐ, and Rea to R₁₁ₐ may be combined with an adjacent group to form a ring.

In Formula 1-2-1, at least one selected from among R₁ₐ to R₄ₐ may be represented by Formula 2. In Formula 1-2-1, at least one selected from among R₅ to R₁₁ may be represented by Formula 2. At positions other than at least one selected from among R₁ₐ to R₄ₐ, the substituent represented by Formula 2 may not be substituted further (e.g., any more). For example, the substituent represented by Formula 2 may be substituted only at positions at least one selected from among R₁ₐ to R₄ₐ, and the substituent represented by Formula 2 may be unsubstituted at the remaining positions.

In Formula 1-2-2, at least one selected from among R₉ₐ to R₁₁ₐ may be represented by Formula 2. In Formula 1-2-2, at least one selected from among R₁ to R₈ may be represented by Formula 2. At positions other than at least one selected from among R₉ₐ to R₁₁ₐ, the substituent represented by Formula 2 may not be substituted further (e.g., any more). For example, the substituent represented by Formula 2 may be substituted only at positions at least one selected from among R₉ₐ to R₁₁ₐ, and the substituent represented by Formula 2 may be unsubstituted at the remaining positions.

In Formula 1-2-1 and Formula 1-2-2, the contents as those explained in Formula 1 may be applied for X₁, X₂, and R₁ to R₁₁.

In one or more embodiments, the fused polycyclic compound represented by Formula 1 may be represented by any one selected from among Formula 1-3-1 to Formula 1-3-3.

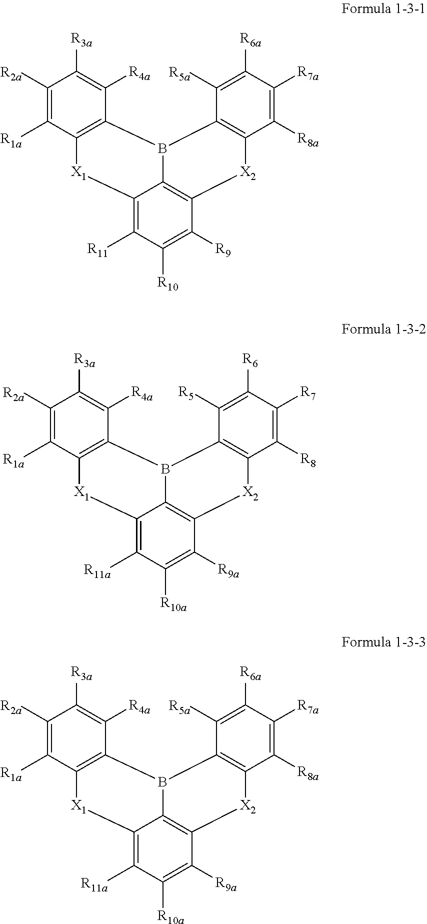

In Formula 1-3-1 to Formula 1-3-3, R₁ₐ to R₁₁ₐ may each independently be a hydrogen atom, a deuterium atom, a halogen atom, a cyano group, a hydroxyl group, a substituted or unsubstituted oxy group, a substituted or unsubstituted thio group, a substituted or unsubstituted silyl group, a substituted or unsubstituted amine group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, a substituted or unsubstituted heteroaryl group of 2 to 30 ring-forming carbon atoms, or the substituent represented by Formula 2. In some embodiments, each of R₁ₐ to R₁₁ₐ may be combined with an adjacent group to form a ring.

In Formula 1-3-1, at least one selected from among R₁ₐ to R₄ₐ, and at least one selected from among R₅ₐ to R₈ₐ may each independently be represented by Formula 2.

In Formula 1-3-2, at least one selected from among R₁ₐ to R₄ₐ, and at least one selected from among R₉ₐ to R₁₁ₐ may each independently be represented by Formula 2.

In Formula 1-3-3, at least one selected from among R₁ₐ to R₄ₐ, at least one selected from among R₅ₐ to R₈ₐ, and at least one selected from among R₉ₐ to R₁₁ₐ may each independently be represented by Formula 2.

In Formula 1-3-1 to Formula 1-3-3, the contents as those explained in Formula 1 may be applied for X₁, X₂, and R₅ to R₁₁.

In one or more embodiments, the fused polycyclic compound represented by Formula 1 may be represented by Formula 1-4-1 or Formula 1-4-2.

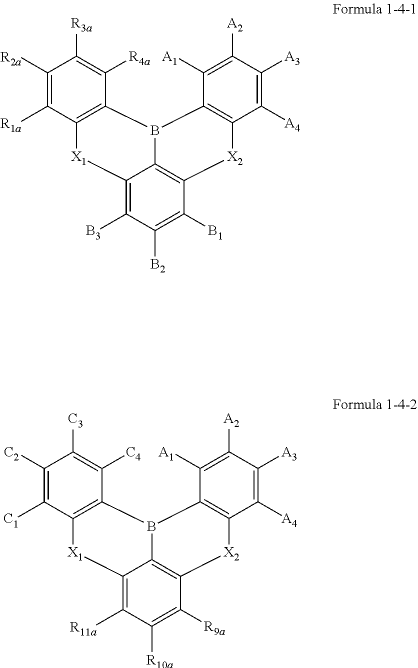

In Formula 1-4-1 and Formula 1-4-2, A₁ to A₄, B₁ to B₃, and C₁ to C₄ may each independently be a hydrogen atom, a deuterium atom, a substituted or unsubstituted alkyl group of 1 to 10 carbon atoms, or the substituent represented by Formula 2 or Formula C1. For example, A₁ to A₄, B₁ to B₃, and C₁ to C₄ may each independently be a hydrogen atom, a deuterium atom, a substituted or unsubstituted t-butyl group, or the substituent represented by Formula 2 or Formula C1.

In Formula 1-4-1 and Formula 1-4-2, R₁ₐ to R₄ₐ, and R₉ₐ to R₁₁ₐ may each independently be a hydrogen atom, a deuterium atom, a halogen atom, a cyano group, a hydroxyl group, a substituted or unsubstituted oxy group, a substituted or unsubstituted thio group, a substituted or unsubstituted silyl group, a substituted or unsubstituted amine group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, a substituted or unsubstituted heteroaryl group of 2 to 30 ring-forming carbon atoms, or the substituent represented by Formula 2. In some embodiments, each of R₁ₐ to R₄ₐ, and R₉ₐ to R₁₁ₐ may be combined with an adjacent group to form a ring. For example, R₁ₐ to R₄ₐ, and R₉ₐ to R₁₁ₐ may each independently be a hydrogen atom, a deuterium atom, or the substituent represented by Formula 2.

In Formula 1-4-1, at least one selected from among R₁ₐ to R₄ₐ may be represented by Formula 2.

In Formula 1-4-2, at least one selected from among R₉ₐ to R₁₁ₐ may be represented by Formula 2.

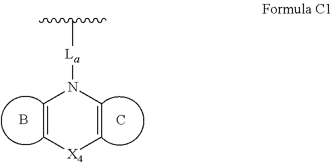

In Formula C1, Lₐ may be a direct linkage, or a substituted or unsubstituted arylene group of 6 to 30 ring-forming carbon atoms. For example, Lₐ may be a direct linkage.

In Formula C1, X₄ may be a direct linkage, O, S, Se, NR₃₁, CR₃₂R₃₃, or SiR₃₄R₃₅. For example, X₄ may be a direct linkage.

In Formula C1, R₃₁ to R₃₅ may each independently be a hydrogen atom, a deuterium atom, a halogen atom, a cyano group, a hydroxyl group, a substituted or unsubstituted oxy group, a substituted or unsubstituted thio group, a substituted or unsubstituted silyl group, a substituted or unsubstituted amine group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms. In some embodiments, each of R₃₁ to R₃₅ may be combined with an adjacent group to form a ring. For example, R₃₁ to R₃₅ may each independently be a substituted or unsubstituted methyl group, or a substituted or unsubstituted phenyl group.

In Formula C1, B and C may each independently be represented by Formula C2

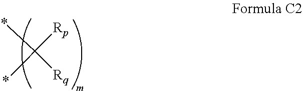

In Formula C2, Rₚ and R_{q} may each independently be a hydrogen atom, a deuterium atom, a halogen atom, a cyano group, a hydroxyl group, a substituted or unsubstituted oxy group, a substituted or unsubstituted thio group, a substituted or unsubstituted silyl group, a substituted or unsubstituted amine group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms. In some embodiments, each of Rₚ and R_{q} may be combined with an adjacent group to form a ring. For example, Rₚ and R_{q} may be hydrogen atoms.

In Formula C2, “m” is an integer of 3 to 6.

In Formula 1-4-1 and Formula 1-4-2, the contents as those explained in Formula 1 may be applied for X₁ and X₂.

In one or more embodiments, the substituent represented by Formula C1 may be represented by any one selected from among Formula C1-1 to Formula C1-10.

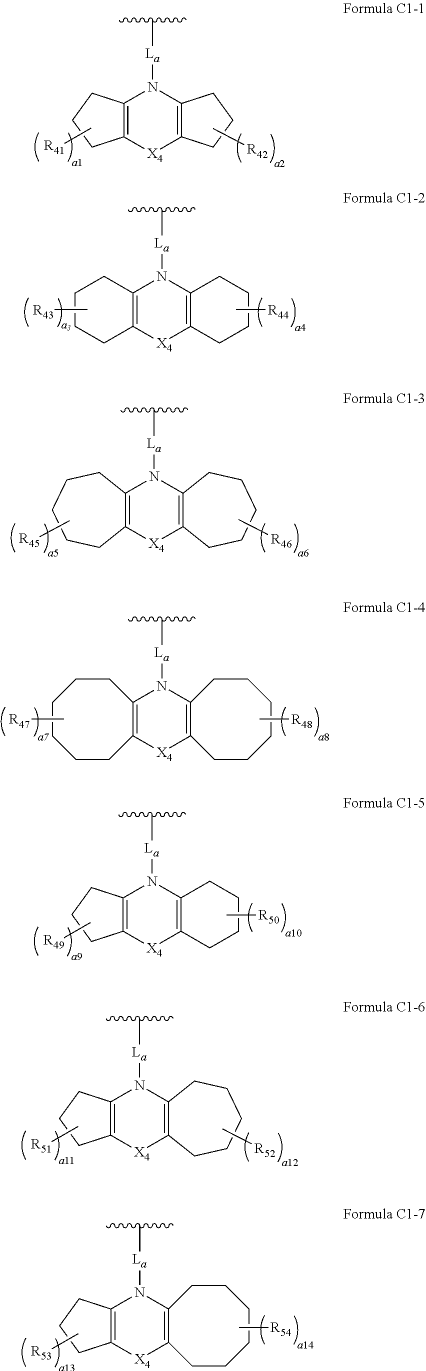

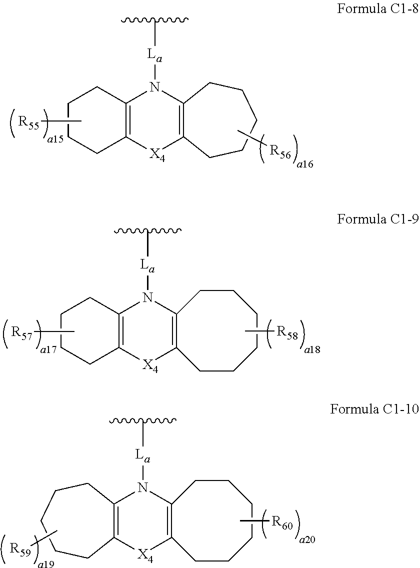

In Formula C1-1 to Formula C1-10, R₄₁ to R₆₀ may each independently be a hydrogen atom, a deuterium atom, a halogen atom, a cyano group, a hydroxyl group, a substituted or unsubstituted oxy group, a substituted or unsubstituted thio group, a substituted or unsubstituted silyl group, a substituted or unsubstituted amine group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms. In some embodiments, each of R₄₁ to R₆₀ may be combined with an adjacent group to form a ring. For example, R₄₁ to R₆₀ may be hydrogen atoms.

In Formula C1-1, and Formula C1-5 to Formula C1-7, a1, a2, a9, a11, and a13 may each independently be an integer of 0 to 6. In Formula C1-1, and Formula C1-5 to Formula C1-7, when a1, a2, a9, a11, and a13 are 0, the fused polycyclic compound of one or more embodiments may be unsubstituted with R₄₁, R₄₂, R₄₉, R₅₁, and R₅₃, respectively. In Formula C1-1, and Formula C1-5 to Formula C1-7, cases where a1, a2, a9, a11, and a13 are 6, and R₄₁, R₄₂, R₄₉, R₅₁, and R₅₃ are all hydrogen atoms, may be the same as cases of Formula C1-1, and Formula C1-5 to Formula C1-7 where a1, a2, a9, a11, and a13 are 0, respectively. When a1, a2, a9, a11, and a13 are integers of 2 or more, each of multiple R₄₁, R₄₂, R₄₉, R₅₁, and R₅₃ may be all the same, or at least one among each of multiple R₄₁, R₄₂, R₄₉, R₅₁, and R₅₃ may be different.

In Formula C1-2, Formula C1-5, Formula C1-8, and Formula C1-9, a3, a4, a10, a15, and a17 may each independently be an integer of 0 to 8. In Formula C1-2, Formula C1-5, Formula C1-8, and Formula C1-9, when a3, a4, a10, a15, and a17 are 0, the fused polycyclic compound of one or more embodiments may be unsubstituted with R₄₃, R₄₄, R₅₀, R₅₅, and R₅₇, respectively. In Formula C1-2, Formula C1-5, Formula C1-8, and Formula C1-9, cases where a3, a4, a10, a15, and a17 are 8, and R₄₃, R₄₄, R₅₀, R₅₅, and R₅₇ are all hydrogen atoms, may be the same as cases of Formula C1-2, Formula C1-5, Formula C1-8, and Formula C1-9 where a3, a4, a10, a15, and a17 are 0, respectively. When a3, a4, a10, a15, and a17 are integers of 2 or more, each of multiple R₄₃, R₄₄, R₅₀, R₅₅, and R₅₇ may be all the same, or at least one among each of multiple R₄₃, R₄₄, R₅₀, R₅₅, and R₅₇ may be different.

In Formula C1-3, Formula C1-6, Formula C1-8, and Formula C1-10, a5, a6, a12, a16, and a19 may each independently be an integer of 0 to 10. In Formula C1-3, Formula C1-6, Formula C1-8, and Formula C1-10, when a5, a6, a12, a16, and a19 are 0, the fused polycyclic compound of one or more embodiments may be unsubstituted with R₄₅, R₄₆, R₅₂, R₅₆, and R₅₉, respectively. In Formula C1-3, Formula C1-6, Formula C1-8, and Formula C1-10, cases where a5, a6, a12, a16, and a19 are 10, and R₄₅, R₄₆, R₅₂, R₅₆, and R₅₉ are all hydrogen atoms, may be the same as cases of Formula C1-3, Formula C1-6, Formula C1-8, and Formula C1-10 where a5, a6, a12, a16, and a19 are 0, respectively. When a5, a6, a12, a16, and a19 are integers of 2 or more, each of multiple R₄₅, R₄₆, R₅₂, R₅₆, and R₅₉ may be all the same, or at least one among each of multiple R₄₅, R₄₆, R₅₂, R₅₆, and R₅₉ may be different.

In Formula C1-4, Formula C1-7, Formula C1-9, and Formula C1-10, a7, a8, a14, a18, and a20 may each independently be an integer of 0 to 12. In Formula C1-4, Formula C1-7, Formula C1-9, and Formula C1-10, when a7, a8, a14, a18, and a20 are 0, the fused polycyclic compound of one or more embodiments may be unsubstituted with R₄₇, R₄₈, R₅₄, R₅₈, and R₆₀, respectively. In Formula C1-4, Formula C1-7, Formula C1-9, and Formula C1-10, cases where a7, a8, a14, a18, and a20 are 12, and R₄₇, R₄₈, R₅₄, R₅₈, and R₆₀ are all hydrogen atoms, may be the same as cases of Formula C1-4, Formula C1-7, Formula C1-9, and Formula C1-10 where a7, a8, a14, a18, and a20 are 0, respectively. When a7, a8, a14, a18, and a20 are integers of 2 or more, each of multiple R₄₇, R₄₈, R₅₄, R₅₈, and R₆₀ may be all the same, or at least one among each of multiple R₄₇, R₄₈, R₅₄, R₅₈, and R₆₀ may be different.

In one or more embodiments, the fused polycyclic compound represented by Formula 1 may be represented by any one selected from among Formula 1-5-1 to Formula 1-5-3.

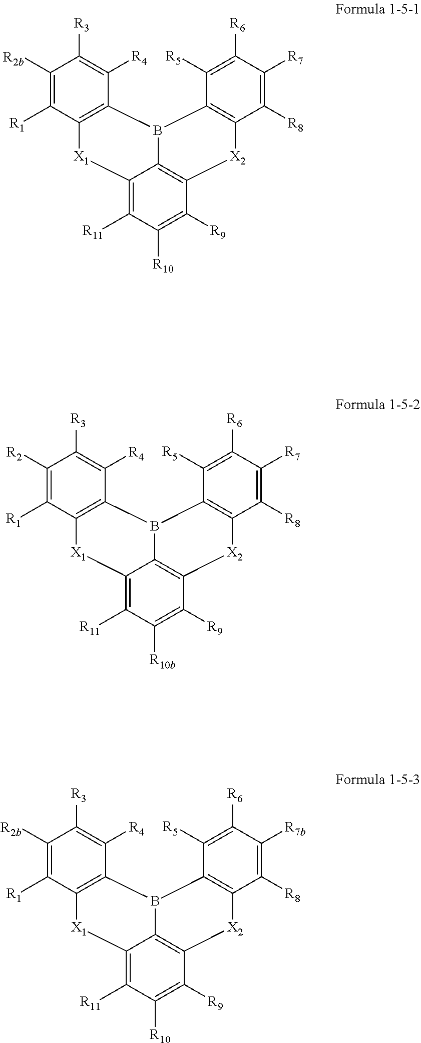

In Formula 1-5-1 to Formula 1-5-3, R_{2b} and R_{10b} may each independently be represented by Formula 2.

In Formula 1-5-3, R_{7b} may be represented by Formula 2 or Formula C1.

In Formula 1-5-1 to Formula 1-5-3, the contents as those explained in Formula 1 may be applied for X₁, X₂ and R₁ to R₁₁.

In one or more embodiments, the fused polycyclic compound represented by Formula 1 may be represented by any one selected from among Formula 1-6-1 to Formula 1-6-3.

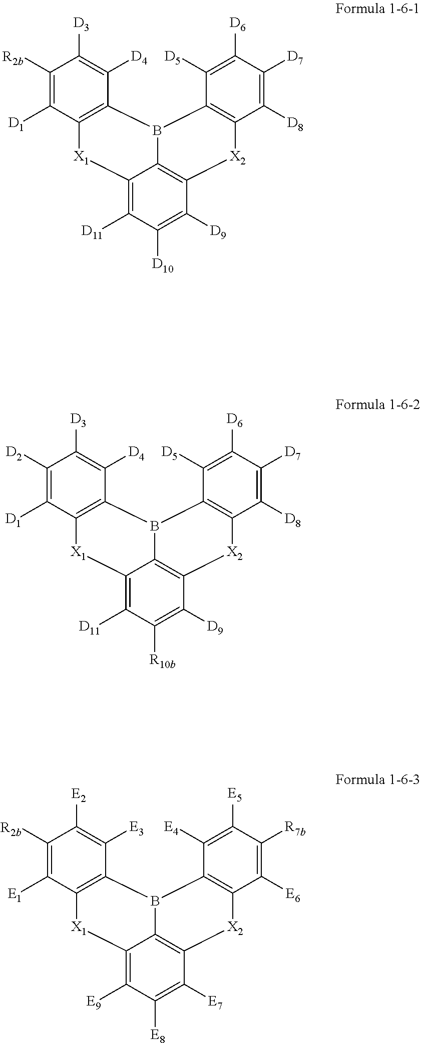

In Formula 1-6-1 and Formula 1-6-2, D₁ to D₁₁ may each independently be a hydrogen atom or a deuterium atom.

In Formula 1-6-3, E₁ to E₉ may each independently be a hydrogen atom, a deuterium atom, or a substituted or unsubstituted alkyl group of 1 to 10 carbon atoms.

In Formula 1-6-1 to Formula 1-6-3, R_{2b} and R₁₀₀ may each independently be represented by Formula 2.

In Formula 1-6-3, R_{7b} may be represented by Formula 2 or Formula C1.

In Formula 1-6-1 to Formula 1-6-3, the contents as those explained in Formula 1 may be applied for X₁ and X₂.

The fused polycyclic compound of one or more embodiments may be any one selected from among the compounds represented in Compound Group 1. The light emitting element ED of one or more embodiments may include at least one fused polycyclic compound selected from among Compound Group 1 in an emission layer EML.

### Compound Group 1

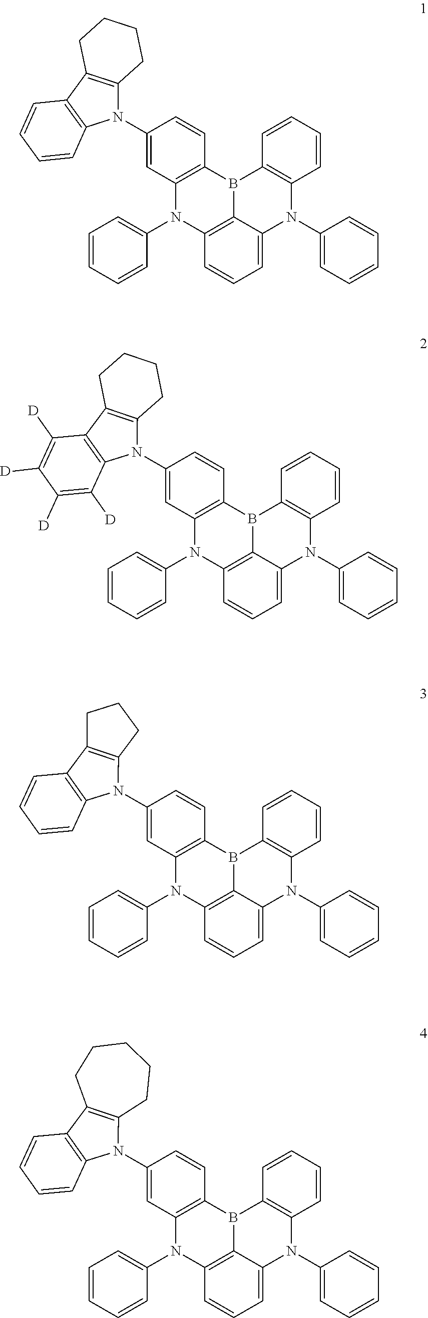 [SMILES: c1ccc(N2c3ccccc3B3c4ccc(-n5c6c(c7ccccc75)CCCC6)cc4N(c4ccccc4)c4cccc2c43)cc1 ; [2H]c1c([2H])c([2H])c2c(c1[2H])c1c(n2-c2ccc3c(c2)N(c2ccccc2)c2cccc4c2B3c2ccccc2N4c2ccccc2)CCCC1 ; c1ccc(N2c3ccccc3B3c4ccc(-n5c6c(c7ccccc75)CCC6)cc4N(c4ccccc4)c4cccc2c43)cc1 ; c1ccc(N2c3ccccc3B3c4ccc(-n5c6c(c7ccccc75)CCCCC6)cc4N(c4ccccc4)c4cccc2c43)cc1]

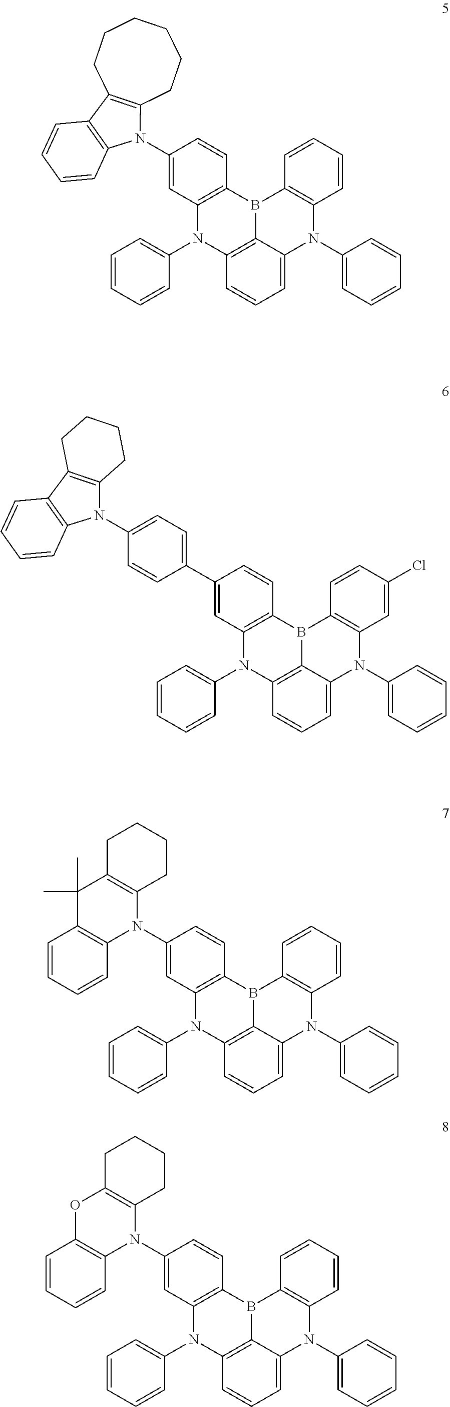

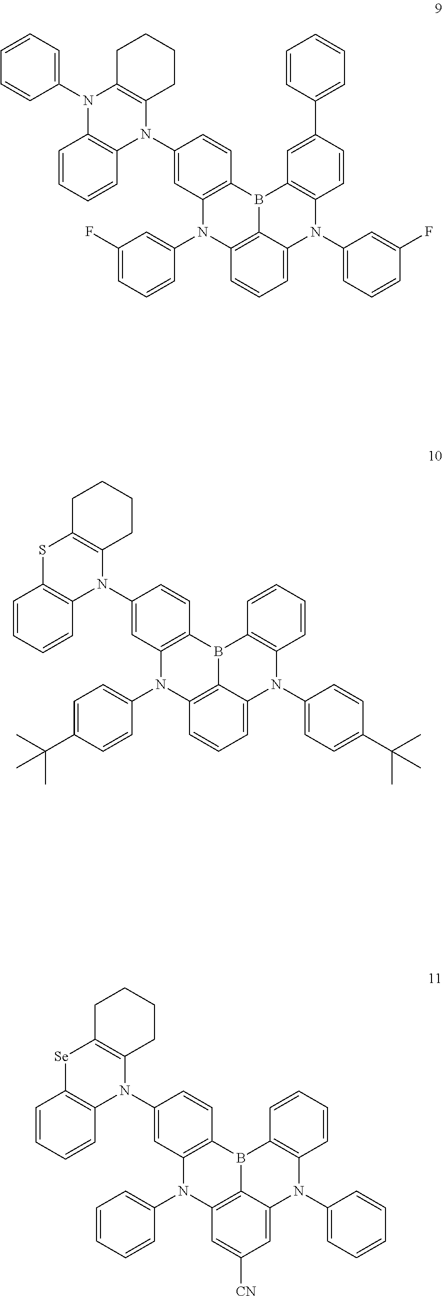 [SMILES: Fc1cccc(N2c3ccc(-c4ccccc4)cc3B3c4ccc(N5C6=C(CCCC6)N(c6ccccc6)c6ccccc65)cc4N(c4cccc(F)c4)c4cccc2c43)c1 ; CC(C)(C)c1ccc(N2c3ccccc3B3c4ccc(N5C6=C(CCCC6)Sc6ccccc65)cc4N(c4ccc(C(C)(C)C)cc4)c4cccc2c43)cc1 ; N#Cc1cc2c3c(c1)N(c1ccccc1)c1cc(N4C5=C(CCCC5)[Se]c5ccccc54)ccc1B3c1ccccc1N2c1ccccc1]

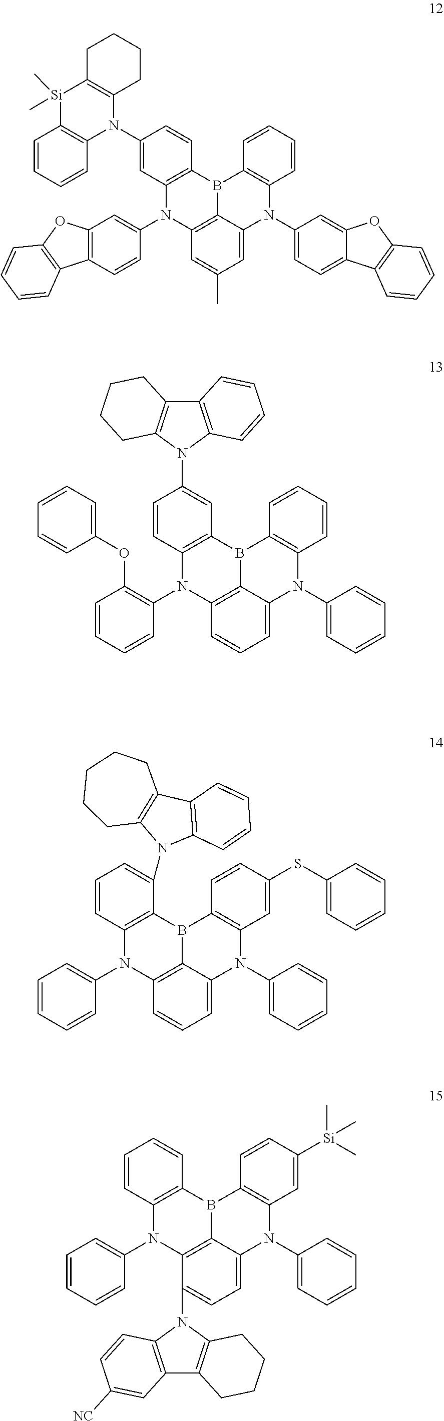 [SMILES: Cc1cc2c3c(c1)N(c1ccc4c(c1)oc1ccccc14)c1cc(N4C5=C(CCCC5)[Si](C)(C)c5ccccc54)ccc1B3c1ccccc1N2c1ccc2c(c1)oc1ccccc12 ; c1ccc(Oc2ccccc2N2c3ccc(-n4c5c(c6ccccc64)CCCC5)cc3B3c4ccccc4N(c4ccccc4)c4cccc2c43)cc1 ; c1ccc(Sc2ccc3c(c2)N(c2ccccc2)c2cccc4c2B3c2c(cccc2-n2c3c(c5ccccc52)CCCCC3)N4c2ccccc2)cc1 ; C[Si](C)(C)c1ccc2c(c1)N(c1ccccc1)c1ccc(-n3c4c(c5cc(C#N)ccc53)CCCC4)c3c1B2c1ccccc1N3c1ccccc1]

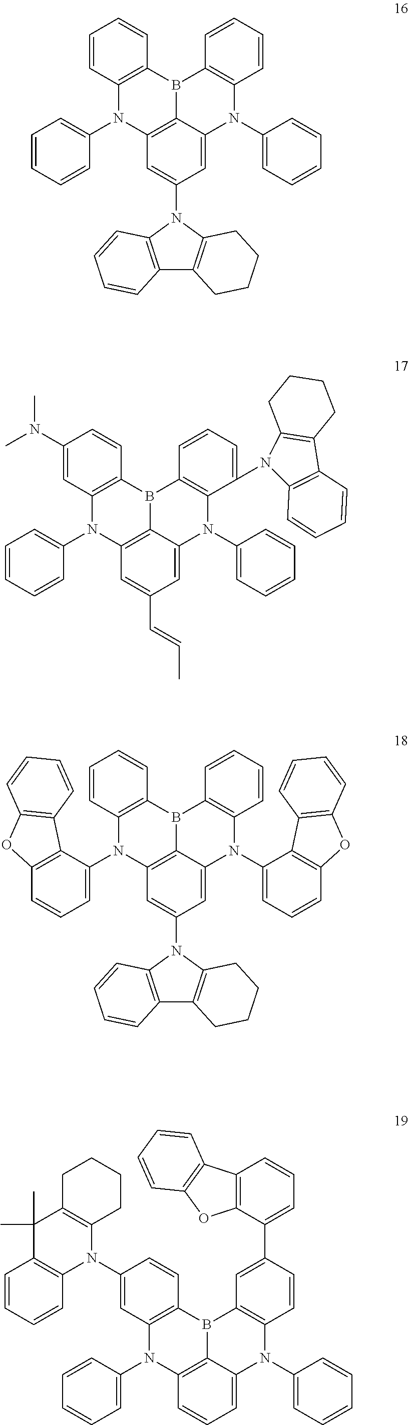 [SMILES: c1ccc(N2c3ccccc3B3c4ccccc4N(c4ccccc4)c4cc(-n5c6c(c7ccccc75)CCCC6)cc2c43)cc1 ; C/C=C/c1cc2c3c(c1)N(c1ccccc1)c1c(cccc1-n1c4c(c5ccccc51)CCCC4)B3c1ccc(N(C)C)cc1N2c1ccccc1 ; c1ccc2c(c1)B1c3ccccc3N(c3cccc4oc5ccccc5c34)c3cc(-n4c5c(c6ccccc64)CCCC5)cc(c31)N2c1cccc2oc3ccccc3c12 ; CC1(C)C2=C(CCCC2)N(c2ccc3c(c2)N(c2ccccc2)c2cccc4c2B3c2cc(-c3cccc5c3oc3ccccc35)ccc2N4c2ccccc2)c2ccccc21]

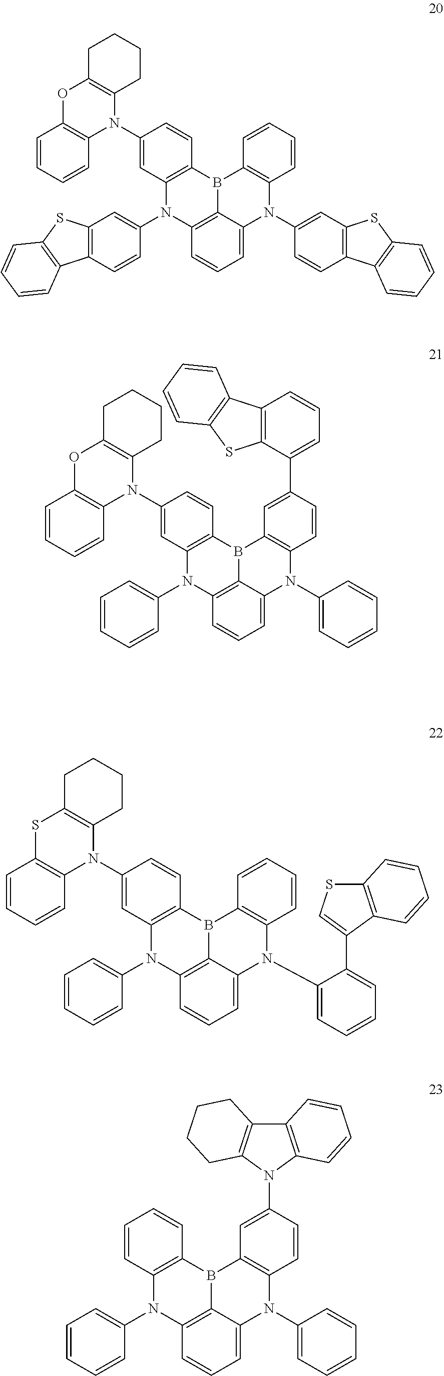 [SMILES: c1ccc2c(c1)OC1=C(CCCC1)N2c1ccc2c(c1)N(c1ccc3c(c1)sc1ccccc13)c1cccc3c1B2c1ccccc1N3c1ccc2c(c1)sc1ccccc12 ; c1ccc(N2c3ccc(-c4cccc5c4sc4ccccc45)cc3B3c4ccc(N5C6=C(CCCC6)Oc6ccccc65)cc4N(c4ccccc4)c4cccc2c43)cc1 ; c1ccc(N2c3cc(N4C5=C(CCCC5)Sc5ccccc54)ccc3B3c4ccccc4N(c4ccccc4-c4csc5ccccc45)c4cccc2c43)cc1 ; c1ccc(N2c3ccccc3B3c4cc(-n5c6c(c7ccccc75)CCCC6)ccc4N(c4ccccc4)c4cccc2c43)cc1]

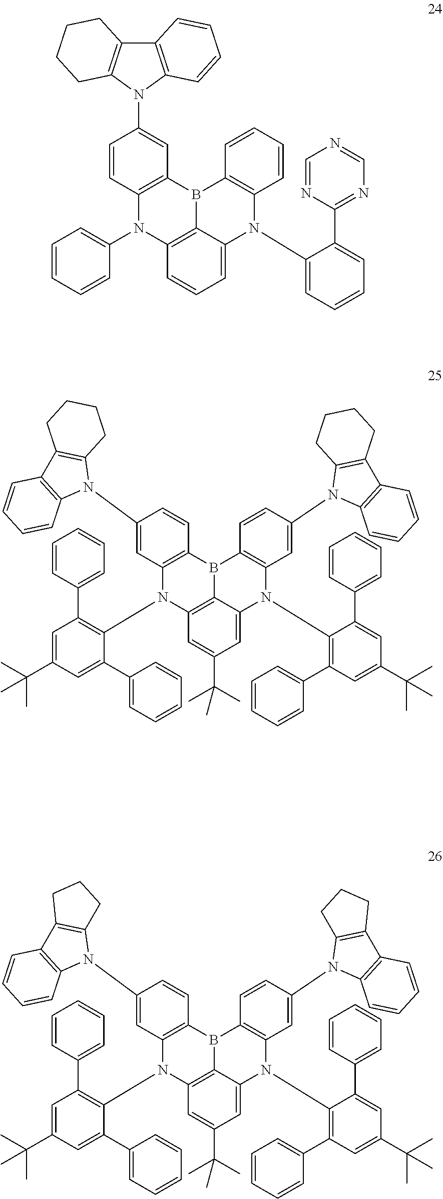

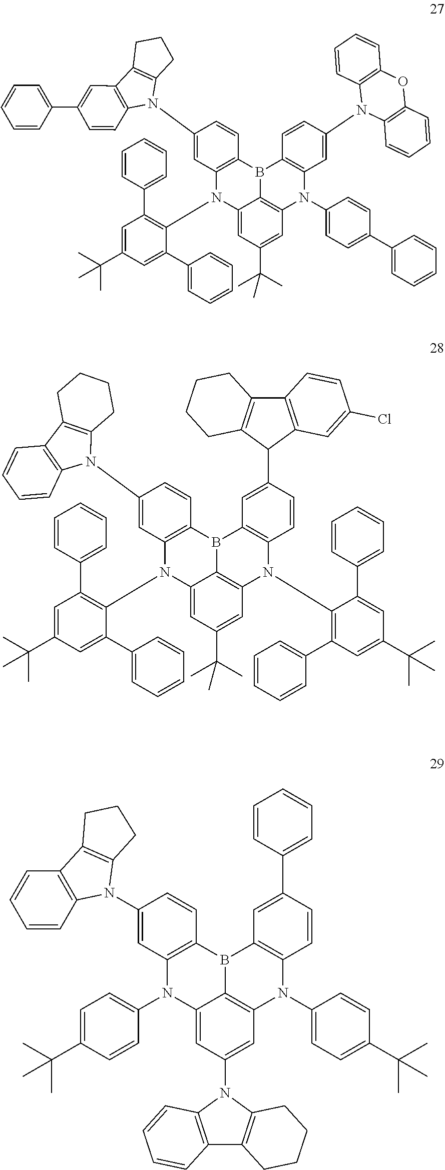 [SMILES: CC(C)(C)c1cc(-c2ccccc2)c(N2c3cc(-n4c5c(c6cc(-c7ccccc7)ccc64)CCC5)ccc3B3c4ccc(N5c6ccccc6Oc6ccccc65)cc4N(c4ccc(-c5ccccc5)cc4)c4cc(C(C)(C)C)cc2c43)c(-c2ccccc2)c1 ; CC(C)(C)c1cc(-c2ccccc2)c(N2c3ccc(C4C5=C(CCCC5)c5ccc(Cl)cc54)cc3B3c4ccc(-n5c6c(c7ccccc75)CCCC6)cc4N(c4c(-c5ccccc5)cc(C(C)(C)C)cc4-c4ccccc4)c4cc(C(C)(C)C)cc2c43)c(-c2ccccc2)c1 ; CC(C)(C)c1ccc(N2c3ccc(-c4ccccc4)cc3B3c4ccc(-n5c6c(c7ccccc75)CCC6)cc4N(c4ccc(C(C)(C)C)cc4)c4cc(-n5c6c(c7ccccc75)CCCC6)cc2c43)cc1]

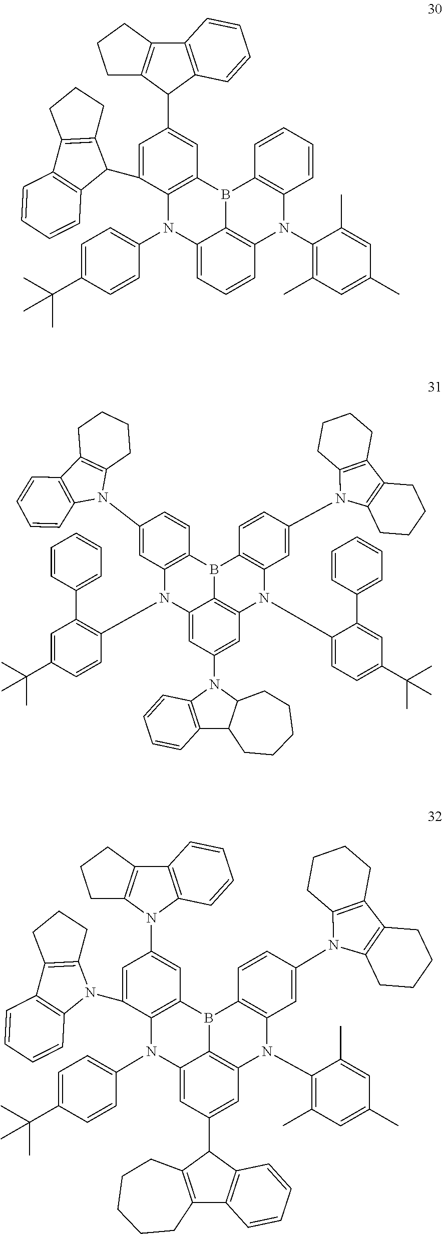

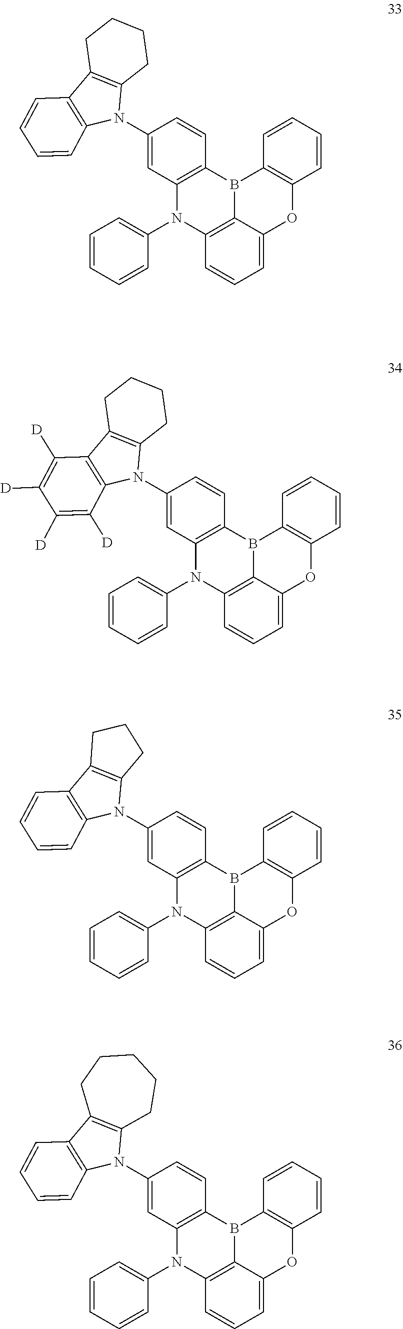 [SMILES: c1ccc(N2c3cc(-n4c5c(c6ccccc64)CCCC5)ccc3B3c4ccccc4Oc4cccc2c43)cc1 ; [2H]c1c([2H])c([2H])c2c(c1[2H])c1c(n2-c2ccc3c(c2)N(c2ccccc2)c2cccc4c2B3c2ccccc2O4)CCCC1 ; c1ccc(N2c3cc(-n4c5c(c6ccccc64)CCC5)ccc3B3c4ccccc4Oc4cccc2c43)cc1 ; c1ccc(N2c3cc(-n4c5c(c6ccccc64)CCCCC5)ccc3B3c4ccccc4Oc4cccc2c43)cc1]

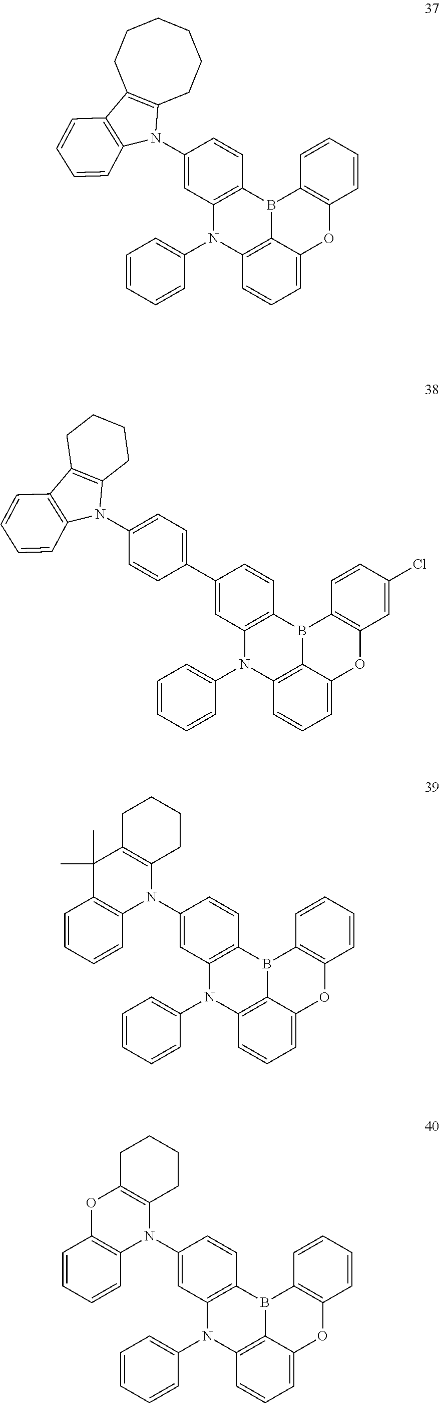 [SMILES: c1ccc(N2c3cc(-n4c5c(c6ccccc64)CCCCCC5)ccc3B3c4ccccc4Oc4cccc2c43)cc1 ; Clc1ccc2c(c1)Oc1cccc3c1B2c1ccc(-c2ccc(-n4c5c(c6ccccc64)CCCC5)cc2)cc1N3c1ccccc1 ; CC1(C)C2=C(CCCC2)N(c2ccc3c(c2)N(c2ccccc2)c2cccc4c2B3c2ccccc2O4)c2ccccc21 ; c1ccc(N2c3cc(N4C5=C(CCCC5)Oc5ccccc54)ccc3B3c4ccccc4Oc4cccc2c43)cc1]

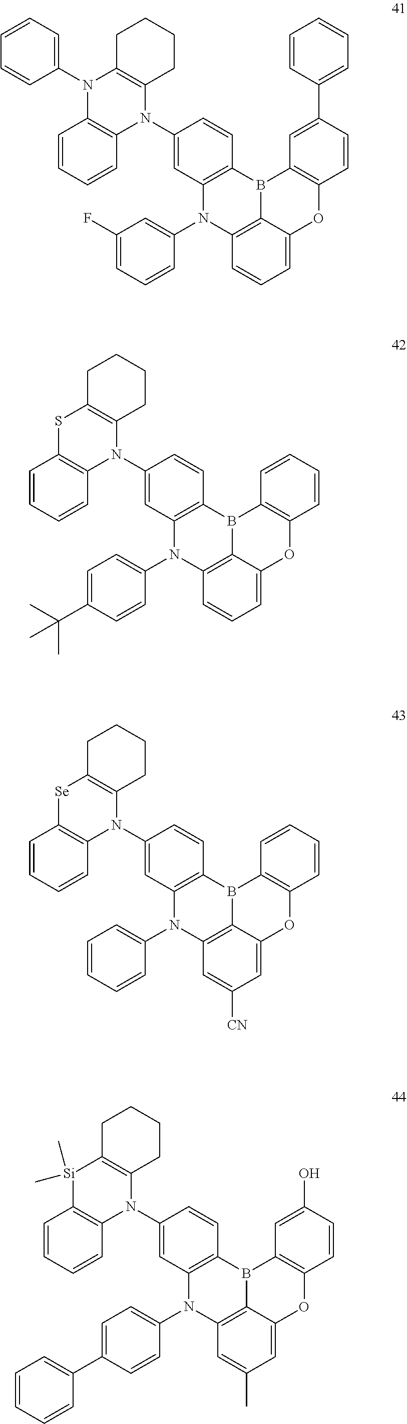 [SMILES: Fc1cccc(N2c3cc(N4C5=C(CCCC5)N(c5ccccc5)c5ccccc54)ccc3B3c4cc(-c5ccccc5)ccc4Oc4cccc2c43)c1 ; CC(C)(C)c1ccc(N2c3cc(N4C5=C(CCCC5)Sc5ccccc54)ccc3B3c4ccccc4Oc4cccc2c43)cc1 ; N#Cc1cc2c3c(c1)N(c1ccccc1)c1cc(N4C5=C(CCCC5)[Se]c5ccccc54)ccc1B3c1ccccc1O2 ; Cc1cc2c3c(c1)N(c1ccc(-c4ccccc4)cc1)c1cc(N4C5=C(CCCC5)[Si](C)(C)c5ccccc54)ccc1B3c1cc(O)ccc1O2]

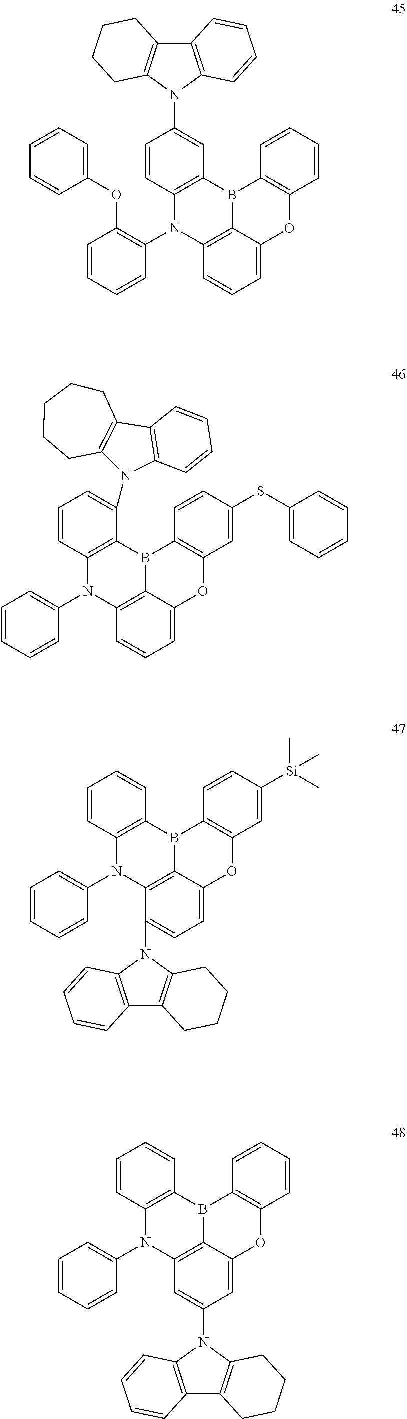 [SMILES: c1ccc(Oc2ccccc2N2c3ccc(-n4c5c(c6ccccc64)CCCC5)cc3B3c4ccccc4Oc4cccc2c43)cc1 ; c1ccc(Sc2ccc3c(c2)Oc2cccc4c2B3c2c(cccc2-n2c3c(c5ccccc52)CCCCC3)N4c2ccccc2)cc1 ; C[Si](C)(C)c1ccc2c(c1)Oc1ccc(-n3c4c(c5ccccc53)CCCC4)c3c1B2c1ccccc1N3c1ccccc1 ; c1ccc(N2c3ccccc3B3c4ccccc4Oc4cc(-n5c6c(c7ccccc75)CCCC6)cc2c43)cc1]

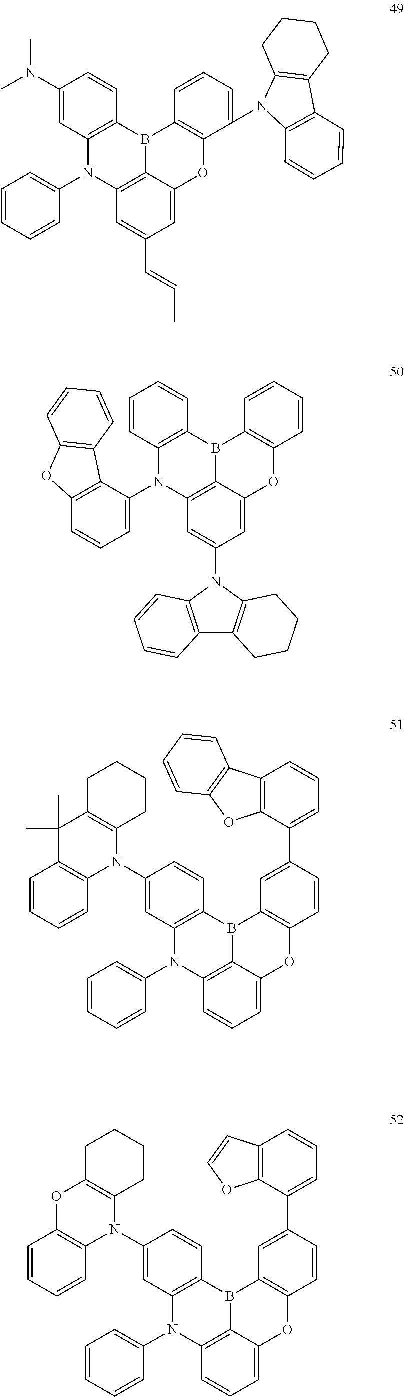 [SMILES: C/C=C/c1cc2c3c(c1)N(c1ccccc1)c1cc(N(C)C)ccc1B3c1cccc(-n3c4c(c5ccccc53)CCCC4)c1O2 ; c1ccc2c(c1)Oc1cc(-n3c4c(c5ccccc53)CCCC4)cc3c1B2c1ccccc1N3c1cccc2oc3ccccc3c12 ; CC1(C)C2=C(CCCC2)N(c2ccc3c(c2)N(c2ccccc2)c2cccc4c2B3c2cc(-c3cccc5c3oc3ccccc35)ccc2O4)c2ccccc21 ; c1ccc(N2c3cc(N4C5=C(CCCC5)Oc5ccccc54)ccc3B3c4cc(-c5cccc6ccoc56)ccc4Oc4cccc2c43)cc1]

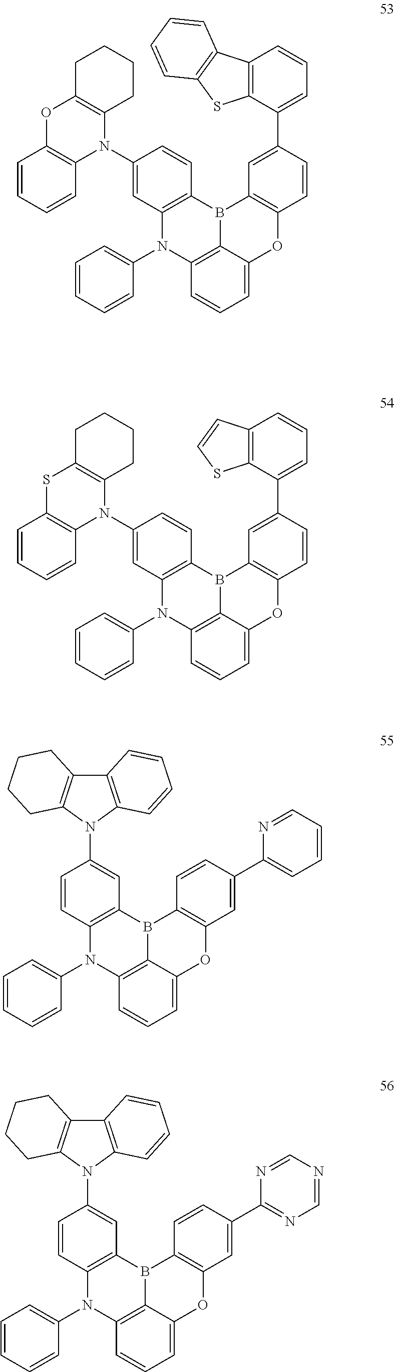 [SMILES: c1ccc(N2c3cc(N4C5=C(CCCC5)Oc5ccccc54)ccc3B3c4cc(-c5cccc6c5sc5ccccc56)ccc4Oc4cccc2c43)cc1 ; c1ccc(N2c3cc(N4C5=C(CCCC5)Sc5ccccc54)ccc3B3c4cc(-c5cccc6ccsc56)ccc4Oc4cccc2c43)cc1 ; c1ccc(N2c3ccc(-n4c5c(c6ccccc64)CCCC5)cc3B3c4ccc(-c5ccccn5)cc4Oc4cccc2c43)cc1 ; c1ccc(N2c3ccc(-n4c5c(c6ccccc64)CCCC5)cc3B3c4ccc(-c5ncncn5)cc4Oc4cccc2c43)cc1]

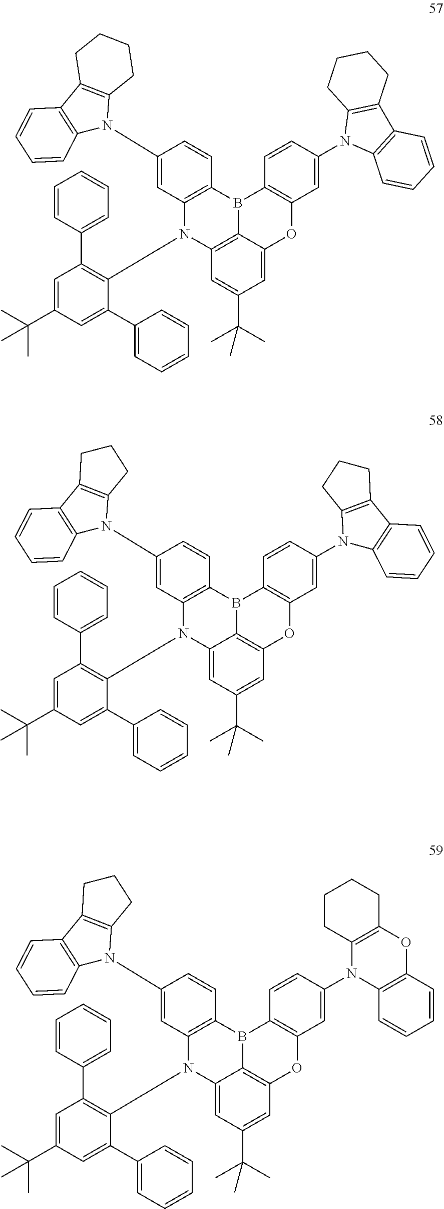 [SMILES: CC(C)(C)c1cc(-c2ccccc2)c(N2c3cc(-n4c5c(c6ccccc64)CCCC5)ccc3B3c4ccc(-n5c6c(c7ccccc75)CCCC6)cc4Oc4cc(C(C)(C)C)cc2c43)c(-c2ccccc2)c1 ; CC(C)(C)c1cc(-c2ccccc2)c(N2c3cc(-n4c5c(c6ccccc64)CCC5)ccc3B3c4ccc(-n5c6c(c7ccccc75)CCC6)cc4Oc4cc(C(C)(C)C)cc2c43)c(-c2ccccc2)c1 ; CC(C)(C)c1cc(-c2ccccc2)c(N2c3cc(-n4c5c(c6ccccc64)CCC5)ccc3B3c4ccc(N5C6=C(CCCC6)Oc6ccccc65)cc4Oc4cc(C(C)(C)C)cc2c43)c(-c2ccccc2)c1]

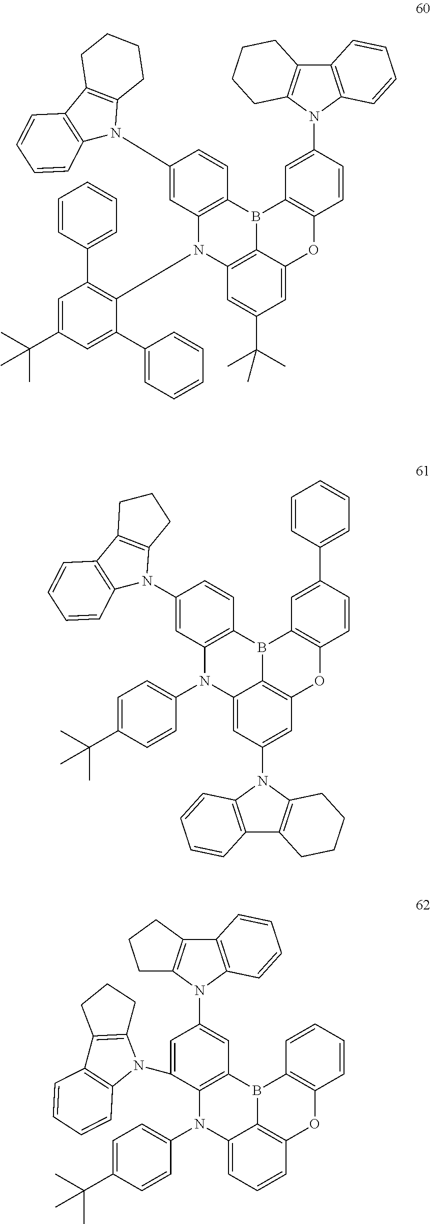 [SMILES: CC(C)(C)c1cc(-c2ccccc2)c(N2c3cc(-n4c5c(c6ccccc64)CCCC5)ccc3B3c4cc(-n5c6c(c7ccccc75)CCCC6)ccc4Oc4cc(C(C)(C)C)cc2c43)c(-c2ccccc2)c1 ; CC(C)(C)c1ccc(N2c3cc(-n4c5c(c6ccccc64)CCC5)ccc3B3c4cc(-c5ccccc5)ccc4Oc4cc(-n5c6c(c7ccccc75)CCCC6)cc2c43)cc1 ; CC(C)(C)c1ccc(N2c3cccc4c3B(c3ccccc3O4)c3cc(-n4c5c(c6ccccc64)CCC5)cc(-n4c5c(c6ccccc64)CCC5)c32)cc1]

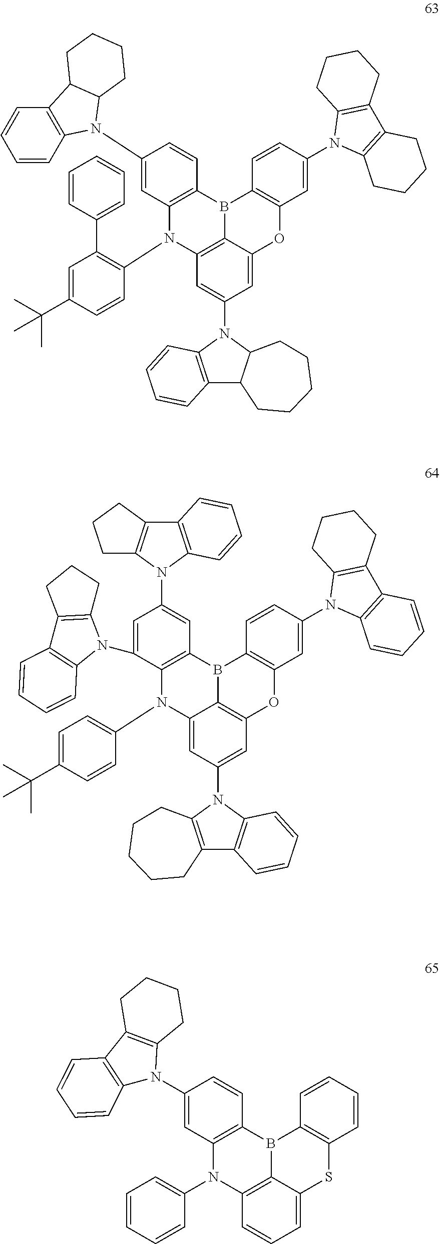 [SMILES: CC(C)(C)c1ccc(N2c3cc(N4c5ccccc5C5CCCCC54)ccc3B3c4ccc(-n5c6c(c7c5CCCC7)CCCC6)cc4Oc4cc(N5c6ccccc6C6CCCCCC65)cc2c43)c(-c2ccccc2)c1 ; CC(C)(C)c1ccc(N2c3cc(-n4c5c(c6ccccc64)CCCCC5)cc4c3B(c3ccc(-n5c6c(c7ccccc75)CCCC6)cc3O4)c3cc(-n4c5c(c6ccccc64)CCC5)cc(-n4c5c(c6ccccc64)CCC5)c32)cc1 ; c1ccc(N2c3cc(-n4c5c(c6ccccc64)CCCC5)ccc3B3c4ccccc4Sc4cccc2c43)cc1]

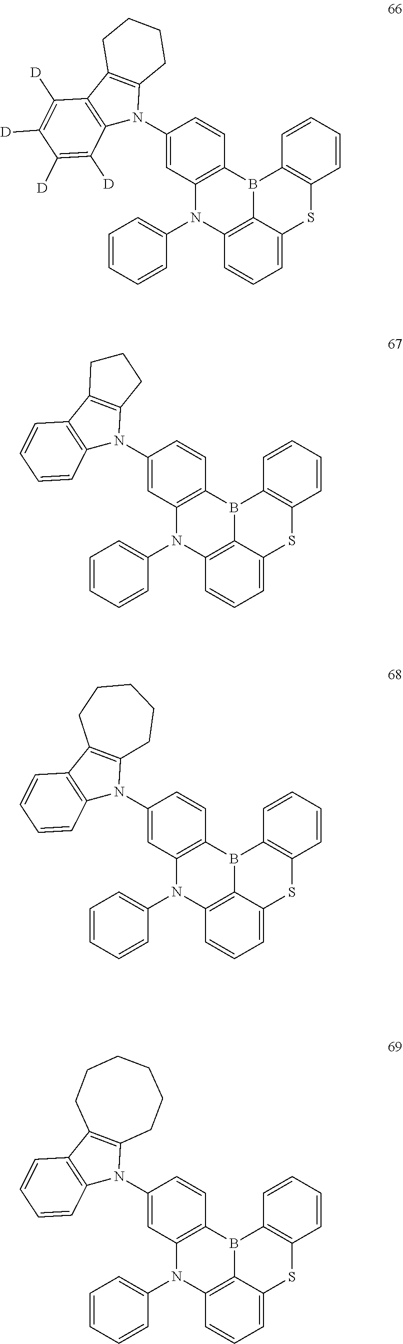 [SMILES: [2H]c1c([2H])c([2H])c2c(c1[2H])c1c(n2-c2ccc3c(c2)N(c2ccccc2)c2cccc4c2B3c2ccccc2S4)CCCC1 ; c1ccc(N2c3cc(-n4c5c(c6ccccc64)CCC5)ccc3B3c4ccccc4Sc4cccc2c43)cc1 ; c1ccc(N2c3cc(-n4c5c(c6ccccc64)CCCCC5)ccc3B3c4ccccc4Sc4cccc2c43)cc1 ; c1ccc(N2c3cc(-n4c5c(c6ccccc64)CCCCCC5)ccc3B3c4ccccc4Sc4cccc2c43)cc1]

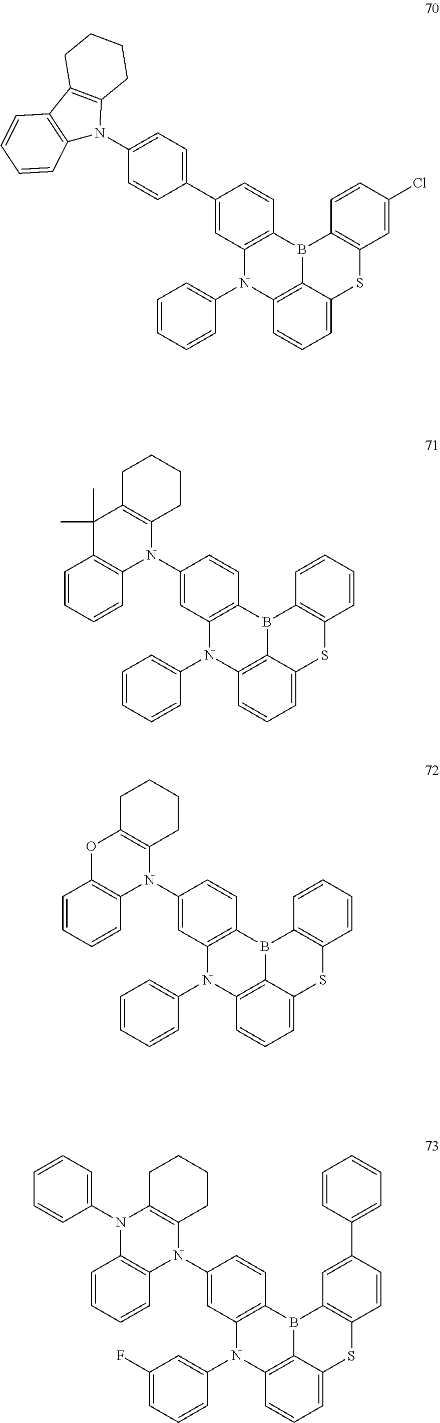 [SMILES: Clc1ccc2c(c1)Sc1cccc3c1B2c1ccc(-c2ccc(-n4c5c(c6ccccc64)CCCC5)cc2)cc1N3c1ccccc1 ; CC1(C)C2=C(CCCC2)N(c2ccc3c(c2)N(c2ccccc2)c2cccc4c2B3c2ccccc2S4)c2ccccc21 ; c1ccc(N2c3cc(N4C5=C(CCCC5)Oc5ccccc54)ccc3B3c4ccccc4Sc4cccc2c43)cc1 ; Fc1cccc(N2c3cc(N4C5=C(CCCC5)N(c5ccccc5)c5ccccc54)ccc3B3c4cc(-c5ccccc5)ccc4Sc4cccc2c43)c1]

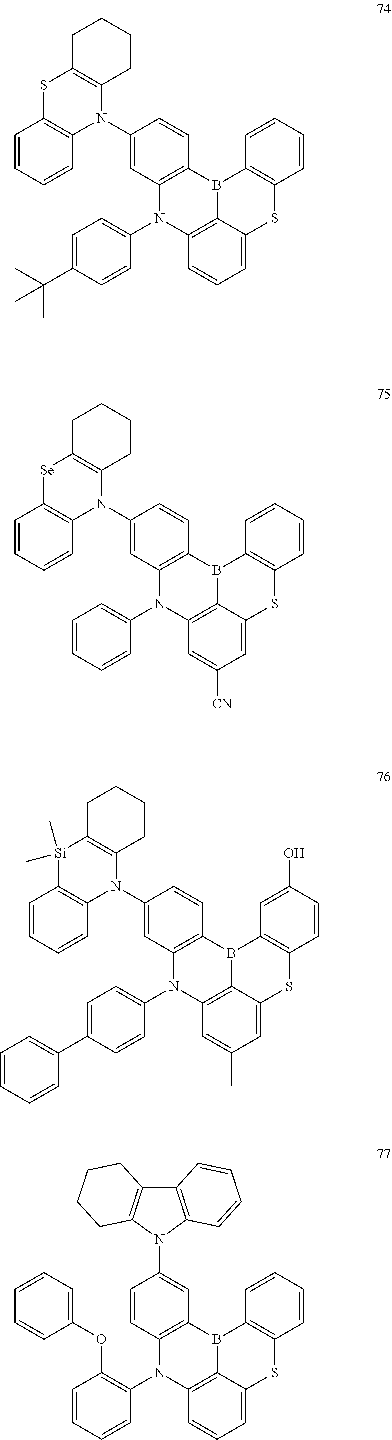 [SMILES: CC(C)(C)c1ccc(N2c3cc(N4C5=C(CCCC5)Sc5ccccc54)ccc3B3c4ccccc4Sc4cccc2c43)cc1 ; N#Cc1cc2c3c(c1)N(c1ccccc1)c1cc(N4C5=C(CCCC5)[Se]c5ccccc54)ccc1B3c1ccccc1S2 ; Cc1cc2c3c(c1)N(c1ccc(-c4ccccc4)cc1)c1cc(N4C5=C(CCCC5)[Si](C)(C)c5ccccc54)ccc1B3c1cc(O)ccc1S2 ; c1ccc(Oc2ccccc2N2c3ccc(-n4c5c(c6ccccc64)CCCC5)cc3B3c4ccccc4Sc4cccc2c43)cc1]

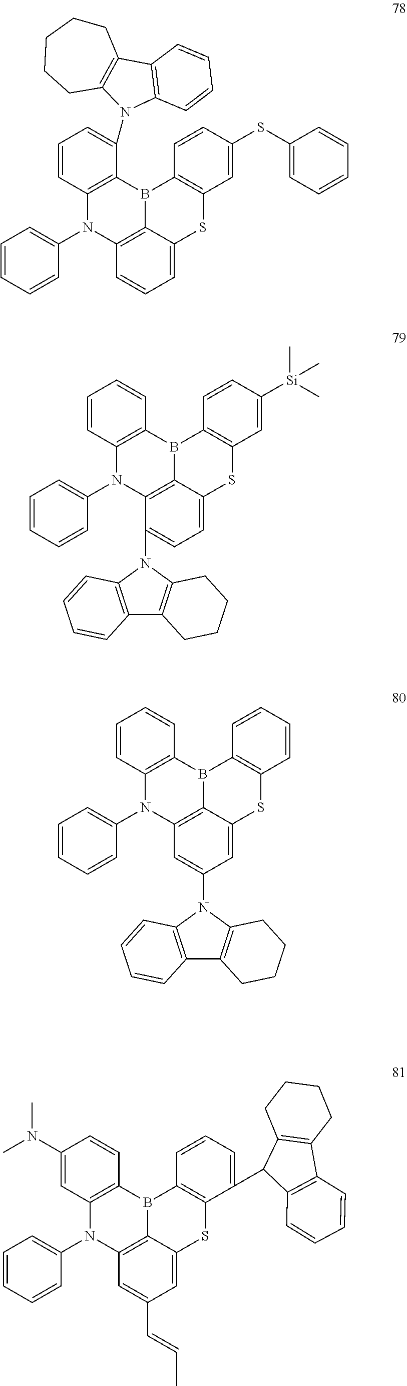 [SMILES: c1ccc(Sc2ccc3c(c2)Sc2cccc4c2B3c2c(cccc2-n2c3c(c5ccccc52)CCCCC3)N4c2ccccc2)cc1 ; C[Si](C)(C)c1ccc2c(c1)Sc1ccc(-n3c4c(c5ccccc53)CCCC4)c3c1B2c1ccccc1N3c1ccccc1 ; c1ccc(N2c3ccccc3B3c4ccccc4Sc4cc(-n5c6c(c7ccccc75)CCCC6)cc2c43)cc1 ; C/C=C/c1cc2c3c(c1)N(c1ccccc1)c1cc(N(C)C)ccc1B3c1cccc(C3C4=C(CCCC4)c4ccccc43)c1S2]

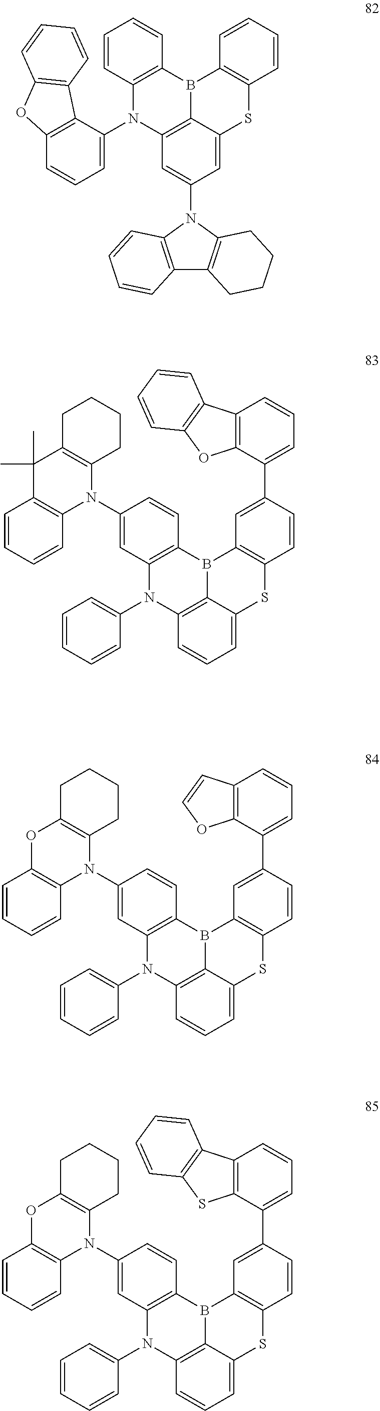 [SMILES: c1ccc2c(c1)Sc1cc(-n3c4c(c5ccccc53)CCCC4)cc3c1B2c1ccccc1N3c1cccc2oc3ccccc3c12 ; CC1(C)C2=C(CCCC2)N(c2ccc3c(c2)N(c2ccccc2)c2cccc4c2B3c2cc(-c3cccc5c3oc3ccccc35)ccc2S4)c2ccccc21 ; c1ccc(N2c3cc(N4C5=C(CCCC5)Oc5ccccc54)ccc3B3c4cc(-c5cccc6ccoc56)ccc4Sc4cccc2c43)cc1 ; c1ccc(N2c3cc(N4C5=C(CCCC5)Oc5ccccc54)ccc3B3c4cc(-c5cccc6c5sc5ccccc56)ccc4Sc4cccc2c43)cc1]

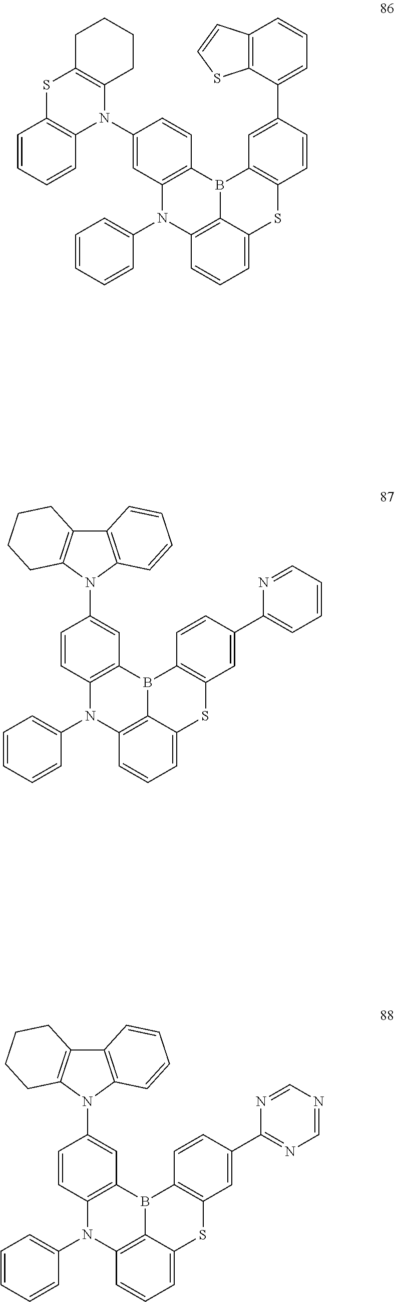 [SMILES: c1ccc(N2c3cc(N4C5=C(CCCC5)Sc5ccccc54)ccc3B3c4cc(-c5cccc6ccsc56)ccc4Sc4cccc2c43)cc1 ; c1ccc(N2c3ccc(-n4c5c(c6ccccc64)CCCC5)cc3B3c4ccc(-c5ccccn5)cc4Sc4cccc2c43)cc1 ; c1ccc(N2c3ccc(-n4c5c(c6ccccc64)CCCC5)cc3B3c4ccc(-c5ncncn5)cc4Sc4cccc2c43)cc1]

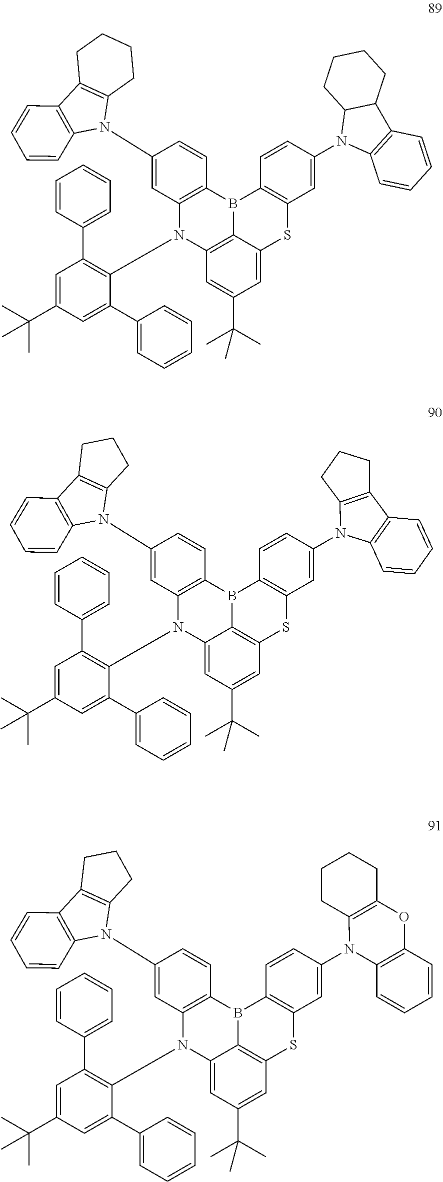 [SMILES: CC(C)(C)c1cc(-c2ccccc2)c(N2c3cc(-n4c5c(c6ccccc64)CCCC5)ccc3B3c4ccc(N5c6ccccc6C6CCCCC65)cc4Sc4cc(C(C)(C)C)cc2c43)c(-c2ccccc2)c1 ; CC(C)(C)c1cc(-c2ccccc2)c(N2c3cc(-n4c5c(c6ccccc64)CCC5)ccc3B3c4ccc(-n5c6c(c7ccccc75)CCC6)cc4Sc4cc(C(C)(C)C)cc2c43)c(-c2ccccc2)c1 ; CC(C)(C)c1cc(-c2ccccc2)c(N2c3cc(-n4c5c(c6ccccc64)CCC5)ccc3B3c4ccc(N5C6=C(CCCC6)Oc6ccccc65)cc4Sc4cc(C(C)(C)C)cc2c43)c(-c2ccccc2)c1]

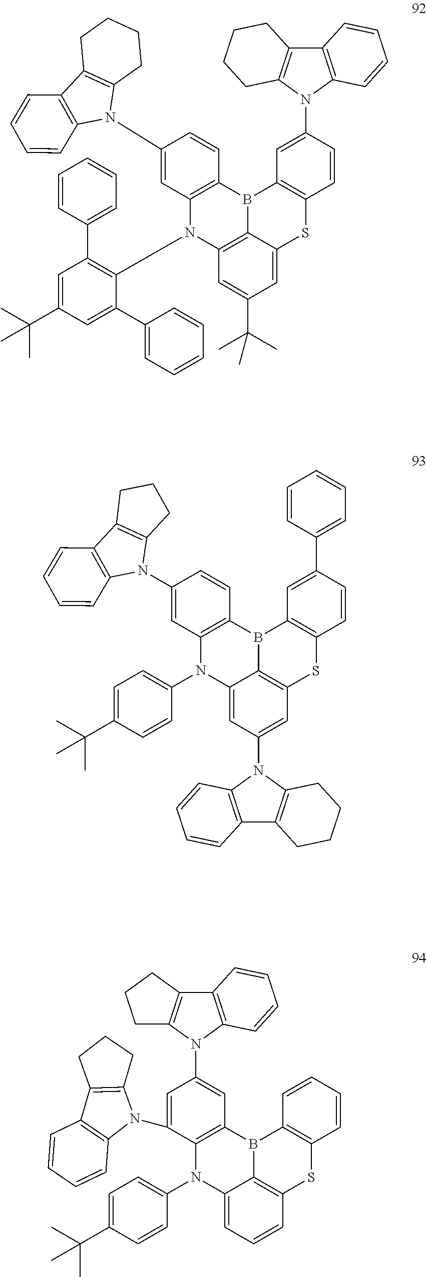 [SMILES: CC(C)(C)c1cc(-c2ccccc2)c(N2c3cc(-n4c5c(c6ccccc64)CCCC5)ccc3B3c4cc(-n5c6c(c7ccccc75)CCCC6)ccc4Sc4cc(C(C)(C)C)cc2c43)c(-c2ccccc2)c1 ; CC(C)(C)c1ccc(N2c3cc(-n4c5c(c6ccccc64)CCC5)ccc3B3c4cc(-c5ccccc5)ccc4Sc4cc(-n5c6c(c7ccccc75)CCCC6)cc2c43)cc1 ; CC(C)(C)c1ccc(N2c3cccc4c3B(c3ccccc3S4)c3cc(-n4c5c(c6ccccc64)CCC5)cc(-n4c5c(c6ccccc64)CCC5)c32)cc1]

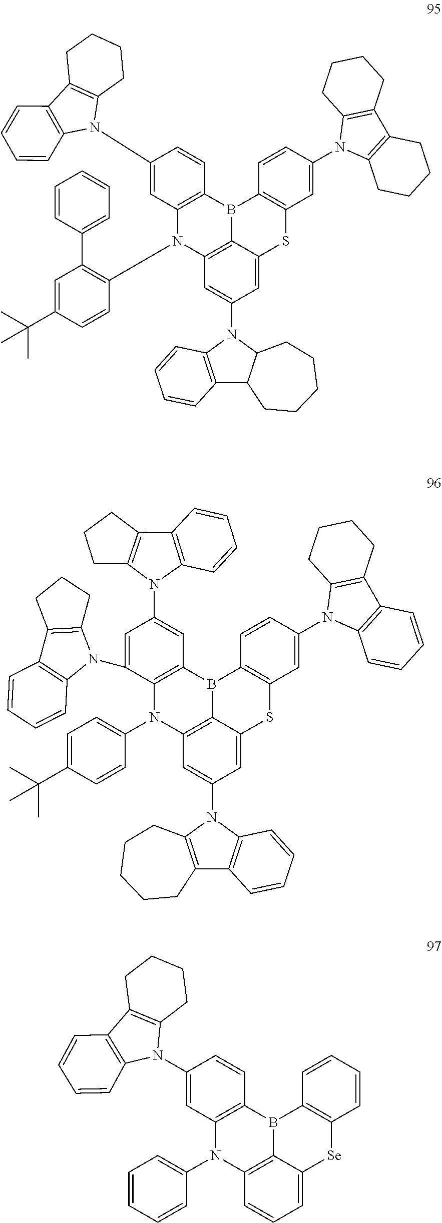 [SMILES: CC(C)(C)c1ccc(N2c3cc(-n4c5c(c6ccccc64)CCCC5)ccc3B3c4ccc(-n5c6c(c7c5CCCC7)CCCC6)cc4Sc4cc(N5c6ccccc6C6CCCCCC65)cc2c43)c(-c2ccccc2)c1 ; CC(C)(C)c1ccc(N2c3cc(-n4c5c(c6ccccc64)CCCCC5)cc4c3B(c3ccc(-n5c6c(c7ccccc75)CCCC6)cc3S4)c3cc(-n4c5c(c6ccccc64)CCC5)cc(-n4c5c(c6ccccc64)CCC5)c32)cc1 ; c1ccc(N2c3cc(-n4c5c(c6ccccc64)CCCC5)ccc3B3c4ccccc4[Se]c4cccc2c43)cc1]

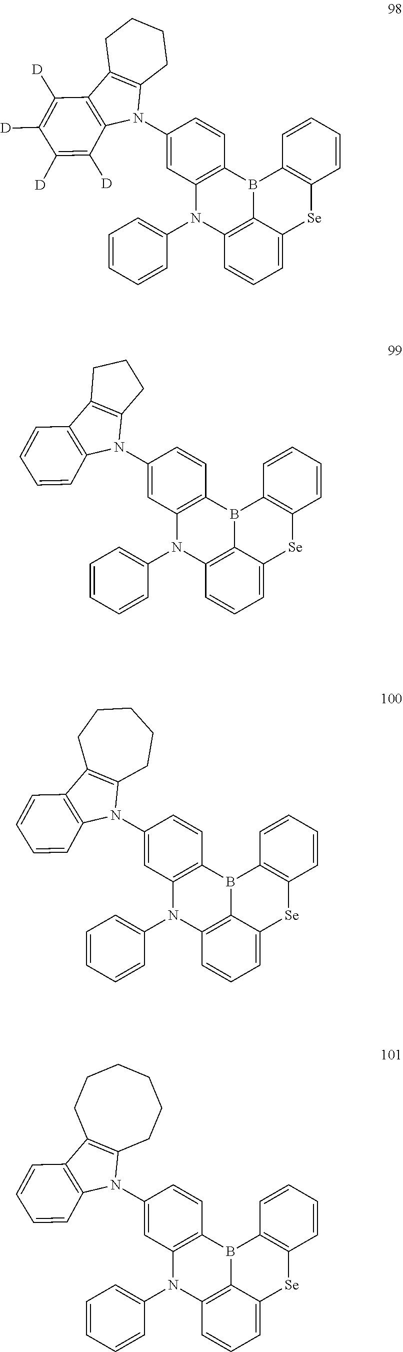 [SMILES: [2H]c1c([2H])c([2H])c2c(c1[2H])c1c(n2-c2ccc3c(c2)N(c2ccccc2)c2cccc4c2B3c2ccccc2[Se]4)CCCC1 ; c1ccc(N2c3cc(-n4c5c(c6ccccc64)CCC5)ccc3B3c4ccccc4[Se]c4cccc2c43)cc1 ; c1ccc(N2c3cc(-n4c5c(c6ccccc64)CCCCC5)ccc3B3c4ccccc4[Se]c4cccc2c43)cc1 ; c1ccc(N2c3cc(-n4c5c(c6ccccc64)CCCCCC5)ccc3B3c4ccccc4[Se]c4cccc2c43)cc1]

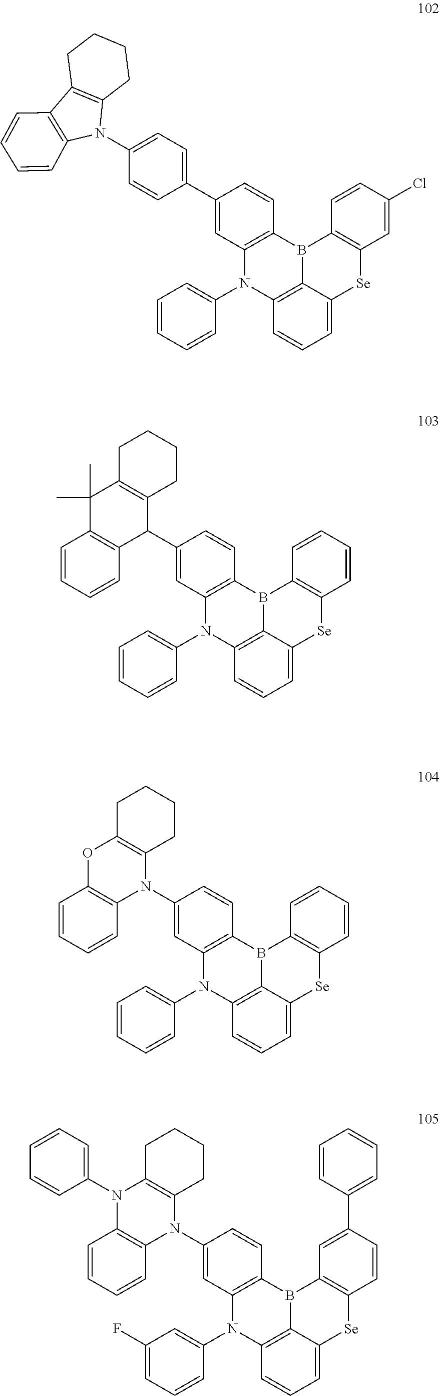 [SMILES: Clc1ccc2c(c1)[Se]c1cccc3c1B2c1ccc(-c2ccc(-n4c5c(c6ccccc64)CCCC5)cc2)cc1N3c1ccccc1 ; CC1(C)C2=C(CCCC2)C(c2ccc3c(c2)N(c2ccccc2)c2cccc4c2B3c2ccccc2[Se]4)c2ccccc21 ; c1ccc(N2c3cc(N4C5=C(CCCC5)Oc5ccccc54)ccc3B3c4ccccc4[Se]c4cccc2c43)cc1 ; Fc1cccc(N2c3cc(N4C5=C(CCCC5)N(c5ccccc5)c5ccccc54)ccc3B3c4cc(-c5ccccc5)ccc4[Se]c4cccc2c43)c1]

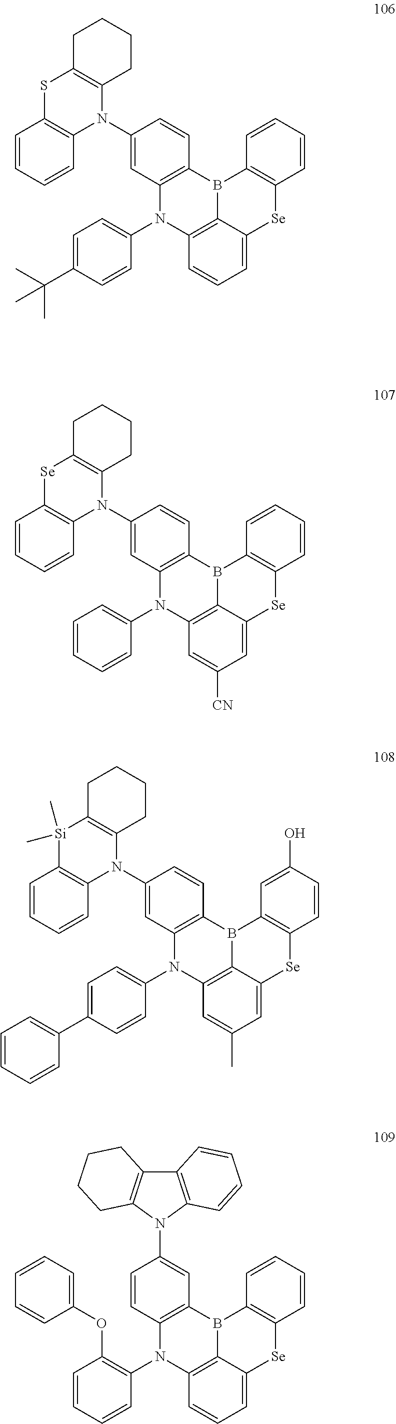 [SMILES: CC(C)(C)c1ccc(N2c3cc(N4C5=C(CCCC5)Sc5ccccc54)ccc3B3c4ccccc4[Se]c4cccc2c43)cc1 ; N#Cc1cc2c3c(c1)N(c1ccccc1)c1cc(N4C5=C(CCCC5)[Se]c5ccccc54)ccc1B3c1ccccc1[Se]2 ; Cc1cc2c3c(c1)N(c1ccc(-c4ccccc4)cc1)c1cc(N4C5=C(CCCC5)[Si](C)(C)c5ccccc54)ccc1B3c1cc(O)ccc1[Se]2 ; c1ccc(Oc2ccccc2N2c3ccc(-n4c5c(c6ccccc64)CCCC5)cc3B3c4ccccc4[Se]c4cccc2c43)cc1]

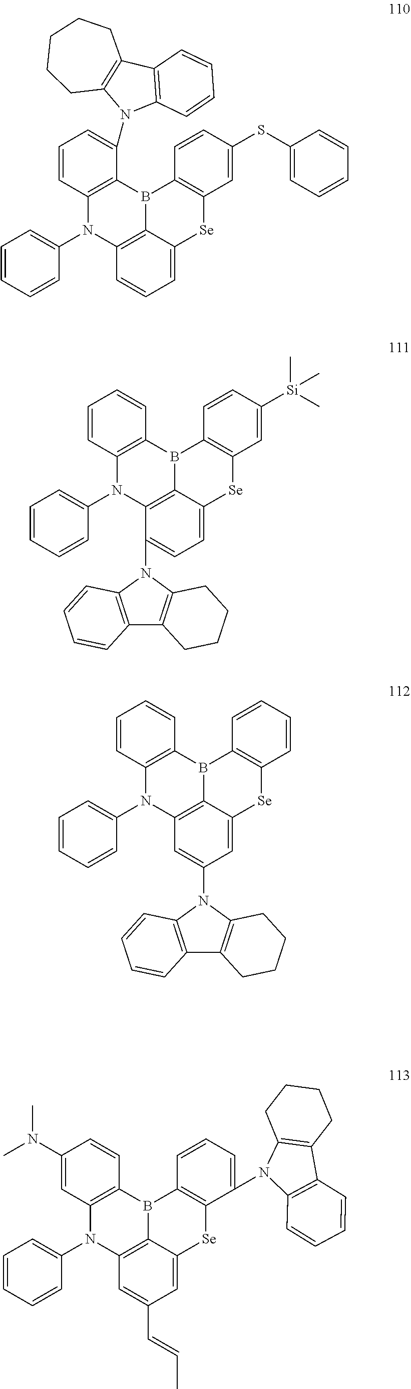 [SMILES: c1ccc(Sc2ccc3c(c2)[Se]c2cccc4c2B3c2c(cccc2-n2c3c(c5ccccc52)CCCCC3)N4c2ccccc2)cc1 ; C[Si](C)(C)c1ccc2c(c1)[Se]c1ccc(-n3c4c(c5ccccc53)CCCC4)c3c1B2c1ccccc1N3c1ccccc1 ; c1ccc(N2c3ccccc3B3c4ccccc4[Se]c4cc(-n5c6c(c7ccccc75)CCCC6)cc2c43)cc1 ; C/C=C/c1cc2c3c(c1)N(c1ccccc1)c1cc(N(C)C)ccc1B3c1cccc(-n3c4c(c5ccccc53)CCCC4)c1[Se]2]

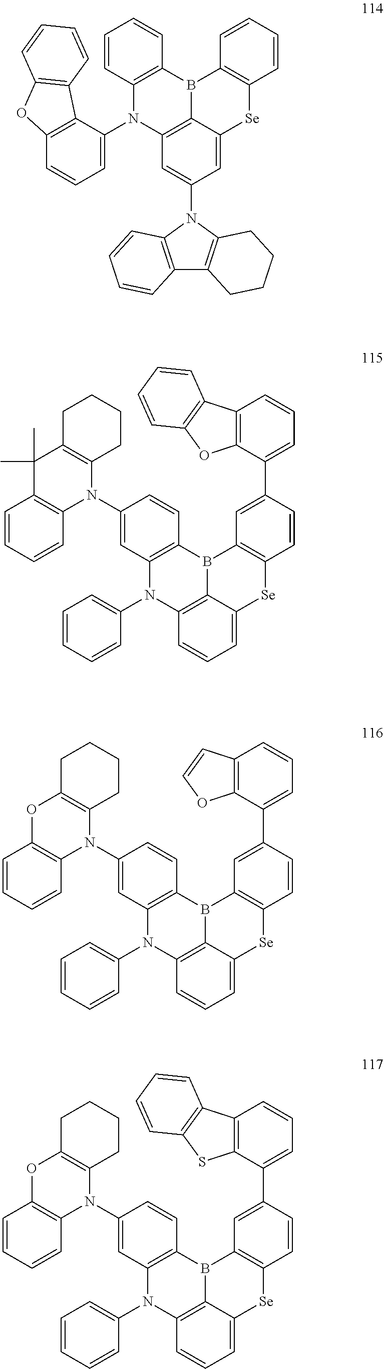 [SMILES: c1ccc2c(c1)[Se]c1cc(-n3c4c(c5ccccc53)CCCC4)cc3c1B2c1ccccc1N3c1cccc2oc3ccccc3c12 ; CC1(C)C2=C(CCCC2)N(c2ccc3c(c2)N(c2ccccc2)c2cccc4c2B3c2cc(-c3cccc5c3oc3ccccc35)ccc2[Se]4)c2ccccc21 ; c1ccc(N2c3cc(N4C5=C(CCCC5)Oc5ccccc54)ccc3B3c4cc(-c5cccc6ccoc56)ccc4[Se]c4cccc2c43)cc1 ; c1ccc(N2c3cc(N4C5=C(CCCC5)Oc5ccccc54)ccc3B3c4cc(-c5cccc6c5sc5ccccc56)ccc4[Se]c4cccc2c43)cc1]

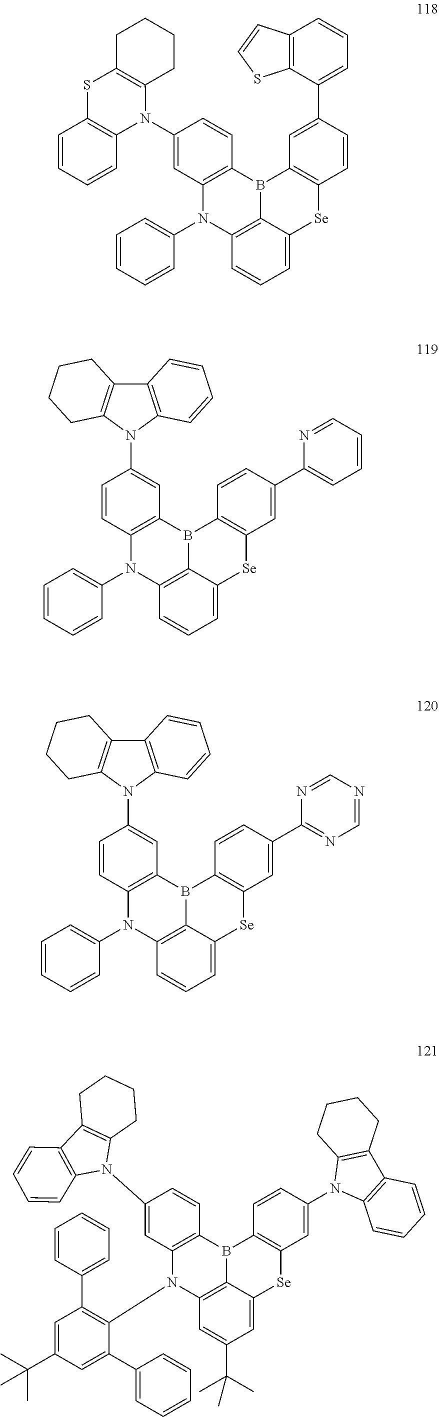 [SMILES: c1ccc(N2c3cc(N4C5=C(CCCC5)Sc5ccccc54)ccc3B3c4cc(-c5cccc6ccsc56)ccc4[Se]c4cccc2c43)cc1 ; c1ccc(N2c3ccc(-n4c5c(c6ccccc64)CCCC5)cc3B3c4ccc(-c5ccccn5)cc4[Se]c4cccc2c43)cc1 ; c1ccc(N2c3ccc(-n4c5c(c6ccccc64)CCCC5)cc3B3c4ccc(-c5ncncn5)cc4[Se]c4cccc2c43)cc1 ; CC(C)(C)c1cc(-c2ccccc2)c(N2c3cc(-n4c5c(c6ccccc64)CCCC5)ccc3B3c4ccc(-n5c6c(c7ccccc75)CCCC6)cc4[Se]c4cc(C(C)(C)C)cc2c43)c(-c2ccccc2)c1]

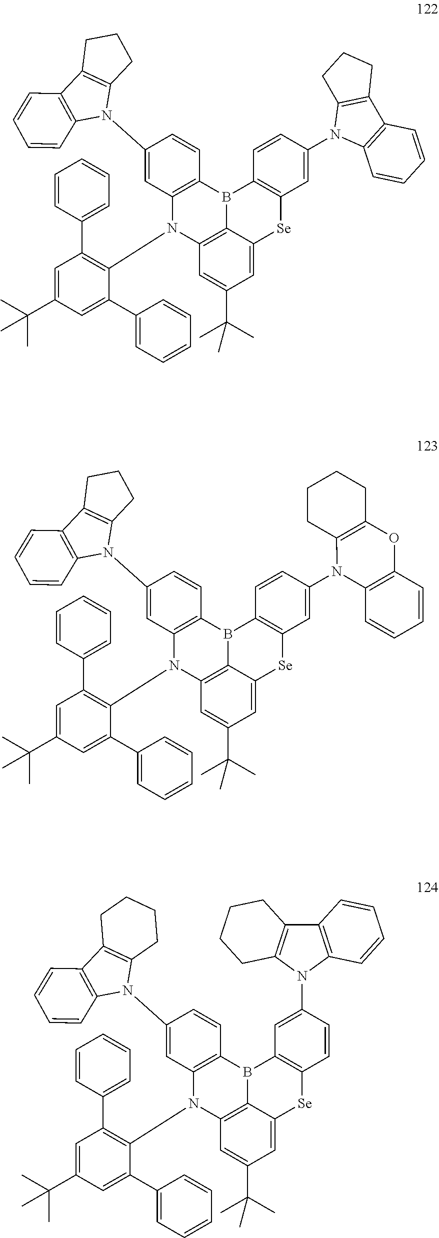 [SMILES: CC(C)(C)c1cc(-c2ccccc2)c(N2c3cc(-n4c5c(c6ccccc64)CCC5)ccc3B3c4ccc(-n5c6c(c7ccccc75)CCC6)cc4[Se]c4cc(C(C)(C)C)cc2c43)c(-c2ccccc2)c1 ; CC(C)(C)c1cc(-c2ccccc2)c(N2c3cc(-n4c5c(c6ccccc64)CCC5)ccc3B3c4ccc(N5C6=C(CCCC6)Oc6ccccc65)cc4[Se]c4cc(C(C)(C)C)cc2c43)c(-c2ccccc2)c1 ; CC(C)(C)c1cc(-c2ccccc2)c(N2c3cc(-n4c5c(c6ccccc64)CCCC5)ccc3B3c4cc(-n5c6c(c7ccccc75)CCCC6)ccc4[Se]c4cc(C(C)(C)C)cc2c43)c(-c2ccccc2)c1]

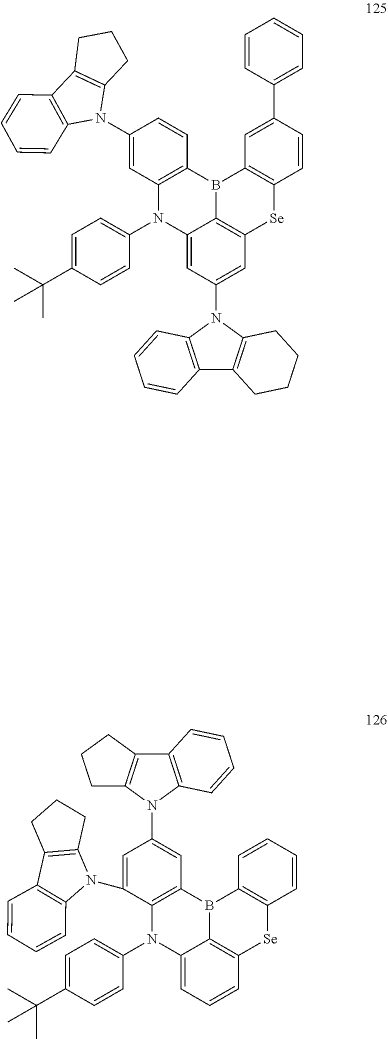 [SMILES: CC(C)(C)c1ccc(N2c3cc(-n4c5c(c6ccccc64)CCC5)ccc3B3c4cc(-c5ccccc5)ccc4[Se]c4cc(-n5c6c(c7ccccc75)CCCC6)cc2c43)cc1 ; CC(C)(C)c1ccc(N2c3cccc4c3B(c3ccccc3[Se]4)c3cc(-n4c5c(c6ccccc64)CCC5)cc(-n4c5c(c6ccccc64)CCC5)c32)cc1]

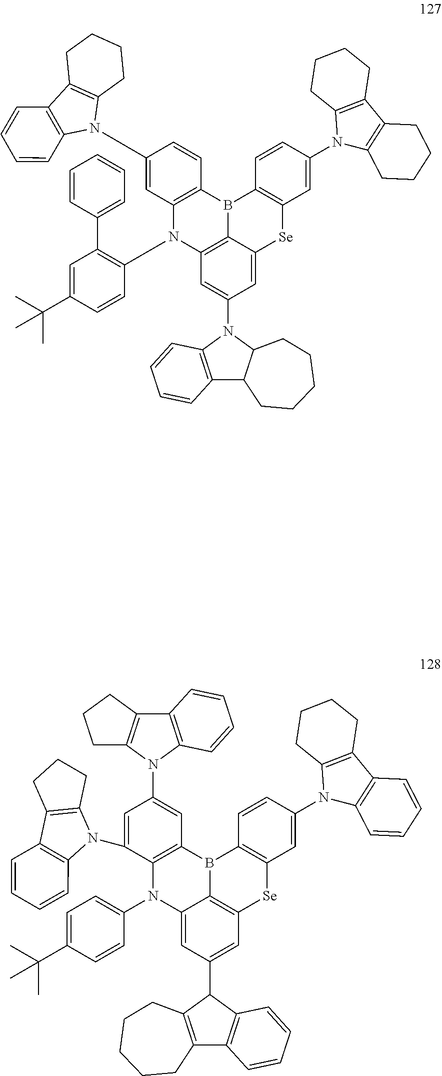 [SMILES: CC(C)(C)c1ccc(N2c3cc(-n4c5c(c6ccccc64)CCCC5)ccc3B3c4ccc(-n5c6c(c7c5CCCC7)CCCC6)cc4[Se]c4cc(N5c6ccccc6C6CCCCCC65)cc2c43)c(-c2ccccc2)c1 ; CC(C)(C)c1ccc(N2c3cc(C4C5=C(CCCCC5)c5ccccc54)cc4c3B(c3ccc(-n5c6c(c7ccccc75)CCCC6)cc3[Se]4)c3cc(-n4c5c(c6ccccc64)CCC5)cc(-n4c5c(c6ccccc64)CCC5)c32)cc1]

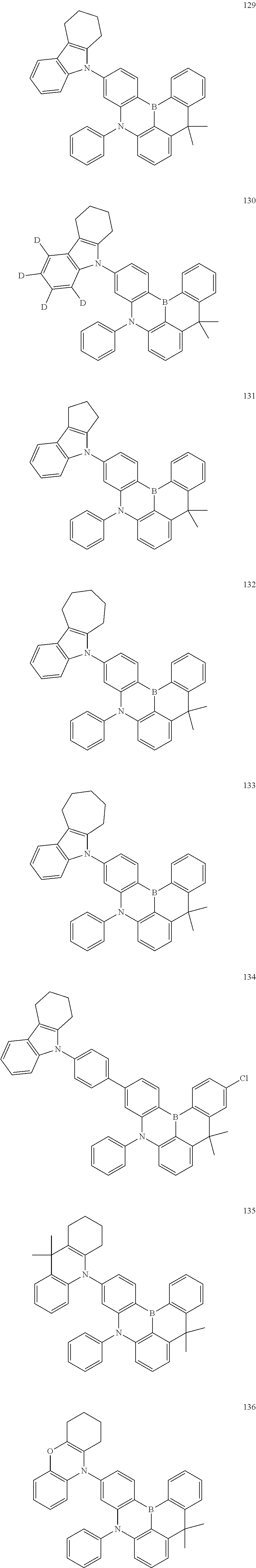

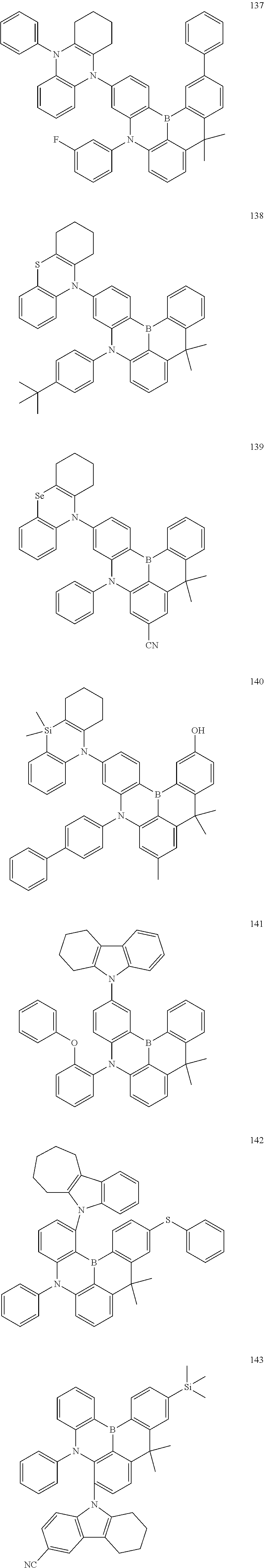

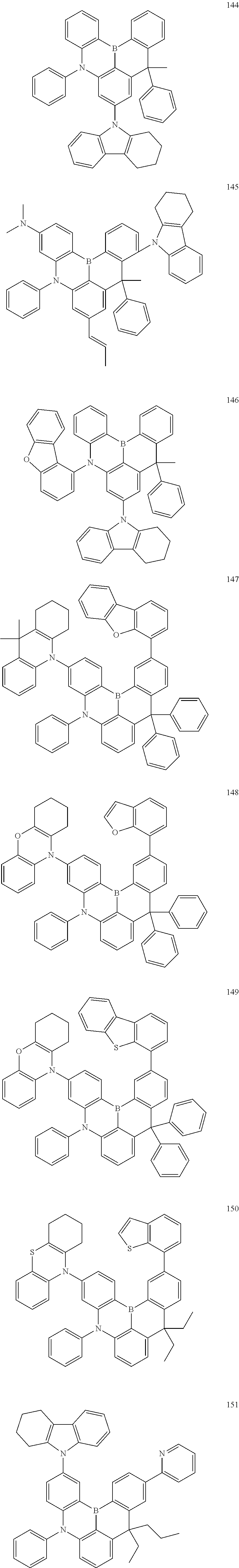

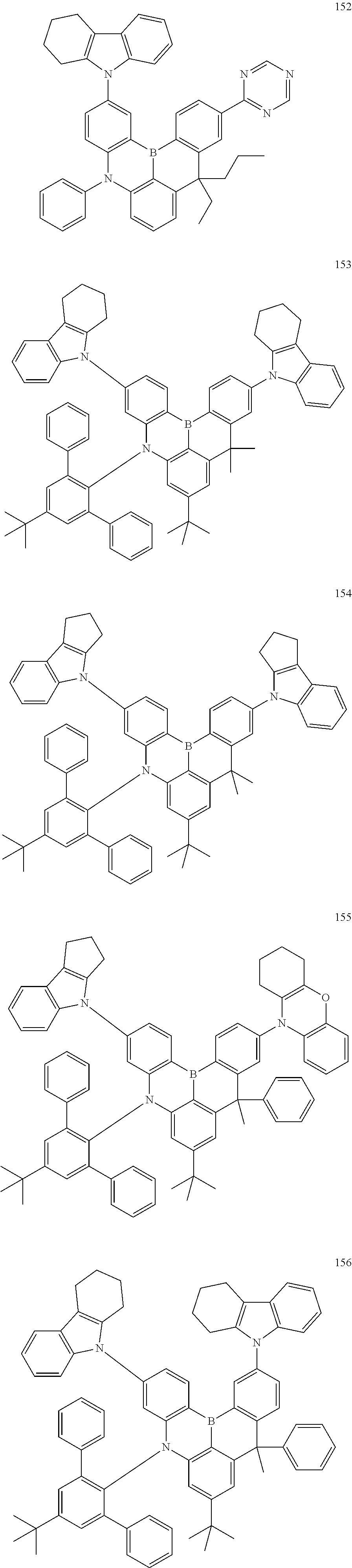

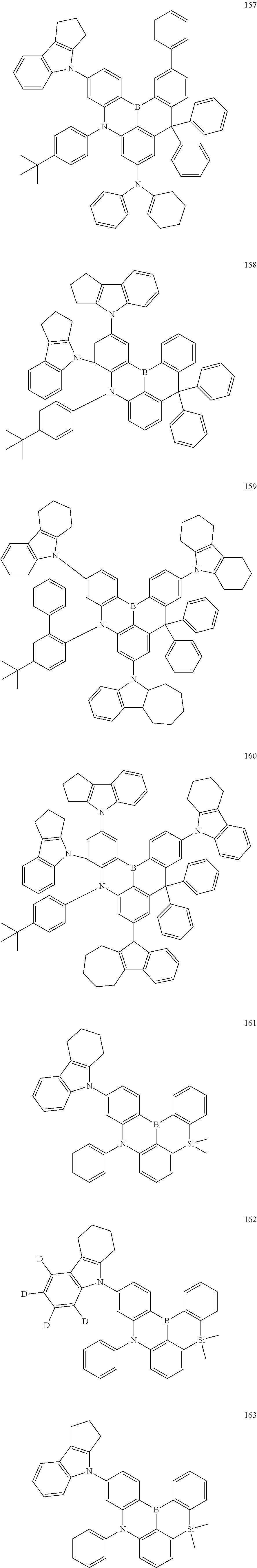

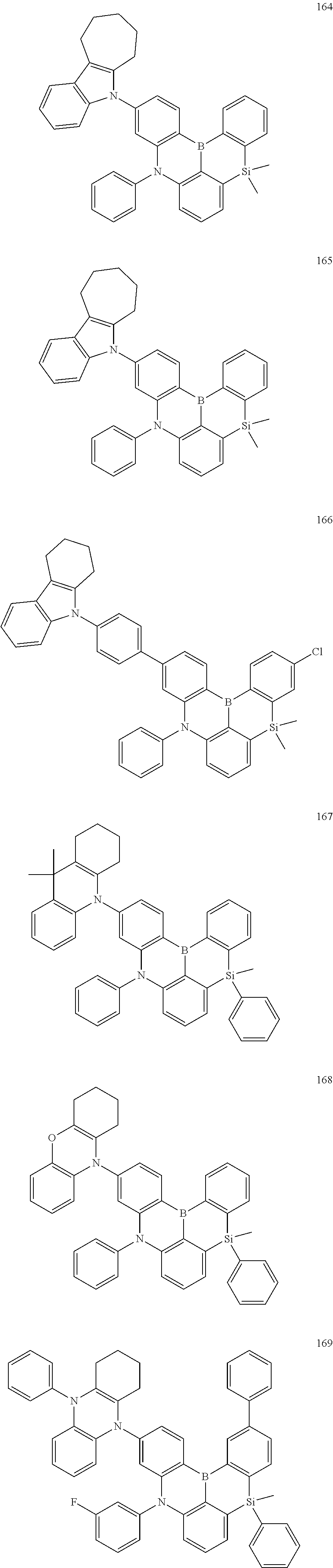

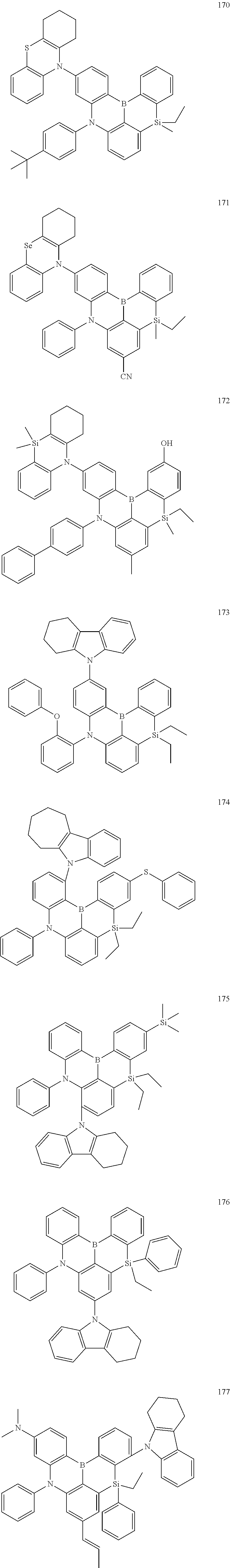

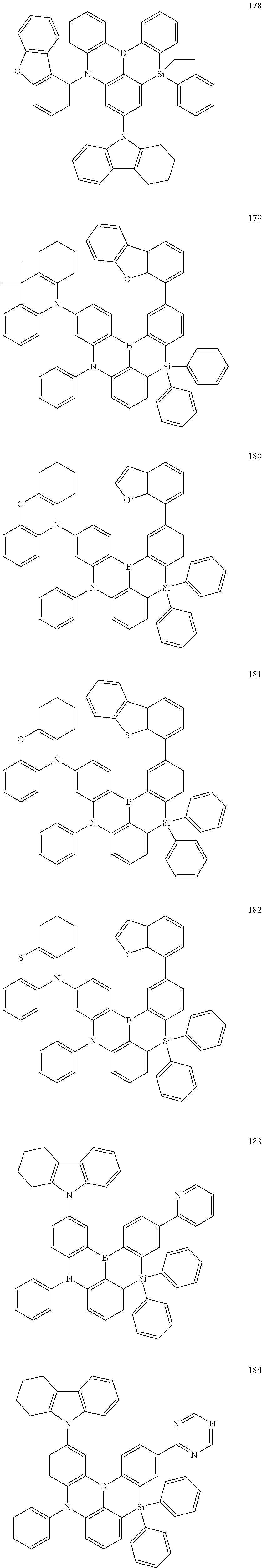

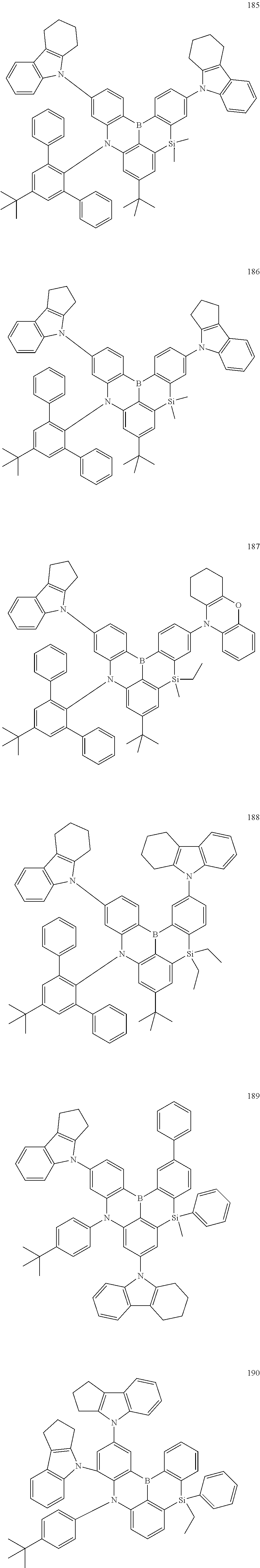

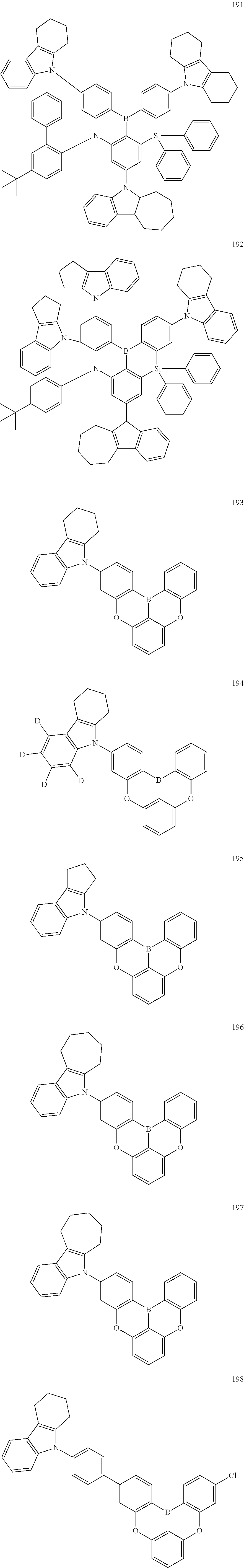

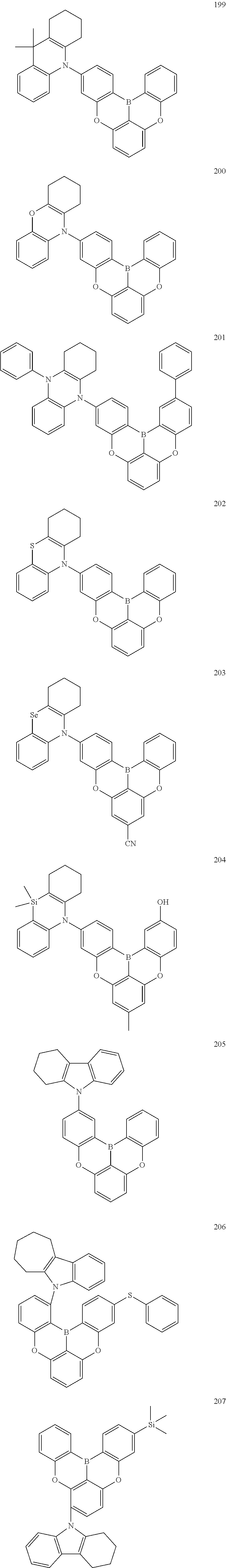

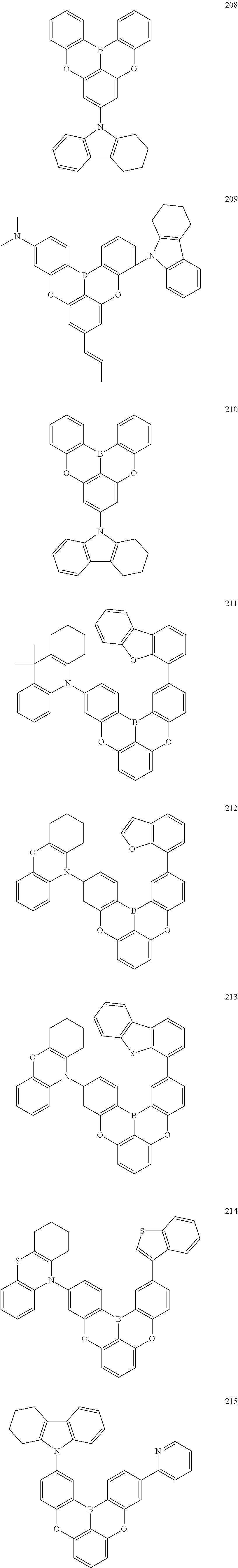

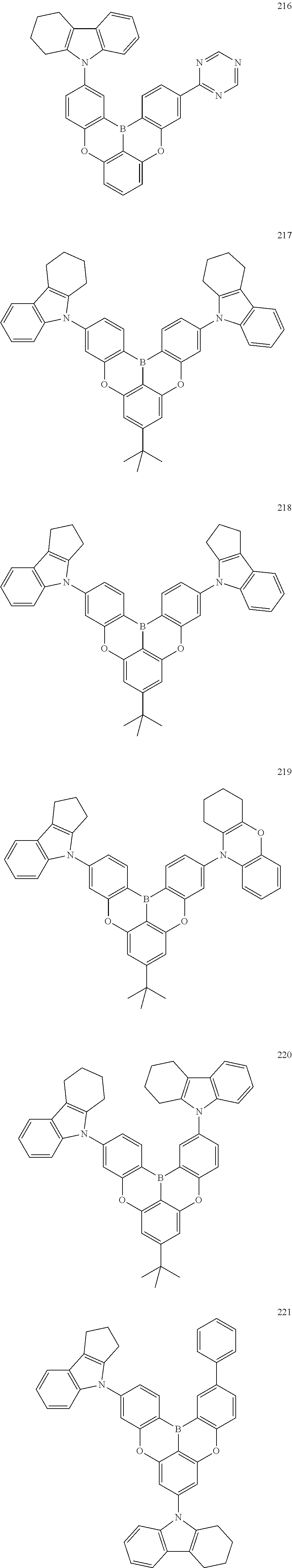

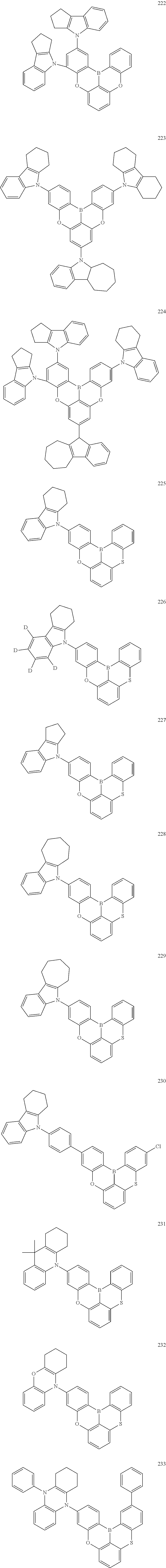

[chemical structure]

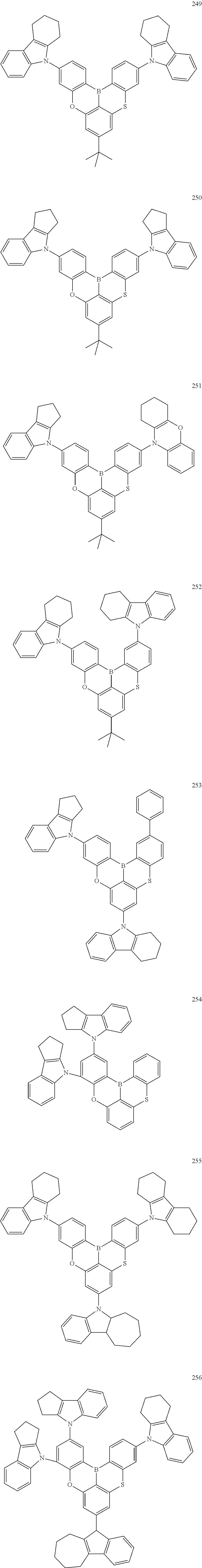

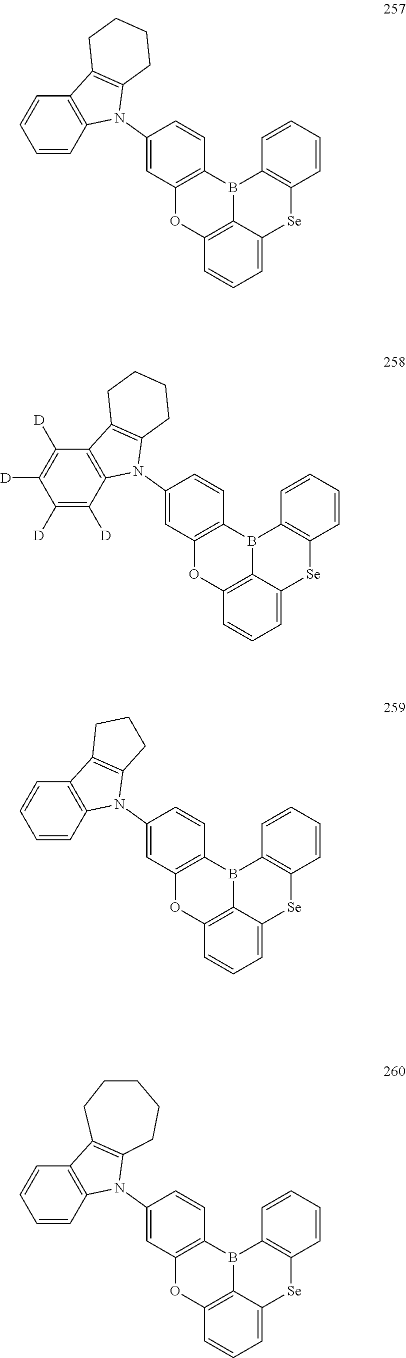 [SMILES: c1ccc2c(c1)[Se]c1cccc3c1B2c1ccc(-n2c4c(c5ccccc52)CCCC4)cc1O3 ; [2H]c1c([2H])c([2H])c2c(c1[2H])c1c(n2-c2ccc3c(c2)Oc2cccc4c2B3c2ccccc2[Se]4)CCCC1 ; c1ccc2c(c1)[Se]c1cccc3c1B2c1ccc(-n2c4c(c5ccccc52)CCC4)cc1O3 ; c1ccc2c(c1)[Se]c1cccc3c1B2c1ccc(-n2c4c(c5ccccc52)CCCCC4)cc1O3]

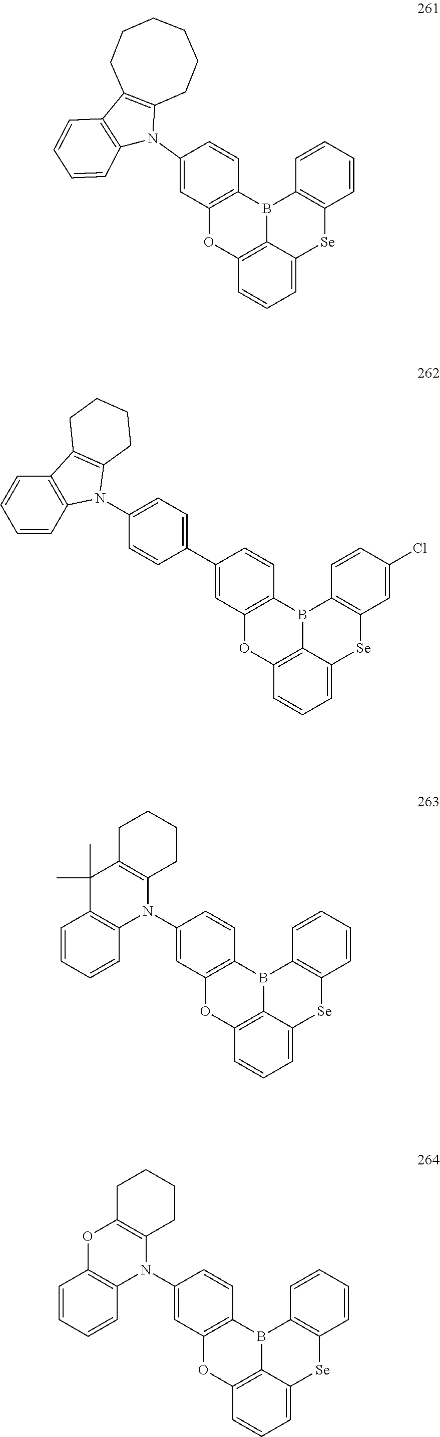 [SMILES: c1ccc2c(c1)[Se]c1cccc3c1B2c1ccc(-n2c4c(c5ccccc52)CCCCCC4)cc1O3 ; Clc1ccc2c(c1)[Se]c1cccc3c1B2c1ccc(-c2ccc(-n4c5c(c6ccccc64)CCCC5)cc2)cc1O3 ; CC1(C)C2=C(CCCC2)N(c2ccc3c(c2)Oc2cccc4c2B3c2ccccc2[Se]4)c2ccccc21 ; c1ccc2c(c1)OC1=C(CCCC1)N2c1ccc2c(c1)Oc1cccc3c1B2c1ccccc1[Se]3]

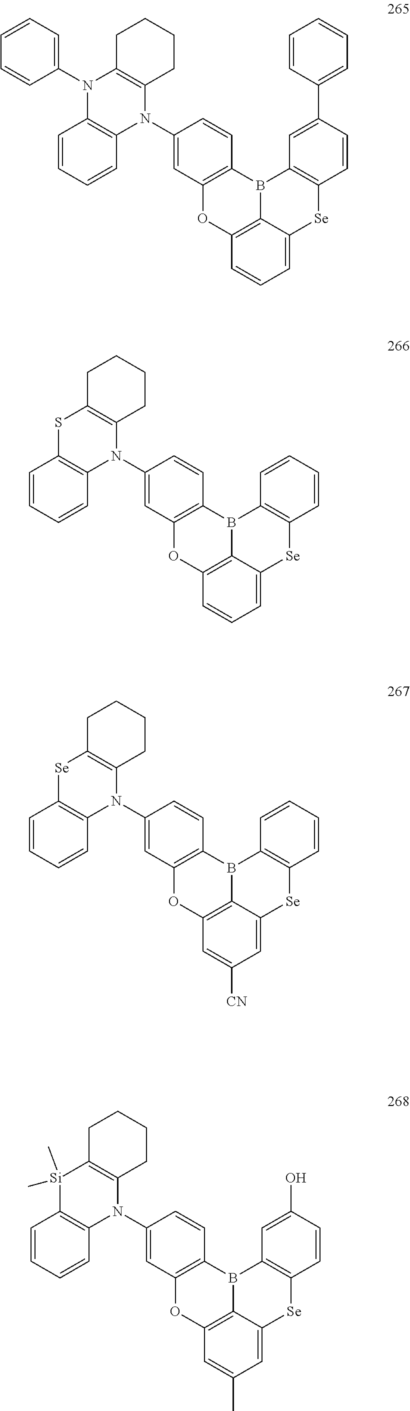 [SMILES: c1ccc(-c2ccc3c(c2)B2c4ccc(N5C6=C(CCCC6)N(c6ccccc6)c6ccccc65)cc4Oc4cccc(c42)[Se]3)cc1 ; c1ccc2c(c1)SC1=C(CCCC1)N2c1ccc2c(c1)Oc1cccc3c1B2c1ccccc1[Se]3 ; N#Cc1cc2c3c(c1)[Se]c1ccccc1B3c1ccc(N3C4=C(CCCC4)[Se]c4ccccc43)cc1O2 ; Cc1cc2c3c(c1)[Se]c1ccc(O)cc1B3c1ccc(N3C4=C(CCCC4)[Si](C)(C)c4ccccc43)cc1O2]

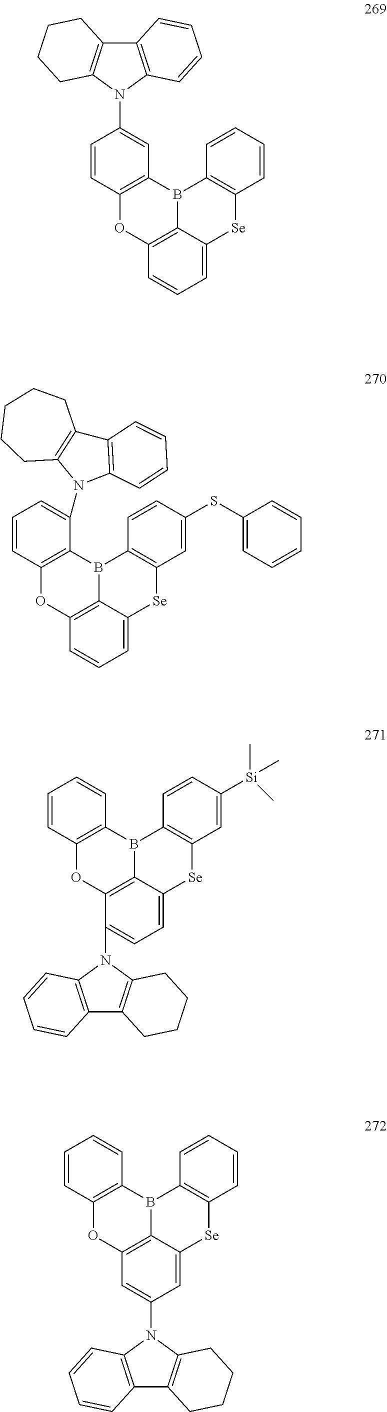 [SMILES: c1ccc2c(c1)[Se]c1cccc3c1B2c1cc(-n2c4c(c5ccccc52)CCCC4)ccc1O3 ; c1ccc(Sc2ccc3c(c2)[Se]c2cccc4c2B3c2c(cccc2-n2c3c(c5ccccc52)CCCCC3)O4)cc1 ; C[Si](C)(C)c1ccc2c(c1)[Se]c1ccc(-n3c4c(c5ccccc53)CCCC4)c3c1B2c1ccccc1O3 ; c1ccc2c(c1)Oc1cc(-n3c4c(c5ccccc53)CCCC4)cc3c1B2c1ccccc1[Se]3]

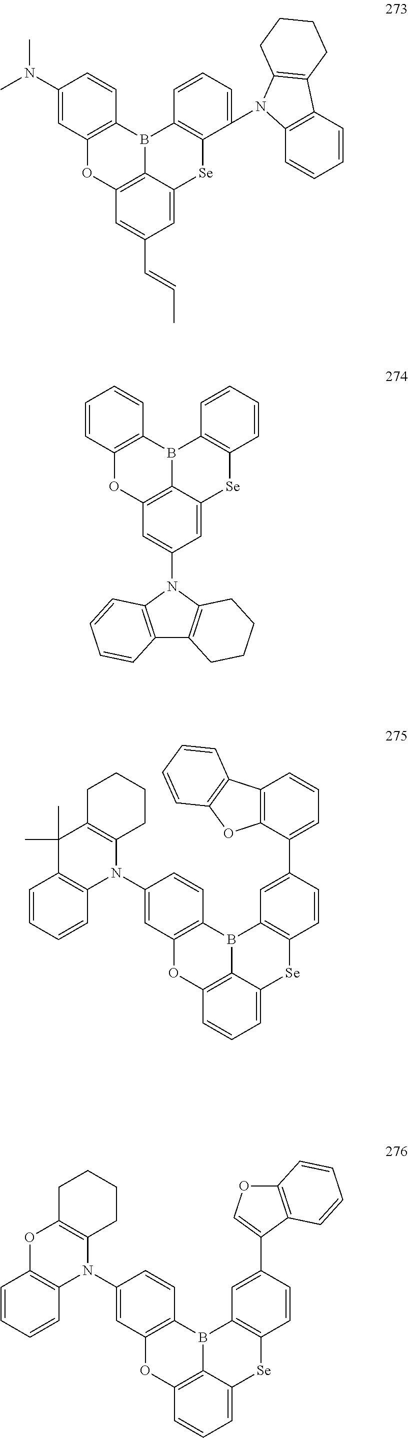 [SMILES: C/C=C/c1cc2c3c(c1)[Se]c1c(cccc1-n1c4c(c5ccccc51)CCCC4)B3c1ccc(N(C)C)cc1O2 ; c1ccc2c(c1)Oc1cc(-n3c4c(c5ccccc53)CCCC4)cc3c1B2c1ccccc1[Se]3 ; CC1(C)C2=C(CCCC2)N(c2ccc3c(c2)Oc2cccc4c2B3c2cc(-c3cccc5c3oc3ccccc35)ccc2[Se]4)c2ccccc21 ; c1ccc2c(c1)OC1=C(CCCC1)N2c1ccc2c(c1)Oc1cccc3c1B2c1cc(-c2coc4ccccc24)ccc1[Se]3]

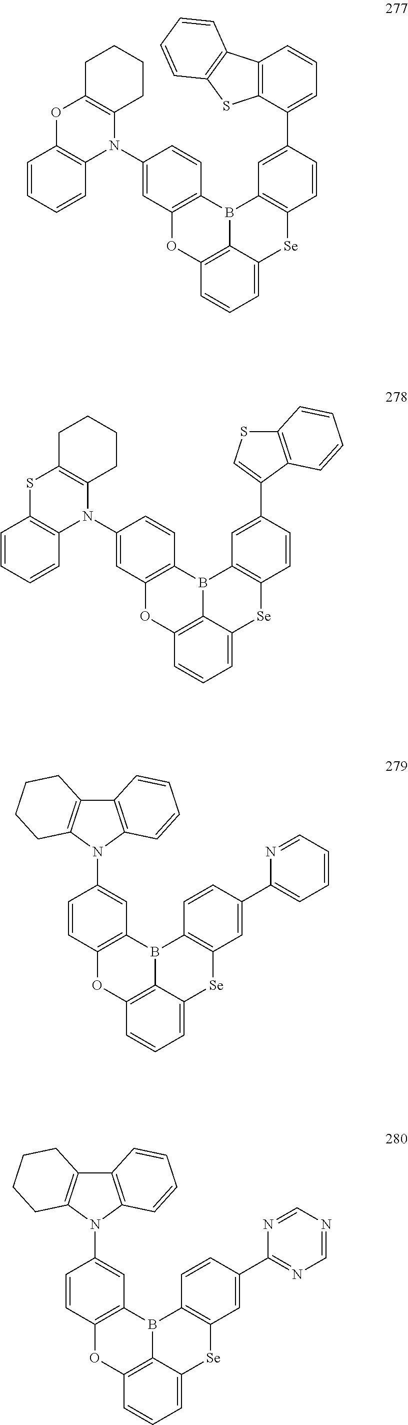 [SMILES: c1ccc2c(c1)OC1=C(CCCC1)N2c1ccc2c(c1)Oc1cccc3c1B2c1cc(-c2cccc4c2sc2ccccc24)ccc1[Se]3 ; c1ccc2c(c1)SC1=C(CCCC1)N2c1ccc2c(c1)Oc1cccc3c1B2c1cc(-c2csc4ccccc24)ccc1[Se]3 ; c1ccc(-c2ccc3c(c2)[Se]c2cccc4c2B3c2cc(-n3c5c(c6ccccc63)CCCC5)ccc2O4)nc1 ; c1cc2c3c(c1)[Se]c1cc(-c4ncncn4)ccc1B3c1cc(-n3c4c(c5ccccc53)CCCC4)ccc1O2]

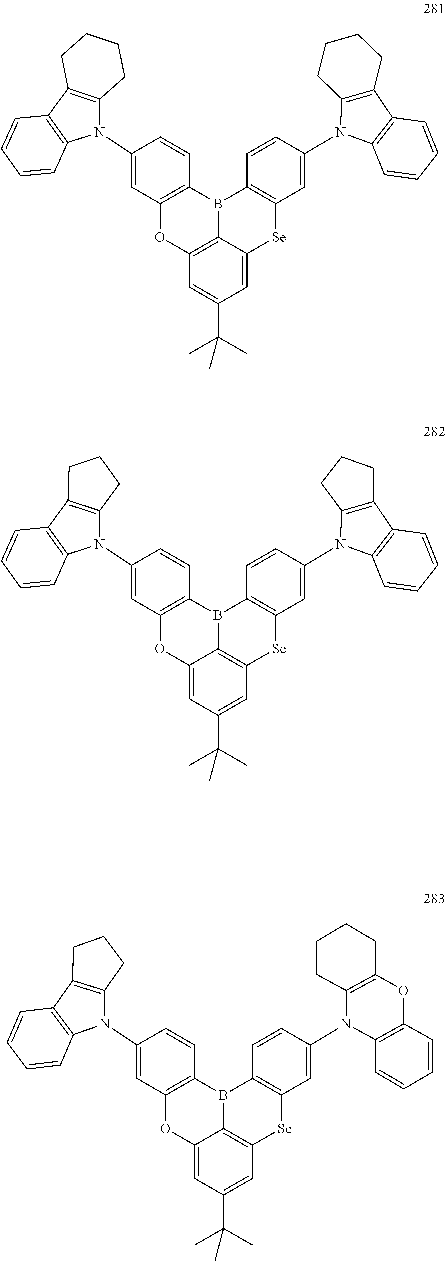 [SMILES: CC(C)(C)c1cc2c3c(c1)[Se]c1cc(-n4c5c(c6ccccc64)CCCC5)ccc1B3c1ccc(-n3c4c(c5ccccc53)CCCC4)cc1O2 ; CC(C)(C)c1cc2c3c(c1)[Se]c1cc(-n4c5c(c6ccccc64)CCC5)ccc1B3c1ccc(-n3c4c(c5ccccc53)CCC4)cc1O2 ; CC(C)(C)c1cc2c3c(c1)[Se]c1cc(N4C5=C(CCCC5)Oc5ccccc54)ccc1B3c1ccc(-n3c4c(c5ccccc53)CCC4)cc1O2]

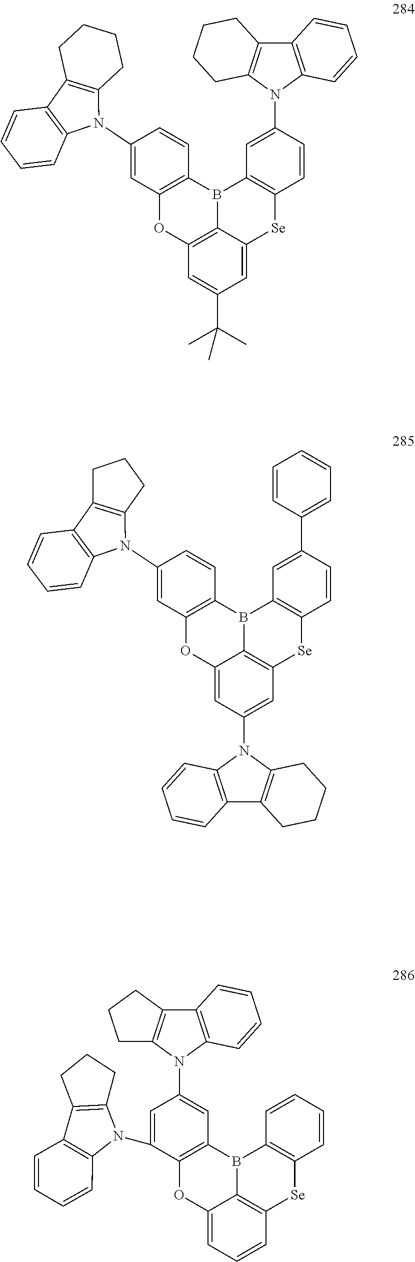 [SMILES: CC(C)(C)c1cc2c3c(c1)[Se]c1ccc(-n4c5c(c6ccccc64)CCCC5)cc1B3c1ccc(-n3c4c(c5ccccc53)CCCC4)cc1O2 ; c1ccc(-c2ccc3c(c2)B2c4ccc(-n5c6c(c7ccccc75)CCC6)cc4Oc4cc(-n5c6c(c7ccccc75)CCCC6)cc(c42)[Se]3)cc1 ; c1ccc2c(c1)[Se]c1cccc3c1B2c1cc(-n2c4c(c5ccccc52)CCC4)cc(-n2c4c(c5ccccc52)CCC4)c1O3]

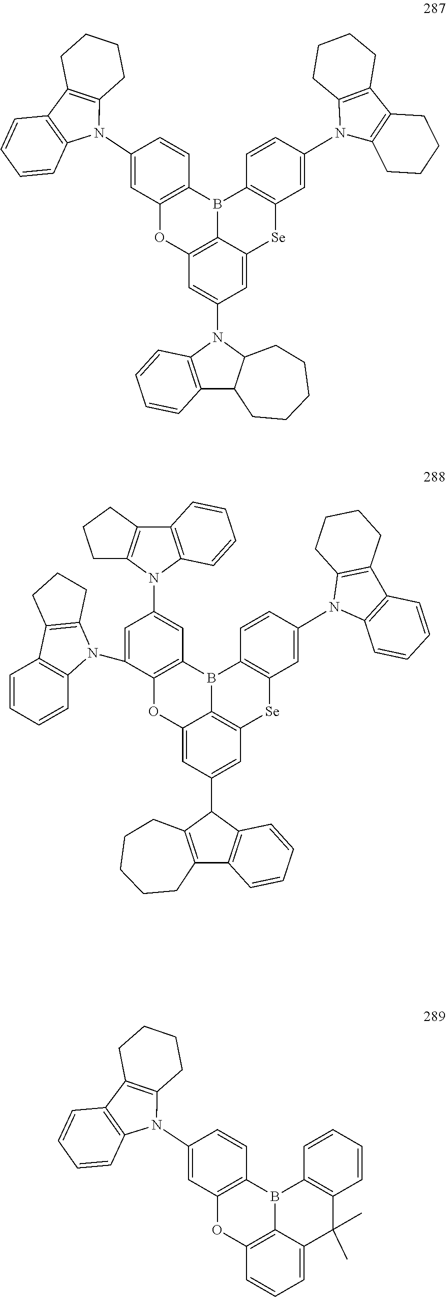 [SMILES: c1ccc2c(c1)C1CCCCCC1N2c1cc2c3c(c1)[Se]c1cc(-n4c5c(c6c4CCCC6)CCCC5)ccc1B3c1ccc(-n3c4c(c5ccccc53)CCCC4)cc1O2 ; c1ccc2c(c1)C1=C(CCCCC1)C2c1cc2c3c(c1)[Se]c1cc(-n4c5c(c6ccccc64)CCCC5)ccc1B3c1cc(-n3c4c(c5ccccc53)CCC4)cc(-n3c4c(c5ccccc53)CCC4)c1O2 ; CC1(C)c2ccccc2B2c3ccc(-n4c5c(c6ccccc64)CCCC5)cc3Oc3cccc1c32]

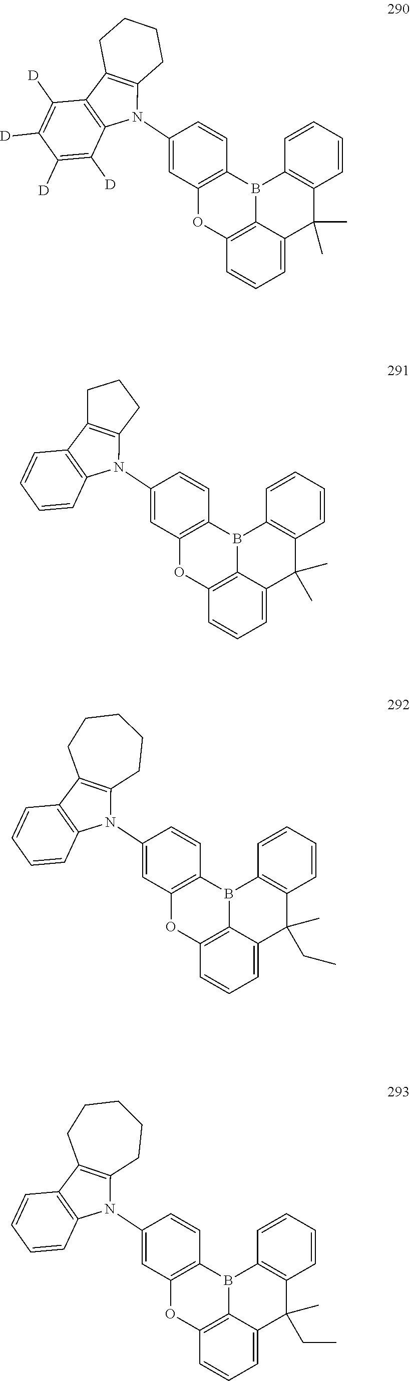 [SMILES: [2H]c1c([2H])c([2H])c2c(c1[2H])c1c(n2-c2ccc3c(c2)Oc2cccc4c2B3c2ccccc2C4(C)C)CCCC1 ; CC1(C)c2ccccc2B2c3ccc(-n4c5c(c6ccccc64)CCC5)cc3Oc3cccc1c32 ; CCC1(C)c2ccccc2B2c3ccc(-n4c5c(c6ccccc64)CCCCC5)cc3Oc3cccc1c32 ; CCC1(C)c2ccccc2B2c3ccc(-n4c5c(c6ccccc64)CCCCC5)cc3Oc3cccc1c32]

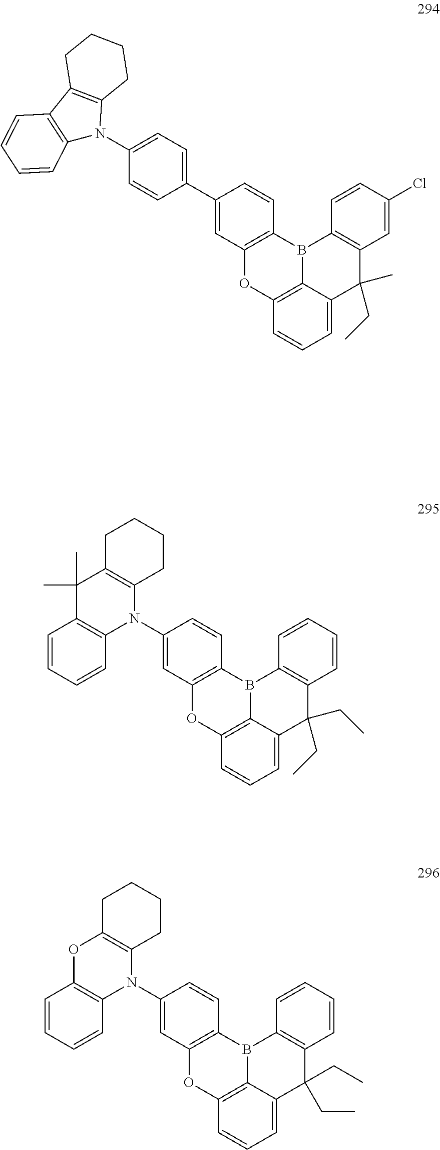 [SMILES: CCC1(C)c2cc(Cl)ccc2B2c3ccc(-c4ccc(-n5c6c(c7ccccc75)CCCC6)cc4)cc3Oc3cccc1c32 ; CCC1(CC)c2ccccc2B2c3ccc(N4C5=C(CCCC5)C(C)(C)c5ccccc54)cc3Oc3cccc1c32 ; CCC1(CC)c2ccccc2B2c3ccc(N4C5=C(CCCC5)Oc5ccccc54)cc3Oc3cccc1c32]

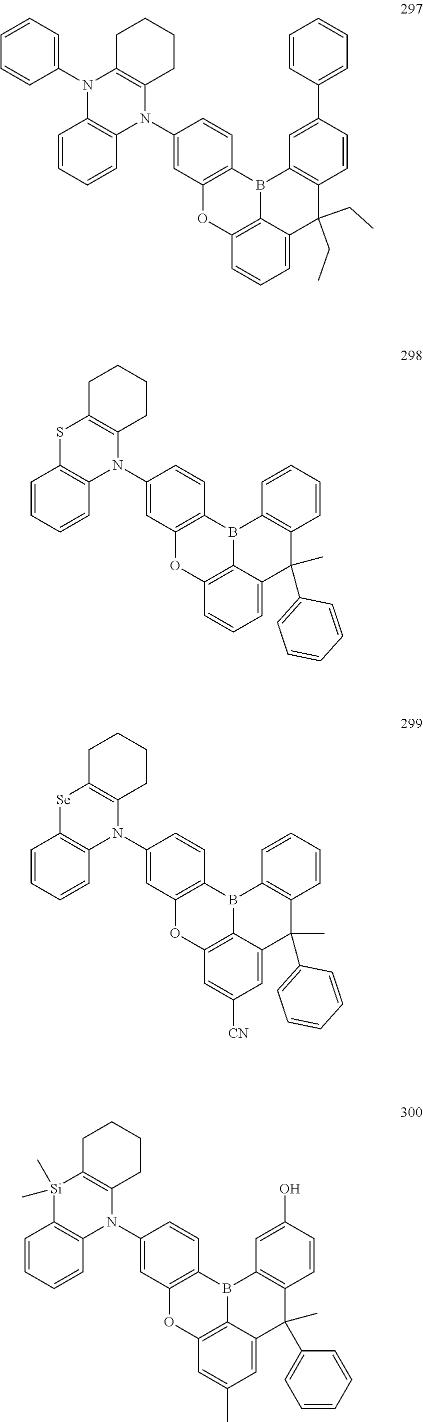

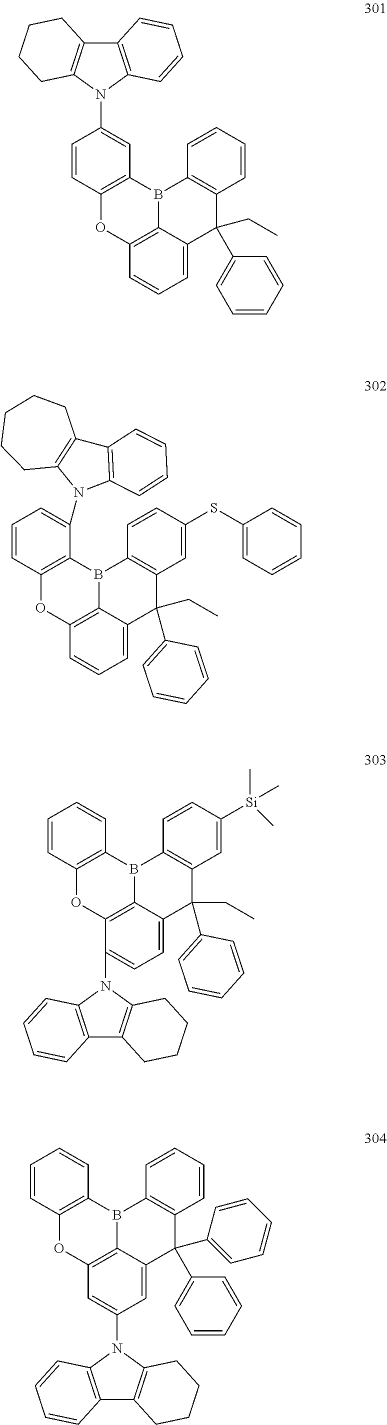 [SMILES: CCC1(c2ccccc2)c2ccccc2B2c3cc(-n4c5c(c6ccccc64)CCCC5)ccc3Oc3cccc1c32 ; CCC1(c2ccccc2)c2cc(Sc3ccccc3)ccc2B2c3c(cccc3-n3c4c(c5ccccc53)CCCCC4)Oc3cccc1c32 ; CCC1(c2ccccc2)c2cc([Si](C)(C)C)ccc2B2c3ccccc3Oc3c(-n4c5c(c6ccccc64)CCCC5)ccc1c32 ; c1ccc(C2(c3ccccc3)c3ccccc3B3c4ccccc4Oc4cc(-n5c6c(c7ccccc75)CCCC6)cc2c43)cc1]

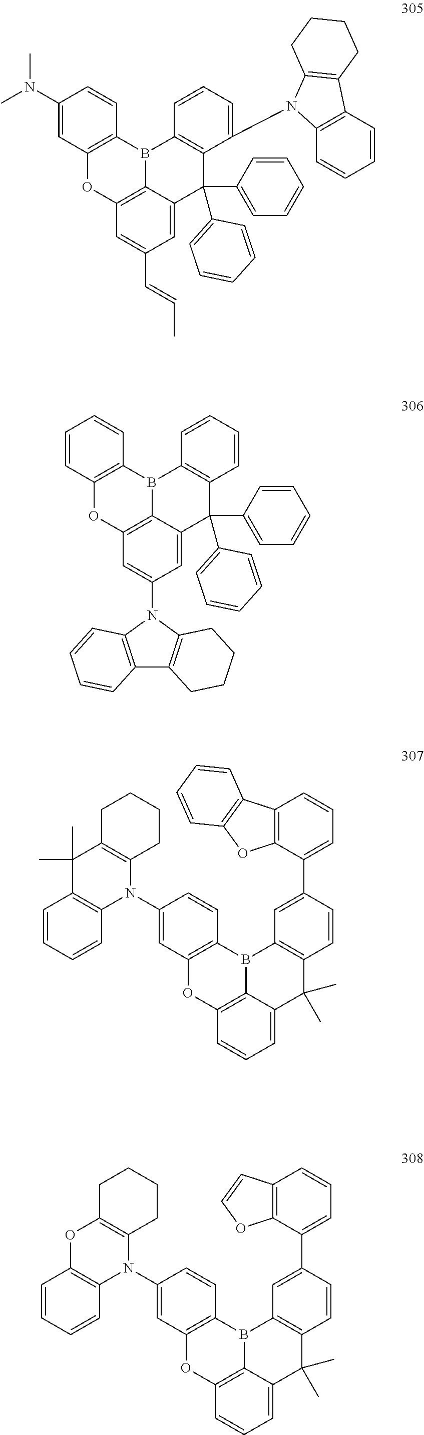

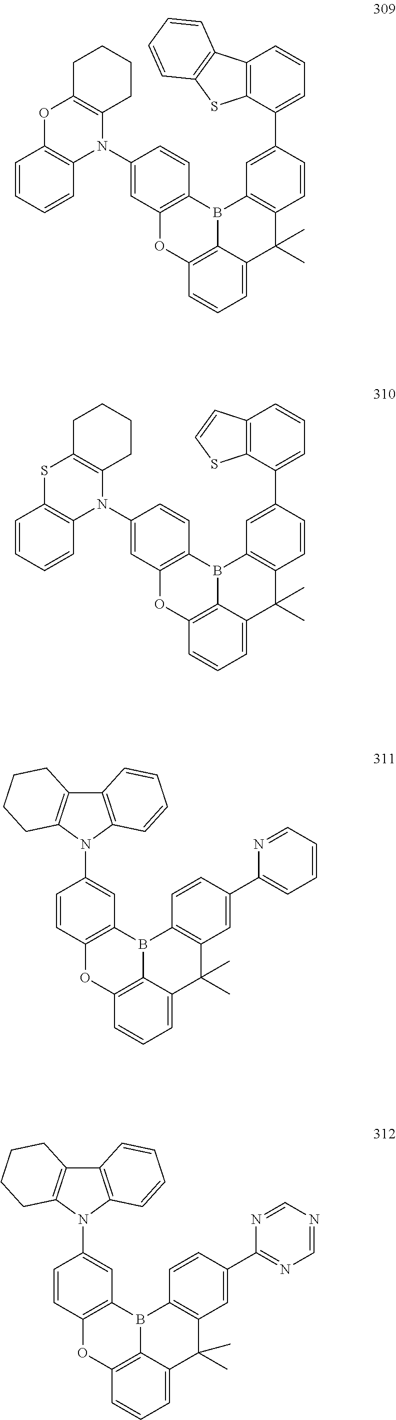 [SMILES: CC1(C)c2ccc(-c3cccc4c3sc3ccccc34)cc2B2c3ccc(N4C5=C(CCCC5)Oc5ccccc54)cc3Oc3cccc1c32 ; CC1(C)c2ccc(-c3cccc4ccsc34)cc2B2c3ccc(N4C5=C(CCCC5)Sc5ccccc54)cc3Oc3cccc1c32 ; CC1(C)c2cc(-c3ccccn3)ccc2B2c3cc(-n4c5c(c6ccccc64)CCCC5)ccc3Oc3cccc1c32 ; CC1(C)c2cc(-c3ncncn3)ccc2B2c3cc(-n4c5c(c6ccccc64)CCCC5)ccc3Oc3cccc1c32]

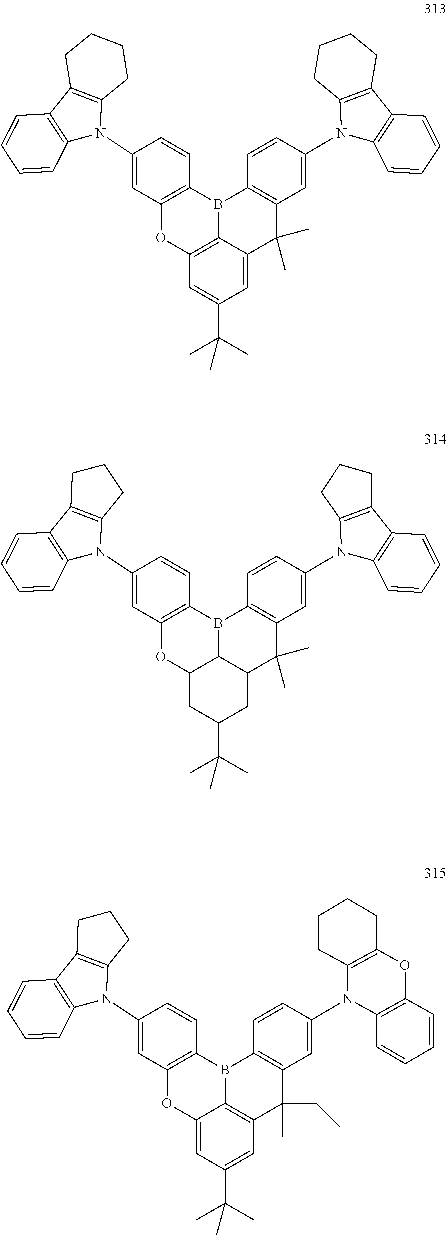 [SMILES: CC(C)(C)c1cc2c3c(c1)C(C)(C)c1cc(-n4c5c(c6ccccc64)CCCC5)ccc1B3c1ccc(-n3c4c(c5ccccc53)CCCC4)cc1O2 ; CC(C)(C)C1CC2Oc3cc(-n4c5c(c6ccccc64)CCC5)ccc3B3c4ccc(-n5c6c(c7ccccc75)CCC6)cc4C(C)(C)C(C1)C32 ; CCC1(C)c2cc(N3C4=C(CCCC4)Oc4ccccc43)ccc2B2c3ccc(-n4c5c(c6ccccc64)CCC5)cc3Oc3cc(C(C)(C)C)cc1c32]

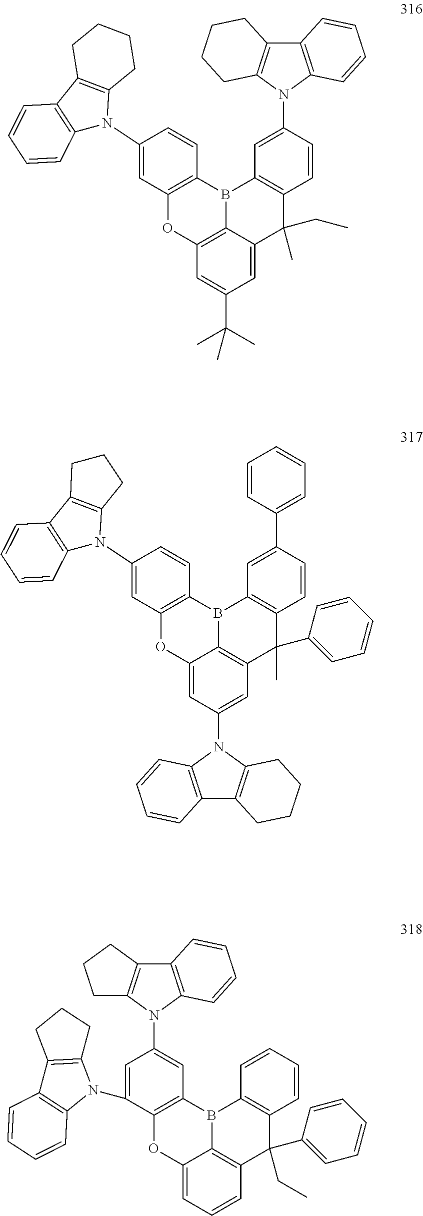 [SMILES: CCC1(C)c2ccc(-n3c4c(c5ccccc53)CCCC4)cc2B2c3ccc(-n4c5c(c6ccccc64)CCCC5)cc3Oc3cc(C(C)(C)C)cc1c32 ; CC1(c2ccccc2)c2ccc(-c3ccccc3)cc2B2c3ccc(-n4c5c(c6ccccc64)CCC5)cc3Oc3cc(-n4c5c(c6ccccc64)CCCC5)cc1c32 ; CCC1(c2ccccc2)c2ccccc2B2c3cc(-n4c5c(c6ccccc64)CCC5)cc(-n4c5c(c6ccccc64)CCC5)c3Oc3cccc1c32]

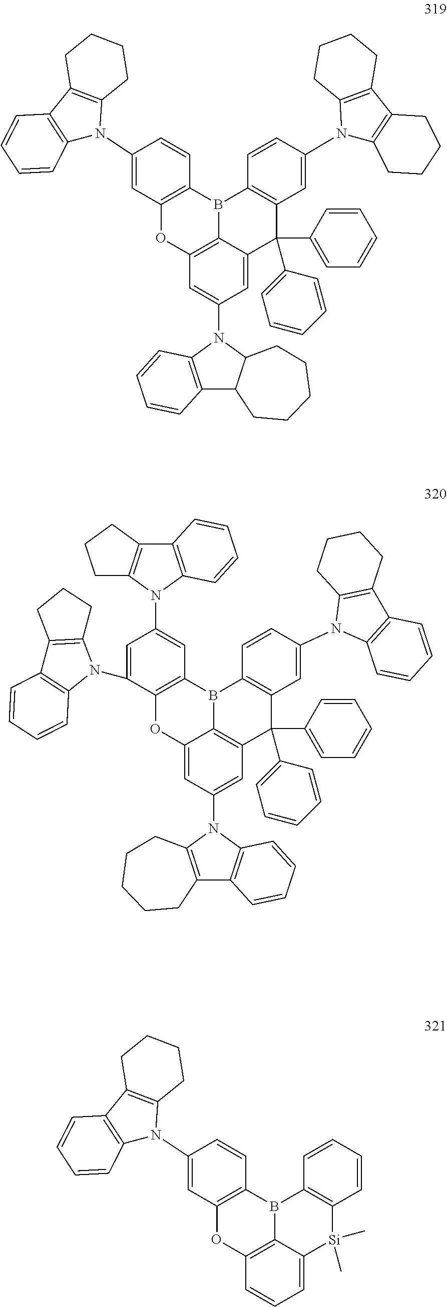 [SMILES: c1ccc(C2(c3ccccc3)c3cc(-n4c5c(c6c4CCCC6)CCCC5)ccc3B3c4ccc(-n5c6c(c7ccccc75)CCCC6)cc4Oc4cc(N5c6ccccc6C6CCCCCC65)cc2c43)cc1 ; c1ccc(C2(c3ccccc3)c3cc(-n4c5c(c6ccccc64)CCCC5)ccc3B3c4cc(-n5c6c(c7ccccc75)CCC6)cc(-n5c6c(c7ccccc75)CCC6)c4Oc4cc(-n5c6c(c7ccccc75)CCCCC6)cc2c43)cc1 ; C[Si]1(C)c2ccccc2B2c3ccc(-n4c5c(c6ccccc64)CCCC5)cc3Oc3cccc1c32]

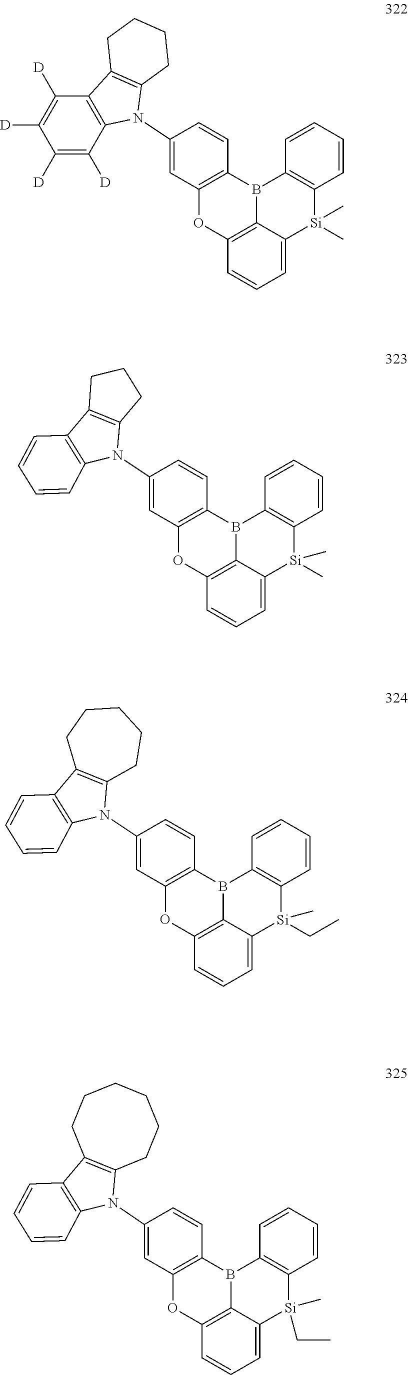 [SMILES: [2H]c1c([2H])c([2H])c2c(c1[2H])c1c(n2-c2ccc3c(c2)Oc2cccc4c2B3c2ccccc2[Si]4(C)C)CCCC1 ; C[Si]1(C)c2ccccc2B2c3ccc(-n4c5c(c6ccccc64)CCC5)cc3Oc3cccc1c32 ; CC[Si]1(C)c2ccccc2B2c3ccc(-n4c5c(c6ccccc64)CCCCC5)cc3Oc3cccc1c32 ; CC[Si]1(C)c2ccccc2B2c3ccc(-n4c5c(c6ccccc64)CCCCCC5)cc3Oc3cccc1c32]

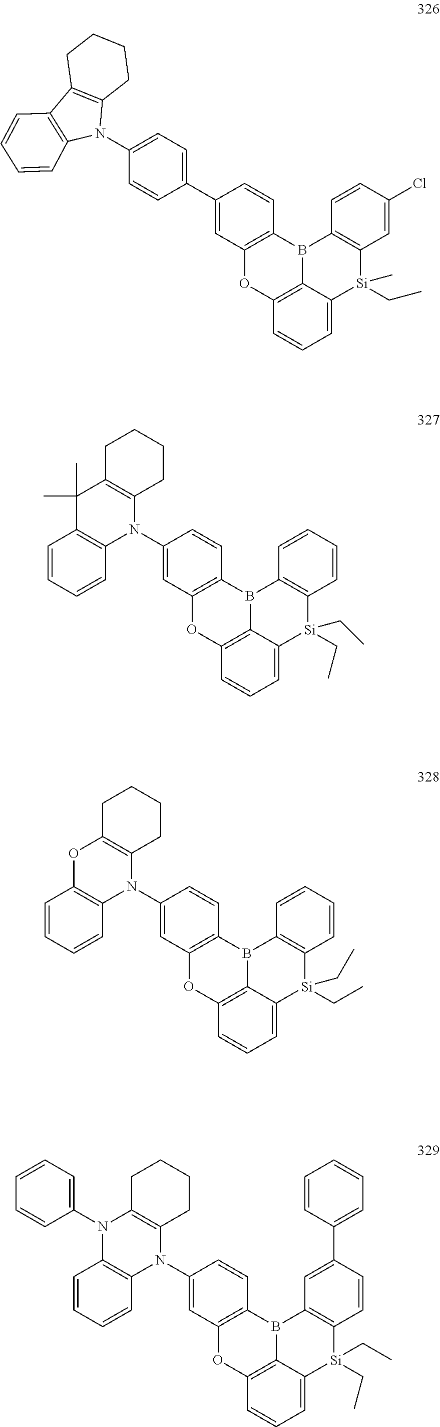

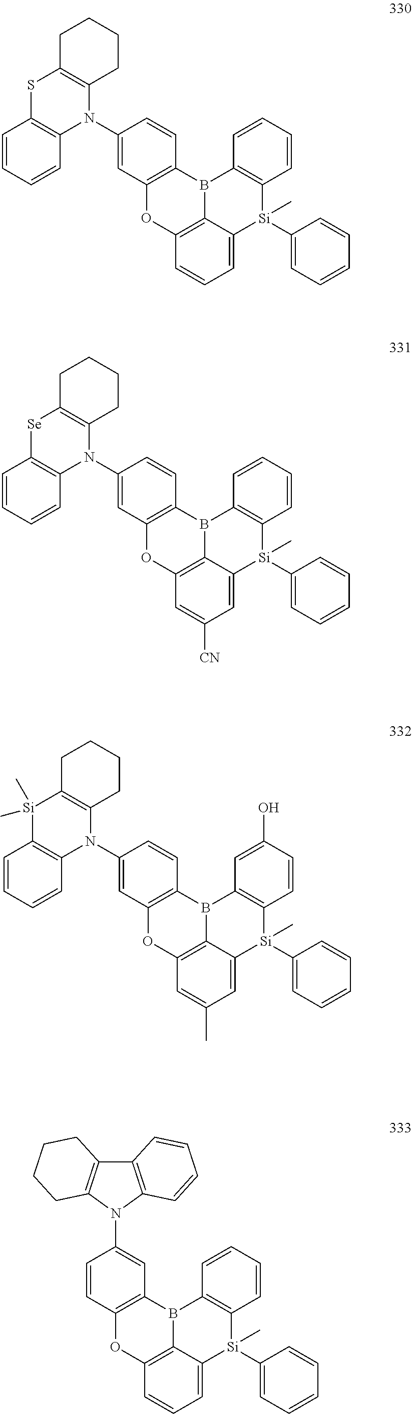 [SMILES: C[Si]1(c2ccccc2)c2ccccc2B2c3ccc(N4C5=C(CCCC5)Sc5ccccc54)cc3Oc3cccc1c32 ; C[Si]1(c2ccccc2)c2ccccc2B2c3ccc(N4C5=C(CCCC5)[Se]c5ccccc54)cc3Oc3cc(C#N)cc1c32 ; Cc1cc2c3c(c1)[Si](C)(c1ccccc1)c1ccc(O)cc1B3c1ccc(N3C4=C(CCCC4)[Si](C)(C)c4ccccc43)cc1O2 ; C[Si]1(c2ccccc2)c2ccccc2B2c3cc(-n4c5c(c6ccccc64)CCCC5)ccc3Oc3cccc1c32]

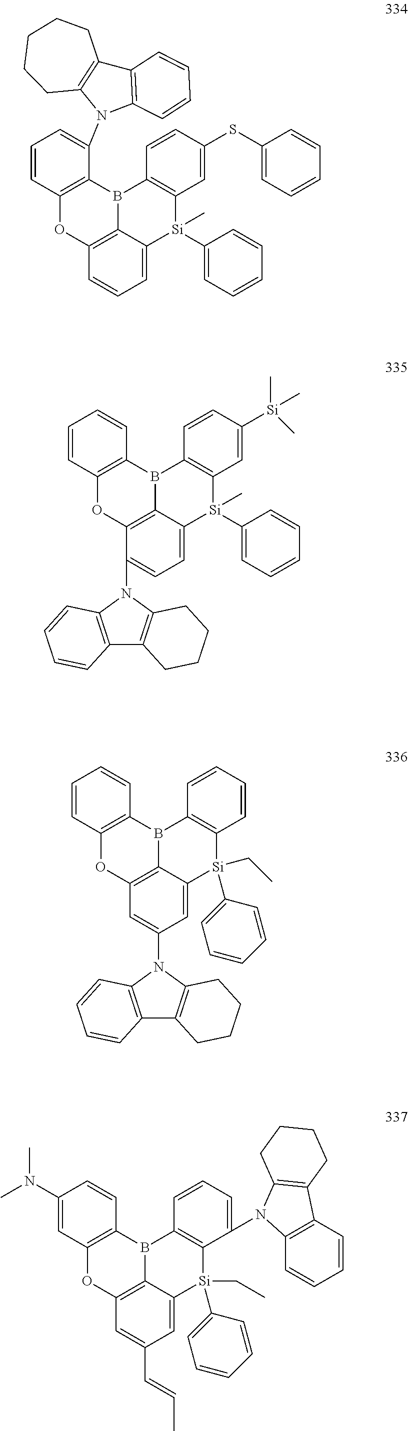

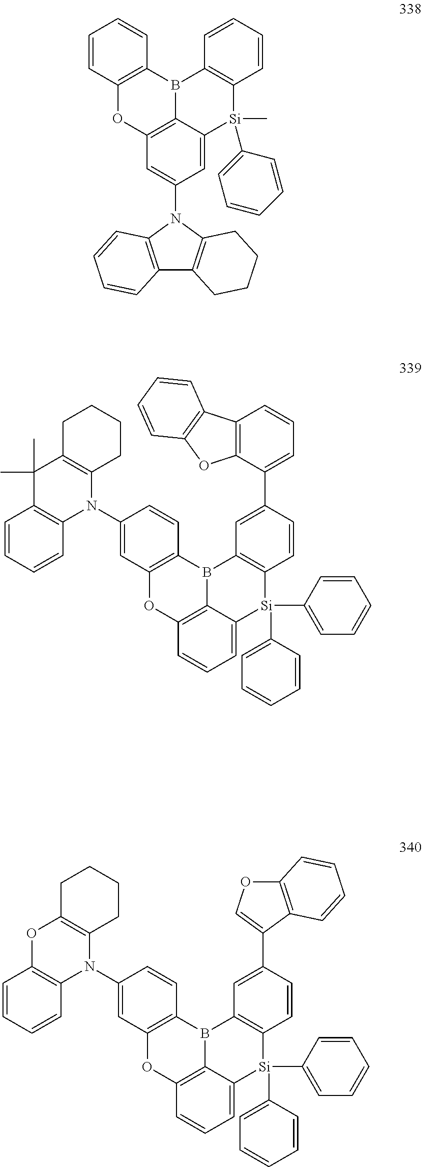 [SMILES: C[Si]1(c2ccccc2)c2ccccc2B2c3ccccc3Oc3cc(-n4c5c(c6ccccc64)CCCC5)cc1c32 ; CC1(C)C2=C(CCCC2)N(c2ccc3c(c2)Oc2cccc4c2B3c2cc(-c3cccc5c3oc3ccccc35)ccc2[Si]4(c2ccccc2)c2ccccc2)c2ccccc21 ; c1ccc([Si]2(c3ccccc3)c3ccc(-c4coc5ccccc45)cc3B3c4ccc(N5C6=C(CCCC6)Oc6ccccc65)cc4Oc4cccc2c43)cc1]

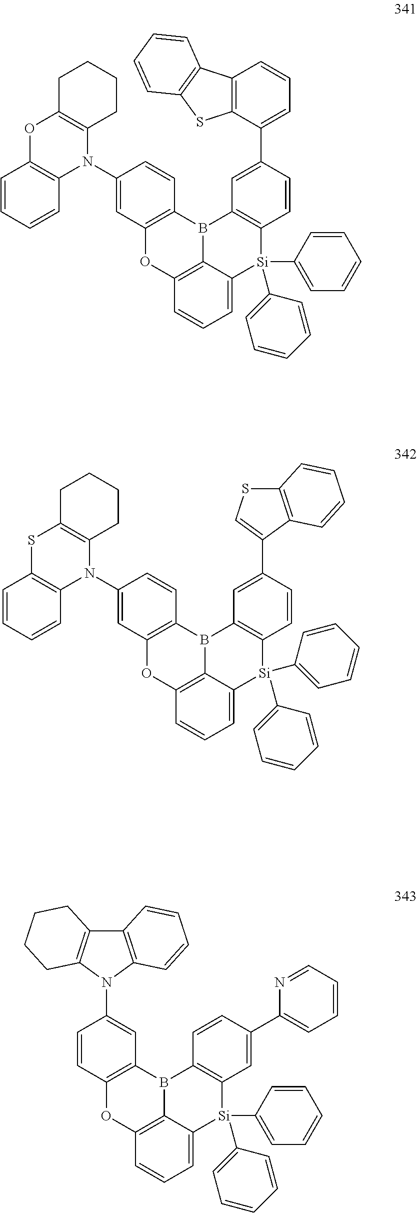 [SMILES: c1ccc([Si]2(c3ccccc3)c3ccc(-c4cccc5c4sc4ccccc45)cc3B3c4ccc(N5C6=C(CCCC6)Oc6ccccc65)cc4Oc4cccc2c43)cc1 ; c1ccc([Si]2(c3ccccc3)c3ccc(-c4csc5ccccc45)cc3B3c4ccc(N5C6=C(CCCC6)Sc6ccccc65)cc4Oc4cccc2c43)cc1 ; c1ccc([Si]2(c3ccccc3)c3cc(-c4ccccn4)ccc3B3c4cc(-n5c6c(c7ccccc75)CCCC6)ccc4Oc4cccc2c43)cc1]

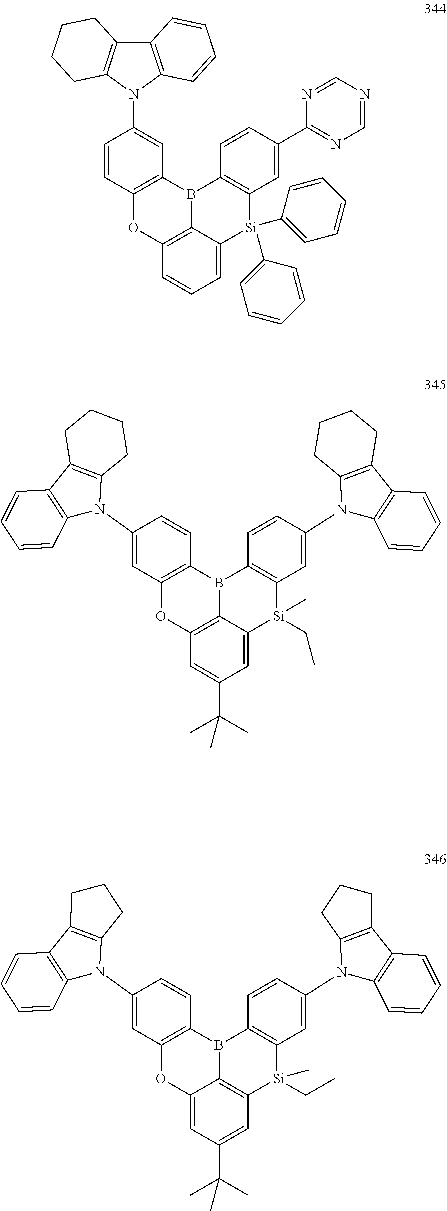 [SMILES: c1ccc([Si]2(c3ccccc3)c3cc(-c4ncncn4)ccc3B3c4cc(-n5c6c(c7ccccc75)CCCC6)ccc4Oc4cccc2c43)cc1 ; CC[Si]1(C)c2cc(-n3c4c(c5ccccc53)CCCC4)ccc2B2c3ccc(-n4c5c(c6ccccc64)CCCC5)cc3Oc3cc(C(C)(C)C)cc1c32 ; CC[Si]1(C)c2cc(-n3c4c(c5ccccc53)CCC4)ccc2B2c3ccc(-n4c5c(c6ccccc64)CCC5)cc3Oc3cc(C(C)(C)C)cc1c32]

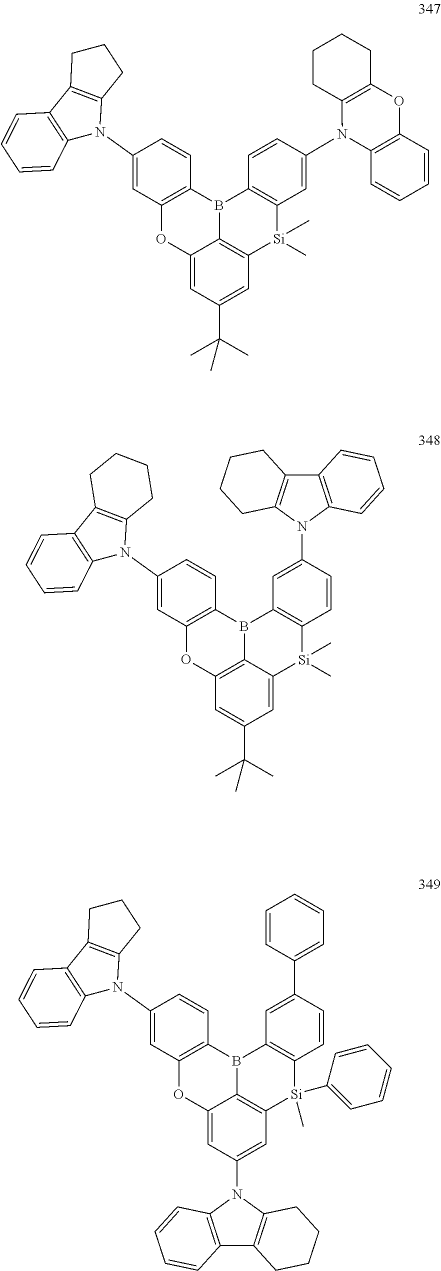 [SMILES: CC(C)(C)c1cc2c3c(c1)[Si](C)(C)c1cc(N4C5=C(CCCC5)Oc5ccccc54)ccc1B3c1ccc(-n3c4c(c5ccccc53)CCC4)cc1O2 ; CC(C)(C)c1cc2c3c(c1)[Si](C)(C)c1ccc(-n4c5c(c6ccccc64)CCCC5)cc1B3c1ccc(-n3c4c(c5ccccc53)CCCC4)cc1O2 ; C[Si]1(c2ccccc2)c2ccc(-c3ccccc3)cc2B2c3ccc(-n4c5c(c6ccccc64)CCC5)cc3Oc3cc(-n4c5c(c6ccccc64)CCCC5)cc1c32]

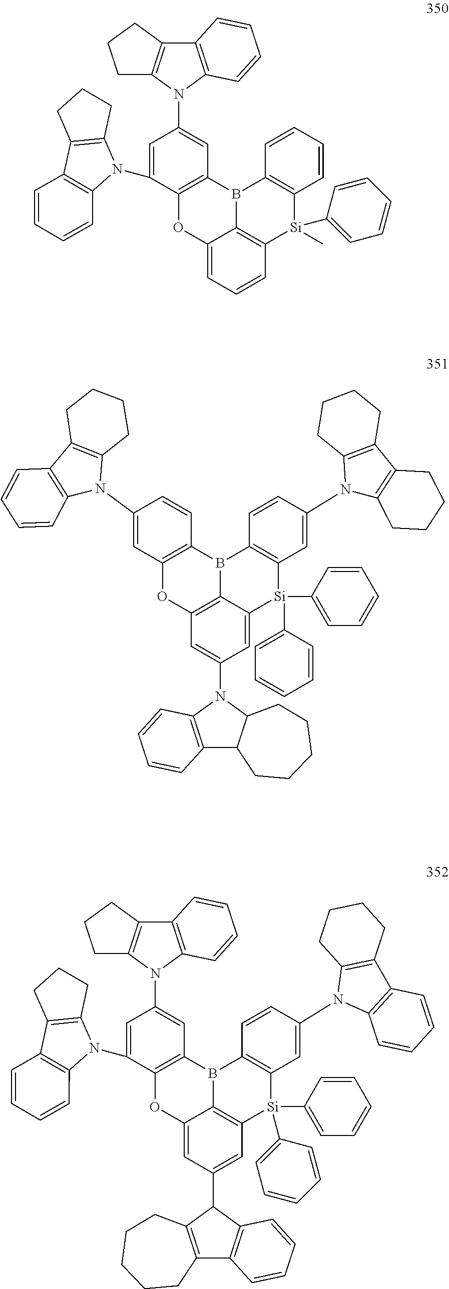 [SMILES: C[Si]1(c2ccccc2)c2ccccc2B2c3cc(-n4c5c(c6ccccc64)CCC5)cc(-n4c5c(c6ccccc64)CCC5)c3Oc3cccc1c32 ; c1ccc([Si]2(c3ccccc3)c3cc(-n4c5c(c6c4CCCC6)CCCC5)ccc3B3c4ccc(-n5c6c(c7ccccc75)CCCC6)cc4Oc4cc(N5c6ccccc6C6CCCCCC65)cc2c43)cc1 ; c1ccc([Si]2(c3ccccc3)c3cc(-n4c5c(c6ccccc64)CCCC5)ccc3B3c4cc(-n5c6c(c7ccccc75)CCC6)cc(-n5c6c(c7ccccc75)CCC6)c4Oc4cc(C5C6=C(CCCCC6)c6ccccc65)cc2c43)cc1]

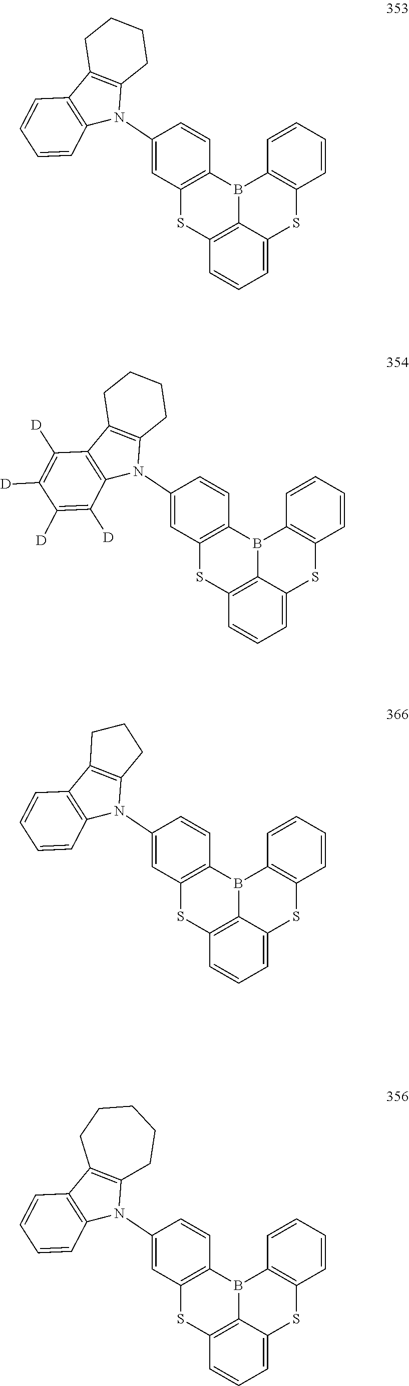 [SMILES: c1ccc2c(c1)Sc1cccc3c1B2c1ccc(-n2c4c(c5ccccc52)CCCC4)cc1S3 ; [2H]c1c([2H])c([2H])c2c(c1[2H])c1c(n2-c2ccc3c(c2)Sc2cccc4c2B3c2ccccc2S4)CCCC1 ; c1ccc2c(c1)Sc1cccc3c1B2c1ccc(-n2c4c(c5ccccc52)CCC4)cc1S3 ; c1ccc2c(c1)Sc1cccc3c1B2c1ccc(-n2c4c(c5ccccc52)CCCCC4)cc1S3]

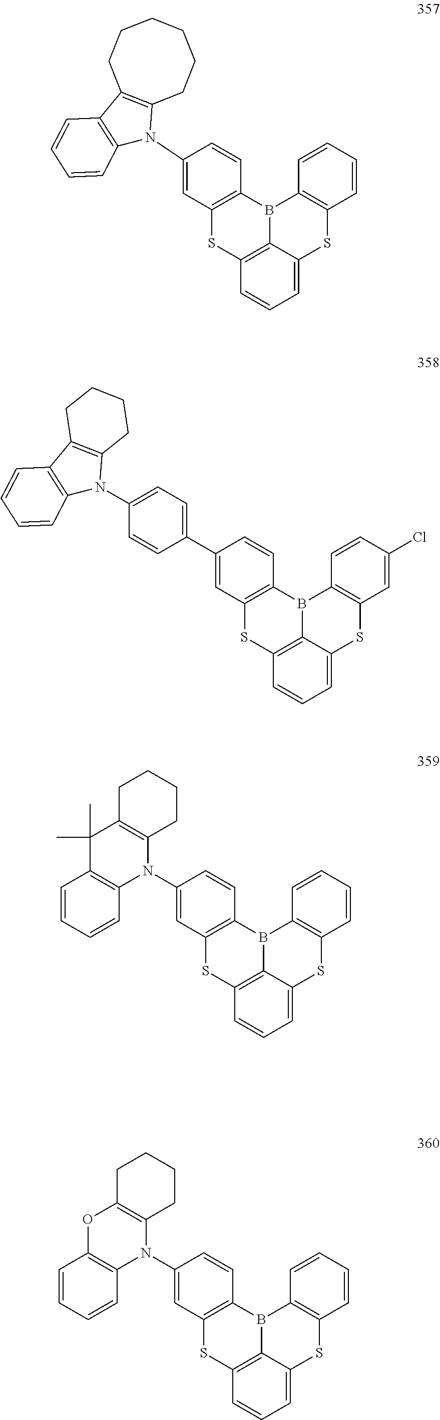 [SMILES: c1ccc2c(c1)Sc1cccc3c1B2c1ccc(-n2c4c(c5ccccc52)CCCCCC4)cc1S3 ; Clc1ccc2c(c1)Sc1cccc3c1B2c1ccc(-c2ccc(-n4c5c(c6ccccc64)CCCC5)cc2)cc1S3 ; CC1(C)C2=C(CCCC2)N(c2ccc3c(c2)Sc2cccc4c2B3c2ccccc2S4)c2ccccc21 ; c1ccc2c(c1)OC1=C(CCCC1)N2c1ccc2c(c1)Sc1cccc3c1B2c1ccccc1S3]

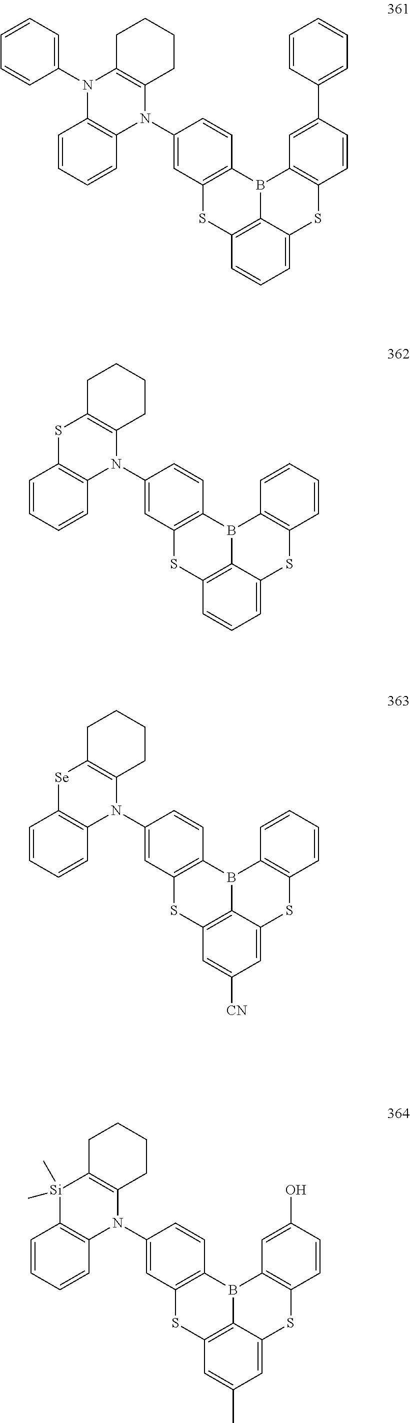 [SMILES: c1ccc(-c2ccc3c(c2)B2c4ccc(N5C6=C(CCCC6)N(c6ccccc6)c6ccccc65)cc4Sc4cccc(c42)S3)cc1 ; c1ccc2c(c1)Sc1cccc3c1B2c1ccc(N2C4=C(CCCC4)Sc4ccccc42)cc1S3 ; N#Cc1cc2c3c(c1)Sc1cc(N4C5=C(CCCC5)[Se]c5ccccc54)ccc1B3c1ccccc1S2 ; Cc1cc2c3c(c1)Sc1ccc(O)cc1B3c1ccc(N3C4=C(CCCC4)[Si](C)(C)c4ccccc43)cc1S2]

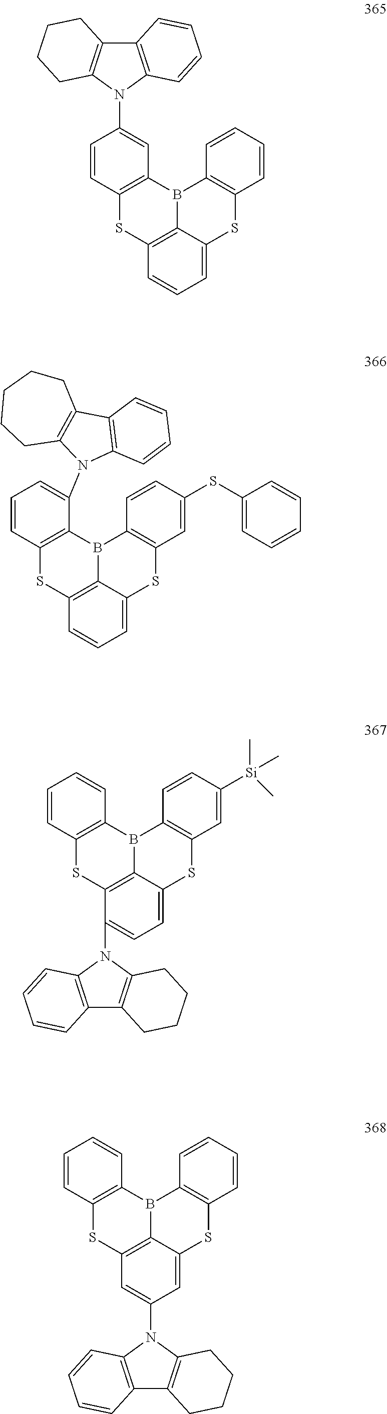 [SMILES: c1ccc2c(c1)Sc1cccc3c1B2c1cc(-n2c4c(c5ccccc52)CCCC4)ccc1S3 ; c1ccc(Sc2ccc3c(c2)Sc2cccc4c2B3c2c(cccc2-n2c3c(c5ccccc52)CCCCC3)S4)cc1 ; C[Si](C)(C)c1ccc2c(c1)Sc1ccc(-n3c4c(c5ccccc53)CCCC4)c3c1B2c1ccccc1S3 ; c1ccc2c(c1)Sc1cc(-n3c4c(c5ccccc53)CCCC4)cc3c1B2c1ccccc1S3]

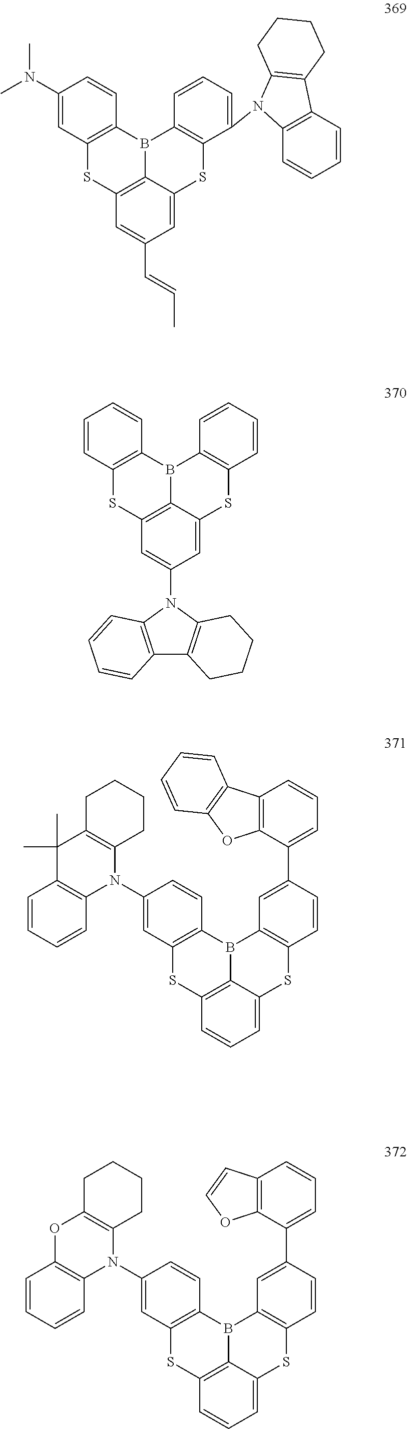 [SMILES: C/C=C/c1cc2c3c(c1)Sc1c(cccc1-n1c4c(c5ccccc51)CCCC4)B3c1ccc(N(C)C)cc1S2 ; c1ccc2c(c1)Sc1cc(-n3c4c(c5ccccc53)CCCC4)cc3c1B2c1ccccc1S3 ; CC1(C)C2=C(CCCC2)N(c2ccc3c(c2)Sc2cccc4c2B3c2cc(-c3cccc5c3oc3ccccc35)ccc2S4)c2ccccc21 ; c1ccc2c(c1)OC1=C(CCCC1)N2c1ccc2c(c1)Sc1cccc3c1B2c1cc(-c2cccc4ccoc24)ccc1S3]

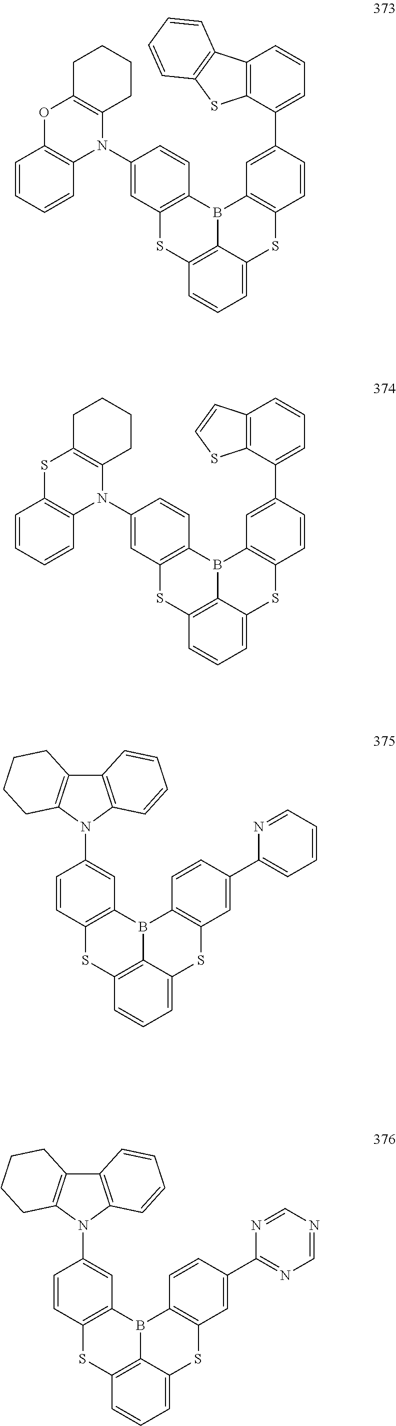 [SMILES: c1ccc2c(c1)OC1=C(CCCC1)N2c1ccc2c(c1)Sc1cccc3c1B2c1cc(-c2cccc4c2sc2ccccc24)ccc1S3 ; c1ccc2c(c1)SC1=C(CCCC1)N2c1ccc2c(c1)Sc1cccc3c1B2c1cc(-c2cccc4ccsc24)ccc1S3 ; c1ccc(-c2ccc3c(c2)Sc2cccc4c2B3c2cc(-n3c5c(c6ccccc63)CCCC5)ccc2S4)nc1 ; c1cc2c3c(c1)Sc1ccc(-n4c5c(c6ccccc64)CCCC5)cc1B3c1ccc(-c3ncncn3)cc1S2]

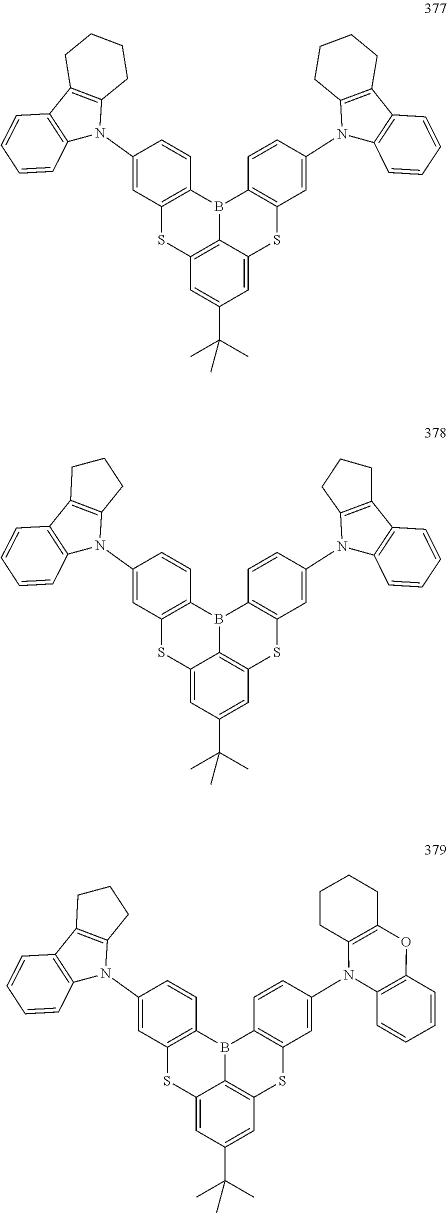 [SMILES: CC(C)(C)c1cc2c3c(c1)Sc1cc(-n4c5c(c6ccccc64)CCCC5)ccc1B3c1ccc(-n3c4c(c5ccccc53)CCCC4)cc1S2 ; CC(C)(C)c1cc2c3c(c1)Sc1cc(-n4c5c(c6ccccc64)CCC5)ccc1B3c1ccc(-n3c4c(c5ccccc53)CCC4)cc1S2 ; CC(C)(C)c1cc2c3c(c1)Sc1cc(-n4c5c(c6ccccc64)CCC5)ccc1B3c1ccc(N3C4=C(CCCC4)Oc4ccccc43)cc1S2]

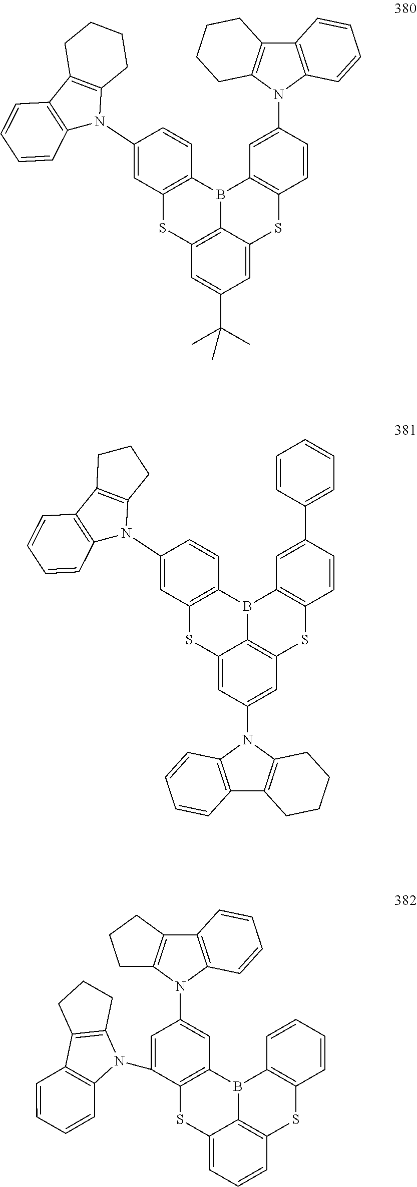 [SMILES: CC(C)(C)c1cc2c3c(c1)Sc1ccc(-n4c5c(c6ccccc64)CCCC5)cc1B3c1ccc(-n3c4c(c5ccccc53)CCCC4)cc1S2 ; c1ccc(-c2ccc3c(c2)B2c4ccc(-n5c6c(c7ccccc75)CCC6)cc4Sc4cc(-n5c6c(c7ccccc75)CCCC6)cc(c42)S3)cc1 ; c1ccc2c(c1)Sc1cccc3c1B2c1cc(-n2c4c(c5ccccc52)CCC4)cc(-n2c4c(c5ccccc52)CCC4)c1S3]

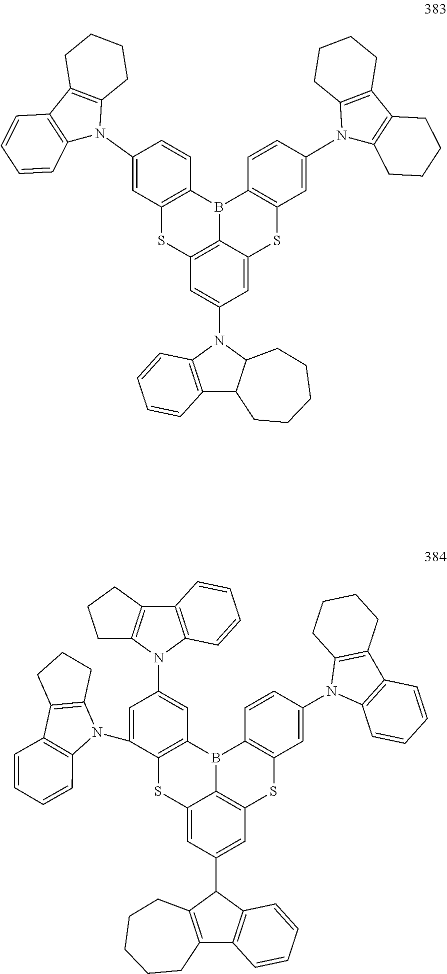 [SMILES: c1ccc2c(c1)C1CCCCCC1N2c1cc2c3c(c1)Sc1cc(-n4c5c(c6ccccc64)CCCC5)ccc1B3c1ccc(-n3c4c(c5c3CCCC5)CCCC4)cc1S2 ; c1ccc2c(c1)C1=C(CCCCC1)C2c1cc2c3c(c1)Sc1c(cc(-n4c5c(c6ccccc64)CCC5)cc1-n1c4c(c5ccccc51)CCC4)B3c1ccc(-n3c4c(c5ccccc53)CCCC4)cc1S2]

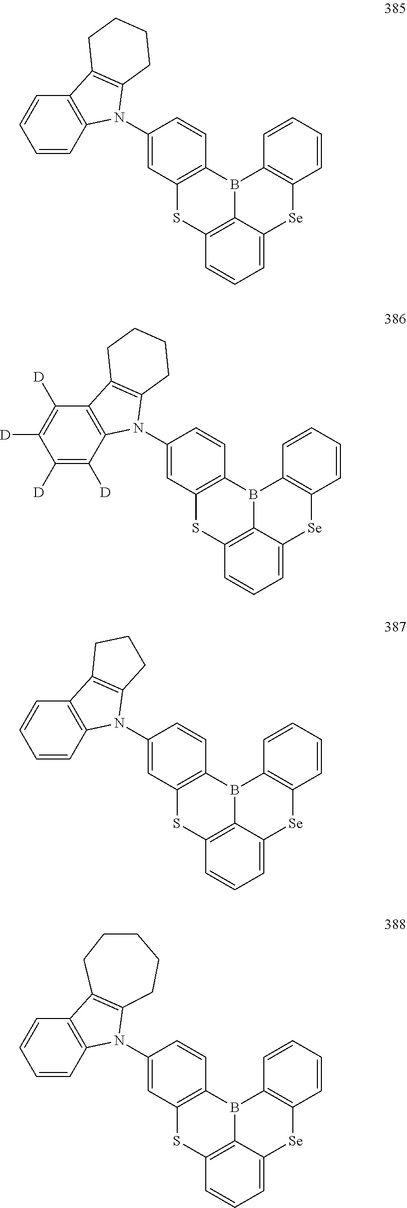 [SMILES: c1ccc2c(c1)[Se]c1cccc3c1B2c1ccc(-n2c4c(c5ccccc52)CCCC4)cc1S3 ; [2H]c1c([2H])c([2H])c2c(c1[2H])c1c(n2-c2ccc3c(c2)Sc2cccc4c2B3c2ccccc2[Se]4)CCCC1 ; c1ccc2c(c1)[Se]c1cccc3c1B2c1ccc(-n2c4c(c5ccccc52)CCC4)cc1S3 ; c1ccc2c(c1)[Se]c1cccc3c1B2c1ccc(-n2c4c(c5ccccc52)CCCCC4)cc1S3]

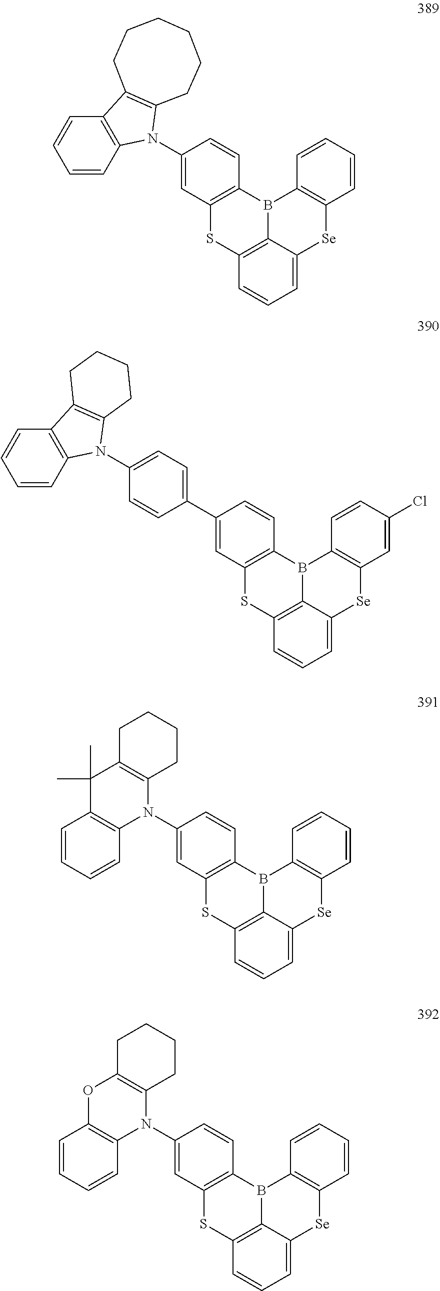 [SMILES: c1ccc2c(c1)[Se]c1cccc3c1B2c1ccc(-n2c4c(c5ccccc52)CCCCCC4)cc1S3 ; Clc1ccc2c(c1)[Se]c1cccc3c1B2c1ccc(-c2ccc(-n4c5c(c6ccccc64)CCCC5)cc2)cc1S3 ; CC1(C)C2=C(CCCC2)N(c2ccc3c(c2)Sc2cccc4c2B3c2ccccc2[Se]4)c2ccccc21 ; c1ccc2c(c1)OC1=C(CCCC1)N2c1ccc2c(c1)Sc1cccc3c1B2c1ccccc1[Se]3]

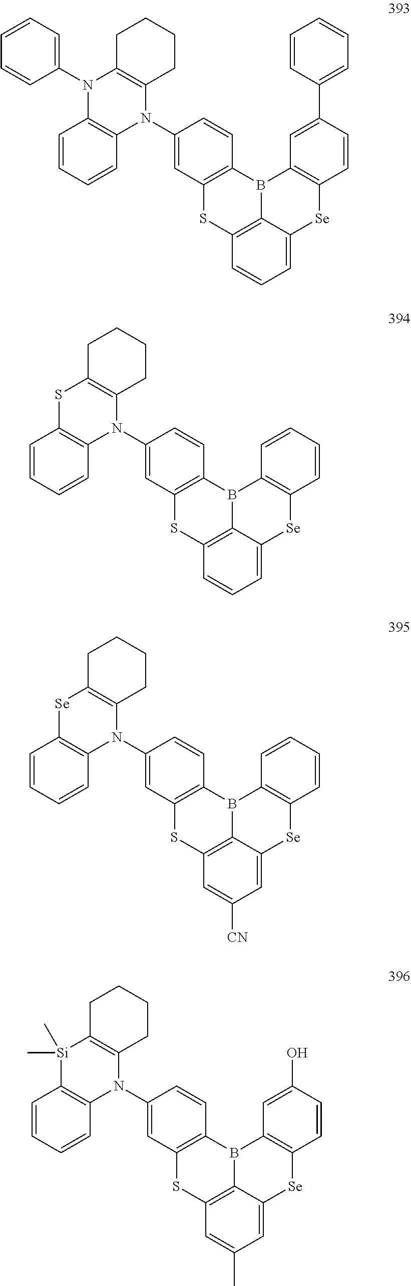 [SMILES: c1ccc(-c2ccc3c(c2)B2c4ccc(N5C6=C(CCCC6)N(c6ccccc6)c6ccccc65)cc4Sc4cccc(c42)[Se]3)cc1 ; c1ccc2c(c1)SC1=C(CCCC1)N2c1ccc2c(c1)Sc1cccc3c1B2c1ccccc1[Se]3 ; N#Cc1cc2c3c(c1)[Se]c1ccccc1B3c1ccc(N3C4=C(CCCC4)[Se]c4ccccc43)cc1S2 ; Cc1cc2c3c(c1)[Se]c1ccc(O)cc1B3c1ccc(N3C4=C(CCCC4)[Si](C)(C)c4ccccc43)cc1S2]

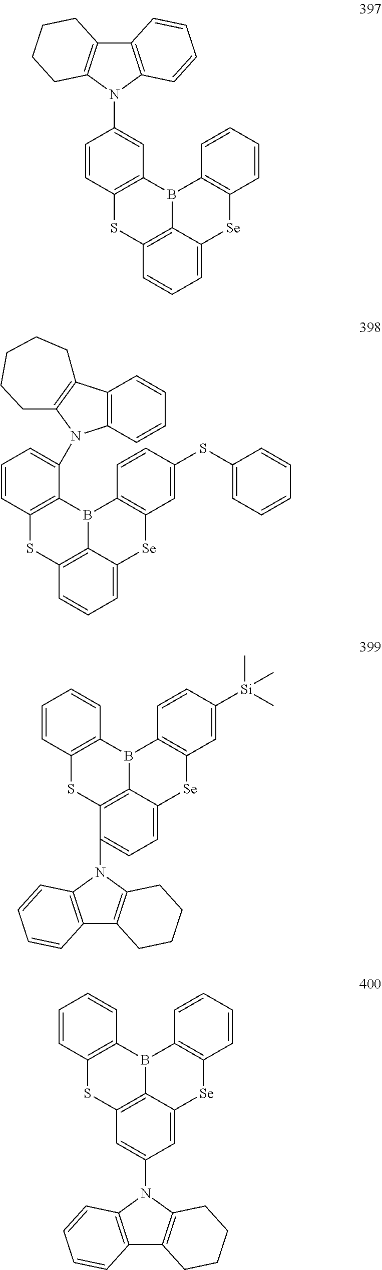 [SMILES: c1ccc2c(c1)[Se]c1cccc3c1B2c1cc(-n2c4c(c5ccccc52)CCCC4)ccc1S3 ; c1ccc(Sc2ccc3c(c2)[Se]c2cccc4c2B3c2c(cccc2-n2c3c(c5ccccc52)CCCCC3)S4)cc1 ; C[Si](C)(C)c1ccc2c(c1)[Se]c1ccc(-n3c4c(c5ccccc53)CCCC4)c3c1B2c1ccccc1S3 ; c1ccc2c(c1)Sc1cc(-n3c4c(c5ccccc53)CCCC4)cc3c1B2c1ccccc1[Se]3]

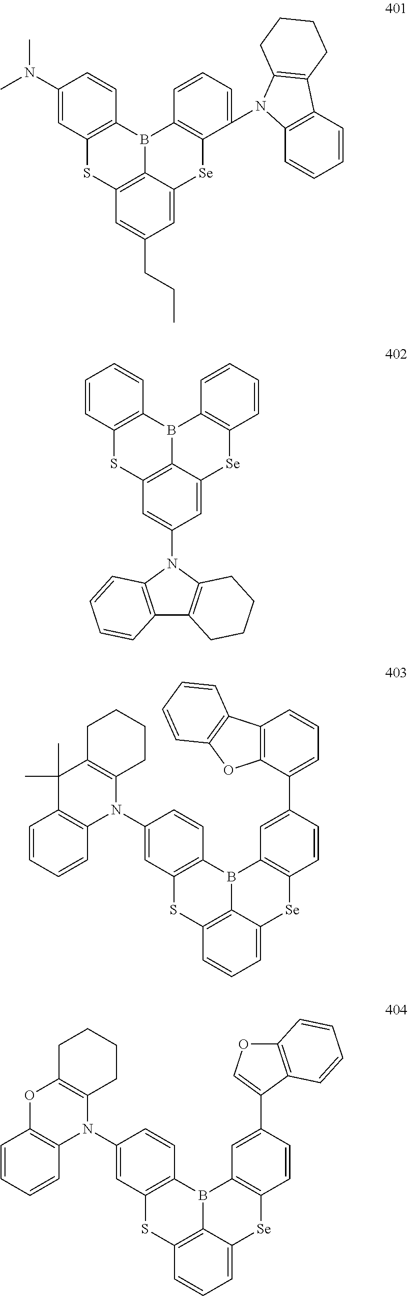

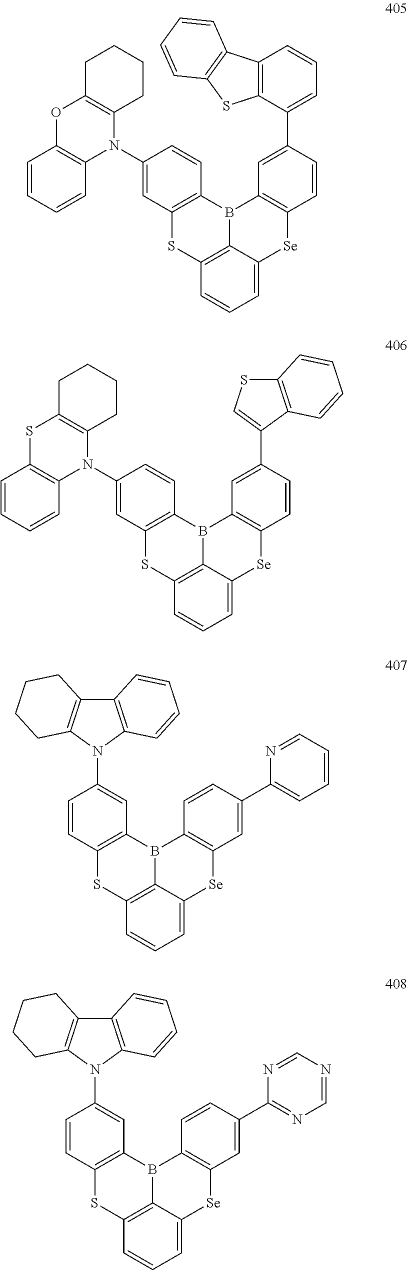 [SMILES: c1ccc2c(c1)OC1=C(CCCC1)N2c1ccc2c(c1)Sc1cccc3c1B2c1cc(-c2cccc4c2sc2ccccc24)ccc1[Se]3 ; c1ccc2c(c1)SC1=C(CCCC1)N2c1ccc2c(c1)Sc1cccc3c1B2c1cc(-c2csc4ccccc24)ccc1[Se]3 ; c1ccc(-c2ccc3c(c2)[Se]c2cccc4c2B3c2cc(-n3c5c(c6ccccc63)CCCC5)ccc2S4)nc1 ; c1cc2c3c(c1)[Se]c1cc(-c4ncncn4)ccc1B3c1cc(-n3c4c(c5ccccc53)CCCC4)ccc1S2]

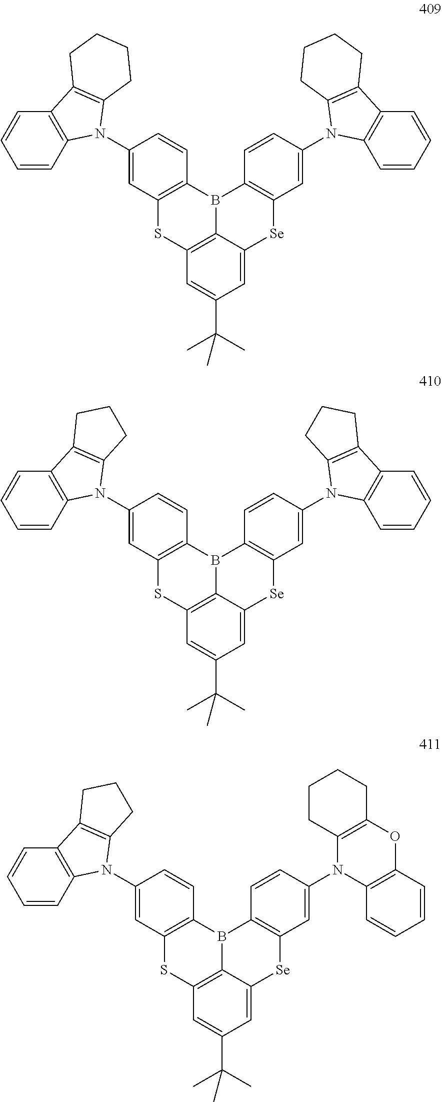 [SMILES: CC(C)(C)c1cc2c3c(c1)[Se]c1cc(-n4c5c(c6ccccc64)CCCC5)ccc1B3c1ccc(-n3c4c(c5ccccc53)CCCC4)cc1S2 ; CC(C)(C)c1cc2c3c(c1)[Se]c1cc(-n4c5c(c6ccccc64)CCC5)ccc1B3c1ccc(-n3c4c(c5ccccc53)CCC4)cc1S2 ; CC(C)(C)c1cc2c3c(c1)[Se]c1cc(N4C5=C(CCCC5)Oc5ccccc54)ccc1B3c1ccc(-n3c4c(c5ccccc53)CCC4)cc1S2]

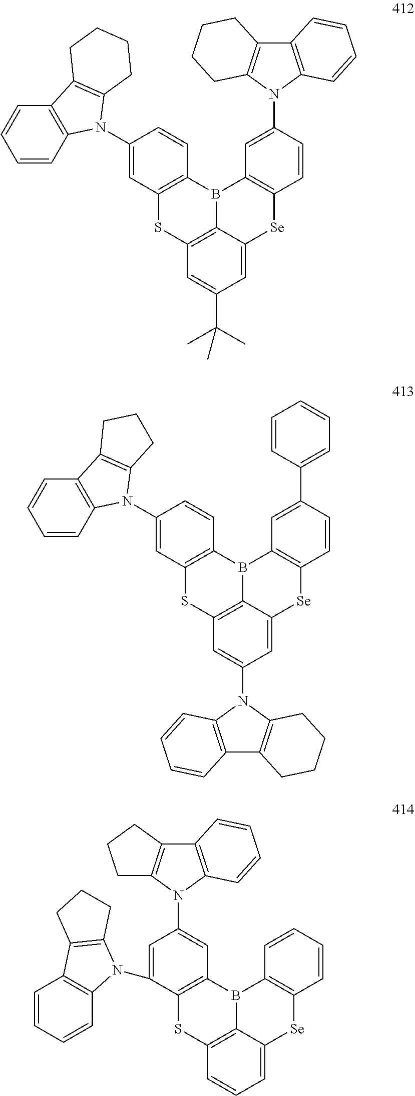

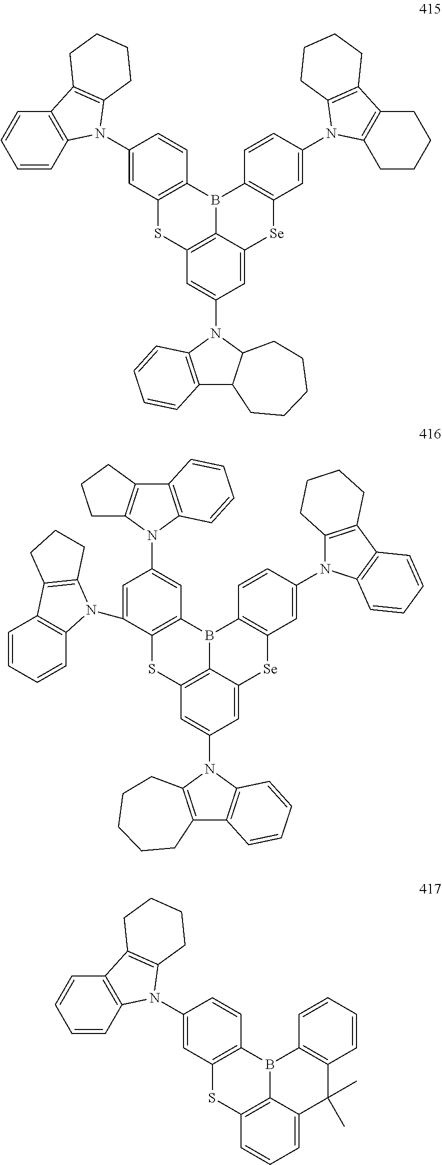 [SMILES: c1ccc2c(c1)C1CCCCCC1N2c1cc2c3c(c1)[Se]c1cc(-n4c5c(c6c4CCCC6)CCCC5)ccc1B3c1ccc(-n3c4c(c5ccccc53)CCCC4)cc1S2 ; c1ccc2c(c1)c1c(n2-c2cc3c4c(c2)[Se]c2cc(-n5c6c(c7ccccc75)CCCC6)ccc2B4c2cc(-n4c5c(c6ccccc64)CCC5)cc(-n4c5c(c6ccccc64)CCC5)c2S3)CCCCC1 ; CC1(C)c2ccccc2B2c3ccc(-n4c5c(c6ccccc64)CCCC5)cc3Sc3cccc1c32]

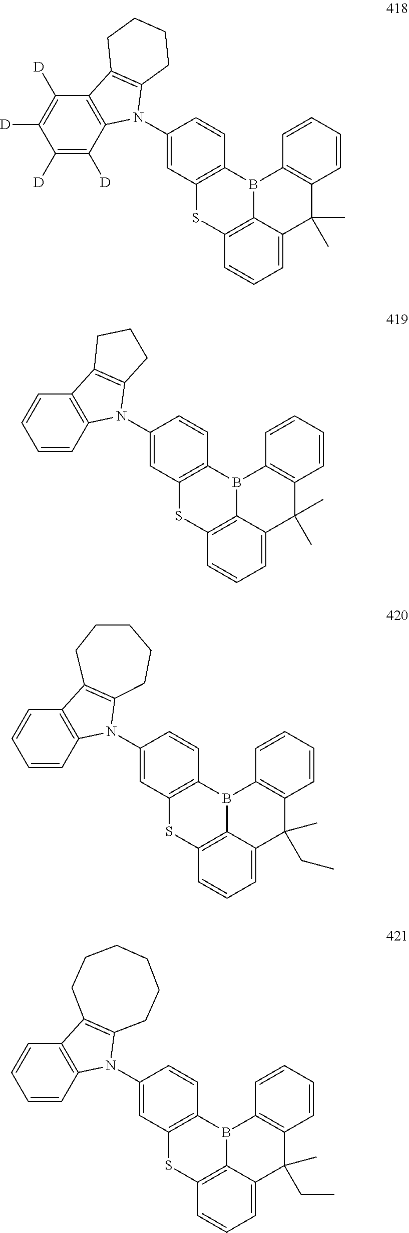 [SMILES: [2H]c1c([2H])c([2H])c2c(c1[2H])c1c(n2-c2ccc3c(c2)Sc2cccc4c2B3c2ccccc2C4(C)C)CCCC1 ; CC1(C)c2ccccc2B2c3ccc(-n4c5c(c6ccccc64)CCC5)cc3Sc3cccc1c32 ; CCC1(C)c2ccccc2B2c3ccc(-n4c5c(c6ccccc64)CCCCC5)cc3Sc3cccc1c32 ; CCC1(C)c2ccccc2B2c3ccc(-n4c5c(c6ccccc64)CCCCCC5)cc3Sc3cccc1c32]

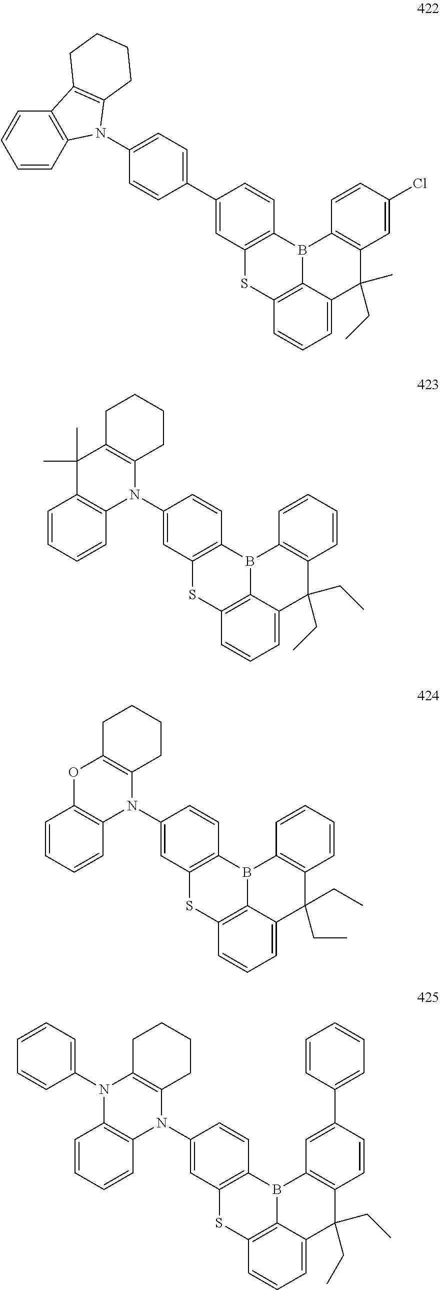 [SMILES: CCC1(C)c2cc(Cl)ccc2B2c3ccc(-c4ccc(-n5c6c(c7ccccc75)CCCC6)cc4)cc3Sc3cccc1c32 ; CCC1(CC)c2ccccc2B2c3ccc(N4C5=C(CCCC5)C(C)(C)c5ccccc54)cc3Sc3cccc1c32 ; CCC1(CC)c2ccccc2B2c3ccc(N4C5=C(CCCC5)Oc5ccccc54)cc3Sc3cccc1c32 ; CCC1(CC)c2ccc(-c3ccccc3)cc2B2c3ccc(N4C5=C(CCCC5)N(c5ccccc5)c5ccccc54)cc3Sc3cccc1c32]

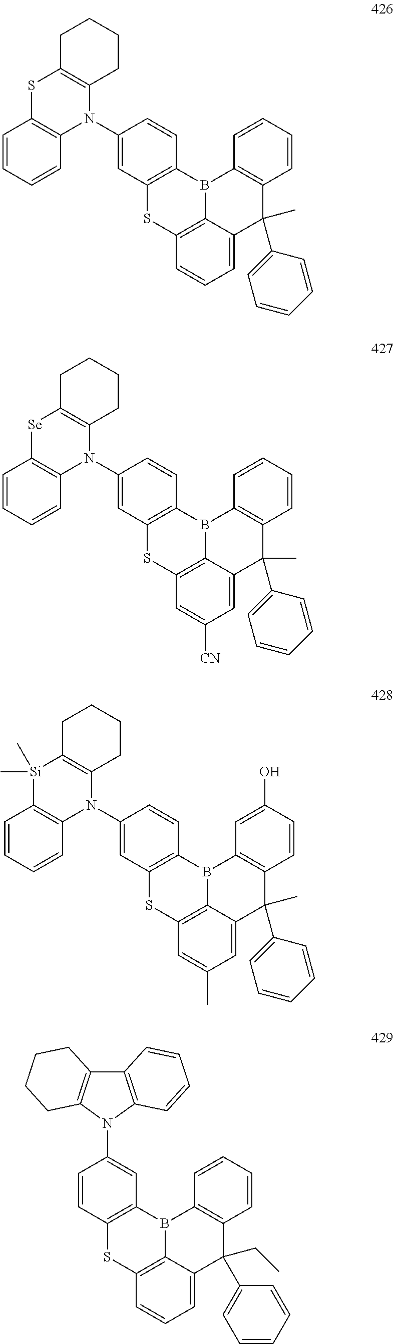 [SMILES: CC1(c2ccccc2)c2ccccc2B2c3ccc(N4C5=C(CCCC5)Sc5ccccc54)cc3Sc3cccc1c32 ; CC1(c2ccccc2)c2ccccc2B2c3ccc(N4C5=C(CCCC5)[Se]c5ccccc54)cc3Sc3cc(C#N)cc1c32 ; Cc1cc2c3c(c1)C(C)(c1ccccc1)c1ccc(O)cc1B3c1ccc(N3C4=C(CCCC4)[Si](C)(C)c4ccccc43)cc1S2 ; CCC1(c2ccccc2)c2ccccc2B2c3cc(-n4c5c(c6ccccc64)CCCC5)ccc3Sc3cccc1c32]

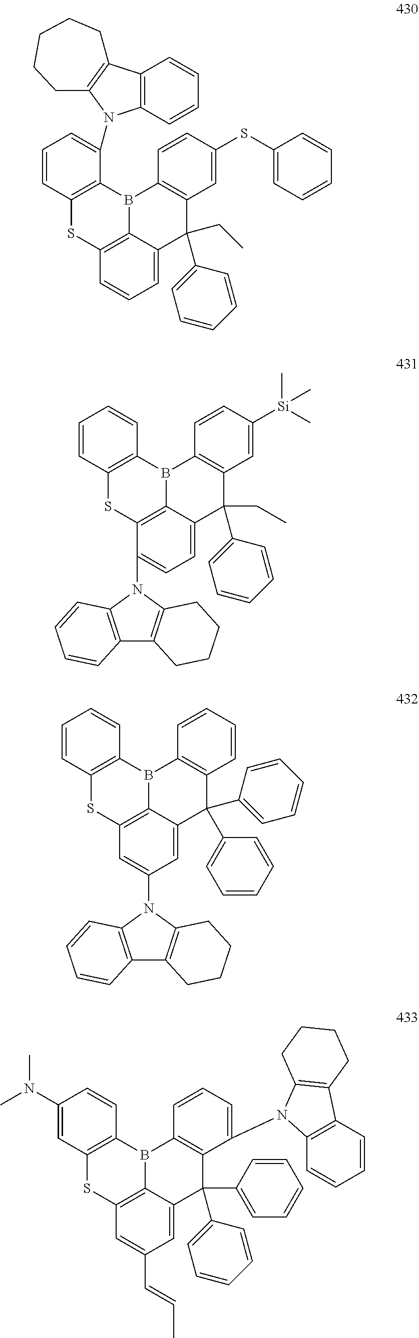

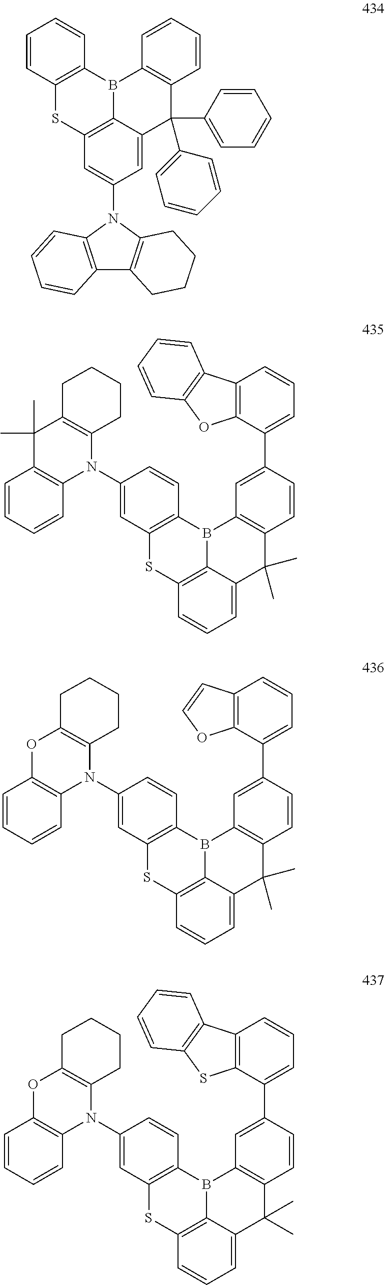

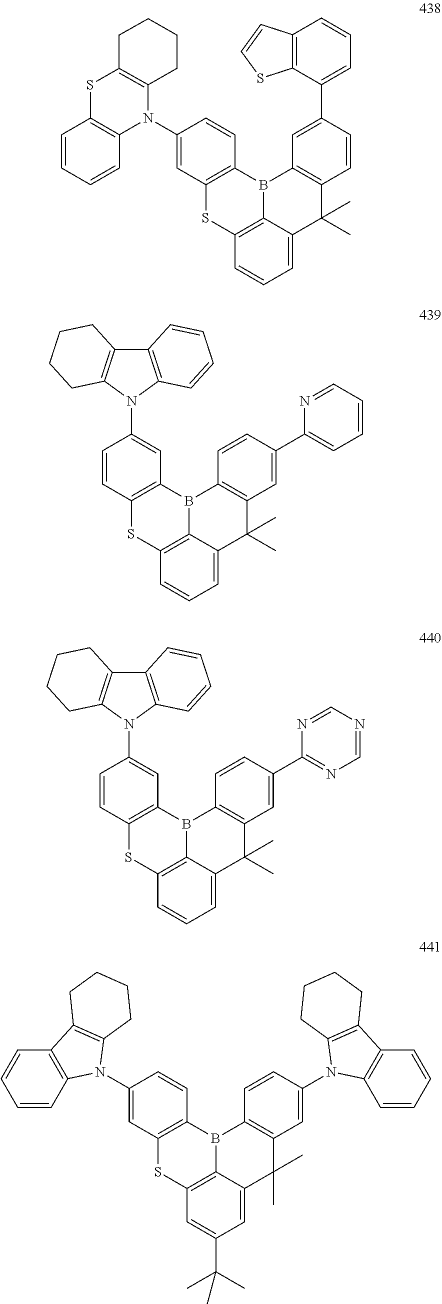 [SMILES: CC1(C)c2ccc(-c3cccc4ccsc34)cc2B2c3ccc(N4C5=C(CCCC5)Sc5ccccc54)cc3Sc3cccc1c32 ; CC1(C)c2cc(-c3ccccn3)ccc2B2c3cc(-n4c5c(c6ccccc64)CCCC5)ccc3Sc3cccc1c32 ; CC1(C)c2cc(-c3ncncn3)ccc2B2c3cc(-n4c5c(c6ccccc64)CCCC5)ccc3Sc3cccc1c32 ; CC(C)(C)c1cc2c3c(c1)C(C)(C)c1cc(-n4c5c(c6ccccc64)CCCC5)ccc1B3c1ccc(-n3c4c(c5ccccc53)CCCC4)cc1S2]

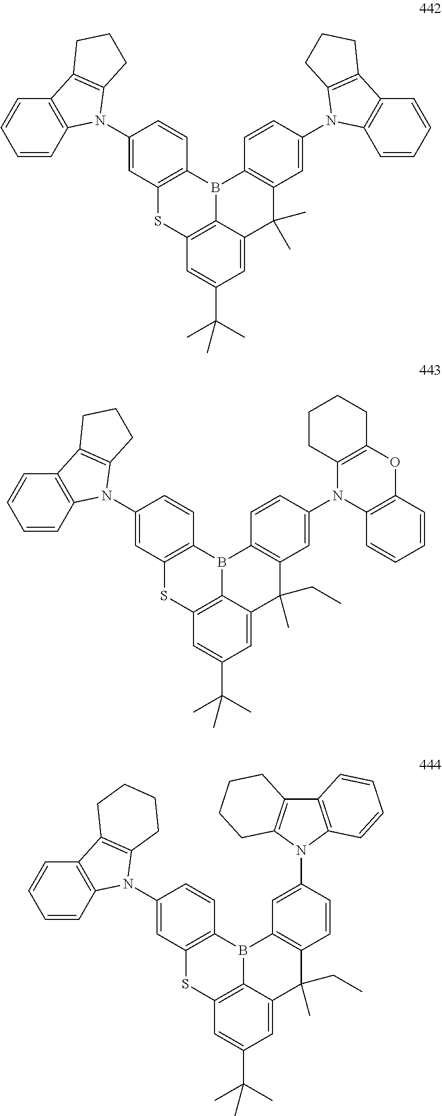 [SMILES: CC(C)(C)c1cc2c3c(c1)C(C)(C)c1cc(-n4c5c(c6ccccc64)CCC5)ccc1B3c1ccc(-n3c4c(c5ccccc53)CCC4)cc1S2 ; CCC1(C)c2cc(N3C4=C(CCCC4)Oc4ccccc43)ccc2B2c3ccc(-n4c5c(c6ccccc64)CCC5)cc3Sc3cc(C(C)(C)C)cc1c32 ; CCC1(C)c2ccc(-n3c4c(c5ccccc53)CCCC4)cc2B2c3ccc(-n4c5c(c6ccccc64)CCCC5)cc3Sc3cc(C(C)(C)C)cc1c32]

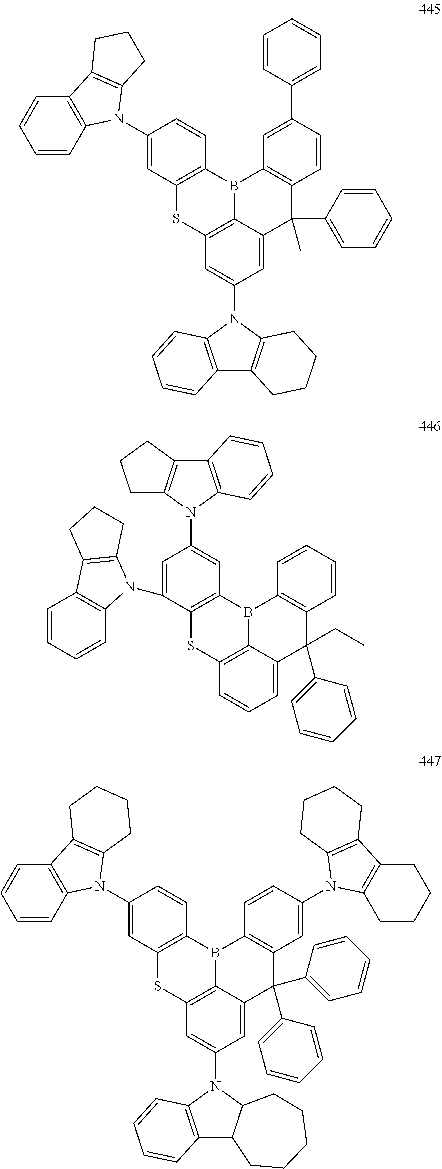

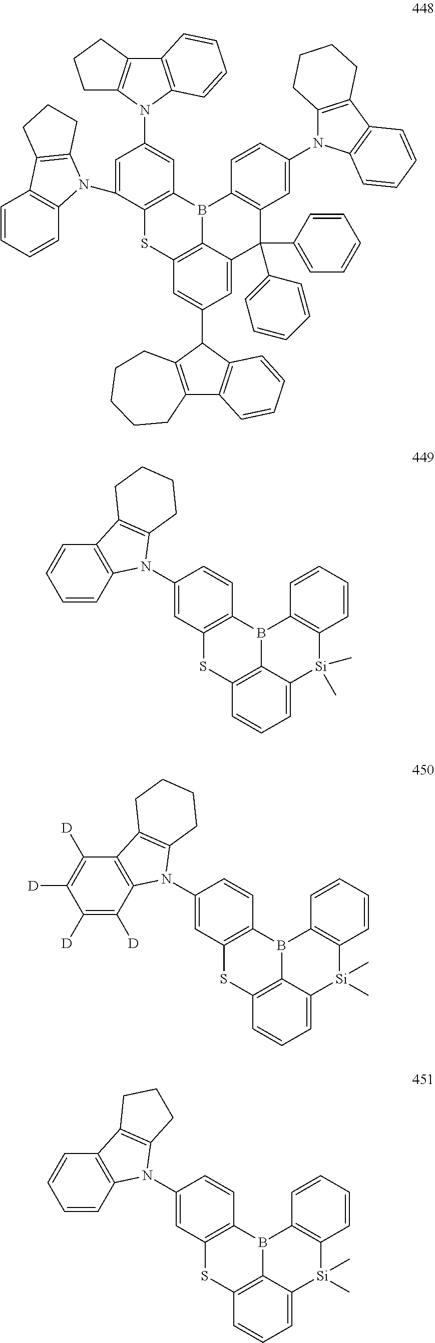

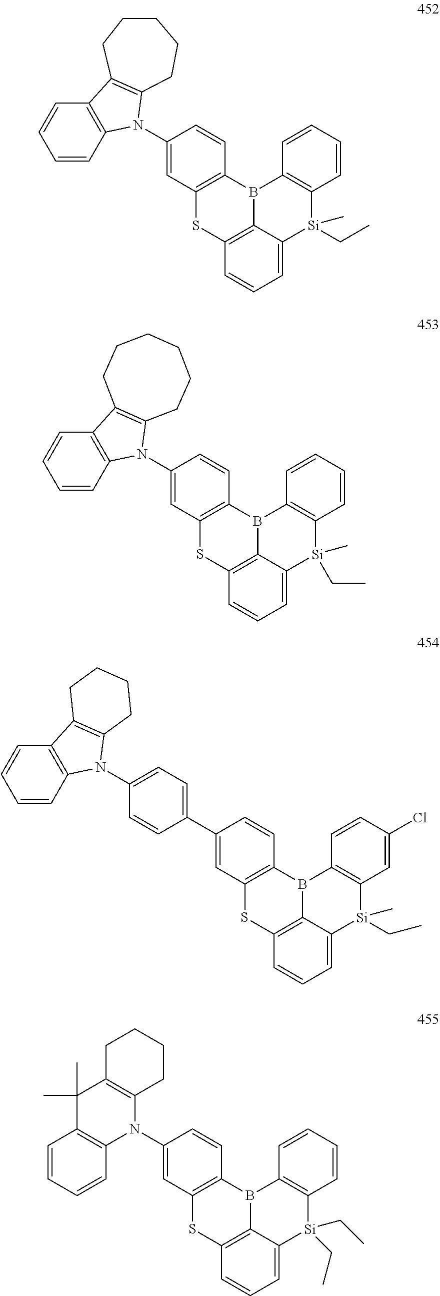

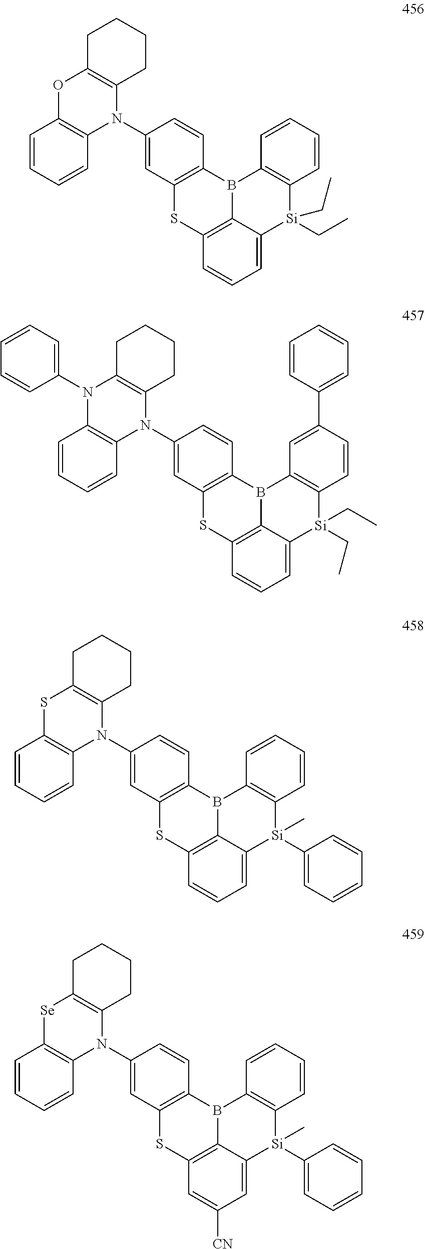 [SMILES: CC[Si]1(CC)c2ccccc2B2c3ccc(N4C5=C(CCCC5)Oc5ccccc54)cc3Sc3cccc1c32 ; CC[Si]1(CC)c2ccc(-c3ccccc3)cc2B2c3ccc(N4C5=C(CCCC5)N(c5ccccc5)c5ccccc54)cc3Sc3cccc1c32 ; C[Si]1(c2ccccc2)c2ccccc2B2c3ccc(N4C5=C(CCCC5)Sc5ccccc54)cc3Sc3cccc1c32 ; C[Si]1(c2ccccc2)c2ccccc2B2c3ccc(N4C5=C(CCCC5)[Se]c5ccccc54)cc3Sc3cc(C#N)cc1c32]

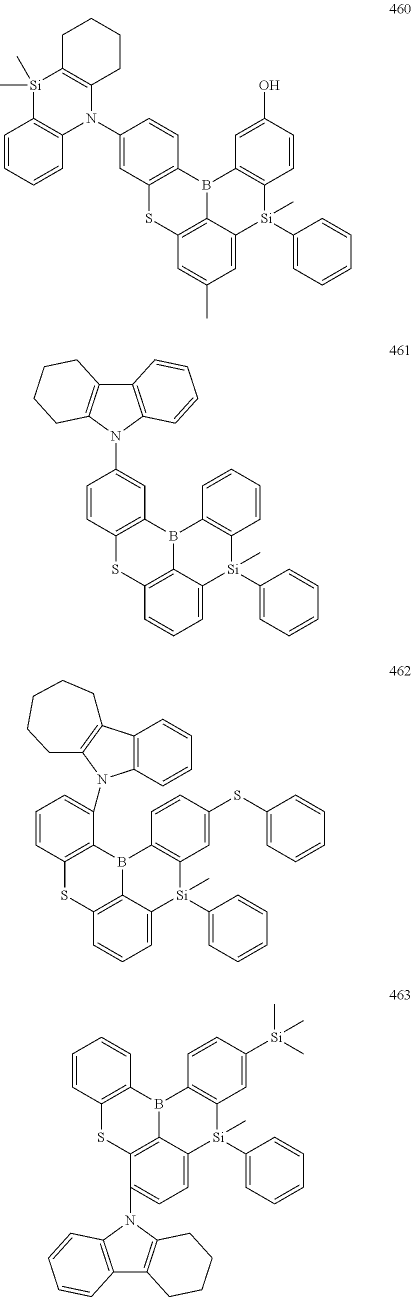 [SMILES: Cc1cc2c3c(c1)[Si](C)(c1ccccc1)c1ccc(O)cc1B3c1ccc(N3C4=C(CCCC4)[Si](C)(C)c4ccccc43)cc1S2 ; C[Si]1(c2ccccc2)c2ccccc2B2c3cc(-n4c5c(c6ccccc64)CCCC5)ccc3Sc3cccc1c32 ; C[Si]1(c2ccccc2)c2cc(Sc3ccccc3)ccc2B2c3c(cccc3-n3c4c(c5ccccc53)CCCCC4)Sc3cccc1c32 ; C[Si](C)(C)c1ccc2c(c1)[Si](C)(c1ccccc1)c1ccc(-n3c4c(c5ccccc53)CCCC4)c3c1B2c1ccccc1S3]

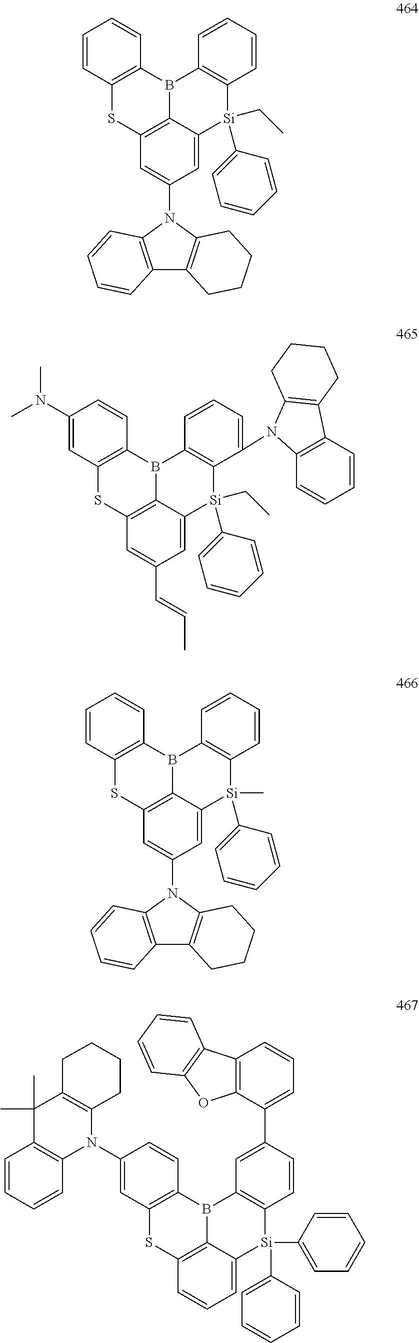 [SMILES: CC[Si]1(c2ccccc2)c2ccccc2B2c3ccccc3Sc3cc(-n4c5c(c6ccccc64)CCCC5)cc1c32 ; C/C=C/c1cc2c3c(c1)[Si](CC)(c1ccccc1)c1c(cccc1-n1c4c(c5ccccc51)CCCC4)B3c1ccc(N(C)C)cc1S2 ; C[Si]1(c2ccccc2)c2ccccc2B2c3ccccc3Sc3cc(-n4c5c(c6ccccc64)CCCC5)cc1c32 ; CC1(C)C2=C(CCCC2)N(c2ccc3c(c2)Sc2cccc4c2B3c2cc(-c3cccc5c3oc3ccccc35)ccc2[Si]4(c2ccccc2)c2ccccc2)c2ccccc21]

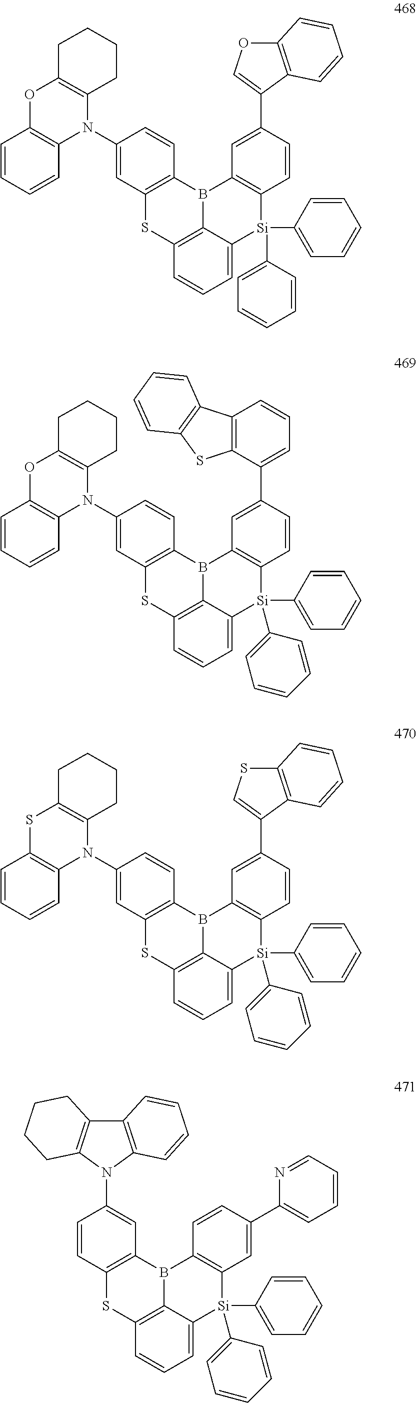 [SMILES: c1ccc([Si]2(c3ccccc3)c3ccc(-c4coc5ccccc45)cc3B3c4ccc(N5C6=C(CCCC6)Oc6ccccc65)cc4Sc4cccc2c43)cc1 ; c1ccc([Si]2(c3ccccc3)c3ccc(-c4cccc5c4sc4ccccc45)cc3B3c4ccc(N5C6=C(CCCC6)Oc6ccccc65)cc4Sc4cccc2c43)cc1 ; c1ccc([Si]2(c3ccccc3)c3ccc(-c4csc5ccccc45)cc3B3c4ccc(N5C6=C(CCCC6)Sc6ccccc65)cc4Sc4cccc2c43)cc1 ; c1ccc([Si]2(c3ccccc3)c3cc(-c4ccccn4)ccc3B3c4cc(-n5c6c(c7ccccc75)CCCC6)ccc4Sc4cccc2c43)cc1]

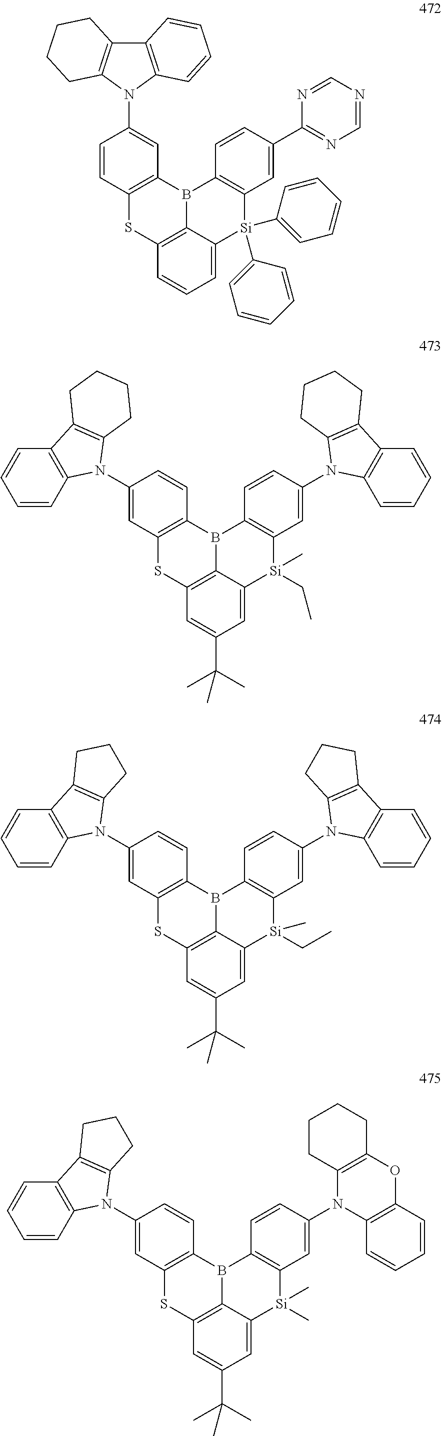 [SMILES: c1ccc([Si]2(c3ccccc3)c3cc(-c4ncncn4)ccc3B3c4cc(-n5c6c(c7ccccc75)CCCC6)ccc4Sc4cccc2c43)cc1 ; CC[Si]1(C)c2cc(-n3c4c(c5ccccc53)CCCC4)ccc2B2c3ccc(-n4c5c(c6ccccc64)CCCC5)cc3Sc3cc(C(C)(C)C)cc1c32 ; CC[Si]1(C)c2cc(-n3c4c(c5ccccc53)CCC4)ccc2B2c3ccc(-n4c5c(c6ccccc64)CCC5)cc3Sc3cc(C(C)(C)C)cc1c32 ; CC(C)(C)c1cc2c3c(c1)[Si](C)(C)c1cc(N4C5=C(CCCC5)Oc5ccccc54)ccc1B3c1ccc(-n3c4c(c5ccccc53)CCC4)cc1S2]

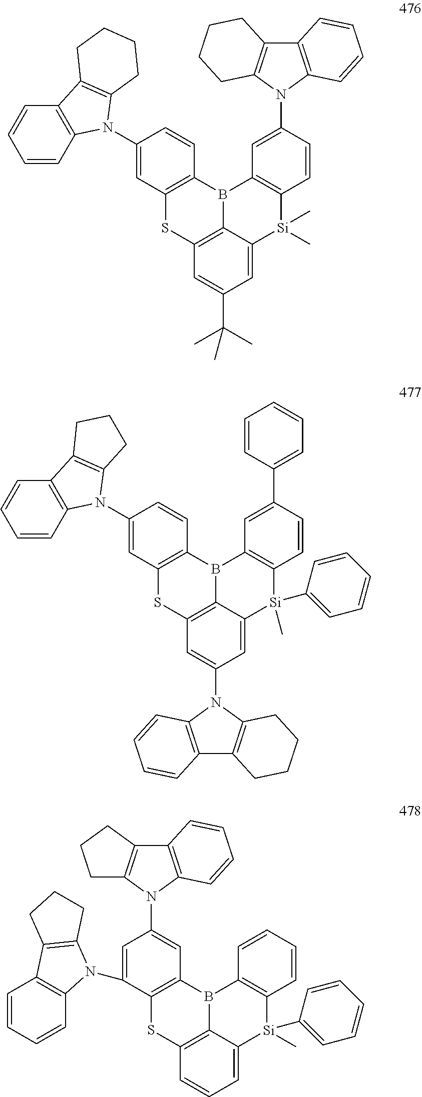

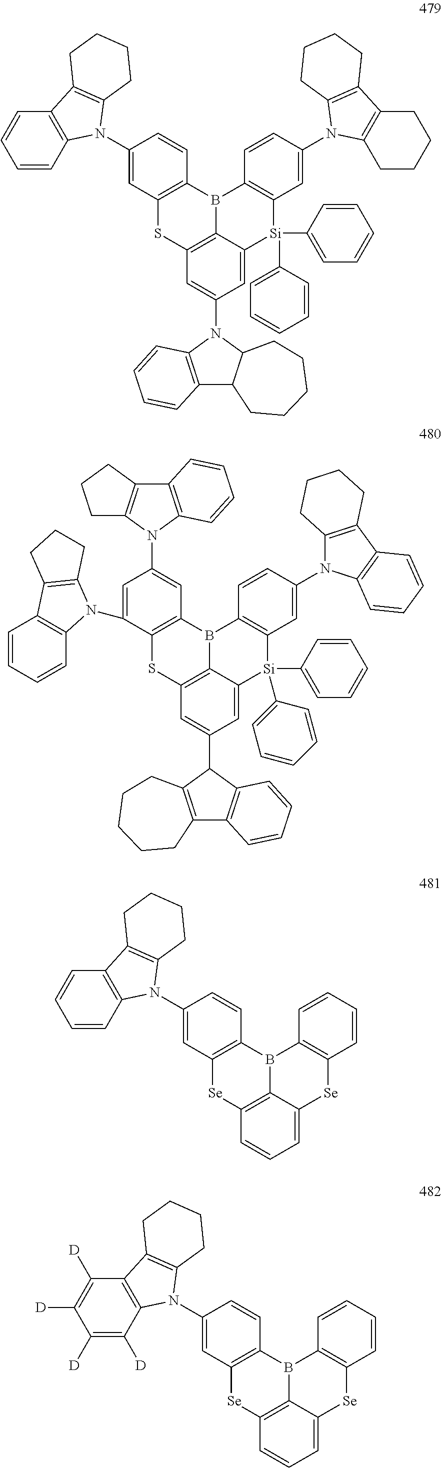

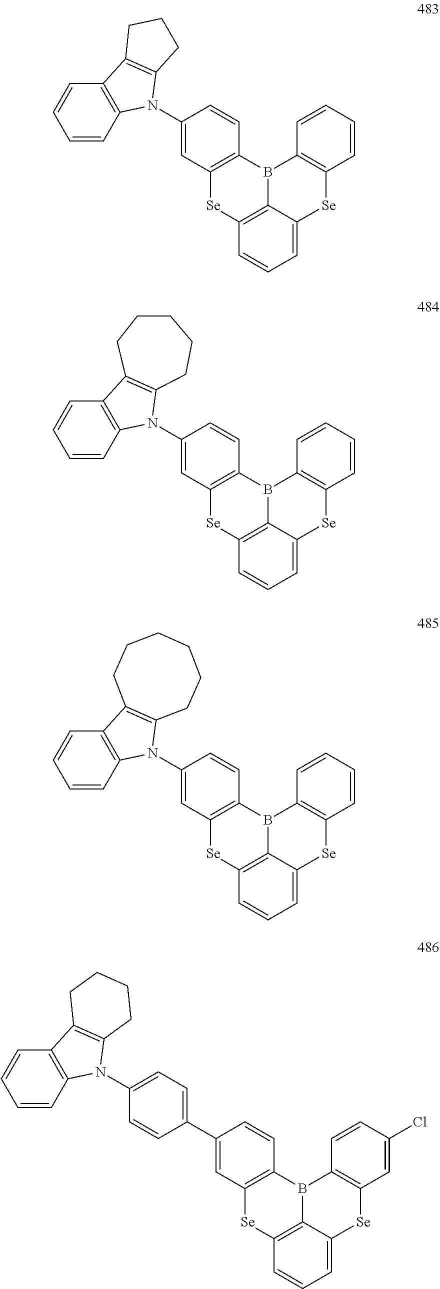 [SMILES: c1ccc2c(c1)[Se]c1cccc3c1B2c1ccc(-n2c4c(c5ccccc52)CCC4)cc1[Se]3 ; c1ccc2c(c1)[Se]c1cccc3c1B2c1ccc(-n2c4c(c5ccccc52)CCCCC4)cc1[Se]3 ; c1ccc2c(c1)[Se]c1cccc3c1B2c1ccc(-n2c4c(c5ccccc52)CCCCCC4)cc1[Se]3 ; Clc1ccc2c(c1)[Se]c1cccc3c1B2c1ccc(-c2ccc(-n4c5c(c6ccccc64)CCCC5)cc2)cc1[Se]3]

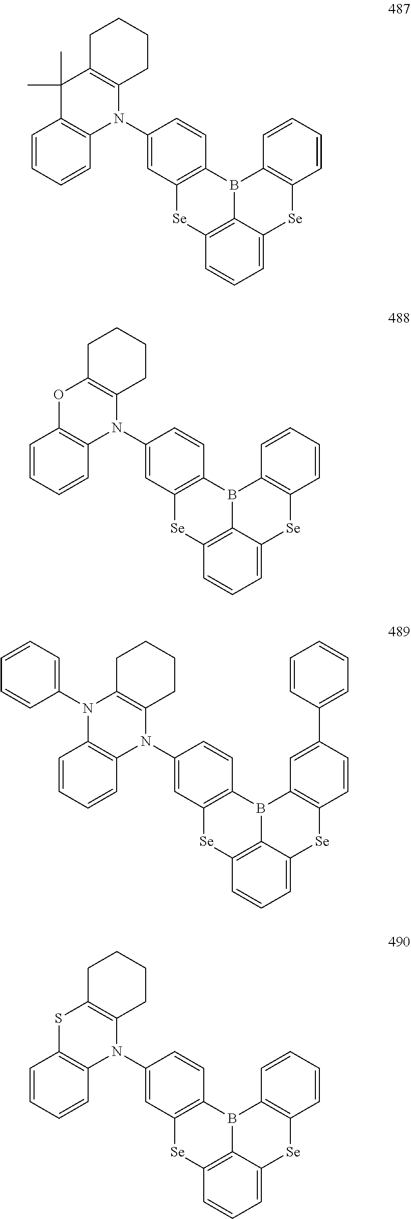 [SMILES: CC1(C)C2=C(CCCC2)N(c2ccc3c(c2)[Se]c2cccc4c2B3c2ccccc2[Se]4)c2ccccc21 ; c1ccc2c(c1)OC1=C(CCCC1)N2c1ccc2c(c1)[Se]c1cccc3c1B2c1ccccc1[Se]3 ; c1ccc(-c2ccc3c(c2)B2c4ccc(N5C6=C(CCCC6)N(c6ccccc6)c6ccccc65)cc4[Se]c4cccc(c42)[Se]3)cc1 ; c1ccc2c(c1)SC1=C(CCCC1)N2c1ccc2c(c1)[Se]c1cccc3c1B2c1ccccc1[Se]3]

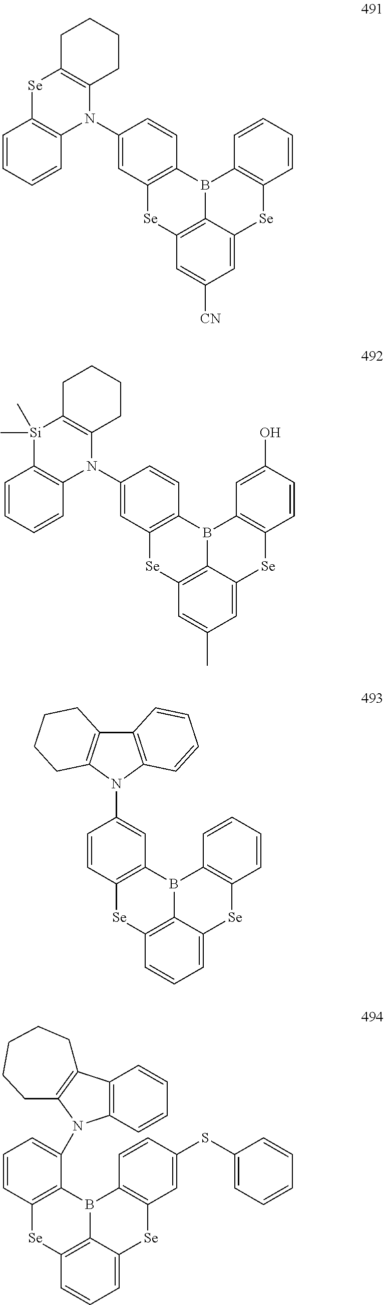 [SMILES: N#Cc1cc2c3c(c1)[Se]c1cc(N4C5=C(CCCC5)[Se]c5ccccc54)ccc1B3c1ccccc1[Se]2 ; Cc1cc2c3c(c1)[Se]c1ccc(O)cc1B3c1ccc(N3C4=C(CCCC4)[Si](C)(C)c4ccccc43)cc1[Se]2 ; c1ccc2c(c1)[Se]c1cccc3c1B2c1cc(-n2c4c(c5ccccc52)CCCC4)ccc1[Se]3 ; c1ccc(Sc2ccc3c(c2)[Se]c2cccc4c2B3c2c(cccc2-n2c3c(c5ccccc52)CCCCC3)[Se]4)cc1]

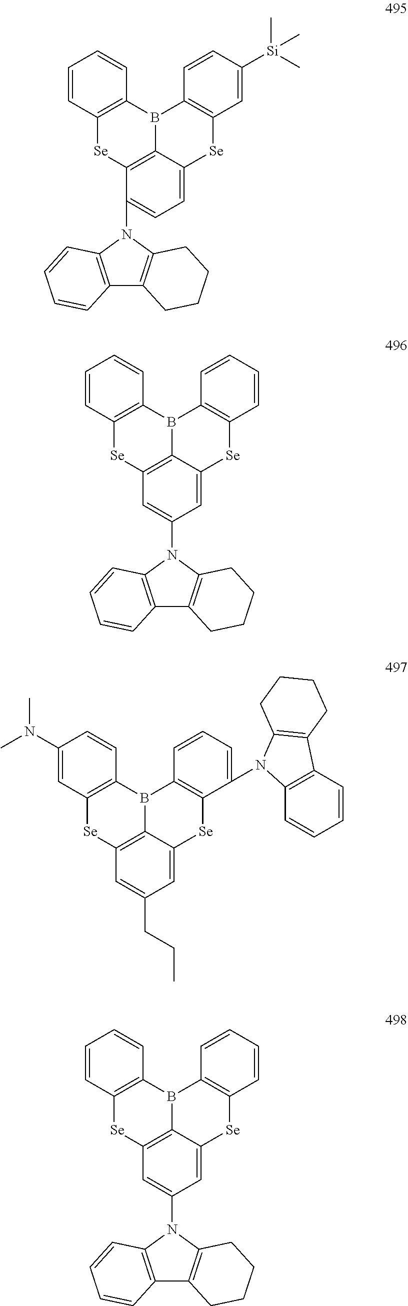

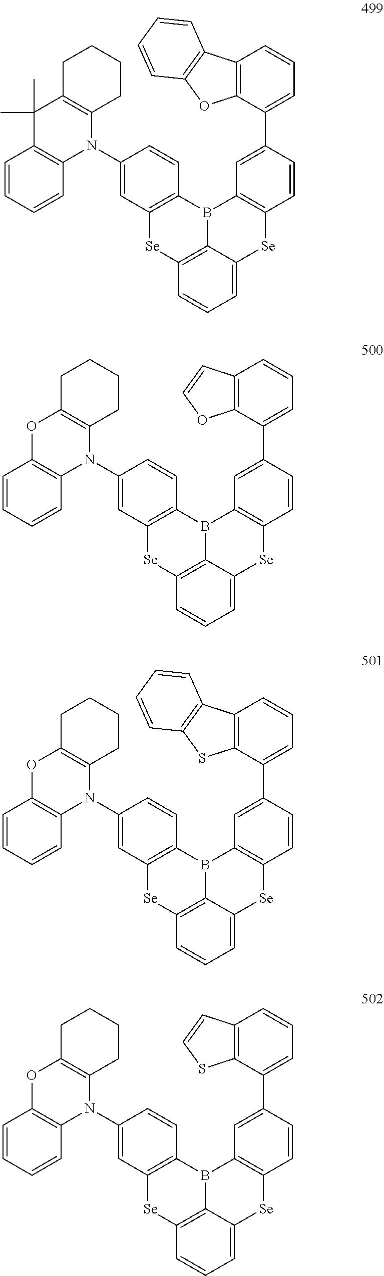 [SMILES: CC1(C)C2=C(CCCC2)N(c2ccc3c(c2)[Se]c2cccc4c2B3c2cc(-c3cccc5c3oc3ccccc35)ccc2[Se]4)c2ccccc21 ; c1ccc2c(c1)OC1=C(CCCC1)N2c1ccc2c(c1)[Se]c1cccc3c1B2c1cc(-c2cccc4ccoc24)ccc1[Se]3 ; c1ccc2c(c1)OC1=C(CCCC1)N2c1ccc2c(c1)[Se]c1cccc3c1B2c1cc(-c2cccc4c2sc2ccccc24)ccc1[Se]3 ; c1ccc2c(c1)OC1=C(CCCC1)N2c1ccc2c(c1)[Se]c1cccc3c1B2c1cc(-c2cccc4ccsc24)ccc1[Se]3]

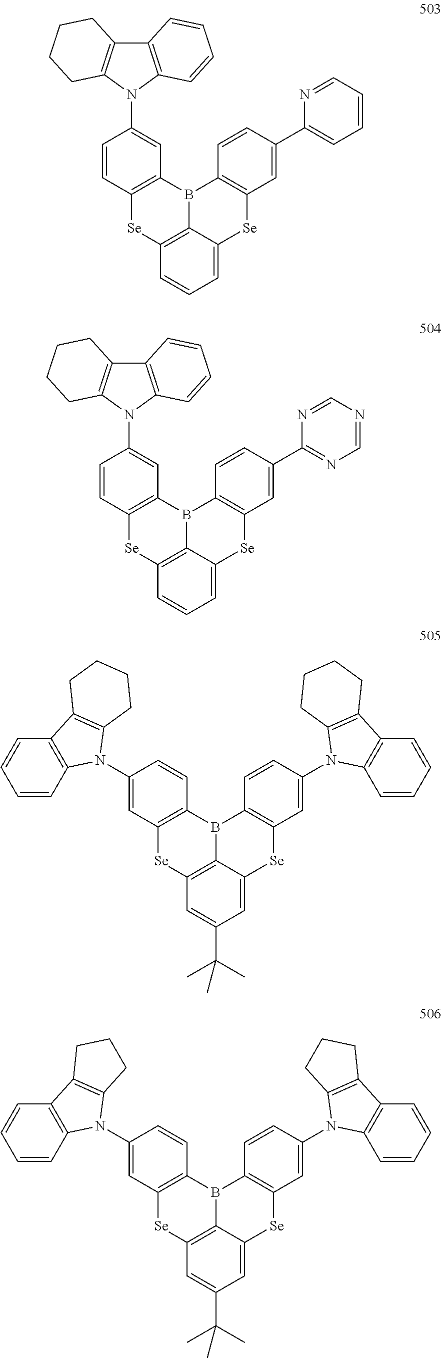 [SMILES: c1ccc(-c2ccc3c(c2)[Se]c2cccc4c2B3c2cc(-n3c5c(c6ccccc63)CCCC5)ccc2[Se]4)nc1 ; c1cc2c3c(c1)[Se]c1ccc(-n4c5c(c6ccccc64)CCCC5)cc1B3c1ccc(-c3ncncn3)cc1[Se]2 ; CC(C)(C)c1cc2c3c(c1)[Se]c1cc(-n4c5c(c6ccccc64)CCCC5)ccc1B3c1ccc(-n3c4c(c5ccccc53)CCCC4)cc1[Se]2 ; CC(C)(C)c1cc2c3c(c1)[Se]c1cc(-n4c5c(c6ccccc64)CCC5)ccc1B3c1ccc(-n3c4c(c5ccccc53)CCC4)cc1[Se]2]

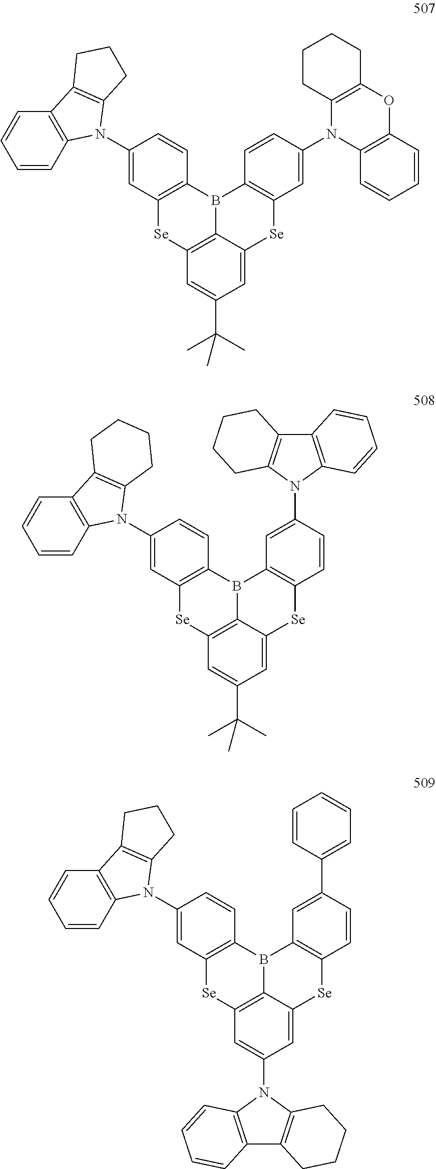 [SMILES: CC(C)(C)c1cc2c3c(c1)[Se]c1cc(-n4c5c(c6ccccc64)CCC5)ccc1B3c1ccc(N3C4=C(CCCC4)Oc4ccccc43)cc1[Se]2 ; CC(C)(C)c1cc2c3c(c1)[Se]c1ccc(-n4c5c(c6ccccc64)CCCC5)cc1B3c1ccc(-n3c4c(c5ccccc53)CCCC4)cc1[Se]2 ; c1ccc(-c2ccc3c(c2)B2c4ccc(-n5c6c(c7ccccc75)CCC6)cc4[Se]c4cc(-n5c6c(c7ccccc75)CCCC6)cc(c42)[Se]3)cc1]

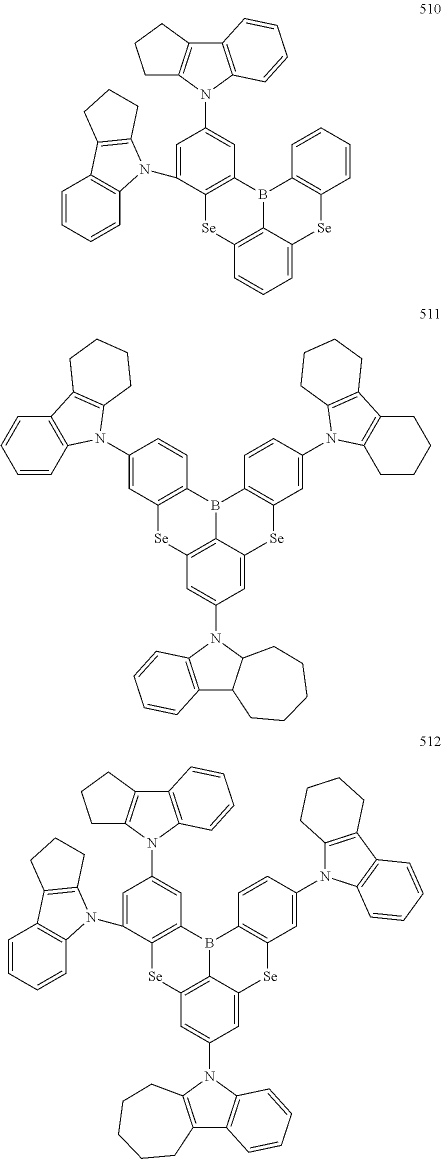 [SMILES: c1ccc2c(c1)[Se]c1cccc3c1B2c1cc(-n2c4c(c5ccccc52)CCC4)cc(-n2c4c(c5ccccc52)CCC4)c1[Se]3 ; c1ccc2c(c1)C1CCCCCC1N2c1cc2c3c(c1)[Se]c1cc(-n4c5c(c6ccccc64)CCCC5)ccc1B3c1ccc(-n3c4c(c5c3CCCC5)CCCC4)cc1[Se]2 ; c1ccc2c(c1)c1c(n2-c2cc3c4c(c2)[Se]c2c(cc(-n5c6c(c7ccccc75)CCC6)cc2-n2c5c(c6ccccc62)CCC5)B4c2ccc(-n4c5c(c6ccccc64)CCCC5)cc2[Se]3)CCCCC1]

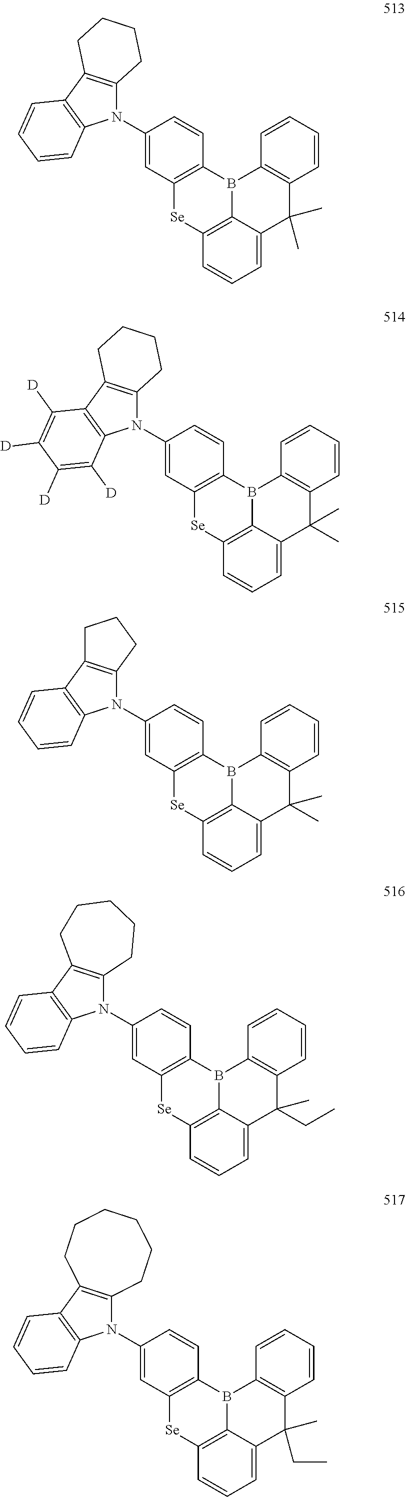 [SMILES: CC1(C)c2ccccc2B2c3ccc(-n4c5c(c6ccccc64)CCCC5)cc3[Se]c3cccc1c32 ; [2H]c1c([2H])c([2H])c2c(c1[2H])c1c(n2-c2ccc3c(c2)[Se]c2cccc4c2B3c2ccccc2C4(C)C)CCCC1 ; CC1(C)c2ccccc2B2c3ccc(-n4c5c(c6ccccc64)CCC5)cc3[Se]c3cccc1c32 ; CCC1(C)c2ccccc2B2c3ccc(-n4c5c(c6ccccc64)CCCCC5)cc3[Se]c3cccc1c32 ; CCC1(C)c2ccccc2B2c3ccc(-n4c5c(c6ccccc64)CCCCCC5)cc3[Se]c3cccc1c32]

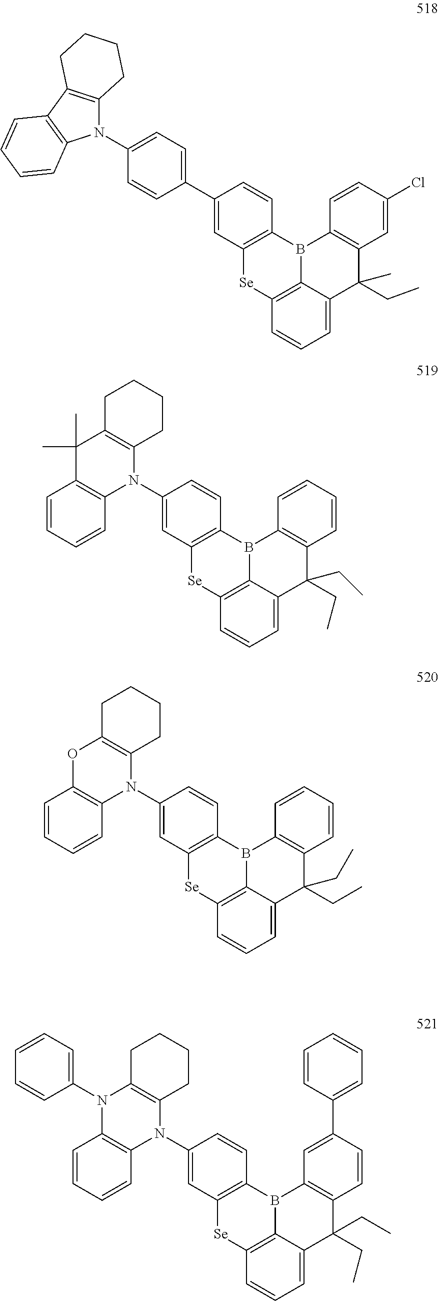

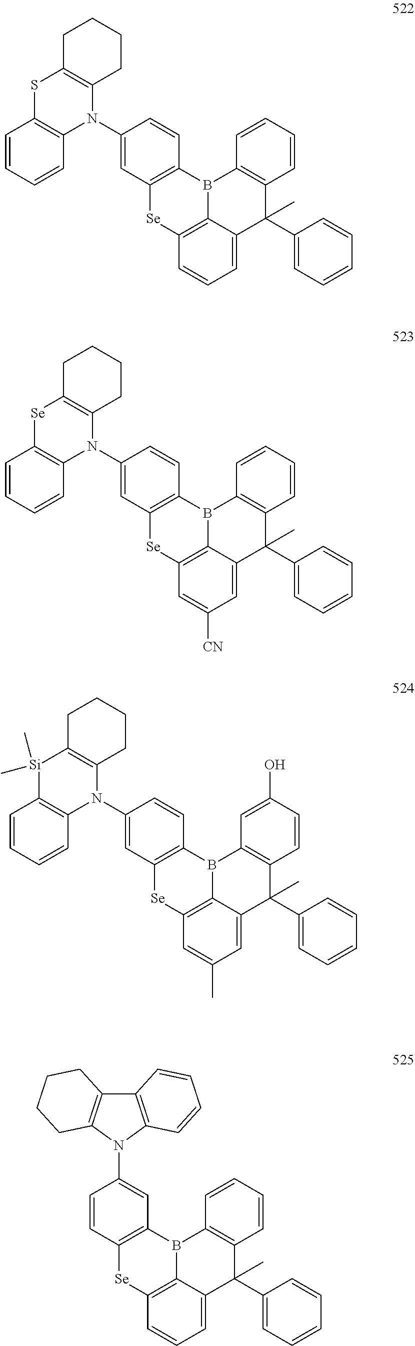 [SMILES: CC1(c2ccccc2)c2ccccc2B2c3ccc(N4C5=C(CCCC5)Sc5ccccc54)cc3[Se]c3cccc1c32 ; CC1(c2ccccc2)c2ccccc2B2c3ccc(N4C5=C(CCCC5)[Se]c5ccccc54)cc3[Se]c3cc(C#N)cc1c32 ; Cc1cc2c3c(c1)C(C)(c1ccccc1)c1ccc(O)cc1B3c1ccc(N3C4=C(CCCC4)[Si](C)(C)c4ccccc43)cc1[Se]2 ; CC1(c2ccccc2)c2ccccc2B2c3cc(-n4c5c(c6ccccc64)CCCC5)ccc3[Se]c3cccc1c32]

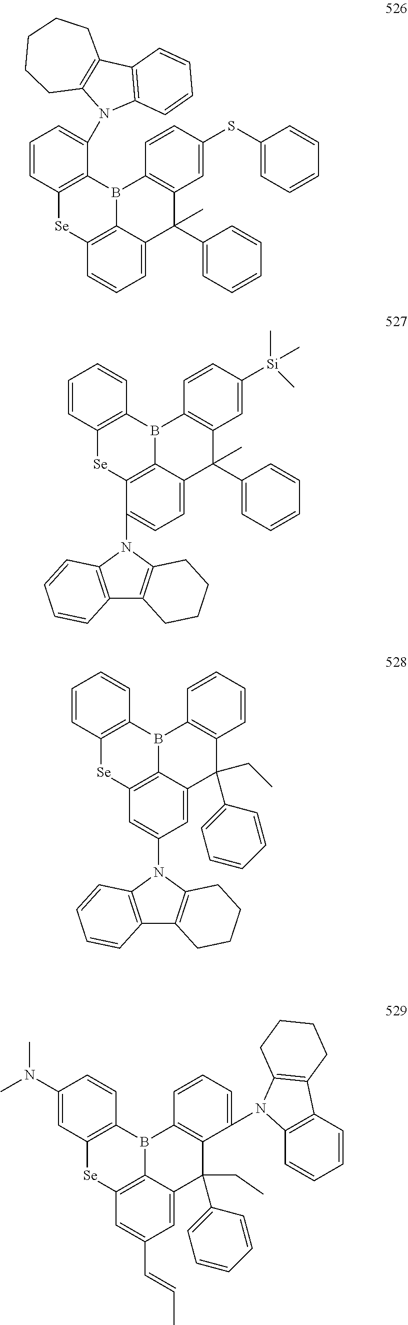

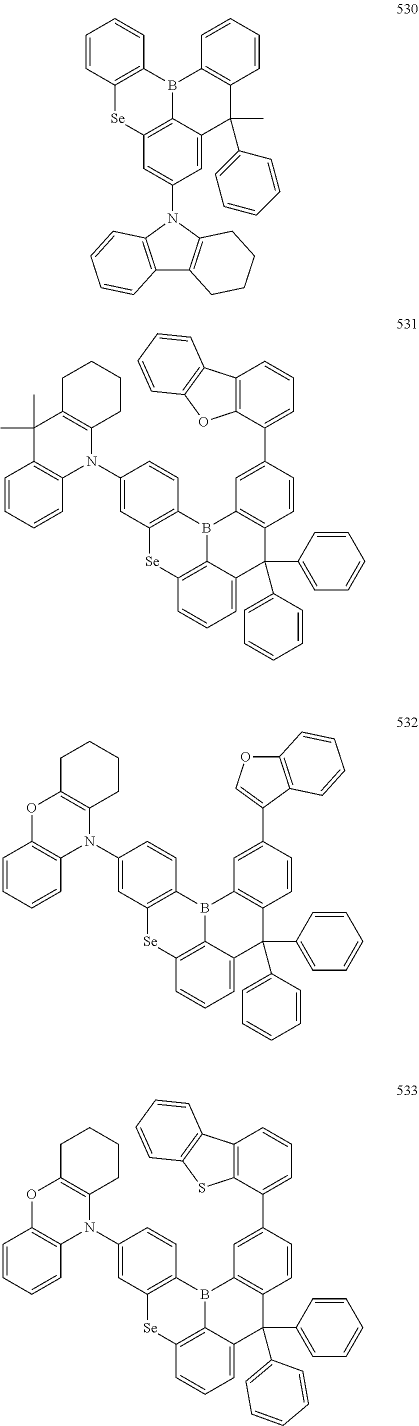

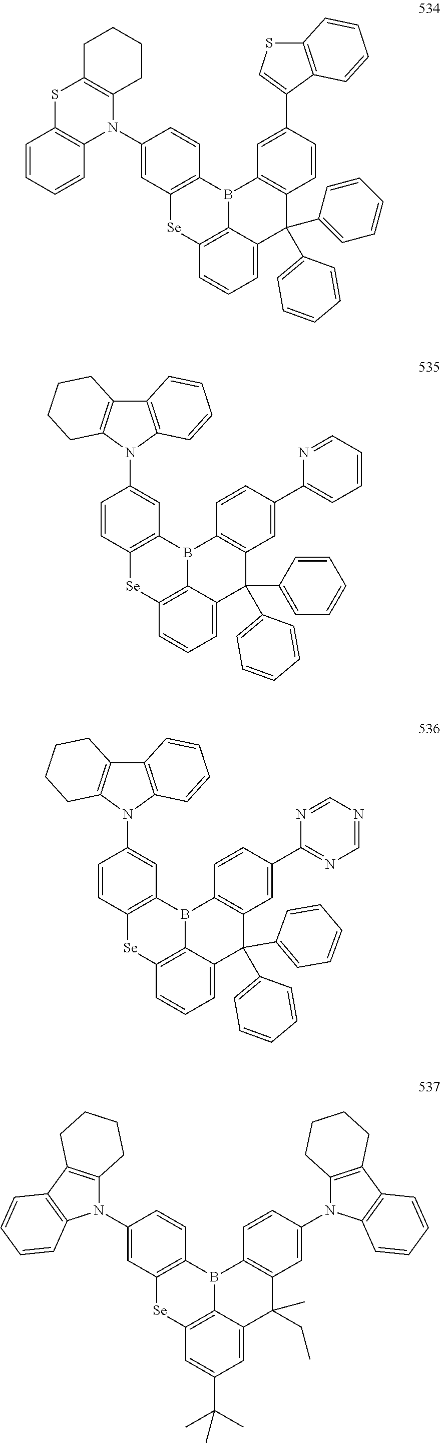 [SMILES: c1ccc(C2(c3ccccc3)c3ccc(-c4csc5ccccc45)cc3B3c4ccc(N5C6=C(CCCC6)Sc6ccccc65)cc4[Se]c4cccc2c43)cc1 ; c1ccc(C2(c3ccccc3)c3cc(-c4ccccn4)ccc3B3c4cc(-n5c6c(c7ccccc75)CCCC6)ccc4[Se]c4cccc2c43)cc1 ; c1ccc(C2(c3ccccc3)c3cc(-c4ncncn4)ccc3B3c4cc(-n5c6c(c7ccccc75)CCCC6)ccc4[Se]c4cccc2c43)cc1 ; CCC1(C)c2cc(-n3c4c(c5ccccc53)CCCC4)ccc2B2c3ccc(-n4c5c(c6ccccc64)CCCC5)cc3[Se]c3cc(C(C)(C)C)cc1c32]

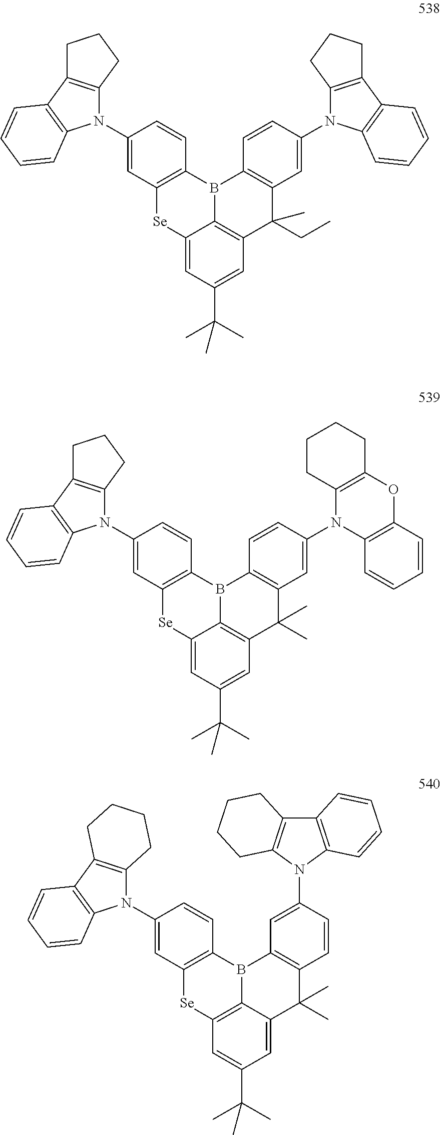 [SMILES: CCC1(C)c2cc(-n3c4c(c5ccccc53)CCC4)ccc2B2c3ccc(-n4c5c(c6ccccc64)CCC5)cc3[Se]c3cc(C(C)(C)C)cc1c32 ; CC(C)(C)c1cc2c3c(c1)C(C)(C)c1cc(N4C5=C(CCCC5)Oc5ccccc54)ccc1B3c1ccc(-n3c4c(c5ccccc53)CCC4)cc1[Se]2 ; CC(C)(C)c1cc2c3c(c1)C(C)(C)c1ccc(-n4c5c(c6ccccc64)CCCC5)cc1B3c1ccc(-n3c4c(c5ccccc53)CCCC4)cc1[Se]2]

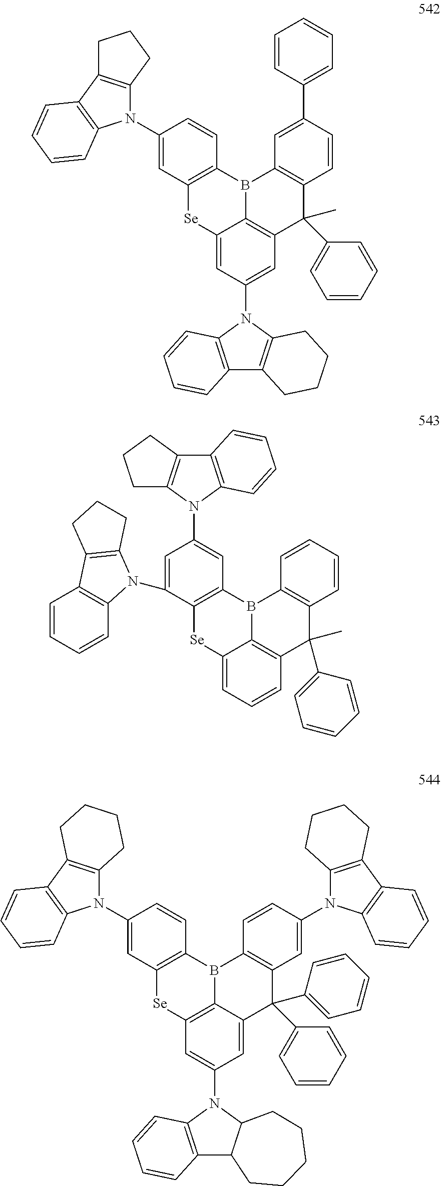

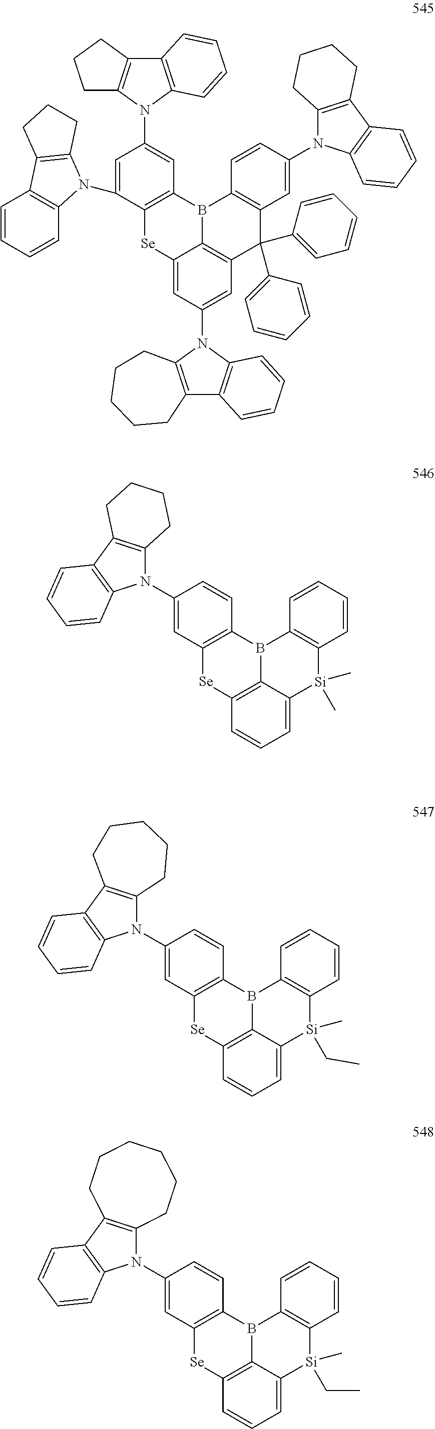 [SMILES: c1ccc(C2(c3ccccc3)c3cc(-n4c5c(c6ccccc64)CCCC5)ccc3B3c4cc(-n5c6c(c7ccccc75)CCC6)cc(-n5c6c(c7ccccc75)CCC6)c4[Se]c4cc(-n5c6c(c7ccccc75)CCCCC6)cc2c43)cc1 ; C[Si]1(C)c2ccccc2B2c3ccc(-n4c5c(c6ccccc64)CCCC5)cc3[Se]c3cccc1c32 ; CC[Si]1(C)c2ccccc2B2c3ccc(-n4c5c(c6ccccc64)CCCCC5)cc3[Se]c3cccc1c32 ; CC[Si]1(C)c2ccccc2B2c3ccc(-n4c5c(c6ccccc64)CCCCCC5)cc3[Se]c3cccc1c32]

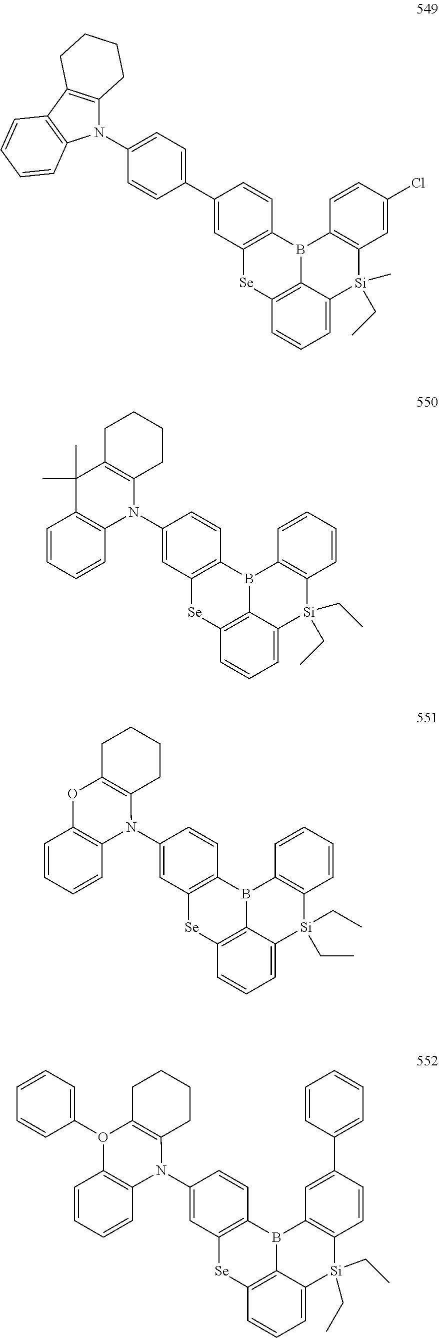

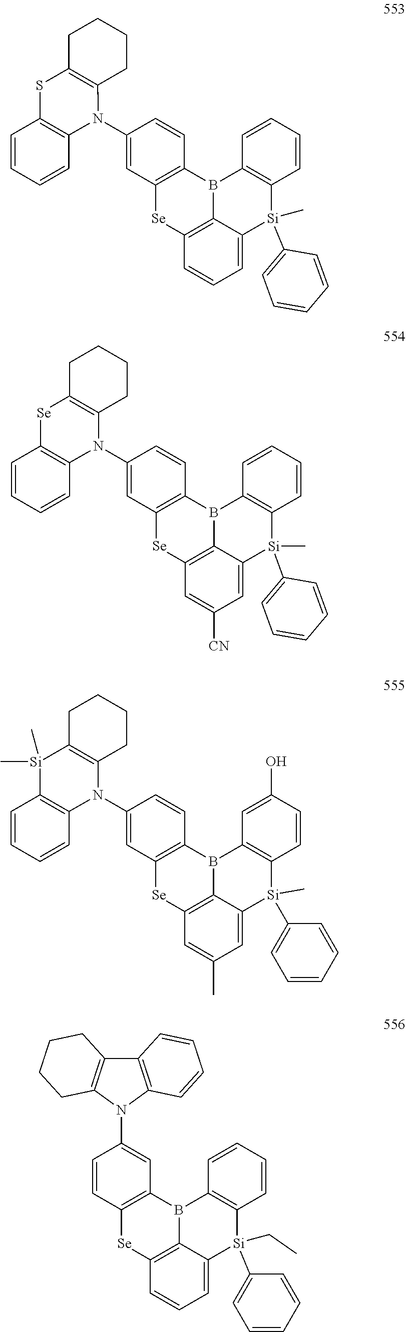 [SMILES: C[Si]1(c2ccccc2)c2ccccc2B2c3ccc(N4C5=C(CCCC5)Sc5ccccc54)cc3[Se]c3cccc1c32 ; C[Si]1(c2ccccc2)c2ccccc2B2c3ccc(N4C5=C(CCCC5)[Se]c5ccccc54)cc3[Se]c3cc(C#N)cc1c32 ; Cc1cc2c3c(c1)[Si](C)(c1ccccc1)c1ccc(O)cc1B3c1ccc(N3C4=C(CCCC4)[Si](C)(C)c4ccccc43)cc1[Se]2 ; CC[Si]1(c2ccccc2)c2ccccc2B2c3cc(-n4c5c(c6ccccc64)CCCC5)ccc3[Se]c3cccc1c32]

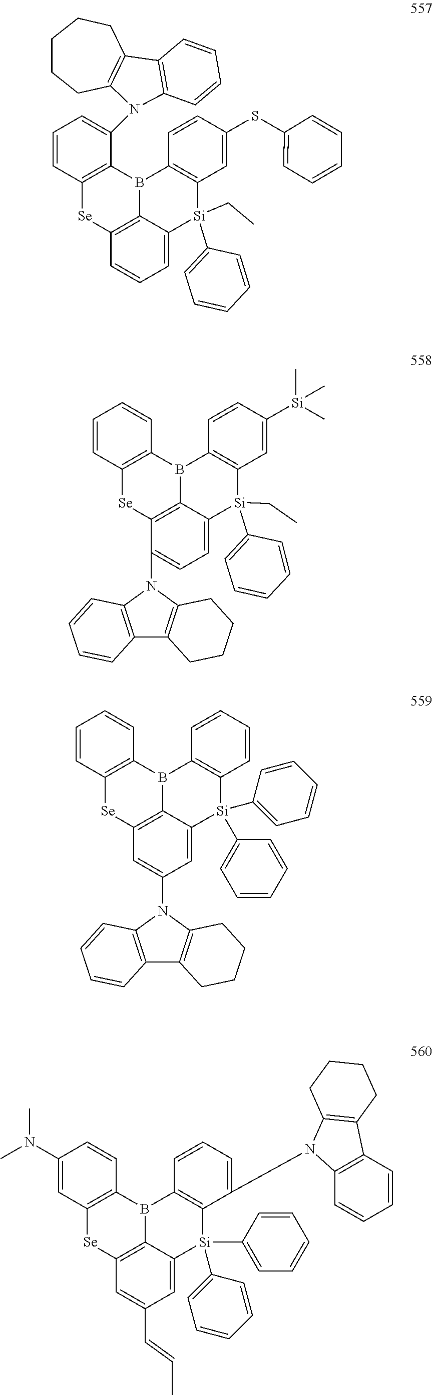

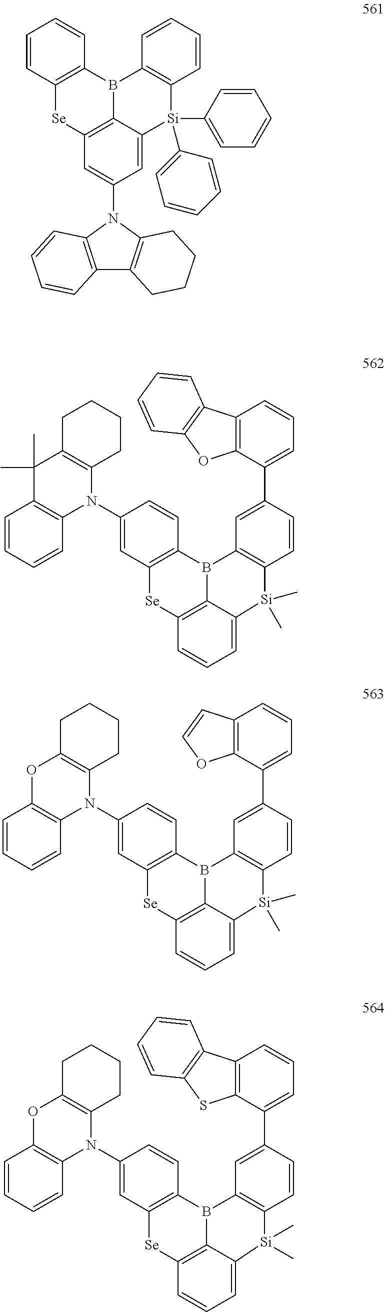

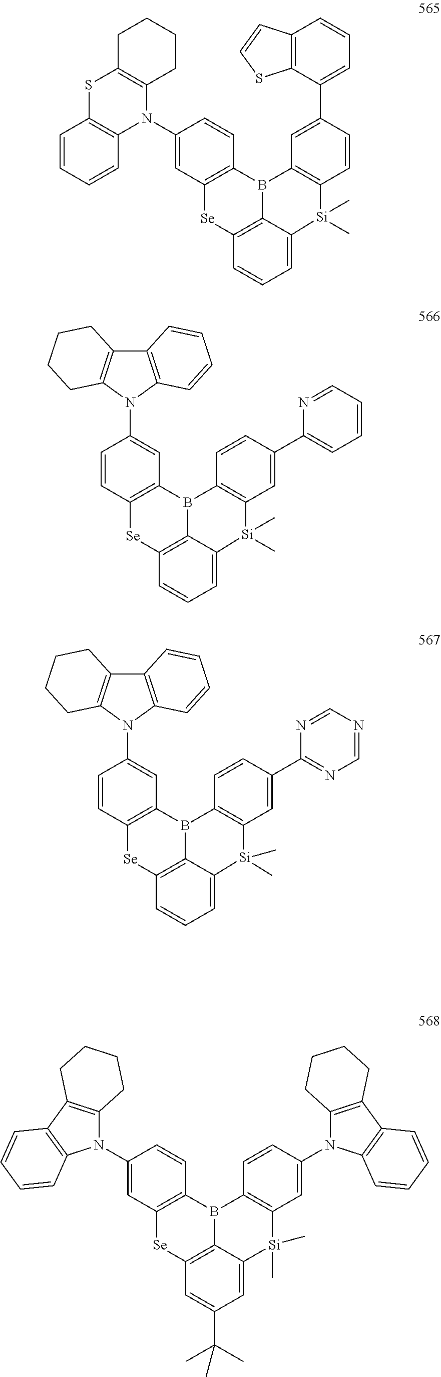 [SMILES: C[Si]1(C)c2ccc(-c3cccc4ccsc34)cc2B2c3ccc(N4C5=C(CCCC5)Sc5ccccc54)cc3[Se]c3cccc1c32 ; C[Si]1(C)c2cc(-c3ccccn3)ccc2B2c3cc(-n4c5c(c6ccccc64)CCCC5)ccc3[Se]c3cccc1c32 ; C[Si]1(C)c2cc(-c3ncncn3)ccc2B2c3cc(-n4c5c(c6ccccc64)CCCC5)ccc3[Se]c3cccc1c32 ; CC(C)(C)c1cc2c3c(c1)[Si](C)(C)c1cc(-n4c5c(c6ccccc64)CCCC5)ccc1B3c1ccc(-n3c4c(c5ccccc53)CCCC4)cc1[Se]2]

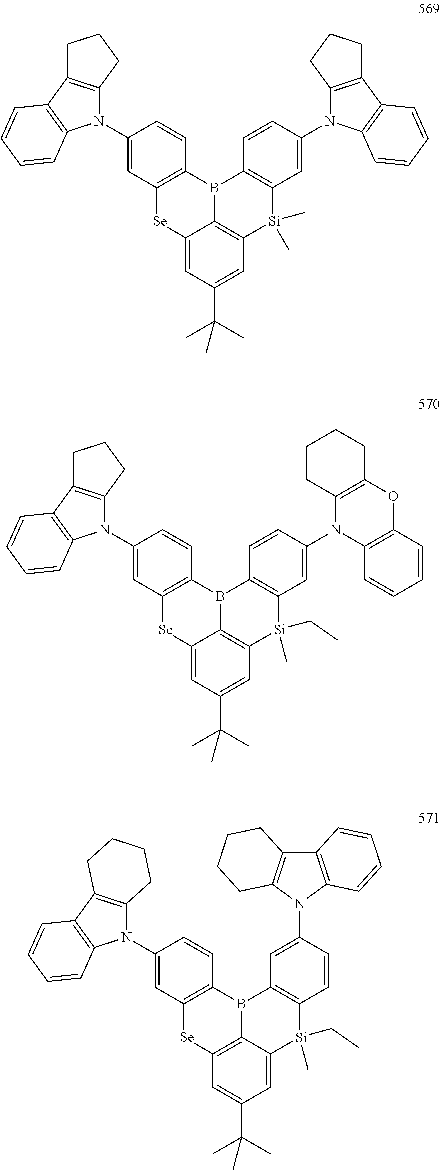 [SMILES: CC(C)(C)c1cc2c3c(c1)[Si](C)(C)c1cc(-n4c5c(c6ccccc64)CCC5)ccc1B3c1ccc(-n3c4c(c5ccccc53)CCC4)cc1[Se]2 ; CC[Si]1(C)c2cc(N3C4=C(CCCC4)Oc4ccccc43)ccc2B2c3ccc(-n4c5c(c6ccccc64)CCC5)cc3[Se]c3cc(C(C)(C)C)cc1c32 ; CC[Si]1(C)c2ccc(-n3c4c(c5ccccc53)CCCC4)cc2B2c3ccc(-n4c5c(c6ccccc64)CCCC5)cc3[Se]c3cc(C(C)(C)C)cc1c32]

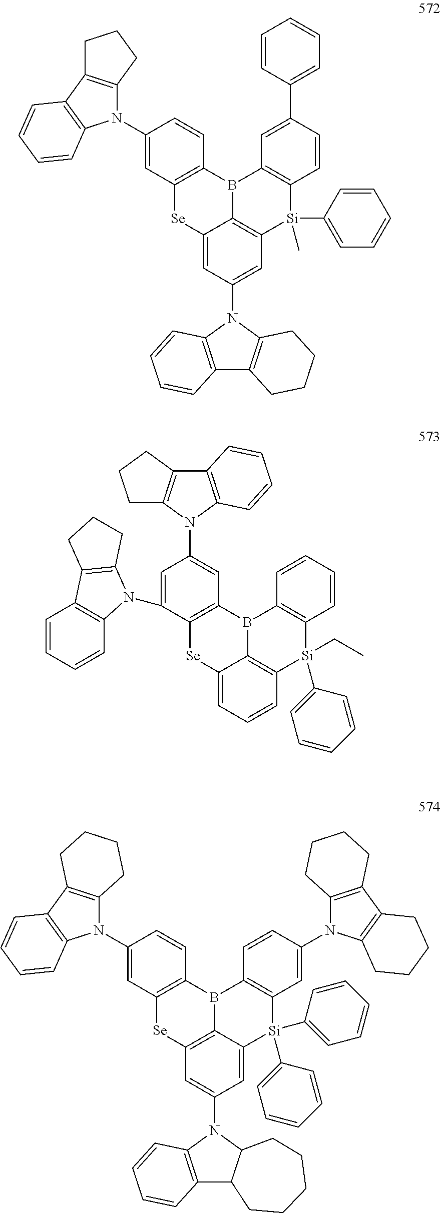 [SMILES: C[Si]1(c2ccccc2)c2ccc(-c3ccccc3)cc2B2c3ccc(-n4c5c(c6ccccc64)CCC5)cc3[Se]c3cc(-n4c5c(c6ccccc64)CCCC5)cc1c32 ; CC[Si]1(c2ccccc2)c2ccccc2B2c3cc(-n4c5c(c6ccccc64)CCC5)cc(-n4c5c(c6ccccc64)CCC5)c3[Se]c3cccc1c32 ; c1ccc([Si]2(c3ccccc3)c3cc(-n4c5c(c6c4CCCC6)CCCC5)ccc3B3c4ccc(-n5c6c(c7ccccc75)CCCC6)cc4[Se]c4cc(N5c6ccccc6C6CCCCCC65)cc2c43)cc1]

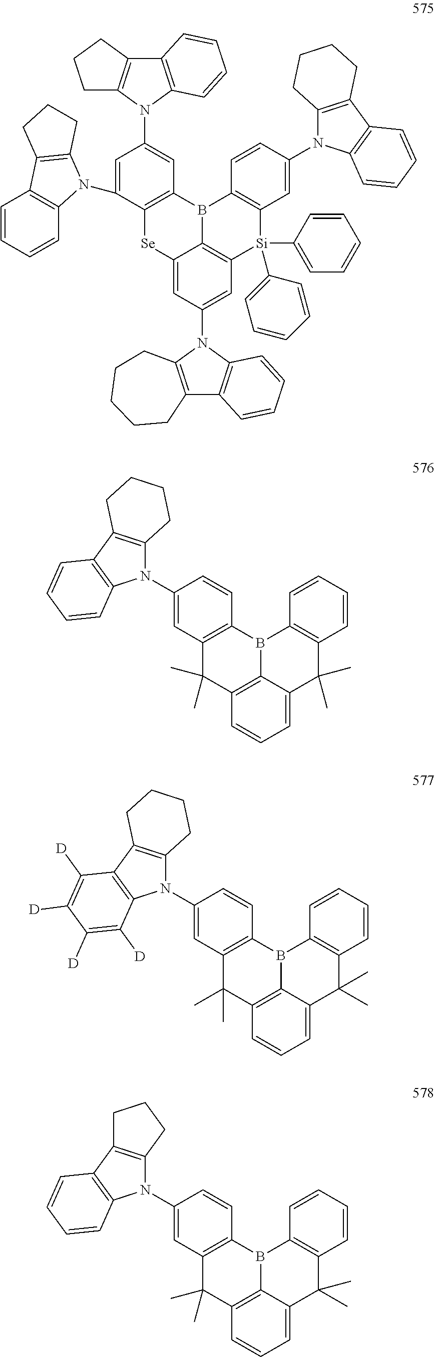 [SMILES: c1ccc([Si]2(c3ccccc3)c3cc(-n4c5c(c6ccccc64)CCCC5)ccc3B3c4cc(-n5c6c(c7ccccc75)CCC6)cc(-n5c6c(c7ccccc75)CCC6)c4[Se]c4cc(-n5c6c(c7ccccc75)CCCCC6)cc2c43)cc1 ; CC1(C)c2ccccc2B2c3ccc(-n4c5c(c6ccccc64)CCCC5)cc3C(C)(C)c3cccc1c32 ; [2H]c1c([2H])c([2H])c2c(c1[2H])c1c(n2-c2ccc3c(c2)C(C)(C)c2cccc4c2B3c2ccccc2C4(C)C)CCCC1 ; CC1(C)c2ccccc2B2c3ccc(-n4c5c(c6ccccc64)CCC5)cc3C(C)(C)c3cccc1c32]

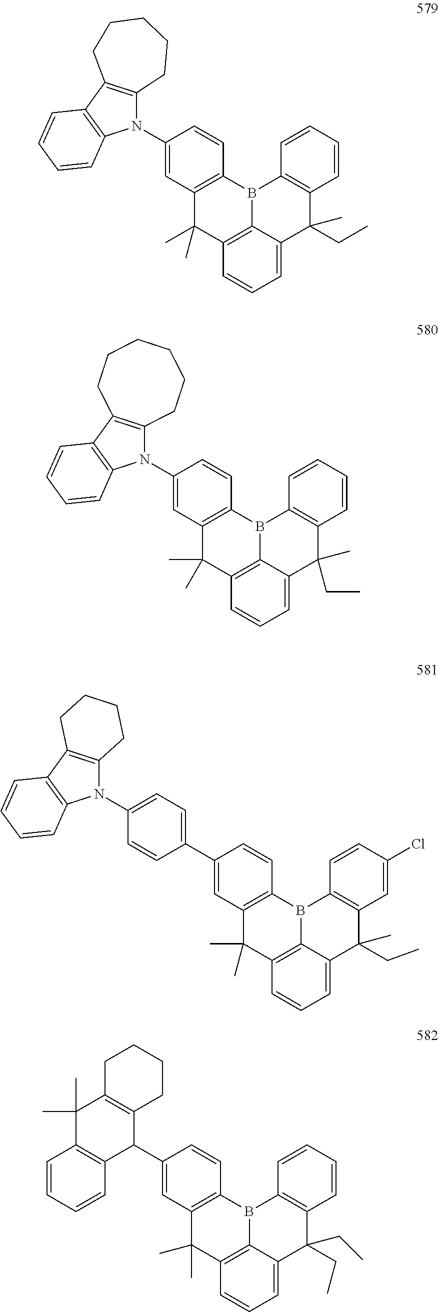

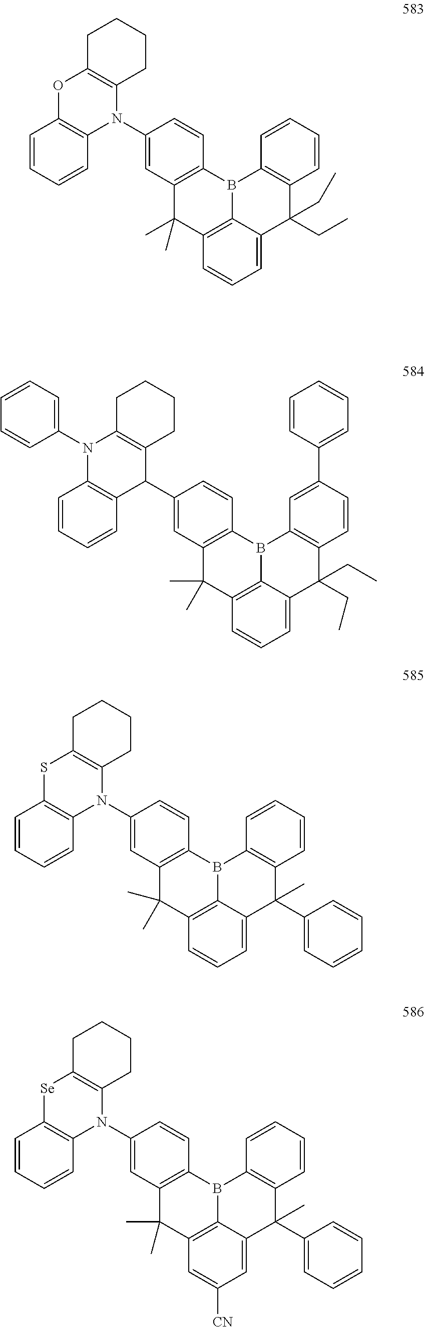 [SMILES: CCC1(CC)c2ccccc2B2c3ccc(N4C5=C(CCCC5)Oc5ccccc54)cc3C(C)(C)c3cccc1c32 ; CCC1(CC)c2ccc(-c3ccccc3)cc2B2c3ccc(C4C5=C(CCCC5)N(c5ccccc5)c5ccccc54)cc3C(C)(C)c3cccc1c32 ; CC1(C)c2cc(N3C4=C(CCCC4)Sc4ccccc43)ccc2B2c3ccccc3C(C)(c3ccccc3)c3cccc1c32 ; CC1(C)c2cc(N3C4=C(CCCC4)[Se]c4ccccc43)ccc2B2c3ccccc3C(C)(c3ccccc3)c3cc(C#N)cc1c32]

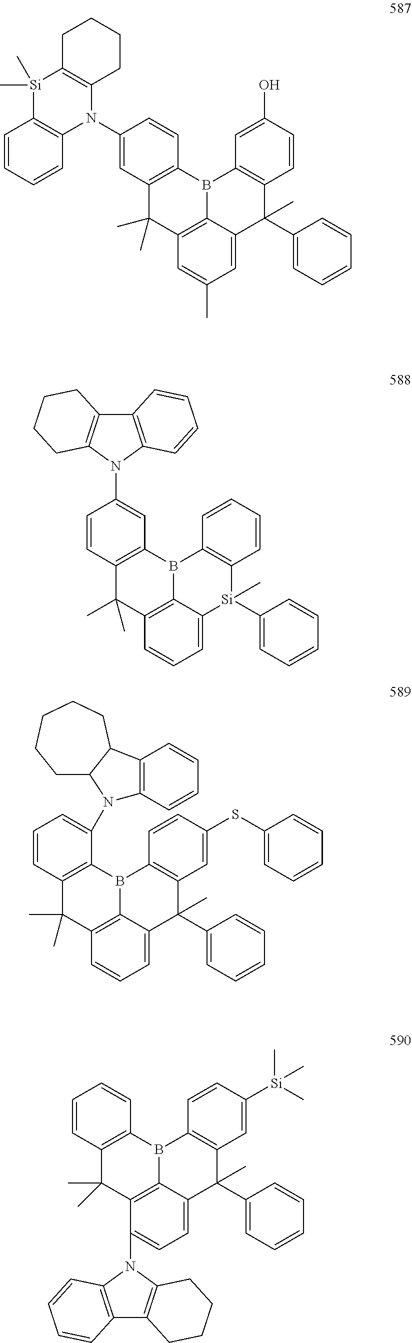 [SMILES: Cc1cc2c3c(c1)C(C)(c1ccccc1)c1ccc(O)cc1B3c1ccc(N3C4=C(CCCC4)[Si](C)(C)c4ccccc43)cc1C2(C)C ; CC1(C)c2ccc(-n3c4c(c5ccccc53)CCCC4)cc2B2c3ccccc3[Si](C)(c3ccccc3)c3cccc1c32 ; CC1(C)c2cccc(N3c4ccccc4C4CCCCCC43)c2B2c3ccc(Sc4ccccc4)cc3C(C)(c3ccccc3)c3cccc1c32 ; CC1(C)c2ccccc2B2c3ccc([Si](C)(C)C)cc3C(C)(c3ccccc3)c3ccc(-n4c5c(c6ccccc64)CCCC5)c1c32]

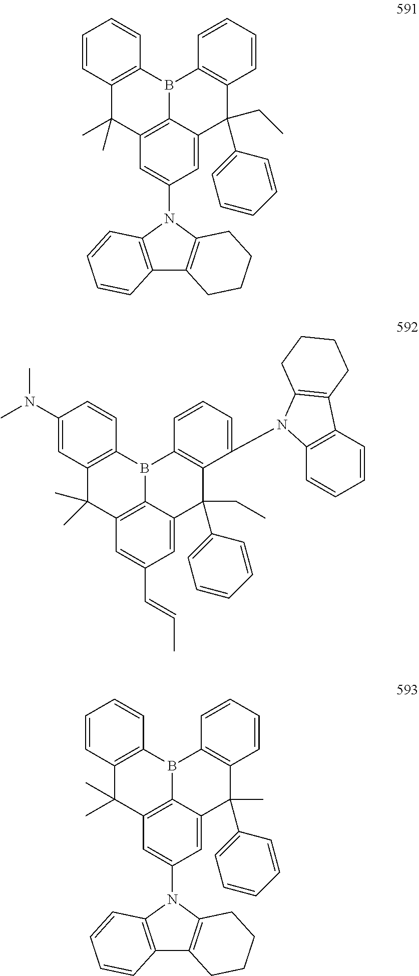 [SMILES: CCC1(c2ccccc2)c2ccccc2B2c3ccccc3C(C)(C)c3cc(-n4c5c(c6ccccc64)CCCC5)cc1c32 ; C/C=C/c1cc2c3c(c1)C(CC)(c1ccccc1)c1c(cccc1-n1c4c(c5ccccc51)CCCC4)B3c1ccc(N(C)C)cc1C2(C)C ; CC1(C)c2ccccc2B2c3ccccc3C(C)(c3ccccc3)c3cc(-n4c5c(c6ccccc64)CCCC5)cc1c32]

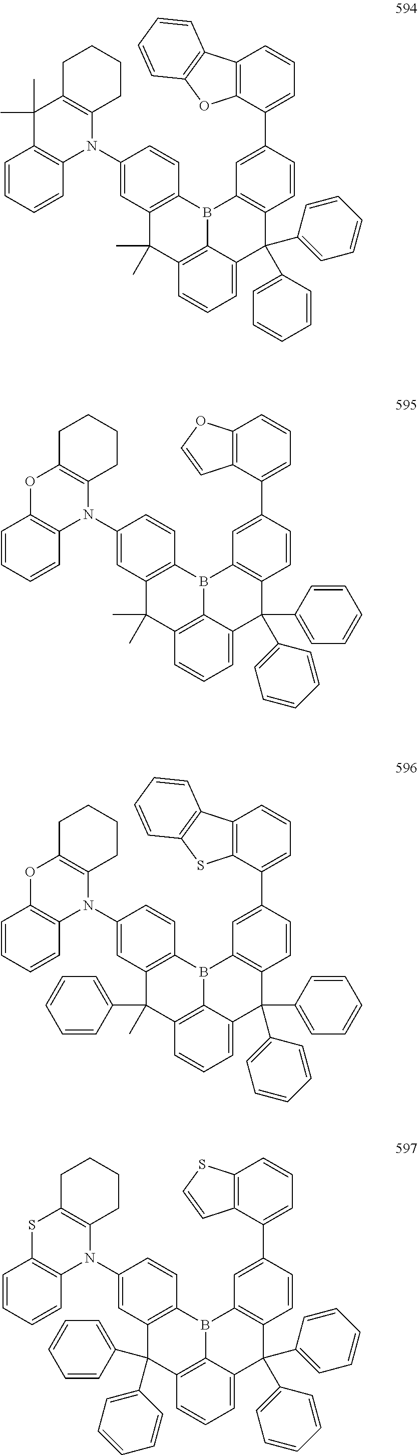 [SMILES: CC1(C)C2=C(CCCC2)N(c2ccc3c(c2)C(C)(C)c2cccc4c2B3c2cc(-c3cccc5c3oc3ccccc35)ccc2C4(c2ccccc2)c2ccccc2)c2ccccc21 ; CC1(C)c2cc(N3C4=C(CCCC4)Oc4ccccc43)ccc2B2c3cc(-c4cccc5occc45)ccc3C(c3ccccc3)(c3ccccc3)c3cccc1c32 ; CC1(c2ccccc2)c2cc(N3C4=C(CCCC4)Oc4ccccc43)ccc2B2c3cc(-c4cccc5c4sc4ccccc45)ccc3C(c3ccccc3)(c3ccccc3)c3cccc1c32 ; c1ccc(C2(c3ccccc3)c3ccc(-c4cccc5sccc45)cc3B3c4ccc(N5C6=C(CCCC6)Sc6ccccc65)cc4C(c4ccccc4)(c4ccccc4)c4cccc2c43)cc1]

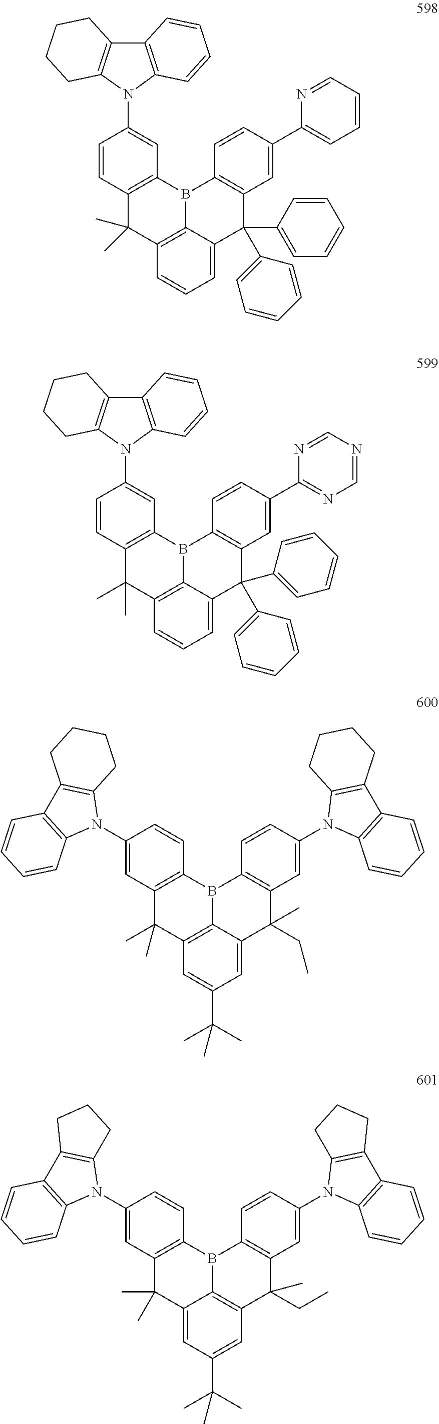 [SMILES: CC1(C)c2ccc(-n3c4c(c5ccccc53)CCCC4)cc2B2c3ccc(-c4ccccn4)cc3C(c3ccccc3)(c3ccccc3)c3cccc1c32 ; CC1(C)c2ccc(-n3c4c(c5ccccc53)CCCC4)cc2B2c3ccc(-c4ncncn4)cc3C(c3ccccc3)(c3ccccc3)c3cccc1c32 ; CCC1(C)c2cc(-n3c4c(c5ccccc53)CCCC4)ccc2B2c3ccc(-n4c5c(c6ccccc64)CCCC5)cc3C(C)(C)c3cc(C(C)(C)C)cc1c32 ; CCC1(C)c2cc(-n3c4c(c5ccccc53)CCC4)ccc2B2c3ccc(-n4c5c(c6ccccc64)CCC5)cc3C(C)(C)c3cc(C(C)(C)C)cc1c32]

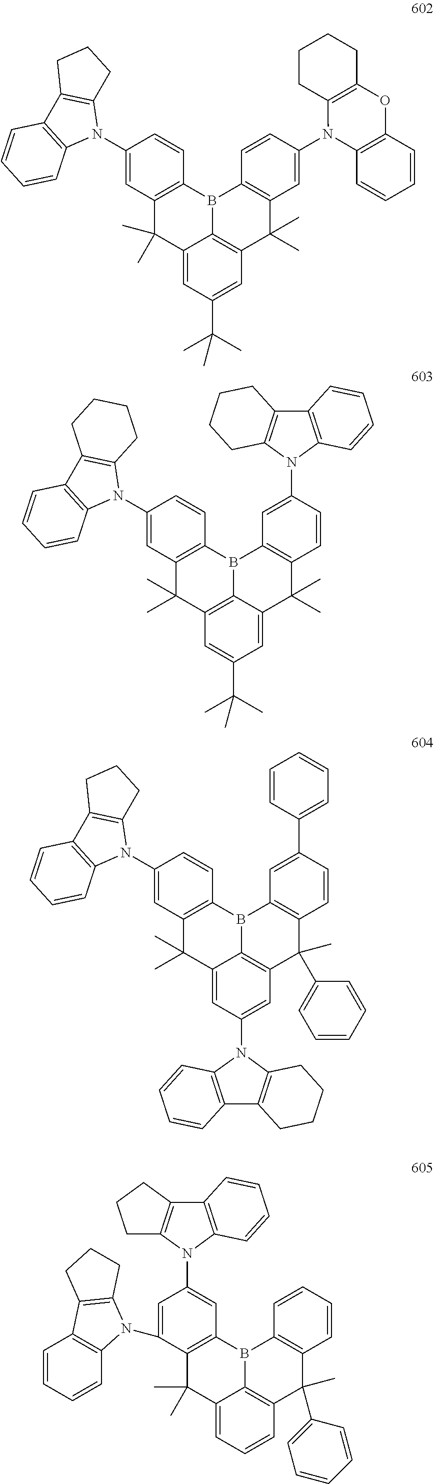

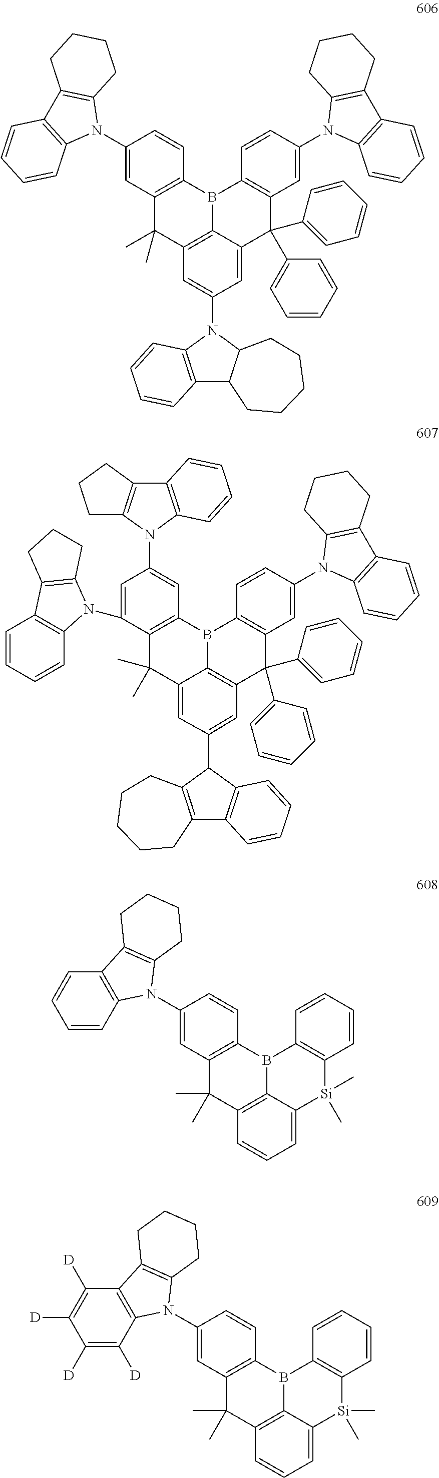

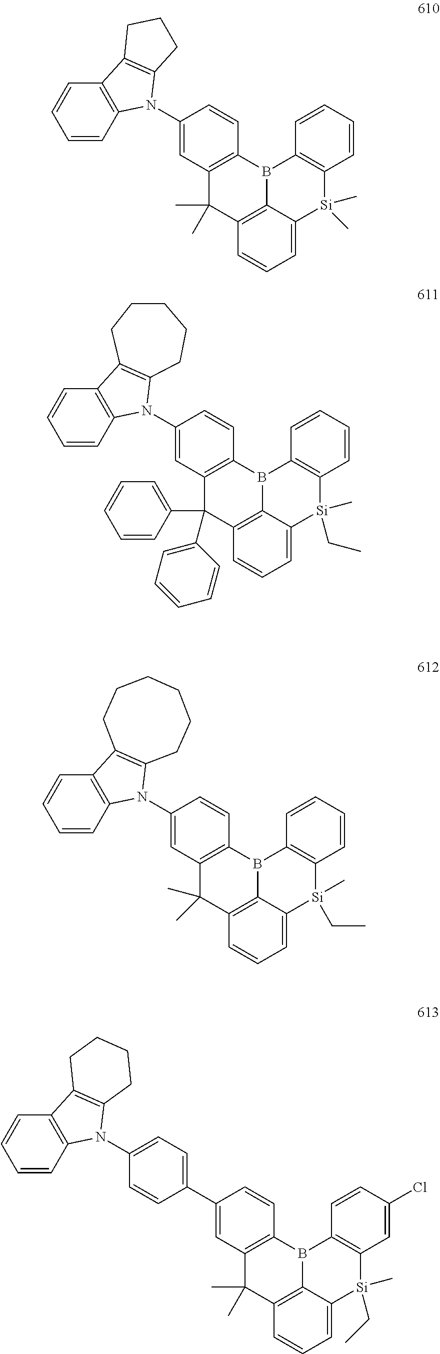 [SMILES: CC1(C)c2cc(-n3c4c(c5ccccc53)CCC4)ccc2B2c3ccccc3[Si](C)(C)c3cccc1c32 ; CC[Si]1(C)c2ccccc2B2c3ccc(-n4c5c(c6ccccc64)CCCCC5)cc3C(c3ccccc3)(c3ccccc3)c3cccc1c32 ; CC[Si]1(C)c2ccccc2B2c3ccc(-n4c5c(c6ccccc64)CCCCCC5)cc3C(C)(C)c3cccc1c32 ; CC[Si]1(C)c2cc(Cl)ccc2B2c3ccc(-c4ccc(-n5c6c(c7ccccc75)CCCC6)cc4)cc3C(C)(C)c3cccc1c32]

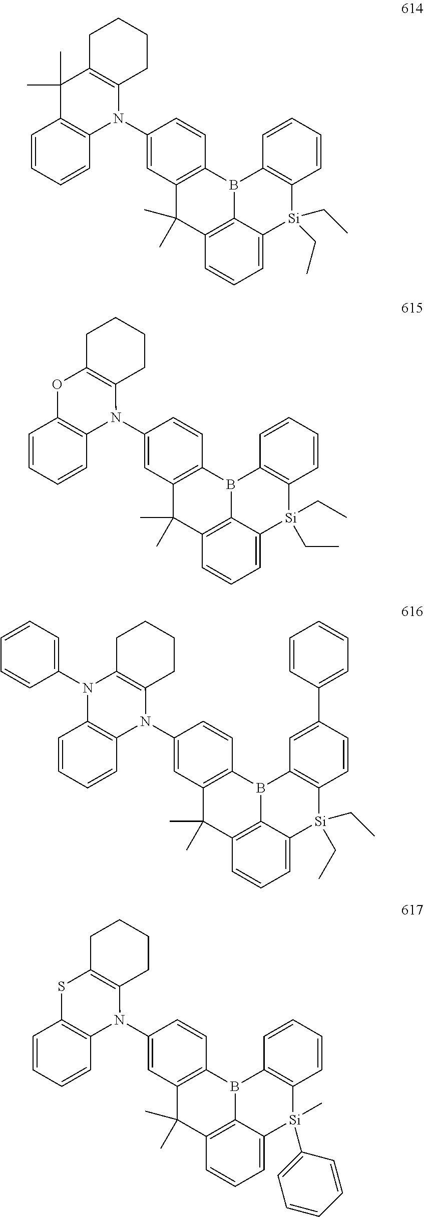 [SMILES: CC[Si]1(CC)c2ccccc2B2c3ccc(N4C5=C(CCCC5)C(C)(C)c5ccccc54)cc3C(C)(C)c3cccc1c32 ; CC[Si]1(CC)c2ccccc2B2c3ccc(N4C5=C(CCCC5)Oc5ccccc54)cc3C(C)(C)c3cccc1c32 ; CC[Si]1(CC)c2ccc(-c3ccccc3)cc2B2c3ccc(N4C5=C(CCCC5)N(c5ccccc5)c5ccccc54)cc3C(C)(C)c3cccc1c32 ; CC1(C)c2cc(N3C4=C(CCCC4)Sc4ccccc43)ccc2B2c3ccccc3[Si](C)(c3ccccc3)c3cccc1c32]

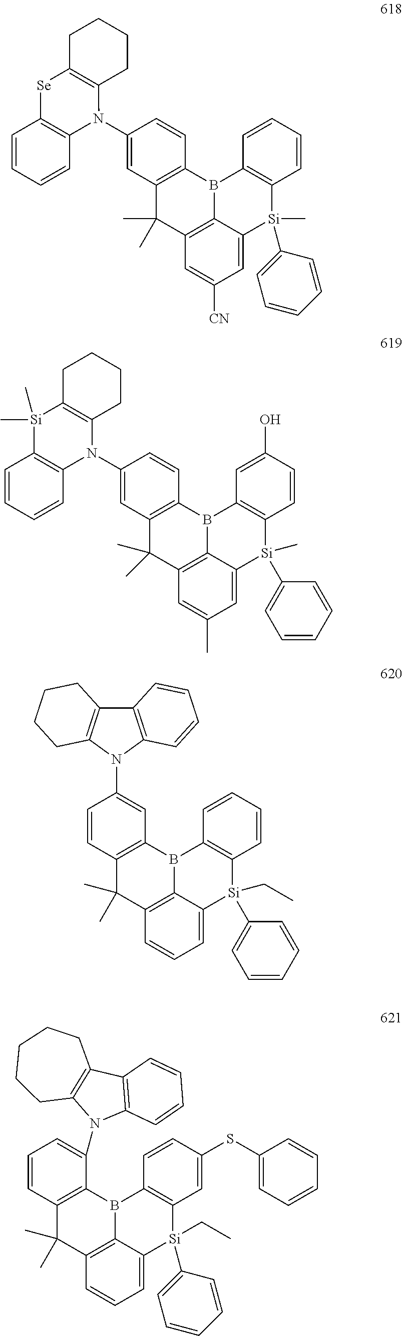

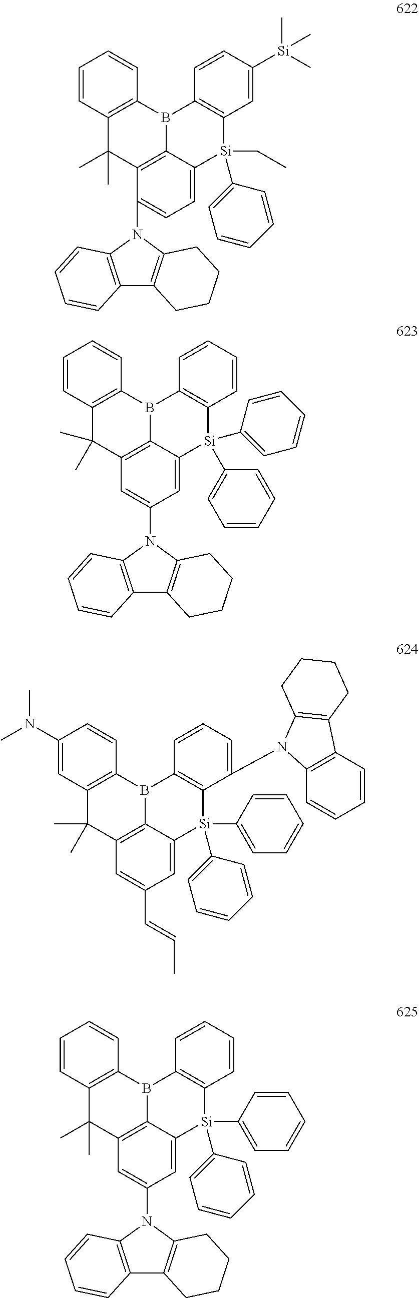

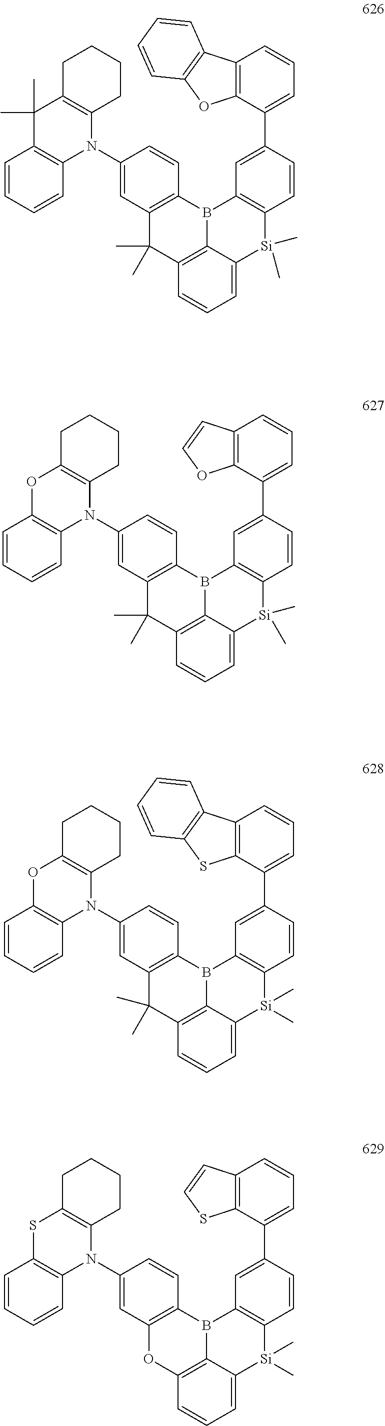

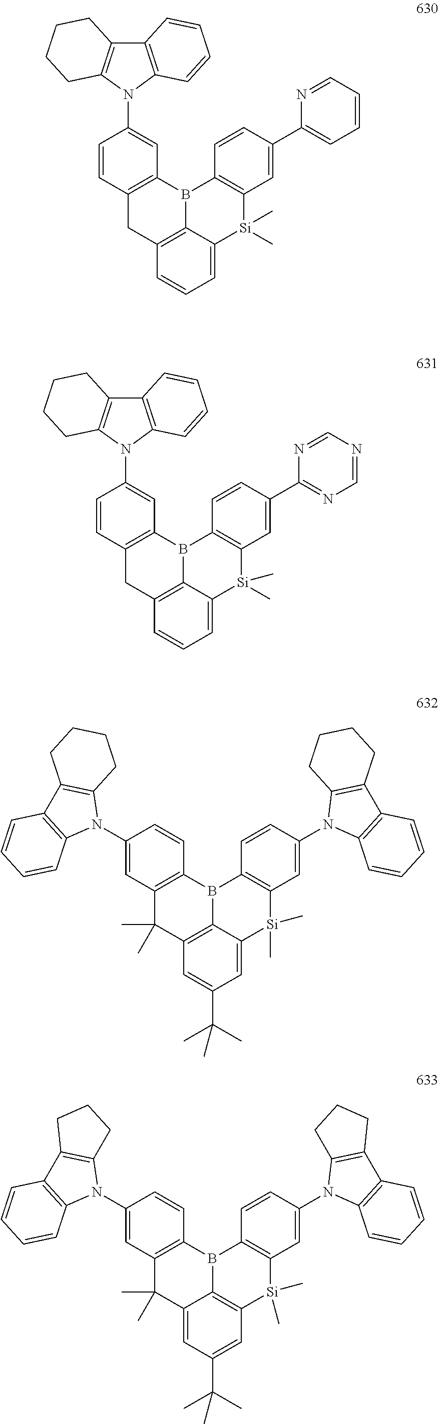 [SMILES: C[Si]1(C)c2cc(-c3ccccn3)ccc2B2c3cc(-n4c5c(c6ccccc64)CCCC5)ccc3Cc3cccc1c32 ; C[Si]1(C)c2cc(-c3ncncn3)ccc2B2c3cc(-n4c5c(c6ccccc64)CCCC5)ccc3Cc3cccc1c32 ; CC(C)(C)c1cc2c3c(c1)[Si](C)(C)c1cc(-n4c5c(c6ccccc64)CCCC5)ccc1B3c1ccc(-n3c4c(c5ccccc53)CCCC4)cc1C2(C)C ; CC(C)(C)c1cc2c3c(c1)[Si](C)(C)c1cc(-n4c5c(c6ccccc64)CCC5)ccc1B3c1ccc(-n3c4c(c5ccccc53)CCC4)cc1C2(C)C]

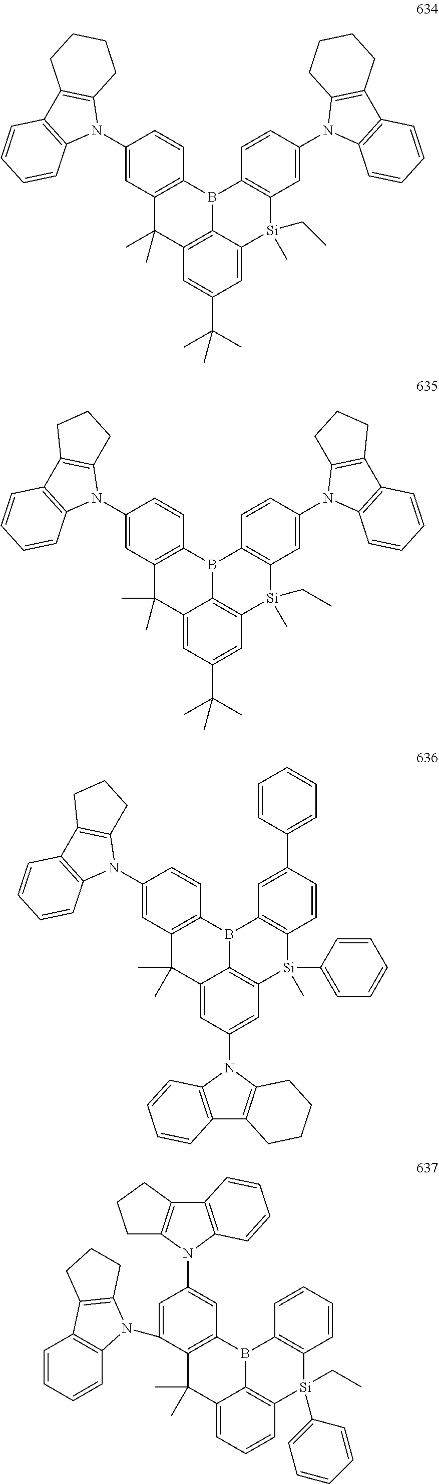

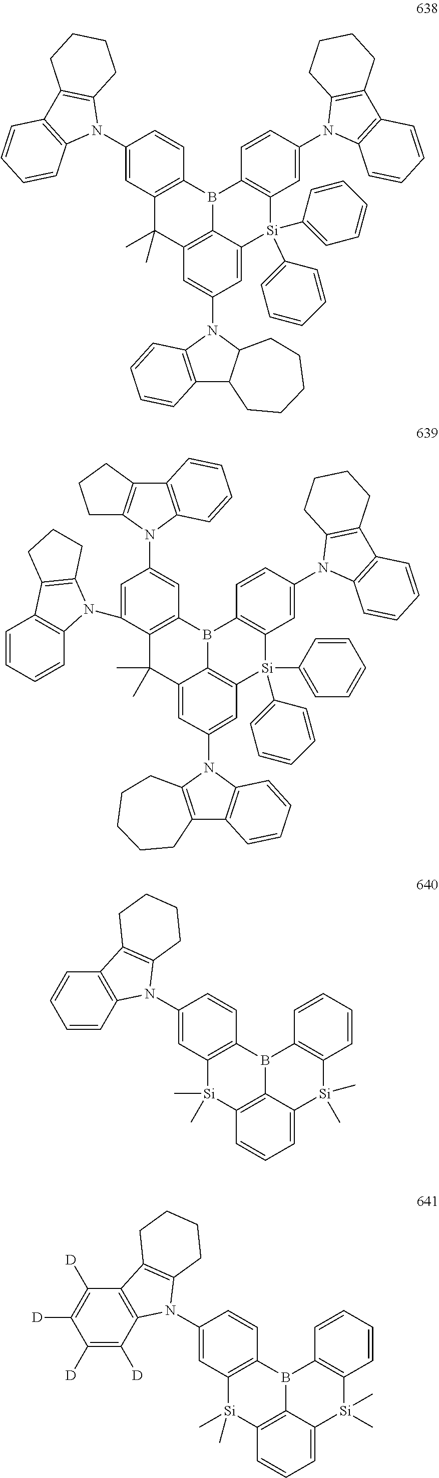

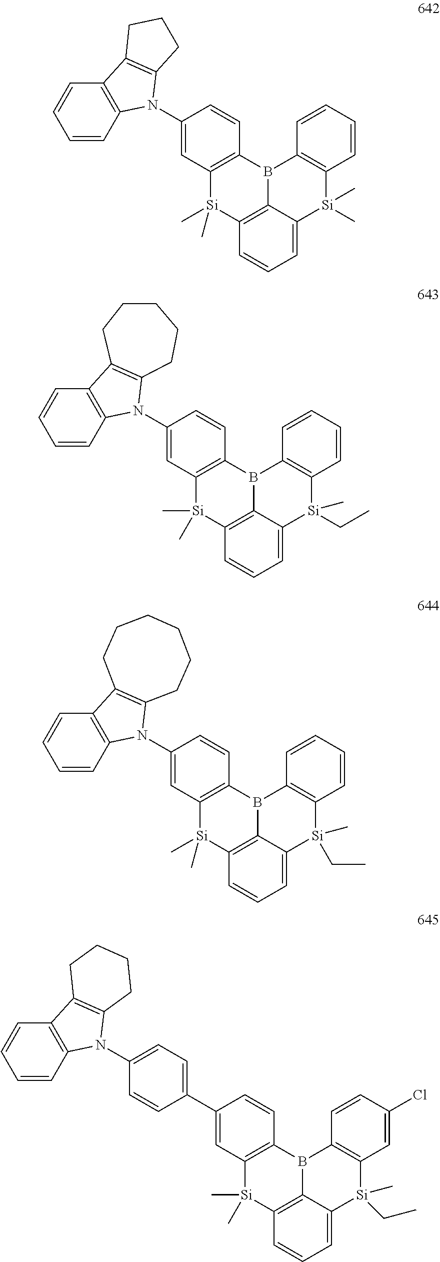 [SMILES: C[Si]1(C)c2ccccc2B2c3ccc(-n4c5c(c6ccccc64)CCC5)cc3[Si](C)(C)c3cccc1c32 ; CC[Si]1(C)c2ccccc2B2c3ccc(-n4c5c(c6ccccc64)CCCCC5)cc3[Si](C)(C)c3cccc1c32 ; CC[Si]1(C)c2ccccc2B2c3ccc(-n4c5c(c6ccccc64)CCCCCC5)cc3[Si](C)(C)c3cccc1c32 ; CC[Si]1(C)c2cc(Cl)ccc2B2c3ccc(-c4ccc(-n5c6c(c7ccccc75)CCCC6)cc4)cc3[Si](C)(C)c3cccc1c32]

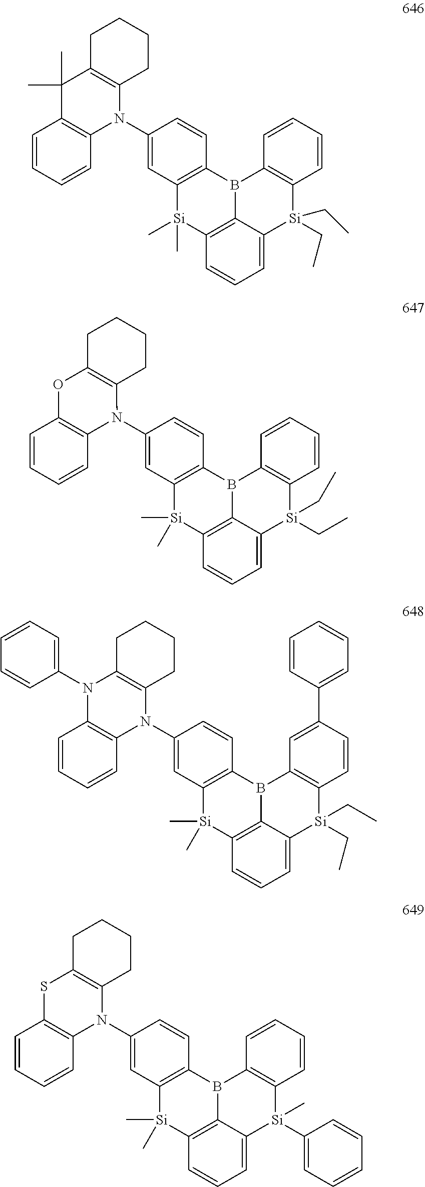 [SMILES: CC[Si]1(CC)c2ccccc2B2c3ccc(N4C5=C(CCCC5)C(C)(C)c5ccccc54)cc3[Si](C)(C)c3cccc1c32 ; CC[Si]1(CC)c2ccccc2B2c3ccc(N4C5=C(CCCC5)Oc5ccccc54)cc3[Si](C)(C)c3cccc1c32 ; CC[Si]1(CC)c2ccc(-c3ccccc3)cc2B2c3ccc(N4C5=C(CCCC5)N(c5ccccc5)c5ccccc54)cc3[Si](C)(C)c3cccc1c32 ; C[Si]1(C)c2cc(N3C4=C(CCCC4)Sc4ccccc43)ccc2B2c3ccccc3[Si](C)(c3ccccc3)c3cccc1c32]

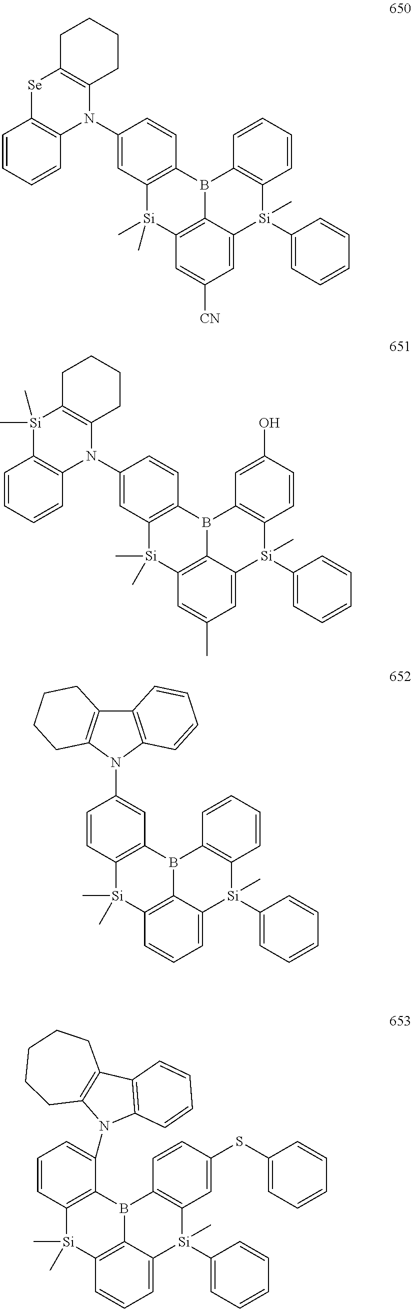

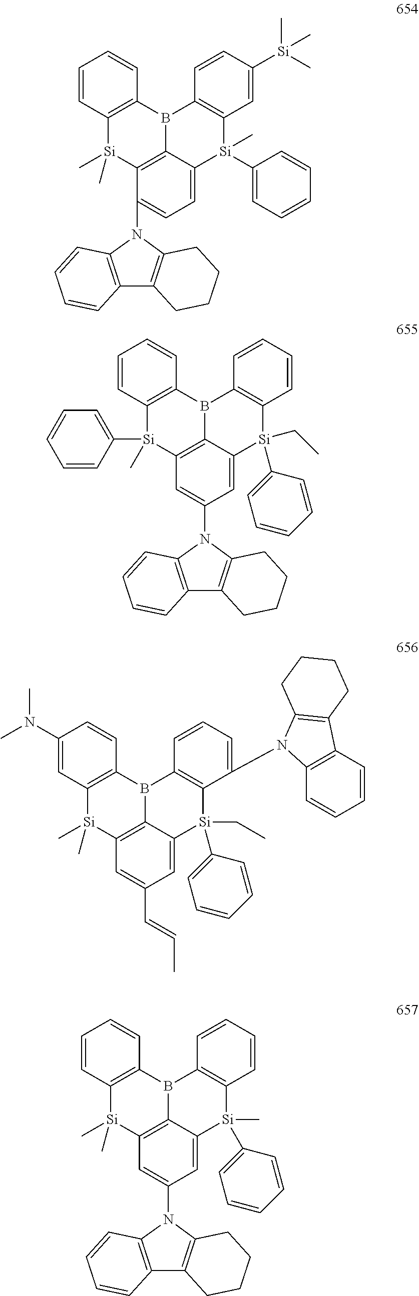

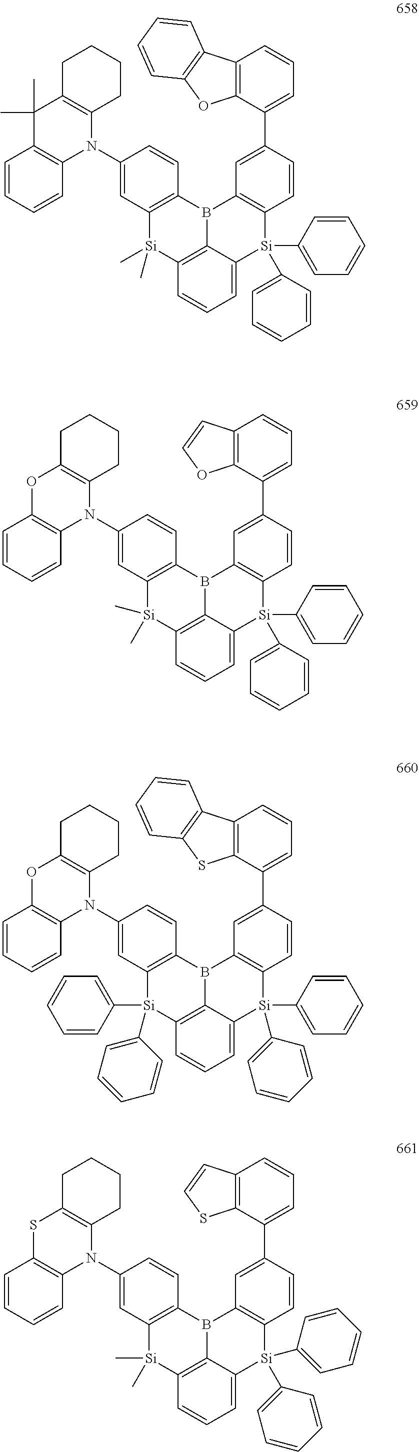 [SMILES: CC1(C)C2=C(CCCC2)N(c2ccc3c(c2)[Si](C)(C)c2cccc4c2B3c2cc(-c3cccc5c3oc3ccccc35)ccc2[Si]4(c2ccccc2)c2ccccc2)c2ccccc21 ; C[Si]1(C)c2cc(N3C4=C(CCCC4)Oc4ccccc43)ccc2B2c3cc(-c4cccc5ccoc45)ccc3[Si](c3ccccc3)(c3ccccc3)c3cccc1c32 ; c1ccc([Si]2(c3ccccc3)c3ccc(-c4cccc5c4sc4ccccc45)cc3B3c4ccc(N5C6=C(CCCC6)Oc6ccccc65)cc4[Si](c4ccccc4)(c4ccccc4)c4cccc2c43)cc1 ; C[Si]1(C)c2cc(N3C4=C(CCCC4)Sc4ccccc43)ccc2B2c3cc(-c4cccc5ccsc45)ccc3[Si](c3ccccc3)(c3ccccc3)c3cccc1c32]

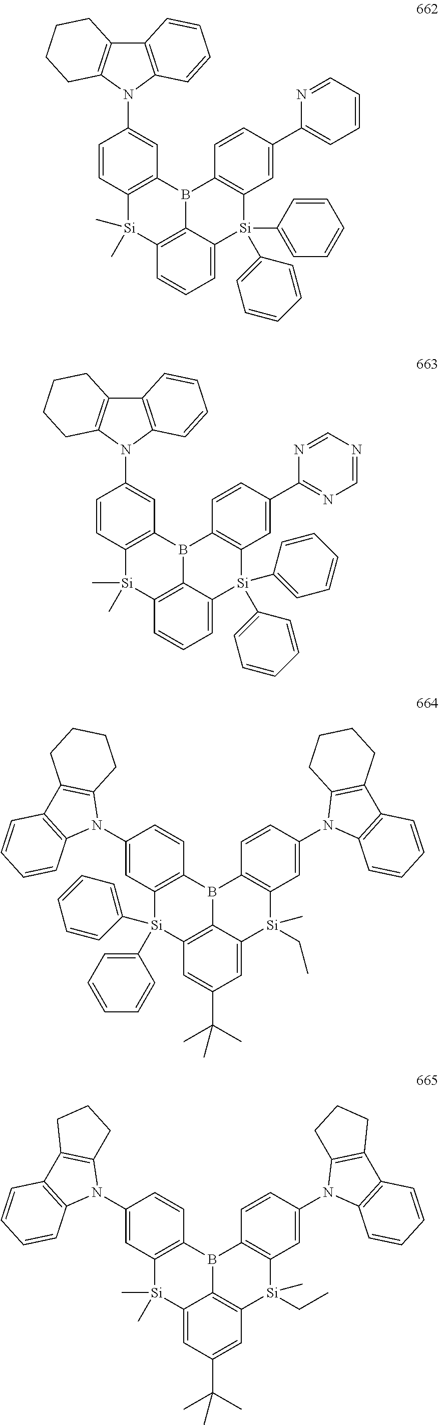 [SMILES: C[Si]1(C)c2ccc(-n3c4c(c5ccccc53)CCCC4)cc2B2c3ccc(-c4ccccn4)cc3[Si](c3ccccc3)(c3ccccc3)c3cccc1c32 ; C[Si]1(C)c2ccc(-n3c4c(c5ccccc53)CCCC4)cc2B2c3ccc(-c4ncncn4)cc3[Si](c3ccccc3)(c3ccccc3)c3cccc1c32 ; CC[Si]1(C)c2cc(-n3c4c(c5ccccc53)CCCC4)ccc2B2c3ccc(-n4c5c(c6ccccc64)CCCC5)cc3[Si](c3ccccc3)(c3ccccc3)c3cc(C(C)(C)C)cc1c32 ; CC[Si]1(C)c2cc(-n3c4c(c5ccccc53)CCC4)ccc2B2c3ccc(-n4c5c(c6ccccc64)CCC5)cc3[Si](C)(C)c3cc(C(C)(C)C)cc1c32]

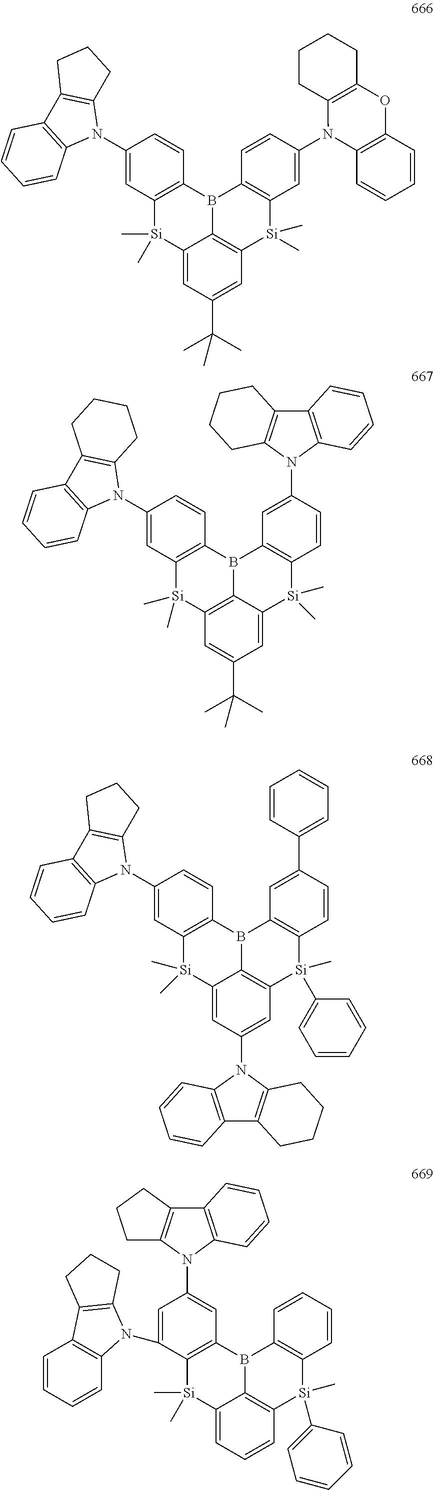

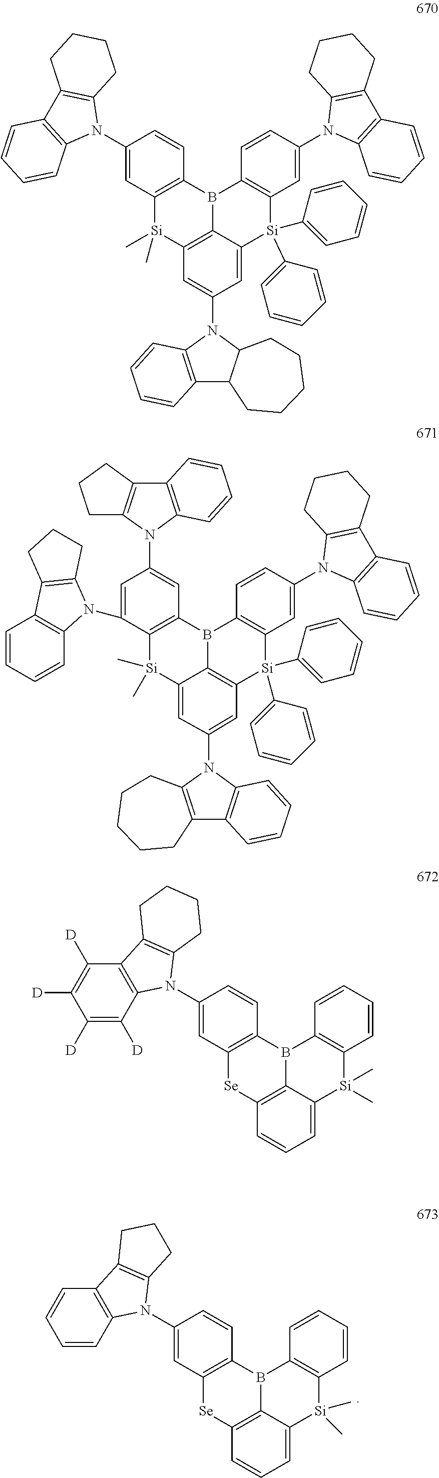

In the example compounds in Compound Group 1, “D” refers to a deuterium atom.

The fused polycyclic compound represented by Formula 1 according to one or more embodiments has a structure including or introducing a first substituent, and may achieve or accomplish long lifetime.

The fused polycyclic compound of one or more embodiments, represented by Formula 1 may include a fused ring core of first to third aromatic rings fused by a boron atom, a first heteroatom and a second heteroatom, and may have a structure in which a first substituent is a substituent in at least one selected from among the first to third aromatic rings. The first substituent may include a partially unsaturated heterocycle moiety formed by fusing a first to third rings. For example, the first substituent includes a first fused ring of a first ring including a six-member aromatic hydrocarbon ring and a second ring including a five- or six-member aromatic heterocycle including a first nitrogen atom, and may include a structure in which a third ring including a cycloalkene moiety is fused with the first fused ring. The fused polycyclic compound of one or more embodiments has a structure in which at least one first substituent is included or introduced into the fused ring core, and may show improved element lifetime characteristics. The fused polycyclic compound of one or more embodiments includes a first substituent having a fused structure of a cycloalkene moiety, and may reduce the planarity of, e.g., on, a molecular structure due to sp³ hybridized carbon and increase intermolecular distance to enhance, or show, effects of reducing exciton quenching, e.g., dexter energy transfer. The dexter energy transfer is a phenomenon of triplet excitons being transferred between molecules, and may be enhanced or increased with short intermolecular distance, and may be a factor increasing quenching phenomenon according to the increase of triplet concentration. According to the present disclosure, the fused polycyclic compound of one or more embodiments includes a structure having a first substituent having a large steric hindrance, and may increase intermolecular distance between adjacent molecules to restrain dexter energy transfer, and accordingly, the deterioration of lifetime, generated according to the increase of triplet concentration, may be restrained. Accordingly, when the fused polycyclic compound of one or more embodiments is applied in the emission layer EML of a light emitting element ED, emission lifetime may be improved.

The emission spectrum of the fused polycyclic compound of one or more embodiments, represented by Formula 1 has a full width at half maximum (FWHM) of about 10 to 50 nm, or, about 20 to 40 nm. Because the emission spectrum of the first compound of one or more embodiments, represented by Formula 1 has the described range of the full width at half maximum, when applied to an element, emission efficiency may be enhanced or improved. In some embodiments, when utilized as a material as a blue light emitting element, element lifetime may be improved.

The fused polycyclic compound of one or more embodiments, represented by Formula 1 may be a material for emitting thermally activated delayed fluorescence. In some embodiments, the fused polycyclic compound of one or more embodiments, represented by Formula 1 may be a thermally activated delayed fluorescence dopant having a difference (ΔE_{ST}) between the lowest triplet excitation energy level (T1 level) and the lowest singlet excitation energy level (S1 level) of about 0.6 eV or less. The fused polycyclic compound of one or more embodiments, represented by Formula 1 may be a thermally activated delayed fluorescence dopant having a difference (ΔE_{ST}) between the lowest triplet excitation energy level (T1 level) and the lowest singlet excitation energy level (S1 level) of about 0.2 eV or less.

The fused polycyclic compound of one or more embodiments, represented by Formula 1 may be a light-emitting material having a light center wavelength in a wavelength region of about 430 nm to about 490 nm. For example, the fused polycyclic compound of one or more embodiments, represented by Formula 1 may be a blue thermally activated delayed fluorescence (TADF) dopant. However, one or more embodiments of the present disclosure is not limited thereto, and when the fused polycyclic compound of one or more embodiments is utilized as a light-emitting material, the first compound may be utilized as a dopant material emitting light in one or more suitable wavelength regions such as a red emitting dopant, and green emitting dopant.

In the light emitting element ED of one or more embodiments, the emission layer EML may be to emit (e.g., configured to emit) delayed fluorescence. For example, the emission layer EML may be to emit (e.g., configured to emit) thermally activated delayed fluorescence (TADF).

In some embodiments, the emission layer EML of the light emitting element ED may be to emit (e.g., configured to emit) blue light. For example, the emission layer EML of an organic electroluminescence light emitting element ED may be to emit (e.g., configured to emit) blue light in a region of about 490 nm or less. However, one or more embodiments of the present disclosure is not limited thereto, and the emission layer EML may be to emit (e.g., configured to emit) green light or red light.

In some embodiments, the fused polycyclic compound of may be included in an emission layer EML. The fused polycyclic compound of one or more embodiments may be included in an emission layer EML as a dopant material. The fused polycyclic compound of one or more embodiments may be a thermally activated delayed fluorescence emitting material. The fused polycyclic compound of one or more embodiments may be utilized as a thermally activated delayed fluorescence dopant. For example, in the light emitting element ED of one or more embodiments, the emission layer EML may include at least one selected from among the fused polycyclic compounds represented in Compound Group 1 as a thermally delayed fluorescence dopant. However, the utilize of the fused polycyclic compound of one or more embodiments is not limited thereto.

In one or more embodiments, the emission layer EML may include multiple compounds. The emission layer EML of one or more embodiments may include the fused polycyclic compound represented by Formula 1, i.e., the first compound, and at least one selected from among a second compound represented by Formula HT-1, a third compound represented by Formula ET-1 and/or a fourth compound represented by Formula D-1.

In one or more embodiments, the emission layer EML may include the first compound represented by Formula 1 and further include at least one selected from among a second compound represented by Formula HT-1 and/or a third compound represented by Formula ET-1.

In one or more embodiments, the emission layer EML may include a second compound represented by Formula HT-1. In one or more embodiments, the second compound may be utilized as a hole transport host material in an emission layer EML.

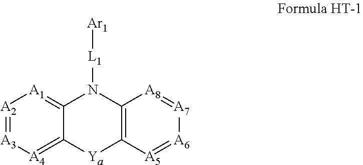

In Formula HT-1, A₁ to A₈ may each independently be N or CR₄₁. For example, all A₁ to A₈ may be CR₅₁. In some embodiments, any one selected from among A₁ to A₈ may be N, and the remainder may be CR₅₁.

In Formula HT-1, L₁ may be a direct linkage, a substituted or unsubstituted arylene group of 6 to 30 ring-forming carbon atoms, or a substituted or unsubstituted heteroarylene group of 2 to 30 ring-forming carbon atoms. For example, L₁ may be a direct linkage, a substituted or unsubstituted phenylene group, a substituted or unsubstituted divalent biphenyl group, a substituted or unsubstituted divalent carbazole group, and/or the like, but one or more embodiments of the present disclosure is not limited thereto.

In Formula HT-1, Yₐ may be a direct linkage, CR₅₂R₅₃, or SiR₅₄R₅₅. For example, it may refer to that two benzene rings connected with the nitrogen atom of Formula HT-1 may be connected via a direct linkage,

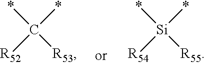

In Formula HT-1, when Yₐ is a direct linkage, the substituent represented by Formula HT-1 may include a carbazole moiety.

In Formula HT-1, Ar₁ may be a substituted or unsubstituted aryl group of 6 to 30 ring-forming carbon atoms, or a substituted or unsubstituted heteroaryl group of 2 to 30 ring-forming carbon atoms. For example, Ar₁ may be a substituted or unsubstituted carbazole group, a substituted or unsubstituted dibenzofuran group, a substituted or unsubstituted dibenzothiophene group, a substituted or unsubstituted biphenyl group, and/or the like, but one or more embodiments of the present disclosure is not limited thereto.

In Formula HT-1, R₅₁ to R₅₅ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 60 ring-forming carbon atoms. In some embodiments, each of R₅₁ to R₅₅ may be combined with an adjacent group to form a ring. For example, R₅₁ to R₅₅ may each independently be a hydrogen atom or a deuterium atom. R₅₁ to R₅₅ may each independently be an unsubstituted methyl group or an unsubstituted phenyl group.

In one or more embodiments, the second compound represented by Formula HT-1 may be represented by any one selected from among the compounds represented in Compound Group 2. An emission layer EML may include at least one selected from among the compounds represented in Compound Group 2 as a hole transport host material.

### Compound Group 2

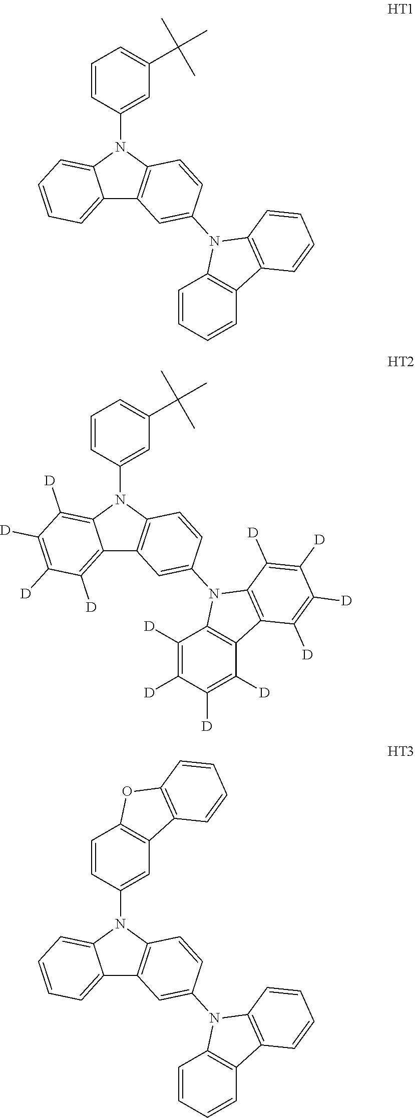

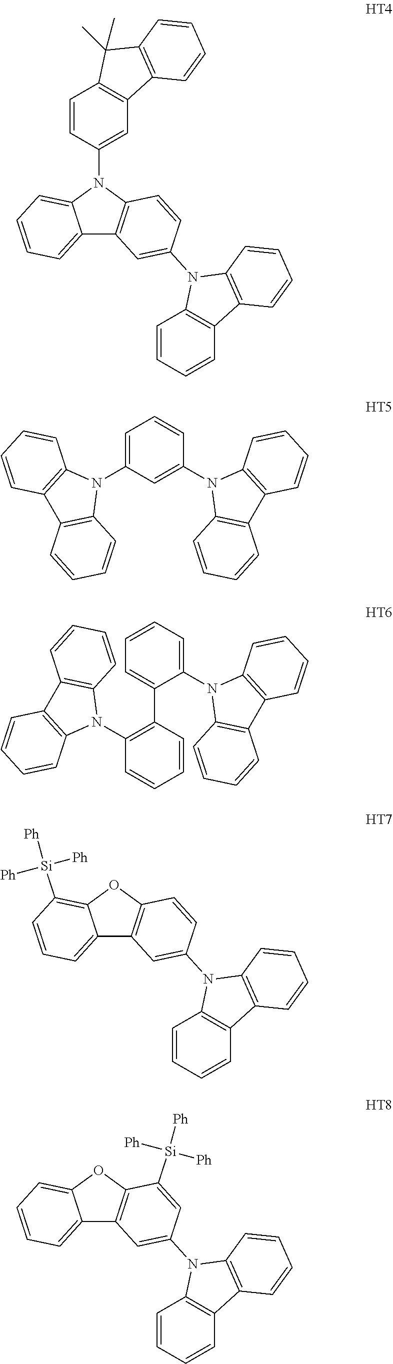

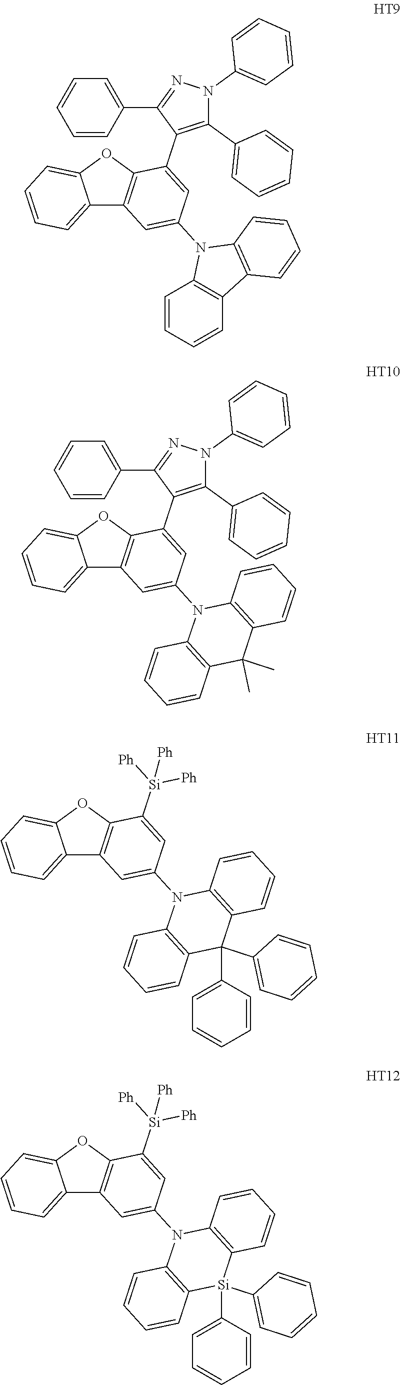 [SMILES: c1ccc(-c2nn(-c3ccccc3)c(-c3ccccc3)c2-c2cc(-n3c4ccccc4c4ccccc43)cc3c2oc2ccccc23)cc1 ; CC1(C)c2ccccc2N(c2cc(-c3c(-c4ccccc4)nn(-c4ccccc4)c3-c3ccccc3)c3oc4ccccc4c3c2)c2ccccc21 ; c1ccc(C2(c3ccccc3)c3ccccc3N(c3cc([Si](c4ccccc4)(c4ccccc4)c4ccccc4)c4oc5ccccc5c4c3)c3ccccc32)cc1 ; c1ccc([Si]2(c3ccccc3)c3ccccc3N(c3cc([Si](c4ccccc4)(c4ccccc4)c4ccccc4)c4oc5ccccc5c4c3)c3ccccc32)cc1]

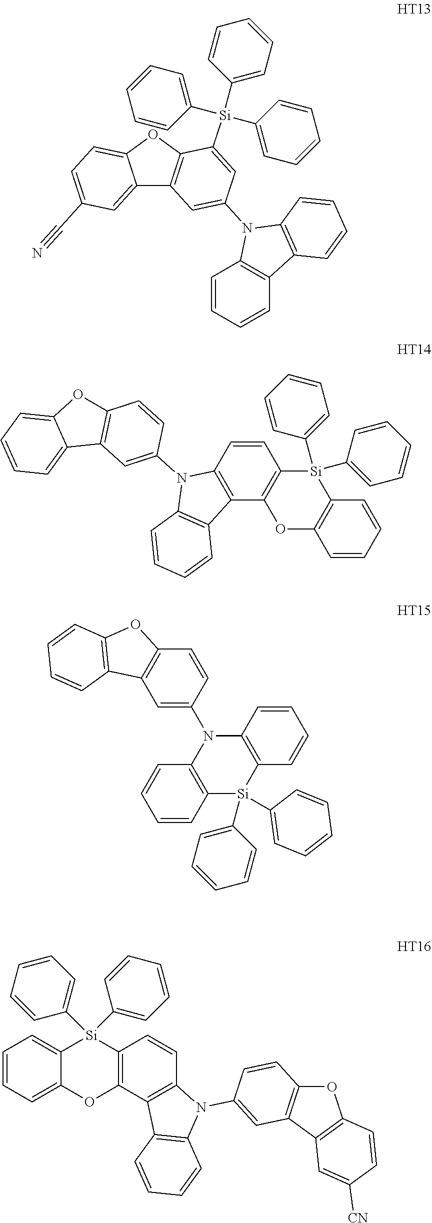 [SMILES: N#Cc1ccc2oc3c([Si](c4ccccc4)(c4ccccc4)c4ccccc4)cc(-n4c5ccccc5c5ccccc54)cc3c2c1 ; c1ccc([Si]2(c3ccccc3)c3ccccc3Oc3c2ccc2c3c3ccccc3n2-c2ccc3oc4ccccc4c3c2)cc1 ; c1ccc([Si]2(c3ccccc3)c3ccccc3N(c3ccc4oc5ccccc5c4c3)c3ccccc32)cc1 ; N#Cc1ccc2oc3ccc(-n4c5ccccc5c5c6c(ccc54)[Si](c4ccccc4)(c4ccccc4)c4ccccc4O6)cc3c2c1]

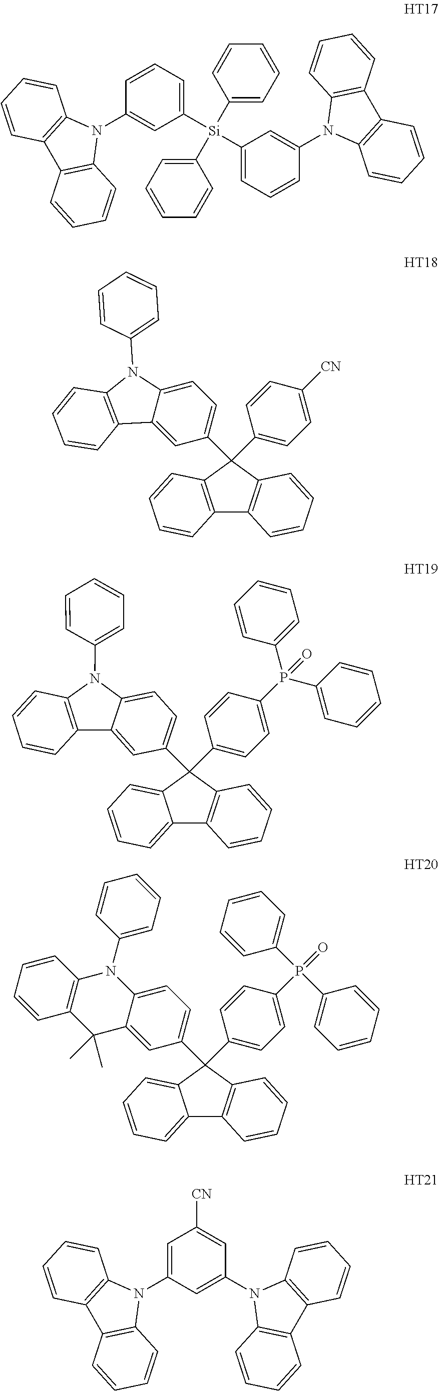

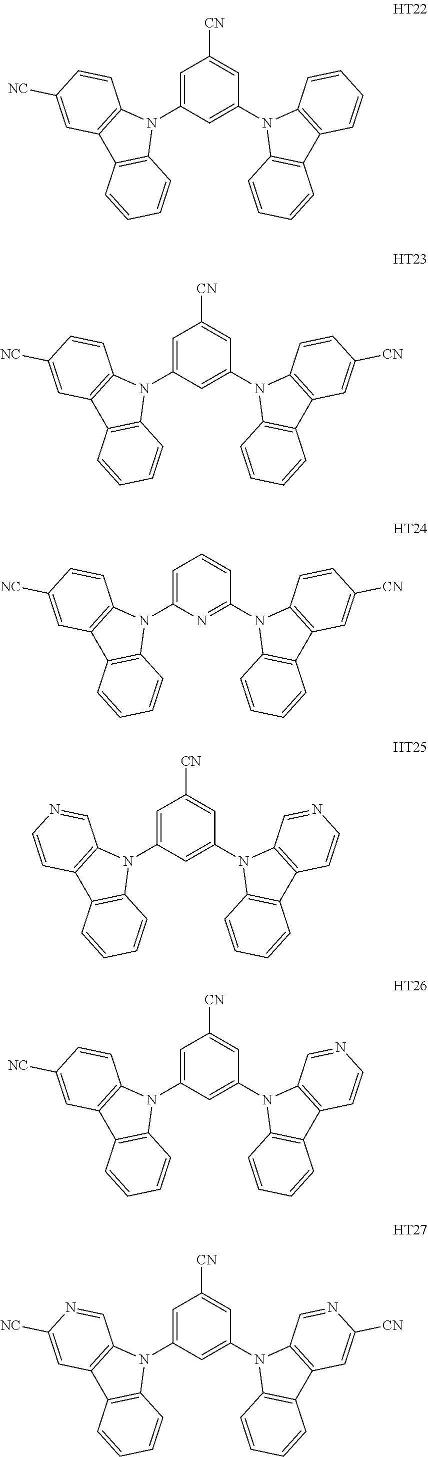 [SMILES: N#Cc1cc(-n2c3ccccc3c3ccccc32)cc(-n2c3ccccc3c3cc(C#N)ccc32)c1 ; N#Cc1cc(-n2c3ccccc3c3cc(C#N)ccc32)cc(-n2c3ccccc3c3cc(C#N)ccc32)c1 ; N#Cc1ccc2c(c1)c1ccccc1n2-c1cccc(-n2c3ccccc3c3cc(C#N)ccc32)n1 ; N#Cc1cc(-n2c3ccccc3c3ccncc32)cc(-n2c3ccccc3c3ccncc32)c1 ; N#Cc1cc(-n2c3ccccc3c3cc(C#N)ccc32)cc(-n2c3ccccc3c3ccncc32)c1 ; N#Cc1cc(-n2c3ccccc3c3cc(C#N)ncc32)cc(-n2c3ccccc3c3cc(C#N)ncc32)c1]

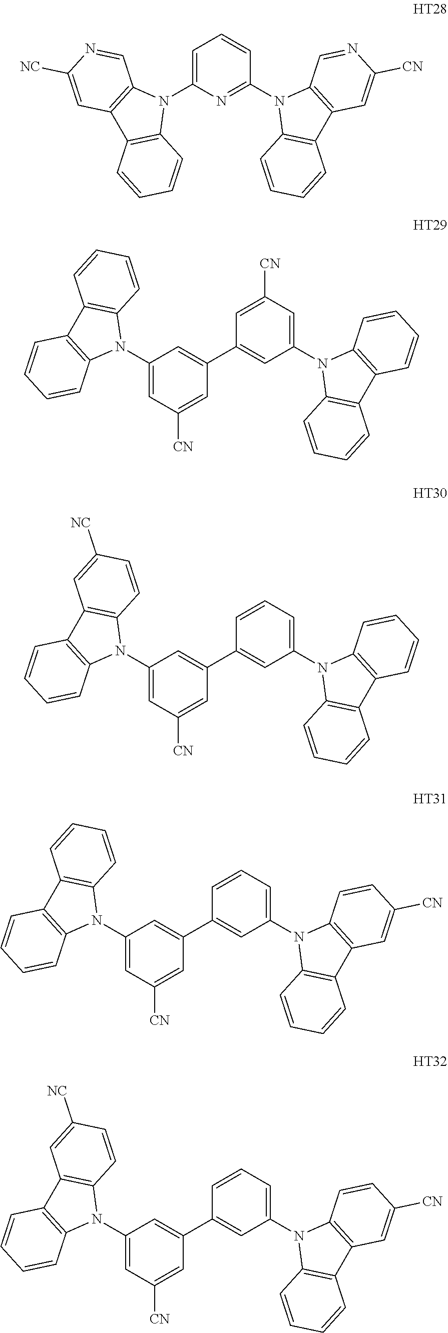 [SMILES: N#Cc1cc2c3ccccc3n(-c3cccc(-n4c5ccccc5c5cc(C#N)ncc54)n3)c2cn1 ; N#Cc1cc(-c2cc(C#N)cc(-n3c4ccccc4c4ccccc43)c2)cc(-n2c3ccccc3c3ccccc32)c1 ; N#Cc1cc(-c2cccc(-n3c4ccccc4c4ccccc43)c2)cc(-n2c3ccccc3c3cc(C#N)ccc32)c1 ; N#Cc1cc(-c2cccc(-n3c4ccccc4c4cc(C#N)ccc43)c2)cc(-n2c3ccccc3c3ccccc32)c1 ; N#Cc1cc(-c2cccc(-n3c4ccccc4c4cc(C#N)ccc43)c2)cc(-n2c3ccccc3c3cc(C#N)ccc32)c1]

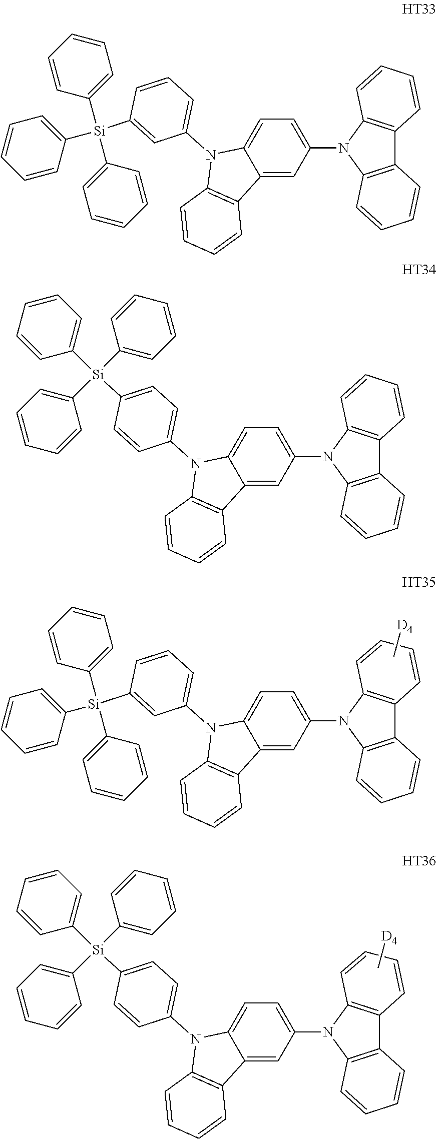

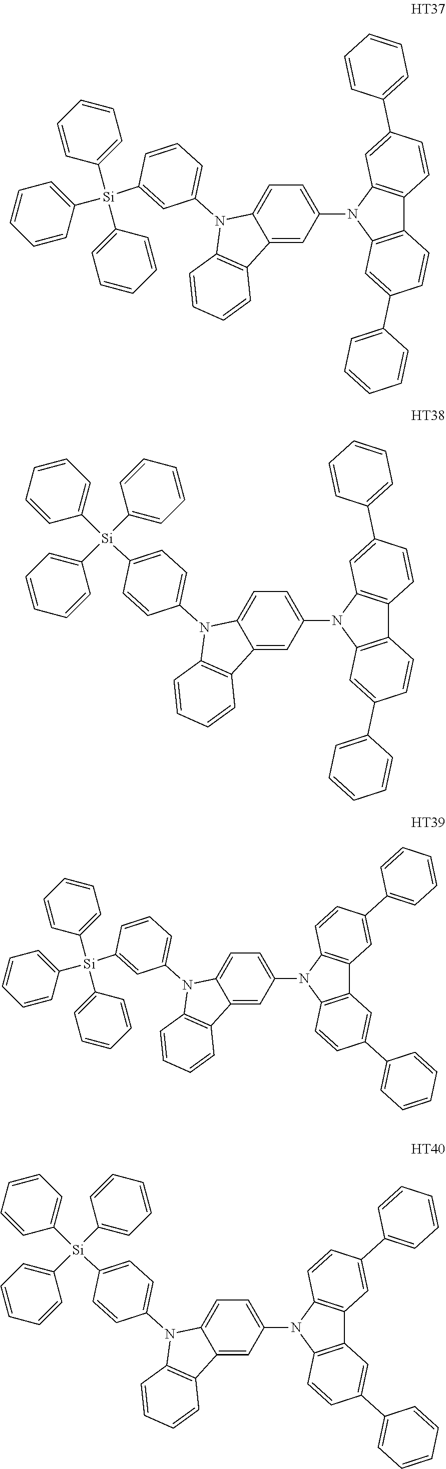 [SMILES: c1ccc(-c2ccc3c4ccc(-c5ccccc5)cc4n(-c4ccc5c(c4)c4ccccc4n5-c4cccc([Si](c5ccccc5)(c5ccccc5)c5ccccc5)c4)c3c2)cc1 ; c1ccc(-c2ccc3c4ccc(-c5ccccc5)cc4n(-c4ccc5c(c4)c4ccccc4n5-c4ccc([Si](c5ccccc5)(c5ccccc5)c5ccccc5)cc4)c3c2)cc1 ; c1ccc(-c2ccc3c(c2)c2cc(-c4ccccc4)ccc2n3-c2ccc3c(c2)c2ccccc2n3-c2cccc([Si](c3ccccc3)(c3ccccc3)c3ccccc3)c2)cc1 ; c1ccc(-c2ccc3c(c2)c2cc(-c4ccccc4)ccc2n3-c2ccc3c(c2)c2ccccc2n3-c2ccc([Si](c3ccccc3)(c3ccccc3)c3ccccc3)cc2)cc1]

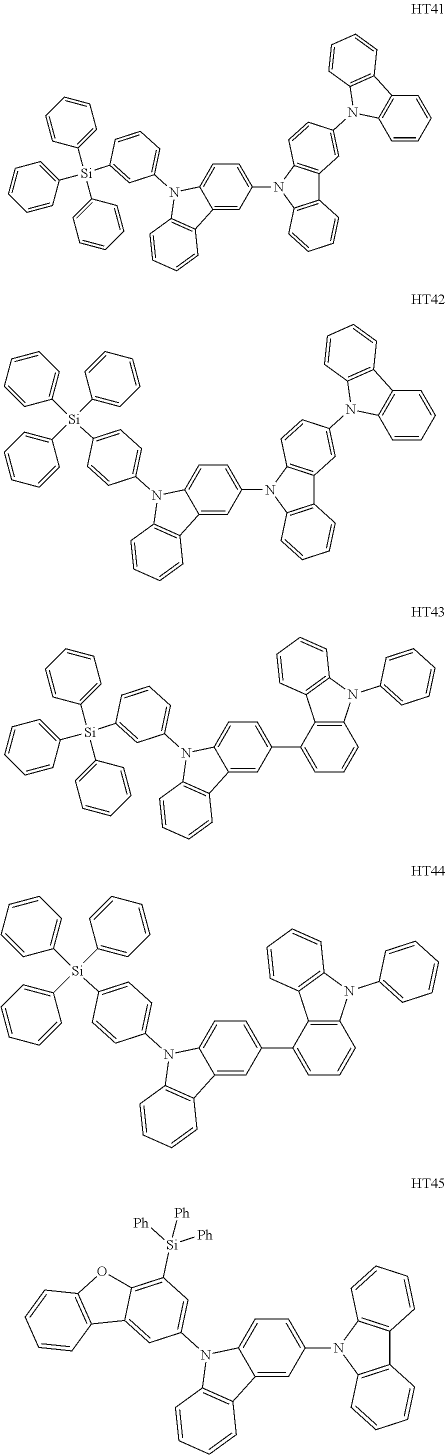

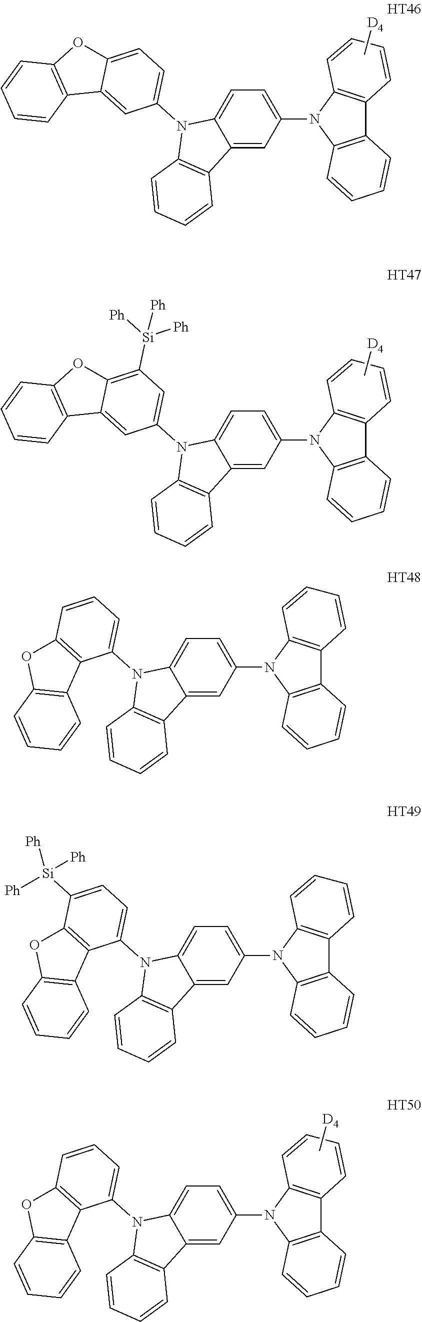

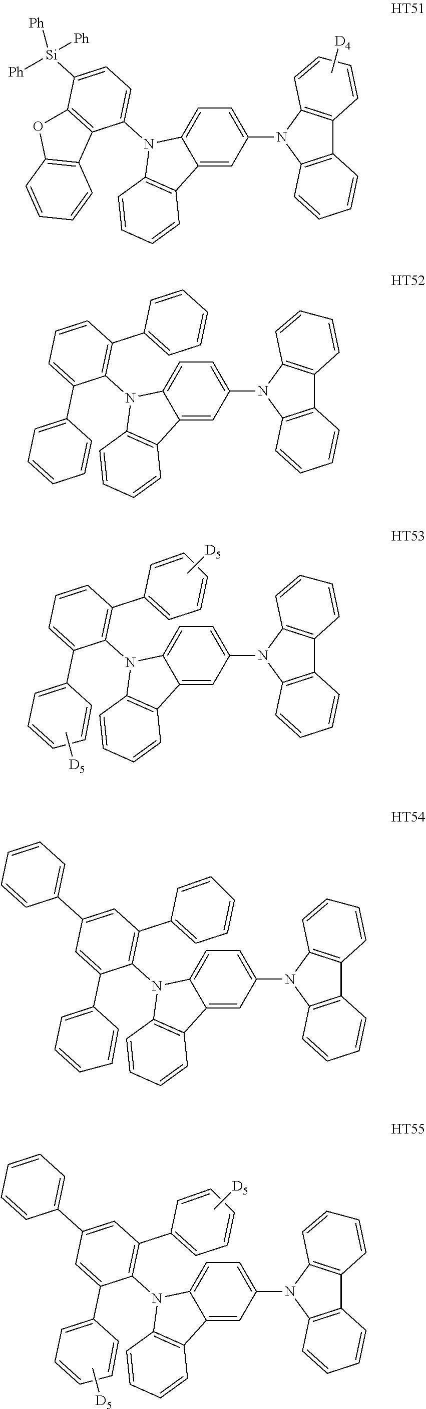

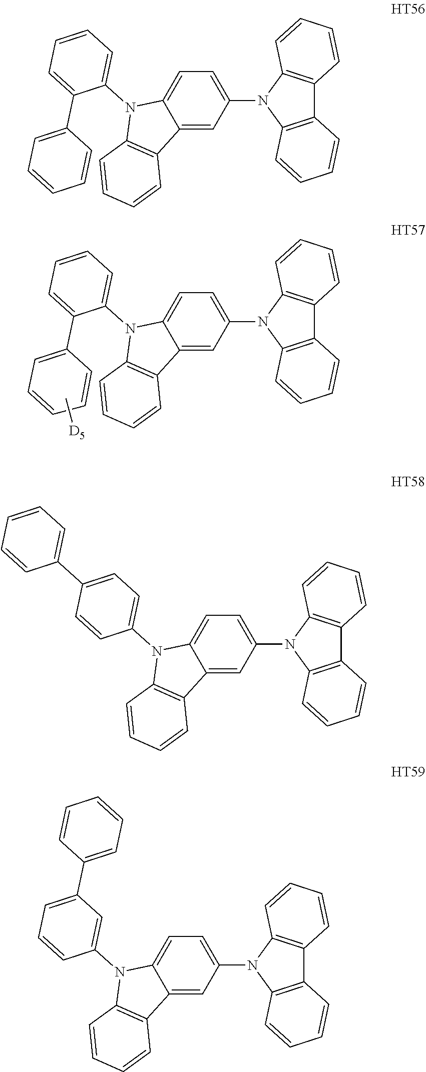

In the example compounds suggested in Compound Group 2, “D” refers to a deuterium atom, and “Ph” may refer to a substituted or unsubstituted phenyl group. For example, in the example compounds suggested in Compound Group 2, “Ph” may be an unsubstituted phenyl group.

In one or more embodiments, the emission layer EML may include a third compound represented by Formula ET-1. For example, the third compound may be utilized as an electron transport host material in the emission layer EML.

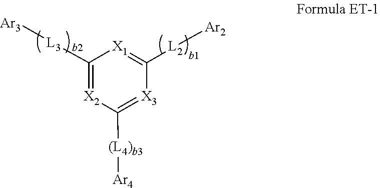

In Formula ET-1, at least one selected from among X₁ to X₃ may be N, and the remainder may be CR₅₆. For example, at least one (e.g., one) selected from among X₁ to X₃ may be N, and the remainder (e.g., the reminder two) may each independently be CR₅₆. In this case, the third compound represented by Formula ET-1 may include a pyridine moiety. In some embodiments, at least two selected from among X₁ to X₃ may be N, and the remainder may be CR₅₆. In this case, the third compound represented by Formula ET-1 may include a pyrimidine moiety. In some embodiments, X₁ to X₃ may be all N. In this case, the third compound represented by Formula ET-1 may include a triazine moiety.

In Formula ET-1, R₅₆ may be a hydrogen atom, a deuterium atom, a substituted or unsubstituted alkyl group of 1 to 20 carbon atoms, a substituted or unsubstituted aryl group of 6 to 60 ring-forming carbon atoms, or a substituted or unsubstituted heteroaryl group of 2 to 60 ring-forming carbon atoms.

In Formula ET-1, b1 to b3 may each independently be an integer of 0 to 10.

In Formula ET-1, Ar₂ to Ar₄ may each independently be a hydrogen atom, a deuterium atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms. For example, Ar₂ to Ar₄ may be substituted or unsubstituted phenyl groups or substituted or unsubstituted carbazole groups.

In Formula ET-1, L₂ to L₄ may each independently be a direct linkage, a substituted or unsubstituted arylene group of 6 to 30 ring-forming carbon atoms, or a substituted or unsubstituted heteroarylene group of 2 to 30 ring-forming carbon atoms. In some embodiments, when each of b1 to b3 is an integer of 2 or more, L₂ to L₄ may each independently be a substituted or unsubstituted arylene group of 6 to 30 ring-forming carbon atoms, or a substituted or unsubstituted heteroarylene group of 2 to 30 ring-forming carbon atoms.

In one or more embodiments, the third compound may be represented by any one selected from among the compounds in Compound Group 3. The light emitting device ED of one or more embodiments may include any one selected from among the compounds in Compound Group 3.

### Compound Group 3

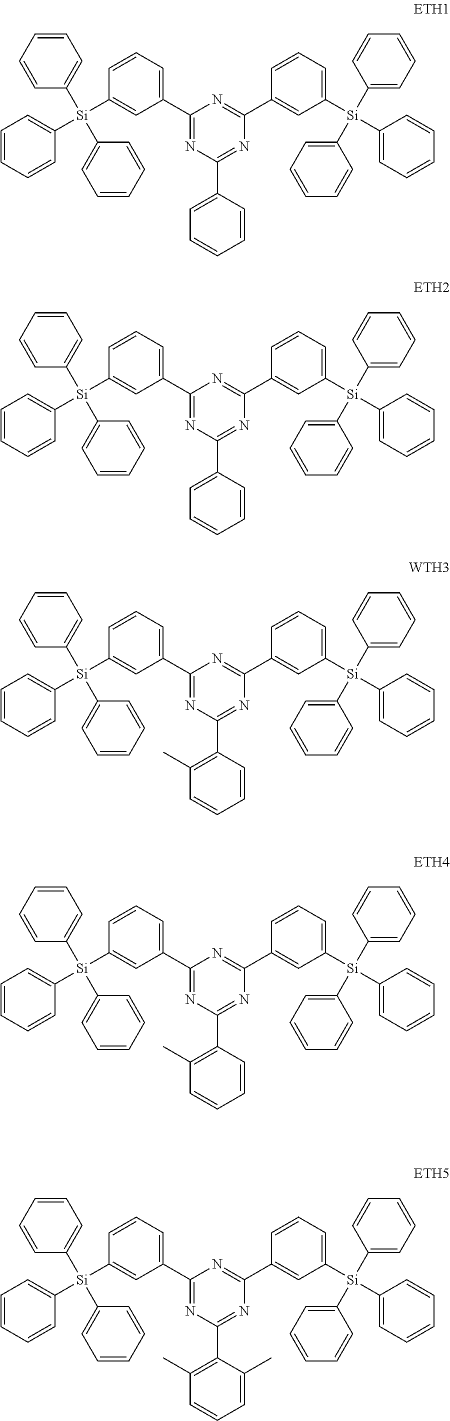

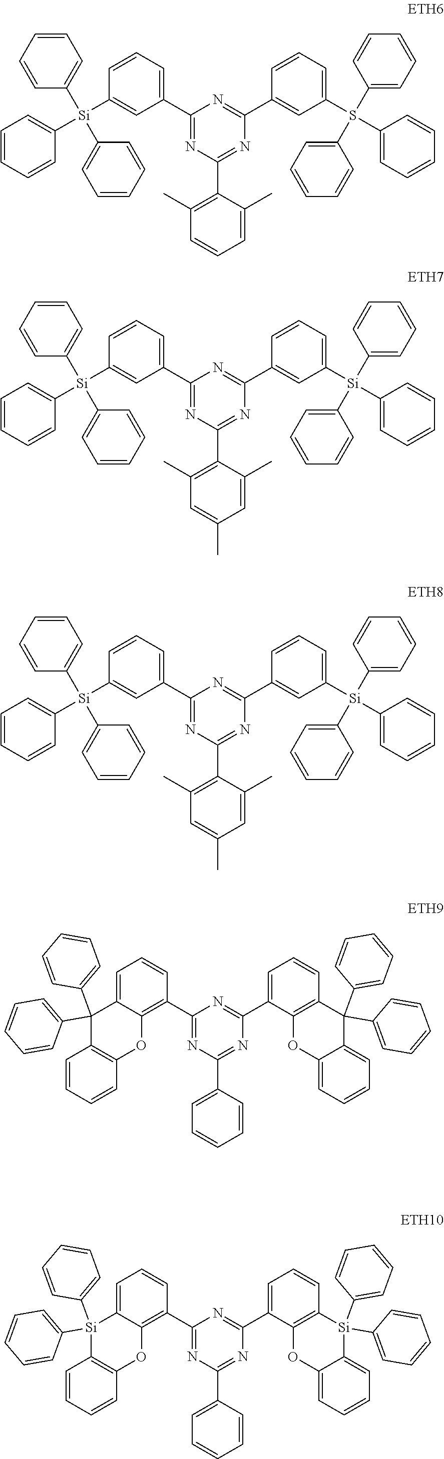

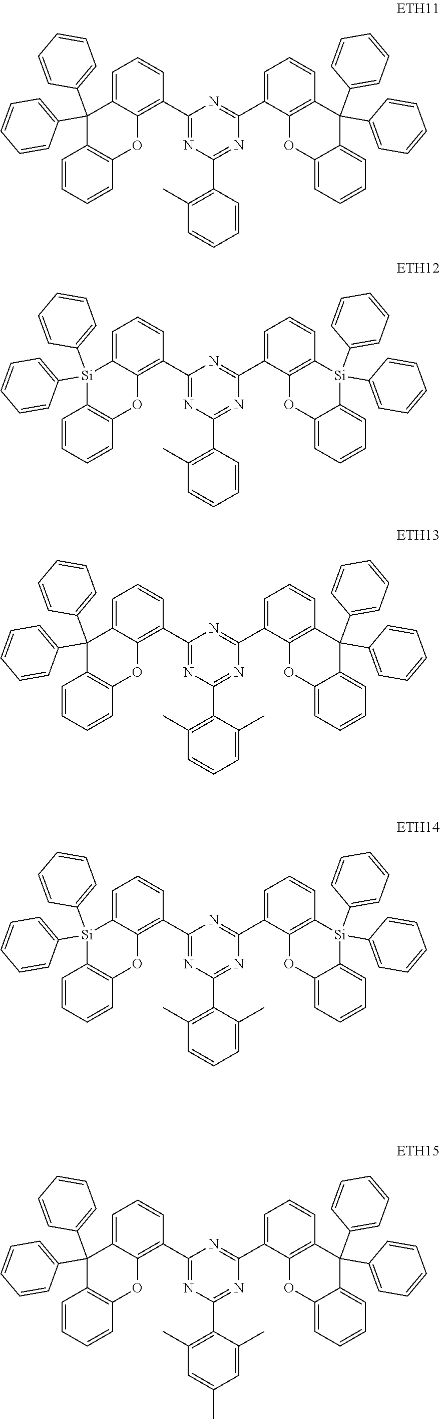

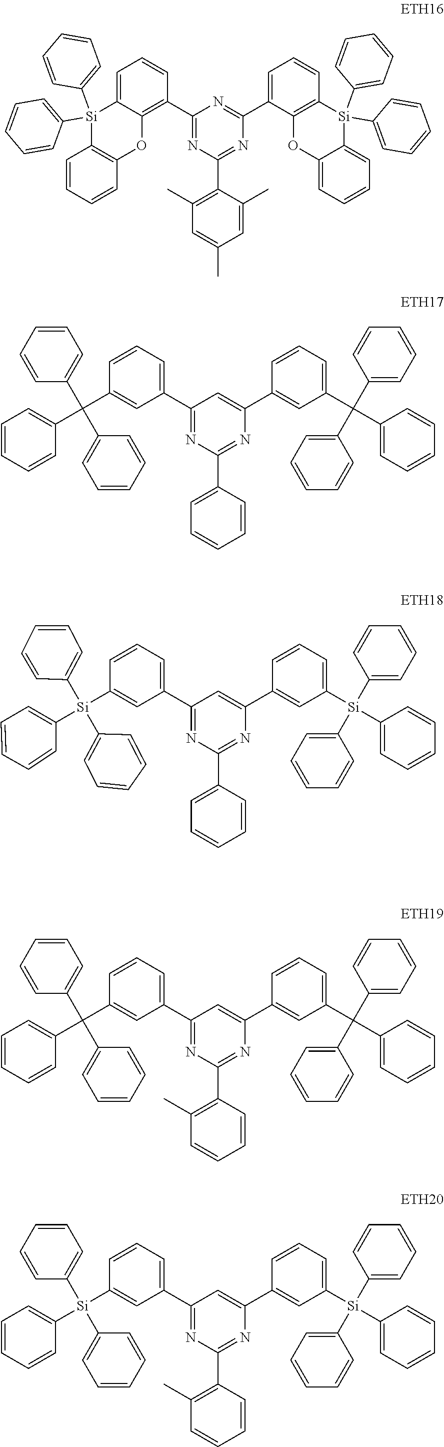

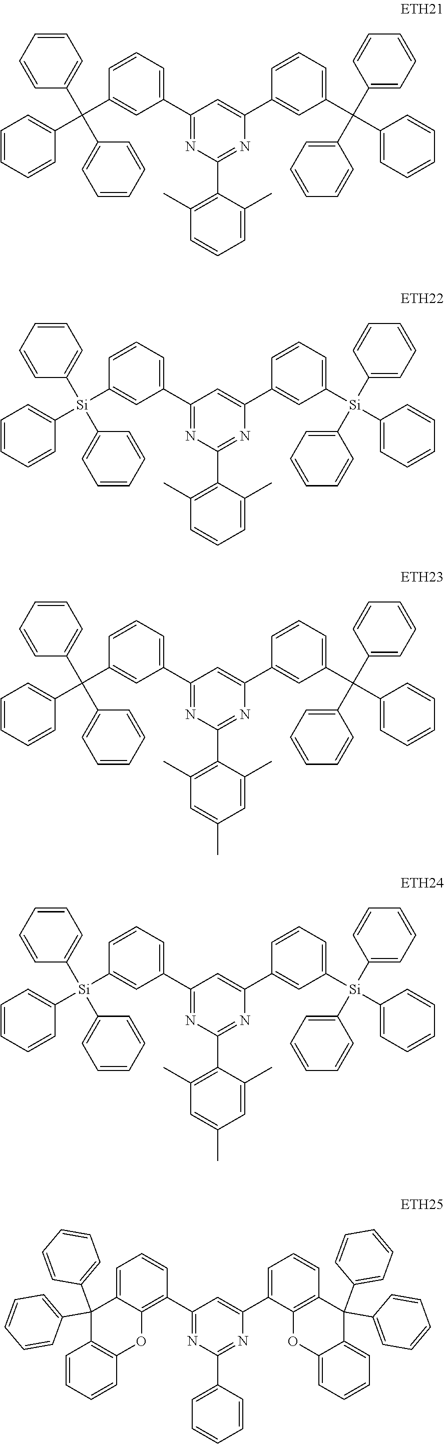

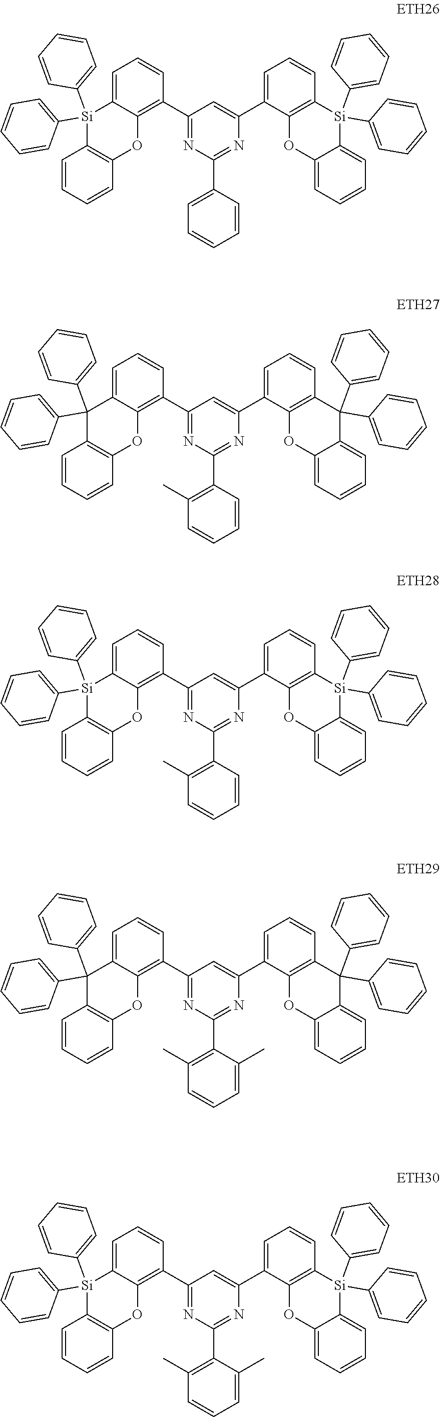

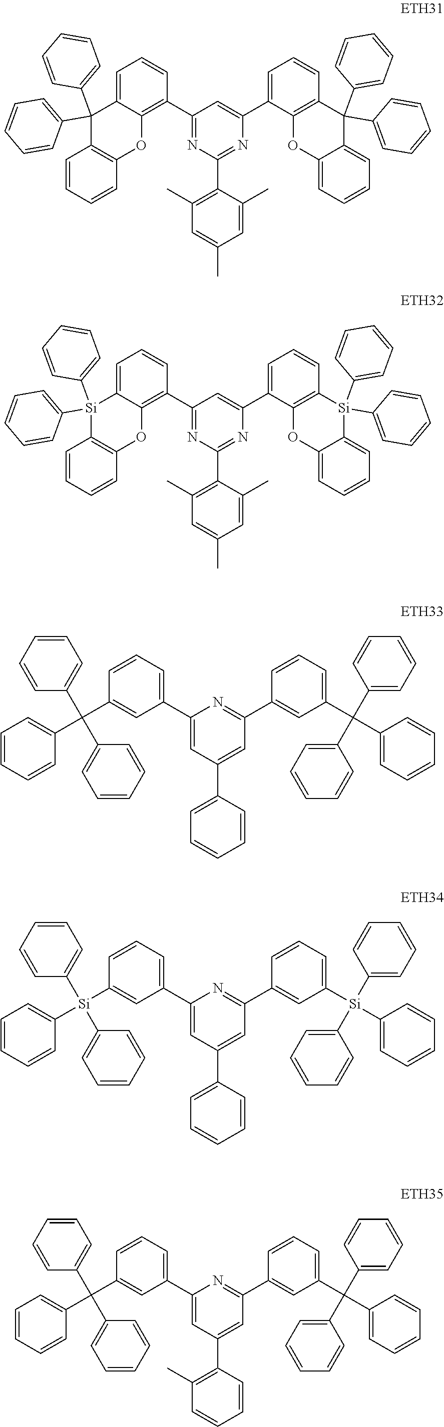

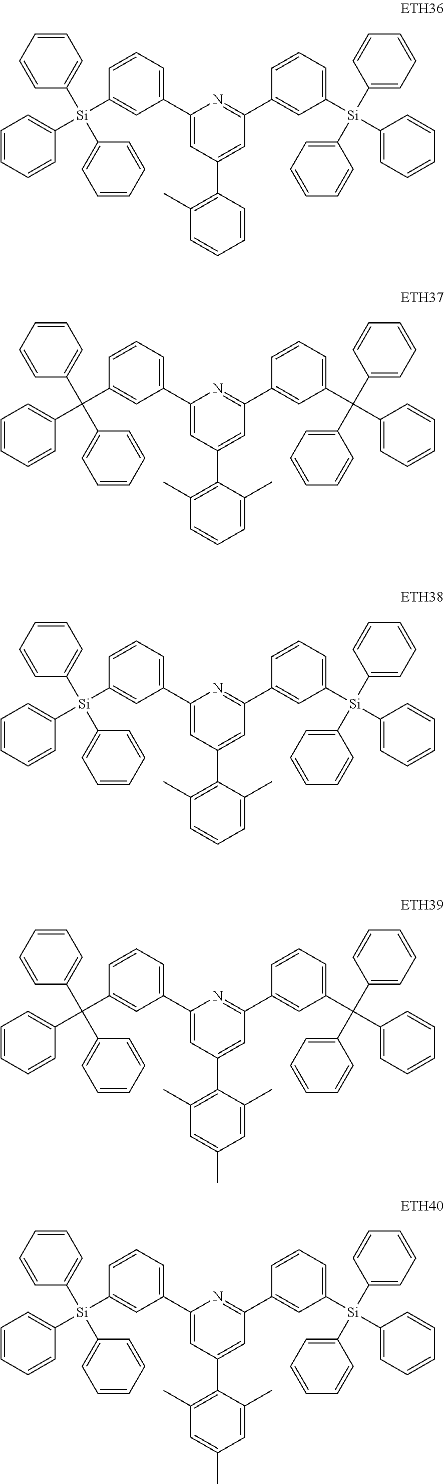

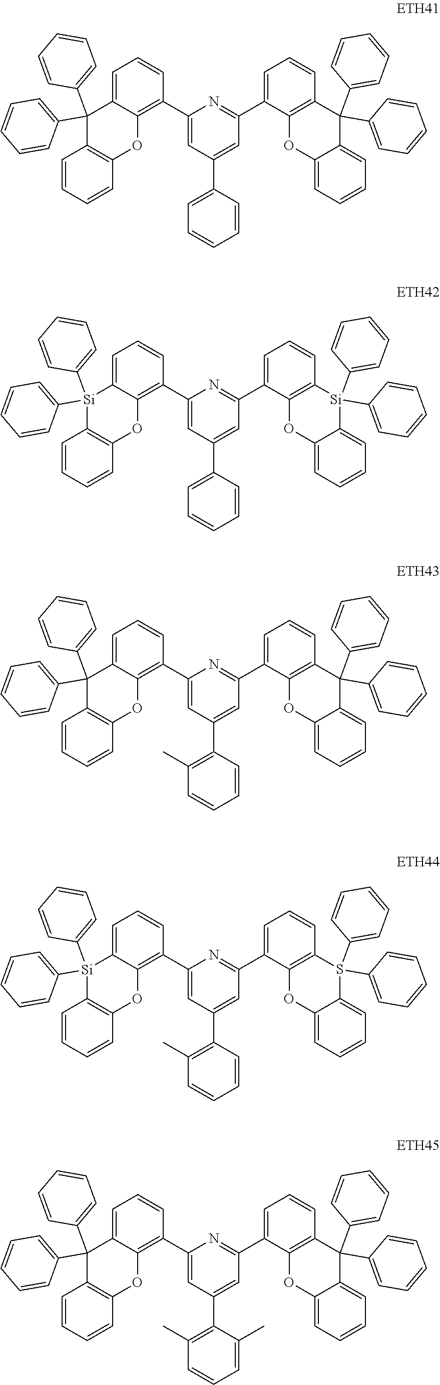

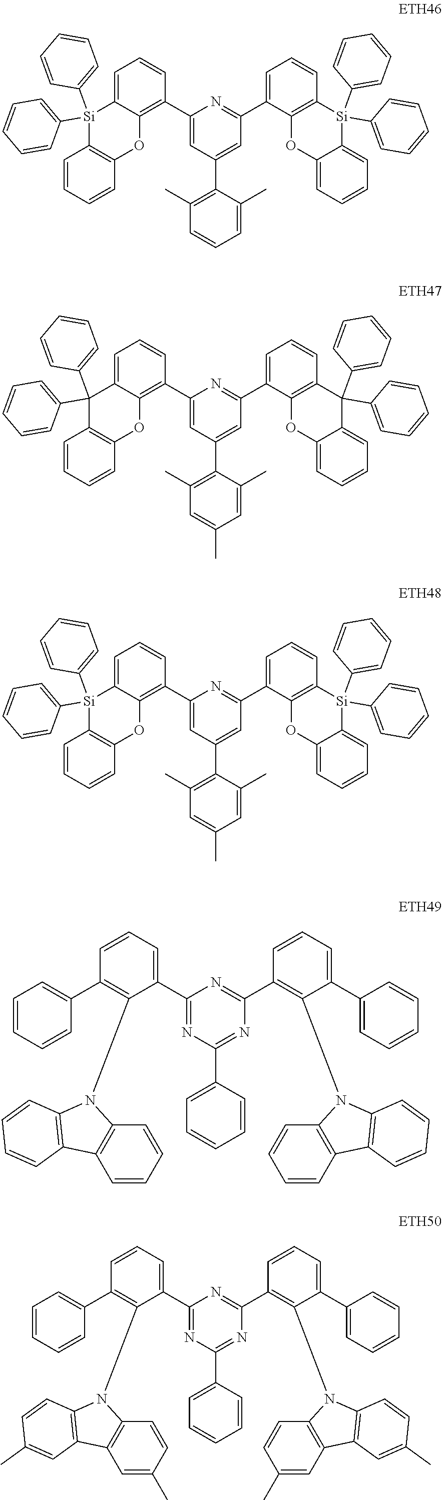

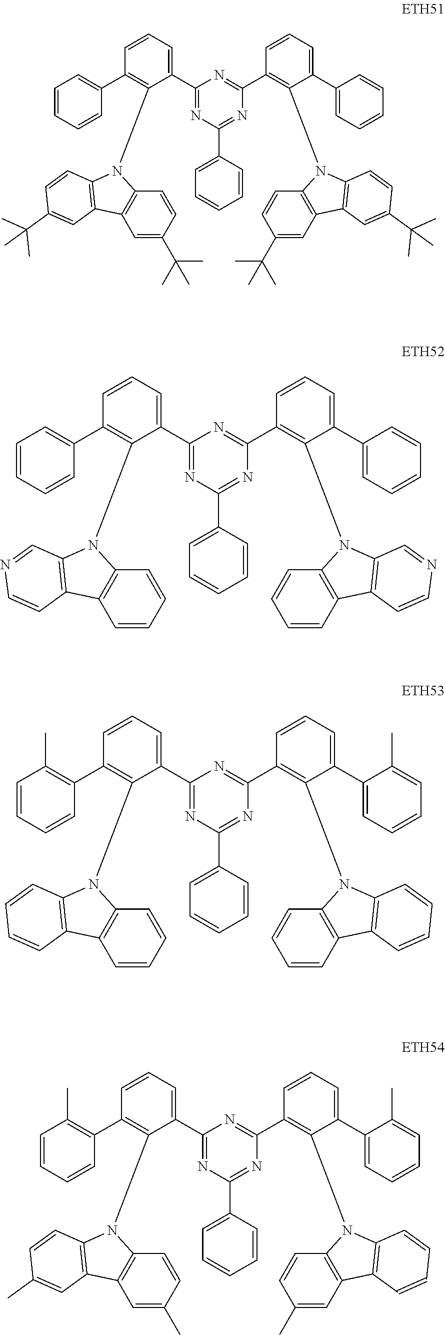

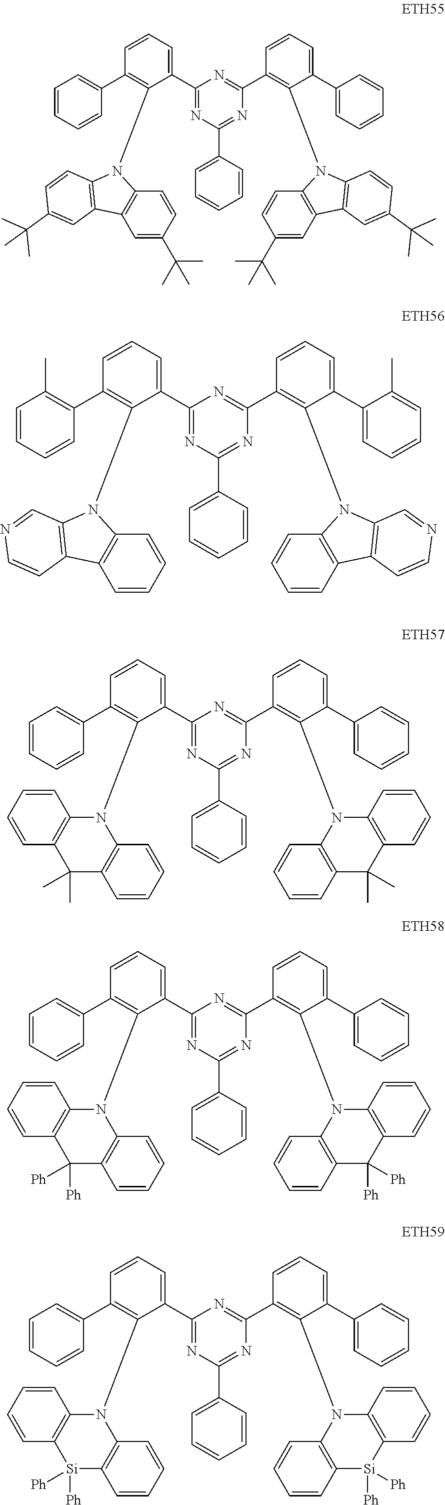

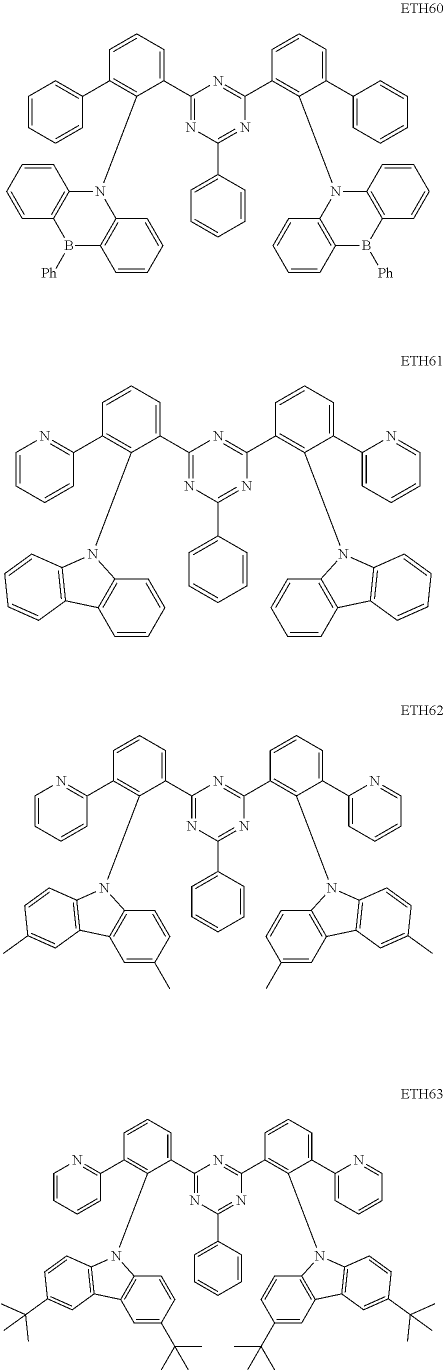

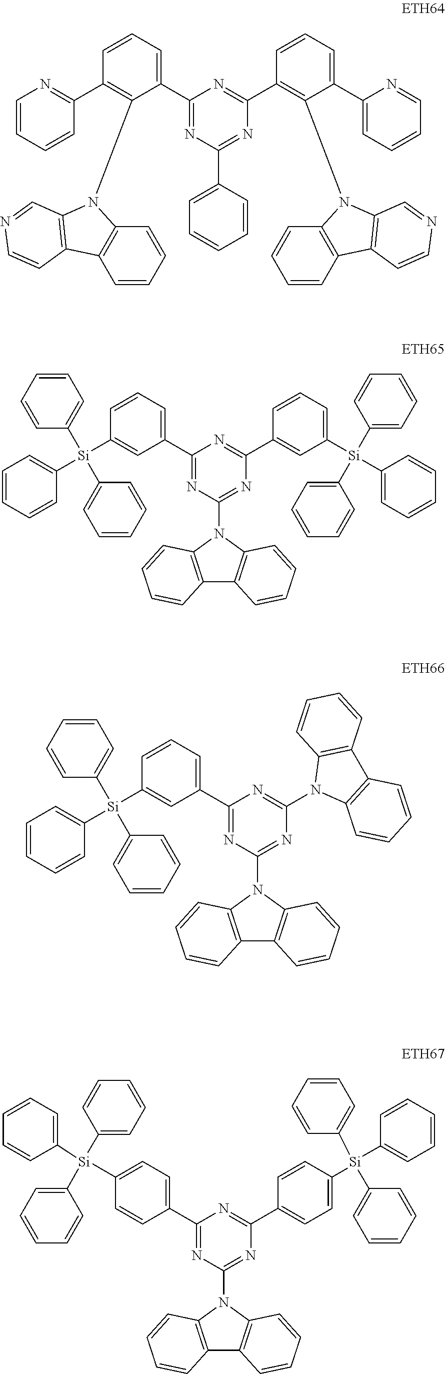 [SMILES: c1ccc(-c2nc(-c3cccc(-c4ccccn4)c3-n3c4ccccc4c4ccncc43)nc(-c3cccc(-c4ccccn4)c3-n3c4ccccc4c4ccncc43)n2)cc1 ; c1ccc([Si](c2ccccc2)(c2ccccc2)c2cccc(-c3nc(-c4cccc([Si](c5ccccc5)(c5ccccc5)c5ccccc5)c4)nc(-n4c5ccccc5c5ccccc54)n3)c2)cc1 ; c1ccc([Si](c2ccccc2)(c2ccccc2)c2cccc(-c3nc(-n4c5ccccc5c5ccccc54)nc(-n4c5ccccc5c5ccccc54)n3)c2)cc1 ; c1ccc([Si](c2ccccc2)(c2ccccc2)c2ccc(-c3nc(-c4ccc([Si](c5ccccc5)(c5ccccc5)c5ccccc5)cc4)nc(-n4c5ccccc5c5ccccc54)n3)cc2)cc1]

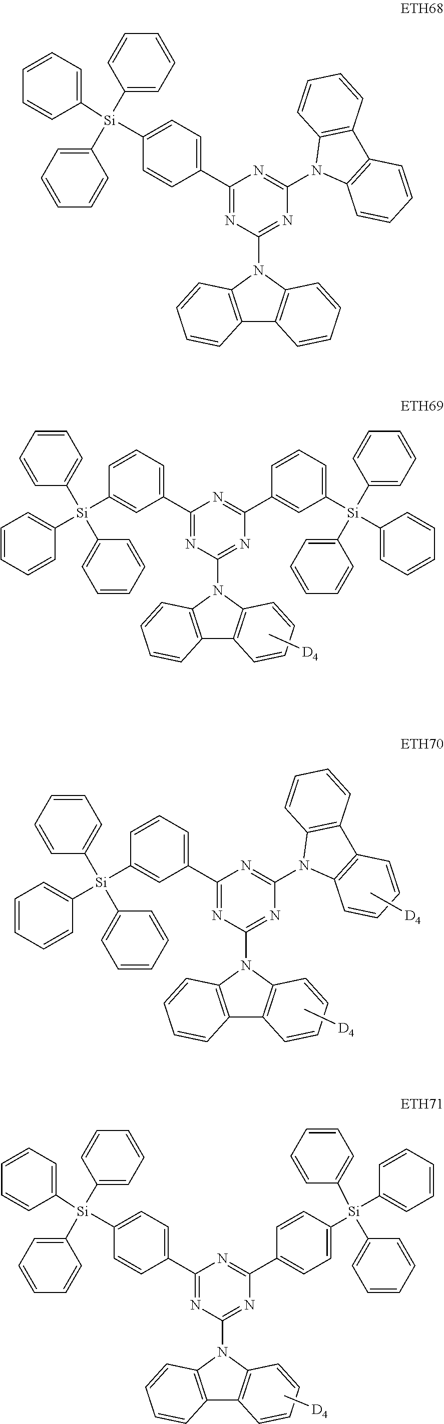

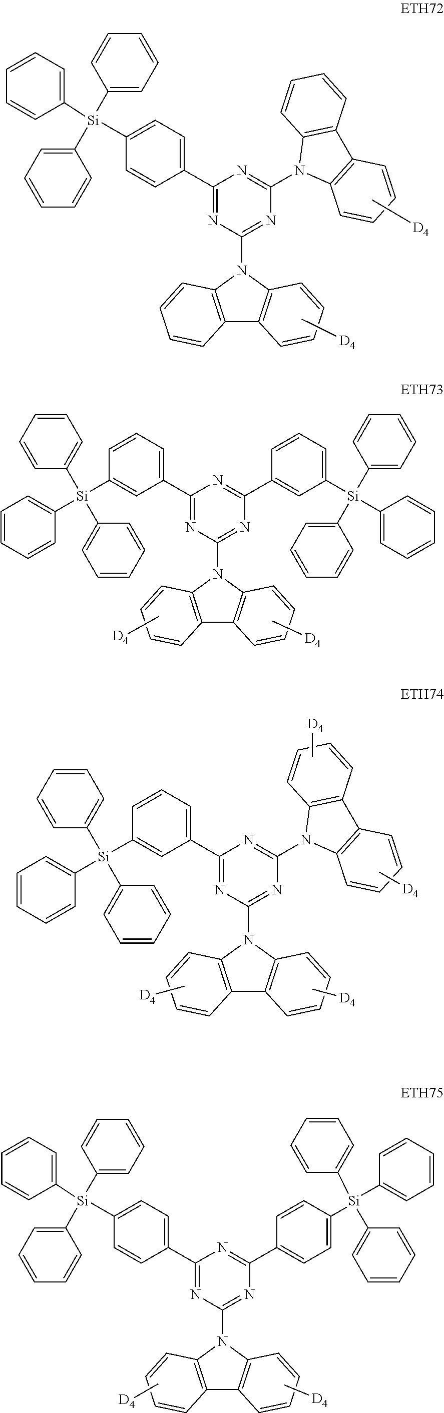

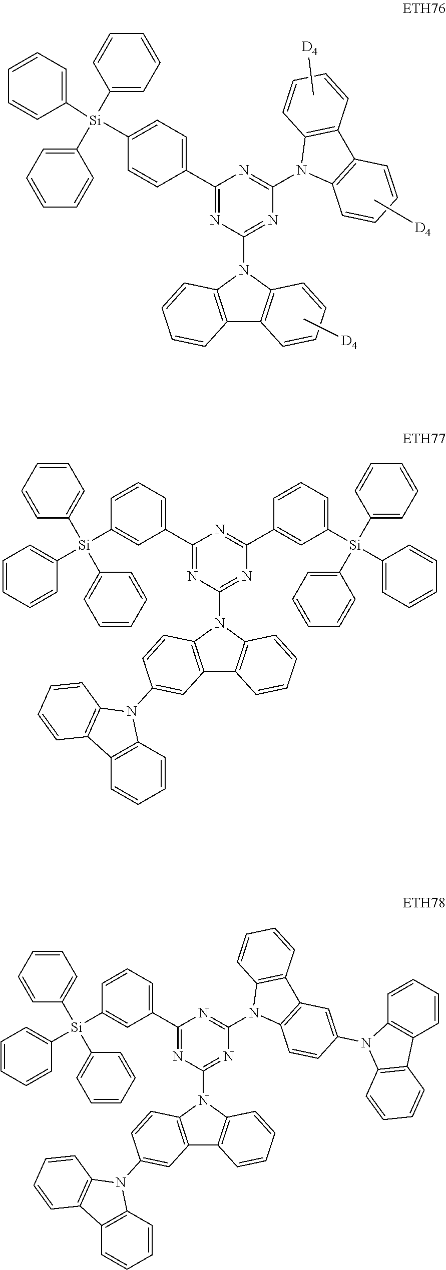

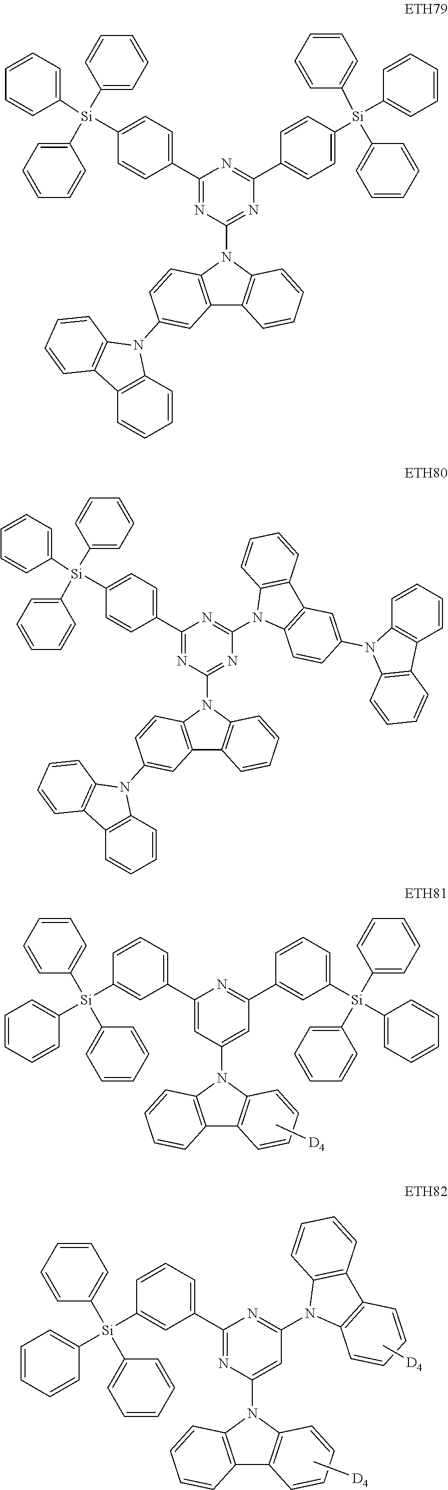

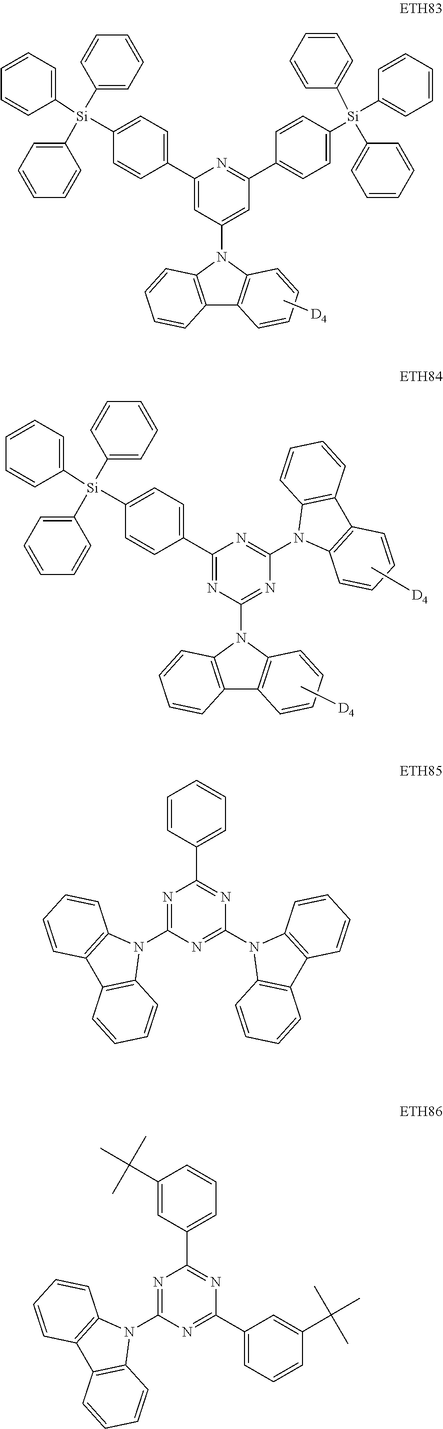

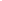

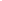

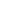

In the example compounds suggested in Compound Group 3, “D” refers to a deuterium atom, and “Ph” refers to an unsubstituted phenyl group.

The emission layer EML may include the second compound and the third compound, and the second compound and the third compound may form an exciplex. In the emission layer EML, the exciplex may be formed by a hole transport host and an electron transport host. In this case, the triplet energy of the exciplex formed by the hole transport host and the electron transport host may correspond to a difference between the lowest unoccupied molecular orbital (LUMO) energy level of the electron transport host and the highest occupied molecular orbital (HOMO) energy level of the hole transport host.

For example, the absolute value of the triplet energy level (T1) of the exciplex formed by the hole transport host and the electron transport host may be about 2.4 electron volt (eV) to about 3.0 eV. In some embodiments, the triplet energy of the exciplex may be a smaller value than the energy gap of each host material. The exciplex may have a triplet energy of about 3.0 eV or less, that is the energy gap between the hole transport host and the electron transport host.

In one or more embodiments, the emission layer EML may include a fourth compound in addition to the first compound to the third compound. The fourth compound may be utilized as a phosphorescence sensitizer of an emission layer EML. Because energy may transfer from the fourth compound to the first compound, light emission may arise.

For example, the emission layer EML may include an organometallic complex including platinum (Pt) as a central metal atom and ligands bonded to the central metal atom, as the fourth compound(s). In the light emitting device ED of one or more embodiments, the emission layer EML may include a compound represented by Formula D-1 as the fourth compound.

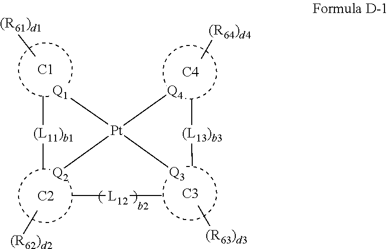

In Formula D-1, Q1 to Q4 may each independently be C or N.

In Formula D-1, C1 to C4 may each independently be a substituted or unsubstituted hydrocarbon ring of 5 to 30 ring-forming carbon atoms, or a substituted or unsubstituted heterocycle of 2 to 30 ring-forming carbon atoms.

In Formula D-1, L₁₁ to L₁₃ may each independently be a direct linkage, *—O—*, *—S—*,

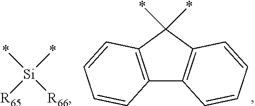

a substituted or unsubstituted divalent alkyl group of 1 to 20 carbon atoms, a substituted or unsubstituted arylene group of 6 to 30 ring-forming carbon atoms, or a substituted or unsubstituted heteroarylene group of 2 to 30 ring-forming carbon atoms. In L₁₁ to L₁₃, “—*” refers to a part connected with C1 to C4.

In Formula D-1, b1 to b3 may each independently be 0 or 1. When b1 is 0, C1 and C2 may be unconnected. When b2 is 0, C2 and C3 may be unconnected. When b3 is 0, C3 and C4 may be unconnected.

In Formula D-1, R₆₁ to R₆₆ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group of 1 to 20 carbon atoms, a substituted or unsubstituted alkenyl group of 2 to 20 carbon atoms, a substituted or unsubstituted aryl group of 6 to 60 ring-forming carbon atoms, or a substituted or unsubstituted heteroaryl group of 2 to 60 ring-forming carbon atoms. In some embodiments, each of R₆₁ to R₆₆ may be combined with an adjacent group to form a ring. R₆₁ to R₆₆ may each independently be a substituted or unsubstituted methyl group, or a substituted or unsubstituted t-butyl group.

In Formula D-1, d1 to d4 may each independently be an integer of 0 to 4. In

Formula D-1, when d1 to d4 are 0, the fourth compound may be unsubstituted with R₆₁ to R₆₄, respectively. A case where d1 to d4 are 4, and R₆₁ to R₆₄ are hydrogen atoms, may be the same as a case where d1 to d4 are 0. When d1 to d4 are integers of 2 or more, each of multiple R₆₁ to R₆₄ may be all the same, or at least one among multiple R₆₁ to R₆₄ may be different.

In Formula D-1, C1 to C4 may each independently be a substituted or unsubstituted hydrocarbon ring or a substituted or unsubstituted heterocycle, represented by any one selected from among C-1 to C-4.

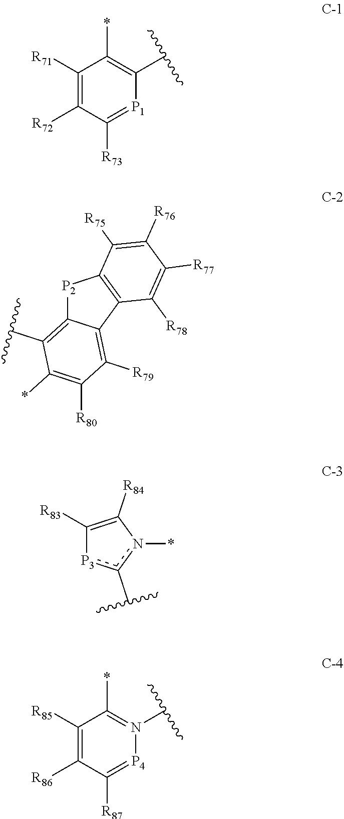

In C-1 to C-4, P₁ may be C—* or CR₇₄, P2 may be N—* or NR₈₁, P₃ may be N—* or NR₈₂, and P₄ may be C—* or CR₈₈. R₇₁ to R₈₈ may each independently be a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring.

In some embodiments, in C-1 to C-4, “

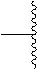

” is a part connected with a central metal atom of Pt, and “—*” corresponds to a part connected with an adjacent ring group (C1 to C4) or linker (L₁₁ to L₁₃).

The emission layer EML of one or more embodiments may include the first compound that is a fused polycyclic compound, and at least one selected from among the second to fourth compounds. For example, the emission layer EML may include the first compound, the second compound and the third compound. In the emission layer EML, the second compound and the third compound may form exciplex, and in the exciplex, energy transfer to the first compound may arise, and light emission may arise.

In some embodiments, the emission layer EML may include the first compound, the second compound, the third compound and the fourth compound. In the emission layer EML, the second compound and the third compound may form exciplex, and in the exciplex, energy transfer to the fourth compound and the first compound may arise, and light emission may arise. In one or more embodiments, the fourth compound may be a sensitizer. In the light emitting device ED of one or more embodiments, the fourth compound included in the emission layer EML may act as a sensitizer and may play the role of transferring energy from a host to the first compound that is a light-emitting dopant. For example, the fourth compound that is selected as (e.g., plays the role of) an auxiliary dopant may accelerate energy transfer to the first compound that is a light emitting dopant and increase the light emitting ratio of the first compound. Accordingly, the emission efficiency of the emission layer EML of one or more embodiments may be improved. In some embodiments, when the energy transfer to the first compound increases, excitons formed in the emission layer EML may not be accumulated but, instead, rapidly emit light, and the deterioration of a device may be reduced. Accordingly, the lifetime of the light emitting device ED of one or more embodiments may be enhanced or increased.

The light emitting device ED of one or more embodiments includes all of the first compound, the second compound, the third compound and the fourth compound, and the emission layer EML may include the combination of two host materials and two dopant materials. In the light emitting device ED of one or more embodiments, the emission layer EML may include the second compound and the third compound, which are two different hosts, the first compound which emits delayed fluorescence, and the fourth compound including an organometallic complex, concurrently (e.g., simultaneously), and may show excellent or suitable emission efficiency properties.

In one or more embodiments, the fourth compound represented by Formula D-1 may be represented by at least one selected from among the compounds represented in Compound Group 4. The emission layer EML may include at least one selected from among the compounds represented in Compound Group 4 as a sensitizer material.

### Compound Group 4

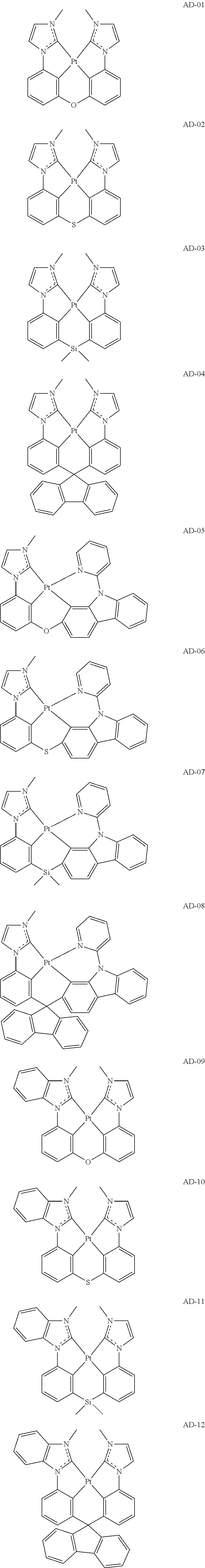

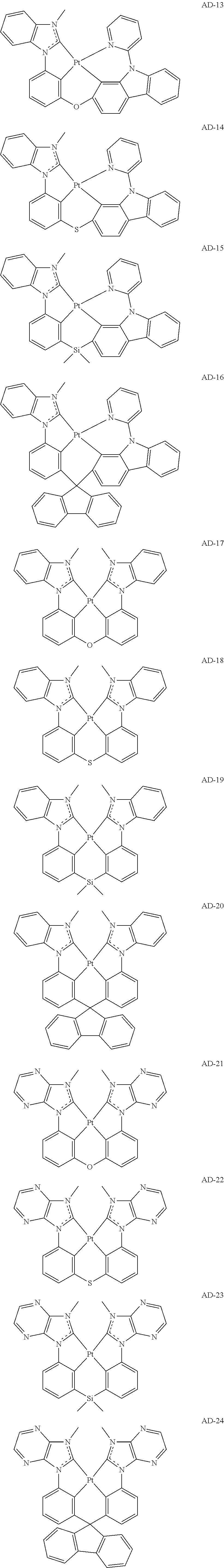

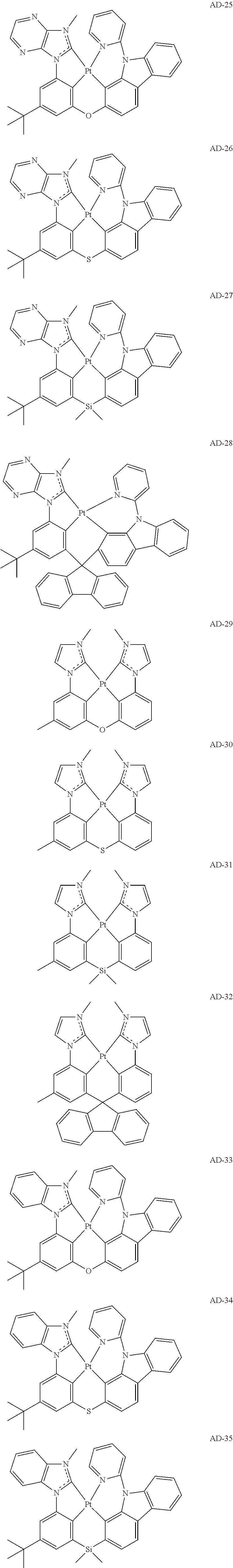

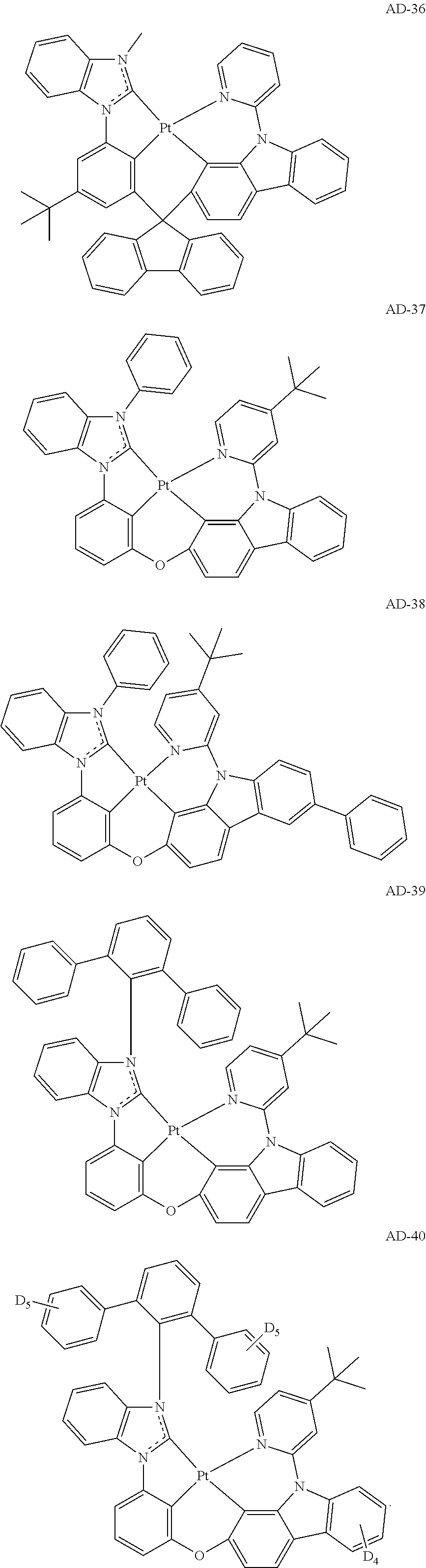

In the example compounds suggested in Compound Group 4, “D” refers to a deuterium atom.

In some embodiments, the light emitting device ED of one or more embodiments may include multiple emission layers. Multiple emission layers may be stacked in order and provided, and for example, a light emitting device ED including multiple emission layers may be to emit (e.g., configured to emit) white light. The light emitting device including multiple emission layers may be a light emitting device of a tandem structure. When the light emitting device ED includes multiple emission layers, at least one emission layer EML may include the first compound represented by Formula 1 of one or more embodiments. In some embodiments, when the light emitting device ED includes multiple emission layers, at least one emission layer EML may include all of the first compound, the second compound, the third compound and the fourth compound as described above.

In the light emitting device ED of one or more embodiments, when the emission layer EML includes all of the first compound, the second compound, and the third compound, the amount of the first compound may be about 0.1 wt % to about 5 wt % based on the total weight of the first compound, the second compound, and the third compound. However, one or more embodiments of the present disclosure is not limited thereto. When the amount of the first compound satisfies the described ratio, energy transfer from the second compound and the third compound to the first compound may increase, and accordingly, the emission efficiency and device lifetime may increase.

In the emission layer EML, the total amount of the second compound and the third compound may be the remaining amount excluding the amount of the first compound. For example, the total amount of the second compound and the third compound may be about 65 wt % to about 95 wt % based on the total weight of the first compound, the second compound and the third compound.

In the total amount of the second compound and the third compound, the weight ratio of the second compound and the third compound may be about 3:7 to about 7:3.

When the total amount of the second compound and the third compound satisfies the described ratio, charge balance properties in the emission layer EML may be improved, and emission efficiency and device lifetime may be improved. When the total amount of the second compound and the third compound deviates from the described ratio range, charge balance in the emission layer EML may be broken, emission efficiency may be degraded, and the device may be easily deteriorated.

When the emission layer EML includes the fourth compound, the amount of the fourth compound may be about 10 wt % to 30 wt % based on the total weight of the first compound, the second compound, the third compound and the fourth compound in the emission layer EML. However, one or more embodiments of the present disclosure is not limited thereto. When the amount of the fourth compound satisfies the described amount, energy transfer from a host to the first compound that is a light emitting dopant may increase, and emission ratio may be improved. Accordingly, the emission efficiency of the emission layer EML may be improved. When the amount ratio of the first compound, the second compound, the third compound and the fourth compound, included in the emission layer EML satisfies the described amount ratio, excellent or suitable emission efficiency and long lifetime may be achieved.

In the light emitting device ED of one or more embodiments, the emission layer EML may further include one or more selected from among anthracene derivatives, pyrene derivatives, fluoranthene derivatives, chrysene derivatives, dihydrobenzanthracene derivatives, and/or triphenylene derivatives. For example, the emission layer EML may include anthracene derivative(s) or pyrene derivative(s).

In the light emitting devices ED of one or more embodiments, shown in FIG. 3 to FIG. 6, the emission layer EML may further include suitable hosts and dopants in addition to the described host and dopant. For example, the emission layer EML may include a compound represented by Formula E-1. The compound represented by Formula E-1 may be utilized as a fluorescence host material.

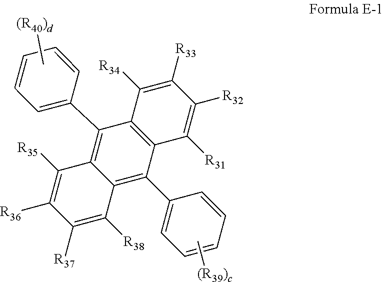

In Formula E-1, R₃₁ to R₄₀ may each independently be a hydrogen atom, a deuterium atom, a halogen atom, a substituted or unsubstituted silyl group, a substituted or unsubstituted thiol group, a substituted or unsubstituted oxy group, a substituted or unsubstituted alkyl group of 1 to 10 carbon atoms, a substituted or unsubstituted alkenyl group of 2 to 10 carbon atoms, a substituted or unsubstituted aryl group of 6 to 30 ring-forming carbon atoms, or a substituted or unsubstituted heteroaryl group of 2 to 30 ring-forming carbon atoms, and/or combined with an adjacent group to form a ring. In some embodiments, R₃₁ to R₄₀ may be combined with an adjacent group to form a saturated hydrocarbon ring, an unsaturated hydrocarbon ring, a saturated heterocycle or an unsaturated heterocycle.

In Formula E-1, “c” and “d” may each independently be an integer of 0 to 5.

Formula E-1 may be represented by any one selected from among Compound E₁ to Compound E₁₉.

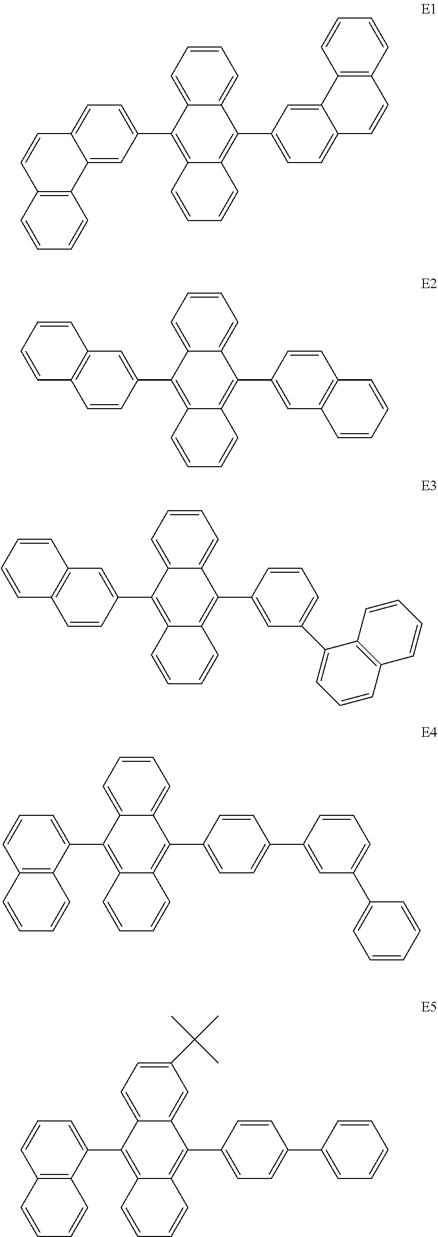

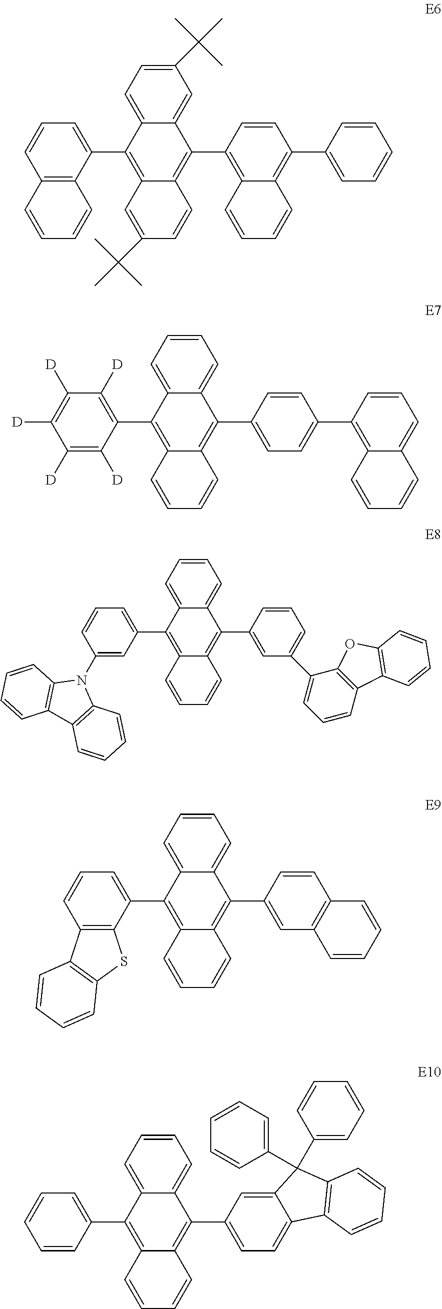

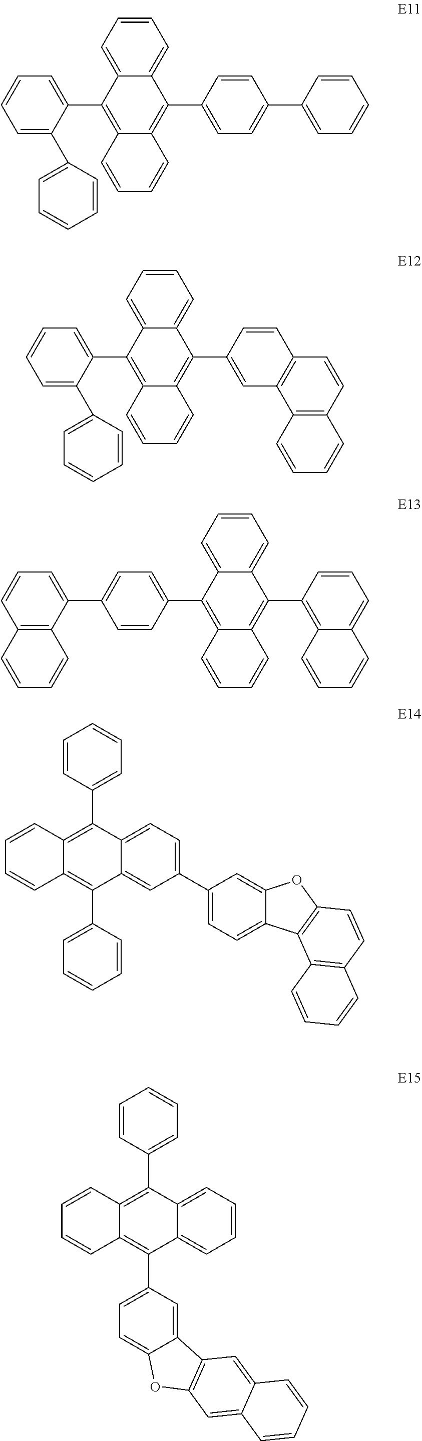

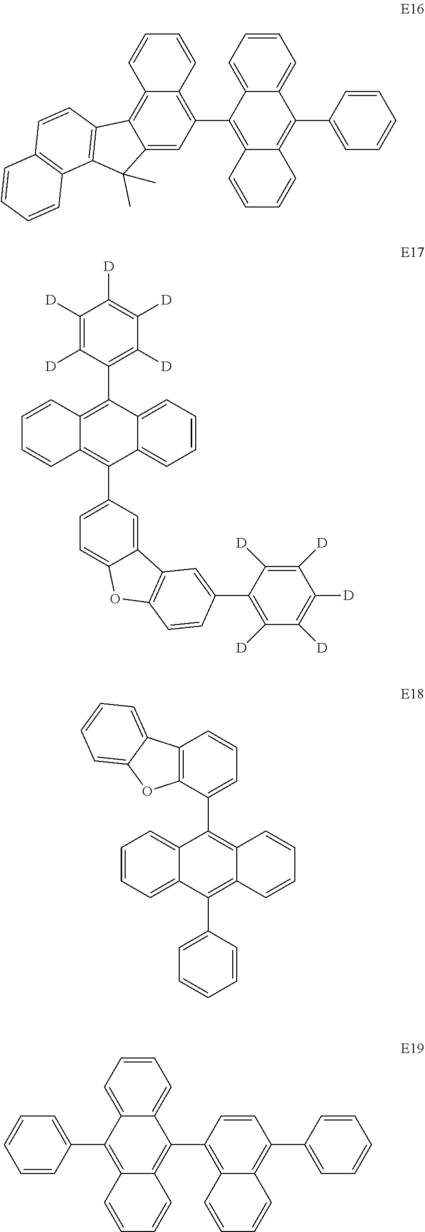

In one or more embodiments, the emission layer EML may include a compound represented by Formula E-2a or Formula E-2b. The compound represented by Formula E-2a or Formula E-2b may be utilized as a phosphorescence host material.

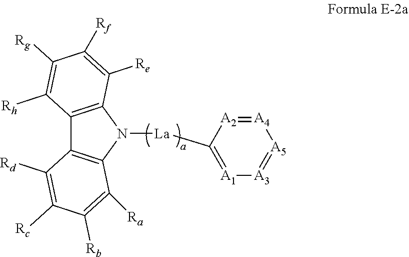

In Formula E-2a, “a” may be an integer of 0 to 10, La may be a direct linkage, a substituted or unsubstituted arylene group of 6 to 30 ring-forming carbon atoms, or a substituted or unsubstituted heteroarylene group of 2 to 30 ring-forming carbon atoms. In some embodiments, when “a” is an integer of 2 or more, multiple La may each independently be a substituted or unsubstituted arylene group of 6 to 30 ring-forming carbon atoms, or a substituted or unsubstituted heteroarylene group of 2 to 30 ring-forming carbon atoms.

In some embodiments, in Formula E-2a, A₁ to A₅ may each independently be N or CRi. Rₐ to Rᵢ may each independently be a hydrogen atom, a deuterium atom, a substituted or unsubstituted amine group, a substituted or unsubstituted thiol group, a substituted or unsubstituted oxy group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, and/or may be combined with an adjacent group to form a ring. Rₐ to Rᵢ may be combined with an adjacent group to form a hydrocarbon ring or a heterocycle including N, O, S, etc. as a ring-forming atom.

In some embodiments, in Formula E-2a, two or three selected from among A₁ to A₅ may be N, and the remainder may be CRi.

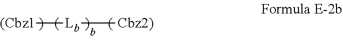

In Formula E-2b, Cbz1 and Cbz2 may each independently be an unsubstituted carbazole group, or a carbazole group substituted with an aryl group of 6 to 30 ring-forming carbon atoms. L_{b} may be a direct linkage, a substituted or unsubstituted arylene group of 6 to 30 ring-forming carbon atoms, or a substituted or unsubstituted heteroarylene group of 2 to 30 ring-forming carbon atoms. “b” is an integer of 0 to 10, and when “b” is an integer of 2 or more, multiple L_{b} may each independently be a substituted or unsubstituted arylene group of 6 to 30 ring-forming carbon atoms, or a substituted or unsubstituted heteroarylene group of 2 to 30 ring-forming carbon atoms.

The compound represented by Formula E-2a or Formula E-2b may be represented by any one selected from among the compounds in Compound Group E-2. However, the compounds shown in Compound Group E-2 are only illustrations, and the compound represented by Formula E-2a or Formula E-2b is not limited to the compounds represented in Compound Group E-2.

### Compound Group E-2

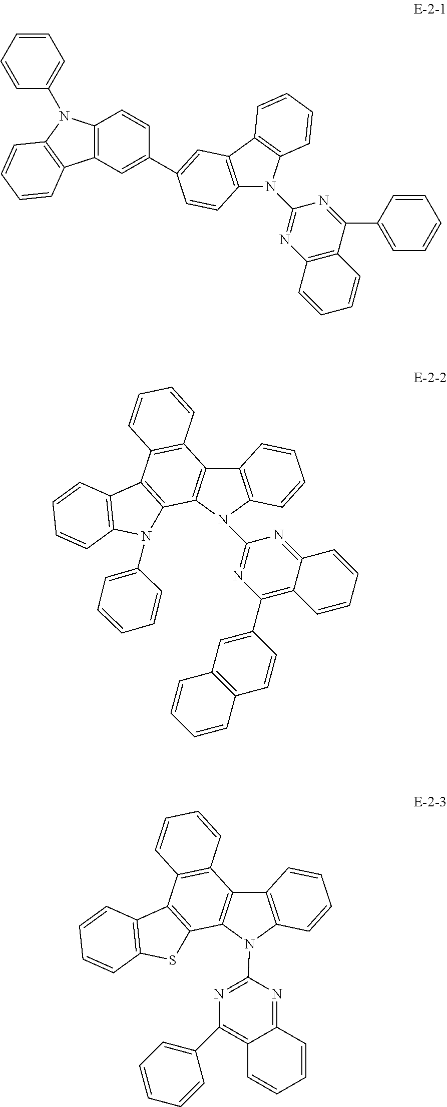 [SMILES: c1ccc(-c2nc(-n3c4ccccc4c4cc(-c5ccc6c(c5)c5ccccc5n6-c5ccccc5)ccc43)nc3ccccc23)cc1 ; c1ccc(-n2c3ccccc3c3c4ccccc4c4c5ccccc5n(-c5nc(-c6ccc7ccccc7c6)c6ccccc6n5)c4c32)cc1 ; c1ccc(-c2nc(-n3c4ccccc4c4c5ccccc5c5c6ccccc6sc5c43)nc3ccccc23)cc1]

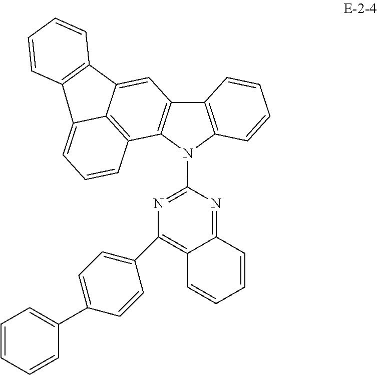 [SMILES: c1ccc(-c2ccc(-c3nc(-n4c5ccccc5c5cc6c7c(cccc7c54)-c4ccccc4-6)nc4ccccc34)cc2)cc1]

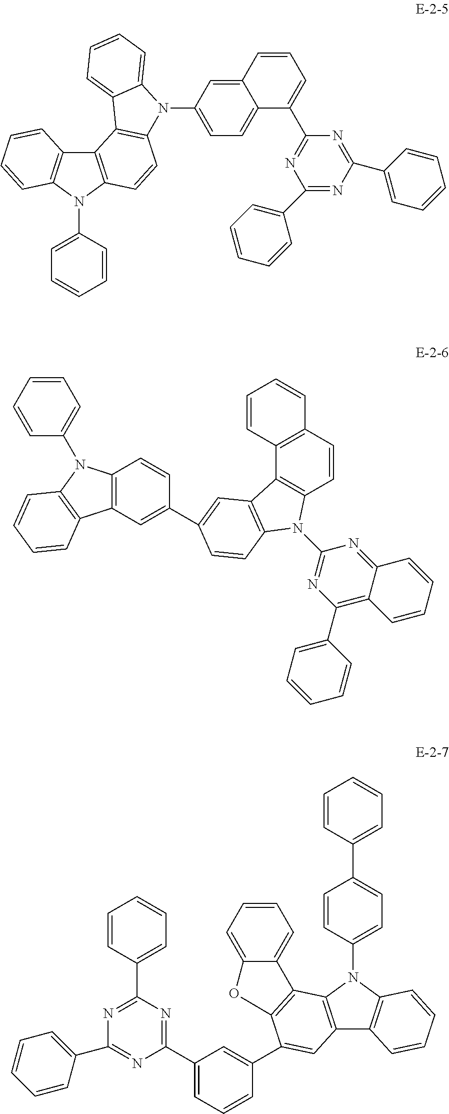 [SMILES: c1ccc(-c2nc(-c3ccccc3)nc(-c3cccc4cc(-n5c6ccccc6c6c7c8ccccc8n(-c8ccccc8)c7ccc65)ccc34)n2)cc1 ; c1ccc(-c2nc(-n3c4ccc(-c5ccc6c(c5)c5ccccc5n6-c5ccccc5)cc4c4c5ccccc5ccc43)nc3ccccc23)cc1 ; c1ccc(-c2ccc(-n3c4ccccc4c4cc(-c5cccc(-c6nc(-c7ccccc7)nc(-c7ccccc7)n6)c5)c5oc6ccccc6c5c43)cc2)cc1]

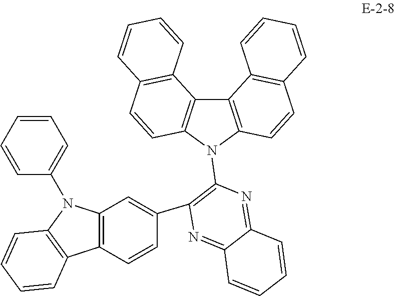 [SMILES: c1ccc(-n2c3ccccc3c3ccc(-c4nc5ccccc5nc4-n4c5ccc6ccccc6c5c5c6ccccc6ccc54)cc32)cc1]

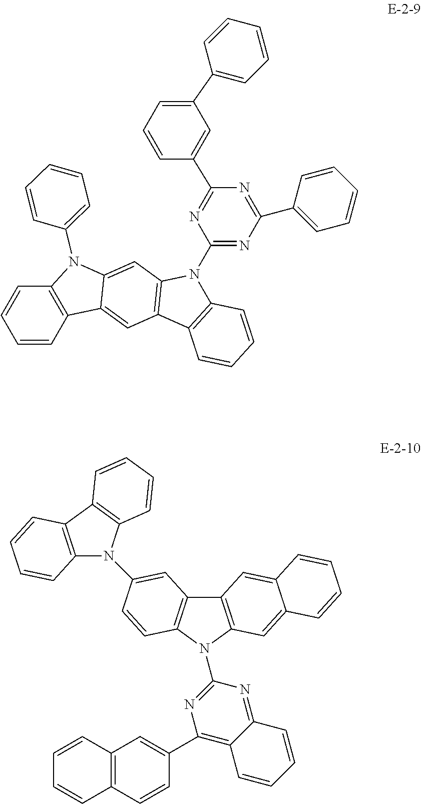 [SMILES: c1ccc(-c2cccc(-c3nc(-c4ccccc4)nc(-n4c5ccccc5c5cc6c7ccccc7n(-c7ccccc7)c6cc54)n3)c2)cc1 ; c1ccc2cc(-c3nc(-n4c5ccc(-n6c7ccccc7c7ccccc76)cc5c5cc6ccccc6cc54)nc4ccccc34)ccc2c1]

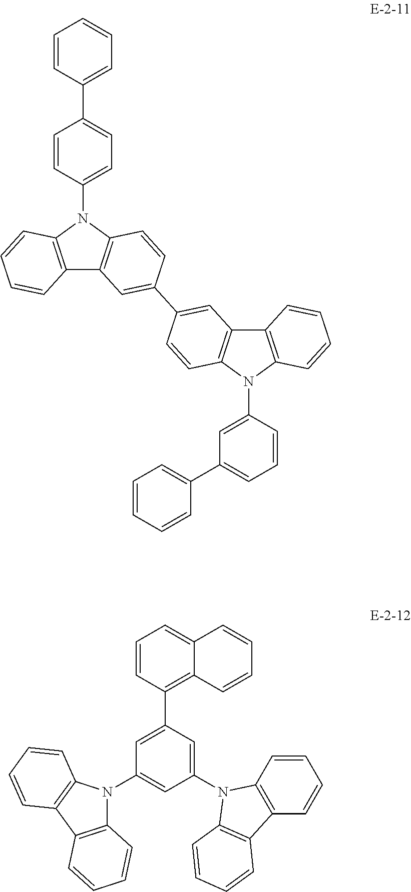 [SMILES: c1ccc(-c2ccc(-n3c4ccccc4c4cc(-c5ccc6c(c5)c5ccccc5n6-c5cccc(-c6ccccc6)c5)ccc43)cc2)cc1 ; c1ccc2c(-c3cc(-n4c5ccccc5c5ccccc54)cc(-n4c5ccccc5c5ccccc54)c3)cccc2c1]

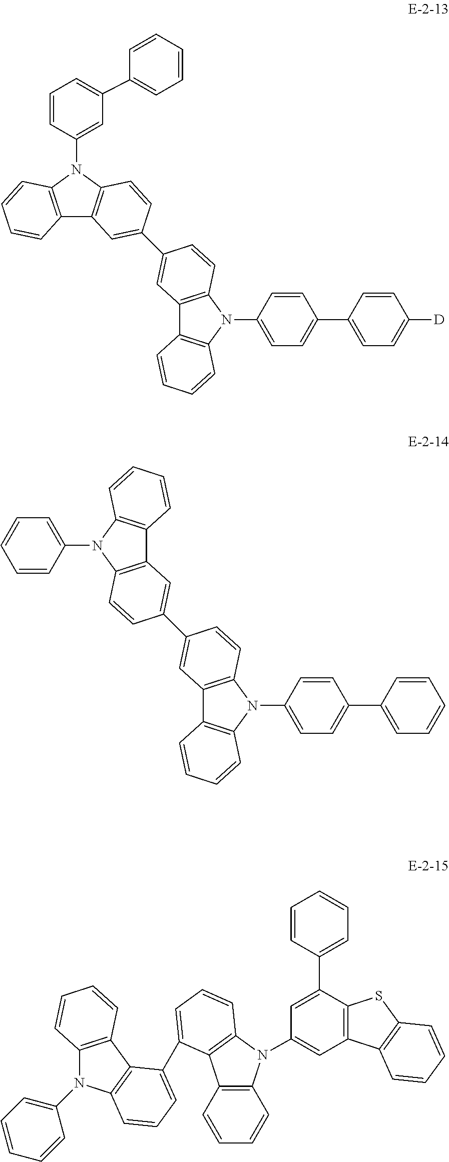 [SMILES: [2H]c1ccc(-c2ccc(-n3c4ccccc4c4cc(-c5ccc6c(c5)c5ccccc5n6-c5cccc(-c6ccccc6)c5)ccc43)cc2)cc1 ; c1ccc(-c2ccc(-n3c4ccccc4c4cc(-c5ccc6c(c5)c5ccccc5n6-c5ccccc5)ccc43)cc2)cc1 ; c1ccc(-c2cc(-n3c4ccccc4c4c(-c5cccc6c5c5ccccc5n6-c5ccccc5)cccc43)cc3c2sc2ccccc23)cc1]

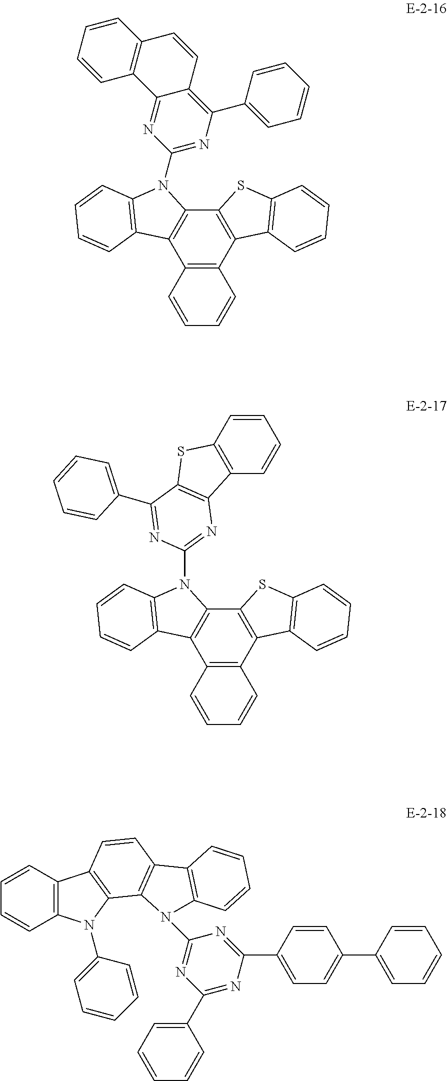 [SMILES: c1ccc(-c2nc(-n3c4ccccc4c4c5ccccc5c5c6ccccc6sc5c43)nc3c2ccc2ccccc23)cc1 ; c1ccc(-c2nc(-n3c4ccccc4c4c5ccccc5c5c6ccccc6sc5c43)nc3c2sc2ccccc23)cc1 ; c1ccc(-c2ccc(-c3nc(-c4ccccc4)nc(-n4c5ccccc5c5ccc6c7ccccc7n(-c7ccccc7)c6c54)n3)cc2)cc1]

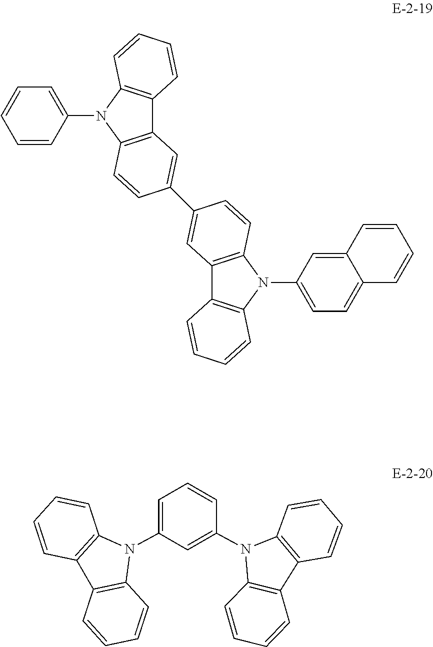 [SMILES: c1ccc(-n2c3ccccc3c3cc(-c4ccc5c(c4)c4ccccc4n5-c4ccc5ccccc5c4)ccc32)cc1 ; c1cc(-n2c3ccccc3c3ccccc32)cc(-n2c3ccccc3c3ccccc32)c1]

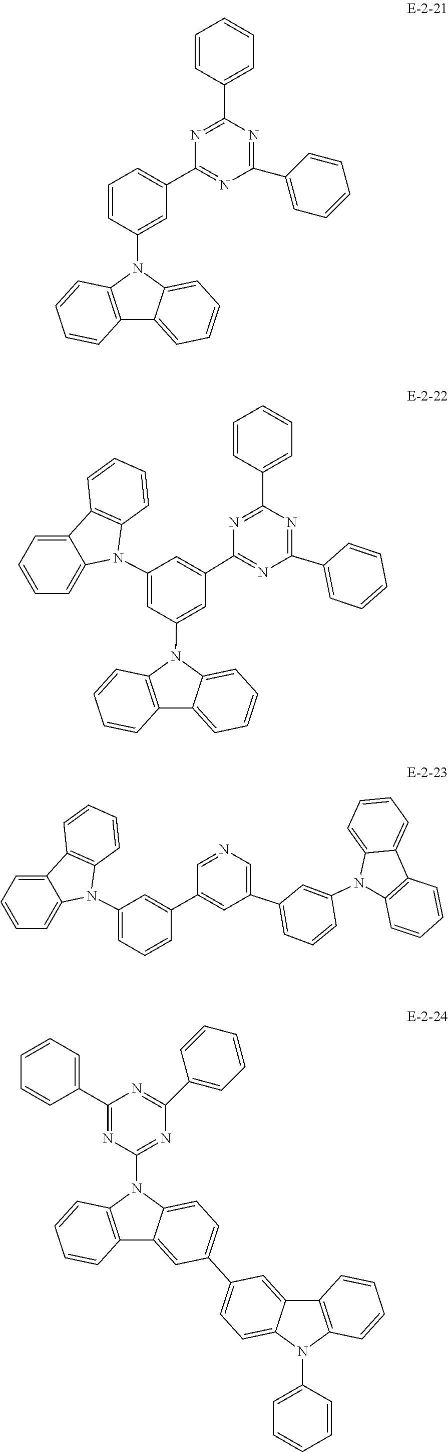 [SMILES: c1ccc(-c2nc(-c3ccccc3)nc(-c3cccc(-n4c5ccccc5c5ccccc54)c3)n2)cc1 ; c1ccc(-c2nc(-c3ccccc3)nc(-c3cc(-n4c5ccccc5c5ccccc54)cc(-n4c5ccccc5c5ccccc54)c3)n2)cc1 ; c1cc(-c2cncc(-c3cccc(-n4c5ccccc5c5ccccc54)c3)c2)cc(-n2c3ccccc3c3ccccc32)c1 ; c1ccc(-c2nc(-c3ccccc3)nc(-n3c4ccccc4c4cc(-c5ccc6c(c5)c5ccccc5n6-c5ccccc5)ccc43)n2)cc1]

The emission layer EML may further include a common material that is suitable in the art as a host material. For example, the emission layer EML may include as a host material, at least one selected from among bis (4-(9H-carbazol-9-yl) phenyl) diphenylsilane (BCPDS), (4-(1-(4-(diphenylamino) phenyl) cyclohexyl) phenyl) diphenyl-phosphine oxide (POPCPA), bis[2-(diphenylphosphino)phenyl] ether oxide (DPEPO), 4,4′-bis(N-carbazolyl)-1,1′-biphenyl (CBP), 1,3-bis(carbazol-9-yl)benzene (mCP), 2,8-bis(diphenylphosphoryl)dibenzo[b,d]furan (PPF), 4,4′,4″-tris(carbazol-9-yl)-triphenylamine (TCTA), and/or 1,3,5-tris(1-phenyl-1H-benzo[d]imidazole-2-yl)benzene (TPBi). However, one or more embodiments of the present disclosure is not limited thereto. For example, tris(8-hydroxyquinolinato)aluminum (Alq₃), 9,10-di(naphthalene-2-yl)anthracene (ADN), 2-tert-butyl-9,10-di(naphth-2-yl)anthracene (TBADN), distyrylarylene (DSA), 4,4′-bis(9-carbazolyl)-2,2′-dimethyl-biphenyl (CDBP), 2-methyl-9,10-bis(naphthalen-2-yl)anthracene (MADN), hexaphenyl cyclotriphosphazene (CP1), 1,4-bis(triphenylsilyl)benzene (UGH2), hexaphenylcyclotrisiloxane (DPSiO₃), octaphenylcyclotetra siloxane (DPSiO₄), and/or the like may be utilized as the host material.

The emission layer EML may include a compound represented by Formula M-a. The compound represented by Formula M-a may be utilized as a phosphorescence dopant material.

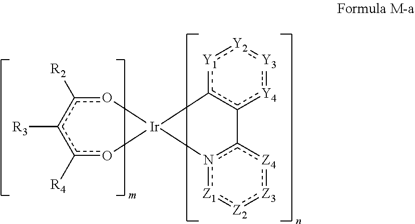

In Formula M-a, Y₁ to Y₄, and Z₁ to Z₄ may each independently be CR₁ or N, and R₁ to R₄ may each independently be a hydrogen atom, a deuterium atom, a substituted or unsubstituted amine group, a substituted or unsubstituted thiol group, a substituted or unsubstituted oxy group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, and/or may be combined with an adjacent group to form a ring. In Formula M-a, “m” is 0 or 1, and “n” is 2 or 3. In Formula M-a, when “m” is 0, “n” is 3, and when “m” is 1, “n” is 2.

The compound represented by Formula M-a may be utilized as a phosphorescence dopant.

The compound represented by Formula M-a may be represented by any one selected from among Compounds M-a1 to M-a25. However, Compounds M-a1 to M-a25 are examples, and the compound represented by Formula M-a is not limited to the compounds represented by Compounds M-a1 to M-a25.

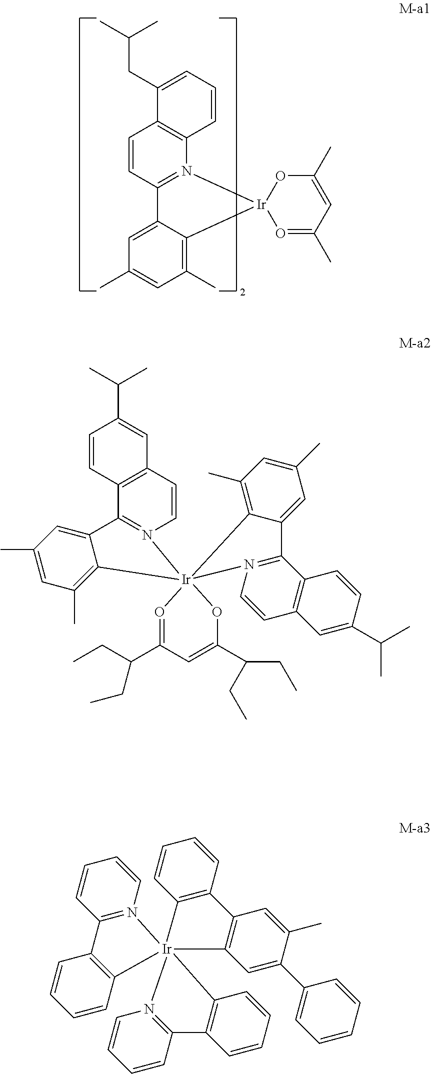

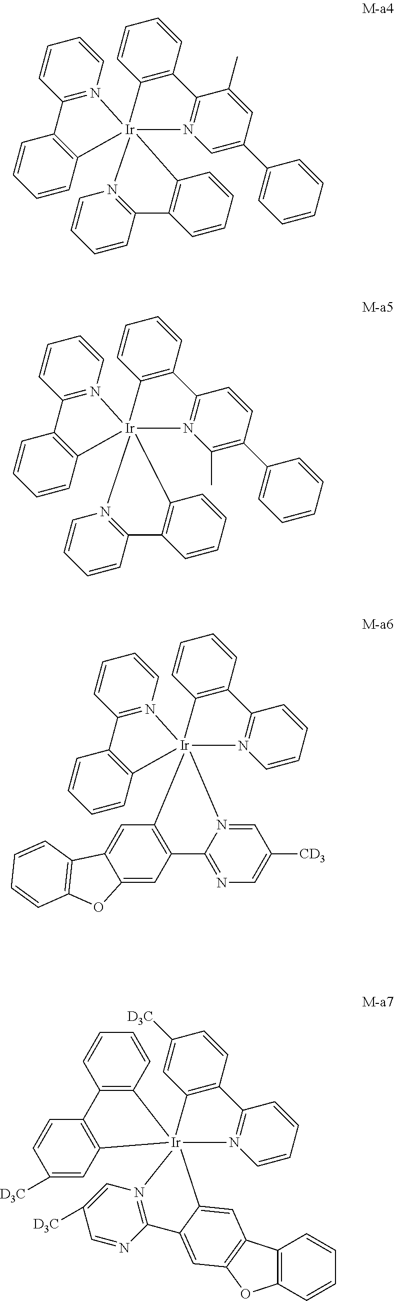

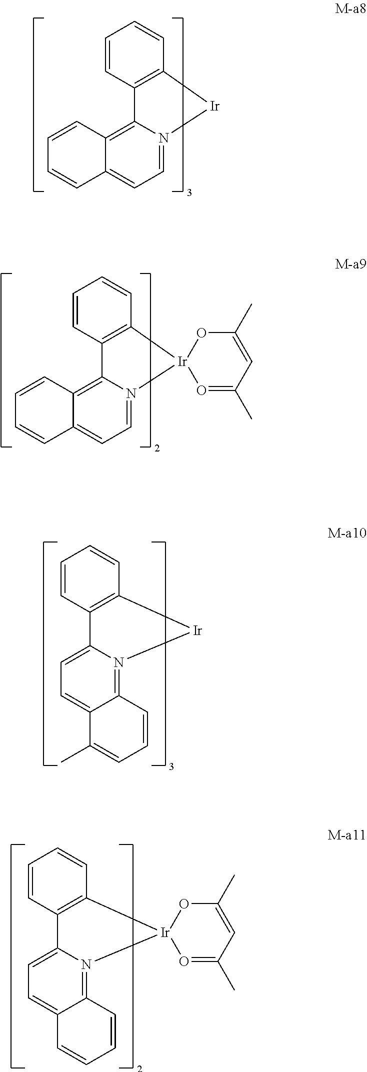

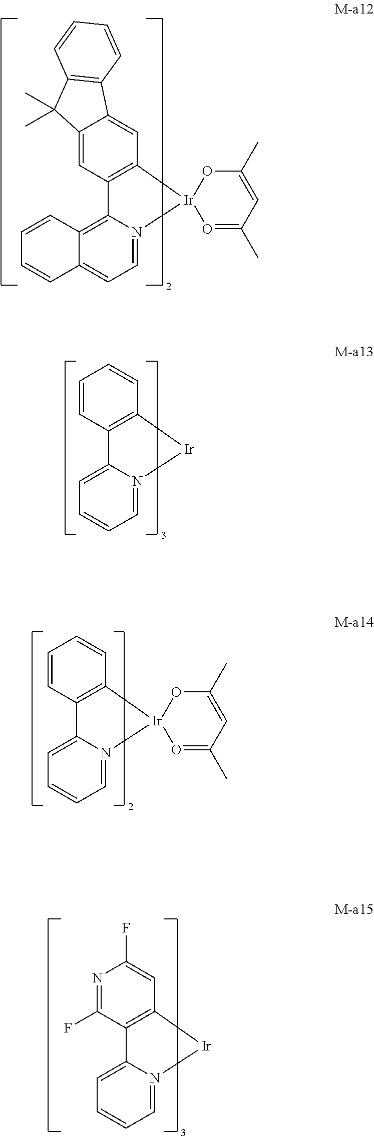

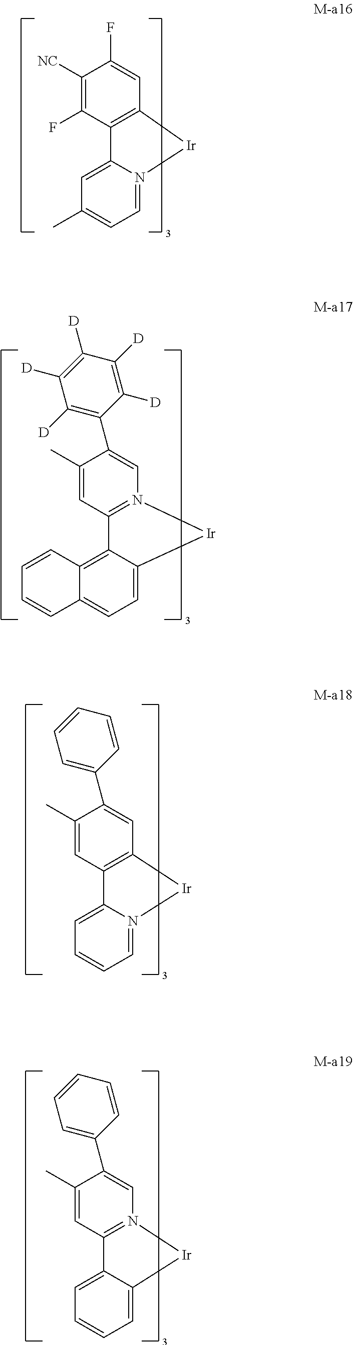

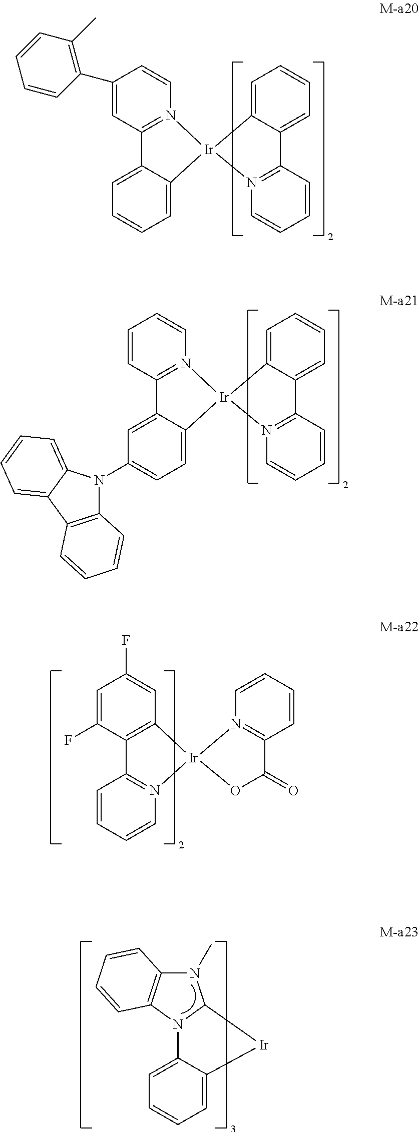

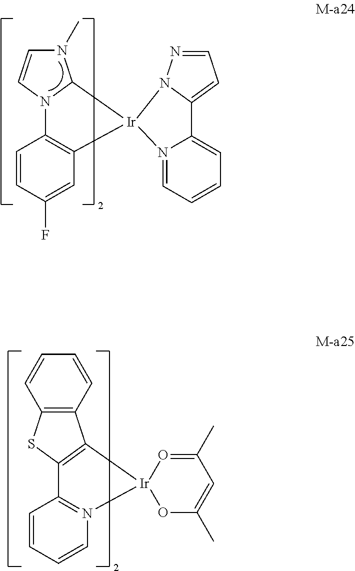

The emission layer EML may further include any one selected from among Formula F-a to Formula F-c. The compounds represented by Formula F-a to Formula F-c may be utilized as fluorescence dopant materials.

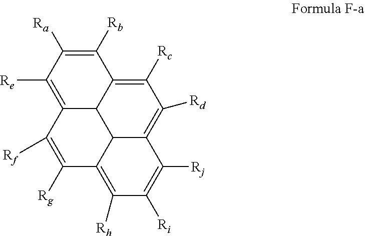

In Formula F-a, two selected from among Ra to Rj may each independently be substituted with *—NAr₁Ar₂. The remainder not substituted with *—NAr₁Ar₂ among Rₐ to Rⱼ may each independently be a hydrogen atom, a deuterium atom, a halogen atom, a cyano group, a substituted or unsubstituted amine group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms.

In *—NAr₁Ar₂, Ar₁ and Ar₂ may each independently be a substituted or unsubstituted aryl group of 6 to 30 ring-forming carbon atoms, or a substituted or unsubstituted heteroaryl group of 2 to 30 ring-forming carbon atoms. For example, at least one among Ar₁ and Ar₂ may be a heteroaryl group including O or S as a ring-forming atom.

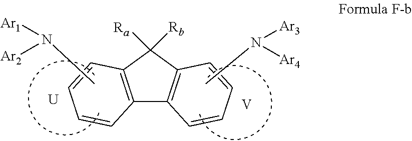

In Formula F-b, Rₐ and R_{b} may each independently be a hydrogen atom, a deuterium atom, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, and/or may be combined with an adjacent group to form a ring. Ar₁ to Ar₄ may each independently be a substituted or unsubstituted aryl group of 6 to 30 ring-forming carbon atoms, or a substituted or unsubstituted heteroaryl group of 2 to 30 ring-forming carbon atoms.

In Formula F-b, U and V may each independently be a substituted or unsubstituted hydrocarbon ring of 5 to 30 ring-forming carbon atoms, or a substituted or unsubstituted heterocycle of 2 to 30 ring-forming carbon atoms. At least one among Ar₁ to Ar₄ may be a heteroaryl group including O or S as a ring-forming atom.

In Formula F-b, the number of rings represented by U and V may each independently be 0 or 1. For example, in Formula F-b, when the number of U or V is 1, one ring forms a fused ring at the designated part by U or V, and when the number of U or V is 0, a ring is not present at the designated part by U or V. For example, when the number of U is 0, and the number of V is 1, or when the number of U is 1, and the number of V is 0, a fused ring having the fluorene core of Formula F-b may be a ring compound with four rings. In some embodiments, when the number of both (e.g., simultaneously) U and V is 0, the fused ring of Formula F-b may be a ring compound with three rings. In some embodiments, when the number of both (e.g., simultaneously) U and V is 1, a fused ring having the fluorene core of Formula F-b may be a ring compound with five rings.

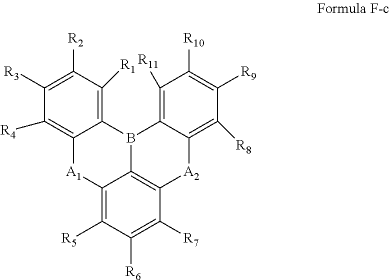

In Formula F-c, A1 and A2 may each independently be O, S, Se, or NRₘ, and Rₘ may be a hydrogen atom, a deuterium atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms. R₁ to R₁₁ may each independently be a hydrogen atom, a deuterium atom, a halogen atom, a cyano group, a substituted or unsubstituted amine group, a substituted or unsubstituted boryl group, a substituted or unsubstituted oxy group, a substituted or unsubstituted thiol group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, and/or combined with an adjacent group to form a ring.

In Formula F-c, A₁ and A₂ may each independently be combined with the substituents of an adjacent ring to form a fused ring. For example, when A₁ and A₂ may each independently be NRₘ, A₁ may be combined with R₄ or R₅ to form a ring. In some embodiments, A₂ may be combined with R₇ or R₈ to form a ring.

In one or more embodiments, the emission layer EML may include as a suitable dopant material, at least one selected from among styryl derivatives (for example, 1,4-bis[2-(3-N-ethylcarbazoryl)vinyl]benzene (BCzVB), 4-(di-p-tolylamino)-4′-[(di-p-tolylamino)styryl]stilbene (DPAVB), N-(4-((E)-2-(6-((E)-4-(diphenylamino)styryl)naphthalen-2-yl)vinyl)phenyl)-N-phenylbenzenamine (N-BDAVBi), and 4,4′-bis[2-(4-(N, N-diphenylamino)phenyl)vinyl]biphenyl (DPAVBi)), perylene and the derivatives thereof (for example, 2,5,8,11-tetra-t-butylperylene (TBP)), pyrene and the derivatives thereof (for example, 1,1-dipyrene, 1,4-dipyrenylbenzene, and 1,4-bis(N, N-diphenylamino)pyrene), and/or the like.

The emission layer EML may include a suitable phosphorescence dopant material. For example, the phosphorescence dopant may utilize a metal complex including iridium (Ir), platinum (Pt), osmium (Os), gold (Au), titanium (Ti), zirconium (Zr), hafnium (Hf), europium (Eu), terbium (Tb) or thulium (Tm). For example, iridium(III) bis(4,6-difluorophenylpyridinato-N, C2′)picolinate (FIrpic), bis(2,4-difluorophenylpyridinato)-tetrakis(1-pyrazolyl)borate iridium(III) (Fir6), or platinum octaethyl porphyrin (PtOEP) may be utilized as the phosphorescence dopant. However, one or more embodiments of the present disclosure is not limited thereto.

The emission layer EML may include a quantum dot material. The core of the quantum dot may be selected from among a II-VI group compound, a III-VI group compound, a I-III-VI group compound, a III-V group compound, a III-II-V group compound, a IV-VI group compound, a IV group element, a IV group compound, and combinations thereof.

The II-VI group compound may be selected from among the group consisting of: a binary compound selected from among the group consisting of CdSe, CdTe, CdS, ZnS, ZnSe, ZnTe, ZnO, HgS, HgSe, HgTe, MgSe, MgS, and mixtures thereof; a ternary compound selected from among the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and mixtures thereof; and a quaternary compound selected from among the group consisting of HgZnTeS, CdZnSeS, CdZnSeTe, CdZnSTe, CdHgSeS, CdHgSeTe, CdHgSTe, HgZnSeS, HgZnSeTe, and/or mixtures thereof.

The III-VI group compound may include a binary compound such as In₂S₃, and In₂Se₃, a ternary compound such as InGaS₃, and InGaSe₃, and/or one or more combinations (e.g., arbitrary combinations) thereof.

The I-III-VI group compound may be selected from among a ternary compound selected from among the group consisting of AgInS, AgInS₂, CuInS, CuInS₂, AgGaS₂, CuGaS₂, CuGaO₂, AgGaO₂, AgAlO₂ and mixtures thereof, and/or a quaternary compound such as AgInGaS₂, and/or CuInGaS₂.

The III-V group compound may be selected from among the group consisting of a binary compound selected from among the group consisting of GaN, GaP, GaAs, GaSb, AlN, AlP, AlAs, AlSb, InN, InP, InAs, InSb, and mixtures thereof, a ternary compound selected from among the group consisting of GaNP, GaNAs, GaNSb, GaPAs, GaPSb, AlNP, AlNAs, AlNSb, AlPAs, AlPSb, InGaP, InAlP, InNP, InNAs, InNSb, InPAs, InPSb, and mixtures thereof, and a quaternary compound selected from among the group consisting of GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and/or mixtures thereof. In some embodiments, the III-V group compound may further include a II group metal. For example, InZnP, etc. may be selected as a III-II-V group compound.

The IV-VI group compound may be selected from among the group consisting of a binary compound selected from among the group consisting of SnS, SnSe, SnTe, PbS, PbSe, PbTe, and mixtures thereof, a ternary compound selected from among the group consisting of SnSeS, SnSeTe, SnSTe, PbSeS, PbSeTe, PbSTe, SnPbS, SnPbSe, SnPbTe, and mixtures thereof, and a quaternary compound selected from among the group consisting of SnPbSSe, SnPbSeTe, SnPbSTe, and/or mixtures thereof. The IV group element may be selected from among the group consisting of Si, Ge, and/or a mixture thereof. The IV group compound may be a binary compound selected from among the group consisting of SiC, SiGe, and/or a mixture thereof.

In this case, the binary compound, the ternary compound and/or the quaternary compound may be present at substantially uniform concentration in a particle or may be present at a partially different concentration distribution state in substantially the same particle. In some embodiments, a core/shell structure in which one quantum dot wraps another quantum dot may be possible. The interface of the core and the shell may have a concentration gradient in which the concentration of an element present in the shell is decreased toward the center.

In some embodiments, the quantum dot may have the described core-shell structure including a core including a nanocrystal and a shell wrapping the core. The shell of the quantum dot may play the role of a protection layer for preventing or reducing the chemical deformation of the core to maintain semiconductor properties and/or a charging layer for imparting the quantum dot with electrophoretic properties. The shell may have a single layer or a multilayer. Examples of the shell of the quantum dot may include a metal or non-metal oxide, a semiconductor compound, or combinations thereof.

For example, the metal or non-metal oxide may include a binary compound selected from among SiO₂, Al₂O₃, TiO₂, ZnO, MnO, Mn₂O₃, Mn₃O₄, CuO, FeO, Fe₂O₃, Fe₃O₄, CoO, Co₃O₄ and/or NiO, or a ternary compound selected from among MgAl₂O₄, CoFe₂O₄, NiFe₂O₄ and/or CoMn₂O₄, but one or more embodiments of the present disclosure is not limited thereto.

Also, the semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, and/or the like, but one or more embodiments of the present disclosure is not limited thereto.

The quantum dot may have a full width of half maximum (FWHM) of emission wavelength spectrum of about 45 nm or less, about 40 nm or less, or about 30 nm or less. Within this range, color purity or color reproducibility may be improved. In some embodiments, light emitted via such quantum dot is emitted in all directions, and light view angle properties may be enhanced or improved (e.g., the size or width of the viewing angle may be enhanced or increased).

In some embodiments, the shape of the quantum dot may be generally utilized shapes in the art, without specific limitation. For example, the shape of spherical, pyramidal, multi-arm, or cubic nanoparticle, nanotube, nanowire, nanofiber, nanoplate particle, and/or the like may be utilized.

The quantum dot may control the color of light emitted according to the particle size, and accordingly, the quantum dot may have one or more suitable emission colors such as blue, red and green.

In the light emitting devices ED of embodiments, as shown in FIG. 3 to FIG. 6, the electron transport region ETR is provided on the emission layer EML. The electron transport region ETR may include at least one selected from among an electron blocking layer HBL, an electron transport layer ETL or an electron injection layer EIL. However, one or more embodiments of the present disclosure is not limited thereto.

The electron transport region ETR may have a single layer formed utilizing a single material, a single layer formed utilizing multiple different materials, or a multilayer structure having multiple layers formed utilizing multiple different materials.

For example, the electron transport region ETR may have a single layer structure of an electron injection layer EIL or an electron transport layer ETL, or a single layer structure formed utilizing an electron injection material and an electron transport material. Further, the electron transport region ETR may have a single layer structure formed utilizing multiple different materials, or a structure stacked from the emission layer EML of electron transport layer ETL/electron injection layer EIL, or hole blocking layer HBL/electron transport layer ETL/electron injection layer EIL, without limitation. The thickness of the electron transport region ETR may be, for example, from about 1,000 Å to about 1,500 Å.

The electron transport region ETR may be formed utilizing one or more suitable methods such as a vacuum deposition method, a spin coating method, a cast method, a Langmuir-Blodgett (LB) method, an inkjet printing method, a laser printing method, and/or a laser induced thermal imaging (LITI) method.

The electron transport region ETR may include a compound represented by Formula ET-2.

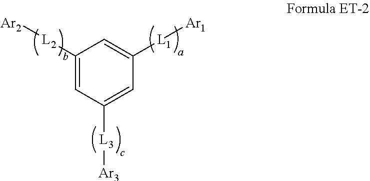

1 In Formula ET-2, at least one among X₁ to X₃ is N, and the remainder are CRₐ. Rₐ may be a hydrogen atom, a deuterium atom, a substituted or unsubstituted alkyl of 1 to 20 carbon atoms, a substituted or unsubstituted aryl group of 6 to 30 ring-forming carbon atoms, or a substituted or unsubstituted heteroaryl group of 2 to 30 ring-forming carbon atoms. Ar₁ to Ar₃ may each independently be a hydrogen atom, a deuterium atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms.

In Formula ET-2, “a” to “c” may each independently be an integer of 0 to 10. In Formula ET-2, L₁ to L₃ may each independently be a direct linkage, a substituted or unsubstituted arylene group of 6 to 30 ring-forming carbon atoms, or a substituted or unsubstituted heteroarylene group of 2 to 30 ring-forming carbon atoms. In some embodiments, when “a” to “c” are integers of 2 or more, L₁ to L₃ may each independently be a substituted or unsubstituted arylene group of 6 to 30 ring-forming carbon atoms, or a substituted or unsubstituted heteroarylene group of 2 to 30 ring-forming carbon atoms.

The electron transport region ETR may include an anthracene-based compound. However, one or more embodiments of the present disclosure is not limited thereto, and the electron transport region ETR may include, for example, at least one selected from among tris(8-hydroxyquinolinato)aluminum (Alq₃), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzoimidazolyl-1-yl)phenyl)-9,10-dinaphthylanthracene, 1,3,5-tri(1-phenyl-1H-benzo[d]imidazol-2-yl)benzene (TPBi), 2,9-dimethyl-4,7-diphenyl-1,10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-N1,O8)-(1,1′-biphenyl-4-olato)aluminum (BAlq), berylliumbis(benzoquinolin-10-olate (Bebq₂), 9,10-di(naphthalene-2-yl)anthracene (ADN), 1,3-bis[3,5-di(pyridin-3-yl)phenyl]benzene (BmPyPhB), and/or mixtures thereof, without limitation.

The electron transport region ETR may include at least one selected from among Compounds ET1 to ET36.

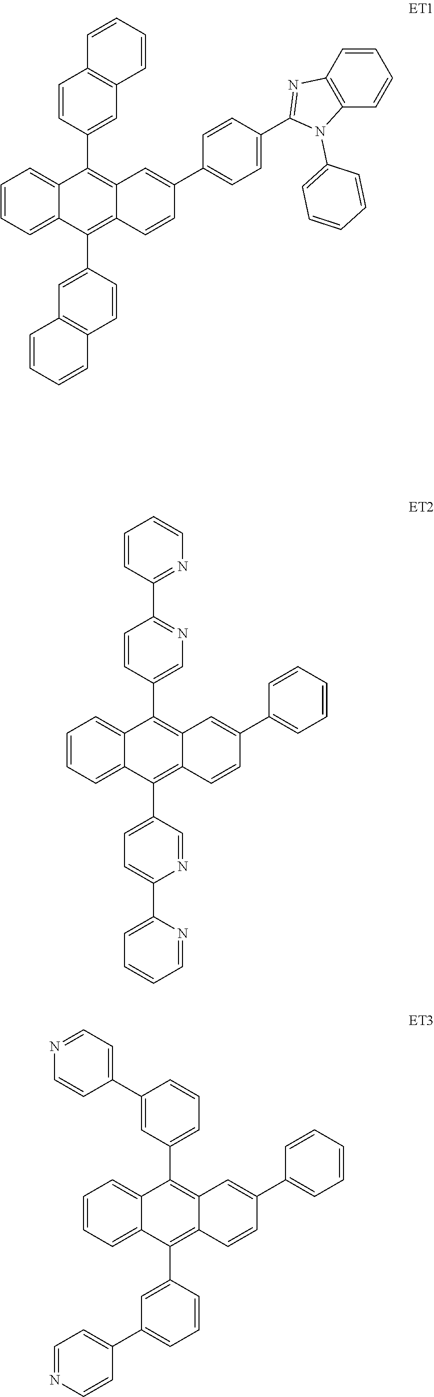 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2ccc3c(-c4ccc(-c5ccccn5)nc4)c4ccccc4c(-c4ccc(-c5ccccn5)nc4)c3c2)cc1 ; c1ccc(-c2ccc3c(-c4cccc(-c5ccncc5)c4)c4ccccc4c(-c4cccc(-c5ccncc5)c4)c3c2)cc1]

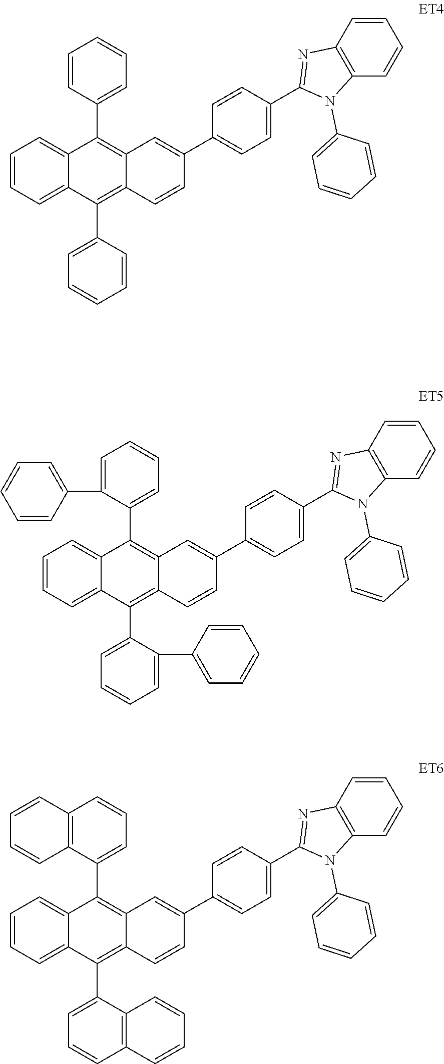 [SMILES: c1ccc(-c2c3ccccc3c(-c3ccccc3)c3cc(-c4ccc(-c5nc6ccccc6n5-c5ccccc5)cc4)ccc23)cc1 ; c1ccc(-c2ccccc2-c2c3ccccc3c(-c3ccccc3-c3ccccc3)c3cc(-c4ccc(-c5nc6ccccc6n5-c5ccccc5)cc4)ccc23)cc1 ; c1ccc(-n2c(-c3ccc(-c4ccc5c(-c6cccc7ccccc67)c6ccccc6c(-c6cccc7ccccc67)c5c4)cc3)nc3ccccc32)cc1]

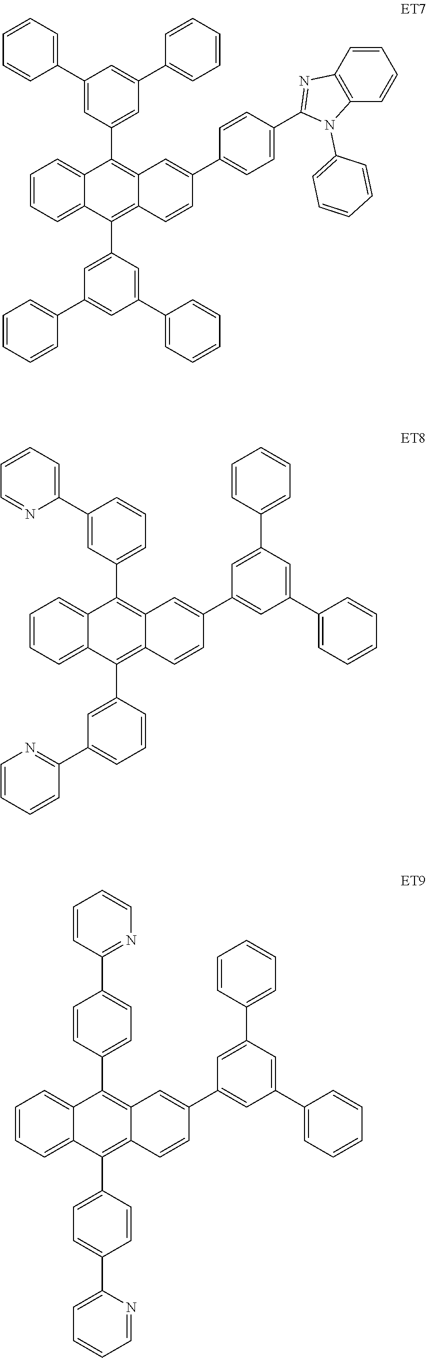 [SMILES: c1ccc(-c2cc(-c3ccccc3)cc(-c3c4ccccc4c(-c4cc(-c5ccccc5)cc(-c5ccccc5)c4)c4cc(-c5ccc(-c6nc7ccccc7n6-c6ccccc6)cc5)ccc34)c2)cc1 ; c1ccc(-c2cc(-c3ccccc3)cc(-c3ccc4c(-c5cccc(-c6ccccn6)c5)c5ccccc5c(-c5cccc(-c6ccccn6)c5)c4c3)c2)cc1 ; c1ccc(-c2cc(-c3ccccc3)cc(-c3ccc4c(-c5ccc(-c6ccccn6)cc5)c5ccccc5c(-c5ccc(-c6ccccn6)cc5)c4c3)c2)cc1]

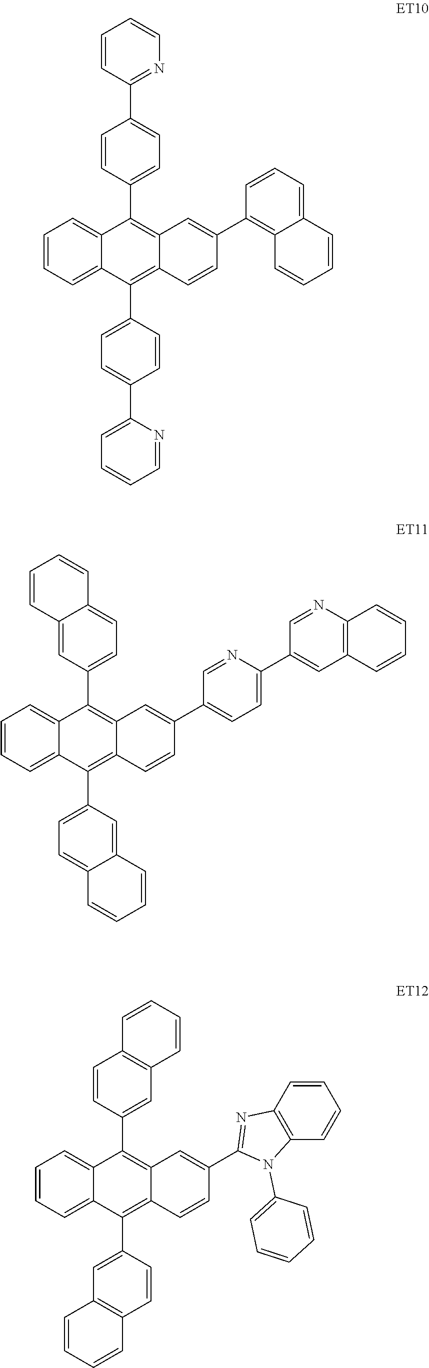 [SMILES: c1ccc(-c2ccc(-c3c4ccccc4c(-c4ccc(-c5ccccn5)cc4)c4cc(-c5cccc6ccccc56)ccc34)cc2)nc1 ; c1ccc2cc(-c3c4ccccc4c(-c4ccc5ccccc5c4)c4cc(-c5ccc(-c6cnc7ccccc7c6)nc5)ccc34)ccc2c1 ; c1ccc(-n2c(-c3ccc4c(-c5ccc6ccccc6c5)c5ccccc5c(-c5ccc6ccccc6c5)c4c3)nc3ccccc32)cc1]

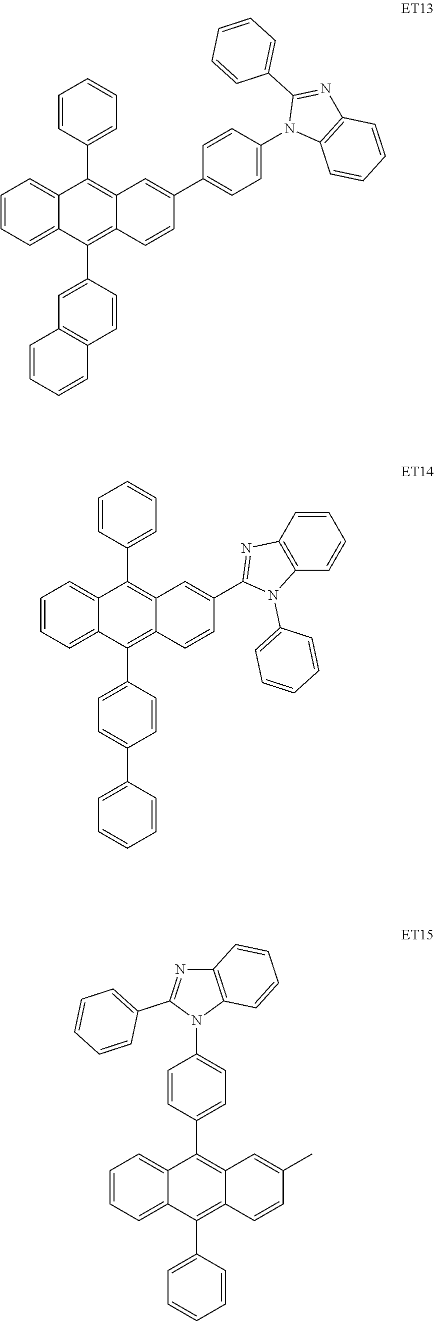 [SMILES: c1ccc(-c2c3ccccc3c(-c3ccc4ccccc4c3)c3ccc(-c4ccc(-n5c(-c6ccccc6)nc6ccccc65)cc4)cc23)cc1 ; c1ccc(-c2ccc(-c3c4ccccc4c(-c4ccccc4)c4cc(-c5nc6ccccc6n5-c5ccccc5)ccc34)cc2)cc1 ; Cc1ccc2c(-c3ccccc3)c3ccccc3c(-c3ccc(-n4c(-c5ccccc5)nc5ccccc54)cc3)c2c1]

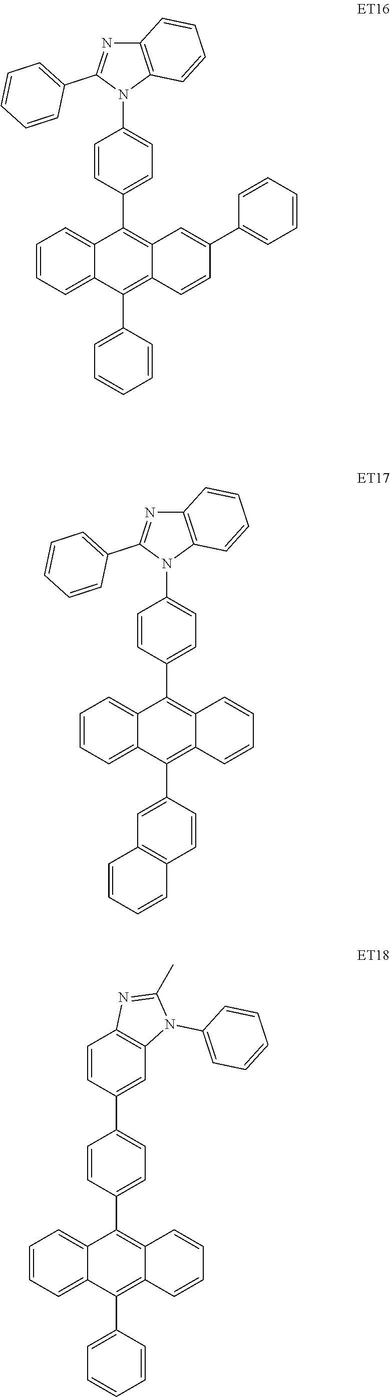 [SMILES: c1ccc(-c2ccc3c(-c4ccccc4)c4ccccc4c(-c4ccc(-n5c(-c6ccccc6)nc6ccccc65)cc4)c3c2)cc1 ; c1ccc(-c2nc3ccccc3n2-c2ccc(-c3c4ccccc4c(-c4ccc5ccccc5c4)c4ccccc34)cc2)cc1 ; Cc1nc2ccc(-c3ccc(-c4c5ccccc5c(-c5ccccc5)c5ccccc45)cc3)cc2n1-c1ccccc1]

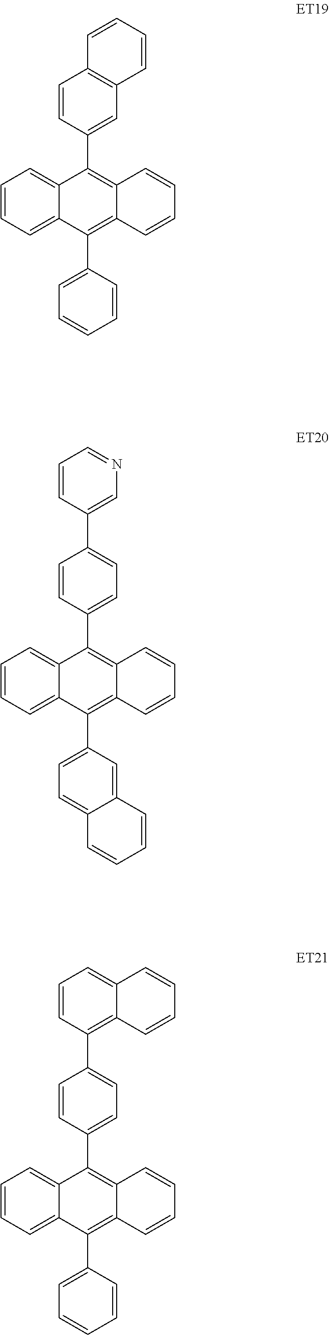

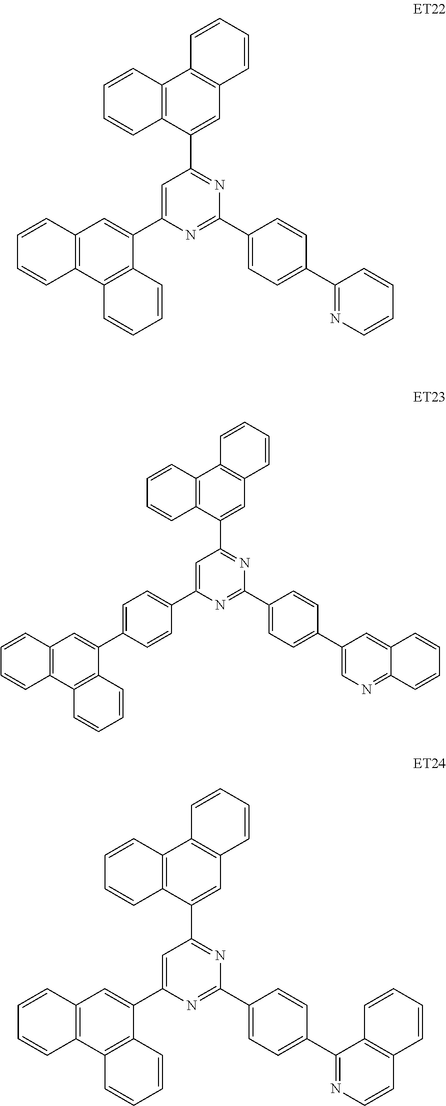 [SMILES: c1ccc(-c2ccc(-c3nc(-c4cc5ccccc5c5ccccc45)cc(-c4cc5ccccc5c5ccccc45)n3)cc2)nc1 ; c1ccc2ncc(-c3ccc(-c4nc(-c5ccc(-c6cc7ccccc7c7ccccc67)cc5)cc(-c5cc6ccccc6c6ccccc56)n4)cc3)cc2c1 ; c1ccc2c(-c3ccc(-c4nc(-c5cc6ccccc6c6ccccc56)cc(-c5cc6ccccc6c6ccccc56)n4)cc3)nccc2c1]

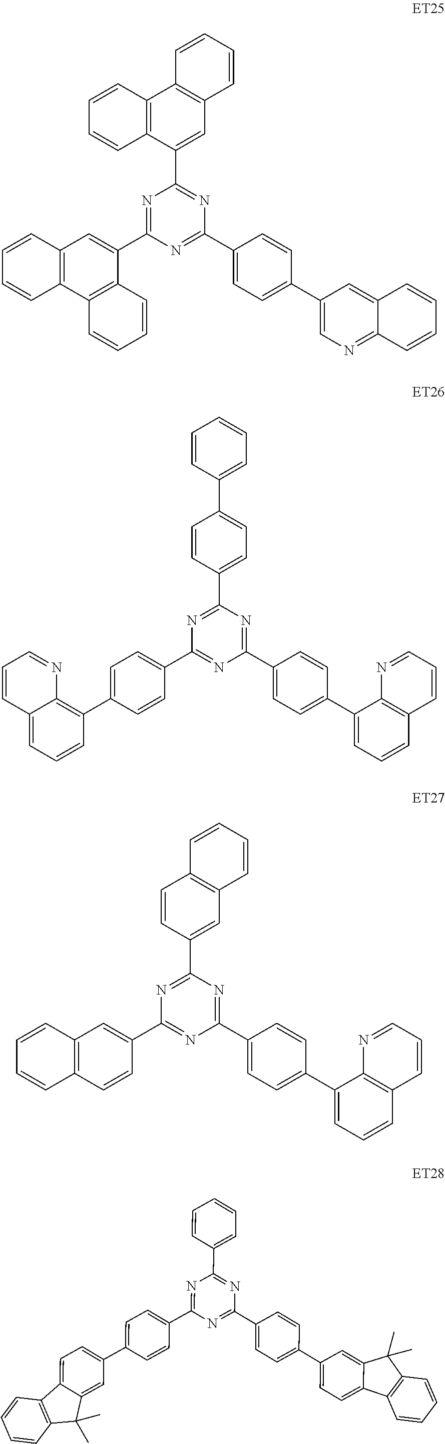 [SMILES: c1ccc2ncc(-c3ccc(-c4nc(-c5cc6ccccc6c6ccccc56)nc(-c5cc6ccccc6c6ccccc56)n4)cc3)cc2c1 ; c1ccc(-c2ccc(-c3nc(-c4ccc(-c5cccc6cccnc56)cc4)nc(-c4ccc(-c5cccc6cccnc56)cc4)n3)cc2)cc1 ; c1ccc2cc(-c3nc(-c4ccc(-c5cccc6cccnc56)cc4)nc(-c4ccc5ccccc5c4)n3)ccc2c1 ; CC1(C)c2ccccc2-c2ccc(-c3ccc(-c4nc(-c5ccccc5)nc(-c5ccc(-c6ccc7c(c6)C(C)(C)c6ccccc6-7)cc5)n4)cc3)cc21]

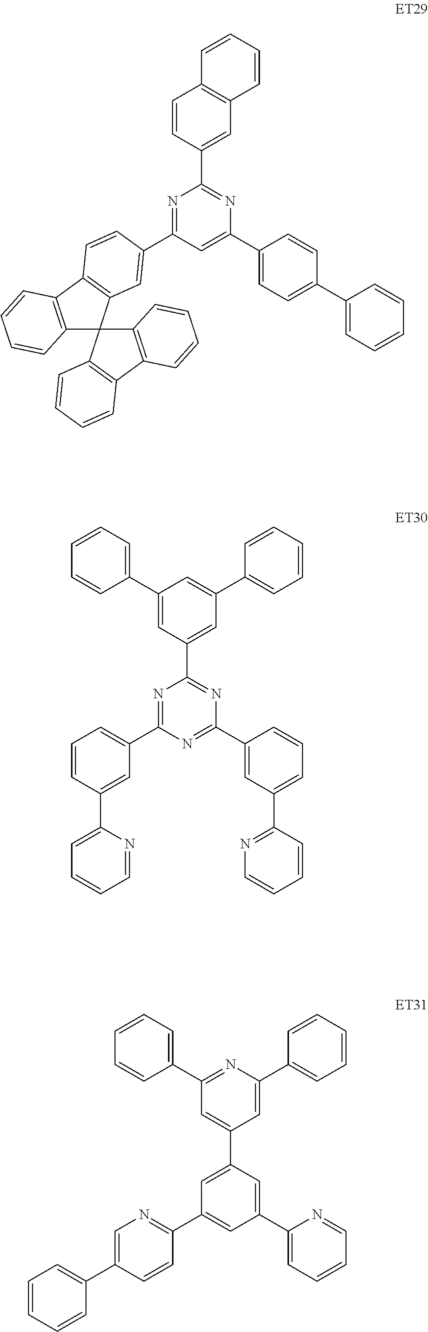 [SMILES: c1ccc(-c2ccc(-c3cc(-c4ccc5c(c4)C4(c6ccccc6-c6ccccc64)c4ccccc4-5)nc(-c4ccc5ccccc5c4)n3)cc2)cc1 ; c1ccc(-c2cc(-c3ccccc3)cc(-c3nc(-c4cccc(-c5ccccn5)c4)nc(-c4cccc(-c5ccccn5)c4)n3)c2)cc1 ; c1ccc(-c2ccc(-c3cc(-c4cc(-c5ccccc5)nc(-c5ccccc5)c4)cc(-c4ccccn4)c3)nc2)cc1]

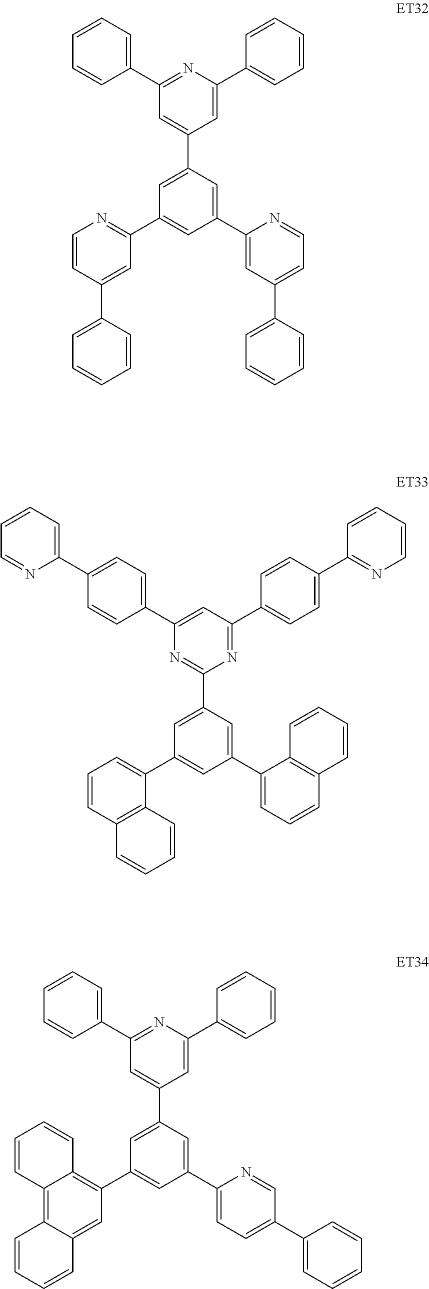 [SMILES: c1ccc(-c2ccnc(-c3cc(-c4cc(-c5ccccc5)nc(-c5ccccc5)c4)cc(-c4cc(-c5ccccc5)ccn4)c3)c2)cc1 ; c1ccc(-c2ccc(-c3cc(-c4ccc(-c5ccccn5)cc4)nc(-c4cc(-c5cccc6ccccc56)cc(-c5cccc6ccccc56)c4)n3)cc2)nc1 ; c1ccc(-c2ccc(-c3cc(-c4cc(-c5ccccc5)nc(-c5ccccc5)c4)cc(-c4cc5ccccc5c5ccccc45)c3)nc2)cc1]

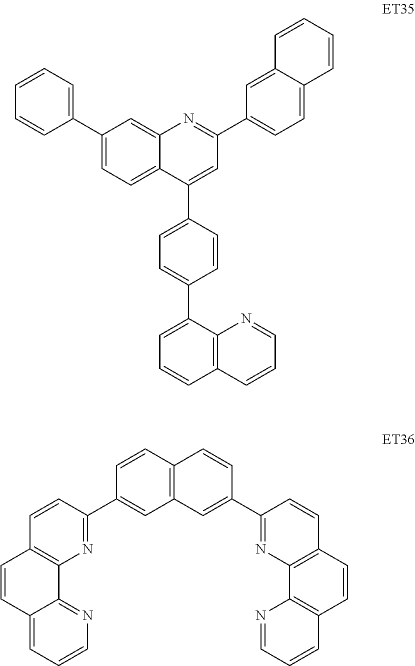 [SMILES: c1ccc(-c2ccc3c(-c4ccc(-c5cccc6cccnc56)cc4)cc(-c4ccc5ccccc5c4)nc3c2)cc1 ; c1cnc2c(c1)ccc1ccc(-c3ccc4ccc(-c5ccc6ccc7cccnc7c6n5)cc4c3)nc12]

In some embodiments, the electron transport region ETR may include a metal halide such as LiF, NaCl, CsF, RbCl, RbI, CuI and KI, a lanthanide metal such as Yb, or a co-depositing material of the metal halide and the lanthanide metal. For example, the electron transport region ETR may include KI:Yb, Rbl:Yb, LiF:Yb, etc., as the co-depositing material. In some embodiments, the electron transport region ETR may utilize a metal oxide such as Li₂O and BaO, or 8-hydroxy-lithium quinolate (Liq). However, one or more embodiments of the present disclosure is not limited thereto. The electron transport region ETR also may be formed utilizing a mixture material of an electron transport material and an insulating organo metal salt. The organo metal salt may be a material having an energy band gap of about 4 eV or more. For example, the organo metal salt may include, for example, metal acetates, metal benzoates, metal acetoacetates, metal acetylacetonates, and/or metal stearates.

The electron transport region ETR may include at least one selected from among 2,9-dimethyl-4,7-diphenyl-1,10-phenanthroline (BCP), diphenyl(4-(triphenylsilyl)phenyl)phosphine oxide (TSPO1), and/or 4,7-diphenyl-1,10-phenanthroline (Bphen) in addition to the aforementioned materials. However, one or more embodiments of the present disclosure is not limited thereto.

The electron transport region ETR may include the compounds of the electron transport region in at least one selected from among an electron injection layer EIL, an electron transport layer ETL, and/or a hole blocking layer HBL.

When the electron transport region ETR includes the electron transport layer ETL, the thickness of the electron transport layer ETL may be from about 100 Å to about 1,000 Å, for example, from about 150 Å to about 500 Å. When the thickness of the electron transport layer ETL satisfies the described range, satisfactory electron transport properties may be obtained without substantial increase of a driving voltage. When the electron transport region ETR includes the electron injection layer EIL, the thickness of the electron injection layer EIL may be from about 1 Å to about 100 Å, and from about 3 Å to about 90 Å. When the thickness of the electron injection layer EIL satisfies the described range, satisfactory electron injection properties may be obtained without inducing substantial increase of a driving voltage.

The second electrode EL2 is provided on the electron transport region ETR. The second electrode EL2 may be a common electrode. The second electrode EL2 may be a cathode or an anode, but one or more embodiments of the present disclosure is not limited thereto. For example, when the first electrode EL1 is an anode, the second cathode EL2 may be a cathode, and when the first electrode EL1 is a cathode, the second electrode EL2 may be an anode.

The second electrode EL2 may be a transmissive electrode, a transflective electrode or a reflective electrode. When the second electrode EL2 is the transmissive electrode, the second electrode EL2 may include a transparent metal oxide, for example, ITO, IZO, ZnO, ITZO, and/or the like.

When the second electrode EL2 is the transflective electrode or the reflective electrode, the second electrode EL2 may include at least one selected from among Ag, Mg, Cu, Al, Pt, Pd, Au, Ni, Nd, Ir, Cr, Li, Ca, LiF/Ca, LiF/Al, Mo, Ti, Yb, and/or W, compounds including thereof, or mixtures thereof (for example, AgMg, AgYb, or MgYb). In some embodiments, the second electrode EL2 may have a multilayered structure including a reflective layer or a transflective layer formed utilizing the above-described materials and a transparent conductive layer formed utilizing ITO, IZO, ZnO, ITZO, and/or the like. For example, the second electrode EL2 may include the aforementioned metal materials, combinations of two or more metal materials selected from the aforementioned metal materials, and/or oxides of the aforementioned metal materials.

In one or more embodiments, the second electrode EL2 may be connected with an auxiliary electrode. When the second electrode EL2 is connected with the auxiliary electrode, the resistance of the second electrode EL2 may decrease.

In some embodiments, on the second electrode EL2 in the light emitting device ED of one or more embodiments, a capping layer CPL may be further provided. The capping layer CPL may include a multilayer or a single layer.

In one or more embodiments, the capping layer CPL may be an organic layer or an inorganic layer. For example, when the capping layer CPL includes an inorganic material, the inorganic material may include an alkali metal compound such as LiF and/or an alkaline earth metal compound such as MgF₂, SiON, SiNx, SiOy, etc. For example, when the capping layer CPL includes an organic material, the organic material may include at least one selected from among 2,2′-dimethyl-N,N′-di-[(1-naphthyl)-N,N′-diphenyl]-1,1′-biphenyl-4,4′-diamine (α-NPD), NPB, TPD, m-MTDATA, Alq₃, CuPc, N4,N4,N4′,N4′-tetra(biphenyl-4-yl) biphenyl-4,4′-diamine (TPD15), 4,4′,4″-tris(carbazol sol-9-yl) triphenylamine (TCTA), and/or the like, or the organic material includes an epoxy resin, or acrylate such as methacrylate. In some embodiments, a capping layer CPL may include at least one selected from among Compounds P1 to P5, but one or more embodiments of the present disclosure is not limited thereto.

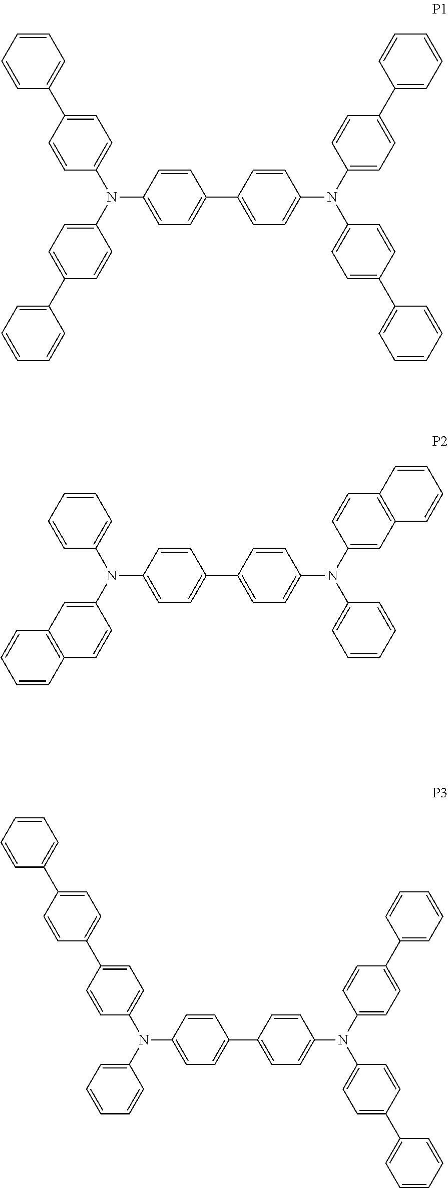 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(N(c2ccc(-c3ccc(N(c4ccccc4)c4ccc5ccccc5c4)cc3)cc2)c2ccc3ccccc3c2)cc1 ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1]

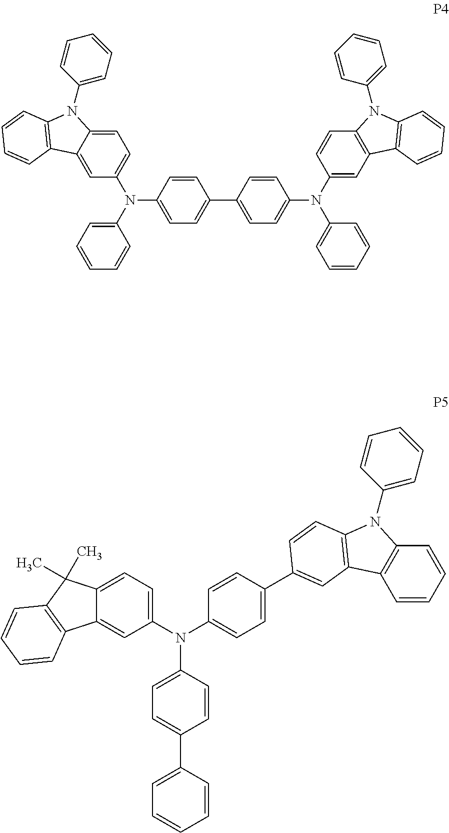 [SMILES: c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1 ; CC1(C)c2ccccc2-c2cc(N(c3ccc(-c4ccccc4)cc3)c3ccc(-c4ccc5c(c4)c4ccccc4n5-c4ccccc4)cc3)ccc21]

In some embodiments, the refractive index of the capping layer CPL may be about 1.6 or more. For example, the refractive index of the capping layer CPL with respect to light in a wavelength range of about 550 nm to about 660 nm may be about 1.6 or more.

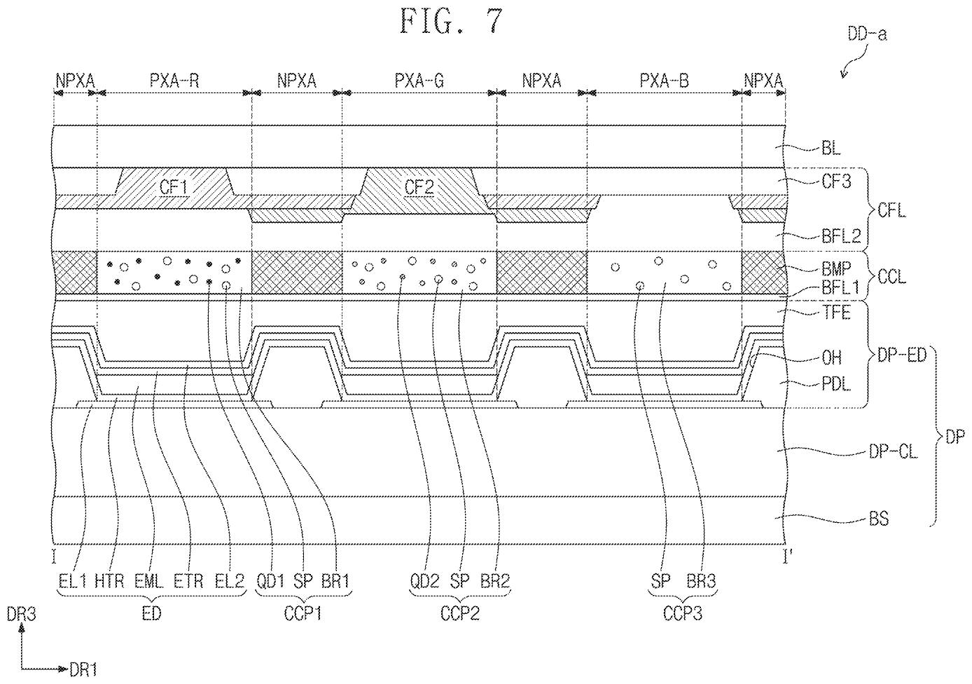

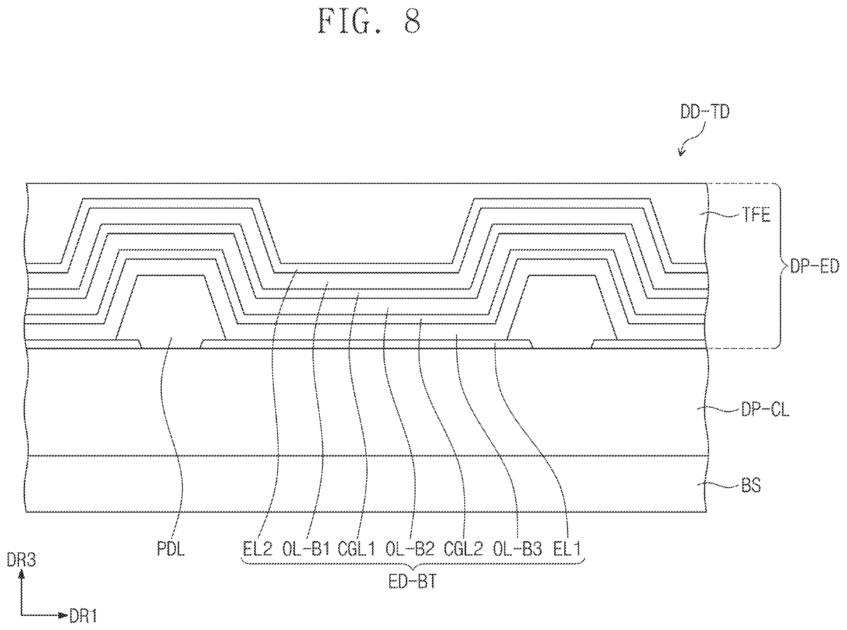

FIG. 7 to FIG. 10 are each a cross-sectional view of a display apparatus according to one or more embodiments, respectively. In the explanation on the display apparatuses of embodiments referring to FIG. 7 to FIG. 10, the overlapping parts with the explanation on FIG. 1 to FIG. 6 will not be explained again, and, instead, the different features will be explained chiefly (e.g., in more detail).

Referring to FIG. 7, the display apparatus DD-a according to one or more embodiments may include a display panel DP including a display device layer DP-ED, a light controlling layer CCL provided on the display panel DP and a color filter layer CFL. In one or more embodiments shown in FIG. 7, the display panel DP includes a base layer BS, a circuit layer DP-CL provided on the base layer BS and a display device layer DP-ED, and the display device layer DP-ED may include a light emitting device ED.

The light emitting device ED may include a first electrode EL1, a hole transport region HTR provided on the first electrode EL1, an emission layer EML provided on the hole transport region HTR, an electron transport region ETR provided on the emission layer EML, and a second electrode EL2 provided on the electron transport region ETR. In some embodiments, the same structures as the light emitting devices of FIG. 3 to FIG. 6 may be applied to the structure of the light emitting device ED shown in FIG. 7.

In the display apparatus DD-a according to one or more embodiments, the emission layer EML of the light emitting device ED may include the fused polycyclic compound of one or more embodiments.

Referring to FIG. 7, the emission layer EML may be provided in an opening part OH defined in a pixel definition layer PDL. For example, the emission layer EML that is divided by the pixel definition layer PDL and correspondingly provided to each of luminous areas PXA-R, PXA-G and PXA-B may be to emit (e.g., configured to emit) light in substantially the same wavelength region. In the display apparatus DD-a of one or more embodiments, the emission layer EML may be to emit (e.g., configured to emit) blue light. In some embodiments, different from the drawings, the emission layer EML may be provided as a common layer for all luminous areas PXA-R, PXA-G and PXA-B.

The light controlling layer CCL may be provided on the display panel DP. The light controlling layer CCL may include a light converter. The light converter may be a quantum dot or a phosphor. The light converter may transform the wavelength of light provided and then emit. For example, the light controlling layer CCL may be a layer including a quantum dot or a layer including a phosphor.

The light controlling layer CCL may include multiple light controlling parts CCP1, CCP2 and CCP3. The light controlling parts CCP1, CCP2 and CCP3 may be separated from one another.

Referring to FIG. 7, a partition pattern BMP may be provided between the separated light controlling parts CCP1, CCP2 and CCP3, but one or more embodiments of the present disclosure is not limited thereto. In FIG. 7, the partition pattern BMP is shown not to be overlapped with the light controlling parts CCP1, CCP2 and CCP3, but at least a portion of the edge of the light controlling parts CCP1, CCP2 and CCP3 may be overlapped with the partition pattern BMP.

The light controlling layer CCL may include a first light controlling part CCP1 including a first quantum dot QD1 converting first color light provided from the light emitting device ED into second color light, a second light controlling part CCP2 including a second quantum dot QD2 converting first color light into third color light, and a third light controlling part CCP3 transmitting first color light. In one or more embodiments, the first light controlling part CCP1 may provide red light which is the second color light, and the second light controlling part CCP2 may provide green light which is the third color light. The third color controlling part CCP3 may be to transmit and provide blue light which is the first color light provided from the light emitting device ED. For example, the first quantum dot QD1 may be a red quantum dot, and the second quantum dot QD2 may be a green quantum dot. On the quantum dots QD1 and QD2, the same contents as those described above may be applied.

In some embodiments, the light controlling layer CCL may further include a scatterer SP. The first light controlling part CCP1 may include the first quantum dot QD1 and the scatterer SP, the second light controlling part CCP2 may include the second quantum dot QD2 and the scatterer SP, and the third light controlling part CCP3 may not include (e.g., may exclude) a (e.g., any) quantum dot but include the scatterer SP.

The scatterer SP may be an inorganic particle. For example, the scatterer SP may include at least one selected from among TiO₂, ZnO, Al₂O₃, SiO₂, and hollow silica. The scatterer SP may include at least one selected from among TiO₂, ZnO, Al₂O₃, SiO₂, and hollow silica, or may be a mixture of two or more materials selected among TiO₂, ZnO, Al₂O₃, SiO₂, and hollow silica.

Each of the first light controlling part CCP1, the second light controlling part CCP2, and the third light controlling part CCP3 may include base resins BR1, BR2 and BR3 dispersing the quantum dots QD1 and QD2 and the scatterer SP. In one or more embodiments, the first light controlling part CCP1 may include the first quantum dot QD1 and the scatterer SP dispersed in the first base resin BR1, the second light controlling part CCP2 may include the second quantum dot QD2 and the scatterer SP dispersed in the second base resin BR2, and the third light controlling part CCP3 may include the scatterer particle SP dispersed in the third base resin BR3.

The base resins BR1, BR2 and BR3 are each a composition (e.g., medium) in which the quantum dots QD1 and QD2 and the scatterer SP are dispersed, and may be composed of one or more suitable resin compositions which may be generally referred to as a binder. For example, the base resins BR1, BR2 and BR3 may be acrylic resins, urethane-based resins, silicone-based resins, epoxy-based resins, and/or the like. The base resins BR1, BR2 and BR3 may be transparent resins. In one or more embodiments, the first base resin BR1, the second base resin BR2 and the third base resin BR3 may be the same or different from each other.

The light controlling layer CCL may include a barrier layer BFL1. The barrier layer BFL1 may play the role of blocking the penetration of moisture and/or oxygen (hereinafter, will be referred to as “humidity/oxygen”). The barrier layer BFL1 may block or reduce the exposure of the light controlling parts CCP1, CCP2 and CCP3 to humidity/oxygen. In some embodiments, the barrier layer BFL1 may cover the light controlling parts CCP1, CCP2 and CCP3. In some embodiments, a color filter layer CFL, which will be explained later, may include a barrier layer BFL2 provided on the light controlling parts CCP1, CCP2 and CCP3.

The barrier layers BFL1 and BFL2 may include at least one inorganic layer. For example, the barrier layers BFL1 and BFL2 may be formed by including an inorganic material. For example, the barrier layers BFL1 and BFL2 may be formed by including silicon nitride, aluminum nitride, zirconium nitride, titanium nitride, hafnium nitride, tantalum nitride, silicon oxide, aluminum oxide, titanium oxide, tin oxide, cerium oxide and/or silicon oxynitride or a metal thin film securing light transmittance. In some embodiments, the barrier layers BFL1 and BFL2 may further include an organic layer. The barrier layers BFL1 and BFL2 may be composed of a single layer of multiple layers.

In the display apparatus DD-a of one or more embodiments, the color filter layer CFL may be provided on the light controlling layer CCL. For example, the color filter layer CFL may be provided directly on the light controlling layer CCL. In this case, the barrier layer BFL2 may not be provided.

The color filter layer CFL may include filters CF1, CF2 and CF3. Each of the first to third filters CF1, CF2 and CF3 may be provided corresponding to a red luminous area PXA-R, a green luminous area PXA-G, and a blue luminous area PXA-B, respectively.

The color filter layer CFL may include a first filter CF1 transmitting second color light, a second filter CF2 transmitting third color light, and a third filter CF3 transmitting first color light. For example, the first filter CF1 may be a red filter, the second filter CF2 may be a green filter, and the third filter CF3 may be a blue filter. Each of the filters CF1, CF2 and CF3 may include a polymer photosensitive resin and a pigment or dye. The first filter CF1 may include a red pigment or dye, the second filter CF2 may include a green pigment or dye, and the third filter CF3 may include a blue pigment or dye.

In some embodiments, one or more embodiments of the present disclosure is not limited thereto, and the third filter CF3 may not include (e.g., may exclude any of) the pigment or dye. The third filter CF3 may include a polymer photosensitive resin and not include a pigment or dye. The third filter CF3 may be transparent. The third filter CF3 may be formed utilizing a transparent photosensitive resin.

In some embodiments, in one or more embodiments, the first filter CF1 and the second filter CF2 may be yellow filters. The first filter CF1 and the second filter CF2 may be provided in one body without distinction.

In one or more embodiments, the color filter layer CFL may further include a light blocking part. The light blocking part may be a black matrix. The light blocking part may be formed by including an organic light blocking material or an inorganic light blocking material including a black pigment or black dye. The light blocking part may prevent or reduce light leakage phenomenon and divide the boundaries among adjacent filters CF1, CF2 and CF3.

On the color filter layer CFL, a base substrate BL may be provided. The base substrate BL may be a member providing a base surface on which the color filter layer CFL, the light controlling layer CCL, etc. are provided. The base substrate BL may be a glass substrate, a metal substrate, a plastic substrate, and/or the like. However, one or more embodiments of the present disclosure is not limited thereto, and the base substrate BL may be an inorganic layer, an organic layer or a composite material layer. In some embodiments, different from the drawing, the base substrate BL may not be provided in one or more embodiments.

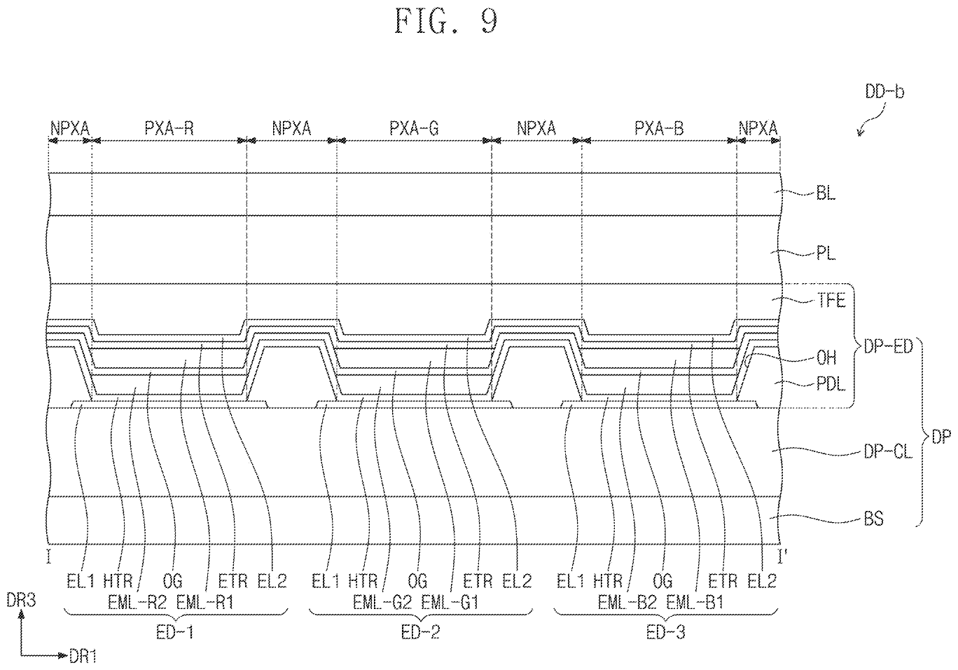

FIG. 8 is a cross-sectional view showing a portion of the display apparatus according to one or more embodiments. In a display apparatus DD-TD of one or more embodiments, the light emitting device ED-BT may include multiple light emitting structures OL-B1, OL-B2 and OL-B3. The light emitting device ED-BT may include oppositely provided first electrode EL1 and second electrode EL2, and the multiple light emitting structures OL-B1, OL-B2 and OL-B3 stacked in order in a thickness direction and provided between the first electrode EL1 and the second electrode EL2. Each of the light emitting structures OL-B1, OL-B2 and OL-B3 may include an emission layer EML (FIG. 7), and a hole transport region HTR and an electron transport region ETR provided with the emission layer EML (FIG. 7) therebetween.

For example, the light emitting device ED-BT included in the display apparatus DD-TD of one or more embodiments may be a light emitting device of a tandem structure including multiple emission layers.

In one or more embodiments shown in FIG. 8, light emitted from the light emitting structures OL-B1, OL-B2 and OL-B3 may be all blue light. However, one or more embodiments of the present disclosure is not limited thereto, and the wavelength regions of light emitted from the light emitting structures OL-B1, OL-B2 and OL-B3 may be different from each other. For example, the light emitting device ED-BT including the multiple light emitting structures OL-B1, OL-B2 and OL-B3 emitting light in different wavelength regions may be to emit (e.g., configured to emit) white light.

Between neighboring light emitting structures OL-B1, OL-B2 and OL-B3, charge generating layers CGL1 and CGL2 may be provided. The charge generating layers CGL1 and CGL2 may include a p-type or kind charge generating layer (e.g., a p-charge generating layer) and/or an n-type or kind charge generating layer (e.g., a n-charge generating layer).

In at least one selected from among the light emitting structures OL-B1, OL-B2 and OL-B3, included in the display apparatus DD-TD of one or more embodiments, the fused polycyclic compound of one or more embodiments may be included. For example, at least one among multiple emission layers included in the light emitting device ED-BT may include the fused polycyclic compound of one or more embodiments.

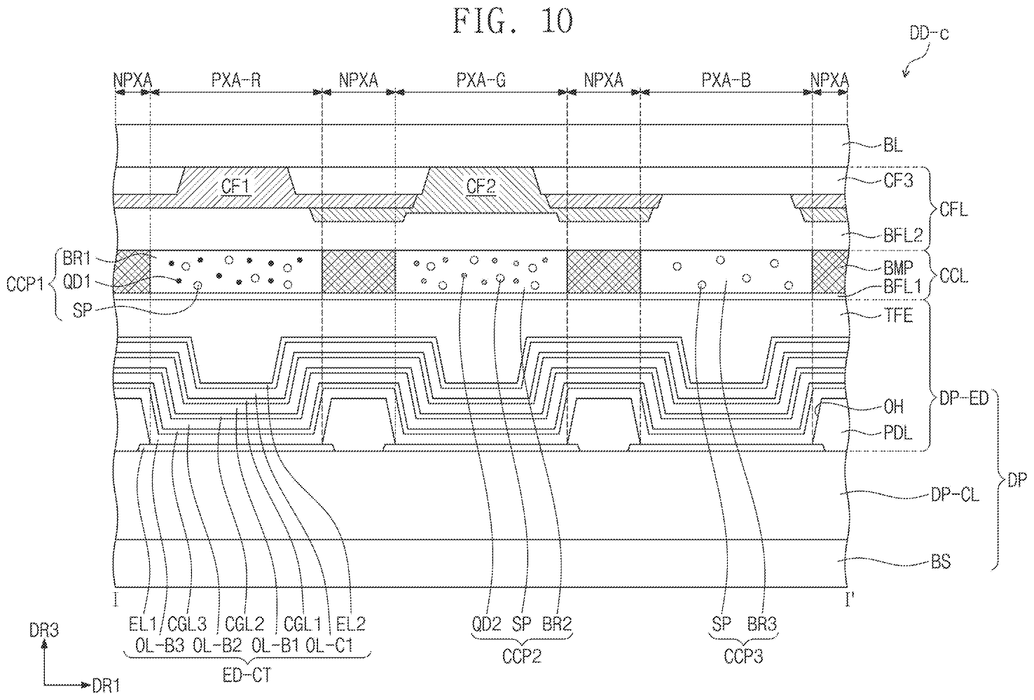

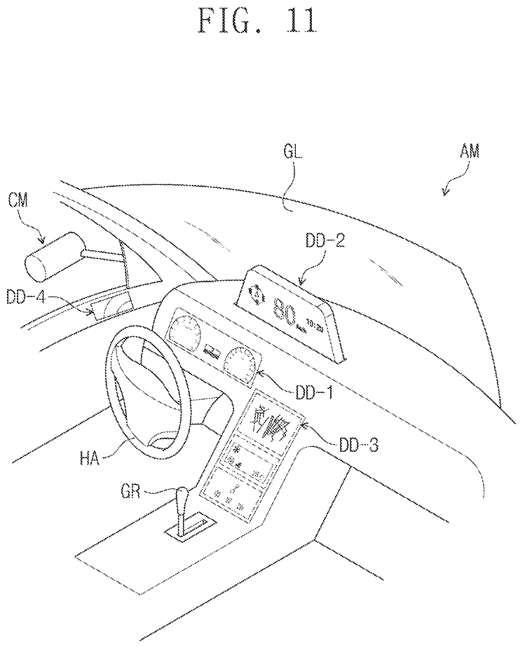

FIG. 9 is a cross-sectional view showing a display apparatus according to one or more embodiments of the present disclosure. FIG. 10 is a cross-sectional view showing a display apparatus according to one or more embodiments of the present disclosure.

Referring to FIG. 9, a display apparatus DD-b according to one or more embodiments may include light emitting devices ED-1, ED-2 and ED-3, formed by stacking two emission layers. Compared to the display apparatus DD of one or more embodiments, shown in FIG. 2, one or more embodiments shown in FIG. 9 is different in that first to third light emitting devices ED-1, ED-2 and ED-3 include two emission layers stacked in a thickness direction, each. In the first to third light emitting devices ED-1, ED-2 and ED-3, two emission layers may be to emit (e.g., configured to emit) light in substantially the same wavelength region.

The first light emitting device ED-1 may include a first red emission layer EML-R1 and a second red emission layer EML-R2. The second light emitting device ED-2 may include a first green emission layer EML-G1 and a second green emission layer EML-G2. In some embodiments, the third light emitting device ED-3 may include a first blue emission layer EML-B1 and a second blue emission layer EML-B2. Between the first red emission layer EML-R1 and the second red emission layer EML-R2, between the first green emission layer EML-G1 and the second green emission layer EML-G2, and between the first blue emission layer EML-B1 and the second blue emission layer EML-B2, an emission auxiliary part OG may be provided.

The emission auxiliary part OG may include a single layer or a multilayer. The emission auxiliary part OG may include a charge generating layer. More particularly, the emission auxiliary part OG may include an electron transport region, a charge generating layer, and a hole transport region stacked in order. The emission auxiliary part OG may be provided as a common layer in all of the first to third light emitting devices ED-1, ED-2 and ED-3. However, one or more embodiments of the present disclosure is not limited thereto, and the emission auxiliary part OG may be patterned and provided in an opening part OH defined in a pixel definition layer PDL.

The first red emission layer EML-R1, the first green emission layer EML-G1 and the first blue emission layer EML-B1 may be provided between the electron transport region ETR and the emission auxiliary part OG. The second red emission layer EML-R2, the second green emission layer EML-G2 and the second blue emission layer EML-B2 may be provided between the emission auxiliary part OG and the hole transport region HTR.

For example, the first light emitting device ED-1 may include a first electrode EL1, a hole transport region HTR, a second red emission layer EML-R2, an emission auxiliary part OG, a first red emission layer EML-R1, an electron transport region ETR, and a second electrode EL2, stacked in order. The second light emitting device ED-2 may include a first electrode EL1, a hole transport region HTR, a second green emission layer EML-G2, an emission auxiliary part OG, a first green emission layer EML-G1, an electron transport region ETR, and a second electrode EL2, stacked in order. The third light emitting device ED-3 may include a first electrode EL1, a hole transport region HTR, a second blue emission layer EML-B2, an emission auxiliary part OG, a first blue emission layer EML-B1, an electron transport region ETR, and a second electrode EL2, stacked in order.

In some embodiments, an optical auxiliary layer PL may be provided on a display device layer DP-ED. The optical auxiliary layer PL may include a polarization layer. The optical auxiliary layer PL may be provided on a display panel DP and may control reflected light at the display panel DP by external light. Different from the drawings, the optical auxiliary layer PL may not be provided from the display apparatus according to one or more embodiments.

At least one emission layer included in the display apparatus DD-b of one or more embodiments, shown in FIG. 9 may include the fused polycyclic compound of one or more embodiments. For example, in one or more embodiments, at least one among a first blue emission layer EML-B1 and a second blue emission layer EML-B2 9 may include the fused polycyclic compound of one or more embodiments.

Different from FIG. 8 and FIG. 9, a display apparatus DD-c in FIG. 10 is shown to include four light emitting structures OL-B1, OL-B2, OL-B3 and OL-C1. A light emitting device ED-CT may include oppositely provided first electrode EL1 and second electrode EL2, and first to fourth light emitting structures OL-B1, OL-B2, OL-B3 and OL-C1 stacked in order in a thickness direction between the first electrode EL1 and the second electrode EL2. Between the first to fourth light emitting structures OL-B1, OL-B2, OL-B3 and OL-C1, charge generating layers CGL1, CGL2 and CGL3 may be provided. Among the four light emitting structures, the first to third light emitting structures OL-B1, OL-B2 and OL-B3 emit blue light, and the fourth light emitting structure OL-C1 may be to emit (e.g., configured to emit) green light. However, one or more embodiments of the present disclosure is not limited thereto, and the first to fourth light emitting structures OL-B1, OL-B2, OL-B3 and OL-C1 may be to emit (e.g., configured to emit) different wavelengths of light.

Charge generating layers CGL1, CGL2 and CGL3 provided among neighboring light emitting structures OL-B1, OL-B2, OL-B3 and OL-C1 may include a p-type or kind charge generating layer (p-charge generating layer) and/or an n-type or kind charge generating layer (n-charge generating layer).

In at least one selected from among the light emitting structures OL-B1, OL-B2, OL-B3 and OL-C1, included in the display device DD-c of one or more embodiments, the fused polycyclic compound of one or more embodiments may be included. For example, in one or more embodiments, at least one among the first to third light emitting structures OL-B1, OL-B2, and OL-B3 may include the fused polycyclic compound of one or more embodiments.

The light emitting element ED according to one or more embodiments of the present disclosure may include the fused polycyclic compound of one or more embodiments, represented by Formula 1 in at least one functional layer provided between a first electrode EL1 and a second electrode EL2 and may show excellent or suitable emission efficiency and improved lifetime characteristics. For example, the polycyclic compound according to one or more embodiments may be included in the emission layer EML of the light emitting element ED, and the light emitting element of one or more embodiments may show long lifetime characteristics.

In one or more embodiments, an electronic apparatus may include a display apparatus including multiple light emitting devices and a control part controlling the display apparatus. The electronic apparatus of one or more embodiments may be an apparatus activated according to electrical signals. The electronic apparatus may include display apparatuses of one or more suitable embodiments. For example, the electronic apparatus may include televisions, monitors, large-size display apparatuses such as outside billboards, personal computers, laptop computers, personal digital terminals, display apparatuses for automobiles, game consoles, portable electronic devices, medium- and small-size display apparatuses such as cameras.

FIG. 11 is a diagram showing an automobile AM in which first to fourth display apparatuses DD-1, DD-2, DD-3 and DD-4 are provided. At least one among the first to fourth display apparatuses DD-1, DD-2, DD-3 and DD-4 may include the same configurations of the display apparatuses DD, DD-TD, DD-a, DD-b and DD-c of embodiments, explained referring to FIGS. 1, 2, and 7 to 10.

In FIG. 11, a vehicle is shown as an automobile AM, but this is an illustration, and the first to fourth display apparatuses DD-1, DD-2, DD-3 and DD-4 may be provided on other transport refers to such as bicycles, motorcycles, trains, ships and airplanes. In some embodiments, at least one among the first to fourth display apparatuses DD-1, DD-2, DD-3 and DD-4 including the same configurations of the display apparatuses DD, DD-TD, DD-a, DD-b and DD-c may be introduced in personal computers, laptop computers, personal digital terminals, game consoles, portable electronic devices, televisions, monitors, external billboards, and/or the like. In some embodiments, these are suggested as examples, and the display apparatus may be introduced in other electronic devices as long as not deviated from the present disclosure.

At least one among the first to fourth display devices DD-1, DD-2, DD-3 and DD-4 may include the light emitting element ED of one or more embodiments, explained referring to FIG. 3 to FIG. 6. The light emitting element ED of one or more embodiments may include the fused polycyclic compound of one or more embodiments. At least one among the first to fourth display devices DD-1, DD-2, DD-3 and DD-4 may include the light emitting element ED including the fused polycyclic compound of one or more embodiments and may show improved display lifetime.

Referring to FIG. 11, an automobile AM may include a steering wheel HA for the operation of the automobile AM and a gear GR. In some embodiments, the automobile AM may include a front window GL provided to face a driver.

A first display apparatus DD-1 may be provided in a first region overlapping with the steering wheel HA. For example, the first display apparatus DD-1 may be a digital cluster displaying the first information of the automobile AM. The first information may include a first graduation showing the running speed of the automobile AM, a second graduation showing the number of revolution of an engine (i.e., revolutions per minute (RPM)), and images showing a fuel state. First graduation and second graduation may be represented by digital images.

A second display apparatus DD-2 may be provided in a second region facing a driver's seat and overlapping with the front window GL. The driver's seat may be a seat where the steering wheel HA is provided. For example, the second display apparatus DD-2 may be a head up display (HUD) showing the second information of the automobile AM. The second display apparatus DD-2 may be optically clear. The second information may include digital numbers showing the running speed of the automobile AM and may further include information including the current time. Different from the drawing, the second information of the second display apparatus DD-2 may be projected and displayed on the front window GL.

A third display apparatus DD-3 may be provided in a third region adjacent to the gear GR. For example, the third display apparatus DD-3 may be a center information display (CID) for an automobile, provided between a driver's seat and a passenger seat and showing third information. The passenger seat may be a seat separated from the driver's seat with the gear GR therebetween. The third information may include information on road conditions (for example, navigation information), on playing music or radio, on playing a dynamic image (or image), on the temperature in the automobile AM, and/or the like.

A fourth display apparatus DD-4 may be provided in a fourth region separated from the steering wheel HA and the gear GR and adjacent to the side of the automobile AM. For example, the fourth display apparatus DD-4 may be a digital wing mirror displaying fourth information. The fourth display apparatus DD-4 may display the external image of the automobile AM, taken by a camera module CM provided at the outside of the automobile AM. The fourth information may include the external image of the automobile AM.

The above-described first to fourth information is for illustration, and the first to fourth display apparatuses DD-1, DD-2, DD-3 and DD-4 may further display information on the inside and outside of the automobile. The first to fourth information may include different information from each other. However, one or more embodiments of the present disclosure is not limited thereto, and a portion of the first to fourth information may include the same information.

Terms such as “substantially,” “about,” and “approximately” are used as relative terms and not as terms of degree, and are intended to account for the inherent deviations in measured or calculated values that would be recognized by those of ordinary skill in the art. They may be inclusive of the stated value and an acceptable range of deviation as determined by one of ordinary skill in the art, considering the limitations and error associated with measurement of that quantity. For example, “about” may refer to one or more standard deviations, or ±30%, 20%, 10%, 5% of the stated value.

Numerical ranges disclosed herein include and are intended to disclose all subsumed sub-ranges of the same numerical precision. For example, a range of “1.0 to 10.0” includes all subranges having a minimum value equal to or greater than 1.0 and a maximum value equal to or less than 10.0, such as, for example, 2.4 to 7.6. Applicant therefore reserves the right to amend this specification, including the claims, to expressly recite any sub-range subsumed within the ranges expressly recited herein.

The light emitting element and/or any other relevant devices or components according to embodiments of the present disclosure described herein may be implemented utilizing any suitable hardware, firmware (e.g., an application-specific integrated circuit), software, or a combination of software, firmware, and hardware. For example, the various components of the light emitting element may be formed on one integrated circuit (IC) chip or on separate IC chips. Further, the various components of the element may be implemented on a flexible printed circuit film, a tape carrier package (TCP), a printed circuit board (PCB), or formed on one substrate. Further, the various components of the element may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

In the present disclosure, when particles are spherical, “diameter” indicates an average particle diameter, and when the particles are non-spherical, the “diameter” indicates a major axis length. The diameter (or size) of the particles may be measured by particle size analysis, dynamic light scattering, scanning electron microscopy, and/or transmission electron microscope photography. When the size of the particles is measured utilizing a particle size analyzer, the average particle diameter (or size) may be referred to as D50. The term “D50” as utilized herein refers to the average diameter (or size) of particles whose cumulative volume corresponds to 50 vol % in the particle size distribution (e.g., cumulative distribution), and refers to the value of the particle size corresponding to 50% from the smallest particle when the total number of particles is 100% in the distribution curve accumulated in the order of the smallest particle size to the largest particle size. Particle size analysis may be performed with a HORIBA LA-950 laser particle size analyzer.

Hereinafter, the fused polycyclic compound according to one or more embodiments and the light emitting element according to one or more embodiments of the present disclosure will be particularly explained referring to embodiments and comparative embodiments. In some embodiments, the embodiments are only illustrations to assist the understanding of the present disclosure, and the scope of the present disclosure is not limited thereto.

### Examples

### 1. Synthesis of Fused Polycyclic Compound

First, the synthetic method of the fused polycyclic compound according to one or more embodiments will be explained by illustrating the synthetic methods (e.g., the synthesis) of Compounds 1, 3, 4, 7, 8, 16, 23, 25, 26, 33, and 353. For example, the synthetic methods of the fused polycyclic compounds explained hereinafter are embodiments, and the synthetic method of the fused polycyclic compound according to one or more embodiments of the present disclosure is not limited to the embodiments.

### (1) Synthesis of Compound 1

Fused Polycyclic Compound 1 according to one or more embodiments may be synthesized by, for example, the reactions.

### Synthesis of Intermediate 3A

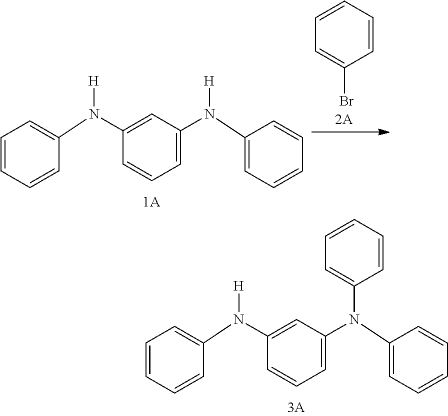 [SMILES: c1ccc(Nc2cccc(Nc3ccccc3)c2)cc1 ; Brc1ccccc1 ; c1ccc(Nc2cccc(N(c3ccccc3)c3ccccc3)c2)cc1]

Under an Ar atmosphere, to a 2000 mL, three-neck flask, Intermediate 1A (100 g), Intermediate 2A (bromobenzene, 60.4 g), bis(dibenzylideneacetone)palladium(0) (Pd(dba)₂, 4.42 g), tri-tert-butylphosphine (4.46 g), sodium tert-butoxide (NaOtBu, 44 g), and toluene (800 mL) were added, and heated and stirred at about 60° C. for about 6 hours. After restoring the temperature to room temperature, water was added, extraction with toluene was performed, and organic layers were collected and dried over MgSO₄. Then, the solvent was removed by distillation under a reduced pressure. The resultant was purified by silica gel column chromatography to obtain 76.8 g of Intermediate 3A (yield 60%). The mass number of Intermediate 3A measured through FAB-MS measurement was 336.

### Synthesis of Intermediate 5A

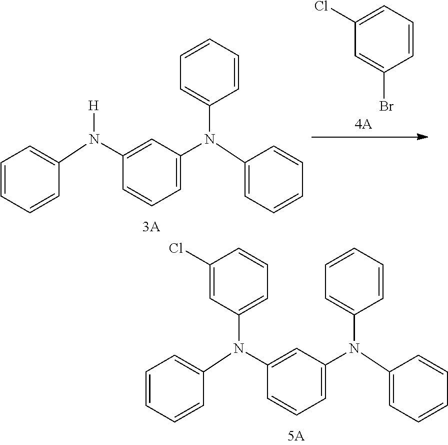 [SMILES: c1ccc(Nc2cccc(N(c3ccccc3)c3ccccc3)c2)cc1 ; Clc1cccc(Br)c1 ; Clc1cccc(N(c2ccccc2)c2cccc(N(c3ccccc3)c3ccccc3)c2)c1]

Under an Ar atmosphere, to a 1000 mL, three-neck flask, Intermediate 3A (76.8 g), Intermediate 4A (1-bromo-3-chlorobenzene, 52.4 g), bis(dibenzylideneacetone)palladium(0) (Pd(dba)₂, 2.62 g), tri-tert-butylphosphine (2.64 g), sodium tert-butoxide (NaOtBu, 26.2 g), and toluene (800 mL) were added, and heated and stirred at about 60° C. for about 6 hours. After restoring the temperature to room temperature, water was added, extraction with toluene was performed, and organic layers were collected and dried over MgSO₄. Then, the solvent was removed by distillation under a reduced pressure. The resultant was purified by silica gel column chromatography to obtain 89.8 g of Intermediate 5A (yield 88%). The mass number of Intermediate 5A measured through FAB-MS measurement was 447.

### Synthesis of Intermediate 6A

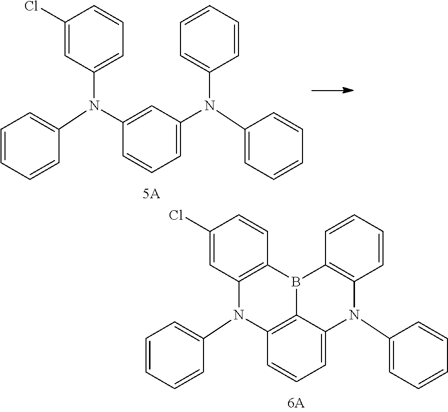 [SMILES: Clc1cccc(N(c2ccccc2)c2cccc(N(c3ccccc3)c3ccccc3)c2)c1 ; Clc1ccc2c(c1)N(c1ccccc1)c1cccc3c1B2c1ccccc1N3c1ccccc1]

Under an Ar atmosphere, to a 1000 mL, three-neck flask, Intermediate 5A (89.8 g) was added and dissolved in o-dichlorobenzene (ODCB, 300 mL). The flask was cooled to about 0° C. in an ice bath, and boron triiodide (Bl₃, 147.4 g) was added thereto, followed by heating and stirring at about 160° C. for about 6 hours. The flask was cooled to about 0° C. in an ice bath, and N, N-diisopropylethylamine (DIPEA, 280 mL) was added thereto. After restoring the temperature to room temperature, the reaction solution was filtered by silica gel, and the solvent of the filtrate was removed by distillation under a reduced pressure. The crude product thus obtained was purified by silica gel column chromatography (Preparative HPLC, eluent: CH₂Cl₂), and recrystallization in toluene to obtain 18.2 g of Intermediate 6A (yield 20%). The mass number of Intermediate 6A measured through FAB-MS measurement was 445.

### Synthesis of Compound 1

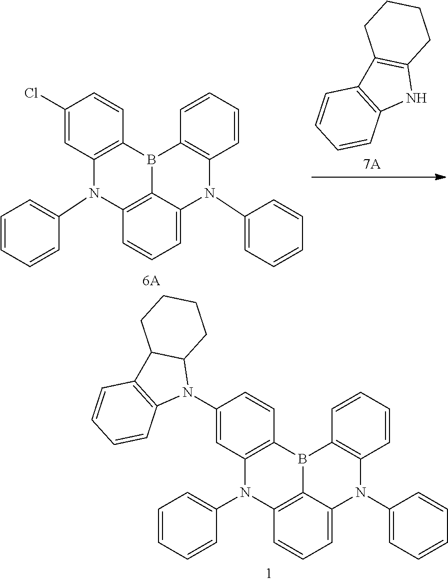

1 Under an Ar atmosphere, to a 500 mL, three-neck flask, Intermediate 6A (3 g), Intermediate 7A (1,2,3,4-Tetrahydrocarbazole, 3.4 g), bis(dibenzylideneacetone)palladium(0) (Pd(dba)₂, 0.50 g), tri-tert-butylphosphine (0.51 g), sodium tert-butoxide (NaOtBu, 1.7 g), and toluene (100 mL) were added, and heated and stirred at about 120° C. for about 6 hours. After restoring the temperature to room temperature, water was added, extraction with toluene was performed, and organic layers were collected and dried over MgSO₄. The solvent was removed by distillation under a reduced pressure. The resultant was purified by silica gel column chromatography to obtain 3.1 g of Compound 1 (yield 80%). The mass number of Compound 1 measured through FAB-MS measurement was 590.

### (2) Synthesis of Compound 3

Fused Polycyclic Compound 3 according to one or more embodiments may be synthesized by, for example, the reaction.

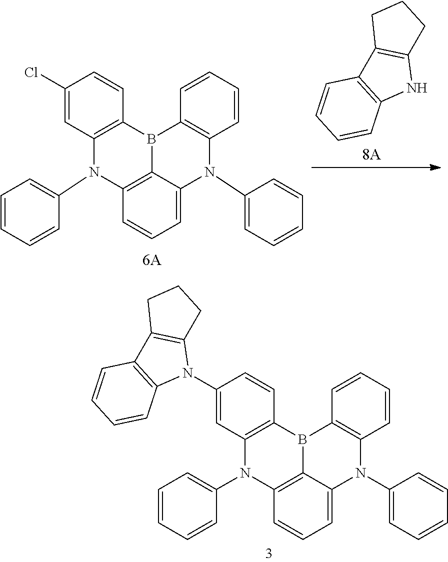 [SMILES: Clc1ccc2c(c1)N(c1ccccc1)c1cccc3c1B2c1ccccc1N3c1ccccc1 ; c1ccc2c3c([nH]c2c1)CCC3 ; c1ccc(N2c3ccccc3B3c4ccc(-n5c6c(c7ccccc75)CCC6)cc4N(c4ccccc4)c4cccc2c43)cc1]

Under an Ar atmosphere, to a 500 mL, three-neck flask, Intermediate 6A (3 g), Intermediate 8A (1,2,3,4-tetrahydrocyclopenta[b]indole, 3.4 g), bis(dibenzylideneacetone)palladium(0) (Pd(dba)₂, 0.44 g), tri-tert-butylphosphine (0.44 g), sodium tert-butoxide (NaOtBu, 1.1 g), and toluene (100 mL) were added, and heated and stirred at about 120° C. for about 6 hours. After restoring the temperature to room temperature, water was added, extraction with toluene was performed, and organic layers were collected and dried over MgSO₄. The solvent was removed by distillation under a reduced pressure. The resultant was purified by silica gel column chromatography to obtain 3 g of Compound 3 (yield 80%). The mass number of Compound 3 measured through FAB-MS measurement was 576.

### (3) Synthesis of Compound 4

Fused Polycyclic Compound 4 according to one or more embodiments may be synthesized by, for example, the reaction.

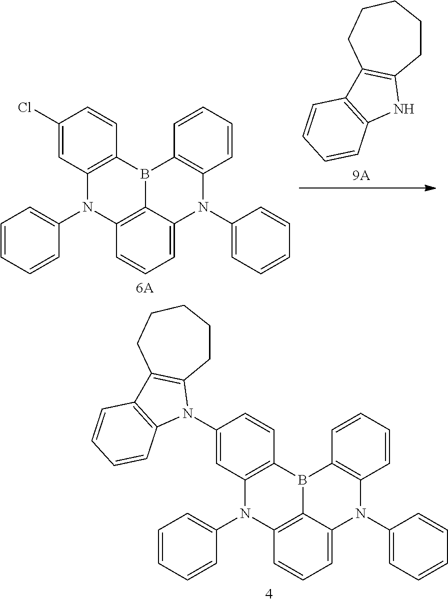

Under an Ar atmosphere, to a 500 mL, three-neck flask, Intermediate 6A (3 g), Intermediate 9A (3.6 g), bis(dibenzylideneacetone)palladium(0) (Pd(dba)₂, 0.44 g), tri-tert-butylphosphine (0.44 g), sodium tert-butoxide (NaOtBu, 1.1 g), and toluene (100 mL) were added, and heated and stirred at about 120° C. for about 6 hours. After restoring the temperature to room temperature, water was added, extraction with toluene was performed, and organic layers were collected and dried over MgSO₄. The solvent was removed by distillation under a reduced pressure. The resultant was purified by silica gel column chromatography to obtain 3 g of Compound 4 (yield 75%). The mass number of Compound 4 measured through FAB-MS measurement was 604.

### (4) Synthesis of Compound 7

Fused Polycyclic Compound 7 according to one or more embodiments may be synthesized by, for example, the reaction.

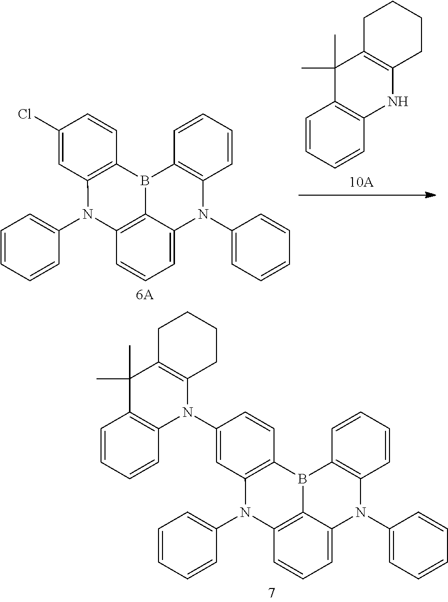 [SMILES: Clc1ccc2c(c1)N(c1ccccc1)c1cccc3c1B2c1ccccc1N3c1ccccc1 ; CC1(C)C2=C(CCCC2)Nc2ccccc21 ; CC1(C)C2=C(CCCC2)N(c2ccc3c(c2)N(c2ccccc2)c2cccc4c2B3c2ccccc2N4c2ccccc2)c2ccccc21]

Under an Ar atmosphere, to a 500 mL, three-neck flask, Intermediate 6A (3 g), Intermediate 10A (3.8 g), bis(dibenzylideneacetone)palladium(0) (Pd(dba)₂, 0.44 g), tri-tert-butylphosphine (0.44 g), sodium tert-butoxide (NaOtBu, 1.1 g), and toluene (100 mL) were added, and heated and stirred at about 120° C. for about 6 hours. After restoring the temperature to room temperature, water was added, extraction with toluene was performed, and organic layers were collected and dried over MgSO₄. The solvent was removed by distillation under a reduced pressure. The resultant was purified by silica gel column chromatography to obtain 3.2 g of Compound 7 (yield 77%). The mass number of Compound 7 measured through FAB-MS measurement was 632.

### (5) Synthesis of Compound 8

Fused Polycyclic Compound 8 according to one or more embodiments may be synthesized by, for example, the reaction.

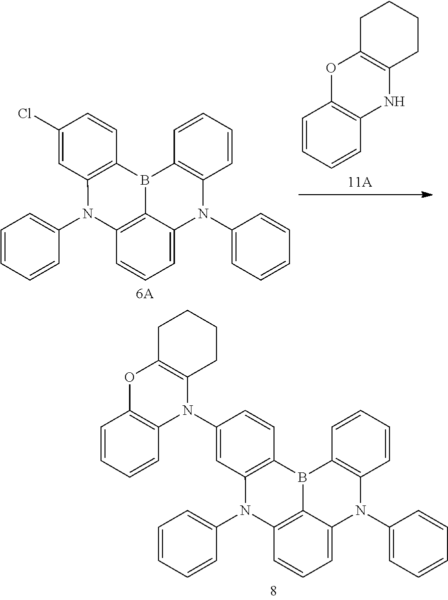 [SMILES: Clc1ccc2c(c1)N(c1ccccc1)c1cccc3c1B2c1ccccc1N3c1ccccc1 ; c1ccc2c(c1)NC1=C(CCCC1)O2 ; c1ccc(N2c3ccccc3B3c4ccc(N5C6=C(CCCC6)Oc6ccccc65)cc4N(c4ccccc4)c4cccc2c43)cc1]

Under an Ar atmosphere, to a 500 mL, three-neck flask, Intermediate 6A (3 g), Intermediate 11A (3.8 g), bis(dibenzylideneacetone)palladium(0) (Pd(dba)₂, 0.44 g), tri-tert-butylphosphine (0.44 g), sodium tert-butoxide (NaOtBu, 1.1 g), and toluene (100 mL) were added, and heated and stirred at about 120° C. for about 6 hours. After restoring the temperature to room temperature, water was added, extraction with toluene was performed, and organic layers were collected and dried over MgSO₄. The solvent was removed by distillation under a reduced pressure. The resultant was purified by silica gel column chromatography to obtain 3.4 g of Compound 8 (yield 85%). The mass number of Compound 8 measured through FAB-MS measurement was 606.

### (6) Synthesis of Compound 16

Fused Polycyclic Compound 16 according to one or more embodiments may be synthesized by, for example, the reactions.

### Synthesis of Intermediate 14A

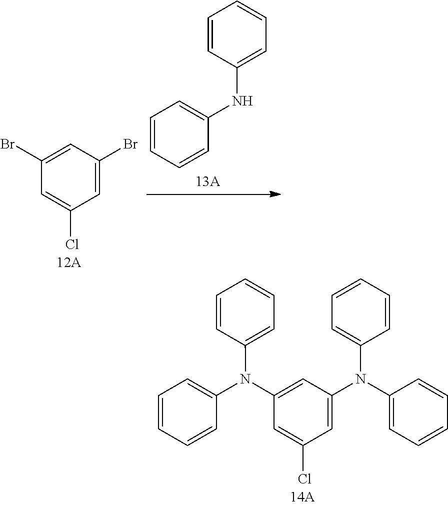

Under an Ar atmosphere, to a 2000 mL, three-neck flask, Intermediate 12A (1,3-dibromo-5-chlorobenzene, 30 g), Intermediate 13A (bis(4-(tert-butyl)phenyl)amine, 56 g), bis(dibenzylideneacetone)palladium(0) (Pd(dba)₂, 1.91 g), tri-tert-butylphosphine (1.93 g), sodium tert-butoxide (NaOtBu, 26.6 g), and toluene (700 mL) were added, and heated and stirred at about 60° C. for about 6 hours. After restoring the temperature to room temperature, water was added, extraction with toluene was performed, and organic layers were collected and dried over MgSO₄. The solvent was removed by distillation under a reduced pressure. The resultant was purified by silica gel column chromatography to obtain 42 g of Intermediate 14A (yield 84%). The mass number of Intermediate 14A measured through FAB-MS measurement was 447.

### Synthesis of Intermediate 15A

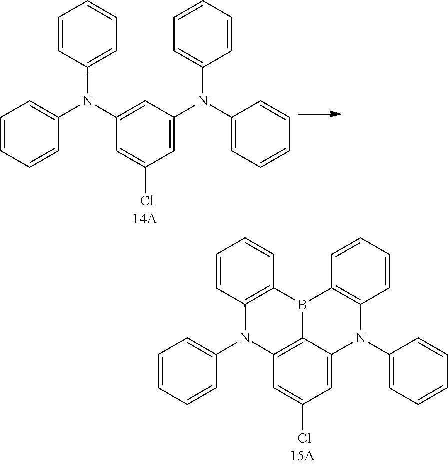 [SMILES: Clc1cc(N(c2ccccc2)c2ccccc2)cc(N(c2ccccc2)c2ccccc2)c1 ; Clc1cc2c3c(c1)N(c1ccccc1)c1ccccc1B3c1ccccc1N2c1ccccc1]

Under an Ar atmosphere, to a 1000 mL, three-neck flask, Intermediate 14A (42 g) was added and dissolved in o-dichlorobenzene (ODCB, 200 mL). The flask was cooled to about 0° C. in an ice bath, and boron triiodide (Bl₃, 70 g) was added thereto, followed by heating and stirring at about 160° C. for about 6 hours. The flask was cooled to about 0° C. in an ice bath, and N, N-diisopropylethylamine (DIPEA, 127 mL) was added thereto. After restoring the temperature to room temperature, the reaction solution was filtered by silica gel, and the solvent of the filtrate was removed by distillation under a reduced pressure. The crude product thus obtained was purified by silica gel column chromatography (Preparative HPLC, eluent: CH₂Cl₂), and recrystallization in toluene to obtain 8.6 g of Intermediate 15A (yield 20%). The mass number of Intermediate 15A measured through FAB-MS measurement was 455.

### Synthesis of Compound 16

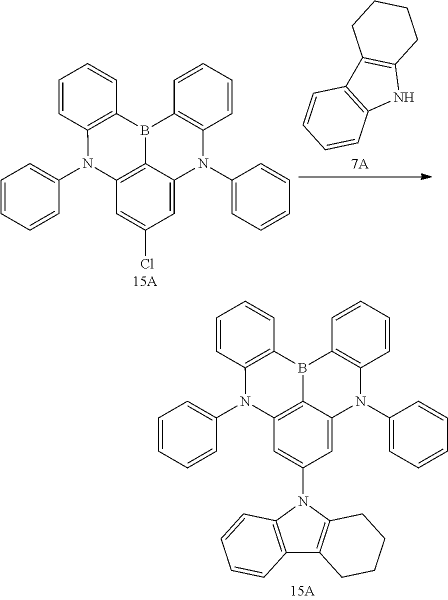 [SMILES: Clc1cc2c3c(c1)N(c1ccccc1)c1ccccc1B3c1ccccc1N2c1ccccc1 ; c1ccc2c3c([nH]c2c1)CCCC3 ; c1ccc(N2c3ccccc3B3c4ccccc4N(c4ccccc4)c4cc(-n5c6c(c7ccccc75)CCCC6)cc2c43)cc1]

Under an Ar atmosphere, to a 500 mL, three-neck flask, Intermediate 15A (3 g), Intermediate 7A (1,2,3,4-tetrahydrocarbazole, 3.4 g), bis(dibenzylideneacetone)palladium(0) (Pd(dba)₂, 0.50 g), tri-tert-butylphosphine (0.51 g), sodium tert-butoxide (NaOtBu, 1.7 g), and toluene (100 mL) were added, and heated and stirred at about 120° C. for about 6 hours. After restoring the temperature to room temperature, water was added, extraction with toluene was performed, and organic layers were collected and dried over MgSO₄. The solvent was removed by distillation under a reduced pressure. The resultant was purified by silica gel column chromatography to obtain 3.1 g of Compound 16 (yield 80%). The mass number of Compound 16 measured through FAB-MS measurement was 590.

### (7) Synthesis of Compound 23

Fused Polycyclic Compound 23 according to one or more embodiments may be synthesized by, for example, the reactions.

### Synthesis of Intermediate 17A

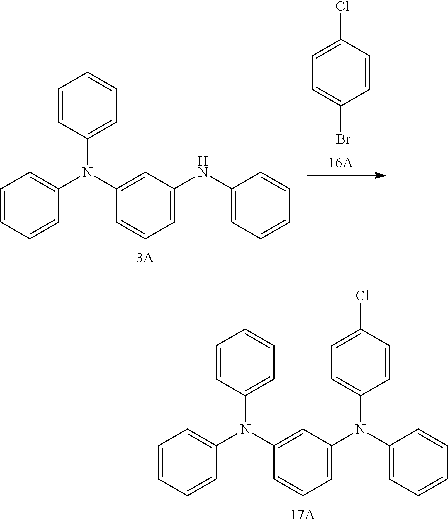 [SMILES: c1ccc(Nc2cccc(N(c3ccccc3)c3ccccc3)c2)cc1 ; Clc1ccc(Br)cc1 ; Clc1ccc(N(c2ccccc2)c2cccc(N(c3ccccc3)c3ccccc3)c2)cc1]

Under an Ar atmosphere, to a 1000 mL, three-neck flask, Intermediate 3A (76.8 g), Intermediate 16A (1-bromo-3-chlorobenzene, 52.4 g), bis(dibenzylideneacetone)palladium(0) (Pd(dba)₂, 2.62 g), tri-tert-butylphosphine (2.64 g), sodium tert-butoxide (NaOtBu, 26.2 g), and toluene (800 mL) were added, and heated and stirred at about 60° C. for about 6 hours. After restoring the temperature to room temperature, water was added, extraction with toluene was performed, and organic layers were collected and dried over MgSO₄. The solvent was removed by distillation under a reduced pressure. The resultant was purified by silica gel column chromatography to obtain 89.8 g of Intermediate 17A (yield 88%). The mass number of Intermediate 17A measured through FAB-MS measurement was 447.

### Synthesis of Intermediate 18A

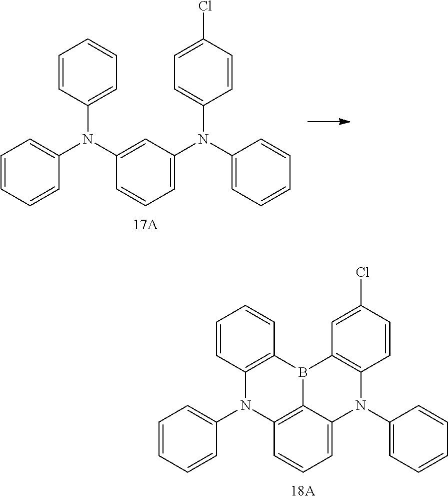 [SMILES: Clc1ccc(N(c2ccccc2)c2cccc(N(c3ccccc3)c3ccccc3)c2)cc1 ; Clc1ccc2c(c1)B1c3ccccc3N(c3ccccc3)c3cccc(c31)N2c1ccccc1]

Under an Ar atmosphere, to a 1000 mL, three-neck flask, Intermediate 18A (89.8 g) was added and dissolved in o-dichlorobenzene (ODCB, 300 mL). The flask was cooled to about 0° C. in an ice bath, and boron triiodide (Bl₃, 147.4 g) was added thereto, followed by heating and stirring at about 160° C. for about 6 hours. The flask was cooled to about 0° C. in an ice bath, and N, N-diisopropylethylamine (DIPEA, 280 mL) was added thereto. After restoring the temperature to room temperature, the reaction solution was filtered by silica gel, and the solvent of the filtrate was removed by distillation under a reduced pressure. The crude product thus obtained was purified by silica gel column chromatography (Preparative HPLC, eluent: CH₂Cl₂), and recrystallization in toluene to obtain 18.2 g of Intermediate 18A (yield 20%). The mass number of Intermediate 18A measured through FAB-MS measurement was 455.

### Synthesis of Compound 23

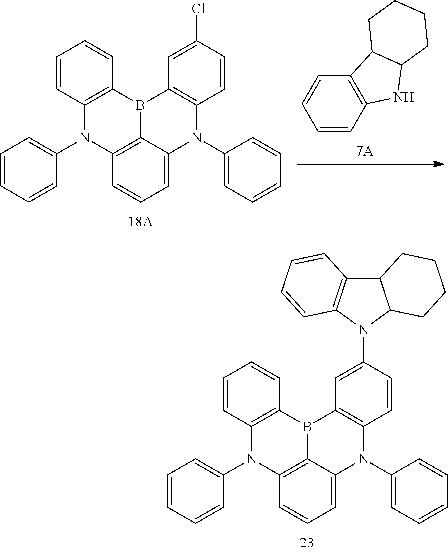

Under an Ar atmosphere, to a 500 mL, three-neck flask, Intermediate 18A (3 g), Intermediate 7A (1,2,3,4-tetrahydrocarbazole, 3.4 g), bis(dibenzylideneacetone)palladium(0) (Pd(dba)₂, 0.50 g), tri-tert-butylphosphine (0.51 g), sodium tert-butoxide (NaOtBu, 1.7 g), and toluene (100 mL) were added, and heated and stirred at about 120° C. for about 6 hours. After restoring the temperature to room temperature, water was added, extraction with toluene was performed, and organic layers were collected and dried over MgSO₄. The solvent was removed by distillation under a reduced pressure. The resultant was purified by silica gel column chromatography to obtain 3.1 g of Compound 23 (yield 80%). The mass number of Compound 23 measured through FAB-MS measurement was 590.

### (8) Synthesis of Compound 25

Fused Polycyclic Compound 25 according to one or more embodiments may be synthesized by, for example, the reactions.

### Synthesis of Intermediate 21A

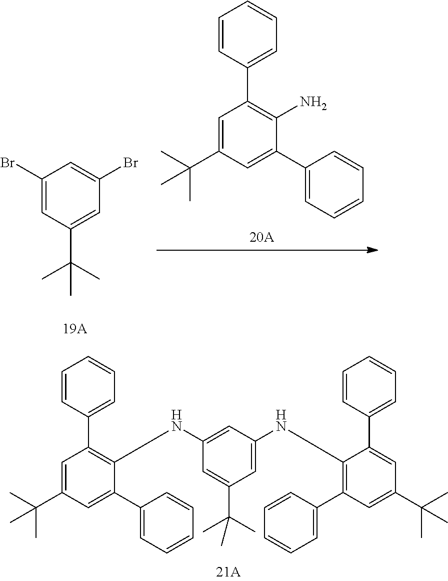

Under an Ar atmosphere, to a 2000 mL, three-neck flask, Intermediate 19A (1,3-dibromo-5-tert-butylbenzene, 50 g), Intermediate 20A (103 g), bis(dibenzylideneacetone)palladium(0) (Pd(dba)₂, 2.95 g), tri-tert-butylphosphine (2.98 g), sodium tert-butoxide (NaOtBu, 41.1 g), and toluene (700 mL) were added, and heated and stirred at about 60° C. for about 6 hours. After restoring the temperature to room temperature, water was added, extraction with toluene was performed, and organic layers were collected and dried over MgSO₄. The solvent was removed by distillation under a reduced pressure. The resultant was purified by silica gel column chromatography to obtain 110 g of Intermediate 21A (yield 88%). The mass number of Intermediate 21A measured through FAB-MS measurement was 733.

### Synthesis of Intermediate 23A

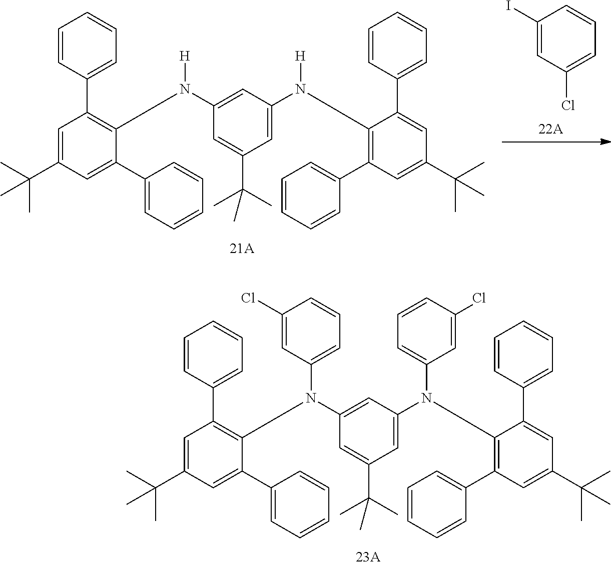

Under an Ar atmosphere, to a 1000 mL, three-neck flask, Intermediate 21A (110 g), 1-chloro-3-iodobenzene (22A, 286 g), CuI (60 g), and K₂CO₃ (124 g) were added, followed by heating and stirring at about 210° C. for about 32 hours. After restoring the temperature to room temperature, water was added, extraction with CH₂Cl₂ was performed, and organic layers were collected and dried over MgSO₄. The solvent was removed by distillation under a reduced pressure. The resultant was purified by silica gel column chromatography to obtain 100 g of Intermediate 23A (yield 70%). The mass number of Intermediate 23A measured through FAB-MS measurement was 954.

### Synthesis of Intermediate 24A

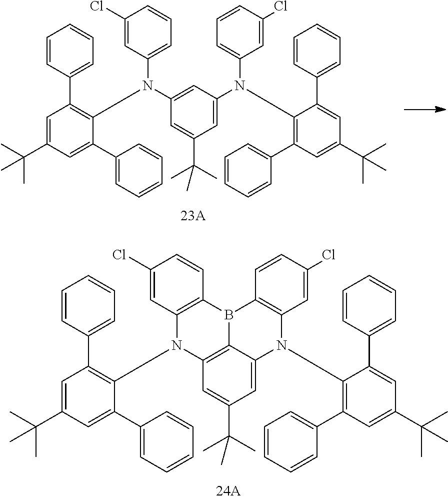

Under an Ar atmosphere, to a 1000 mL, three-neck flask, Intermediate 23A (110 g) was added and dissolved in o-dichlorobenzene (ODCB, 200 mL). The flask was cooled to about 0° C. in an ice bath, and boron triiodide (Bl₃, 90.3 g) was added thereto, followed by heating and stirring at about 160° C. for about 6 hours. The flask was cooled to about 0° C. in an ice bath, and N, N-diisopropylethylamine (DIPEA, 160 mL) was added thereto. After restoring the temperature to room temperature, the reaction solution was filtered by silica gel, and the solvent of the filtrate was removed by distillation under a reduced pressure. The crude product thus obtained was purified by silica gel column chromatography (Preparative HPLC, eluent: CH₂Cl₂), and recrystallization in toluene to obtain 18.7 g of Intermediate 24A (yield 17%). The mass number of Intermediate 24A measured through FAB-MS measurement was 962.

### Synthesis of Compound 25

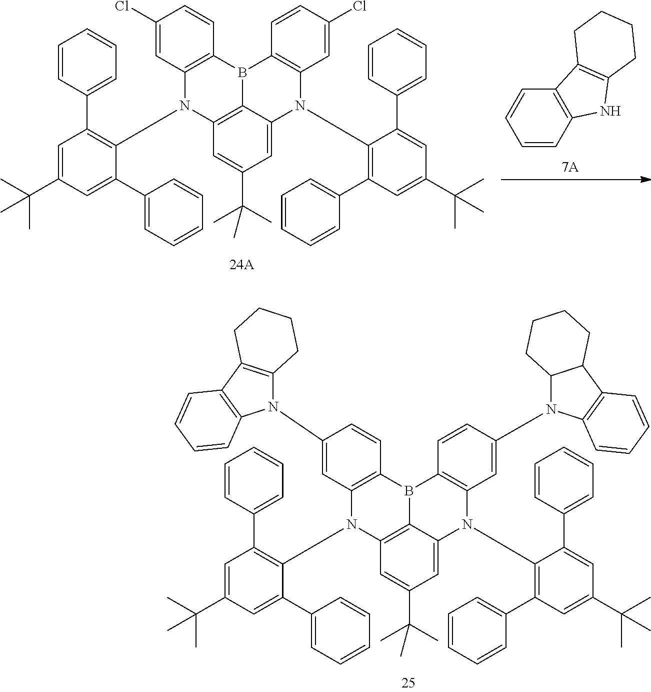

Under an Ar atmosphere, to a 500 mL, three-neck flask, Intermediate 24A (4 g), Intermediate 7A (2.1 g), bis(dibenzylideneacetone)palladium(0) (Pd(dba)₂, 0.24 g), tri-tert-butylphosphine (0.24 g), sodium tert-butoxide (NaOtBu, 1.2 g), and toluene (100 mL) were added, and heated and stirred at about 120° C. for about 6 hours. After restoring the temperature to room temperature, water was added, extraction with toluene was performed, and organic layers were collected and dried over MgSO₄. The solvent was removed by distillation under a reduced pressure. The resultant was purified by silica gel column chromatography to obtain 4 g of Compound 25 (yield 79%). The mass number of Compound 25 measured through FAB-MS measurement was 1231.

### (9) Synthesis of Compound 26

Fused Polycyclic Compound 26 according to one or more embodiments may be synthesized by, for example, the reaction.

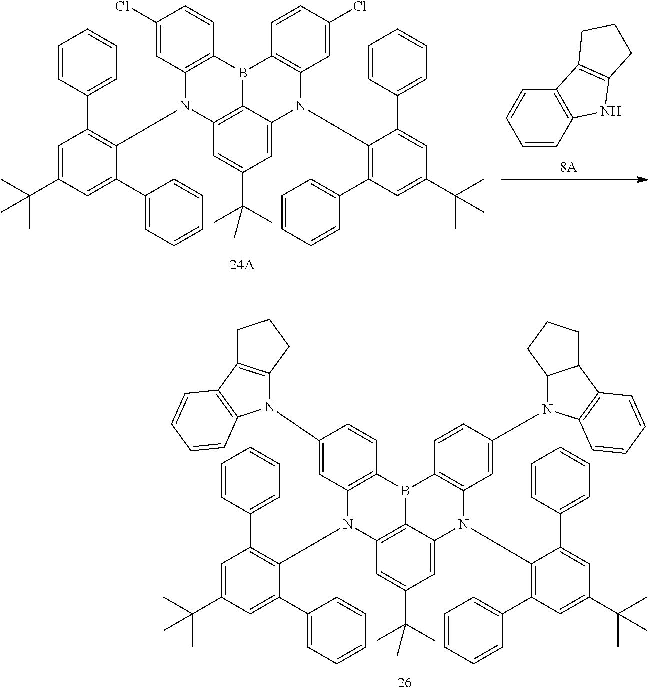

Under an Ar atmosphere, to a 500 mL, three-neck flask, Intermediate 23A (4 g), Intermediate 8A (2.1 g), bis(dibenzylideneacetone)palladium(0) (Pd(dba)₂, 0.24 g), tri-tert-butylphosphine (0.24 g), sodium tert-butoxide (NaOtBu, 1.2 g), and toluene (100 mL) were added, and heated and stirred at about 120° C. for about 6 hours. After restoring the temperature to room temperature, water was added, extraction with toluene was performed, and organic layers were collected and dried over MgSO₄. The solvent was removed by distillation under a reduced pressure. The resultant was purified by silica gel column chromatography to obtain 3.9 g of Compound 26 (yield 79%). The mass number of Compound 26 measured through FAB-MS measurement was 1203.

### (10) Synthesis of Compound 33

Fused Polycyclic Compound 33 according to one or more embodiments may be synthesized by, for example, the reactions.

### Synthesis of Intermediate 27A

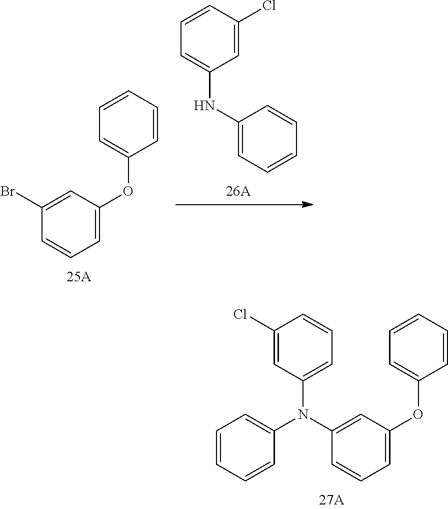 [SMILES: Brc1cccc(Oc2ccccc2)c1 ; Clc1cccc(Nc2ccccc2)c1 ; Clc1cccc(N(c2ccccc2)c2cccc(Oc3ccccc3)c2)c1]

Under an Ar atmosphere, to a 2000 mL, three-neck flask, Intermediate 25A (20 g), Intermediate 26A (3-chlorodiphenylamine, 20 g), bis(dibenzylideneacetone)palladium(0) (Pd(dba)₂, 1.39 g), tri-tert-butylphosphine (1.40 g), sodium tert-butoxide (NaOtBu, 15.4 g), and toluene (700 mL) were added, and heated and stirred at about 60° C. for about 6 hours. After restoring the temperature to room temperature, water was added, extraction with toluene was performed, and organic layers were collected and dried over MgSO₄. The solvent was removed by distillation under a reduced pressure. The resultant was purified by silica gel column chromatography to obtain 24 g of Intermediate 27A (yield 80%). The mass number of Intermediate 27A measured through FAB-MS measurement was 372.

### Synthesis of Intermediate 28A

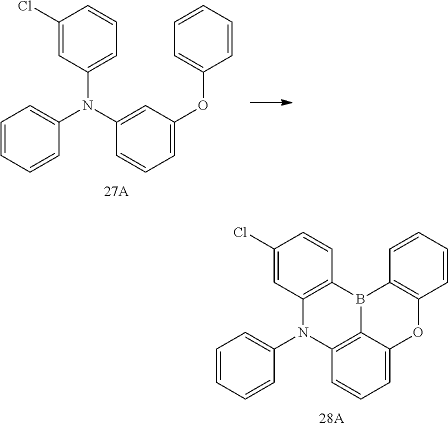 [SMILES: Clc1cccc(N(c2ccccc2)c2cccc(Oc3ccccc3)c2)c1 ; Clc1ccc2c(c1)N(c1ccccc1)c1cccc3c1B2c1ccccc1O3]

Under an Ar atmosphere, to a 1000 mL, three-neck flask, Intermediate 27A (24 g) was added and dissolved in o-dichlorobenzene (ODCB, 200 mL). The flask was cooled to about 0° C. in an ice bath, and boron triiodide (Bl₃, 50 g) was added thereto, followed by heating and stirring at about 160° C. for about 6 hours. The flask was cooled to about 0° C. in an ice bath, and N,N-diisopropylethylamine (DIPEA, 160 mL) was added thereto. After restoring the temperature to room temperature, the reaction solution was filtered by silica gel, and the solvent of the filtrate was removed by distillation under a reduced pressure. The crude product thus obtained was purified by silica gel column chromatography (Preparative HPLC, eluent: CH₂Cl₂), and recrystallization in toluene to obtain 4.2 g of Intermediate 28A (yield 17%). The mass number of Intermediate 28A measured through FAB-MS measurement was 380.

### Synthesis of Compound 33

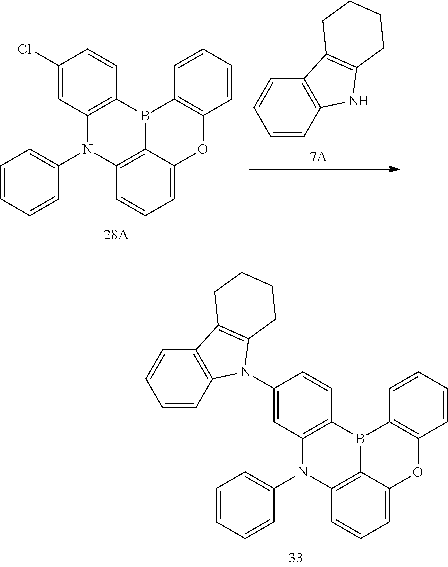

Under an Ar atmosphere, to a 500 mL, three-neck flask, Intermediate 28A (4.2 g), Intermediate 7A (1,2,3,4-tetrahydrocarbazole, 5.7 g), bis(dibenzylideneacetone)palladium(0) (Pd(dba)₂, 0.65 g), tri-tert-butylphosphine (0.65 g), sodium tert-butoxide (NaOtBu, 3.3 g), and toluene (100 mL) were added, and heated and stirred at about 120° C. for about 6 hours. After restoring the temperature to room temperature, water was added, extraction with toluene was performed, and organic layers were collected and dried over MgSO₄. The solvent was removed by distillation under a reduced pressure. The resultant was purified by silica gel column chromatography to obtain 4.6 g of Compound 33 (yield 80%). The mass number of Compound 33 measured through FAB-MS measurement was 514.

### (11) Synthesis of Compound 353

Fused Polycyclic Compound 353 according to one or more embodiments may be synthesized by, for example, the reactions.

### Synthesis of Intermediate 31A

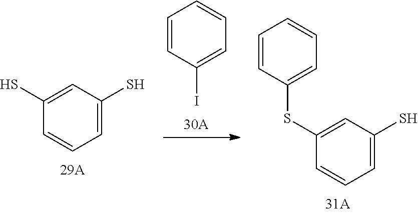

Under an Ar atmosphere, to a 2000 mL, three-neck flask, Intermediate 29A (20 g), Intermediate 30A (iodobenzene, 29 g), CuI (27 g), K₂CO₃ (20 g), and DMF (500 mL) were added, and heated and stirred at about 210° C. for about 32 hours. After restoring the temperature to room temperature, water was added, extraction with CH₂Cl₂ was performed, and organic layers were collected and dried over MgSO₄. The solvent was removed by distillation under a reduced pressure. The resultant was purified by silica gel column chromatography to obtain 18 g of Intermediate 31A (yield 60%). The mass number of Intermediate 31A measured through FAB-MS measurement was 218.

### Synthesis of Intermediate 32A

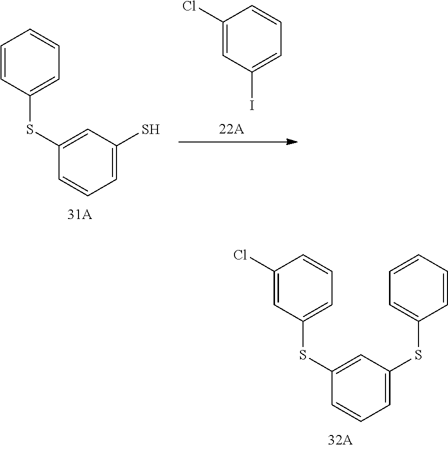 [SMILES: Sc1cccc(Sc2ccccc2)c1 ; Clc1cccc(I)c1 ; Clc1cccc(Sc2cccc(Sc3ccccc3)c2)c1]

Under an Ar atmosphere, to a 2000 mL, three-neck flask, Intermediate 31A (18 g), Intermediate 22A (20 g), CuI (16 g), K₂CO₃ (12 g), and DMF (500 mL) were added, and heated and stirred at about 210° C. for about 32 hours. After restoring the temperature to room temperature, water was added, extraction with CH₂Cl₂ was performed, and organic layers were collected and dried over MgSO₄. The solvent was removed by distillation under a reduced pressure. The resultant was purified by silica gel column chromatography to obtain 24.4 g of Intermediate 32A (yield 90%). The mass number of Intermediate 32A measured through FAB-MS measurement was 329.

### Synthesis of Intermediate 33A

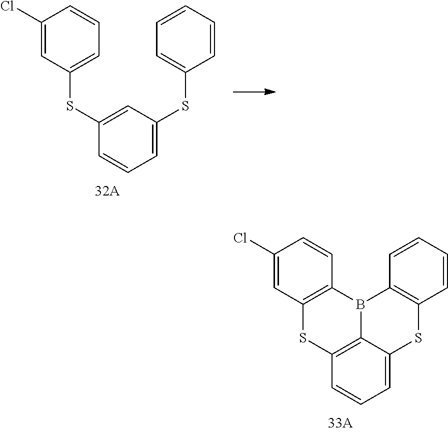 [SMILES: Clc1cccc(Sc2cccc(Sc3ccccc3)c2)c1 ; Clc1ccc2c(c1)Sc1cccc3c1B2c1ccccc1S3]

Under an Ar atmosphere, to a 1000 mL, three-neck flask, Intermediate 32A (24 g) was added and dissolved in o-dichlorobenzene (ODCB, 200 mL). The flask was cooled to about 0° C. in an ice bath, and boron triiodide (Bl₃, 64 g) was added thereto, followed by heating and stirring at about 160° C. for about 6 hours. The flask was cooled to about 0° C. in an ice bath, and N, N-diisopropylethylamine (DIPEA, 160 mL) was added thereto. After restoring the temperature to room temperature, the reaction solution was filtered by silica gel, and the solvent of the filtrate was removed by distillation under a reduced pressure. The crude product thus obtained was purified by silica gel column chromatography (Preparative HPLC, eluent: CH₂Cl₂), and recrystallization in toluene to obtain 4.2 g of Intermediate 33A (yield 17%). The mass number of Intermediate 33A measured through FAB-MS measurement was 337.

### Synthesis of Compound 353

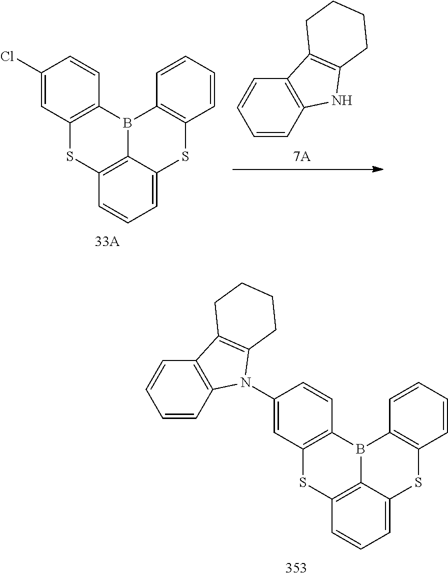

Under an Ar atmosphere, to a 500 mL, three-neck flask, Intermediate 33A (4.2 g), Intermediate 7A (1,2,3,4-tetrahydrocarbazole, 6.4 g), bis(dibenzylideneacetone)palladium(0) (Pd(dba)₂, 0.72 g), tri-tert-butylphosphine (0.72 g), sodium tert-butoxide (NaOtBu, 3.6 g), and toluene (100 mL) were added, and heated and stirred at about 120° C. for about 6 hours. After restoring the temperature to room temperature, water was added, extraction with toluene was performed, and organic layers were collected and dried over MgSO₄. The solvent was removed by distillation under a reduced pressure. The resultant was purified by silica gel column chromatography to obtain 4.7 g of Compound 353 (yield 80%). The mass number of Compound 353 measured through FAB-MS measurement was 471.

### 2. Manufacture and Evaluation of Light Emitting Element

### (1) Manufacture of Light Emitting Elements

The light emitting element of one or more embodiments, including the fused polycyclic compound of one or more embodiments in an emission layer was manufactured by a method. Light emitting elements of Example 1 to Example 11 were manufactured utilizing the fused polycyclic compounds of Example Compounds 1, 3, 4, 7, 8, 16, 23, 25, 26, 33, and 353 as the dopant materials of emission layers. Comparative Example 1 to Comparative Example 9 correspond to light emitting elements manufactured utilizing Comparative Compound X-1 to Comparative Compound X-9 as the dopant materials of emission layers.

### Example Compounds

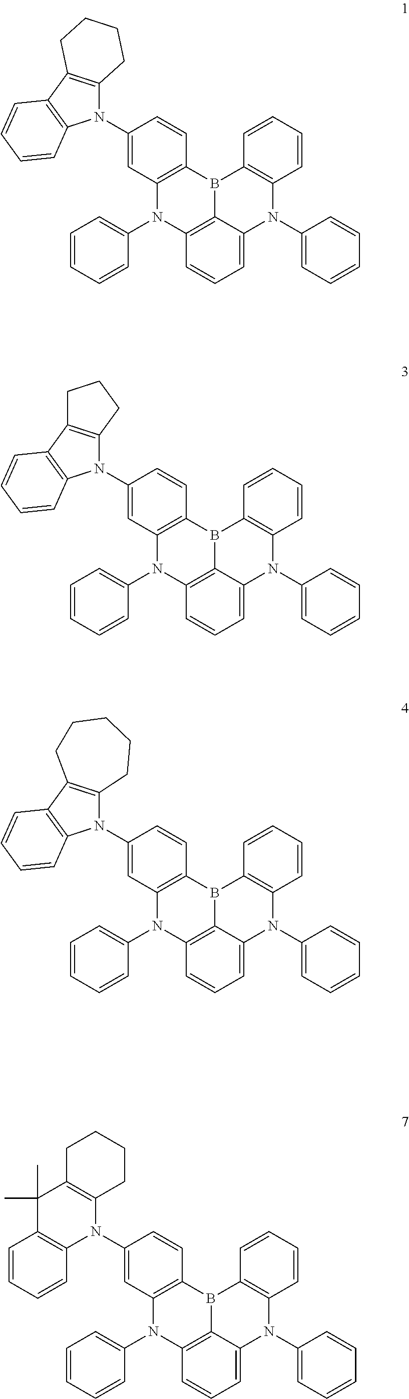 [SMILES: c1ccc(N2c3ccccc3B3c4ccc(-n5c6c(c7ccccc75)CCCC6)cc4N(c4ccccc4)c4cccc2c43)cc1 ; c1ccc(N2c3ccccc3B3c4ccc(-n5c6c(c7ccccc75)CCC6)cc4N(c4ccccc4)c4cccc2c43)cc1 ; c1ccc(N2c3ccccc3B3c4ccc(-n5c6c(c7ccccc75)CCCCC6)cc4N(c4ccccc4)c4cccc2c43)cc1 ; CC1(C)C2=C(CCCC2)N(c2ccc3c(c2)N(c2ccccc2)c2cccc4c2B3c2ccccc2N4c2ccccc2)c2ccccc21]

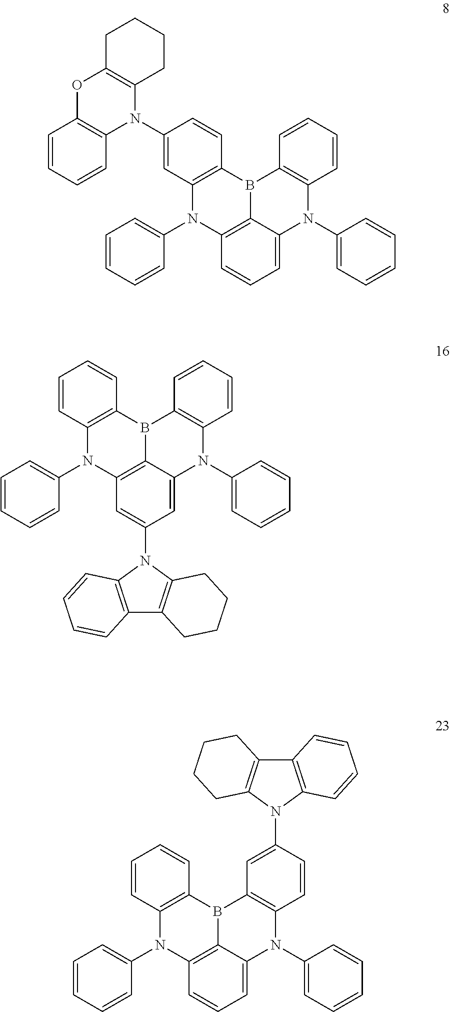 [SMILES: c1ccc(N2c3ccccc3B3c4ccc(N5C6=C(CCCC6)Oc6ccccc65)cc4N(c4ccccc4)c4cccc2c43)cc1 ; c1ccc(N2c3ccccc3B3c4ccccc4N(c4ccccc4)c4cc(-n5c6c(c7ccccc75)CCCC6)cc2c43)cc1 ; c1ccc(N2c3ccccc3B3c4cc(-n5c6c(c7ccccc75)CCCC6)ccc4N(c4ccccc4)c4cccc2c43)cc1]

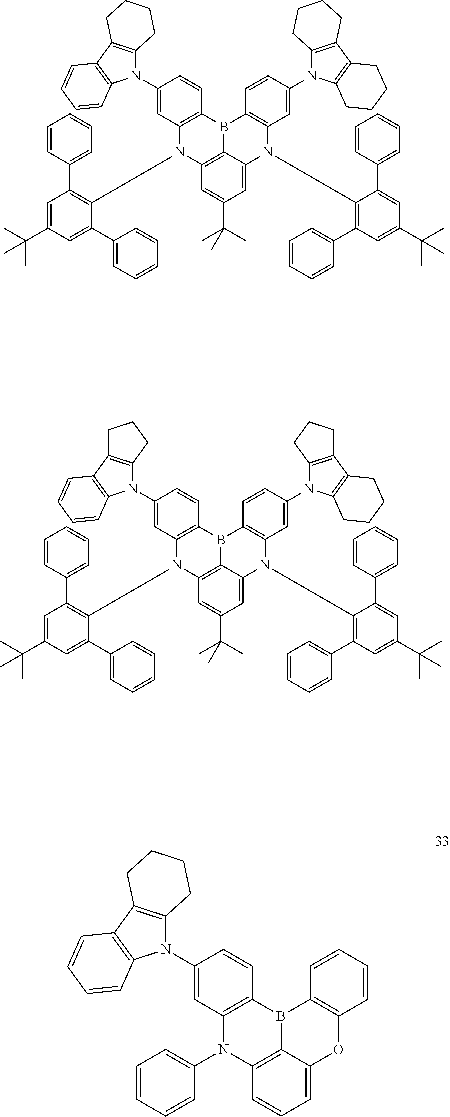

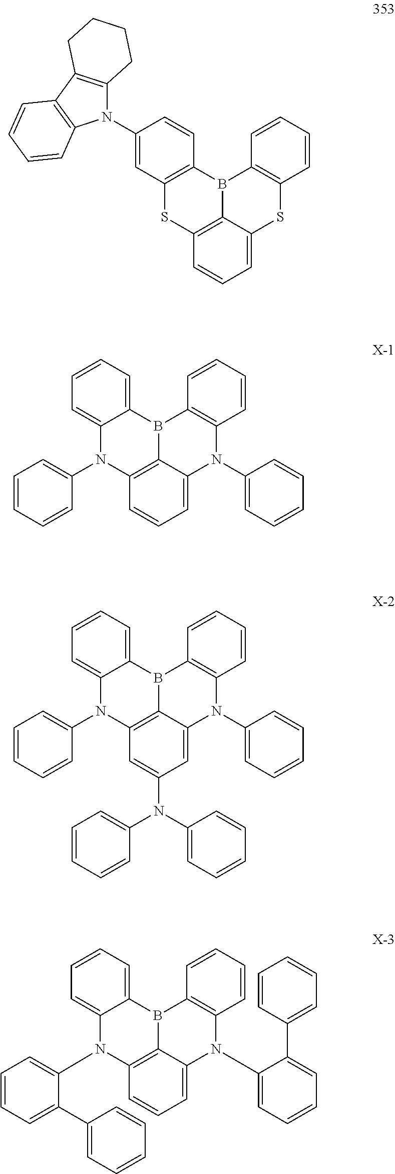 [SMILES: c1ccc2c(c1)Sc1cccc3c1B2c1ccc(-n2c4c(c5ccccc52)CCCC4)cc1S3 ; c1ccc(N2c3ccccc3B3c4ccccc4N(c4ccccc4)c4cccc2c43)cc1 ; c1ccc(N(c2ccccc2)c2cc3c4c(c2)N(c2ccccc2)c2ccccc2B4c2ccccc2N3c2ccccc2)cc1 ; c1ccc(-c2ccccc2N2c3ccccc3B3c4ccccc4N(c4ccccc4-c4ccccc4)c4cccc2c43)cc1]

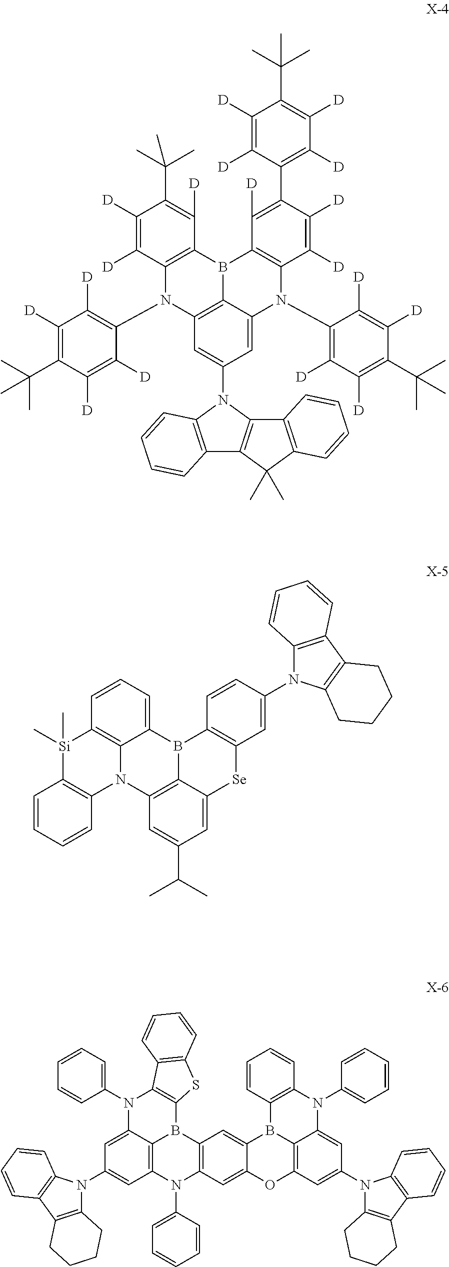 [SMILES: [2H]c1c([2H])c(C(C)(C)C)c([2H])c([2H])c1-c1c([2H])c([2H])c2c(c1[2H])B1c3c(cc(-n4c5c(c6ccccc64)C(C)(C)c4ccccc4-5)cc3N(c3c([2H])c([2H])c(C(C)(C)C)c([2H])c3[2H])c3c([2H])c([2H])c(C(C)(C)C)c([2H])c31)N2c1c([2H])c([2H])c(C(C)(C)C)c([2H])c1[2H] ; CC(C)c1cc2c3c(c1)N1c4ccccc4[Si](C)(C)c4cccc(c41)B3c1ccc(-n3c4c(c5ccccc53)CCCC4)cc1[Se]2 ; c1ccc(N2c3ccccc3B3c4cc5c(cc4Oc4cc(-n6c7c(c8ccccc86)CCCC7)cc2c43)N(c2ccccc2)c2cc(-n3c4c(c6ccccc63)CCCC4)cc3c2B5c2sc4ccccc4c2N3c2ccccc2)cc1]

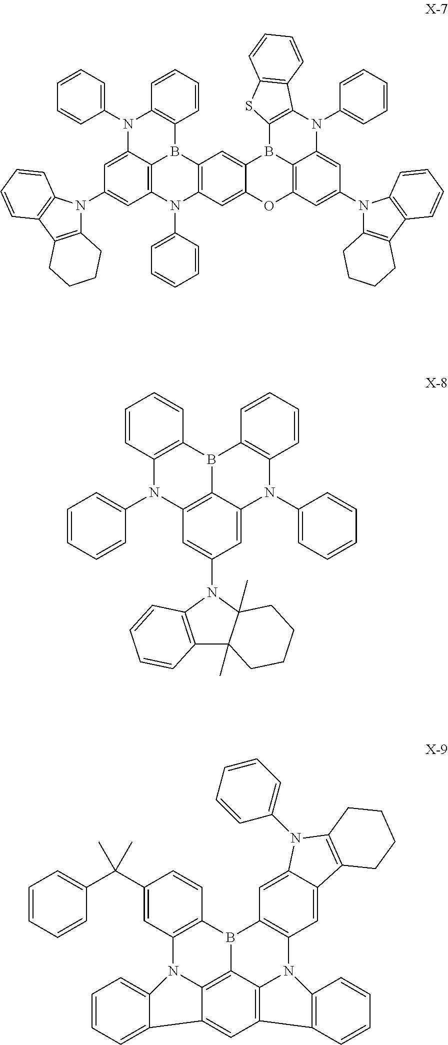 [SMILES: c1ccc(N2c3ccccc3B3c4cc5c(cc4N(c4ccccc4)c4cc(-n6c7c(c8ccccc86)CCCC7)cc2c43)Oc2cc(-n3c4c(c6ccccc63)CCCC4)cc3c2B5c2sc4ccccc4c2N3c2ccccc2)cc1 ; CC12CCCCC1(C)N(c1cc3c4c(c1)N(c1ccccc1)c1ccccc1B4c1ccccc1N3c1ccccc1)c1ccccc12 ; CC(C)(c1ccccc1)c1ccc2c(c1)-n1c3ccccc3c3cc4c5ccccc5n5c4c(c31)B2c1cc2c(cc1-5)c1c(n2-c2ccccc2)CCCC1]

### Comparative Compounds

### Manufacture of Light Emitting Element

A first electrode with a thickness of about 250 nanometer (nm) was formed utilizing ITO, a hole injection layer with a thickness of about 10 nm was formed utilizing dipyrazino[2,3-f: 2′,3′-h] quinoxaline-2,3,6,7,10,11-hexacarbonitrile (HATCN) on the first electrode, a hole transport layer with a thickness of about 80 nm was formed utilizing N, N′-di(1-naphthyl)-N,N′-diphenyl-(1,1″-biphenyl)-4,4″-diamine (NPD) on the hole injection layer, an emission auxiliary layer with a thickness of about 5 nm was formed utilizing 1,3-Bis(N-carbazolyl)benzene (mCP) on the hole transport layer, an emission layer with a thickness of about 20 nm was formed utilizing 3,3′-di(9H-carbazol-9-yl)-1,1′-biphenyl (mCBP) doped with 1% of the Example Compound or Comparative Compound on the emission auxiliary layer, an electron transport layer with a thickness of about 30 nm was formed utilizing 2,2′,2″-(1,3,5-Benzinetriyl)-tris(1-phenyl-1-H-benzimidazole) (TPBi) on the emission layer, an electron injection layer with a thickness of about 0.5 nm was formed utilizing LiF on the electron transport layer, and a second electrode with a thickness of about 300 nm was formed utilizing AI on the electron injection layer. All layers were formed by a vacuum deposition method in a vacuum atmosphere.

The compounds utilized for the manufacture of the light emitting elements of the Examples and Comparative Examples are shown. The materials were utilized after purchasing commercial products and performing sublimation purification.

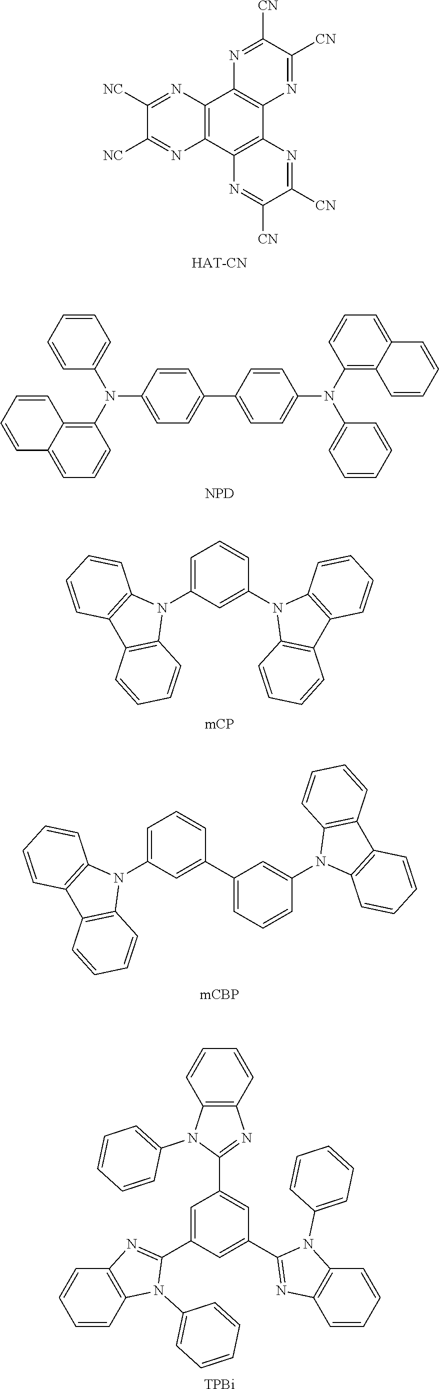

### (2) Evaluation of Properties of Light Emitting Elements

The lifetimes (lifespans) of the light emitting elements manufactured by Examples 1 to 11, and by utilizing Comparative Compounds X-1 to X-9 were evaluated. In Table 1, the evaluation results on the light emitting elements of Examples 1 to 11, and Comparative Examples 1 to 9 are shown. For the evaluation of the elements, the time consumed to reach about 50% luminance in contrast to an initial luminance at about 900 candela per square meter (cd/m²) was measured as the lifetime (T90), and the results are shown in Table 1

TABLE 1

| | | Relative |
|---|---|---|
| | | element |
| Element manufacturing | | lifetime |
| example | Dopant | LT50 |
| Example 1 | Compound 1 | 1.8 |
| Example 2 | Compound 3 | 1.7 |
| Example 3 | Compound 4 | 1.7 |
| Example 4 | Compound 7 | 1.7 |
| Example 5 | Compound 8 | 1.8 |
| Example 6 | Compound 16 | 1.8 |
| Example 7 | Compound 23 | 1.7 |
| Example 8 | Compound 25 | 2.8 |
| Example 9 | Compound 26 | 2.7 |
| Example 10 | Compound 33 | 1.7 |
| Example 11 | Compound 353 | 1.6 |
| Comparative Example 1 | Comparative Compound X-1 | 1.2 |
| Comparative Example 2 | Comparative Compound X-2 | 1.3 |
| Comparative Example 3 | Comparative Compound X-3 | 1.4 |
| Comparative Example 4 | Comparative Compound X-4 | 0.7 |
| Comparative Example 5 | Comparative Compound X-5 | 0.9 |
| Comparative Example 6 | Comparative Compound X-6 | 0.1 |
| Comparative Example 7 | Comparative Compound X-7 | 0.1 |
| Comparative Example 8 | Comparative Compound X-8 | 0.1 |
| Comparative Example 9 | Comparative Compound X-9 | 0.2 |

Referring to the results of Table 1, it may be confirmed that the Examples of the light emitting elements utilizing the fused polycyclic compounds of one or more embodiments of the present disclosure as light emitting materials, showed (e.g., exhibited) enhanced or improved emission efficiency and lifetime characteristics when compared to the Comparative Examples.

The Example Compound includes a fused ring core in which first to third aromatic rings are fused with a boron atom, and first and second heteroatoms in the center, wherein a first substituent is combined with the fused ring core via a first nitrogen atom, and multiple resonance effects may be improved to achieve low ΔE_{ST}. Accordingly, intersystem crossing from a triplet excitation state to a singlet excitation state may occur easily to enhance or improve delayed fluorescence properties and increase emission efficiency.

In one or more embodiments, it may be confirmed that the Example Compounds have structures in which a first substituent is introduced in a fused ring core, and when applied to light emitting elements, high emission efficiency and improved life characteristics are shown in contrast to the Comparative Examples. The Example Compounds have a structure in which a first substituent is connected with a fused ring core, and the deterioration of lifetime due to intermolecular interaction may be reduced or decreased, and long lifetime may be achieved. More particularly, in the cases of the Example Compounds, a first substituent introduces a cycloalkene moiety including sp³ carbon, and accordingly, planarity on a molecular structure is low, and a relatively twisted structure is exhibited or shown. Accordingly, intermolecular interaction may be reduced or decreased, and exciton quenching phenomenon due to intermolecular stacking may be restrained to improve life characteristics.

The light emitting element of one or more embodiments includes the first dopant of one or more embodiments as the light emitting dopant of a thermally activated delayed fluorescence (TADF) light emitting element, and high element efficiency may particularly be achieved even in a blue light wavelength range.

The light emitting element of one or more embodiments includes the fused polycyclic compound of one or more embodiments as the light emitting dopant of a thermally activated delayed fluorescence (TADF) light emitting element, and long lifetime may be achieved.

Referring to Comparative Example 1 to Comparative Example 4, Comparative Compound X-1 to Comparative Compound X-4 include a plate-type or kind skeleton structure with one boron atom and two nitrogen atoms in the center, but the first substituent suggested in the present disclosure is not included in the plate-type or kind skeleton. Accordingly, when applied to an element, markedly degraded element lifetime was shown when compared to the Examples. For example, it may be confirmed that Comparative Example 4 showed markedly degraded element lifetime when compared to Comparative Examples 1 to 3. In the case of Comparative Compound X-4, a benzoindenopyrrole moiety is included in a molecular structure, and it is thought that the fused ring skeleton of a corresponding structure shows degraded stability of a compound due to high planarity, and when applied to an element, the lifetime is decreased.

Comparative Example 5 showed degraded results of the element lifetime when compared to Examples 1 to 11. Different from the Example Compounds, Comparative Compound X-5 includes a structure in which a heterocycle including a Si atom is additionally fused in addition to first to third aromatic ring, and it is thought that the stability of a compound is deteriorated, and when applied to an element, the lifetime is deteriorated.

Comparative Examples 6 and 7 showed markedly degraded element lifetime when compared to Examples 1 to 11. Different from the Example Compounds, Comparative Compounds X-6 and X-7 have a structure in which a ring is additionally fused with the fused ring core, and a benzothiophene moiety is included in the additional ring. Accordingly, it is thought that the stability of the compounds is deteriorated, and when applied to elements, the lifetime is deteriorated.

Comparative Example 8 showed degraded element lifetime when compared to Example 6. Different from the Example Compounds including a cycloalkene moiety, Comparative Compound X-8 includes a cycloalkane moiety that is different, and it is thought that the stability of the compounds is deteriorated, and when applied to elements, the lifetime is deteriorated.

Comparative Example 9 showed degraded element lifetime when compared to Example 7. Different from the Example Compounds, in the case of Comparative Compound X-9, a cycloalkene moiety forms a ring with the fused ring core to form an additionally fused structure, and it is thought that the stability of the compounds is deteriorated, and when applied to elements, the lifetime is deteriorated.

The light emitting element of one or more embodiments may show improved element properties of long lifetime.

The fused polycyclic compound of one or more embodiments may be included in the emission layer of a light emitting element and may contribute to the increase of the lifetime of the light emitting element.

Although the embodiments of the present disclosure have been described, it is understood that the present disclosure should not be limited to these embodiments, but one or more suitable changes and modifications can be made by one ordinary skilled in the art within the spirit and scope of the present disclosure as hereinafter claimed without departing from the spirit and scope of the present disclosure as set forth in the following claims and equivalents thereof.

Accordingly, the technical scope of the present disclosure is not intended to be limited to the contents set forth in the detailed description of the specification, but is intended to be defined by the appended claims and equivalents thereof.

What is claimed is:

1. A light emitting element, comprising:
a first electrode;
a second electrode at the first electrode; and
at least one functional layer between the first electrode and the second electrode, and comprising a fused polycyclic compound represented by Formula 1: 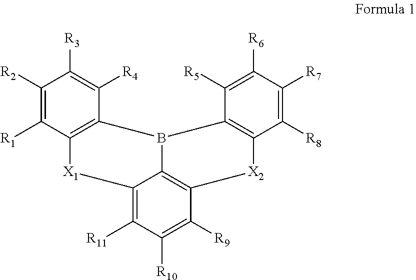
in Formula 1,
X₁ and X₂ are each independently O, S, Se, NR₁₂, CR₁₃R₁₄, or SiR₁₅R₁₆,
R₁ to R₁₆ are each independently a hydrogen atom, a deuterium atom, a halogen atom, a cyano group, a hydroxyl group, a substituted or unsubstituted oxy group, a substituted or unsubstituted thio group, a substituted or unsubstituted silyl group, a substituted or unsubstituted amine group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, a substituted or unsubstituted heteroaryl group of 2 to 30 ring-forming carbon atoms, or a substituent represented by Formula 2, and/or combined with an adjacent group to form a ring,
when each of R₁ to R₁₆ is combined with the adjacent group to form the ring, the ring excludes:
a heterocycle comprising Si in the ring as a ring-forming atom; or
a substituted or unsubstituted benzothiophene moiety, and
at least one selected from among R₁ to R₁₁ is represented by Formula 2: 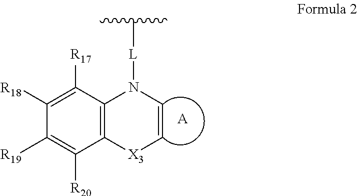
in Formula 2,
L is a direct linkage, or a substituted or unsubstituted arylene group of 6 to 30 ring-forming carbon atoms,
X₃ is a direct linkage, O, S, Se, NR₂₁, CR₂₂R₂₃, or SiR₂₄R₂₅,
R₁₇ to R₂₅ are each independently a hydrogen atom, a deuterium atom, a halogen atom, a cyano group, a hydroxyl group, a substituted or unsubstituted oxy group, a substituted or unsubstituted thio group, a substituted or unsubstituted silyl group, a substituted or unsubstituted amine group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, and/or combined with an adjacent group to form a ring, 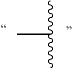
is a position connected with Formula 1, and
A is represented by Formula 3: 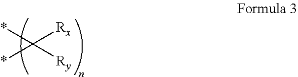
in Formula 3,
Rₓ and R_{y} are each independently a hydrogen atom, a deuterium atom, a halogen atom, a cyano group, a hydroxyl group, a substituted or unsubstituted oxy group, a substituted or unsubstituted thio group, a substituted or unsubstituted silyl group, a substituted or unsubstituted amine group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, and/or combined with an adjacent group to form a ring,
“n” is an integer of 3 to 6, and
“—*” is a position connected with Formula 2.

2. The light emitting element of claim 1, wherein the at least one functional layer comprises an emission layer, a hole transport region between the first electrode and the emission layer, and an electron transport region between the emission layer and the second electrode, and
the emission layer comprises the fused polycyclic compound.

3. The light emitting element of claim 2, wherein the emission layer is configured to emit delayed fluorescence.

4. The light emitting element of claim 2, wherein the emission layer is configured to emit light having a light center wavelength of about 430 nanometer (nm) to about 490 nm.

5. The light emitting element of claim 1, wherein the substituent represented by Formula 2 is represented by any one selected from among Formula 2-1-1 to Formula 2-1-4: 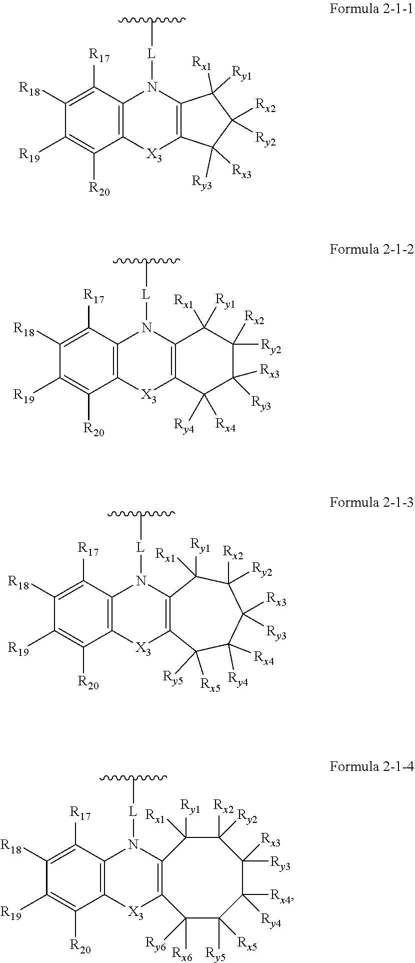
and
in Formula 2-1-1 to Formula 2-1-4,
Rₓ₁ to Rₓ₆, and R_{y1} to R_{y6} are each independently a hydrogen atom, a deuterium atom, a halogen atom, a cyano group, a hydroxyl group, a substituted or unsubstituted oxy group, a substituted or unsubstituted thio group, a substituted or unsubstituted silyl group, a substituted or unsubstituted amine group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, and/or combined with an adjacent group to form a ring, and
L, X₃, and R₁₇ to R₂₀ are as defined in Formula 2.

6. The light emitting element of claim 1, wherein the substituent represented by Formula 2 is represented by any one selected from among Formula 2-2-1 to Formula 2-2-7: 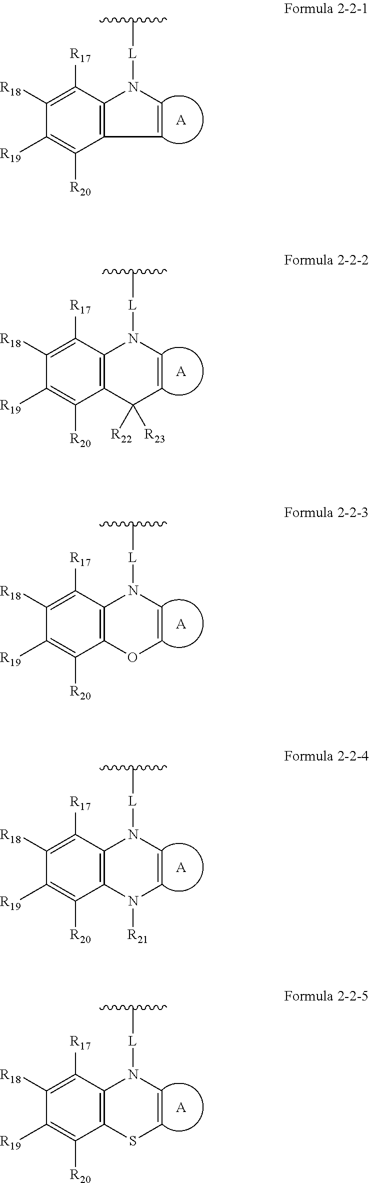 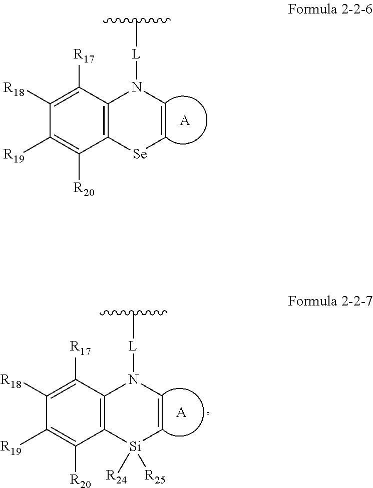
and
in Formula 2-2-1 to Formula 2-2-7,
L, R₁₇ to R₂₅, and A are as defined in Formula 2.

7. The light emitting element of claim 1, wherein the fused polycyclic compound represented by Formula 1 is represented by any one selected from among Formula 1-1-1 to Formula 1-1-3: 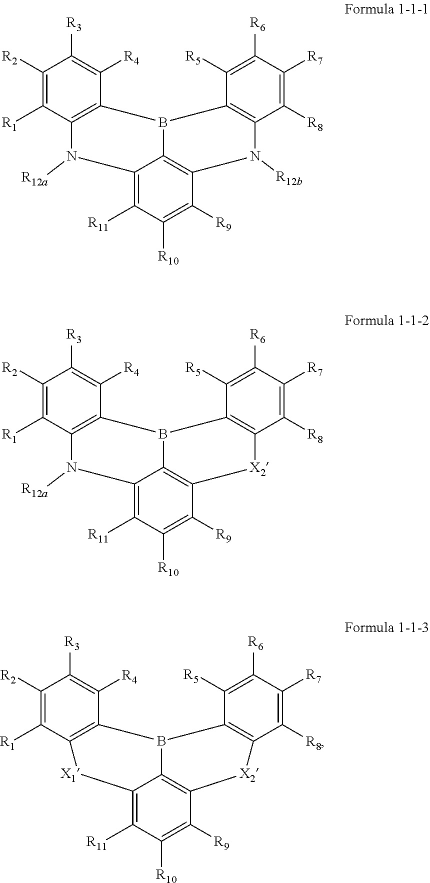
and
in Formula 1-1-1 to Formula 1-1-3,
X₁′ and X₂′ are each independently O, S, Se, CR₂₈R₂₇, or SiR₂₈R₂₉,
R₂₆ to R₂₉ are each independently a hydrogen atom, a deuterium atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, and/or combined with an adjacent group to form a ring,
R₁₂ₐ and R_{12b} are each independently a substituted or unsubstituted aryl group of 6 to 30 ring-forming carbon atoms, or a substituted or unsubstituted heteroaryl group of 2 to 30 ring-forming carbon atoms, and/or combined with an adjacent group to form a ring, and
R₁ to R₁₁ are as defined in Formula 1.

8. The light emitting element of claim 1, wherein the fused polycyclic compound represented by Formula 1 is represented by Formula 1-2-1 or Formula 1-2-2: 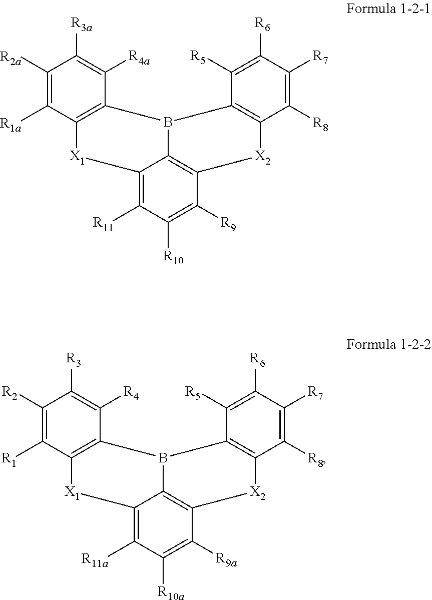
and
in Formula 1-2-1 and Formula 1-2-2,
R₁ₐ to R₄ₐ, and Rea to R₁₁ₐ are each independently a hydrogen atom, a deuterium atom, a halogen atom, a cyano group, a hydroxyl group, a substituted or unsubstituted oxy group, a substituted or unsubstituted thio group, a substituted or unsubstituted silyl group, a substituted or unsubstituted amine group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, a substituted or unsubstituted heteroaryl group of 2 to 30 ring-forming carbon atoms, and/or the substituent represented by Formula 2, or combined with an adjacent group to form a ring,
in Formula 1-2-1,
at least one selected from among R₁ₐ to R₄ₐ is represented by Formula 2,
in Formula 1-2-2,
at least one selected from among R₉ₐ to R₁₁ₐ is represented by Formula 2, and
in Formula 1-2-1 and Formula 1-2-2,
X₁, X₂, and R₁ to R₁₁ are as defined in Formula 1.

9. The light emitting element of claim 1, wherein the fused polycyclic compound represented by Formula 1 is represented by any one selected from among Formula 1-3-1 to Formula 1-3-3: 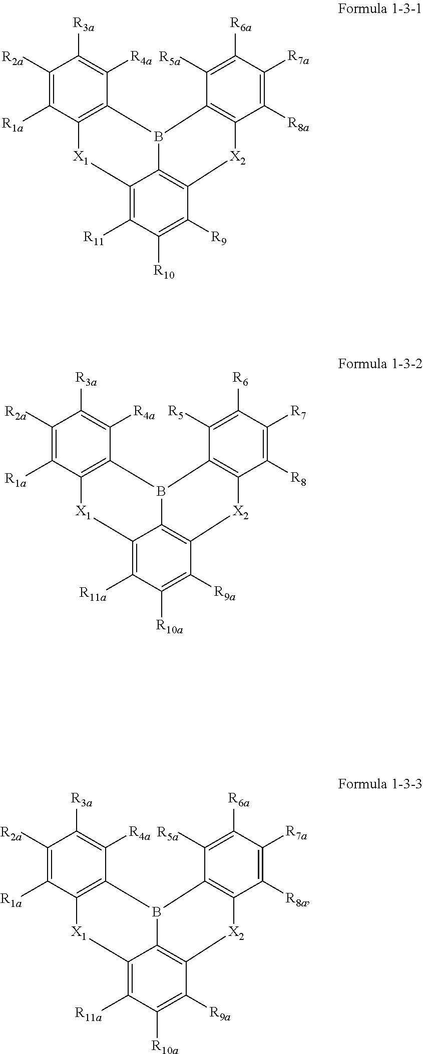
and
in Formula 1-3-1 to Formula 1-3-3,
R₁ₐ to R₁₁ₐ are each independently a hydrogen atom, a deuterium atom, a halogen atom, a cyano group, a hydroxyl group, a substituted or unsubstituted oxy group, a substituted or unsubstituted thio group, a substituted or unsubstituted silyl group, a substituted or unsubstituted amine group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, a substituted or unsubstituted heteroaryl group of 2 to 30 ring-forming carbon atoms, or the substituent represented by Formula 2, and/or combined with an adjacent group to form a ring,
in Formula 1-3-1,
at least one selected from among R₁ₐ to R₄ₐ, and at least one selected from among R₅ₐ to R₈ₐ are represented by Formula 2,
in Formula 1-3-2,
at least one selected from among R₁ₐ to R₄ₐ, and at least one selected from among R₉ₐ to R₁₁ₐ are represented by Formula 2,
in Formula 1-3-3,
at least one selected from among R₁ₐ to R₄ₐ, at least one selected from among R₅ₐ to R₈ₐ, and at least one selected from among R₉ₐ to R₁₁ₐ are represented by Formula 2, and
in Formula 1-3-1 to Formula 1-3-3,
X₁, X₂, and R₅ to R₁₁ are as defined in Formula 1.

10. The light emitting element of claim 1, wherein the fused polycyclic compound represented by Formula 1 is represented by Formula 1-4-1 or Formula 1-4-2: 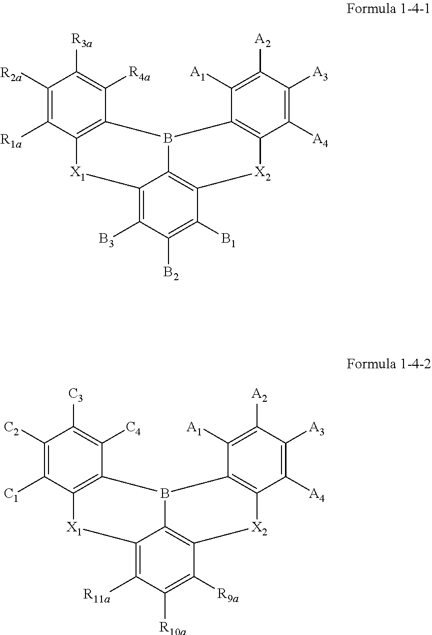
in Formula 1-4-1 and Formula 1-4-2,
A₁ to A₄, B₁ to B₃, and C₁ to C₄ are each independently a hydrogen atom, a deuterium atom, a substituted or unsubstituted alkyl group of 1 to 10 carbon atoms, the substituent represented by Formula 2, or a substituent represented by Formula C1,
R₁ₐ to R₄ₐ, and R₉ₐ to R₁₁ₐ are each independently a hydrogen atom, a deuterium atom, a halogen atom, a cyano group, a hydroxyl group, a substituted or unsubstituted oxy group, a substituted or unsubstituted thio group, a substituted or unsubstituted silyl group, a substituted or unsubstituted amine group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, a substituted or unsubstituted heteroaryl group of 2 to 30 ring-forming carbon atoms, or the substituent represented by Formula 2, and/or combined with an adjacent group to form a ring,
in Formula 1-4-1,
at least one selected from among R₁ₐ to R₄ₐ is represented by Formula 2,
in Formula 1-4-2,
at least one selected from among R₉ₐ to R₁₁ₐ is represented by Formula 2, 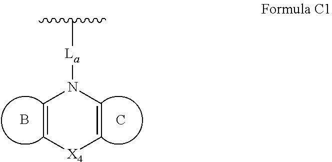
in Formula C1,
Lₐ is a direct linkage, or a substituted or unsubstituted arylene group of 6 to 30 ring-forming carbon atoms,
X₄ is a direct linkage, O, S, Se, NR₃₁, CR₃₂R₃₃, or SiR₃₄R₃₅,
R₃₁ to R₃₅ are each independently a hydrogen atom, a deuterium atom, a halogen atom, a cyano group, a hydroxyl group, a substituted or unsubstituted oxy group, a substituted or unsubstituted thio group, a substituted or unsubstituted silyl group, a substituted or unsubstituted amine group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, and/or combined with an adjacent group to form a ring, and
B and C are each independently represented by Formula C2: 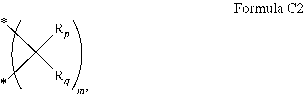
and
in Formula C2,
Rₚ and R_{q} are each independently a hydrogen atom, a deuterium atom, a halogen atom, a cyano group, a hydroxyl group, a substituted or unsubstituted oxy group, a substituted or unsubstituted thio group, a substituted or unsubstituted silyl group, a substituted or unsubstituted amine group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, and/or combined with an adjacent group to form a ring, and
“m” is an integer of 3 to 6, and
in Formula 1-4-1 and Formula 1-4-2,
X₁ and X₂ are as defined in Formula 1.

11. The light emitting element of claim 1, wherein the fused polycyclic compound represented by Formula 1 is represented by any one selected from among Formula 1-5-1 to Formula 1-5-3: 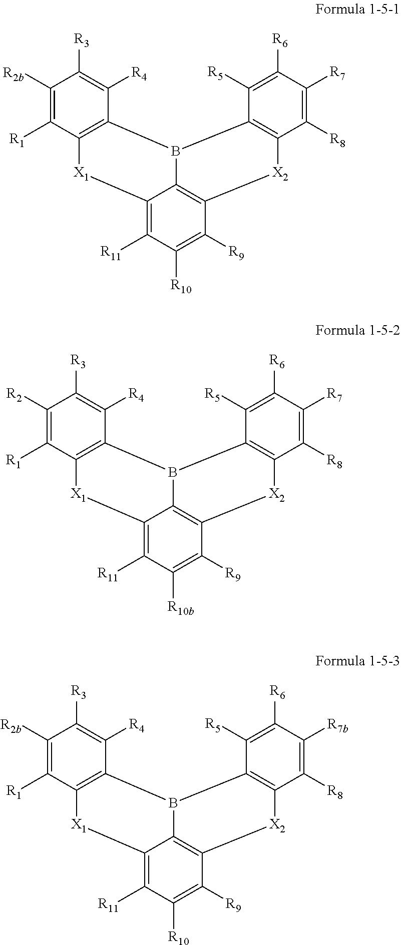
in Formula 1-5-1 to Formula 1-5-3,
R_{2b} and R_{10b} are each independently represented by Formula 2, and
R_{7b} is represented by Formula 2 or Formula C1: 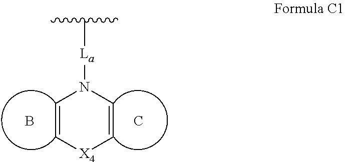
in Formula C1,
Lₐ is a direct linkage, or a substituted or unsubstituted arylene group of 6 to 30 ring-forming carbon atoms,
X₄ is a direct linkage, O, S, Se, NR₃₁, CR₃₂R₃₃, or SiR₃₄R₃₅,
R₃₁ to R₃₅ are each independently a hydrogen atom, a deuterium atom, a halogen atom, a cyano group, a hydroxyl group, a substituted or unsubstituted oxy group, a substituted or unsubstituted thio group, a substituted or unsubstituted silyl group, a substituted or unsubstituted amine group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, and/or combined with an adjacent group to form a ring, and
B and C are each independently represented by Formula C2: 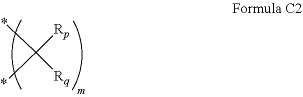
in Formula C2,
Rₚ and R_{q} are each independently a hydrogen atom, a deuterium atom, a halogen atom, a cyano group, a hydroxyl group, a substituted or unsubstituted oxy group, a substituted or unsubstituted thio group, a substituted or unsubstituted silyl group, a substituted or unsubstituted amine group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, and/or combined with an adjacent group to form a ring, and
“m” is an integer of 3 to 6, and
in Formula 1-5-1 to Formula 1-5-3,
X₁, X₂ and R₁ to R₁₁ are as defined in Formula 1.

12. The light emitting element of claim 1, wherein the fused polycyclic compound represented by Formula 1 is represented by any one selected from among Formula 1-6-1 to Formula 1-6-3: 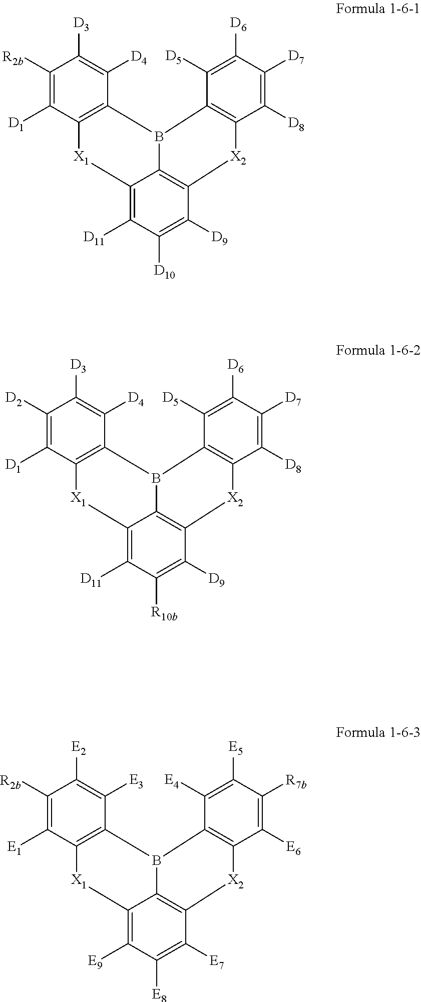
in Formula 1-6-1 to Formula 1-6-3,
D₁ to D₁₁ are each independently a hydrogen atom or a deuterium atom,
E₁ to E₉ are each independently a hydrogen atom, a deuterium atom, or a substituted or unsubstituted alkyl group of 1 to 10 carbon atoms,
R_{2b} and R_{10b} are each independently represented by Formula 2, and
R_{7b} is represented by Formula 2 or Formula C1: 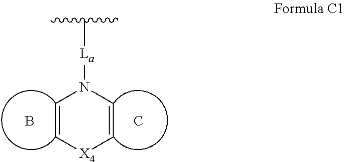
in Formula C1,
Lₐ is a direct linkage, or a substituted or unsubstituted arylene group of 6 to 30 ring-forming carbon atoms,
X₄ is a direct linkage, O, S, Se, NR₃₁, CR₃₂R₃₃, or SiR₃₄R₃₅,
R₃₁ to R₃₅ are each independently a hydrogen atom, a deuterium atom, a halogen atom, a cyano group, a hydroxyl group, a substituted or unsubstituted oxy group, a substituted or unsubstituted thio group, a substituted or unsubstituted silyl group, a substituted or unsubstituted amine group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, and/or combined with an adjacent group to form a ring, and
B and C are each independently represented by Formula C2: 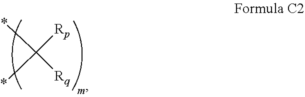
and
in Formula C2,
Rₚ and R_{q} are each independently a hydrogen atom, a deuterium atom, a halogen atom, a cyano group, a hydroxyl group, a substituted or unsubstituted oxy group, a substituted or unsubstituted thio group, a substituted or unsubstituted silyl group, a substituted or unsubstituted amine group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, and/or combined with an adjacent group to form a ring, and
“m” is an integer of 3 to 6, and
in Formula 1-6-1 to Formula 1-6-3,
X₁ and X₂ are as defined in Formula 1.

13. The light emitting element of claim 1, wherein the fused polycyclic compound comprises at least one selected from among compounds in Compound Group 1:
Compound Group 1

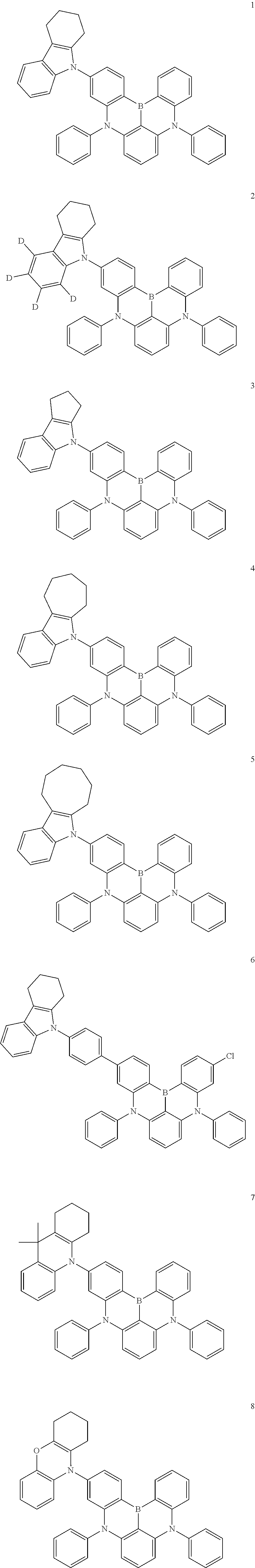

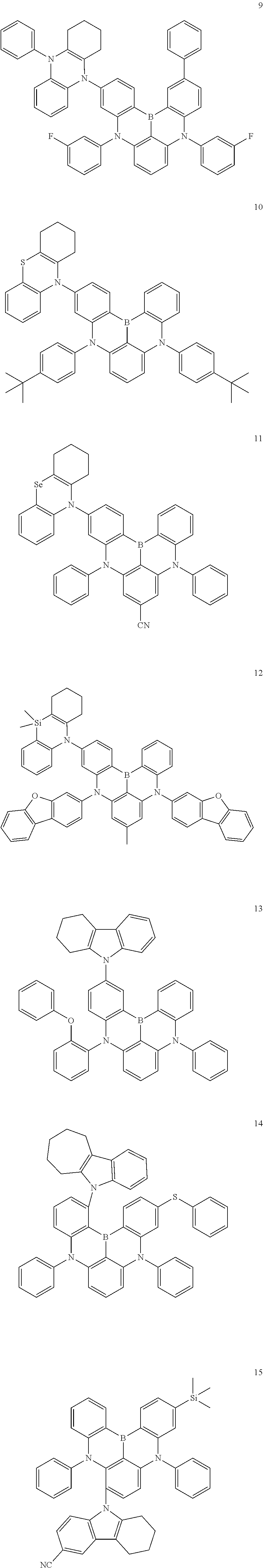

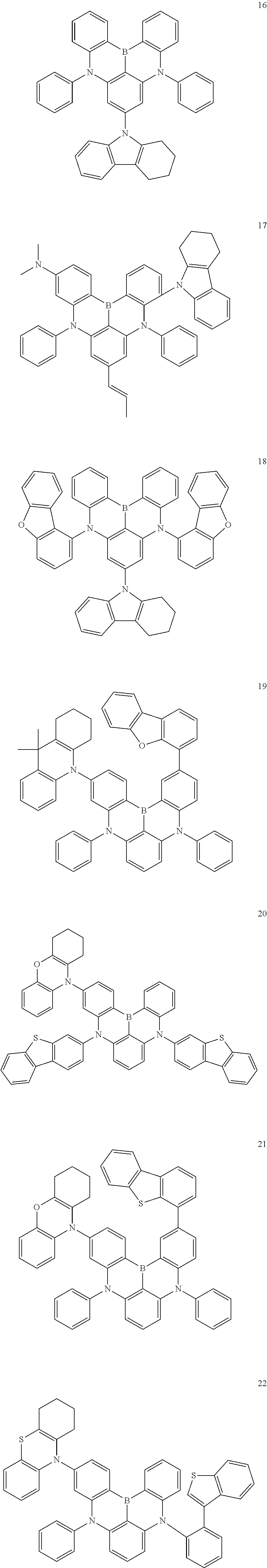

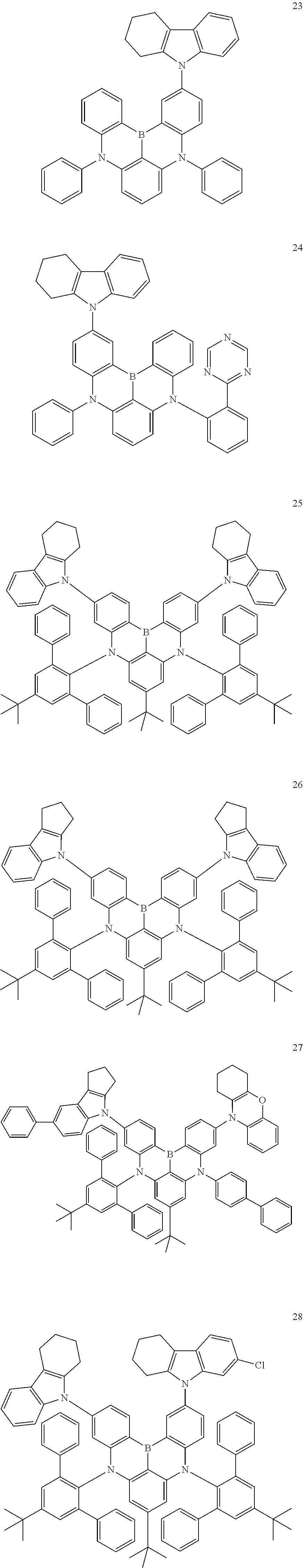

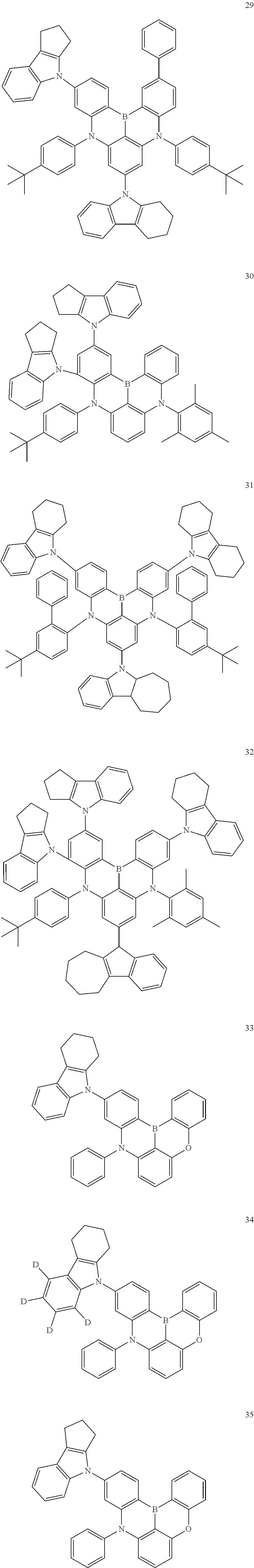

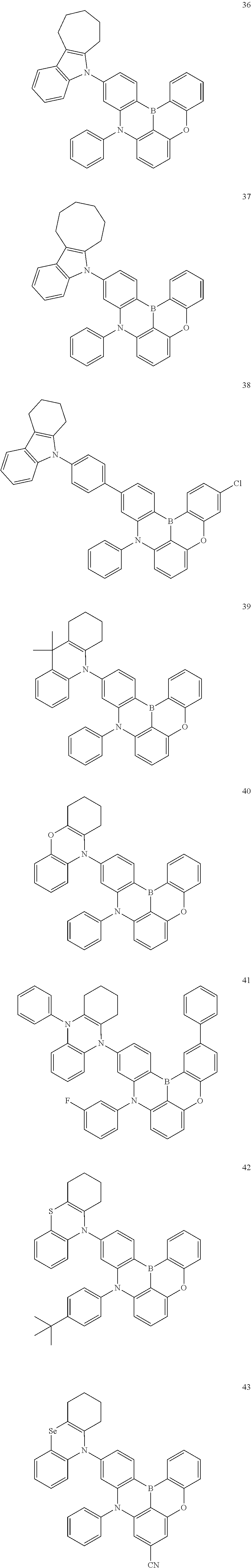

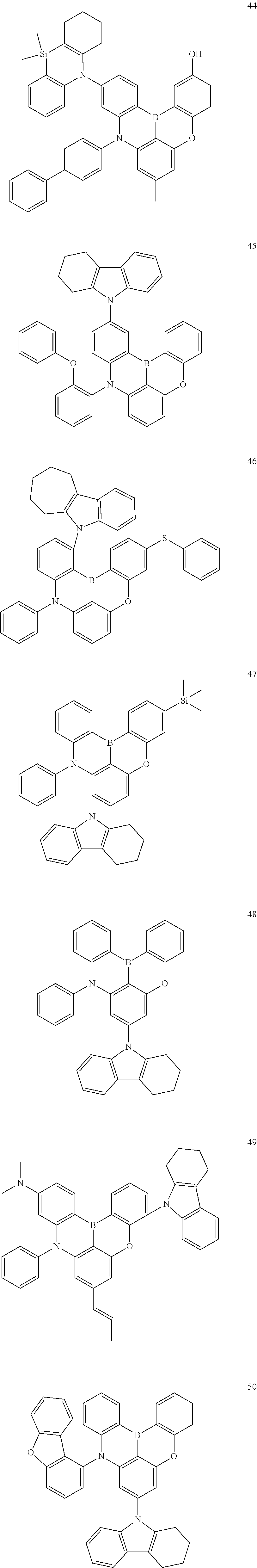

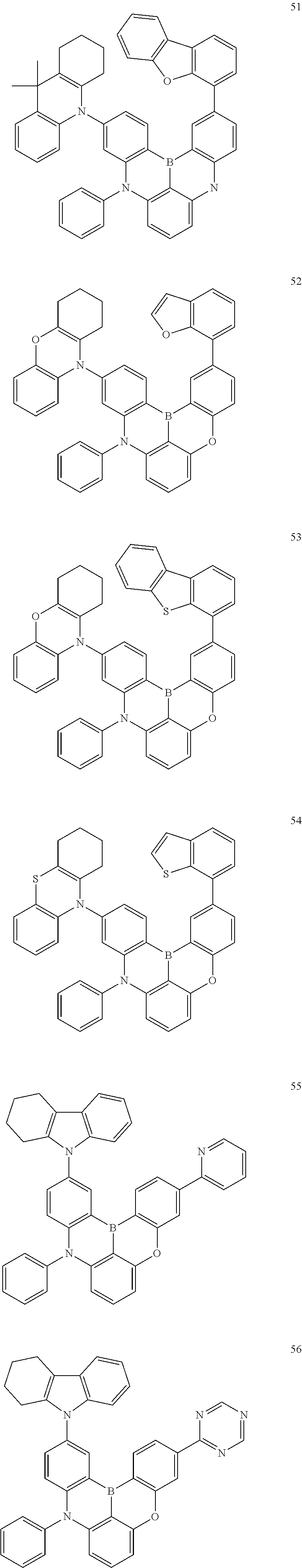

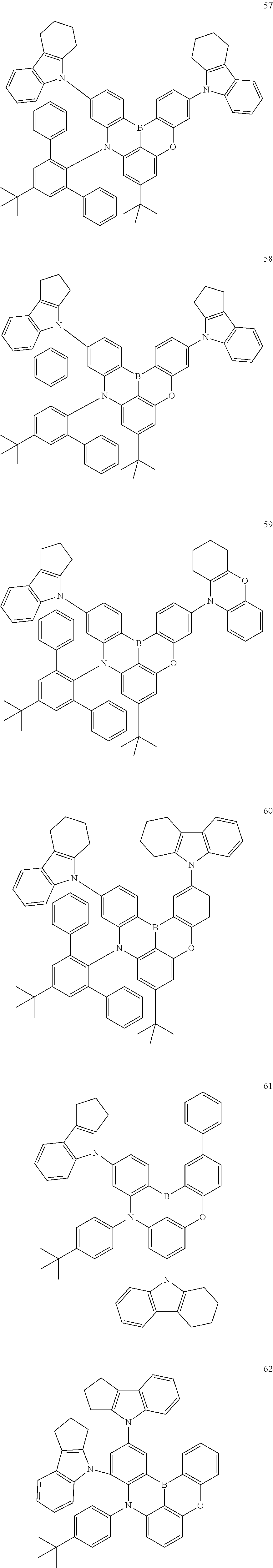

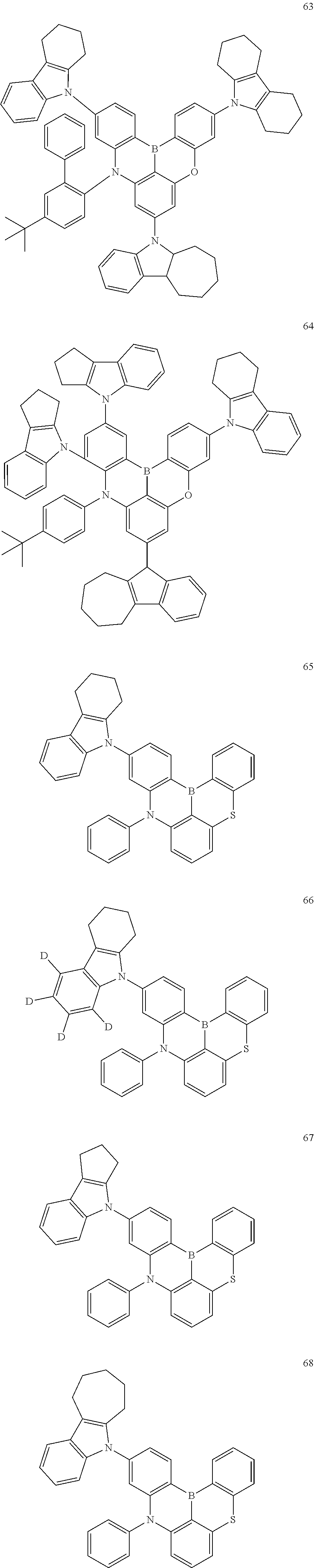

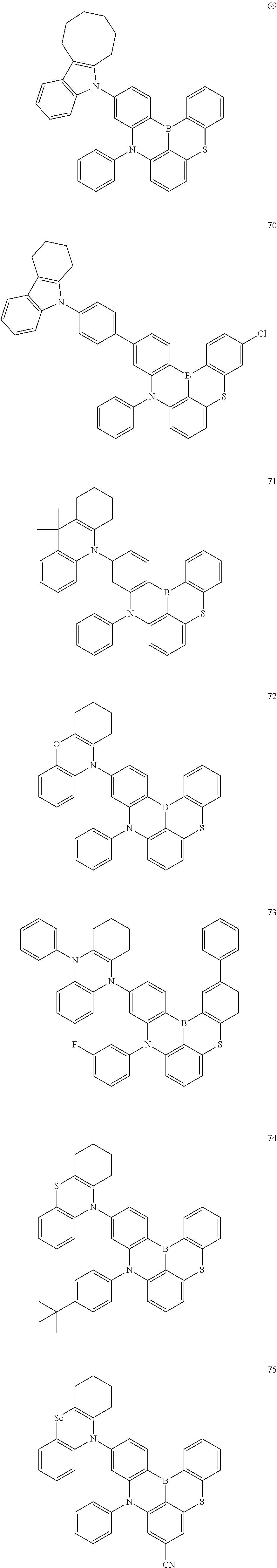

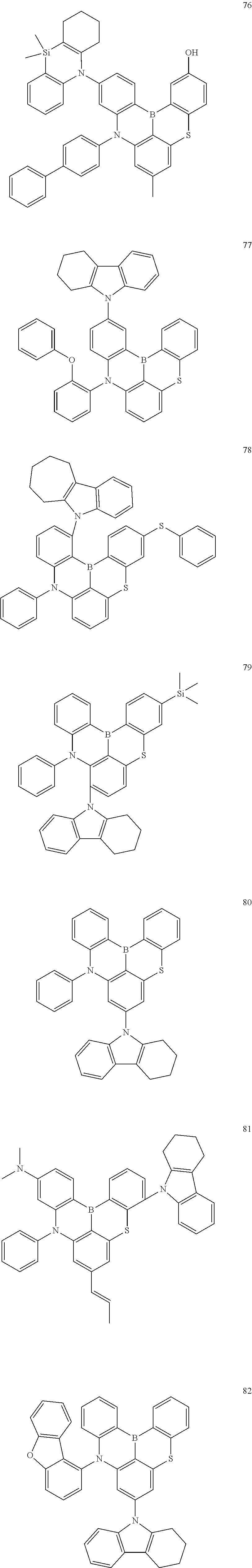

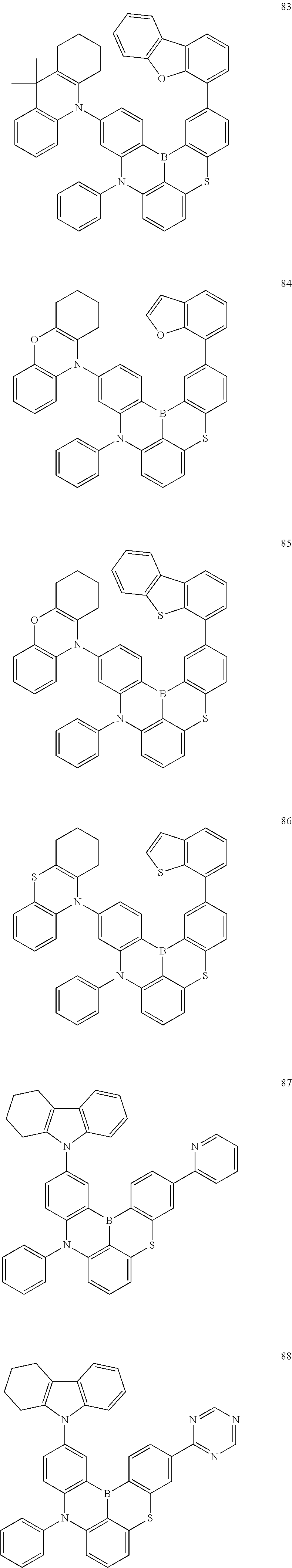

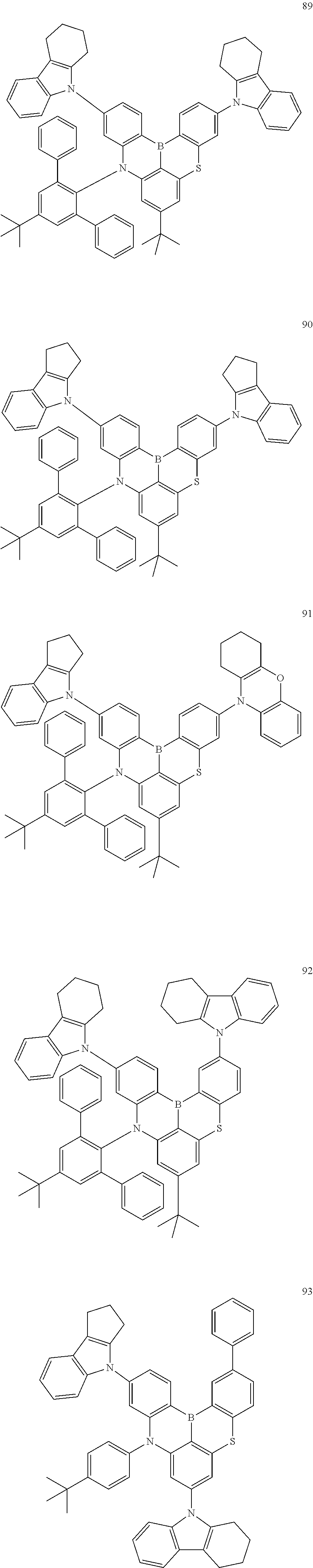

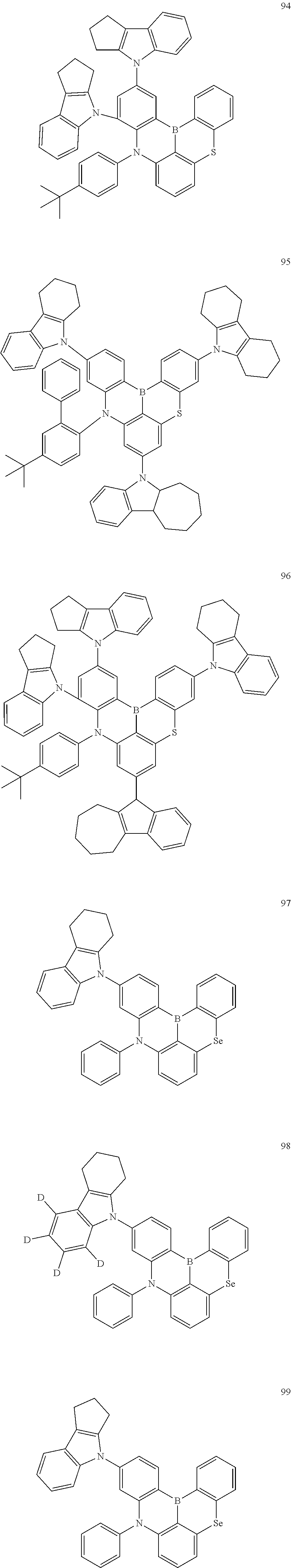

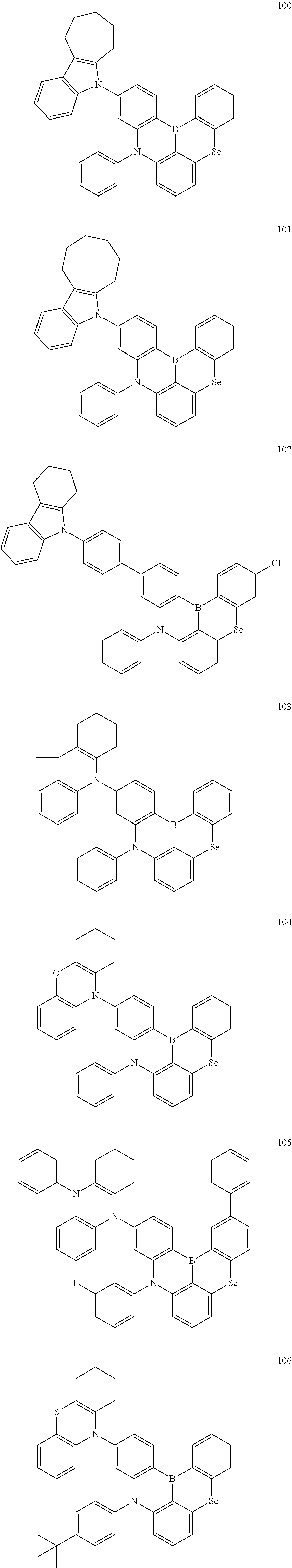

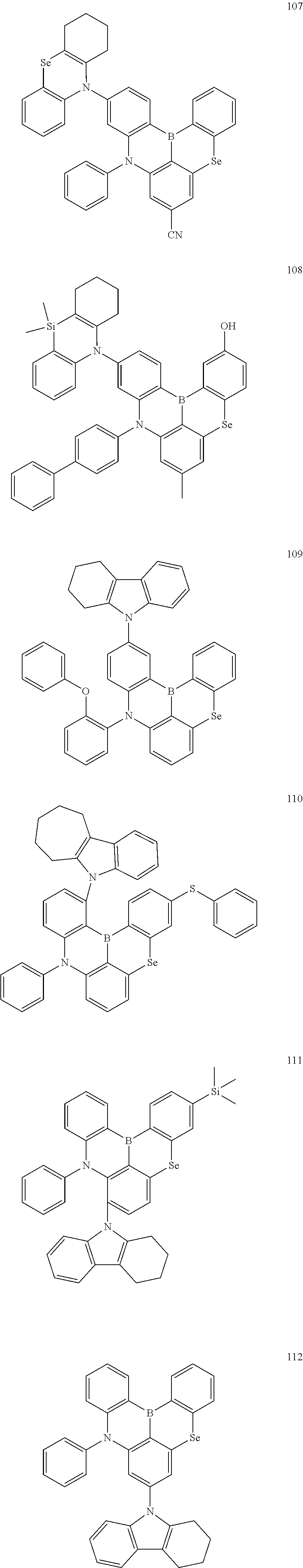 [SMILES: N#Cc1cc2c3c(c1)N(c1ccccc1)c1cc(N4C5=C(CCCC5)[Se]c5ccccc54)ccc1B3c1ccccc1[Se]2 ; Cc1cc2c3c(c1)N(c1ccc(-c4ccccc4)cc1)c1cc(N4C5=C(CCCC5)[Si](C)(C)c5ccccc54)ccc1B3c1cc(O)ccc1[Se]2 ; c1ccc(Oc2ccccc2N2c3ccc(-n4c5c(c6ccccc64)CCCC5)cc3B3c4ccccc4[Se]c4cccc2c43)cc1 ; c1ccc(Sc2ccc3c(c2)[Se]c2cccc4c2B3c2c(cccc2-n2c3c(c5ccccc52)CCCCC3)N4c2ccccc2)cc1 ; C[Si](C)(C)c1ccc2c(c1)[Se]c1ccc(-n3c4c(c5ccccc53)CCCC4)c3c1B2c1ccccc1N3c1ccccc1 ; c1ccc(N2c3ccccc3B3c4ccccc4[Se]c4cc(-n5c6c(c7ccccc75)CCCC6)cc2c43)cc1]

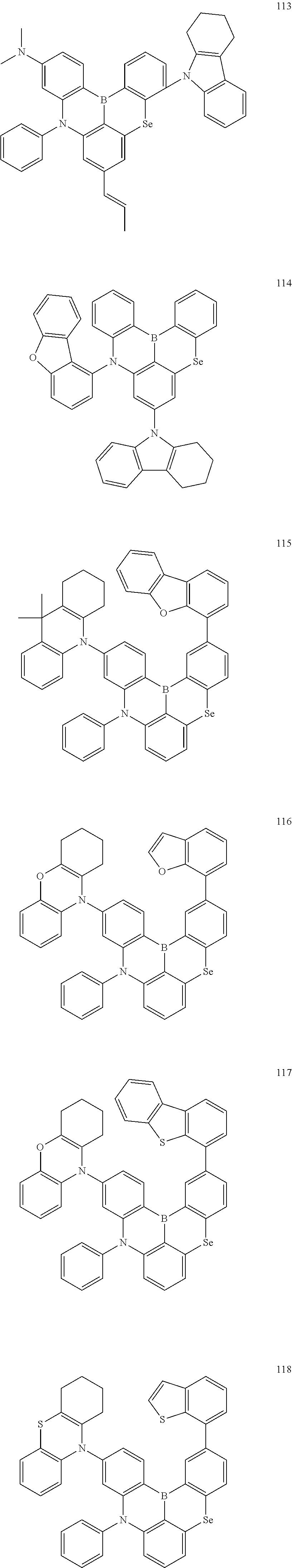

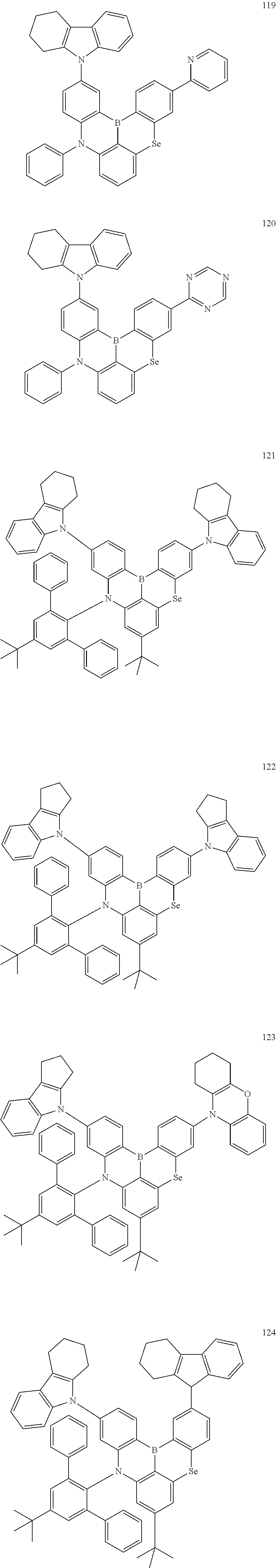

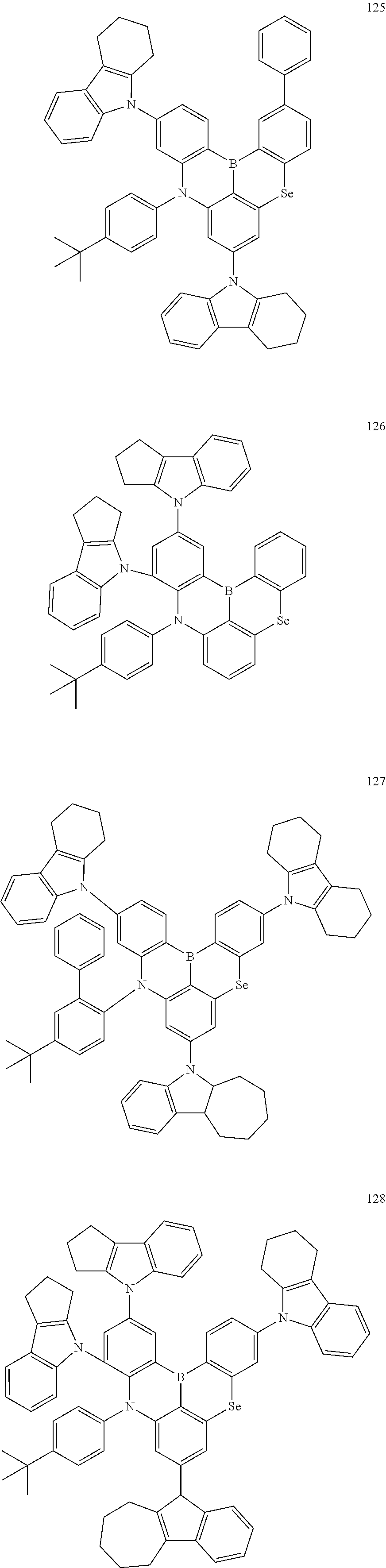

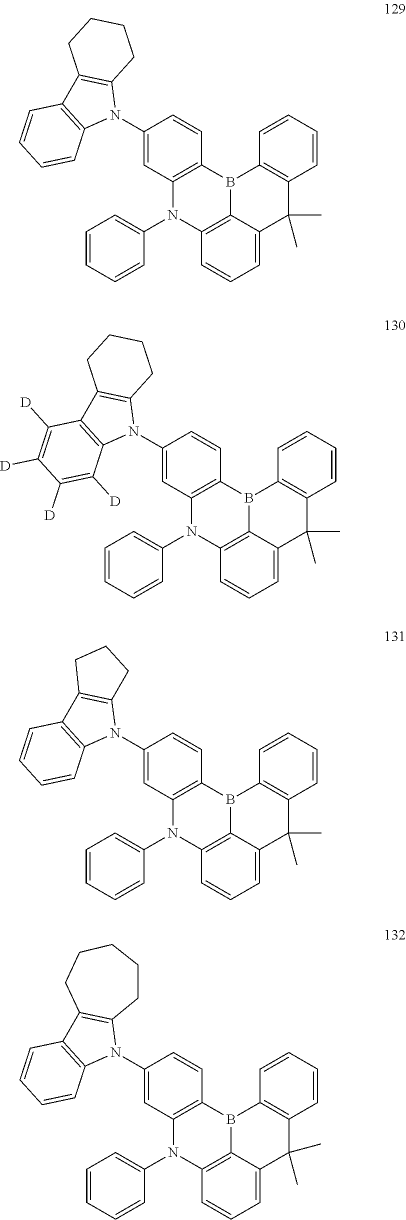

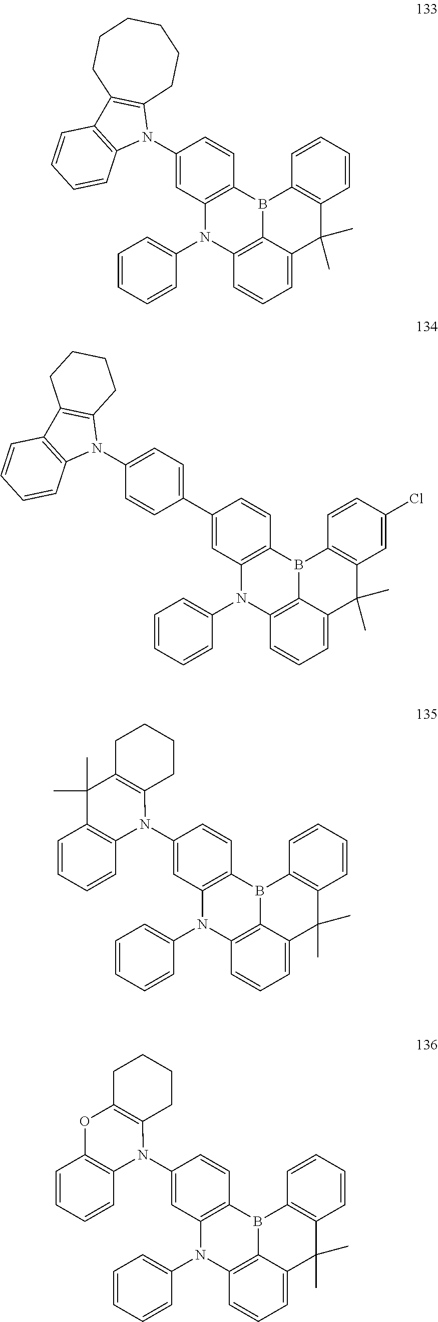

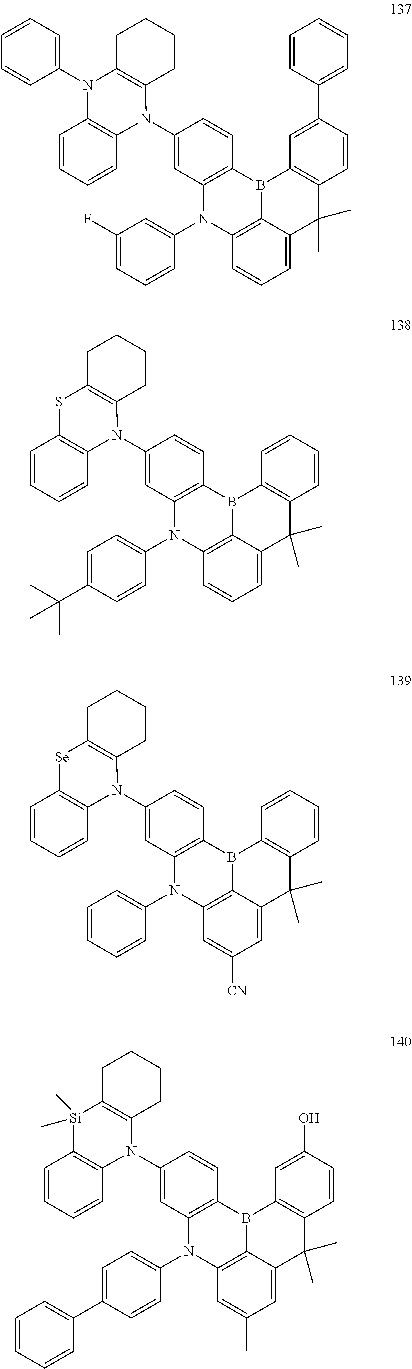 [SMILES: CC1(C)c2ccc(-c3ccccc3)cc2B2c3ccc(N4C5=C(CCCC5)N(c5ccccc5)c5ccccc54)cc3N(c3cccc(F)c3)c3cccc1c32 ; CC(C)(C)c1ccc(N2c3cc(N4C5=C(CCCC5)Sc5ccccc54)ccc3B3c4ccccc4C(C)(C)c4cccc2c43)cc1 ; CC1(C)c2ccccc2B2c3ccc(N4C5=C(CCCC5)[Se]c5ccccc54)cc3N(c3ccccc3)c3cc(C#N)cc1c32 ; Cc1cc2c3c(c1)C(C)(C)c1ccc(O)cc1B3c1ccc(N3C4=C(CCCC4)[Si](C)(C)c4ccccc43)cc1N2c1ccc(-c2ccccc2)cc1]

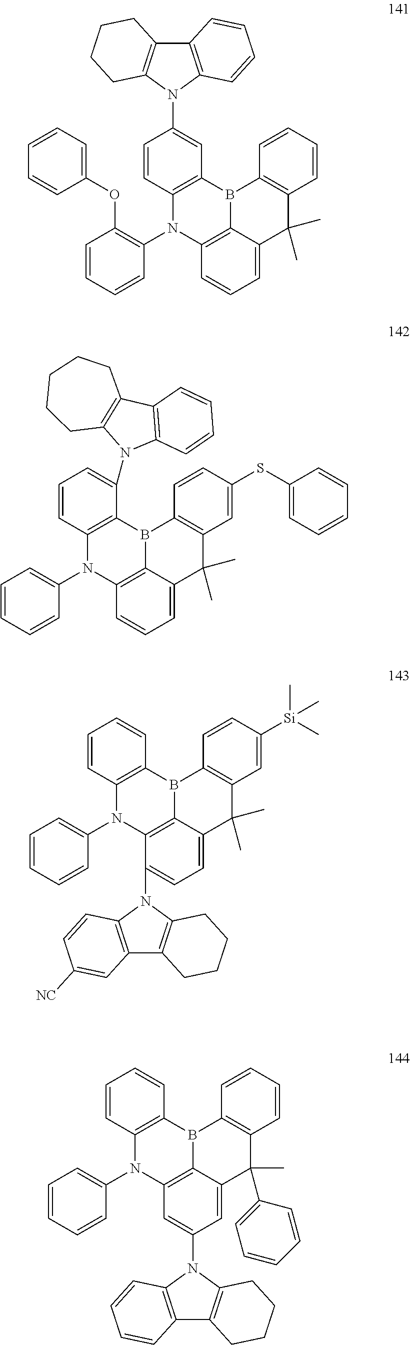 [SMILES: CC1(C)c2ccccc2B2c3cc(-n4c5c(c6ccccc64)CCCC5)ccc3N(c3ccccc3Oc3ccccc3)c3cccc1c32 ; CC1(C)c2cc(Sc3ccccc3)ccc2B2c3c(cccc3-n3c4c(c5ccccc53)CCCCC4)N(c3ccccc3)c3cccc1c32 ; CC1(C)c2cc([Si](C)(C)C)ccc2B2c3ccccc3N(c3ccccc3)c3c(-n4c5c(c6cc(C#N)ccc64)CCCC5)ccc1c32 ; CC1(c2ccccc2)c2ccccc2B2c3ccccc3N(c3ccccc3)c3cc(-n4c5c(c6ccccc64)CCCC5)cc1c32]

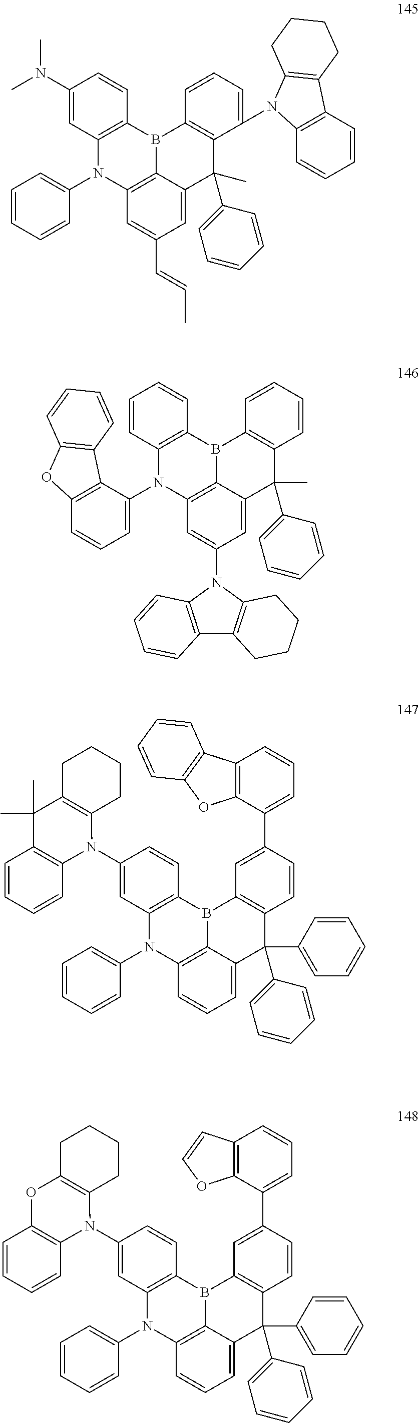 [SMILES: C/C=C/c1cc2c3c(c1)C(C)(c1ccccc1)c1c(cccc1-n1c4c(c5ccccc51)CCCC4)B3c1ccc(N(C)C)cc1N2c1ccccc1 ; CC1(c2ccccc2)c2ccccc2B2c3ccccc3N(c3cccc4oc5ccccc5c34)c3cc(-n4c5c(c6ccccc64)CCCC5)cc1c32 ; CC1(C)C2=C(CCCC2)N(c2ccc3c(c2)N(c2ccccc2)c2cccc4c2B3c2cc(-c3cccc5c3oc3ccccc35)ccc2C4(c2ccccc2)c2ccccc2)c2ccccc21 ; c1ccc(N2c3cc(N4C5=C(CCCC5)Oc5ccccc54)ccc3B3c4cc(-c5cccc6ccoc56)ccc4C(c4ccccc4)(c4ccccc4)c4cccc2c43)cc1]

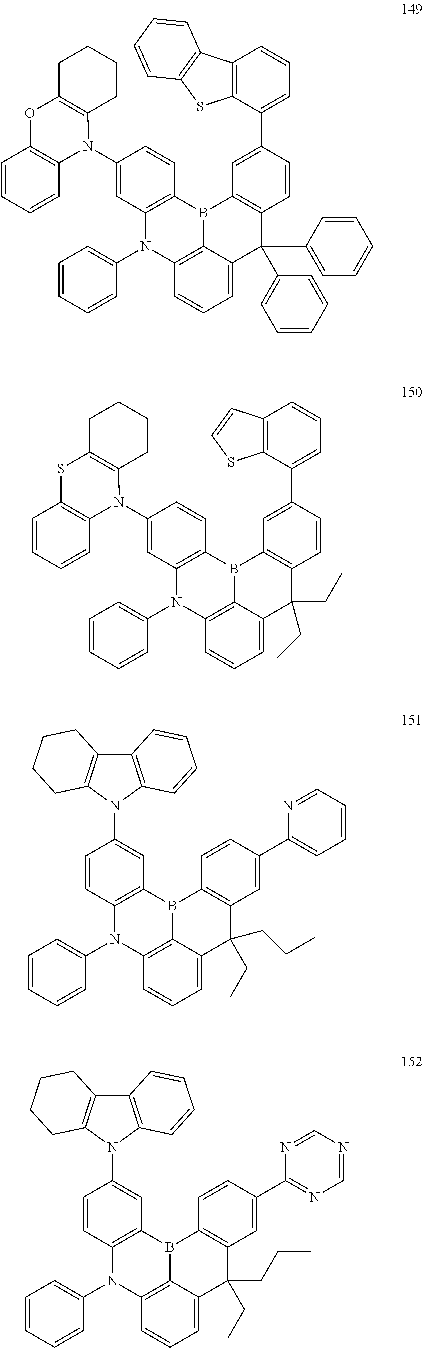 [SMILES: c1ccc(N2c3cc(N4C5=C(CCCC5)Oc5ccccc54)ccc3B3c4cc(-c5cccc6c5sc5ccccc56)ccc4C(c4ccccc4)(c4ccccc4)c4cccc2c43)cc1 ; CCC1(CC)c2ccc(-c3cccc4ccsc34)cc2B2c3ccc(N4C5=C(CCCC5)Sc5ccccc54)cc3N(c3ccccc3)c3cccc1c32 ; CCCC1(CC)c2cc(-c3ccccn3)ccc2B2c3cc(-n4c5c(c6ccccc64)CCCC5)ccc3N(c3ccccc3)c3cccc1c32 ; CCCC1(CC)c2cc(-c3ncncn3)ccc2B2c3cc(-n4c5c(c6ccccc64)CCCC5)ccc3N(c3ccccc3)c3cccc1c32]

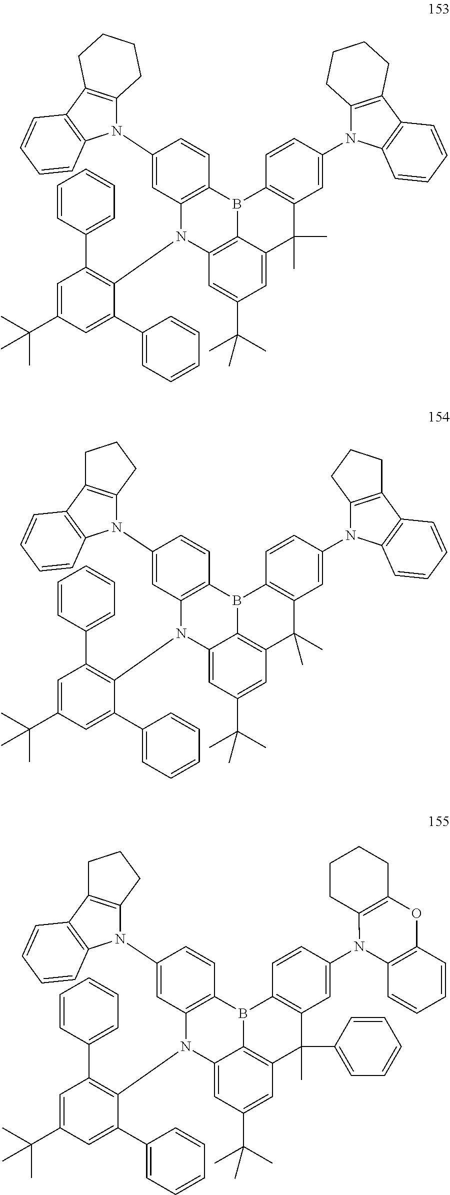 [SMILES: CC(C)(C)c1cc(-c2ccccc2)c(N2c3cc(-n4c5c(c6ccccc64)CCCC5)ccc3B3c4ccc(-n5c6c(c7ccccc75)CCCC6)cc4C(C)(C)c4cc(C(C)(C)C)cc2c43)c(-c2ccccc2)c1 ; CC(C)(C)c1cc(-c2ccccc2)c(N2c3cc(-n4c5c(c6ccccc64)CCC5)ccc3B3c4ccc(-n5c6c(c7ccccc75)CCC6)cc4C(C)(C)c4cc(C(C)(C)C)cc2c43)c(-c2ccccc2)c1 ; CC(C)(C)c1cc(-c2ccccc2)c(N2c3cc(-n4c5c(c6ccccc64)CCC5)ccc3B3c4ccc(N5C6=C(CCCC6)Oc6ccccc65)cc4C(C)(c4ccccc4)c4cc(C(C)(C)C)cc2c43)c(-c2ccccc2)c1]

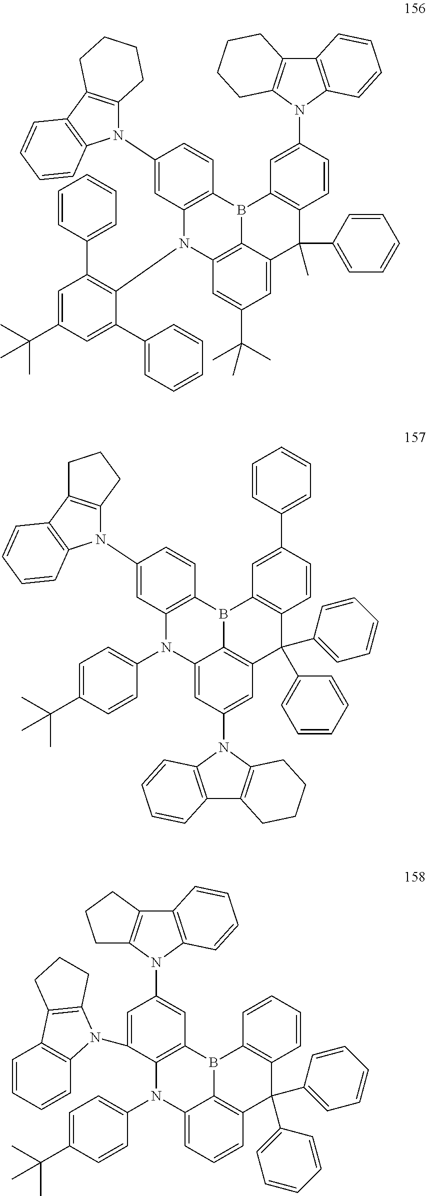 [SMILES: CC(C)(C)c1cc(-c2ccccc2)c(N2c3cc(-n4c5c(c6ccccc64)CCCC5)ccc3B3c4cc(-n5c6c(c7ccccc75)CCCC6)ccc4C(C)(c4ccccc4)c4cc(C(C)(C)C)cc2c43)c(-c2ccccc2)c1 ; CC(C)(C)c1ccc(N2c3cc(-n4c5c(c6ccccc64)CCC5)ccc3B3c4cc(-c5ccccc5)ccc4C(c4ccccc4)(c4ccccc4)c4cc(-n5c6c(c7ccccc75)CCCC6)cc2c43)cc1 ; CC(C)(C)c1ccc(N2c3cccc4c3B(c3ccccc3C4(c3ccccc3)c3ccccc3)c3cc(-n4c5c(c6ccccc64)CCC5)cc(-n4c5c(c6ccccc64)CCC5)c32)cc1]

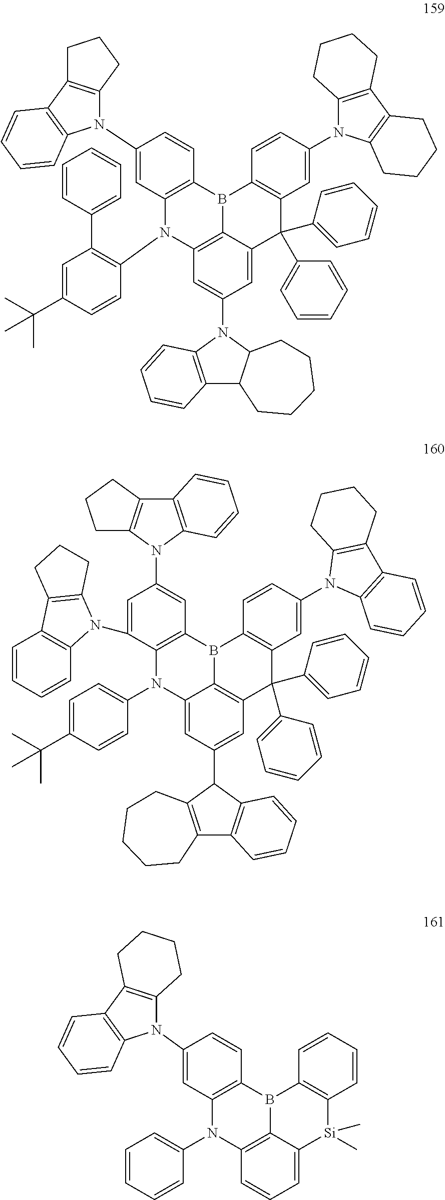 [SMILES: CC(C)(C)c1ccc(N2c3cc(-n4c5c(c6ccccc64)CCC5)ccc3B3c4ccc(-n5c6c(c7c5CCCC7)CCCC6)cc4C(c4ccccc4)(c4ccccc4)c4cc(N5c6ccccc6C6CCCCCC65)cc2c43)c(-c2ccccc2)c1 ; CC(C)(C)c1ccc(N2c3cc(C4C5=C(CCCCC5)c5ccccc54)cc4c3B(c3ccc(-n5c6c(c7ccccc75)CCCC6)cc3C4(c3ccccc3)c3ccccc3)c3cc(-n4c5c(c6ccccc64)CCC5)cc(-n4c5c(c6ccccc64)CCC5)c32)cc1 ; C[Si]1(C)c2ccccc2B2c3ccc(-n4c5c(c6ccccc64)CCCC5)cc3N(c3ccccc3)c3cccc1c32]

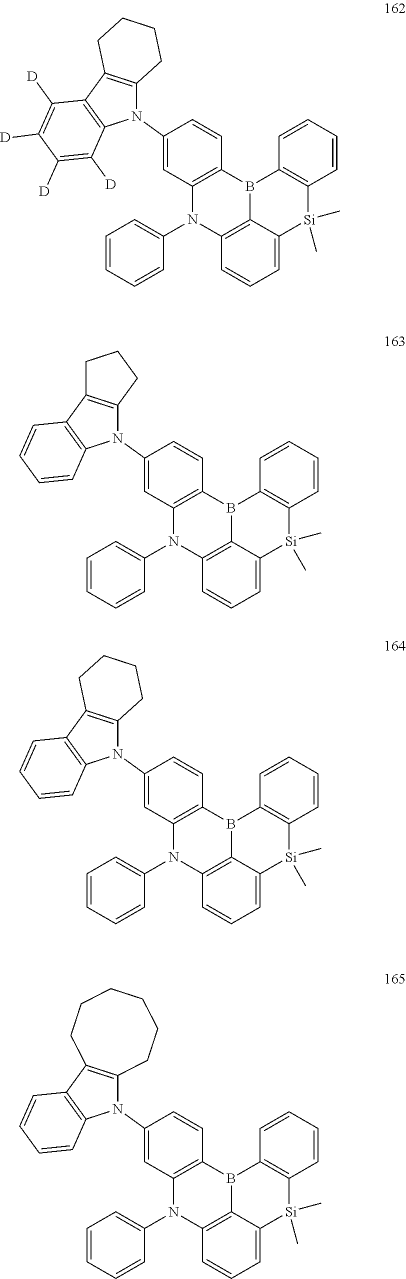 [SMILES: [2H]c1c([2H])c([2H])c2c(c1[2H])c1c(n2-c2ccc3c(c2)N(c2ccccc2)c2cccc4c2B3c2ccccc2[Si]4(C)C)CCCC1 ; C[Si]1(C)c2ccccc2B2c3ccc(-n4c5c(c6ccccc64)CCC5)cc3N(c3ccccc3)c3cccc1c32 ; C[Si]1(C)c2ccccc2B2c3ccc(-n4c5c(c6ccccc64)CCCC5)cc3N(c3ccccc3)c3cccc1c32 ; C[Si]1(C)c2ccccc2B2c3ccc(-n4c5c(c6ccccc64)CCCCCC5)cc3N(c3ccccc3)c3cccc1c32]

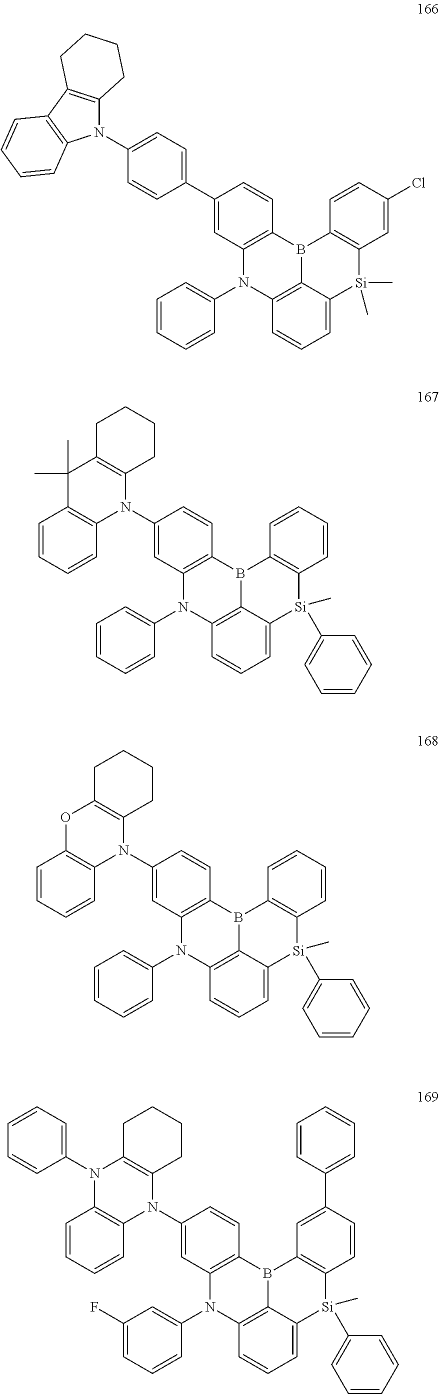 [SMILES: C[Si]1(C)c2cc(Cl)ccc2B2c3ccc(-c4ccc(-n5c6c(c7ccccc75)CCCC6)cc4)cc3N(c3ccccc3)c3cccc1c32 ; CC1(C)C2=C(CCCC2)N(c2ccc3c(c2)N(c2ccccc2)c2cccc4c2B3c2ccccc2[Si]4(C)c2ccccc2)c2ccccc21 ; C[Si]1(c2ccccc2)c2ccccc2B2c3ccc(N4C5=C(CCCC5)Oc5ccccc54)cc3N(c3ccccc3)c3cccc1c32 ; C[Si]1(c2ccccc2)c2ccc(-c3ccccc3)cc2B2c3ccc(N4C5=C(CCCC5)N(c5ccccc5)c5ccccc54)cc3N(c3cccc(F)c3)c3cccc1c32]

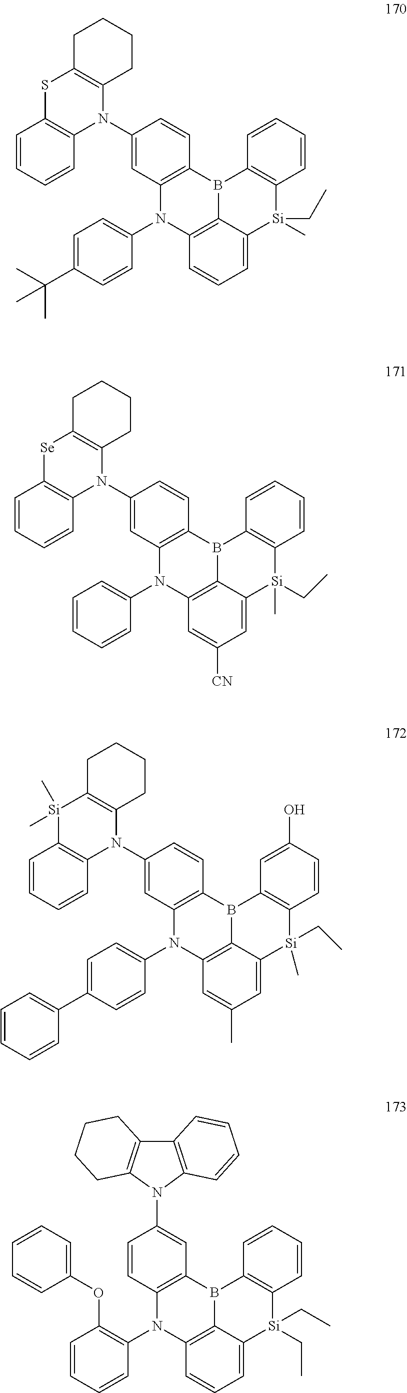 [SMILES: CC[Si]1(C)c2ccccc2B2c3ccc(N4C5=C(CCCC5)Sc5ccccc54)cc3N(c3ccc(C(C)(C)C)cc3)c3cccc1c32 ; CC[Si]1(C)c2ccccc2B2c3ccc(N4C5=C(CCCC5)[Se]c5ccccc54)cc3N(c3ccccc3)c3cc(C#N)cc1c32 ; CC[Si]1(C)c2ccc(O)cc2B2c3ccc(N4C5=C(CCCC5)[Si](C)(C)c5ccccc54)cc3N(c3ccc(-c4ccccc4)cc3)c3cc(C)cc1c32 ; CC[Si]1(CC)c2ccccc2B2c3cc(-n4c5c(c6ccccc64)CCCC5)ccc3N(c3ccccc3Oc3ccccc3)c3cccc1c32]

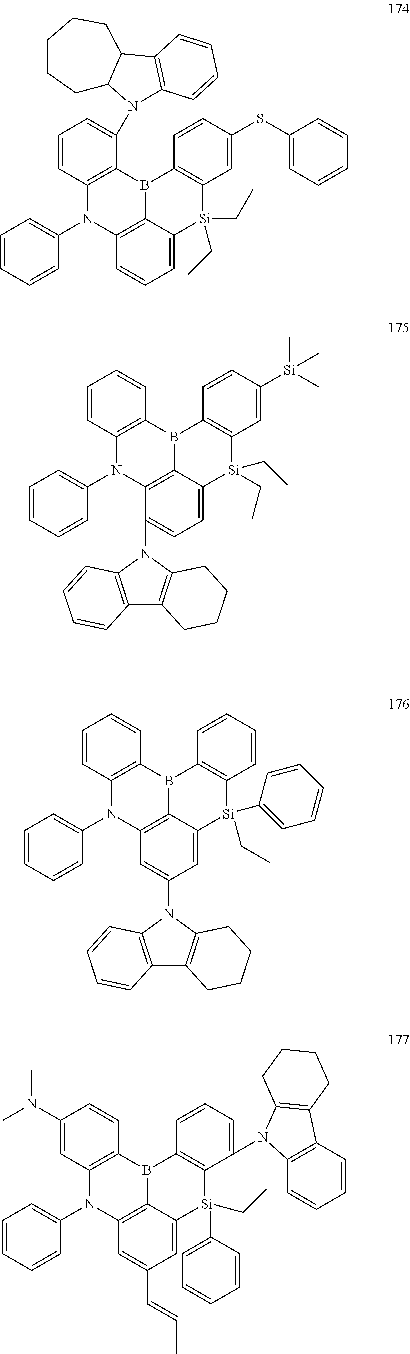 [SMILES: CC[Si]1(CC)c2cc(Sc3ccccc3)ccc2B2c3c(cccc3N3c4ccccc4C4CCCCCC43)N(c3ccccc3)c3cccc1c32 ; CC[Si]1(CC)c2cc([Si](C)(C)C)ccc2B2c3ccccc3N(c3ccccc3)c3c(-n4c5c(c6ccccc64)CCCC5)ccc1c32 ; CC[Si]1(c2ccccc2)c2ccccc2B2c3ccccc3N(c3ccccc3)c3cc(-n4c5c(c6ccccc64)CCCC5)cc1c32 ; C/C=C/c1cc2c3c(c1)[Si](CC)(c1ccccc1)c1c(cccc1-n1c4c(c5ccccc51)CCCC4)B3c1ccc(N(C)C)cc1N2c1ccccc1]

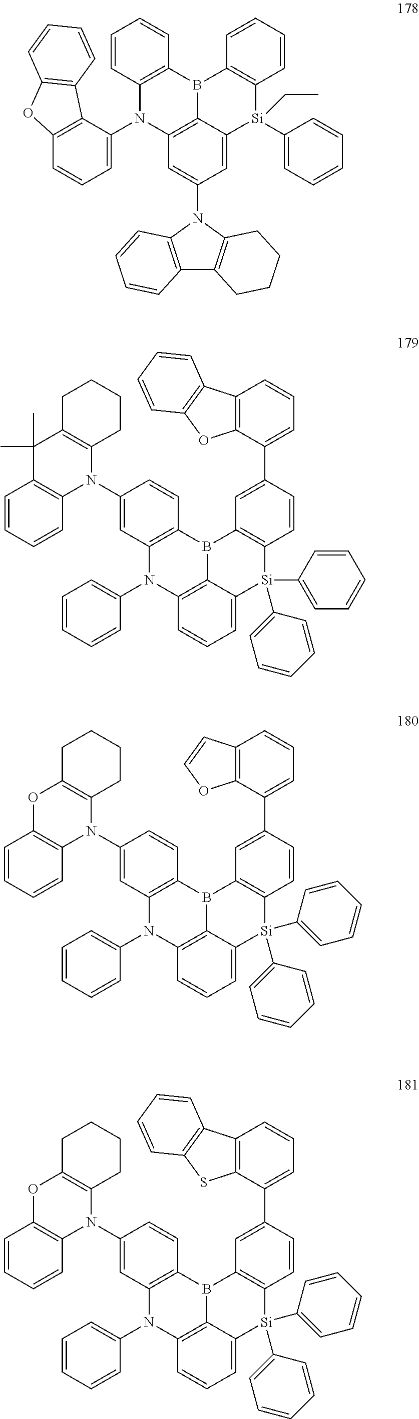 [SMILES: CC[Si]1(c2ccccc2)c2ccccc2B2c3ccccc3N(c3cccc4oc5ccccc5c34)c3cc(-n4c5c(c6ccccc64)CCCC5)cc1c32 ; CC1(C)C2=C(CCCC2)N(c2ccc3c(c2)N(c2ccccc2)c2cccc4c2B3c2cc(-c3cccc5c3oc3ccccc35)ccc2[Si]4(c2ccccc2)c2ccccc2)c2ccccc21 ; c1ccc(N2c3cc(N4C5=C(CCCC5)Oc5ccccc54)ccc3B3c4cc(-c5cccc6ccoc56)ccc4[Si](c4ccccc4)(c4ccccc4)c4cccc2c43)cc1 ; c1ccc(N2c3cc(N4C5=C(CCCC5)Oc5ccccc54)ccc3B3c4cc(-c5cccc6c5sc5ccccc56)ccc4[Si](c4ccccc4)(c4ccccc4)c4cccc2c43)cc1]

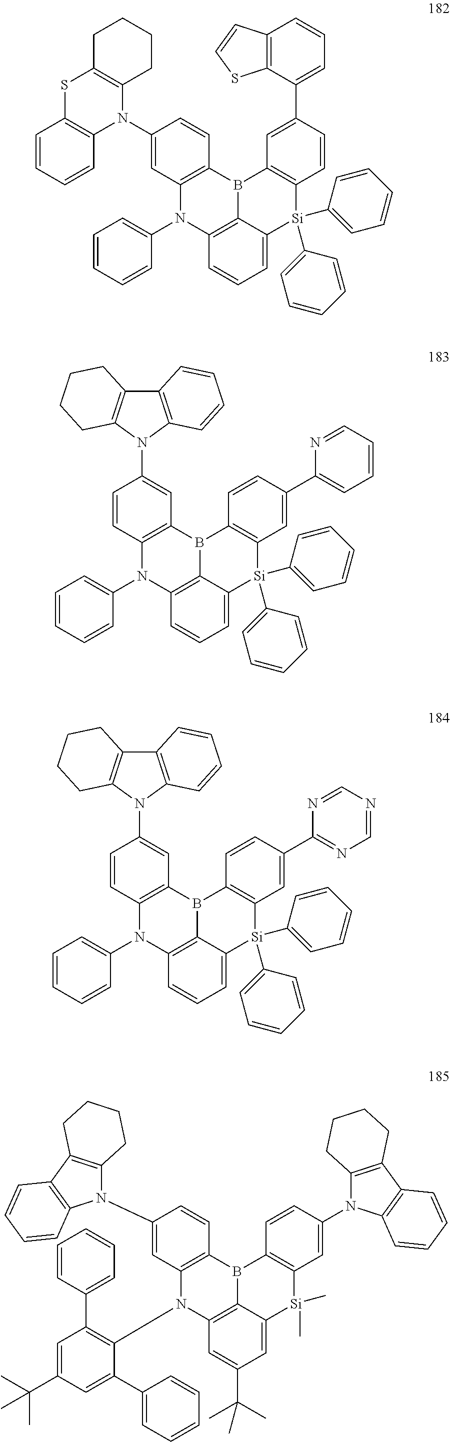 [SMILES: c1ccc(N2c3cc(N4C5=C(CCCC5)Sc5ccccc54)ccc3B3c4cc(-c5cccc6ccsc56)ccc4[Si](c4ccccc4)(c4ccccc4)c4cccc2c43)cc1 ; c1ccc(N2c3ccc(-n4c5c(c6ccccc64)CCCC5)cc3B3c4ccc(-c5ccccn5)cc4[Si](c4ccccc4)(c4ccccc4)c4cccc2c43)cc1 ; c1ccc(N2c3ccc(-n4c5c(c6ccccc64)CCCC5)cc3B3c4ccc(-c5ncncn5)cc4[Si](c4ccccc4)(c4ccccc4)c4cccc2c43)cc1 ; CC(C)(C)c1cc(-c2ccccc2)c(N2c3cc(-n4c5c(c6ccccc64)CCCC5)ccc3B3c4ccc(-n5c6c(c7ccccc75)CCCC6)cc4[Si](C)(C)c4cc(C(C)(C)C)cc2c43)c(-c2ccccc2)c1]

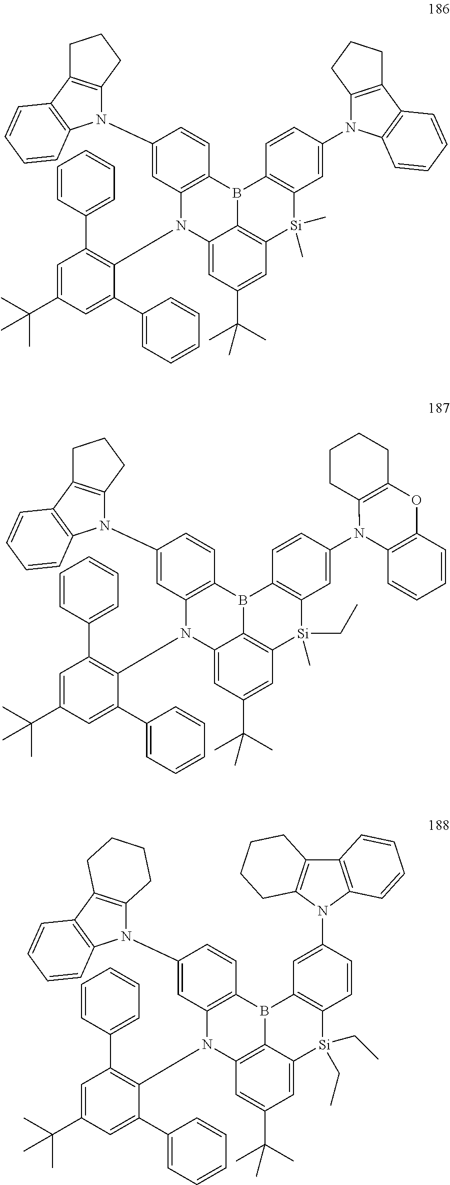 [SMILES: CC(C)(C)c1cc(-c2ccccc2)c(N2c3cc(-n4c5c(c6ccccc64)CCC5)ccc3B3c4ccc(-n5c6c(c7ccccc75)CCC6)cc4[Si](C)(C)c4cc(C(C)(C)C)cc2c43)c(-c2ccccc2)c1 ; CC[Si]1(C)c2cc(N3C4=C(CCCC4)Oc4ccccc43)ccc2B2c3ccc(-n4c5c(c6ccccc64)CCC5)cc3N(c3c(-c4ccccc4)cc(C(C)(C)C)cc3-c3ccccc3)c3cc(C(C)(C)C)cc1c32 ; CC[Si]1(CC)c2ccc(-n3c4c(c5ccccc53)CCCC4)cc2B2c3ccc(-n4c5c(c6ccccc64)CCCC5)cc3N(c3c(-c4ccccc4)cc(C(C)(C)C)cc3-c3ccccc3)c3cc(C(C)(C)C)cc1c32]

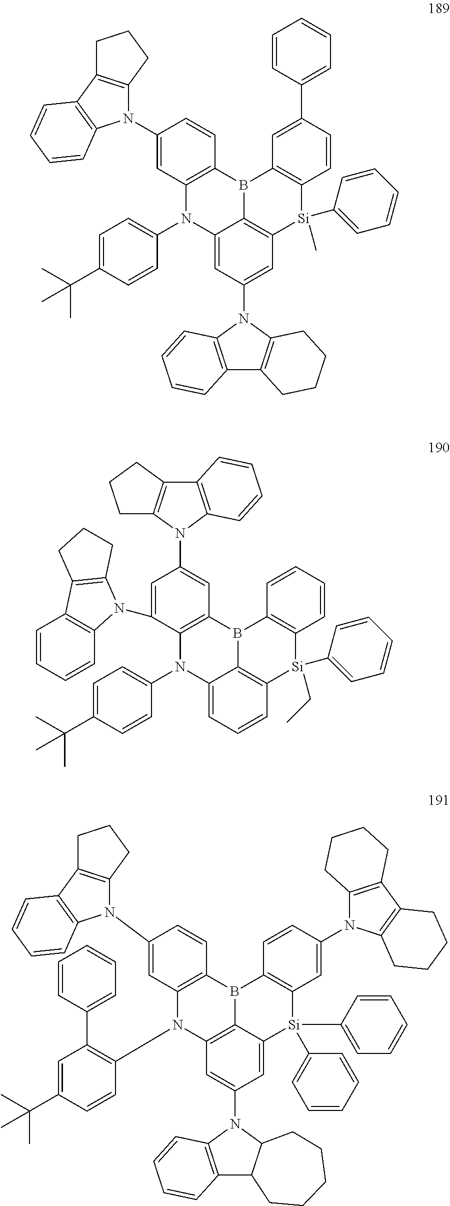 [SMILES: CC(C)(C)c1ccc(N2c3cc(-n4c5c(c6ccccc64)CCC5)ccc3B3c4cc(-c5ccccc5)ccc4[Si](C)(c4ccccc4)c4cc(-n5c6c(c7ccccc75)CCCC6)cc2c43)cc1 ; CC[Si]1(c2ccccc2)c2ccccc2B2c3cc(-n4c5c(c6ccccc64)CCC5)cc(-n4c5c(c6ccccc64)CCC5)c3N(c3ccc(C(C)(C)C)cc3)c3cccc1c32 ; CC(C)(C)c1ccc(N2c3cc(-n4c5c(c6ccccc64)CCC5)ccc3B3c4ccc(-n5c6c(c7c5CCCC7)CCCC6)cc4[Si](c4ccccc4)(c4ccccc4)c4cc(N5c6ccccc6C6CCCCCC65)cc2c43)c(-c2ccccc2)c1]

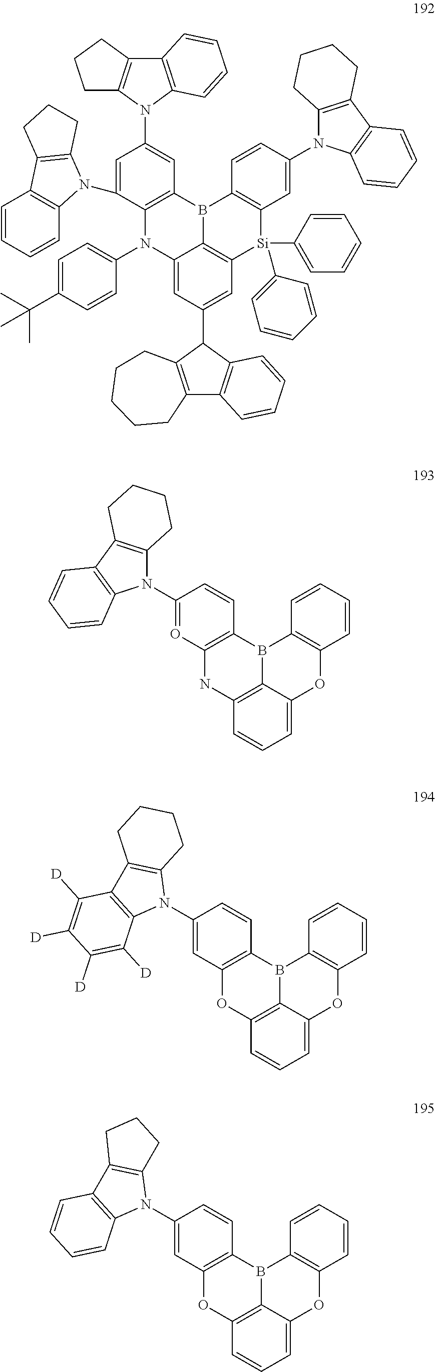

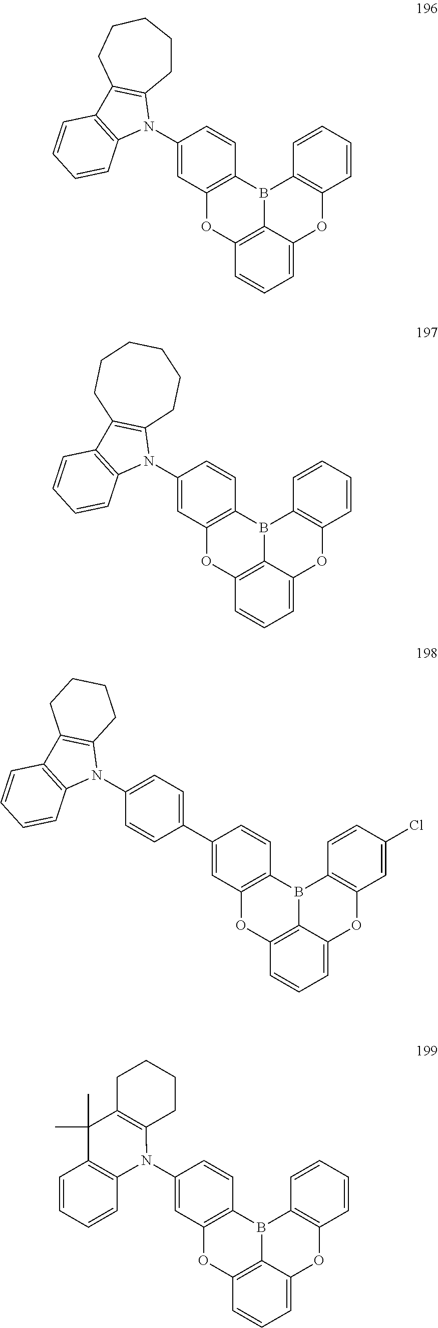 [SMILES: c1ccc2c(c1)Oc1cccc3c1B2c1ccc(-n2c4c(c5ccccc52)CCCCC4)cc1O3 ; c1ccc2c(c1)Oc1cccc3c1B2c1ccc(-n2c4c(c5ccccc52)CCCCCC4)cc1O3 ; Clc1ccc2c(c1)Oc1cccc3c1B2c1ccc(-c2ccc(-n4c5c(c6ccccc64)CCCC5)cc2)cc1O3 ; CC1(C)C2=C(CCCC2)N(c2ccc3c(c2)Oc2cccc4c2B3c2ccccc2O4)c2ccccc21]

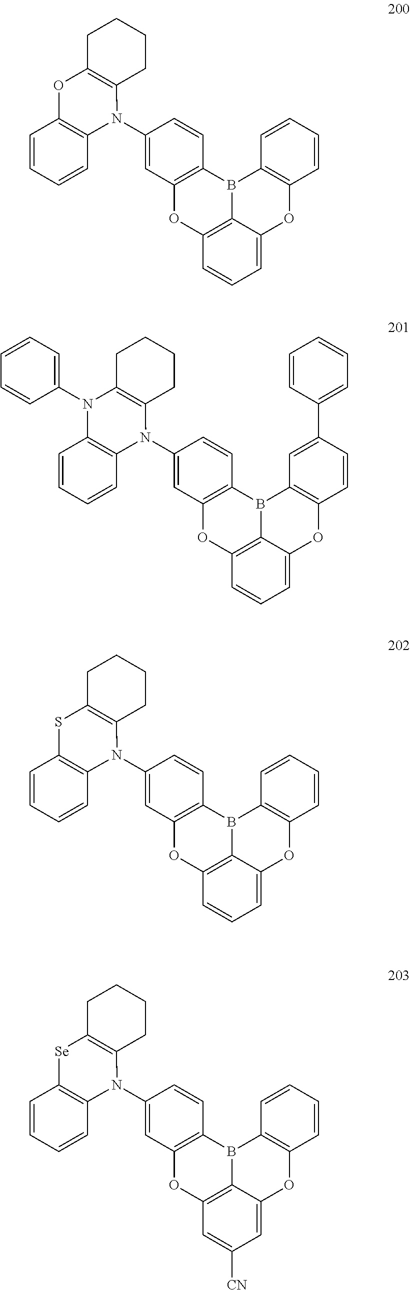 [SMILES: c1ccc2c(c1)Oc1cccc3c1B2c1ccc(N2C4=C(CCCC4)Oc4ccccc42)cc1O3 ; c1ccc(-c2ccc3c(c2)B2c4ccc(N5C6=C(CCCC6)N(c6ccccc6)c6ccccc65)cc4Oc4cccc(c42)O3)cc1 ; c1ccc2c(c1)Oc1cccc3c1B2c1ccc(N2C4=C(CCCC4)Sc4ccccc42)cc1O3 ; N#Cc1cc2c3c(c1)Oc1cc(N4C5=C(CCCC5)[Se]c5ccccc54)ccc1B3c1ccccc1O2]

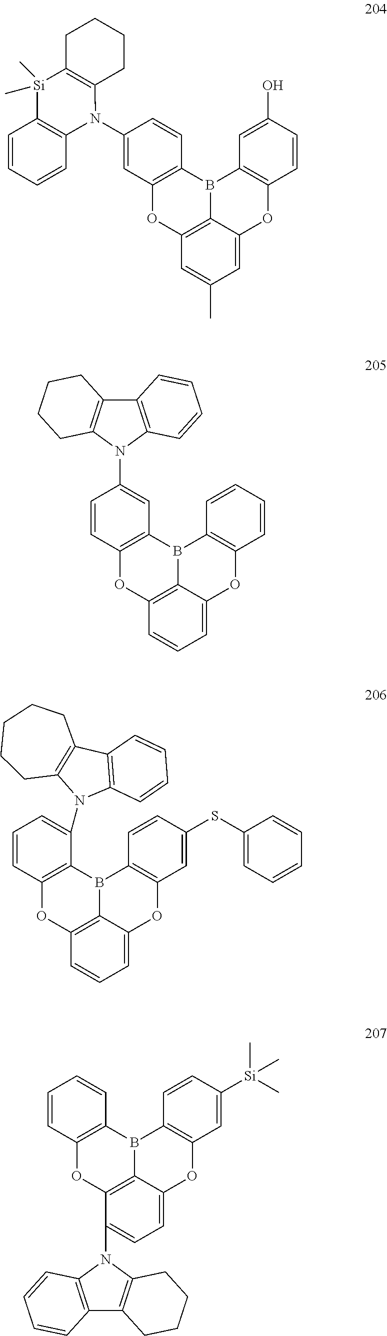 [SMILES: Cc1cc2c3c(c1)Oc1ccc(O)cc1B3c1ccc(N3C4=C(CCCC4)[Si](C)(C)c4ccccc43)cc1O2 ; c1ccc2c(c1)Oc1cccc3c1B2c1cc(-n2c4c(c5ccccc52)CCCC4)ccc1O3 ; c1ccc(Sc2ccc3c(c2)Oc2cccc4c2B3c2c(cccc2-n2c3c(c5ccccc52)CCCCC3)O4)cc1 ; C[Si](C)(C)c1ccc2c(c1)Oc1ccc(-n3c4c(c5ccccc53)CCCC4)c3c1B2c1ccccc1O3]

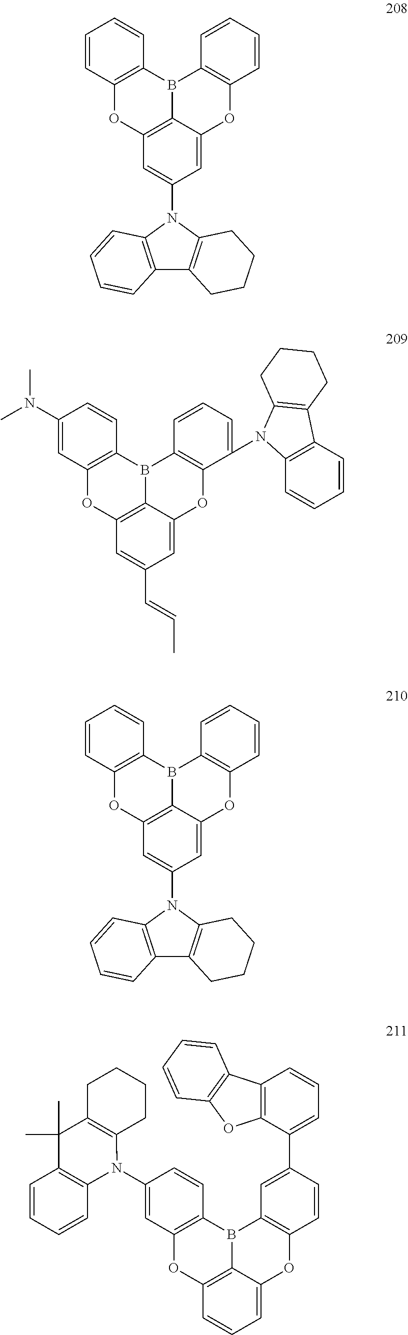 [SMILES: c1ccc2c(c1)Oc1cc(-n3c4c(c5ccccc53)CCCC4)cc3c1B2c1ccccc1O3 ; C/C=C/c1cc2c3c(c1)Oc1c(cccc1-n1c4c(c5ccccc51)CCCC4)B3c1ccc(N(C)C)cc1O2 ; c1ccc2c(c1)Oc1cc(-n3c4c(c5ccccc53)CCCC4)cc3c1B2c1ccccc1O3 ; CC1(C)C2=C(CCCC2)N(c2ccc3c(c2)Oc2cccc4c2B3c2cc(-c3cccc5c3oc3ccccc35)ccc2O4)c2ccccc21]

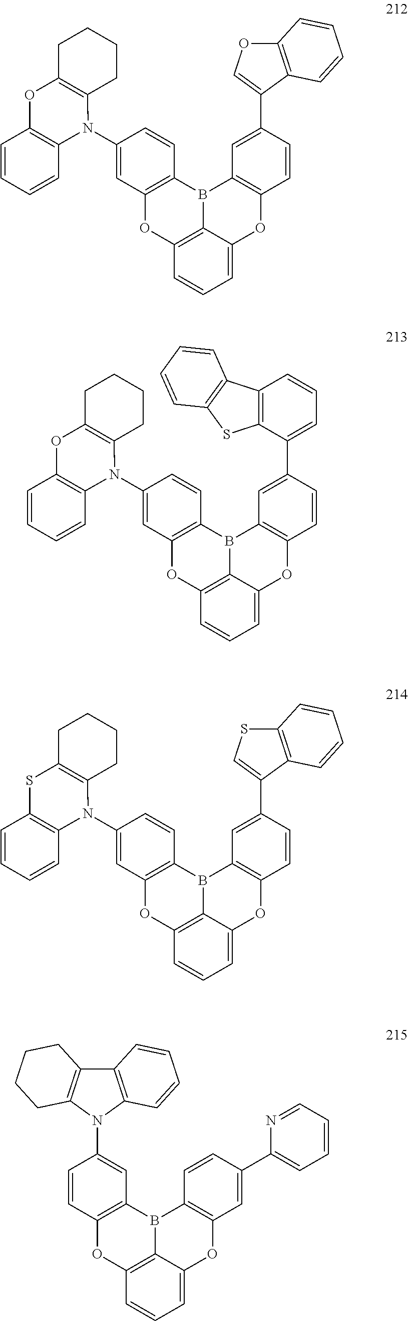 [SMILES: c1ccc2c(c1)OC1=C(CCCC1)N2c1ccc2c(c1)Oc1cccc3c1B2c1cc(-c2coc4ccccc24)ccc1O3 ; c1ccc2c(c1)OC1=C(CCCC1)N2c1ccc2c(c1)Oc1cccc3c1B2c1cc(-c2cccc4c2sc2ccccc24)ccc1O3 ; c1cc2c3c(c1)Oc1ccc(-c4csc5ccccc45)cc1B3c1ccc(N3C4=C(CCCC4)Sc4ccccc43)cc1O2 ; c1ccc(-c2ccc3c(c2)Oc2cccc4c2B3c2cc(-n3c5c(c6ccccc63)CCCC5)ccc2O4)nc1]

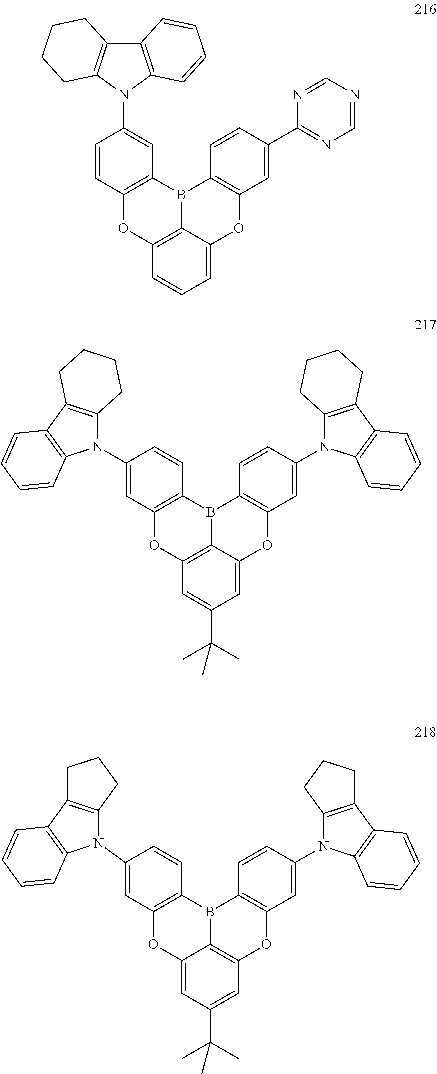 [SMILES: c1cc2c3c(c1)Oc1ccc(-n4c5c(c6ccccc64)CCCC5)cc1B3c1ccc(-c3ncncn3)cc1O2 ; CC(C)(C)c1cc2c3c(c1)Oc1cc(-n4c5c(c6ccccc64)CCCC5)ccc1B3c1ccc(-n3c4c(c5ccccc53)CCCC4)cc1O2 ; CC(C)(C)c1cc2c3c(c1)Oc1cc(-n4c5c(c6ccccc64)CCC5)ccc1B3c1ccc(-n3c4c(c5ccccc53)CCC4)cc1O2]

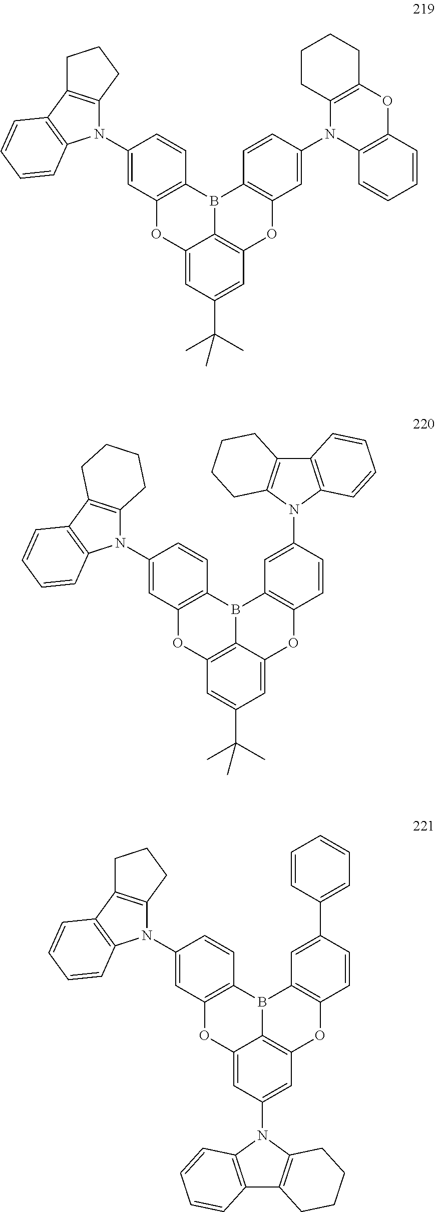 [SMILES: CC(C)(C)c1cc2c3c(c1)Oc1cc(-n4c5c(c6ccccc64)CCC5)ccc1B3c1ccc(N3C4=C(CCCC4)Oc4ccccc43)cc1O2 ; CC(C)(C)c1cc2c3c(c1)Oc1ccc(-n4c5c(c6ccccc64)CCCC5)cc1B3c1ccc(-n3c4c(c5ccccc53)CCCC4)cc1O2 ; c1ccc(-c2ccc3c(c2)B2c4ccc(-n5c6c(c7ccccc75)CCC6)cc4Oc4cc(-n5c6c(c7ccccc75)CCCC6)cc(c42)O3)cc1]

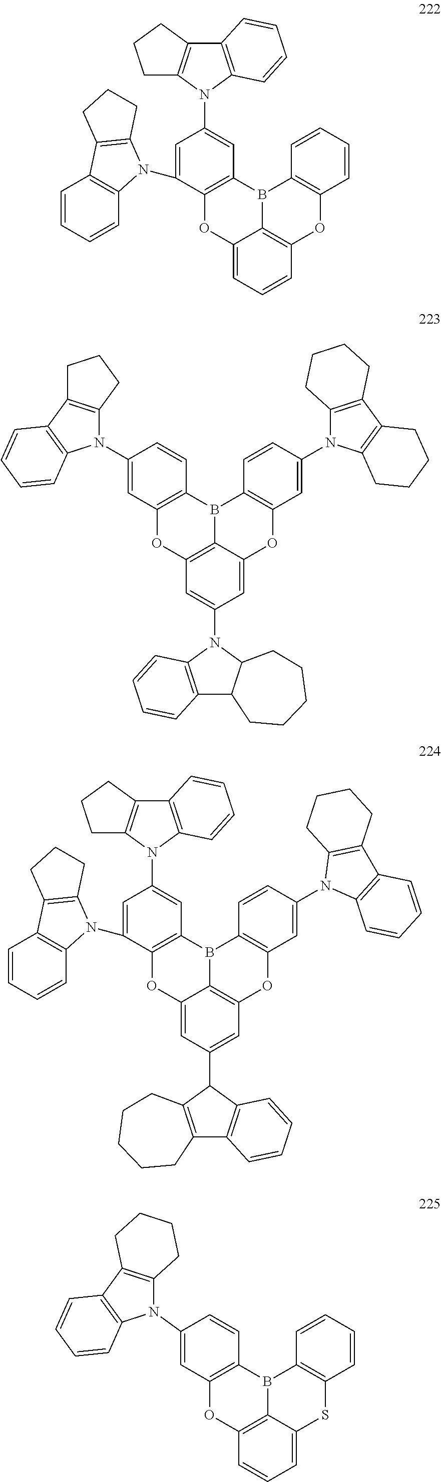

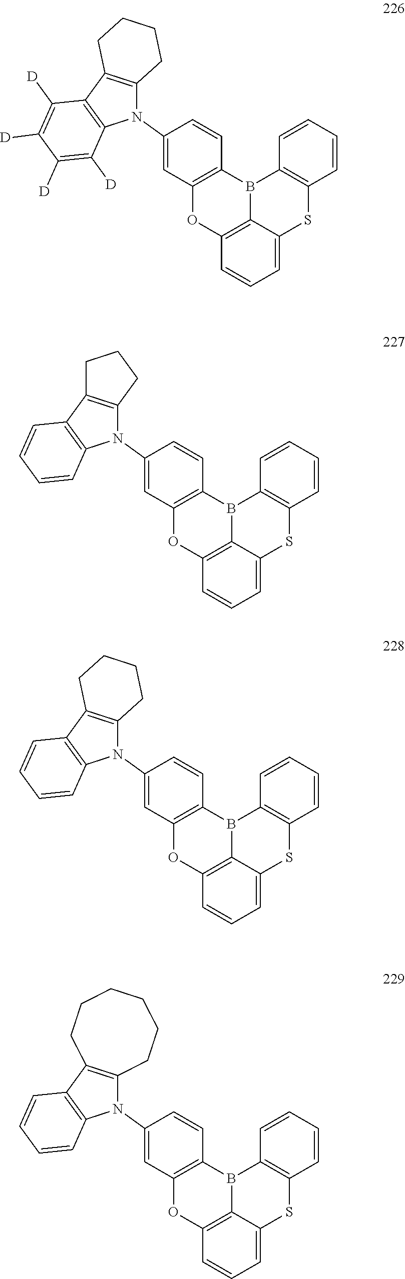 [SMILES: [2H]c1c([2H])c([2H])c2c(c1[2H])c1c(n2-c2ccc3c(c2)Oc2cccc4c2B3c2ccccc2S4)CCCC1 ; c1ccc2c(c1)Sc1cccc3c1B2c1ccc(-n2c4c(c5ccccc52)CCC4)cc1O3 ; c1ccc2c(c1)Sc1cccc3c1B2c1ccc(-n2c4c(c5ccccc52)CCCC4)cc1O3 ; c1ccc2c(c1)Sc1cccc3c1B2c1ccc(-n2c4c(c5ccccc52)CCCCCC4)cc1O3]

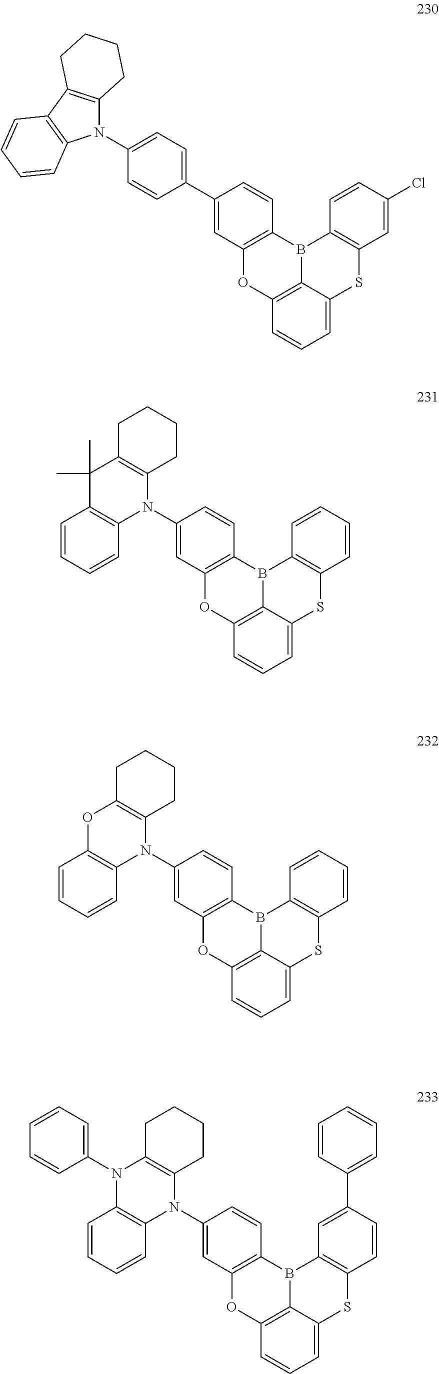 [SMILES: Clc1ccc2c(c1)Sc1cccc3c1B2c1ccc(-c2ccc(-n4c5c(c6ccccc64)CCCC5)cc2)cc1O3 ; CC1(C)C2=C(CCCC2)N(c2ccc3c(c2)Oc2cccc4c2B3c2ccccc2S4)c2ccccc21 ; c1ccc2c(c1)OC1=C(CCCC1)N2c1ccc2c(c1)Oc1cccc3c1B2c1ccccc1S3 ; c1ccc(-c2ccc3c(c2)B2c4ccc(N5C6=C(CCCC6)N(c6ccccc6)c6ccccc65)cc4Oc4cccc(c42)S3)cc1]

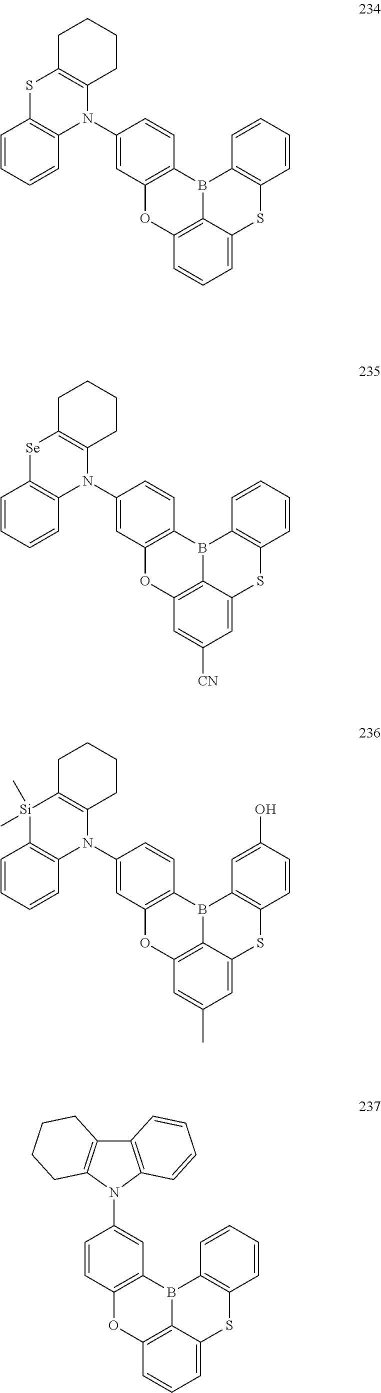 [SMILES: c1ccc2c(c1)Sc1cccc3c1B2c1ccc(N2C4=C(CCCC4)Sc4ccccc42)cc1O3 ; N#Cc1cc2c3c(c1)Sc1ccccc1B3c1ccc(N3C4=C(CCCC4)[Se]c4ccccc43)cc1O2 ; Cc1cc2c3c(c1)Sc1ccc(O)cc1B3c1ccc(N3C4=C(CCCC4)[Si](C)(C)c4ccccc43)cc1O2 ; c1ccc2c(c1)Sc1cccc3c1B2c1cc(-n2c4c(c5ccccc52)CCCC4)ccc1O3]

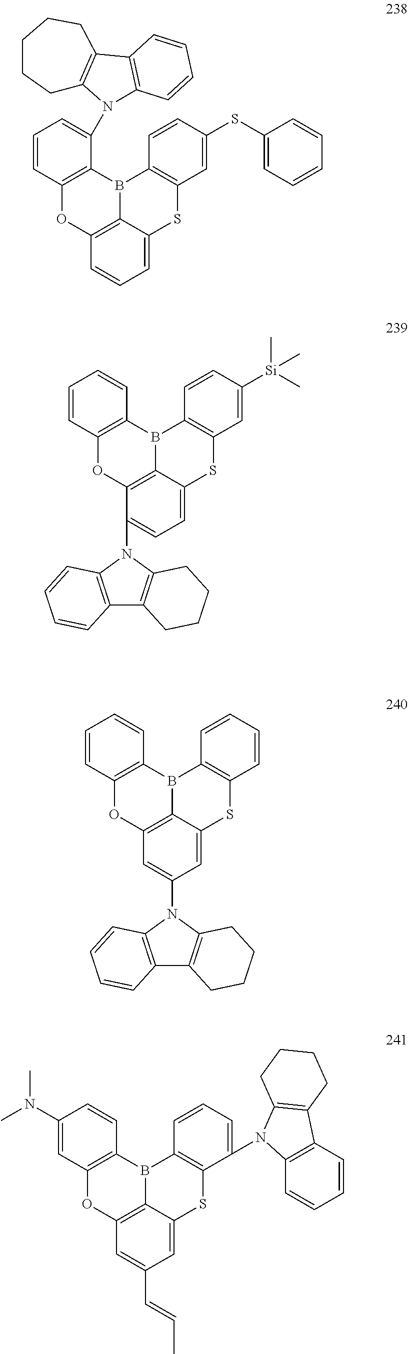

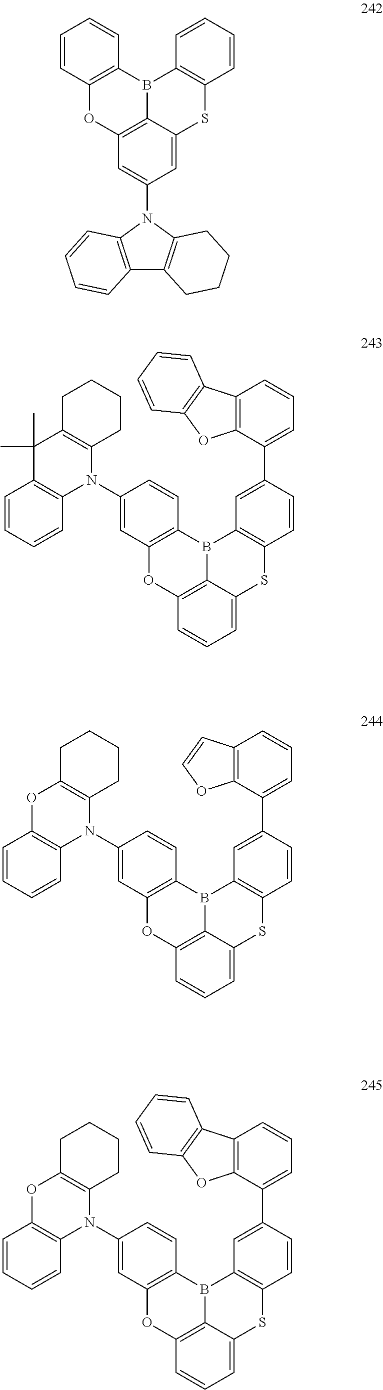 [SMILES: c1ccc2c(c1)Oc1cc(-n3c4c(c5ccccc53)CCCC4)cc3c1B2c1ccccc1S3 ; CC1(C)C2=C(CCCC2)N(c2ccc3c(c2)Oc2cccc4c2B3c2cc(-c3cccc5c3oc3ccccc35)ccc2S4)c2ccccc21 ; c1ccc2c(c1)OC1=C(CCCC1)N2c1ccc2c(c1)Oc1cccc3c1B2c1cc(-c2cccc4ccoc24)ccc1S3 ; c1ccc2c(c1)OC1=C(CCCC1)N2c1ccc2c(c1)Oc1cccc3c1B2c1cc(-c2cccc4c2oc2ccccc24)ccc1S3]

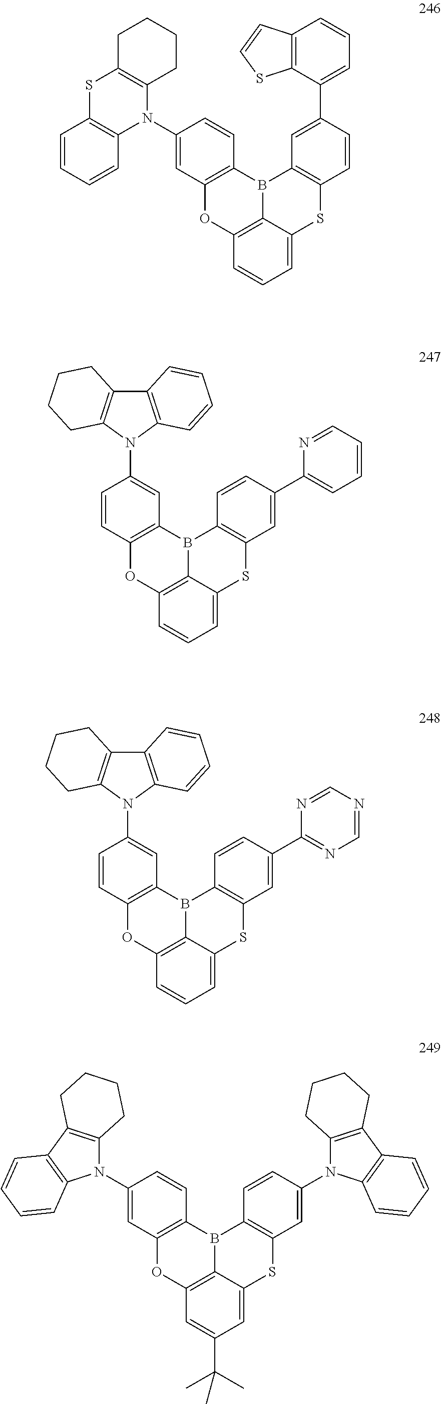 [SMILES: c1ccc2c(c1)SC1=C(CCCC1)N2c1ccc2c(c1)Oc1cccc3c1B2c1cc(-c2cccc4ccsc24)ccc1S3 ; c1ccc(-c2ccc3c(c2)Sc2cccc4c2B3c2cc(-n3c5c(c6ccccc63)CCCC5)ccc2O4)nc1 ; c1cc2c3c(c1)Sc1cc(-c4ncncn4)ccc1B3c1cc(-n3c4c(c5ccccc53)CCCC4)ccc1O2 ; CC(C)(C)c1cc2c3c(c1)Sc1cc(-n4c5c(c6ccccc64)CCCC5)ccc1B3c1ccc(-n3c4c(c5ccccc53)CCCC4)cc1O2]

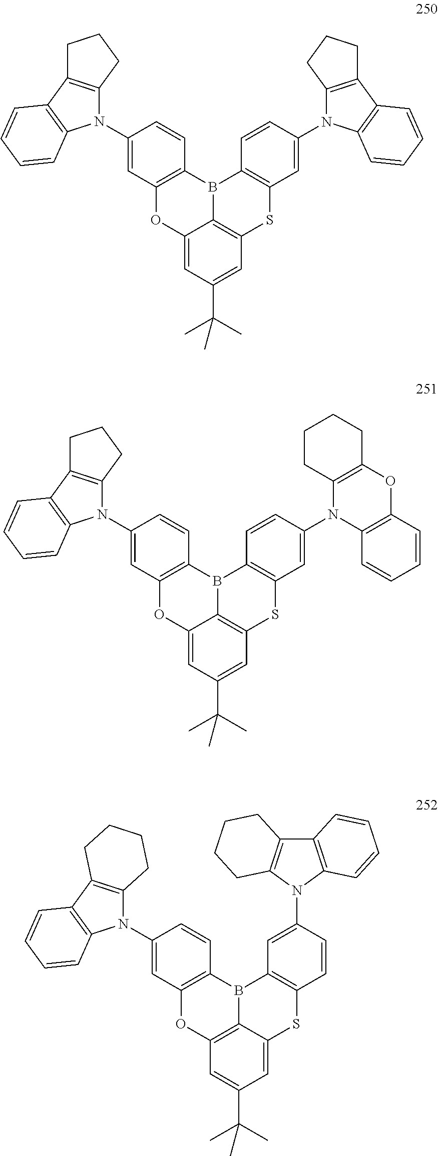 [SMILES: CC(C)(C)c1cc2c3c(c1)Sc1cc(-n4c5c(c6ccccc64)CCC5)ccc1B3c1ccc(-n3c4c(c5ccccc53)CCC4)cc1O2 ; CC(C)(C)c1cc2c3c(c1)Sc1cc(N4C5=C(CCCC5)Oc5ccccc54)ccc1B3c1ccc(-n3c4c(c5ccccc53)CCC4)cc1O2 ; CC(C)(C)c1cc2c3c(c1)Sc1ccc(-n4c5c(c6ccccc64)CCCC5)cc1B3c1ccc(-n3c4c(c5ccccc53)CCCC4)cc1O2]

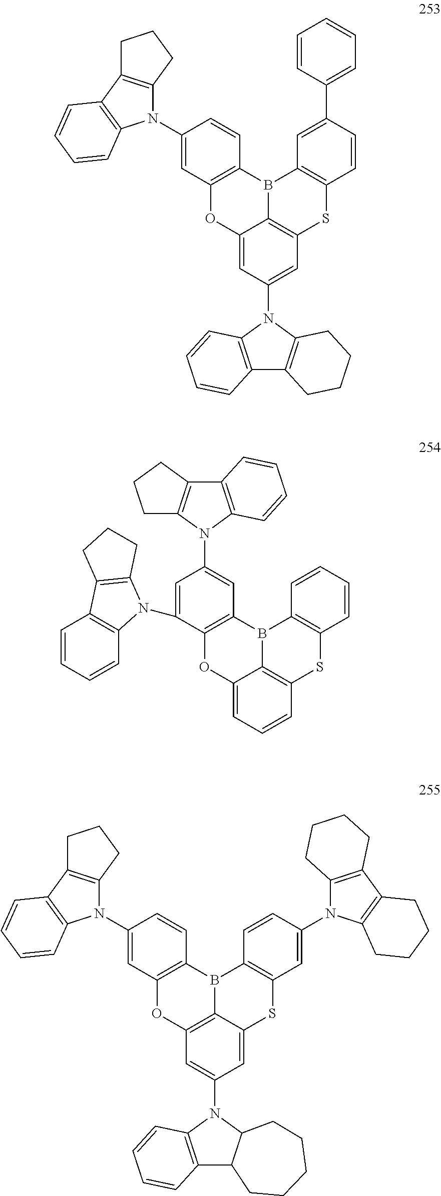 [SMILES: c1ccc(-c2ccc3c(c2)B2c4ccc(-n5c6c(c7ccccc75)CCC6)cc4Oc4cc(-n5c6c(c7ccccc75)CCCC6)cc(c42)S3)cc1 ; c1ccc2c(c1)Sc1cccc3c1B2c1cc(-n2c4c(c5ccccc52)CCC4)cc(-n2c4c(c5ccccc52)CCC4)c1O3 ; c1ccc2c(c1)C1CCCCCC1N2c1cc2c3c(c1)Sc1cc(-n4c5c(c6c4CCCC6)CCCC5)ccc1B3c1ccc(-n3c4c(c5ccccc53)CCC4)cc1O2]

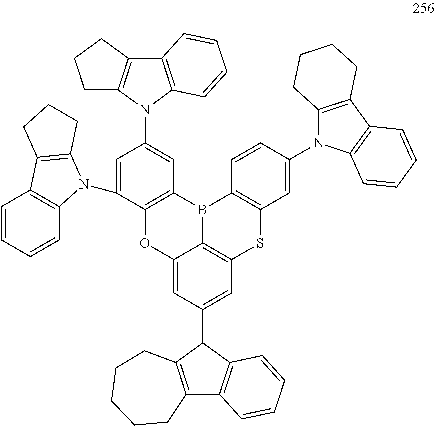 [SMILES: c1ccc2c(c1)C1=C(CCCCC1)C2c1cc2c3c(c1)Sc1cc(-n4c5c(c6ccccc64)CCCC5)ccc1B3c1cc(-n3c4c(c5ccccc53)CCC4)cc(-n3c4c(c5ccccc53)CCC4)c1O2]

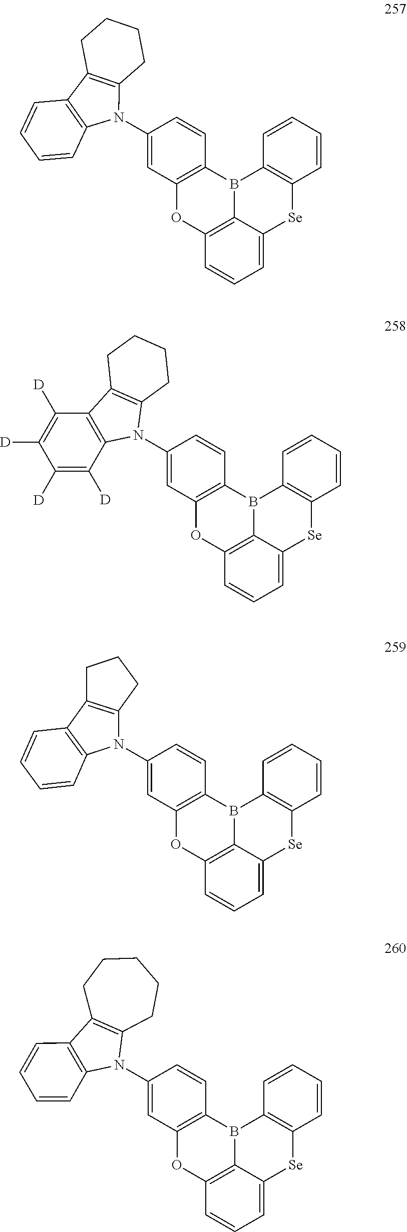 [SMILES: c1ccc2c(c1)[Se]c1cccc3c1B2c1ccc(-n2c4c(c5ccccc52)CCCC4)cc1O3 ; [2H]c1c([2H])c([2H])c2c(c1[2H])c1c(n2-c2ccc3c(c2)Oc2cccc4c2B3c2ccccc2[Se]4)CCCC1 ; c1ccc2c(c1)[Se]c1cccc3c1B2c1ccc(-n2c4c(c5ccccc52)CCC4)cc1O3 ; c1ccc2c(c1)[Se]c1cccc3c1B2c1ccc(-n2c4c(c5ccccc52)CCCCC4)cc1O3]

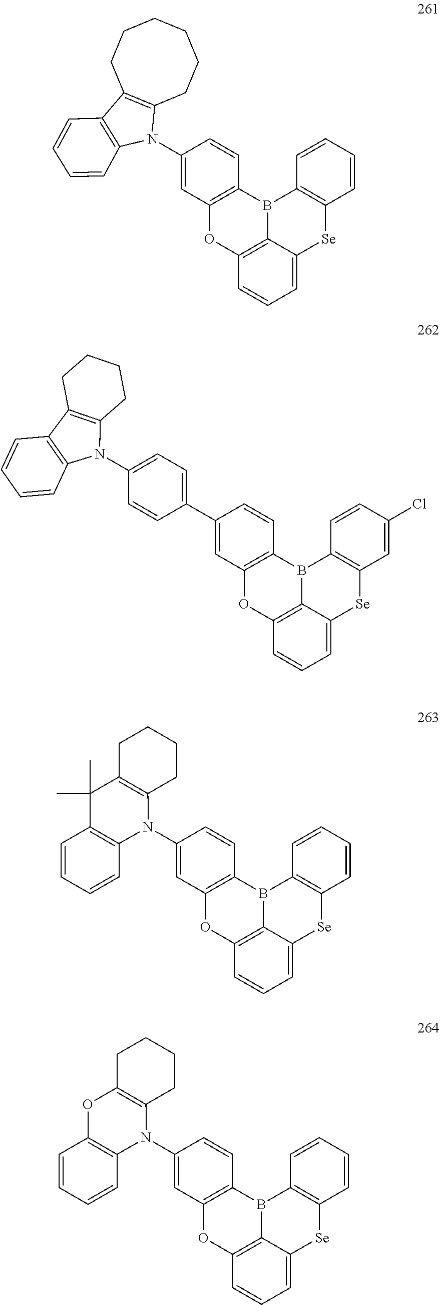 [SMILES: c1ccc2c(c1)[Se]c1cccc3c1B2c1ccc(-n2c4c(c5ccccc52)CCCCCC4)cc1O3 ; Clc1ccc2c(c1)[Se]c1cccc3c1B2c1ccc(-c2ccc(-n4c5c(c6ccccc64)CCCC5)cc2)cc1O3 ; CC1(C)C2=C(CCCC2)N(c2ccc3c(c2)Oc2cccc4c2B3c2ccccc2[Se]4)c2ccccc21 ; c1ccc2c(c1)OC1=C(CCCC1)N2c1ccc2c(c1)Oc1cccc3c1B2c1ccccc1[Se]3]

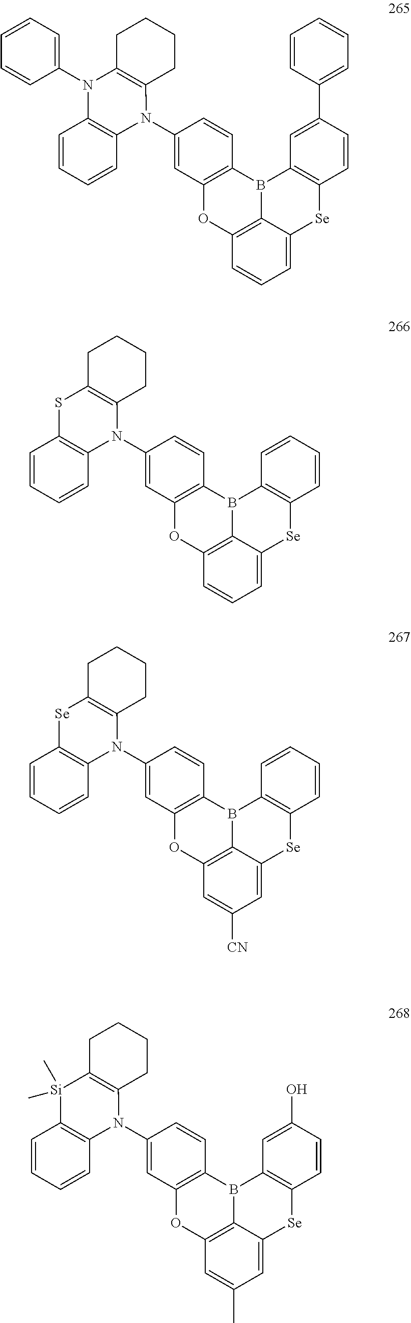 [SMILES: c1ccc(-c2ccc3c(c2)B2c4ccc(N5C6=C(CCCC6)N(c6ccccc6)c6ccccc65)cc4Oc4cccc(c42)[Se]3)cc1 ; c1ccc2c(c1)SC1=C(CCCC1)N2c1ccc2c(c1)Oc1cccc3c1B2c1ccccc1[Se]3 ; N#Cc1cc2c3c(c1)[Se]c1ccccc1B3c1ccc(N3C4=C(CCCC4)[Se]c4ccccc43)cc1O2 ; Cc1cc2c3c(c1)[Se]c1ccc(O)cc1B3c1ccc(N3C4=C(CCCC4)[Si](C)(C)c4ccccc43)cc1O2]

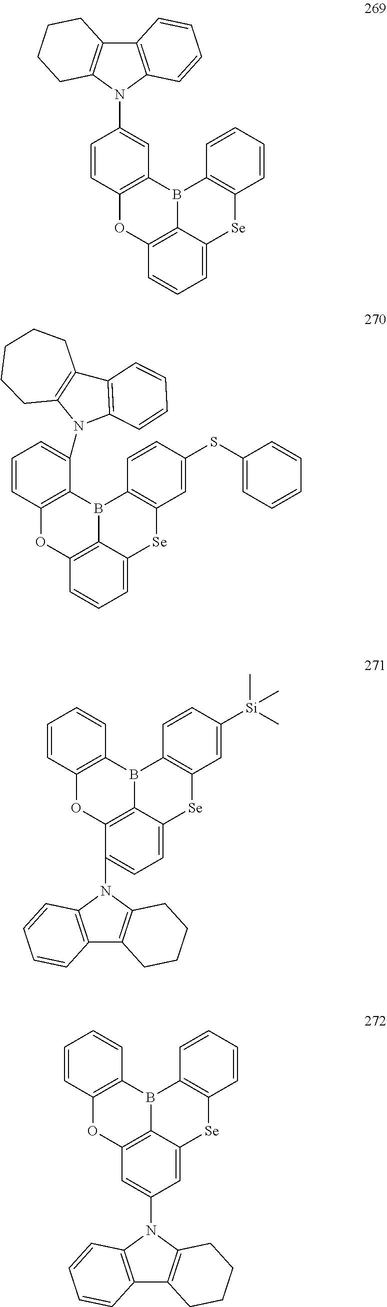 [SMILES: c1ccc2c(c1)[Se]c1cccc3c1B2c1cc(-n2c4c(c5ccccc52)CCCC4)ccc1O3 ; c1ccc(Sc2ccc3c(c2)[Se]c2cccc4c2B3c2c(cccc2-n2c3c(c5ccccc52)CCCCC3)O4)cc1 ; C[Si](C)(C)c1ccc2c(c1)[Se]c1ccc(-n3c4c(c5ccccc53)CCCC4)c3c1B2c1ccccc1O3 ; c1ccc2c(c1)Oc1cc(-n3c4c(c5ccccc53)CCCC4)cc3c1B2c1ccccc1[Se]3]

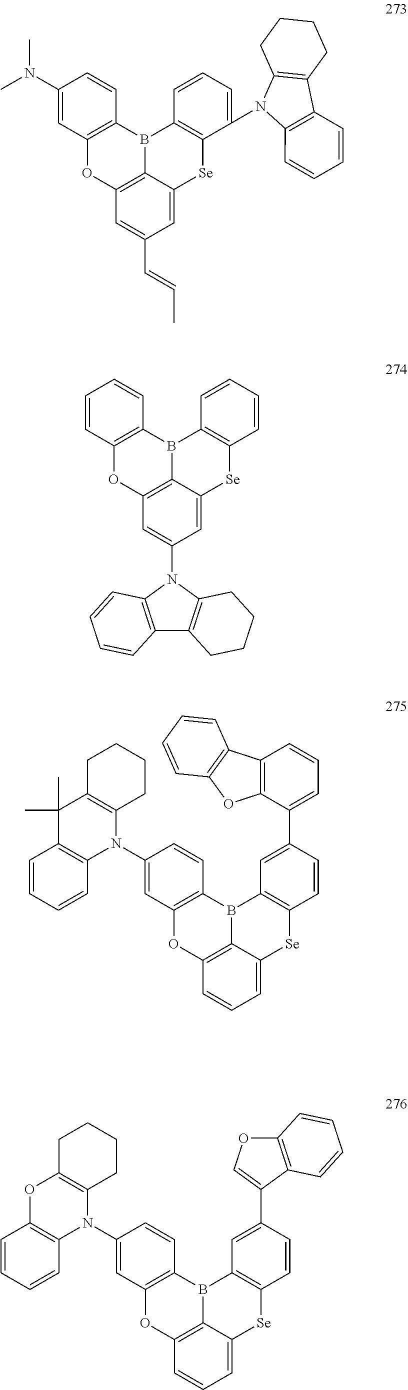 [SMILES: C/C=C/c1cc2c3c(c1)[Se]c1c(cccc1-n1c4c(c5ccccc51)CCCC4)B3c1ccc(N(C)C)cc1O2 ; c1ccc2c(c1)Oc1cc(-n3c4c(c5ccccc53)CCCC4)cc3c1B2c1ccccc1[Se]3 ; CC1(C)C2=C(CCCC2)N(c2ccc3c(c2)Oc2cccc4c2B3c2cc(-c3cccc5c3oc3ccccc35)ccc2[Se]4)c2ccccc21 ; c1ccc2c(c1)OC1=C(CCCC1)N2c1ccc2c(c1)Oc1cccc3c1B2c1cc(-c2coc4ccccc24)ccc1[Se]3]

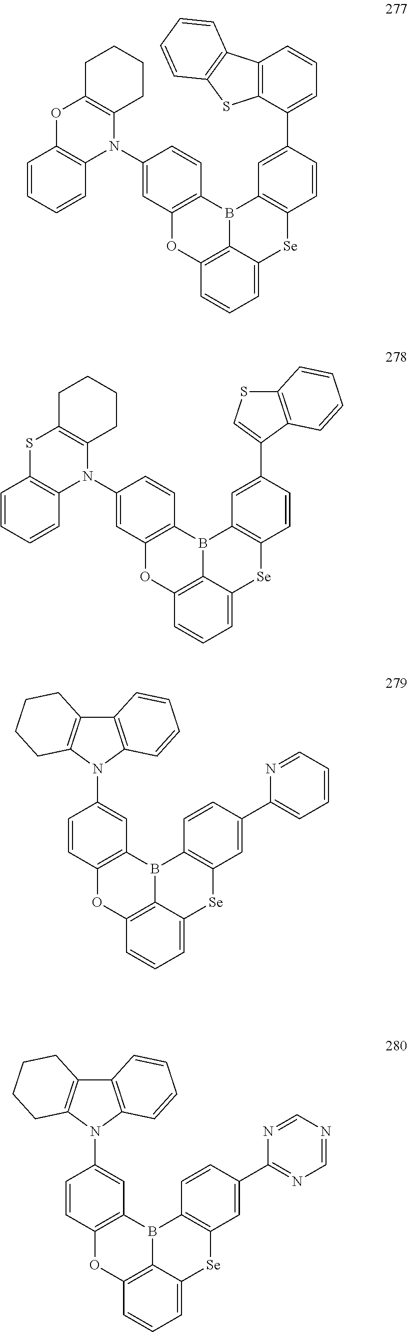 [SMILES: c1ccc2c(c1)OC1=C(CCCC1)N2c1ccc2c(c1)Oc1cccc3c1B2c1cc(-c2cccc4c2sc2ccccc24)ccc1[Se]3 ; c1ccc2c(c1)SC1=C(CCCC1)N2c1ccc2c(c1)Oc1cccc3c1B2c1cc(-c2csc4ccccc24)ccc1[Se]3 ; c1ccc(-c2ccc3c(c2)[Se]c2cccc4c2B3c2cc(-n3c5c(c6ccccc63)CCCC5)ccc2O4)nc1 ; c1cc2c3c(c1)[Se]c1cc(-c4ncncn4)ccc1B3c1cc(-n3c4c(c5ccccc53)CCCC4)ccc1O2]

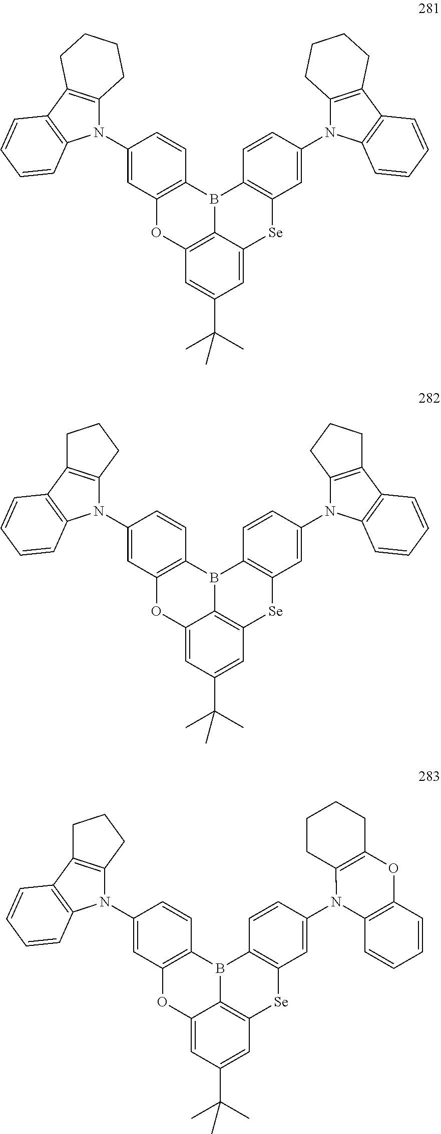 [SMILES: CC(C)(C)c1cc2c3c(c1)[Se]c1cc(-n4c5c(c6ccccc64)CCCC5)ccc1B3c1ccc(-n3c4c(c5ccccc53)CCCC4)cc1O2 ; CC(C)(C)c1cc2c3c(c1)[Se]c1cc(-n4c5c(c6ccccc64)CCC5)ccc1B3c1ccc(-n3c4c(c5ccccc53)CCC4)cc1O2 ; CC(C)(C)c1cc2c3c(c1)[Se]c1cc(N4C5=C(CCCC5)Oc5ccccc54)ccc1B3c1ccc(-n3c4c(c5ccccc53)CCC4)cc1O2]

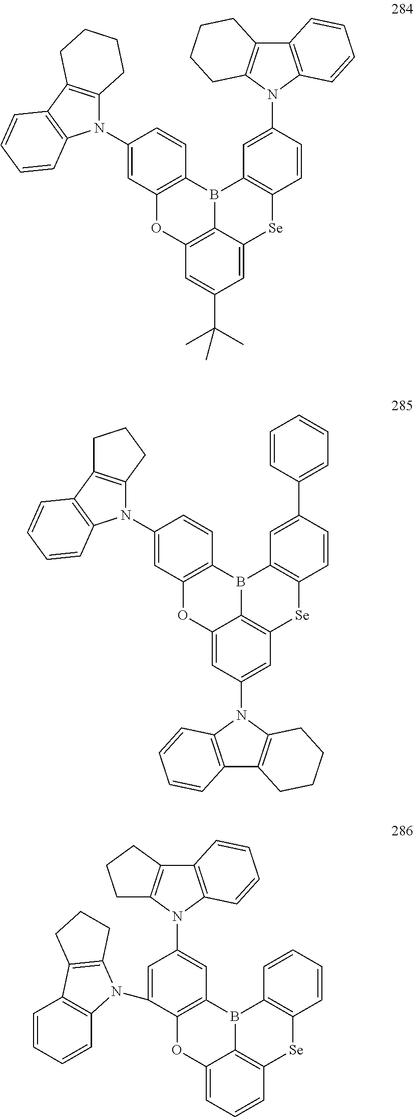 [SMILES: CC(C)(C)c1cc2c3c(c1)[Se]c1ccc(-n4c5c(c6ccccc64)CCCC5)cc1B3c1ccc(-n3c4c(c5ccccc53)CCCC4)cc1O2 ; c1ccc(-c2ccc3c(c2)B2c4ccc(-n5c6c(c7ccccc75)CCC6)cc4Oc4cc(-n5c6c(c7ccccc75)CCCC6)cc(c42)[Se]3)cc1 ; c1ccc2c(c1)[Se]c1cccc3c1B2c1cc(-n2c4c(c5ccccc52)CCC4)cc(-n2c4c(c5ccccc52)CCC4)c1O3]

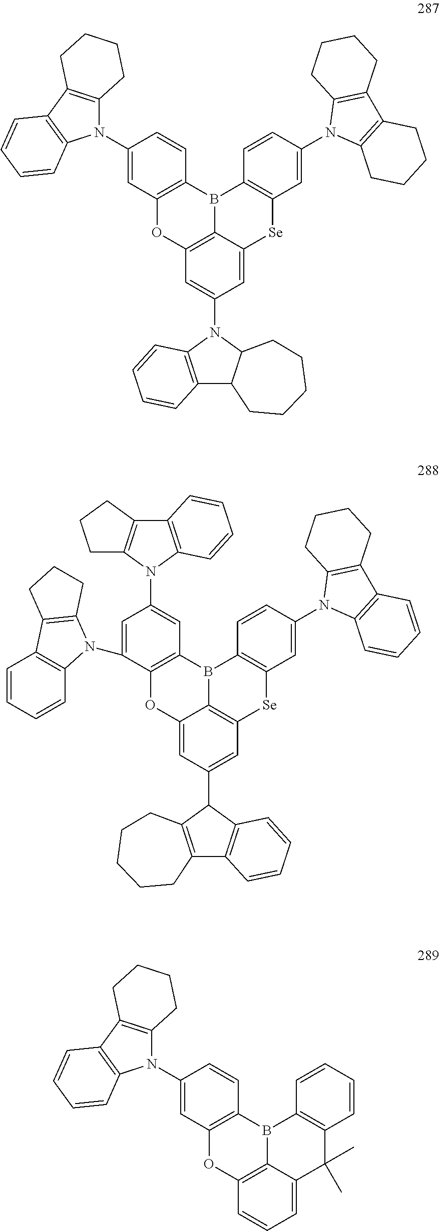 [SMILES: c1ccc2c(c1)C1CCCCCC1N2c1cc2c3c(c1)[Se]c1cc(-n4c5c(c6c4CCCC6)CCCC5)ccc1B3c1ccc(-n3c4c(c5ccccc53)CCCC4)cc1O2 ; c1ccc2c(c1)C1=C(CCCCC1)C2c1cc2c3c(c1)[Se]c1cc(-n4c5c(c6ccccc64)CCCC5)ccc1B3c1cc(-n3c4c(c5ccccc53)CCC4)cc(-n3c4c(c5ccccc53)CCC4)c1O2 ; CC1(C)c2ccccc2B2c3ccc(-n4c5c(c6ccccc64)CCCC5)cc3Oc3cccc1c32]

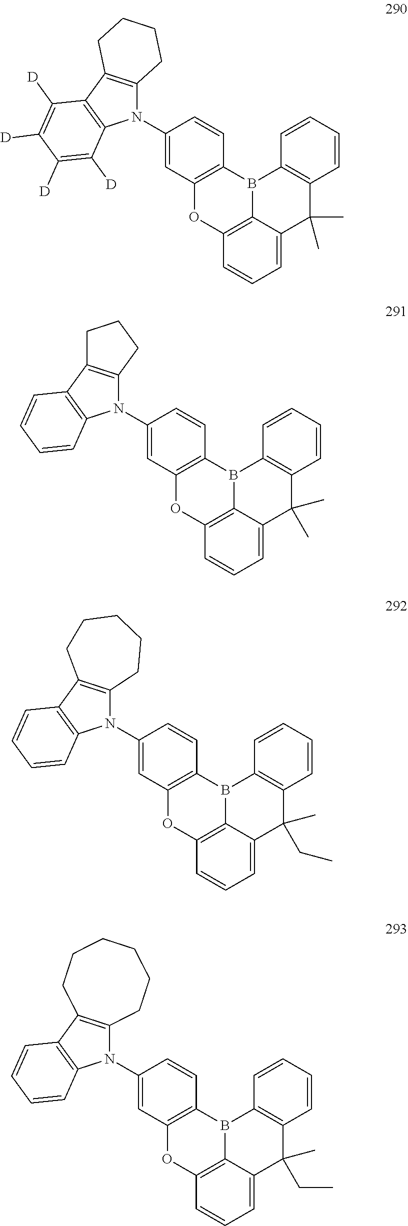 [SMILES: [2H]c1c([2H])c([2H])c2c(c1[2H])c1c(n2-c2ccc3c(c2)Oc2cccc4c2B3c2ccccc2C4(C)C)CCCC1 ; CC1(C)c2ccccc2B2c3ccc(-n4c5c(c6ccccc64)CCC5)cc3Oc3cccc1c32 ; CCC1(C)c2ccccc2B2c3ccc(-n4c5c(c6ccccc64)CCCCC5)cc3Oc3cccc1c32 ; CCC1(C)c2ccccc2B2c3ccc(-n4c5c(c6ccccc64)CCCCCC5)cc3Oc3cccc1c32]

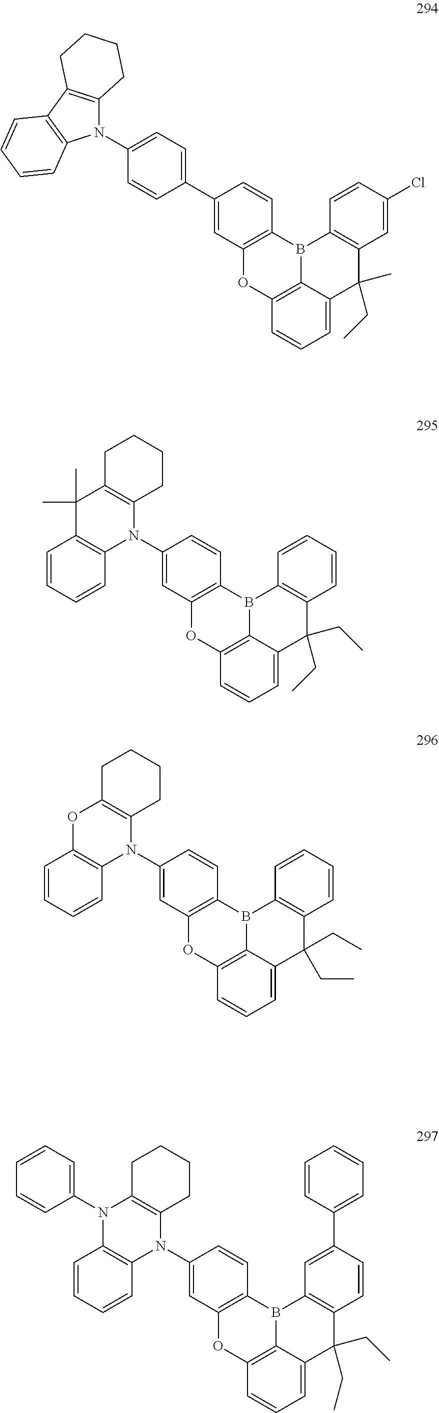 [SMILES: CCC1(C)c2cc(Cl)ccc2B2c3ccc(-c4ccc(-n5c6c(c7ccccc75)CCCC6)cc4)cc3Oc3cccc1c32 ; CCC1(CC)c2ccccc2B2c3ccc(N4C5=C(CCCC5)C(C)(C)c5ccccc54)cc3Oc3cccc1c32 ; CCC1(CC)c2ccccc2B2c3ccc(N4C5=C(CCCC5)Oc5ccccc54)cc3Oc3cccc1c32 ; CCC1(CC)c2ccc(-c3ccccc3)cc2B2c3ccc(N4C5=C(CCCC5)N(c5ccccc5)c5ccccc54)cc3Oc3cccc1c32]

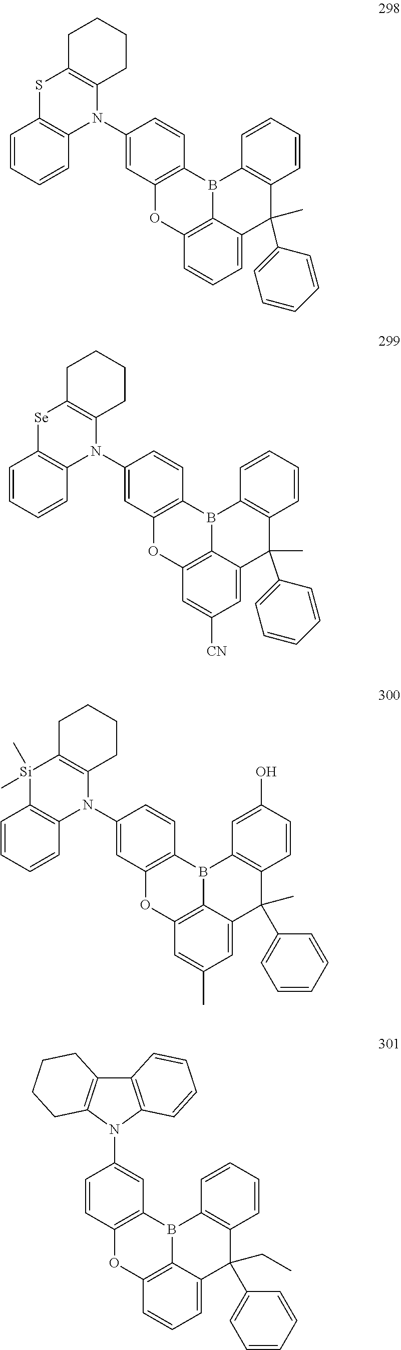 [SMILES: CC1(c2ccccc2)c2ccccc2B2c3ccc(N4C5=C(CCCC5)Sc5ccccc54)cc3Oc3cccc1c32 ; CC1(c2ccccc2)c2ccccc2B2c3ccc(N4C5=C(CCCC5)[Se]c5ccccc54)cc3Oc3cc(C#N)cc1c32 ; Cc1cc2c3c(c1)C(C)(c1ccccc1)c1ccc(O)cc1B3c1ccc(N3C4=C(CCCC4)[Si](C)(C)c4ccccc43)cc1O2 ; CCC1(c2ccccc2)c2ccccc2B2c3cc(-n4c5c(c6ccccc64)CCCC5)ccc3Oc3cccc1c32]

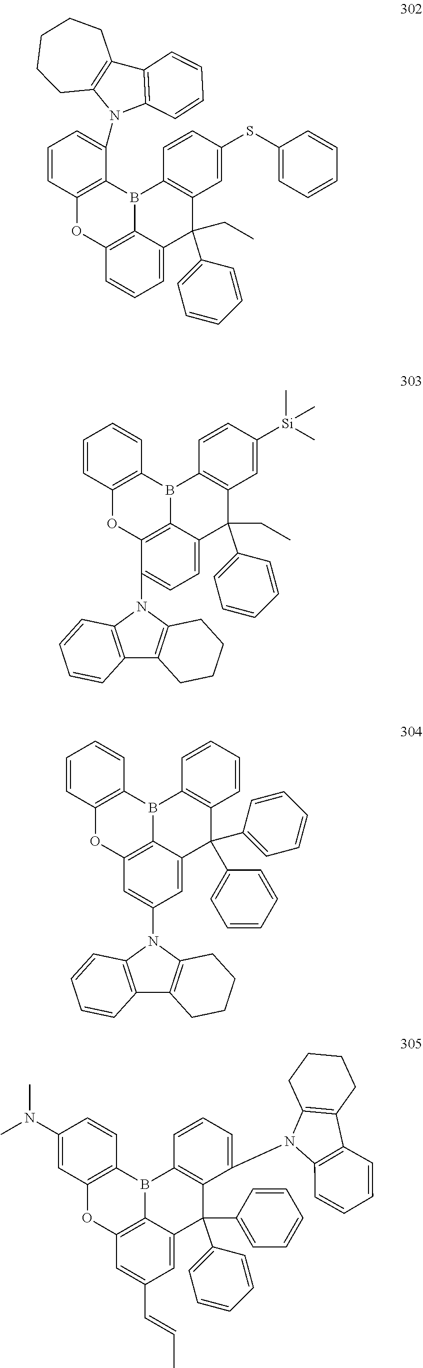

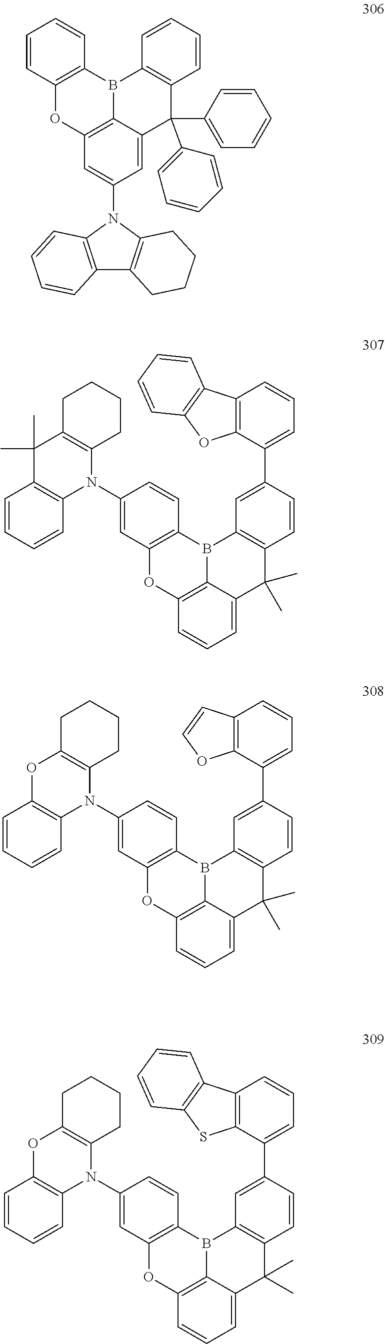

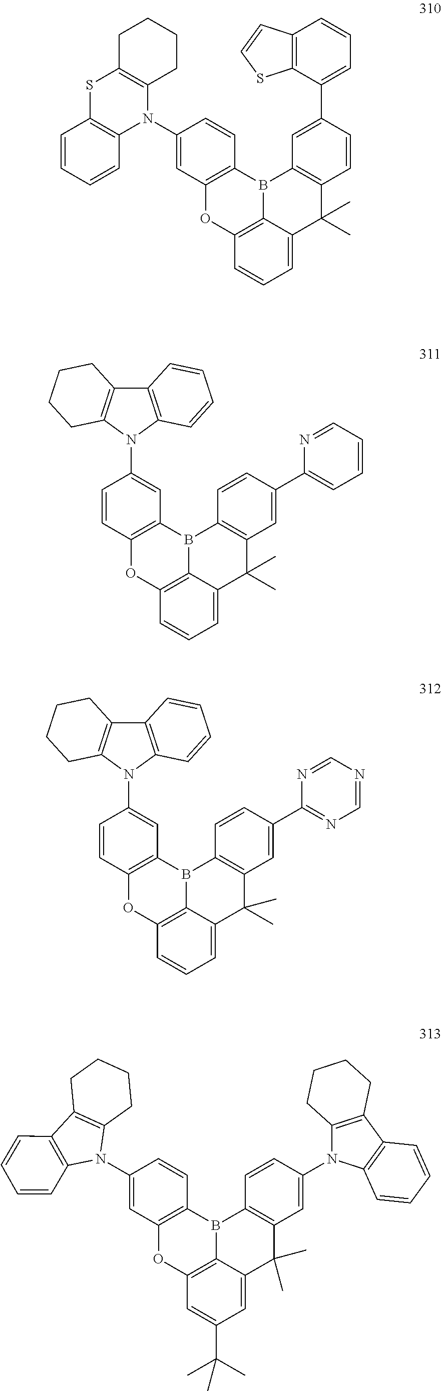 [SMILES: CC1(C)c2ccc(-c3cccc4ccsc34)cc2B2c3ccc(N4C5=C(CCCC5)Sc5ccccc54)cc3Oc3cccc1c32 ; CC1(C)c2cc(-c3ccccn3)ccc2B2c3cc(-n4c5c(c6ccccc64)CCCC5)ccc3Oc3cccc1c32 ; CC1(C)c2cc(-c3ncncn3)ccc2B2c3cc(-n4c5c(c6ccccc64)CCCC5)ccc3Oc3cccc1c32 ; CC(C)(C)c1cc2c3c(c1)C(C)(C)c1cc(-n4c5c(c6ccccc64)CCCC5)ccc1B3c1ccc(-n3c4c(c5ccccc53)CCCC4)cc1O2]

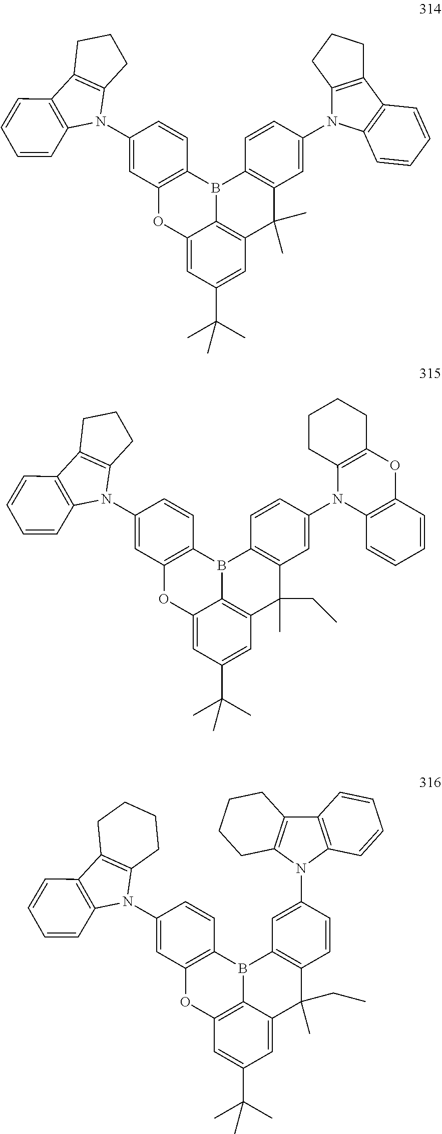 [SMILES: CC(C)(C)c1cc2c3c(c1)C(C)(C)c1cc(-n4c5c(c6ccccc64)CCC5)ccc1B3c1ccc(-n3c4c(c5ccccc53)CCC4)cc1O2 ; CCC1(C)c2cc(N3C4=C(CCCC4)Oc4ccccc43)ccc2B2c3ccc(-n4c5c(c6ccccc64)CCC5)cc3Oc3cc(C(C)(C)C)cc1c32 ; CCC1(C)c2ccc(-n3c4c(c5ccccc53)CCCC4)cc2B2c3ccc(-n4c5c(c6ccccc64)CCCC5)cc3Oc3cc(C(C)(C)C)cc1c32]

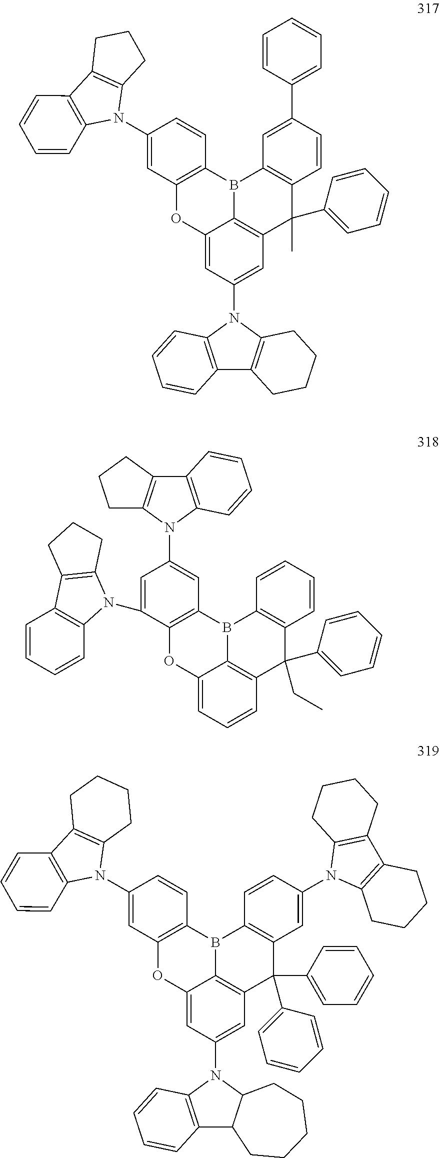 [SMILES: CC1(c2ccccc2)c2ccc(-c3ccccc3)cc2B2c3ccc(-n4c5c(c6ccccc64)CCC5)cc3Oc3cc(-n4c5c(c6ccccc64)CCCC5)cc1c32 ; CCC1(c2ccccc2)c2ccccc2B2c3cc(-n4c5c(c6ccccc64)CCC5)cc(-n4c5c(c6ccccc64)CCC5)c3Oc3cccc1c32 ; c1ccc(C2(c3ccccc3)c3cc(-n4c5c(c6c4CCCC6)CCCC5)ccc3B3c4ccc(-n5c6c(c7ccccc75)CCCC6)cc4Oc4cc(N5c6ccccc6C6CCCCCC65)cc2c43)cc1]

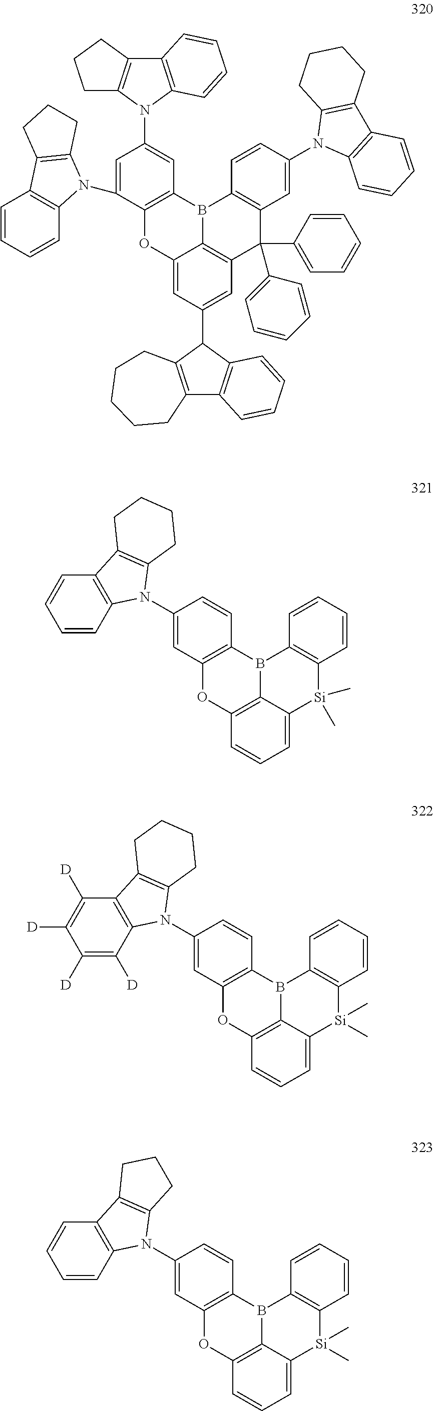 [SMILES: c1ccc(C2(c3ccccc3)c3cc(-n4c5c(c6ccccc64)CCCC5)ccc3B3c4cc(-n5c6c(c7ccccc75)CCC6)cc(-n5c6c(c7ccccc75)CCC6)c4Oc4cc(C5C6=C(CCCCC6)c6ccccc65)cc2c43)cc1 ; C[Si]1(C)c2ccccc2B2c3ccc(-n4c5c(c6ccccc64)CCCC5)cc3Oc3cccc1c32 ; [2H]c1c([2H])c([2H])c2c(c1[2H])c1c(n2-c2ccc3c(c2)Oc2cccc4c2B3c2ccccc2[Si]4(C)C)CCCC1 ; C[Si]1(C)c2ccccc2B2c3ccc(-n4c5c(c6ccccc64)CCC5)cc3Oc3cccc1c32]

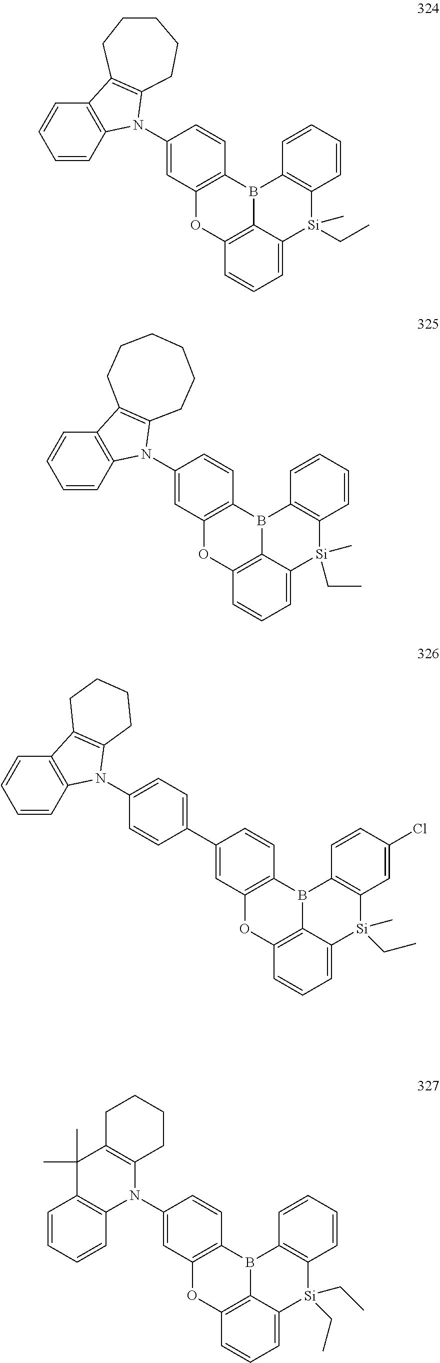

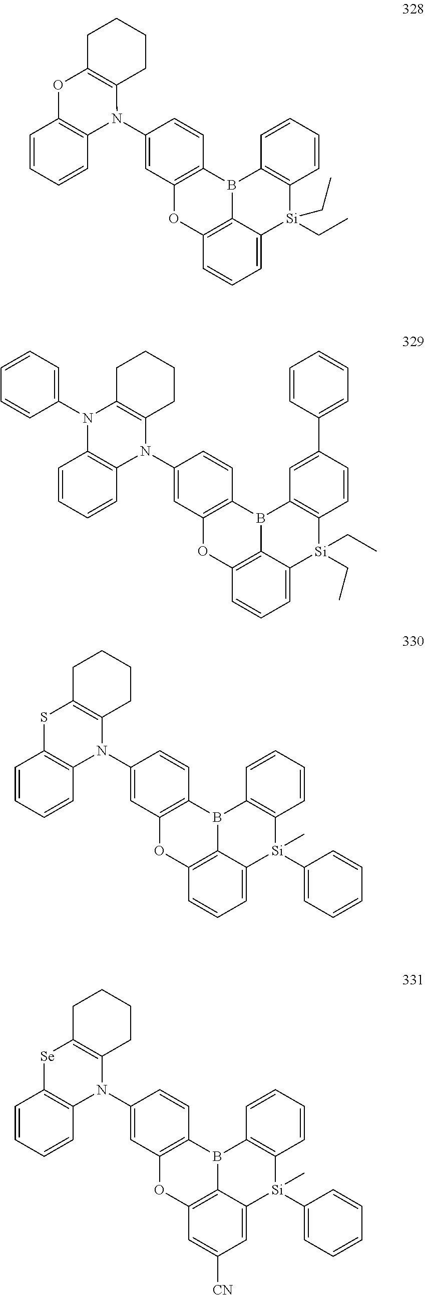 [SMILES: CC[Si]1(CC)c2ccccc2B2c3ccc(N4C5=C(CCCC5)Oc5ccccc54)cc3Oc3cccc1c32 ; CC[Si]1(CC)c2ccc(-c3ccccc3)cc2B2c3ccc(N4C5=C(CCCC5)N(c5ccccc5)c5ccccc54)cc3Oc3cccc1c32 ; C[Si]1(c2ccccc2)c2ccccc2B2c3ccc(N4C5=C(CCCC5)Sc5ccccc54)cc3Oc3cccc1c32 ; C[Si]1(c2ccccc2)c2ccccc2B2c3ccc(N4C5=C(CCCC5)[Se]c5ccccc54)cc3Oc3cc(C#N)cc1c32]

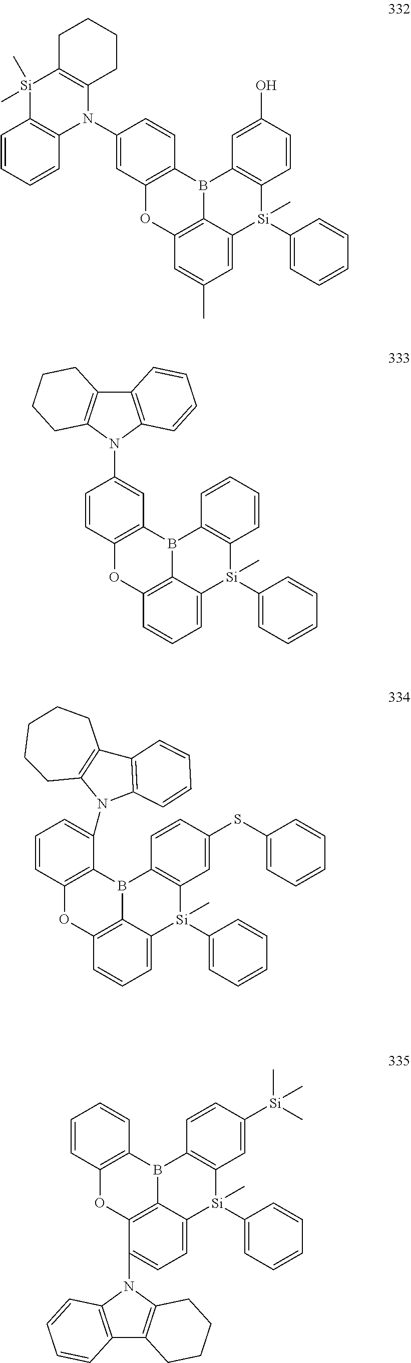 [SMILES: Cc1cc2c3c(c1)[Si](C)(c1ccccc1)c1ccc(O)cc1B3c1ccc(N3C4=C(CCCC4)[Si](C)(C)c4ccccc43)cc1O2 ; C[Si]1(c2ccccc2)c2ccccc2B2c3cc(-n4c5c(c6ccccc64)CCCC5)ccc3Oc3cccc1c32 ; C[Si]1(c2ccccc2)c2cc(Sc3ccccc3)ccc2B2c3c(cccc3-n3c4c(c5ccccc53)CCCCC4)Oc3cccc1c32 ; C[Si](C)(C)c1ccc2c(c1)[Si](C)(c1ccccc1)c1ccc(-n3c4c(c5ccccc53)CCCC4)c3c1B2c1ccccc1O3]

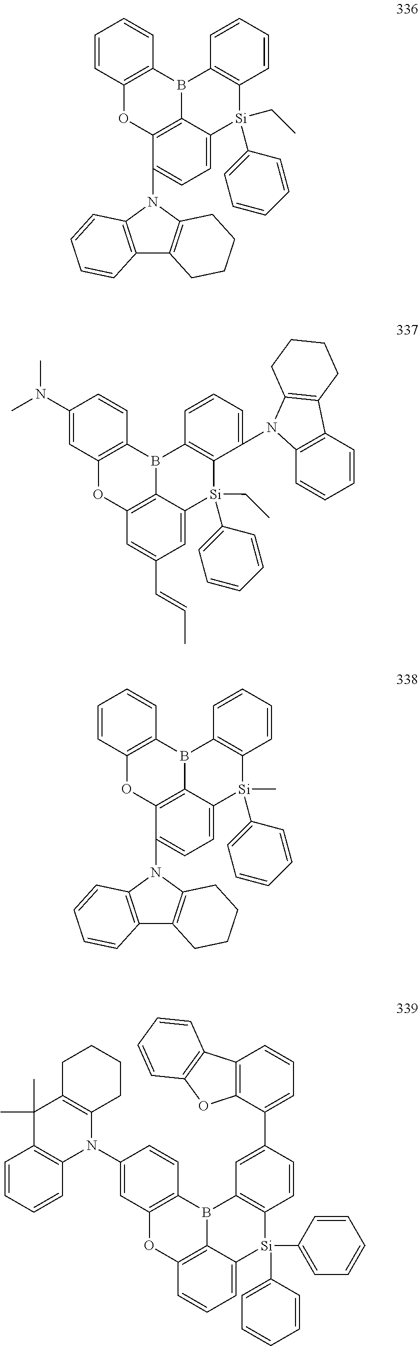

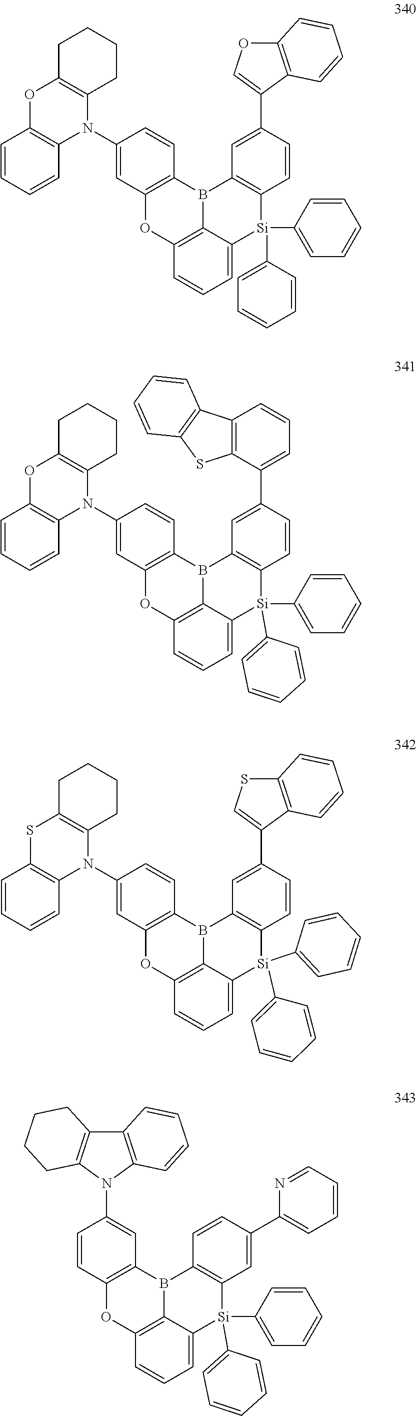 [SMILES: c1ccc([Si]2(c3ccccc3)c3ccc(-c4coc5ccccc45)cc3B3c4ccc(N5C6=C(CCCC6)Oc6ccccc65)cc4Oc4cccc2c43)cc1 ; c1ccc([Si]2(c3ccccc3)c3ccc(-c4cccc5c4sc4ccccc45)cc3B3c4ccc(N5C6=C(CCCC6)Oc6ccccc65)cc4Oc4cccc2c43)cc1 ; c1ccc([Si]2(c3ccccc3)c3ccc(-c4csc5ccccc45)cc3B3c4ccc(N5C6=C(CCCC6)Sc6ccccc65)cc4Oc4cccc2c43)cc1 ; c1ccc([Si]2(c3ccccc3)c3cc(-c4ccccn4)ccc3B3c4cc(-n5c6c(c7ccccc75)CCCC6)ccc4Oc4cccc2c43)cc1]

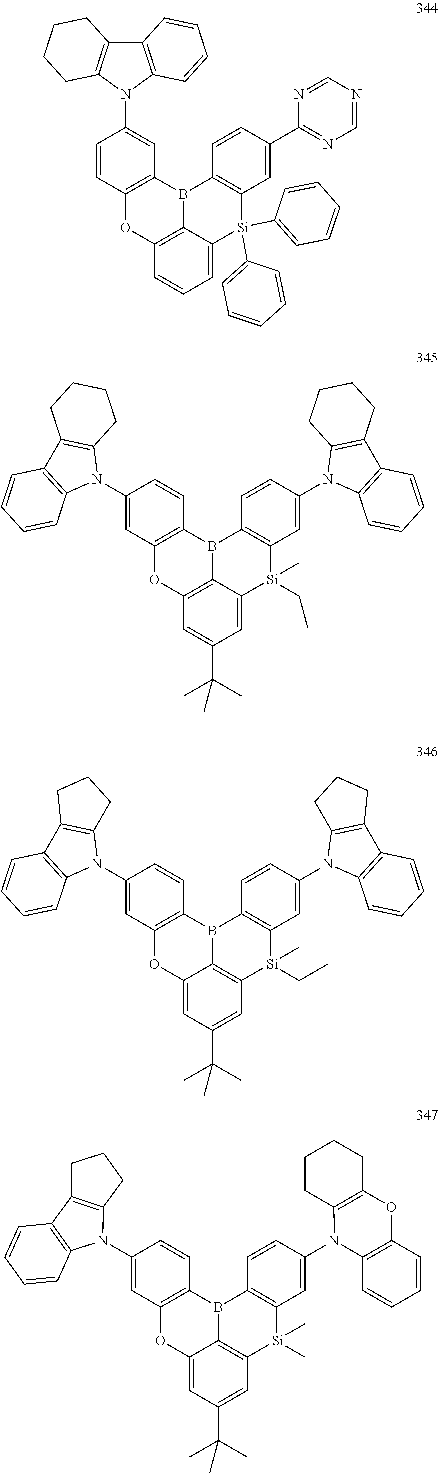 [SMILES: c1ccc([Si]2(c3ccccc3)c3cc(-c4ncncn4)ccc3B3c4cc(-n5c6c(c7ccccc75)CCCC6)ccc4Oc4cccc2c43)cc1 ; CC[Si]1(C)c2cc(-n3c4c(c5ccccc53)CCCC4)ccc2B2c3ccc(-n4c5c(c6ccccc64)CCCC5)cc3Oc3cc(C(C)(C)C)cc1c32 ; CC[Si]1(C)c2cc(-n3c4c(c5ccccc53)CCC4)ccc2B2c3ccc(-n4c5c(c6ccccc64)CCC5)cc3Oc3cc(C(C)(C)C)cc1c32 ; CC(C)(C)c1cc2c3c(c1)[Si](C)(C)c1cc(N4C5=C(CCCC5)Oc5ccccc54)ccc1B3c1ccc(-n3c4c(c5ccccc53)CCC4)cc1O2]

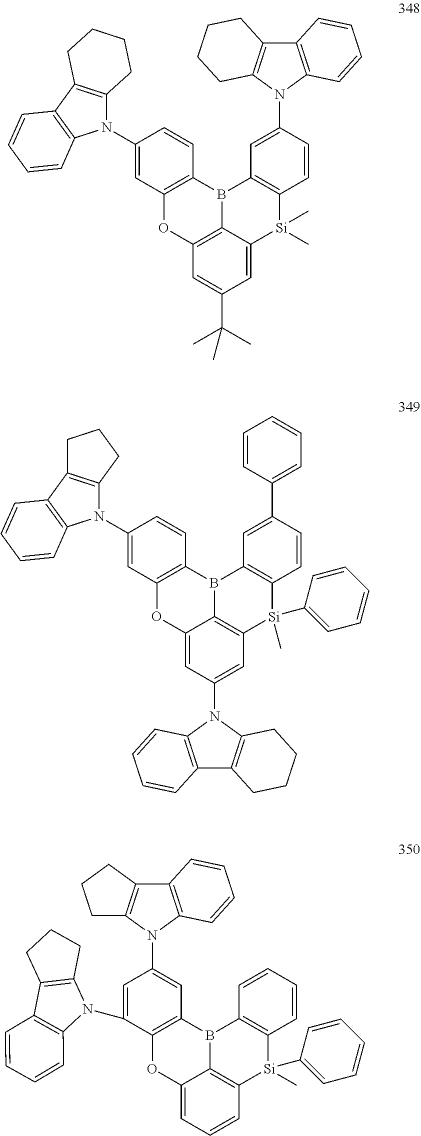 [SMILES: CC(C)(C)c1cc2c3c(c1)[Si](C)(C)c1ccc(-n4c5c(c6ccccc64)CCCC5)cc1B3c1ccc(-n3c4c(c5ccccc53)CCCC4)cc1O2 ; C[Si]1(c2ccccc2)c2ccc(-c3ccccc3)cc2B2c3ccc(-n4c5c(c6ccccc64)CCC5)cc3Oc3cc(-n4c5c(c6ccccc64)CCCC5)cc1c32 ; C[Si]1(c2ccccc2)c2ccccc2B2c3cc(-n4c5c(c6ccccc64)CCC5)cc(-n4c5c(c6ccccc64)CCC5)c3Oc3cccc1c32]

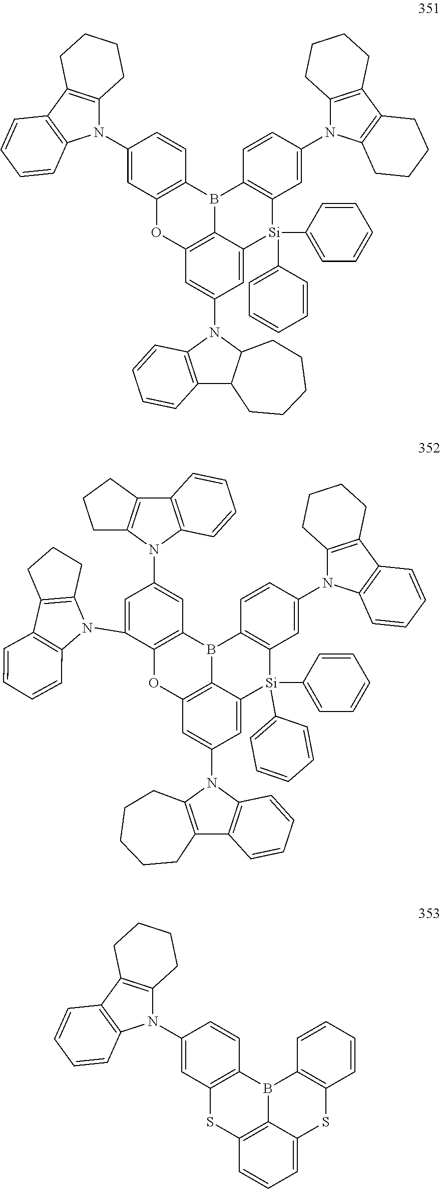 [SMILES: c1ccc([Si]2(c3ccccc3)c3cc(-n4c5c(c6c4CCCC6)CCCC5)ccc3B3c4ccc(-n5c6c(c7ccccc75)CCCC6)cc4Oc4cc(N5c6ccccc6C6CCCCCC65)cc2c43)cc1 ; c1ccc([Si]2(c3ccccc3)c3cc(-n4c5c(c6ccccc64)CCCC5)ccc3B3c4cc(-n5c6c(c7ccccc75)CCC6)cc(-n5c6c(c7ccccc75)CCC6)c4Oc4cc(-n5c6c(c7ccccc75)CCCCC6)cc2c43)cc1 ; c1ccc2c(c1)Sc1cccc3c1B2c1ccc(-n2c4c(c5ccccc52)CCCC4)cc1S3]

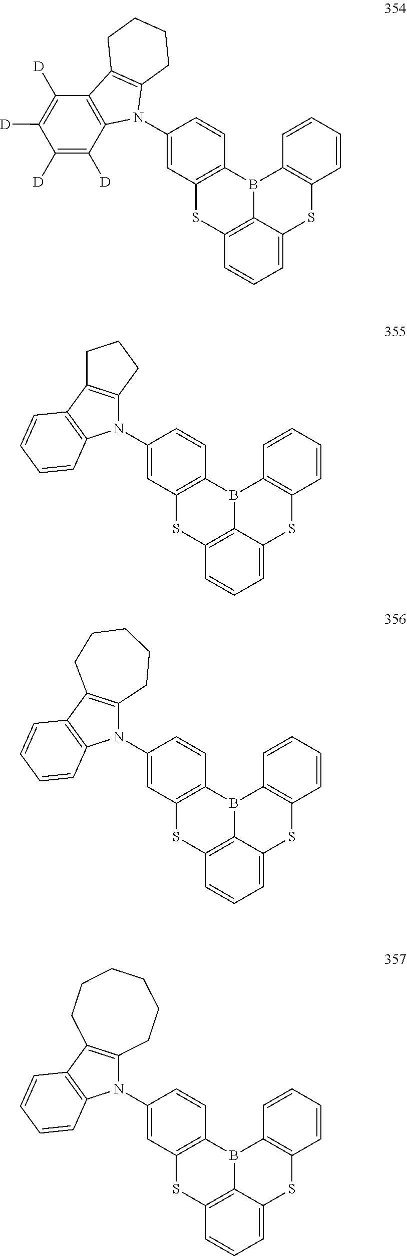 [SMILES: [2H]c1c([2H])c([2H])c2c(c1[2H])c1c(n2-c2ccc3c(c2)Sc2cccc4c2B3c2ccccc2S4)CCCC1 ; c1ccc2c(c1)Sc1cccc3c1B2c1ccc(-n2c4c(c5ccccc52)CCC4)cc1S3 ; c1ccc2c(c1)Sc1cccc3c1B2c1ccc(-n2c4c(c5ccccc52)CCCCC4)cc1S3 ; c1ccc2c(c1)Sc1cccc3c1B2c1ccc(-n2c4c(c5ccccc52)CCCCCC4)cc1S3]

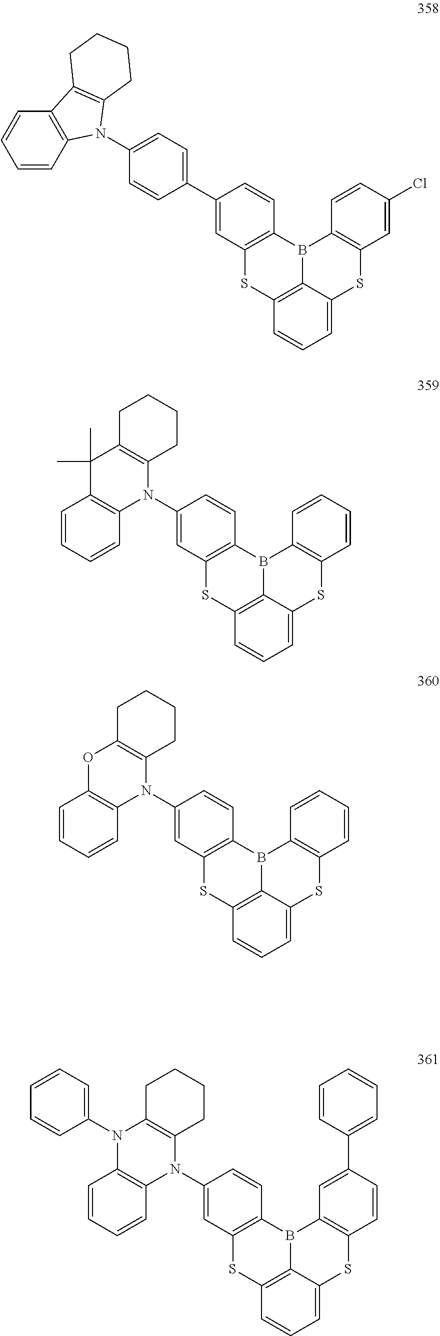 [SMILES: Clc1ccc2c(c1)Sc1cccc3c1B2c1ccc(-c2ccc(-n4c5c(c6ccccc64)CCCC5)cc2)cc1S3 ; CC1(C)C2=C(CCCC2)N(c2ccc3c(c2)Sc2cccc4c2B3c2ccccc2S4)c2ccccc21 ; c1ccc2c(c1)OC1=C(CCCC1)N2c1ccc2c(c1)Sc1cccc3c1B2c1ccccc1S3 ; c1ccc(-c2ccc3c(c2)B2c4ccc(N5C6=C(CCCC6)N(c6ccccc6)c6ccccc65)cc4Sc4cccc(c42)S3)cc1]

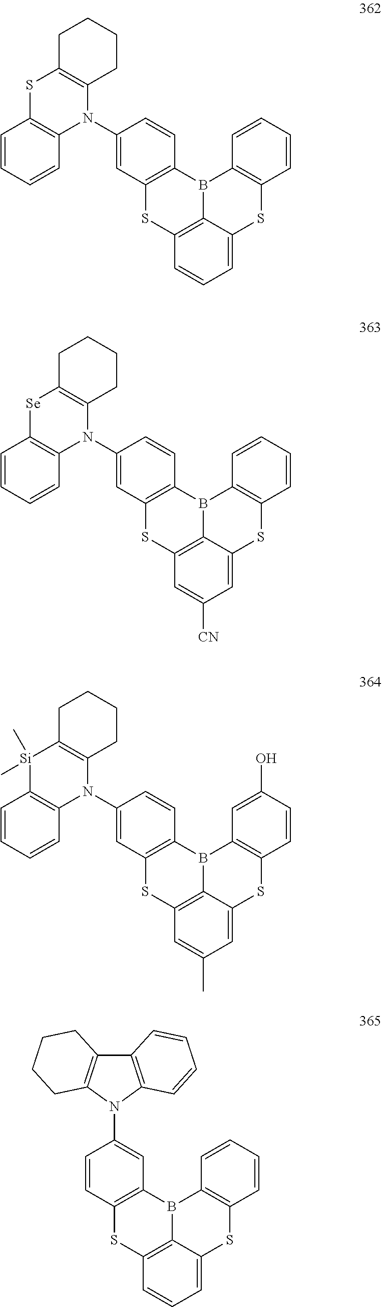 [SMILES: c1ccc2c(c1)Sc1cccc3c1B2c1ccc(N2C4=C(CCCC4)Sc4ccccc42)cc1S3 ; N#Cc1cc2c3c(c1)Sc1cc(N4C5=C(CCCC5)[Se]c5ccccc54)ccc1B3c1ccccc1S2 ; Cc1cc2c3c(c1)Sc1ccc(O)cc1B3c1ccc(N3C4=C(CCCC4)[Si](C)(C)c4ccccc43)cc1S2 ; c1ccc2c(c1)Sc1cccc3c1B2c1cc(-n2c4c(c5ccccc52)CCCC4)ccc1S3]

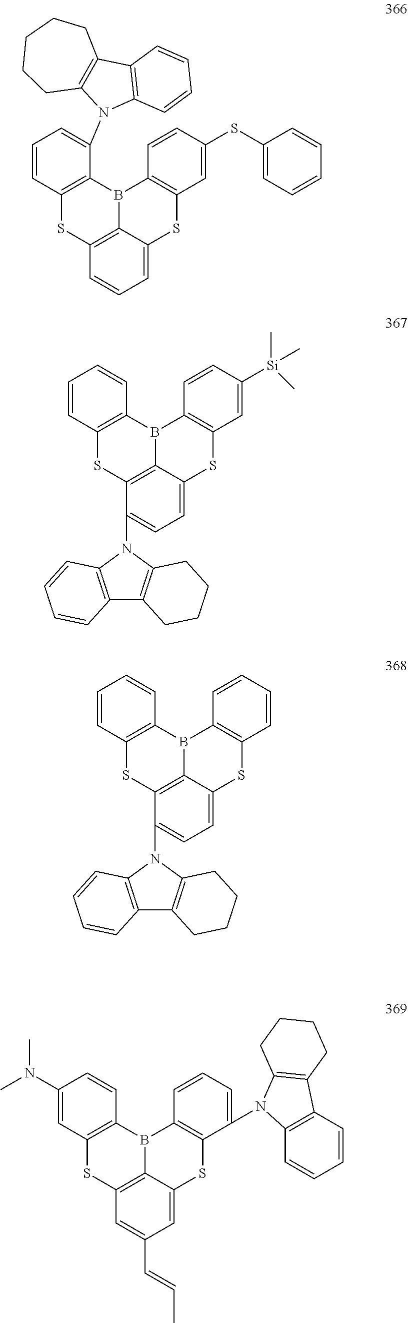

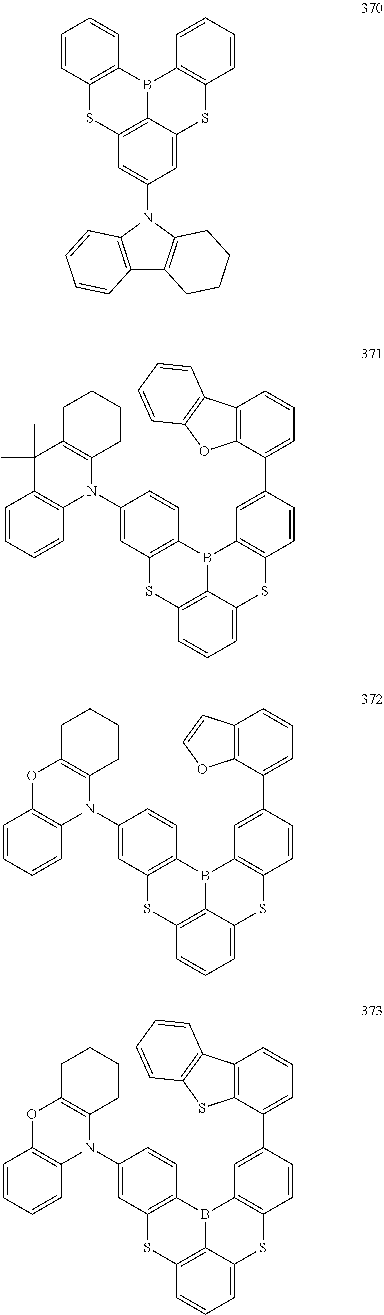 [SMILES: c1ccc2c(c1)Sc1cc(-n3c4c(c5ccccc53)CCCC4)cc3c1B2c1ccccc1S3 ; CC1(C)C2=C(CCCC2)N(c2ccc3c(c2)Sc2cccc4c2B3c2cc(-c3cccc5c3oc3ccccc35)ccc2S4)c2ccccc21 ; c1ccc2c(c1)OC1=C(CCCC1)N2c1ccc2c(c1)Sc1cccc3c1B2c1cc(-c2cccc4ccoc24)ccc1S3 ; c1ccc2c(c1)OC1=C(CCCC1)N2c1ccc2c(c1)Sc1cccc3c1B2c1cc(-c2cccc4c2sc2ccccc24)ccc1S3]

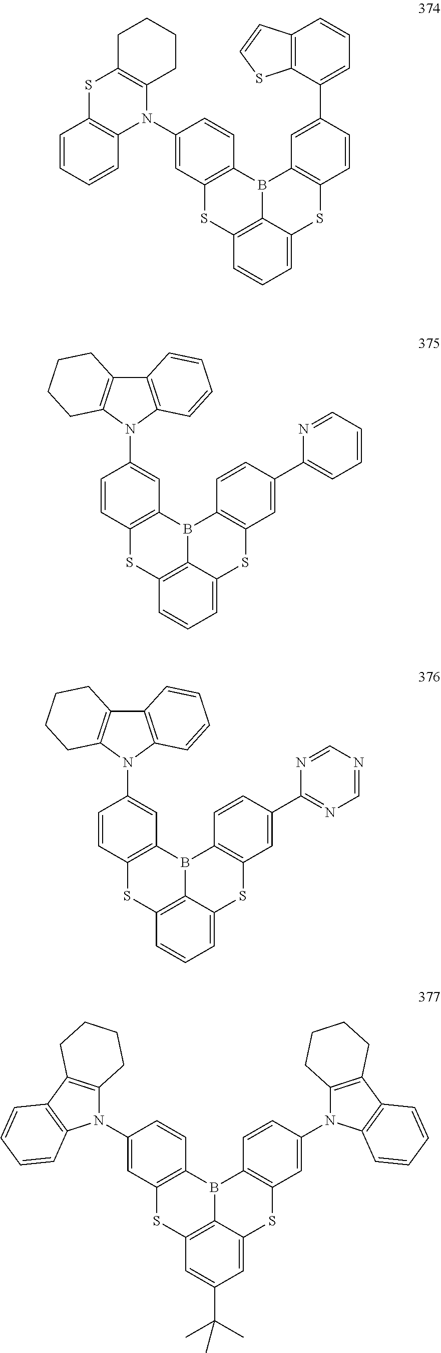 [SMILES: c1ccc2c(c1)SC1=C(CCCC1)N2c1ccc2c(c1)Sc1cccc3c1B2c1cc(-c2cccc4ccsc24)ccc1S3 ; c1ccc(-c2ccc3c(c2)Sc2cccc4c2B3c2cc(-n3c5c(c6ccccc63)CCCC5)ccc2S4)nc1 ; c1cc2c3c(c1)Sc1ccc(-n4c5c(c6ccccc64)CCCC5)cc1B3c1ccc(-c3ncncn3)cc1S2 ; CC(C)(C)c1cc2c3c(c1)Sc1cc(-n4c5c(c6ccccc64)CCCC5)ccc1B3c1ccc(-n3c4c(c5ccccc53)CCCC4)cc1S2]

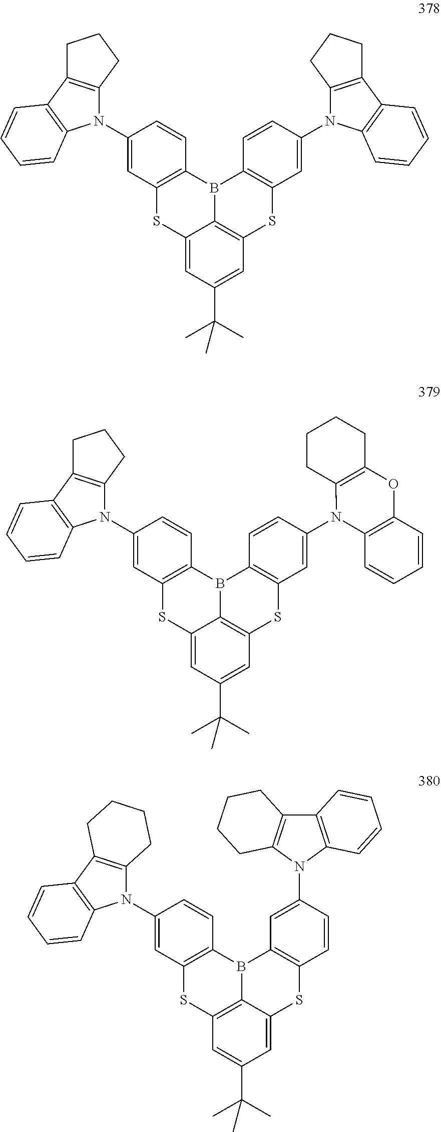 [SMILES: CC(C)(C)c1cc2c3c(c1)Sc1cc(-n4c5c(c6ccccc64)CCC5)ccc1B3c1ccc(-n3c4c(c5ccccc53)CCC4)cc1S2 ; CC(C)(C)c1cc2c3c(c1)Sc1cc(-n4c5c(c6ccccc64)CCC5)ccc1B3c1ccc(N3C4=C(CCCC4)Oc4ccccc43)cc1S2 ; CC(C)(C)c1cc2c3c(c1)Sc1ccc(-n4c5c(c6ccccc64)CCCC5)cc1B3c1ccc(-n3c4c(c5ccccc53)CCCC4)cc1S2]

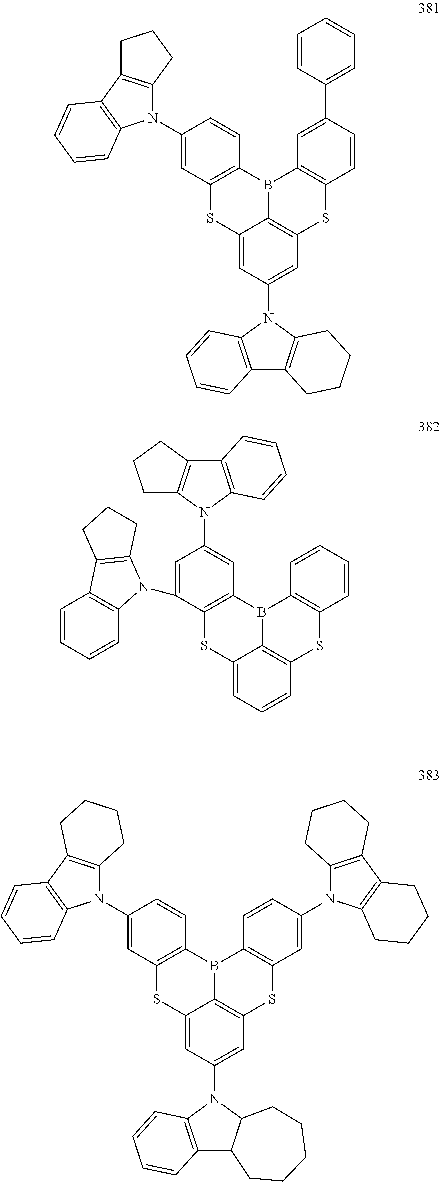

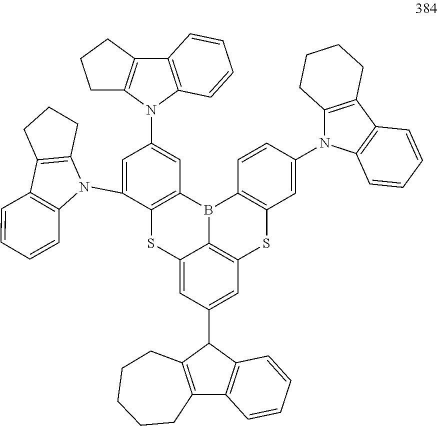 [SMILES: c1ccc2c(c1)C1=C(CCCCC1)C2c1cc2c3c(c1)Sc1c(cc(-n4c5c(c6ccccc64)CCC5)cc1-n1c4c(c5ccccc51)CCC4)B3c1ccc(-n3c4c(c5ccccc53)CCCC4)cc1S2]

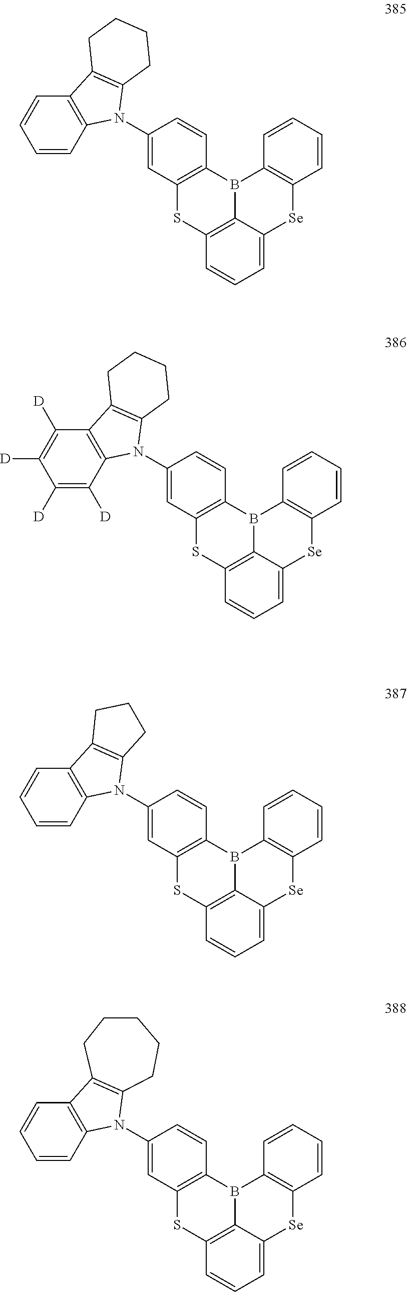 [SMILES: c1ccc2c(c1)[Se]c1cccc3c1B2c1ccc(-n2c4c(c5ccccc52)CCCC4)cc1S3 ; [2H]c1c([2H])c([2H])c2c(c1[2H])c1c(n2-c2ccc3c(c2)Sc2cccc4c2B3c2ccccc2[Se]4)CCCC1 ; c1ccc2c(c1)[Se]c1cccc3c1B2c1ccc(-n2c4c(c5ccccc52)CCC4)cc1S3 ; c1ccc2c(c1)[Se]c1cccc3c1B2c1ccc(-n2c4c(c5ccccc52)CCCCC4)cc1S3]

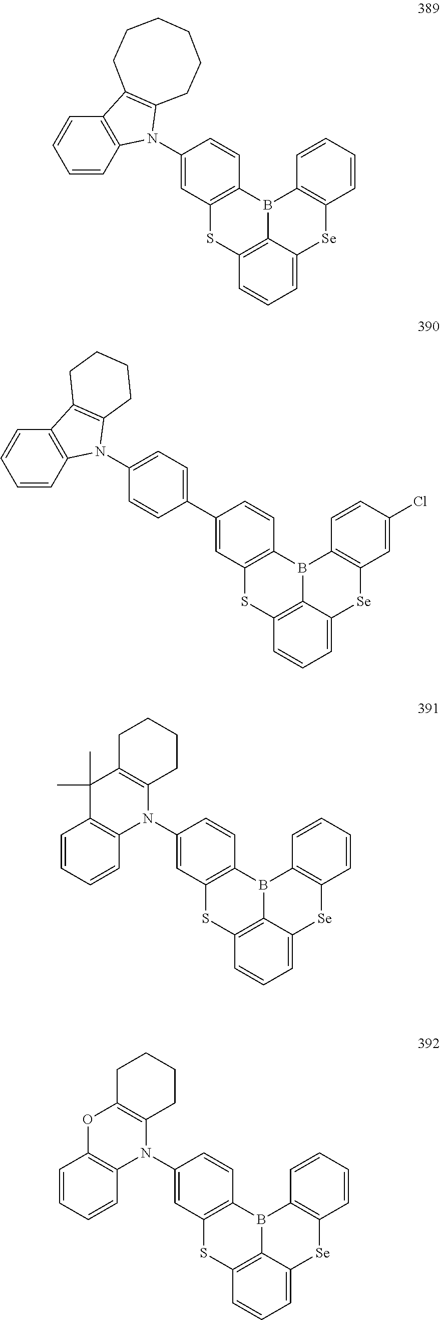 [SMILES: c1ccc2c(c1)[Se]c1cccc3c1B2c1ccc(-n2c4c(c5ccccc52)CCCCCC4)cc1S3 ; Clc1ccc2c(c1)[Se]c1cccc3c1B2c1ccc(-c2ccc(-n4c5c(c6ccccc64)CCCC5)cc2)cc1S3 ; CC1(C)C2=C(CCCC2)N(c2ccc3c(c2)Sc2cccc4c2B3c2ccccc2[Se]4)c2ccccc21 ; c1ccc2c(c1)OC1=C(CCCC1)N2c1ccc2c(c1)Sc1cccc3c1B2c1ccccc1[Se]3]

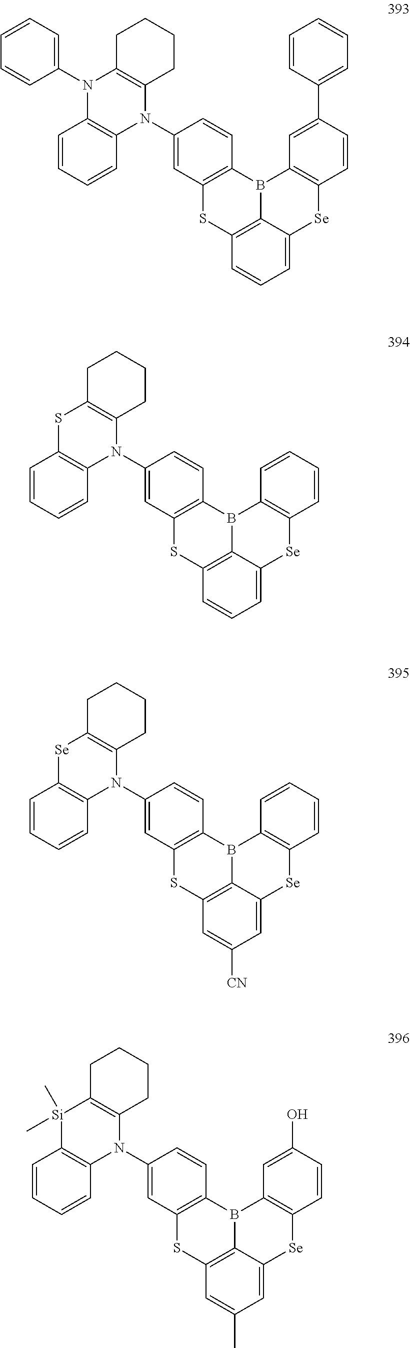 [SMILES: c1ccc(-c2ccc3c(c2)B2c4ccc(N5C6=C(CCCC6)N(c6ccccc6)c6ccccc65)cc4Sc4cccc(c42)[Se]3)cc1 ; c1ccc2c(c1)SC1=C(CCCC1)N2c1ccc2c(c1)Sc1cccc3c1B2c1ccccc1[Se]3 ; N#Cc1cc2c3c(c1)[Se]c1ccccc1B3c1ccc(N3C4=C(CCCC4)[Se]c4ccccc43)cc1S2 ; Cc1cc2c3c(c1)[Se]c1ccc(O)cc1B3c1ccc(N3C4=C(CCCC4)[Si](C)(C)c4ccccc43)cc1S2]

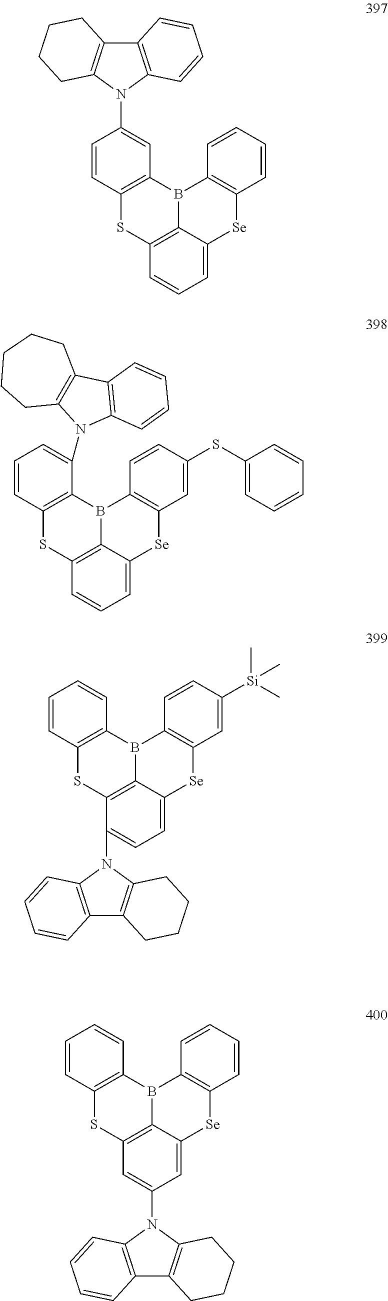 [SMILES: c1ccc2c(c1)[Se]c1cccc3c1B2c1cc(-n2c4c(c5ccccc52)CCCC4)ccc1S3 ; c1ccc(Sc2ccc3c(c2)[Se]c2cccc4c2B3c2c(cccc2-n2c3c(c5ccccc52)CCCCC3)S4)cc1 ; C[Si](C)(C)c1ccc2c(c1)[Se]c1ccc(-n3c4c(c5ccccc53)CCCC4)c3c1B2c1ccccc1S3 ; c1ccc2c(c1)Sc1cc(-n3c4c(c5ccccc53)CCCC4)cc3c1B2c1ccccc1[Se]3]

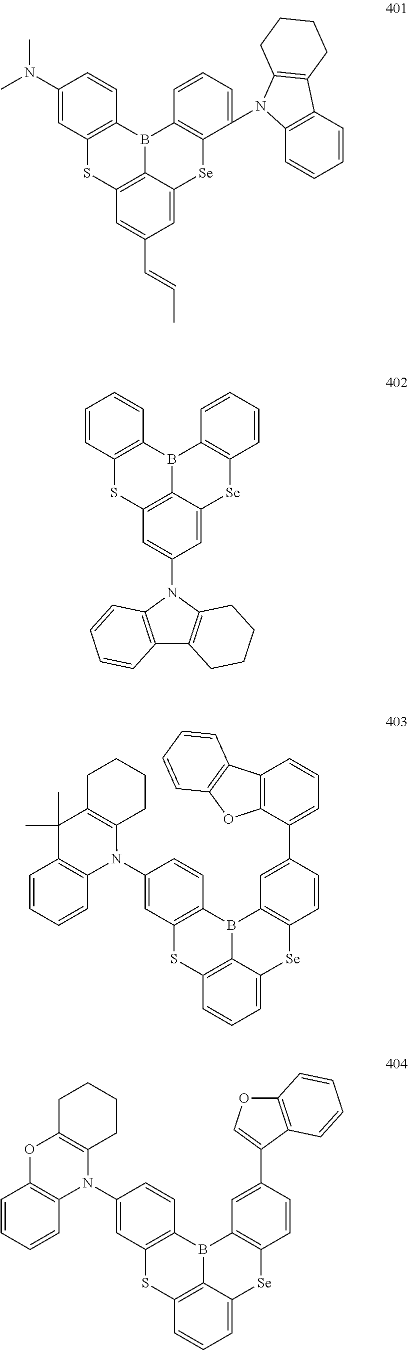 [SMILES: C/C=C/c1cc2c3c(c1)[Se]c1c(cccc1-n1c4c(c5ccccc51)CCCC4)B3c1ccc(N(C)C)cc1S2 ; c1ccc2c(c1)Sc1cc(-n3c4c(c5ccccc53)CCCC4)cc3c1B2c1ccccc1[Se]3 ; CC1(C)C2=C(CCCC2)N(c2ccc3c(c2)Sc2cccc4c2B3c2cc(-c3cccc5c3oc3ccccc35)ccc2[Se]4)c2ccccc21 ; c1ccc2c(c1)OC1=C(CCCC1)N2c1ccc2c(c1)Sc1cccc3c1B2c1cc(-c2coc4ccccc24)ccc1[Se]3]

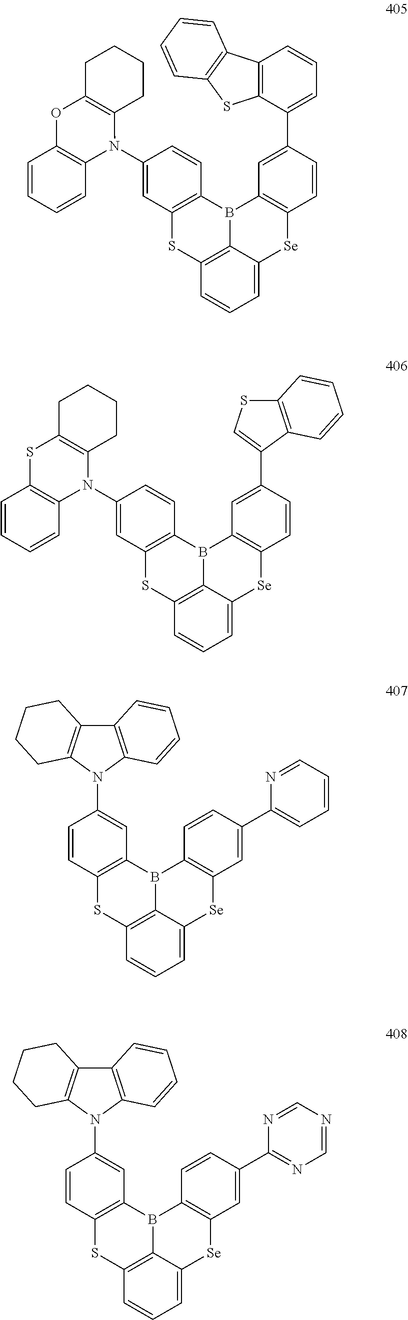 [SMILES: c1ccc2c(c1)OC1=C(CCCC1)N2c1ccc2c(c1)Sc1cccc3c1B2c1cc(-c2cccc4c2sc2ccccc24)ccc1[Se]3 ; c1ccc2c(c1)SC1=C(CCCC1)N2c1ccc2c(c1)Sc1cccc3c1B2c1cc(-c2csc4ccccc24)ccc1[Se]3 ; c1ccc(-c2ccc3c(c2)[Se]c2cccc4c2B3c2cc(-n3c5c(c6ccccc63)CCCC5)ccc2S4)nc1 ; c1cc2c3c(c1)[Se]c1cc(-c4ncncn4)ccc1B3c1cc(-n3c4c(c5ccccc53)CCCC4)ccc1S2]

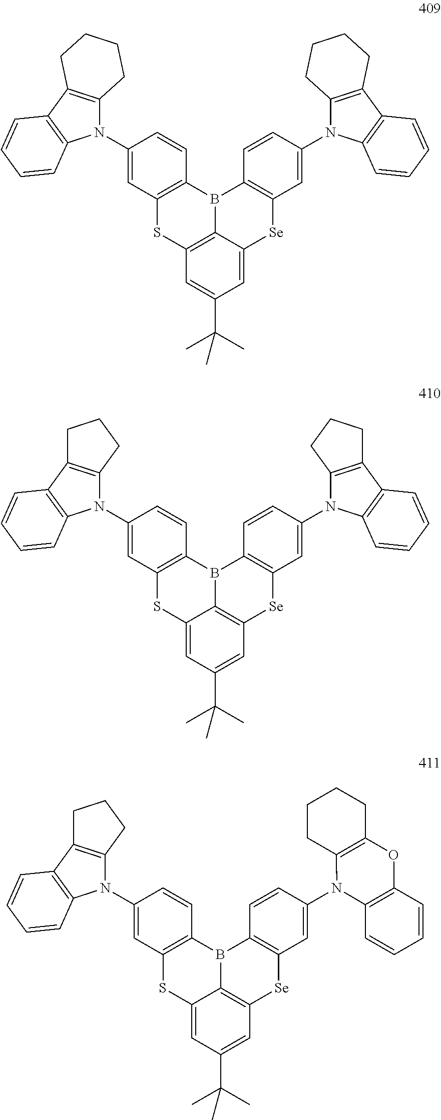 [SMILES: CC(C)(C)c1cc2c3c(c1)[Se]c1cc(-n4c5c(c6ccccc64)CCCC5)ccc1B3c1ccc(-n3c4c(c5ccccc53)CCCC4)cc1S2 ; CC(C)(C)c1cc2c3c(c1)[Se]c1cc(-n4c5c(c6ccccc64)CCC5)ccc1B3c1ccc(-n3c4c(c5ccccc53)CCC4)cc1S2 ; CC(C)(C)c1cc2c3c(c1)[Se]c1cc(N4C5=C(CCCC5)Oc5ccccc54)ccc1B3c1ccc(-n3c4c(c5ccccc53)CCC4)cc1S2]

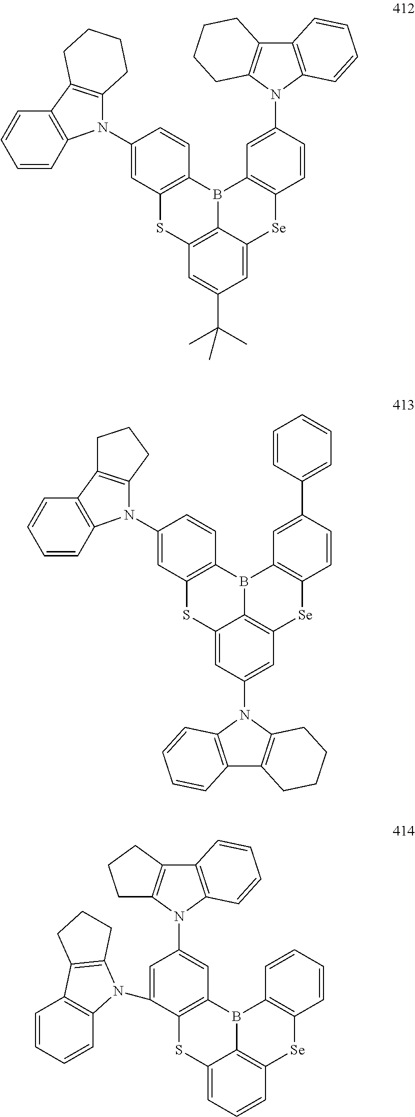 [SMILES: CC(C)(C)c1cc2c3c(c1)[Se]c1ccc(-n4c5c(c6ccccc64)CCCC5)cc1B3c1ccc(-n3c4c(c5ccccc53)CCCC4)cc1S2 ; c1ccc(-c2ccc3c(c2)B2c4ccc(-n5c6c(c7ccccc75)CCC6)cc4Sc4cc(-n5c6c(c7ccccc75)CCCC6)cc(c42)[Se]3)cc1 ; c1ccc2c(c1)[Se]c1cccc3c1B2c1cc(-n2c4c(c5ccccc52)CCC4)cc(-n2c4c(c5ccccc52)CCC4)c1S3]

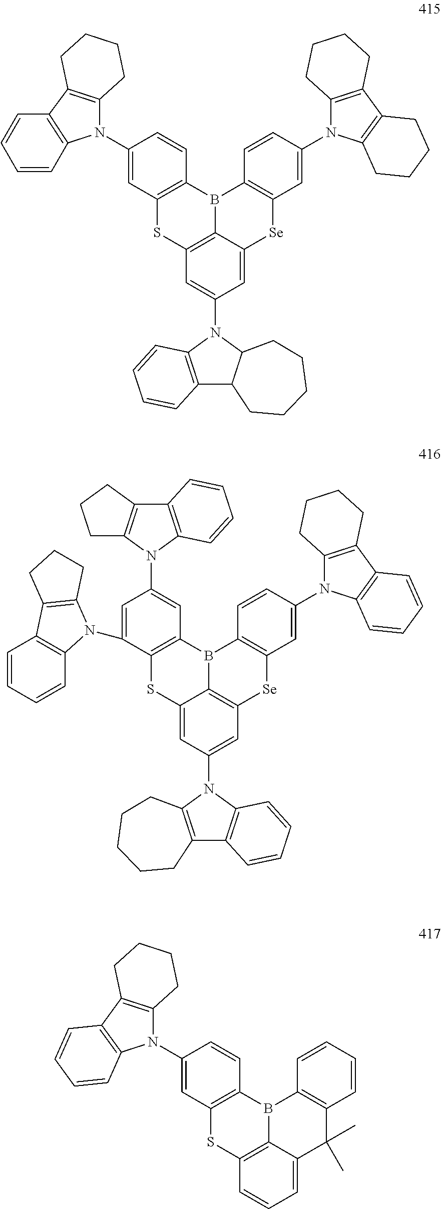 [SMILES: c1ccc2c(c1)C1CCCCCC1N2c1cc2c3c(c1)[Se]c1cc(-n4c5c(c6c4CCCC6)CCCC5)ccc1B3c1ccc(-n3c4c(c5ccccc53)CCCC4)cc1S2 ; c1ccc2c(c1)c1c(n2-c2cc3c4c(c2)[Se]c2cc(-n5c6c(c7ccccc75)CCCC6)ccc2B4c2cc(-n4c5c(c6ccccc64)CCC5)cc(-n4c5c(c6ccccc64)CCC5)c2S3)CCCCC1 ; CC1(C)c2ccccc2B2c3ccc(-n4c5c(c6ccccc64)CCCC5)cc3Sc3cccc1c32]

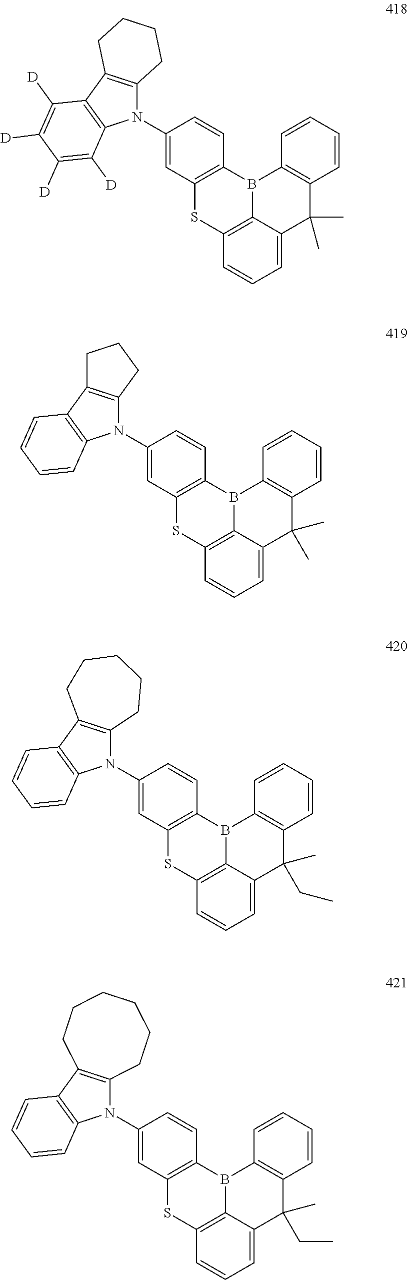 [SMILES: [2H]c1c([2H])c([2H])c2c(c1[2H])c1c(n2-c2ccc3c(c2)Sc2cccc4c2B3c2ccccc2C4(C)C)CCCC1 ; CC1(C)c2ccccc2B2c3ccc(-n4c5c(c6ccccc64)CCC5)cc3Sc3cccc1c32 ; CCC1(C)c2ccccc2B2c3ccc(-n4c5c(c6ccccc64)CCCCC5)cc3Sc3cccc1c32 ; CCC1(C)c2ccccc2B2c3ccc(-n4c5c(c6ccccc64)CCCCCC5)cc3Sc3cccc1c32]

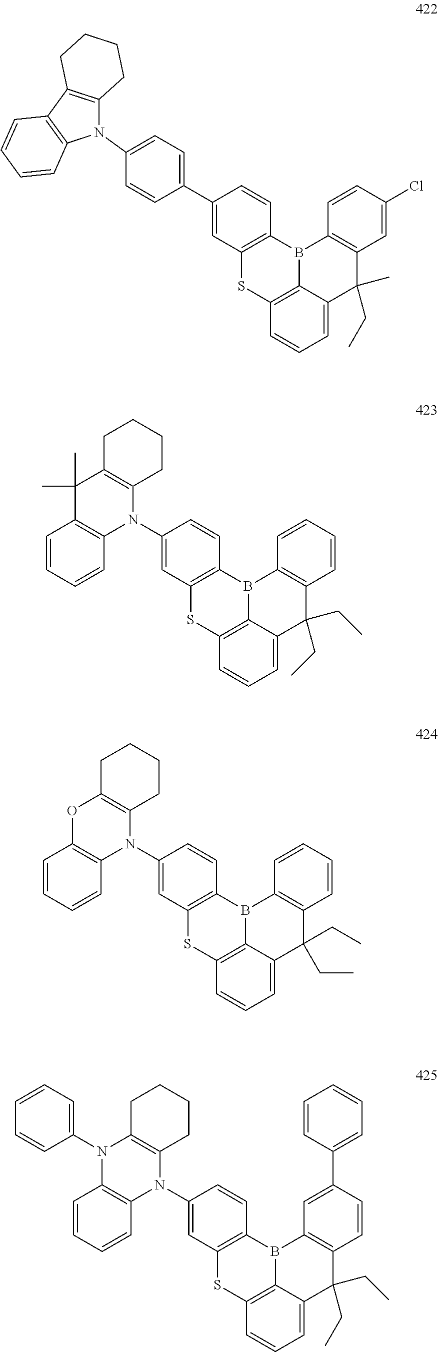 [SMILES: CCC1(C)c2cc(Cl)ccc2B2c3ccc(-c4ccc(-n5c6c(c7ccccc75)CCCC6)cc4)cc3Sc3cccc1c32 ; CCC1(CC)c2ccccc2B2c3ccc(N4C5=C(CCCC5)C(C)(C)c5ccccc54)cc3Sc3cccc1c32 ; CCC1(CC)c2ccccc2B2c3ccc(N4C5=C(CCCC5)Oc5ccccc54)cc3Sc3cccc1c32 ; CCC1(CC)c2ccc(-c3ccccc3)cc2B2c3ccc(N4C5=C(CCCC5)N(c5ccccc5)c5ccccc54)cc3Sc3cccc1c32]

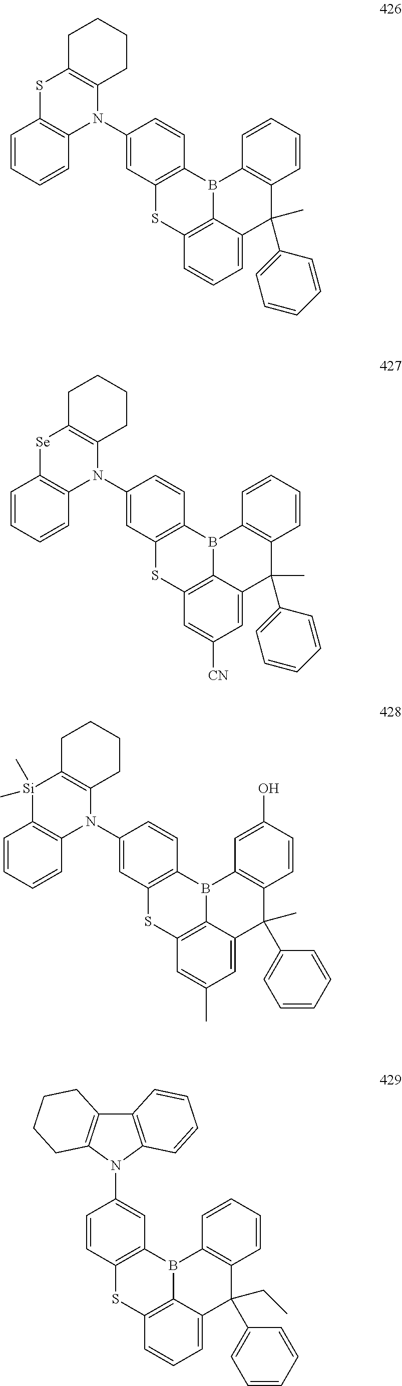 [SMILES: CC1(c2ccccc2)c2ccccc2B2c3ccc(N4C5=C(CCCC5)Sc5ccccc54)cc3Sc3cccc1c32 ; CC1(c2ccccc2)c2ccccc2B2c3ccc(N4C5=C(CCCC5)[Se]c5ccccc54)cc3Sc3cc(C#N)cc1c32 ; Cc1cc2c3c(c1)C(C)(c1ccccc1)c1ccc(O)cc1B3c1ccc(N3C4=C(CCCC4)[Si](C)(C)c4ccccc43)cc1S2 ; CCC1(c2ccccc2)c2ccccc2B2c3cc(-n4c5c(c6ccccc64)CCCC5)ccc3Sc3cccc1c32]

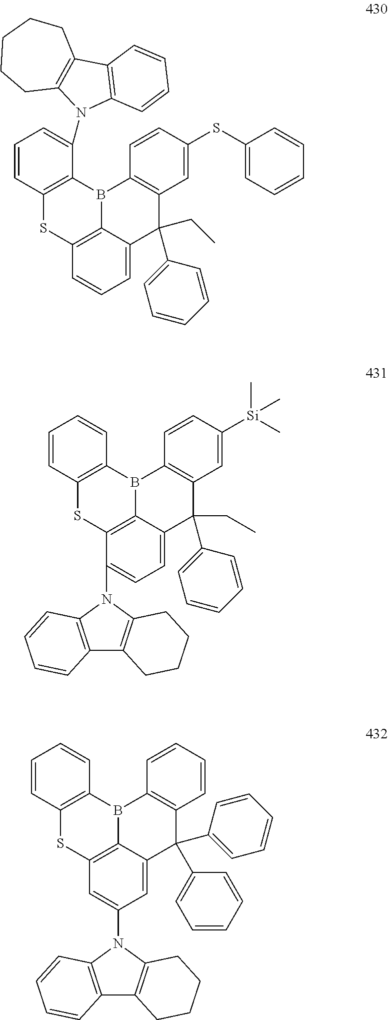 [SMILES: CCC1(c2ccccc2)c2cc(Sc3ccccc3)ccc2B2c3c(cccc3-n3c4c(c5ccccc53)CCCCC4)Sc3cccc1c32 ; CCC1(c2ccccc2)c2cc([Si](C)(C)C)ccc2B2c3ccccc3Sc3c(-n4c5c(c6ccccc64)CCCC5)ccc1c32 ; c1ccc(C2(c3ccccc3)c3ccccc3B3c4ccccc4Sc4cc(-n5c6c(c7ccccc75)CCCC6)cc2c43)cc1]

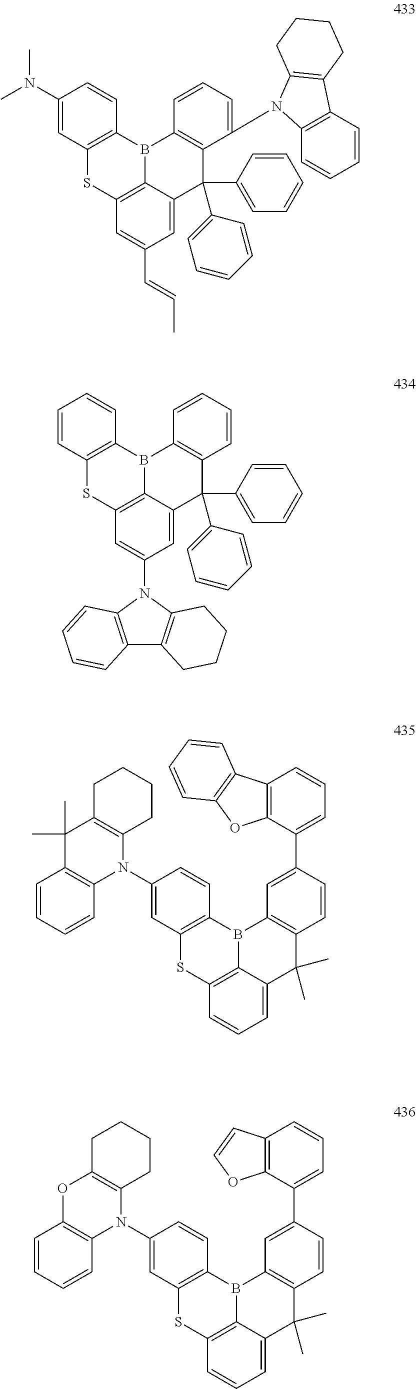

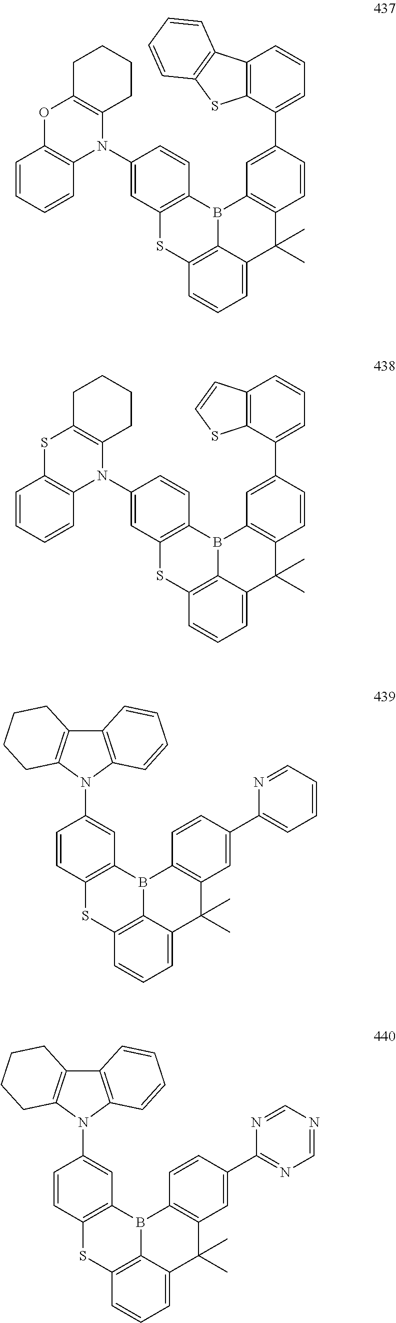 [SMILES: CC1(C)c2ccc(-c3cccc4c3sc3ccccc34)cc2B2c3ccc(N4C5=C(CCCC5)Oc5ccccc54)cc3Sc3cccc1c32 ; CC1(C)c2ccc(-c3cccc4ccsc34)cc2B2c3ccc(N4C5=C(CCCC5)Sc5ccccc54)cc3Sc3cccc1c32 ; CC1(C)c2cc(-c3ccccn3)ccc2B2c3cc(-n4c5c(c6ccccc64)CCCC5)ccc3Sc3cccc1c32 ; CC1(C)c2cc(-c3ncncn3)ccc2B2c3cc(-n4c5c(c6ccccc64)CCCC5)ccc3Sc3cccc1c32]

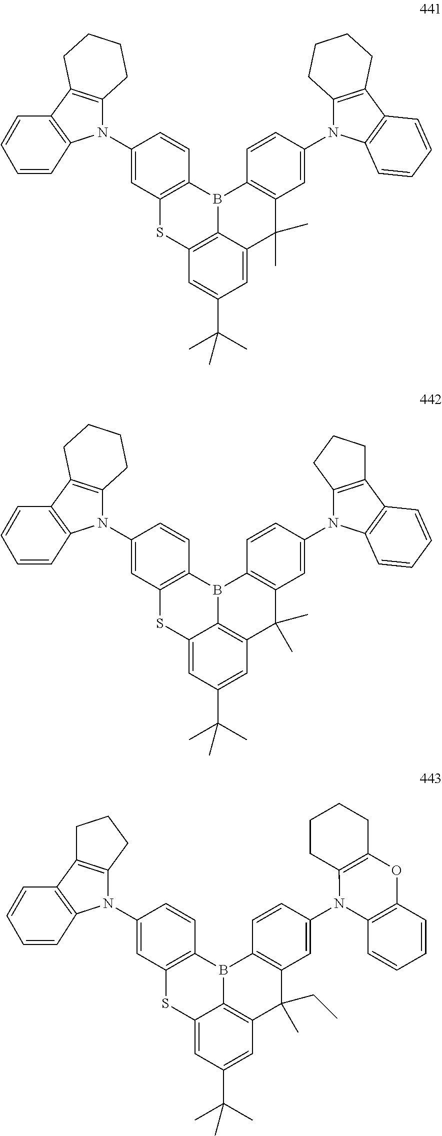 [SMILES: CC(C)(C)c1cc2c3c(c1)C(C)(C)c1cc(-n4c5c(c6ccccc64)CCCC5)ccc1B3c1ccc(-n3c4c(c5ccccc53)CCCC4)cc1S2 ; CC(C)(C)c1cc2c3c(c1)C(C)(C)c1cc(-n4c5c(c6ccccc64)CCC5)ccc1B3c1ccc(-n3c4c(c5ccccc53)CCCC4)cc1S2 ; CCC1(C)c2cc(N3C4=C(CCCC4)Oc4ccccc43)ccc2B2c3ccc(-n4c5c(c6ccccc64)CCC5)cc3Sc3cc(C(C)(C)C)cc1c32]

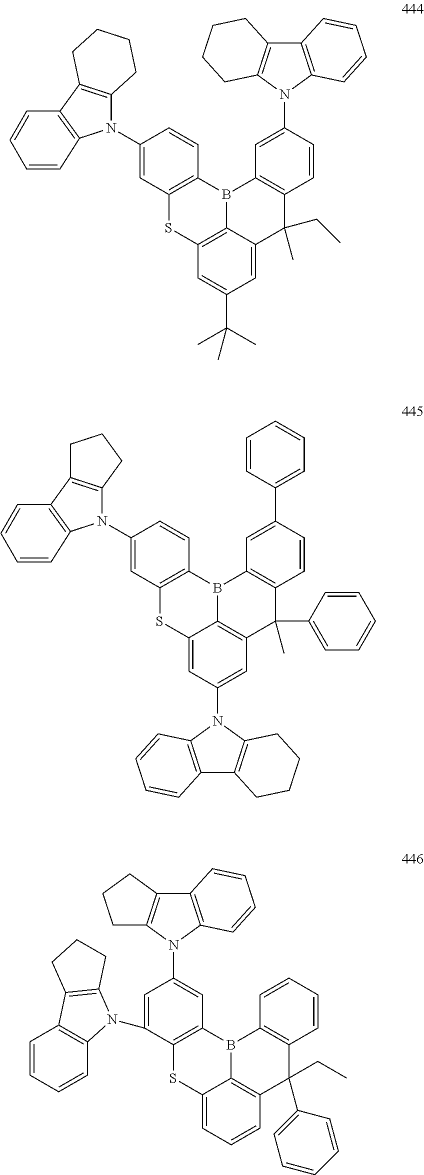 [SMILES: CCC1(C)c2ccc(-n3c4c(c5ccccc53)CCCC4)cc2B2c3ccc(-n4c5c(c6ccccc64)CCCC5)cc3Sc3cc(C(C)(C)C)cc1c32 ; CC1(c2ccccc2)c2ccc(-c3ccccc3)cc2B2c3ccc(-n4c5c(c6ccccc64)CCC5)cc3Sc3cc(-n4c5c(c6ccccc64)CCCC5)cc1c32 ; CCC1(c2ccccc2)c2ccccc2B2c3cc(-n4c5c(c6ccccc64)CCC5)cc(-n4c5c(c6ccccc64)CCC5)c3Sc3cccc1c32]

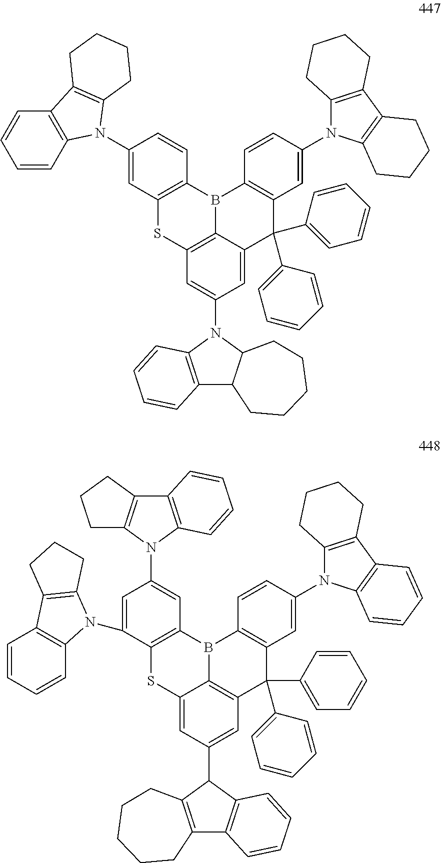 [SMILES: c1ccc(C2(c3ccccc3)c3cc(-n4c5c(c6c4CCCC6)CCCC5)ccc3B3c4ccc(-n5c6c(c7ccccc75)CCCC6)cc4Sc4cc(N5c6ccccc6C6CCCCCC65)cc2c43)cc1 ; c1ccc(C2(c3ccccc3)c3cc(-n4c5c(c6ccccc64)CCCC5)ccc3B3c4cc(-n5c6c(c7ccccc75)CCC6)cc(-n5c6c(c7ccccc75)CCC6)c4Sc4cc(C5C6=C(CCCCC6)c6ccccc65)cc2c43)cc1]

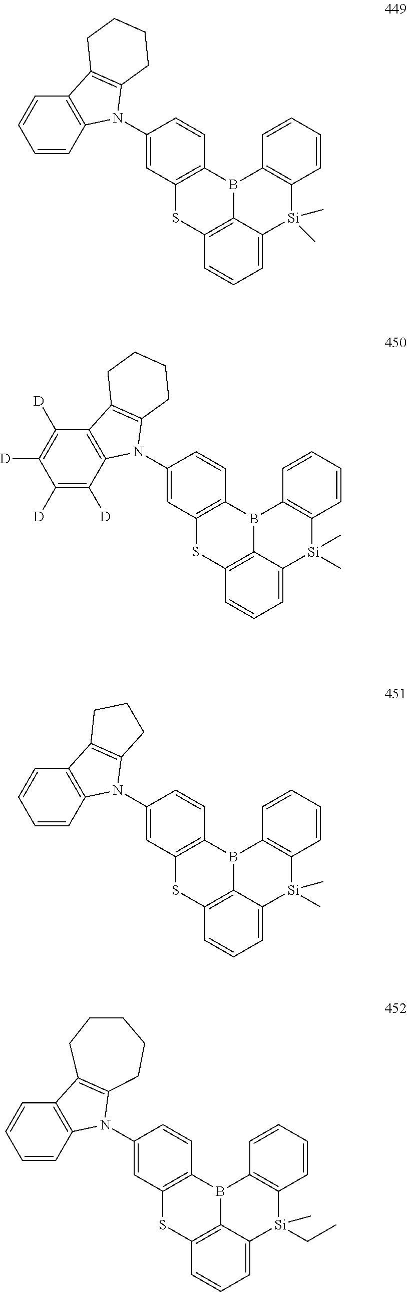 [SMILES: C[Si]1(C)c2ccccc2B2c3ccc(-n4c5c(c6ccccc64)CCCC5)cc3Sc3cccc1c32 ; [2H]c1c([2H])c([2H])c2c(c1[2H])c1c(n2-c2ccc3c(c2)Sc2cccc4c2B3c2ccccc2[Si]4(C)C)CCCC1 ; C[Si]1(C)c2ccccc2B2c3ccc(-n4c5c(c6ccccc64)CCC5)cc3Sc3cccc1c32 ; CC[Si]1(C)c2ccccc2B2c3ccc(-n4c5c(c6ccccc64)CCCCC5)cc3Sc3cccc1c32]

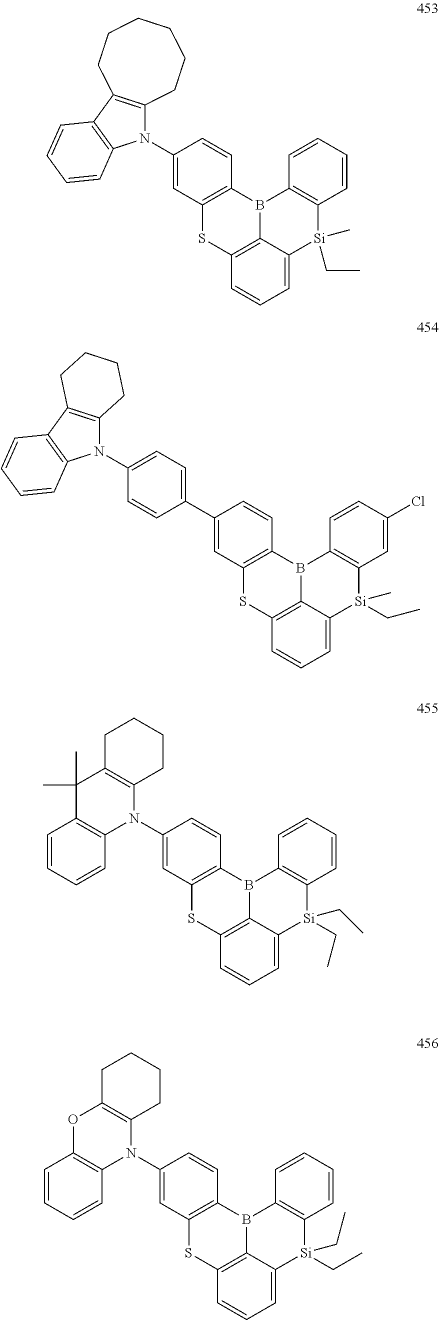

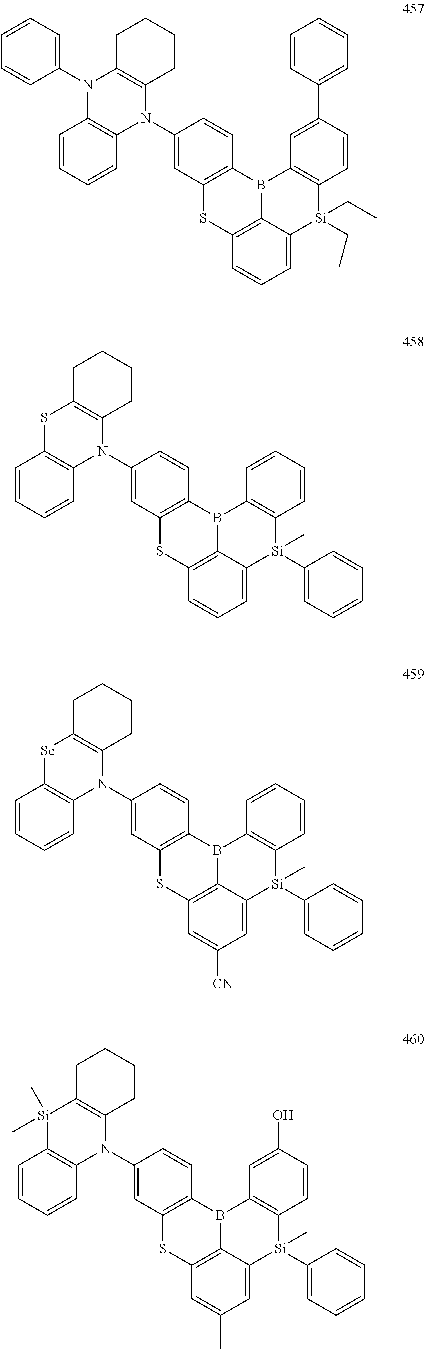

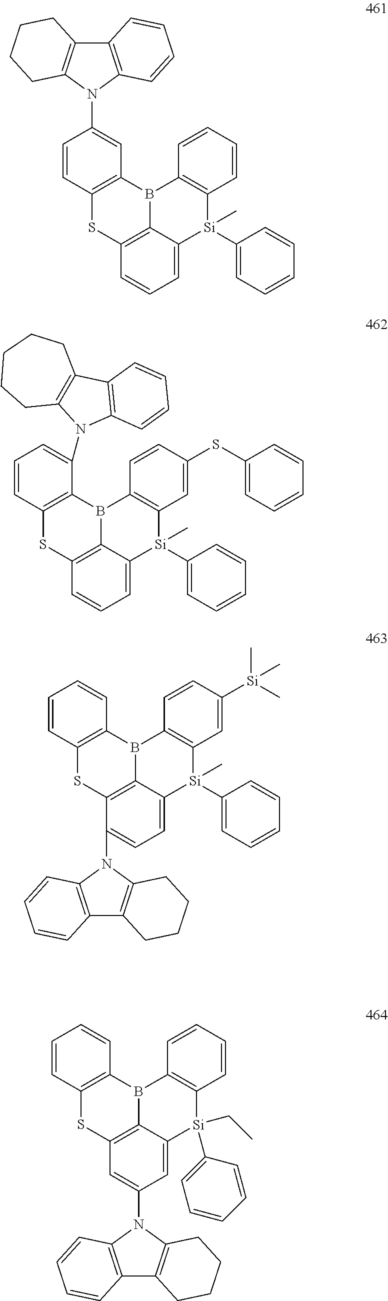 [SMILES: C[Si]1(c2ccccc2)c2ccccc2B2c3cc(-n4c5c(c6ccccc64)CCCC5)ccc3Sc3cccc1c32 ; C[Si]1(c2ccccc2)c2cc(Sc3ccccc3)ccc2B2c3c(cccc3-n3c4c(c5ccccc53)CCCCC4)Sc3cccc1c32 ; C[Si](C)(C)c1ccc2c(c1)[Si](C)(c1ccccc1)c1ccc(-n3c4c(c5ccccc53)CCCC4)c3c1B2c1ccccc1S3 ; CC[Si]1(c2ccccc2)c2ccccc2B2c3ccccc3Sc3cc(-n4c5c(c6ccccc64)CCCC5)cc1c32]

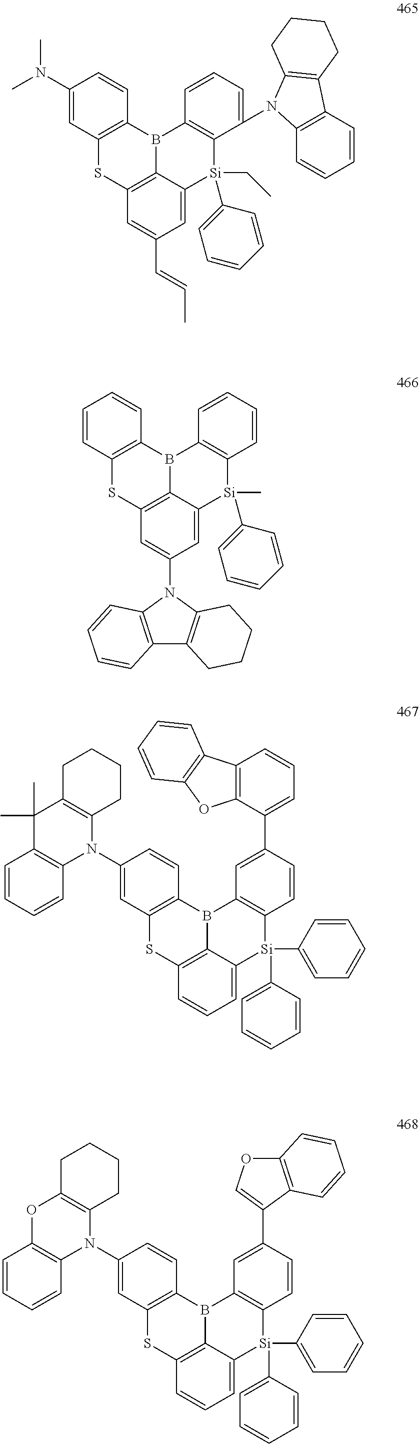 [SMILES: C/C=C/c1cc2c3c(c1)[Si](CC)(c1ccccc1)c1c(cccc1-n1c4c(c5ccccc51)CCCC4)B3c1ccc(N(C)C)cc1S2 ; C[Si]1(c2ccccc2)c2ccccc2B2c3ccccc3Sc3cc(-n4c5c(c6ccccc64)CCCC5)cc1c32 ; CC1(C)C2=C(CCCC2)N(c2ccc3c(c2)Sc2cccc4c2B3c2cc(-c3cccc5c3oc3ccccc35)ccc2[Si]4(c2ccccc2)c2ccccc2)c2ccccc21 ; c1ccc([Si]2(c3ccccc3)c3ccc(-c4coc5ccccc45)cc3B3c4ccc(N5C6=C(CCCC6)Oc6ccccc65)cc4Sc4cccc2c43)cc1]

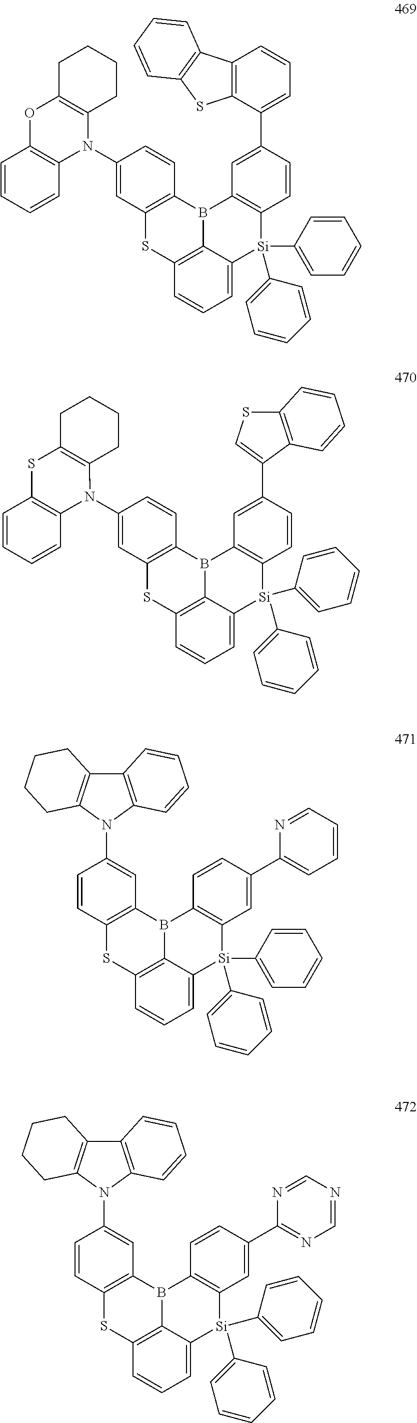 [SMILES: c1ccc([Si]2(c3ccccc3)c3ccc(-c4cccc5c4sc4ccccc45)cc3B3c4ccc(N5C6=C(CCCC6)Oc6ccccc65)cc4Sc4cccc2c43)cc1 ; c1ccc([Si]2(c3ccccc3)c3ccc(-c4csc5ccccc45)cc3B3c4ccc(N5C6=C(CCCC6)Sc6ccccc65)cc4Sc4cccc2c43)cc1 ; c1ccc([Si]2(c3ccccc3)c3cc(-c4ccccn4)ccc3B3c4cc(-n5c6c(c7ccccc75)CCCC6)ccc4Sc4cccc2c43)cc1 ; c1ccc([Si]2(c3ccccc3)c3cc(-c4ncncn4)ccc3B3c4cc(-n5c6c(c7ccccc75)CCCC6)ccc4Sc4cccc2c43)cc1]

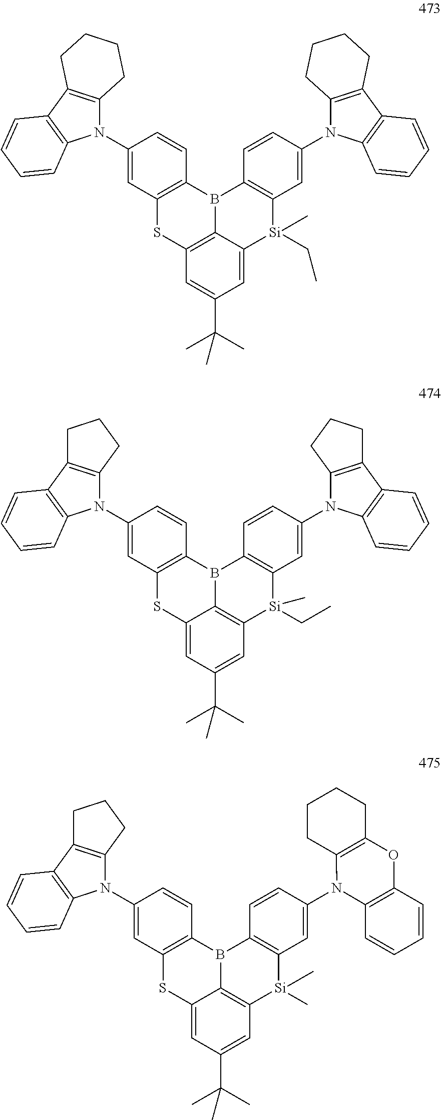 [SMILES: CC[Si]1(C)c2cc(-n3c4c(c5ccccc53)CCCC4)ccc2B2c3ccc(-n4c5c(c6ccccc64)CCCC5)cc3Sc3cc(C(C)(C)C)cc1c32 ; CC[Si]1(C)c2cc(-n3c4c(c5ccccc53)CCC4)ccc2B2c3ccc(-n4c5c(c6ccccc64)CCC5)cc3Sc3cc(C(C)(C)C)cc1c32 ; CC(C)(C)c1cc2c3c(c1)[Si](C)(C)c1cc(N4C5=C(CCCC5)Oc5ccccc54)ccc1B3c1ccc(-n3c4c(c5ccccc53)CCC4)cc1S2]

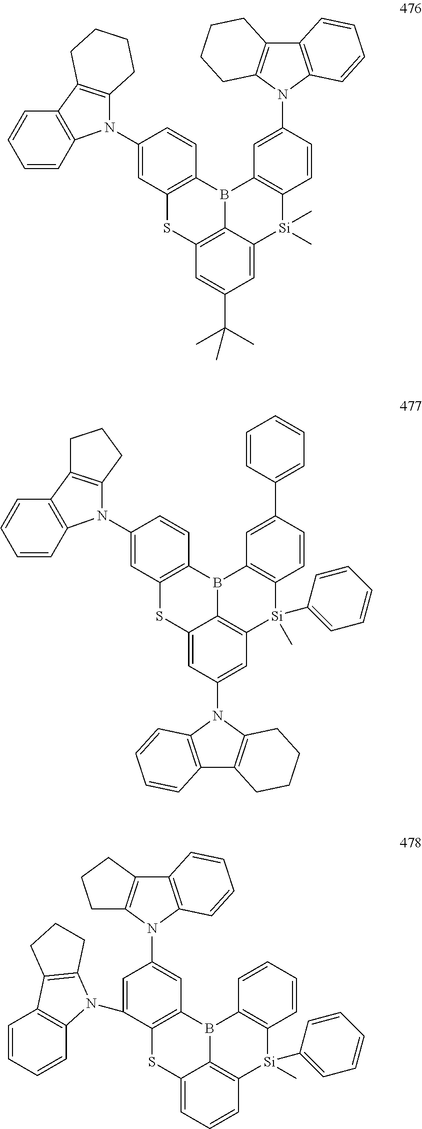 [SMILES: CC(C)(C)c1cc2c3c(c1)[Si](C)(C)c1ccc(-n4c5c(c6ccccc64)CCCC5)cc1B3c1ccc(-n3c4c(c5ccccc53)CCCC4)cc1S2 ; C[Si]1(c2ccccc2)c2ccc(-c3ccccc3)cc2B2c3ccc(-n4c5c(c6ccccc64)CCC5)cc3Sc3cc(-n4c5c(c6ccccc64)CCCC5)cc1c32 ; C[Si]1(c2ccccc2)c2ccccc2B2c3cc(-n4c5c(c6ccccc64)CCC5)cc(-n4c5c(c6ccccc64)CCC5)c3Sc3cccc1c32]

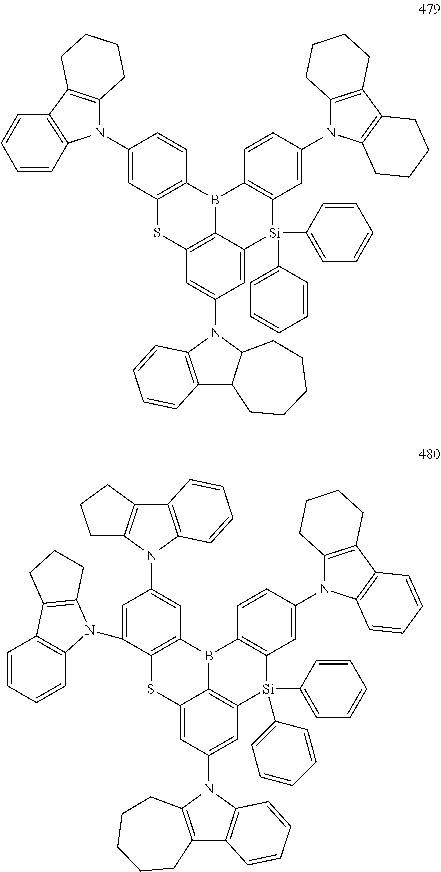 [SMILES: c1ccc([Si]2(c3ccccc3)c3cc(-n4c5c(c6c4CCCC6)CCCC5)ccc3B3c4ccc(-n5c6c(c7ccccc75)CCCC6)cc4Sc4cc(N5c6ccccc6C6CCCCCC65)cc2c43)cc1 ; c1ccc([Si]2(c3ccccc3)c3cc(-n4c5c(c6ccccc64)CCCC5)ccc3B3c4cc(-n5c6c(c7ccccc75)CCC6)cc(-n5c6c(c7ccccc75)CCC6)c4Sc4cc(-n5c6c(c7ccccc75)CCCCC6)cc2c43)cc1]

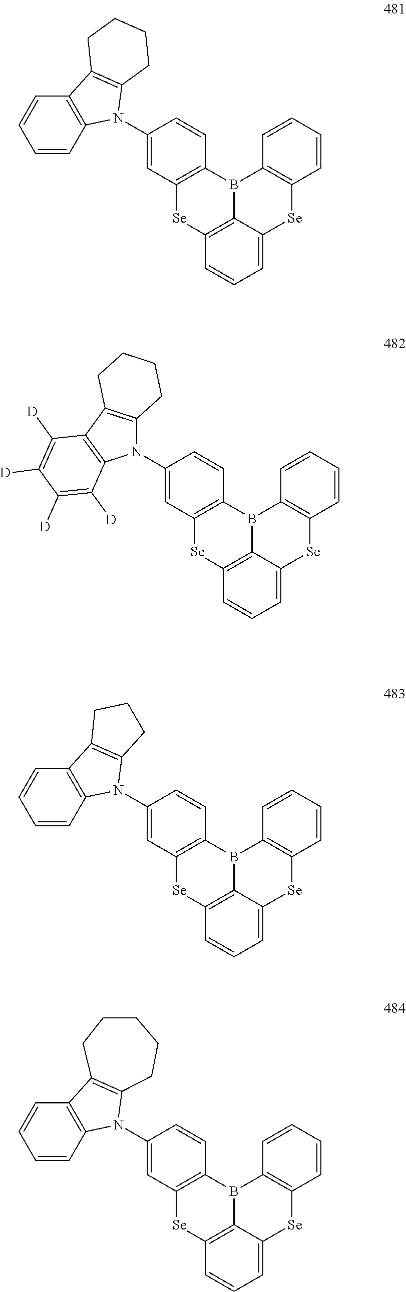 [SMILES: c1ccc2c(c1)[Se]c1cccc3c1B2c1ccc(-n2c4c(c5ccccc52)CCCC4)cc1[Se]3 ; [2H]c1c([2H])c([2H])c2c(c1[2H])c1c(n2-c2ccc3c(c2)[Se]c2cccc4c2B3c2ccccc2[Se]4)CCCC1 ; c1ccc2c(c1)[Se]c1cccc3c1B2c1ccc(-n2c4c(c5ccccc52)CCC4)cc1[Se]3 ; c1ccc2c(c1)[Se]c1cccc3c1B2c1ccc(-n2c4c(c5ccccc52)CCCCC4)cc1[Se]3]

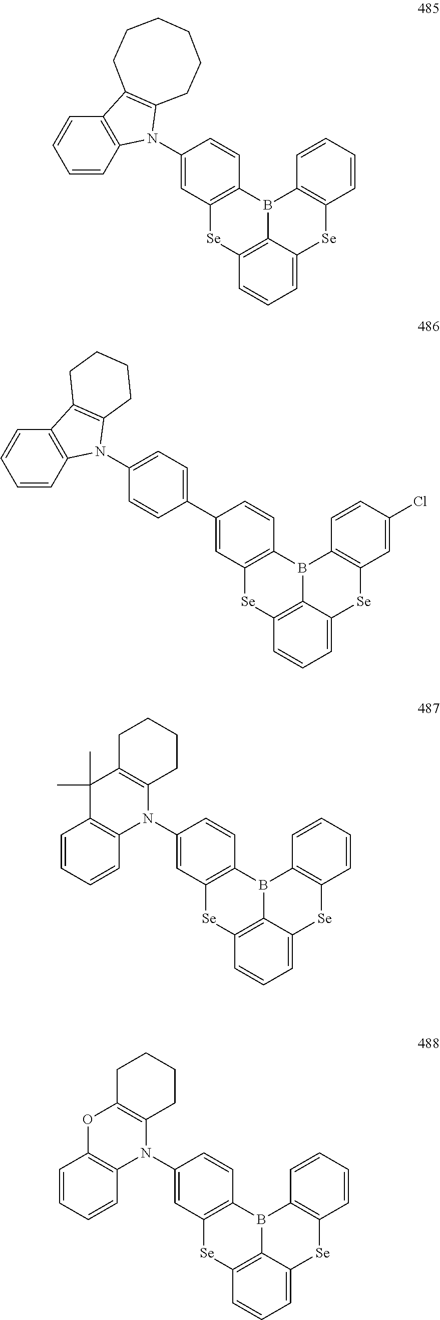 [SMILES: c1ccc2c(c1)[Se]c1cccc3c1B2c1ccc(-n2c4c(c5ccccc52)CCCCCC4)cc1[Se]3 ; Clc1ccc2c(c1)[Se]c1cccc3c1B2c1ccc(-c2ccc(-n4c5c(c6ccccc64)CCCC5)cc2)cc1[Se]3 ; CC1(C)C2=C(CCCC2)N(c2ccc3c(c2)[Se]c2cccc4c2B3c2ccccc2[Se]4)c2ccccc21 ; c1ccc2c(c1)OC1=C(CCCC1)N2c1ccc2c(c1)[Se]c1cccc3c1B2c1ccccc1[Se]3]

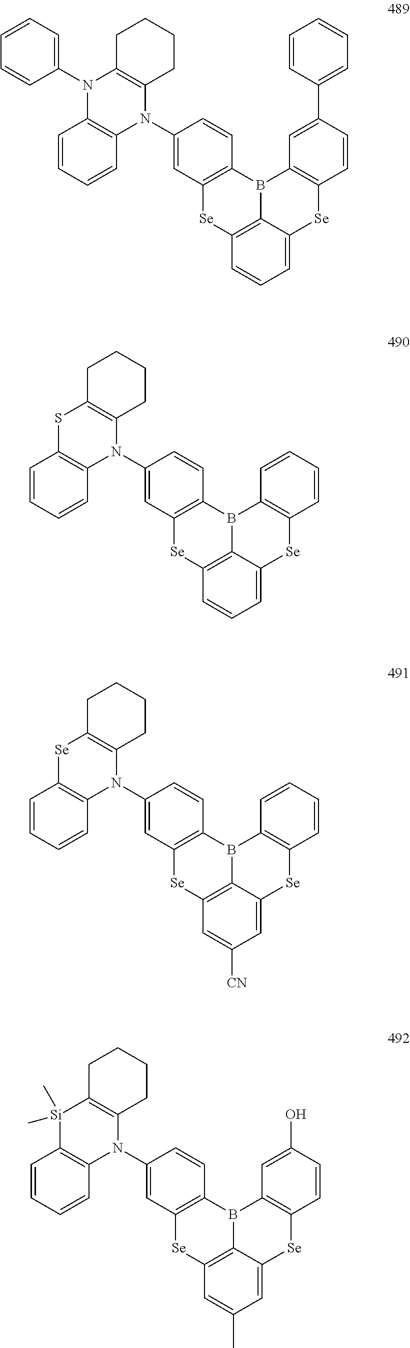 [SMILES: c1ccc(-c2ccc3c(c2)B2c4ccc(N5C6=C(CCCC6)N(c6ccccc6)c6ccccc65)cc4[Se]c4cccc(c42)[Se]3)cc1 ; c1ccc2c(c1)SC1=C(CCCC1)N2c1ccc2c(c1)[Se]c1cccc3c1B2c1ccccc1[Se]3 ; N#Cc1cc2c3c(c1)[Se]c1cc(N4C5=C(CCCC5)[Se]c5ccccc54)ccc1B3c1ccccc1[Se]2 ; Cc1cc2c3c(c1)[Se]c1ccc(O)cc1B3c1ccc(N3C4=C(CCCC4)[Si](C)(C)c4ccccc43)cc1[Se]2]

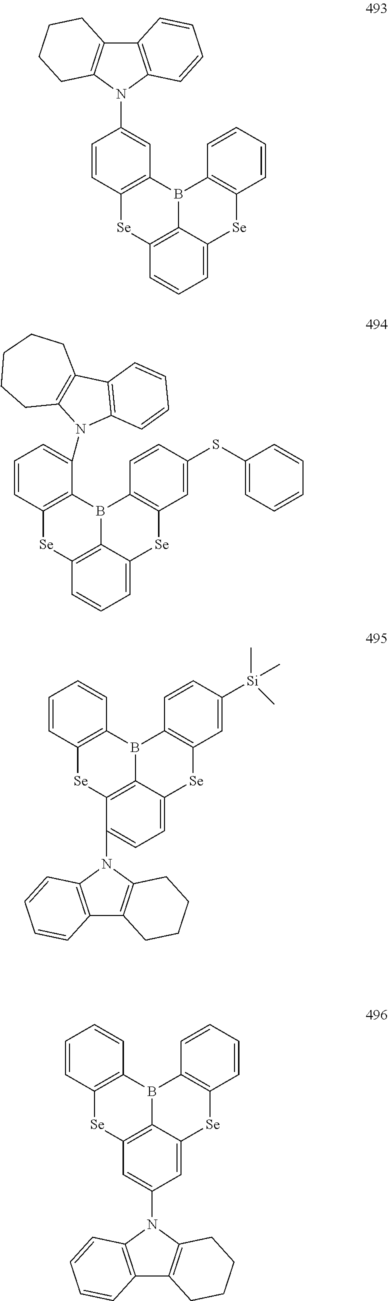 [SMILES: c1ccc2c(c1)[Se]c1cccc3c1B2c1cc(-n2c4c(c5ccccc52)CCCC4)ccc1[Se]3 ; c1ccc(Sc2ccc3c(c2)[Se]c2cccc4c2B3c2c(cccc2-n2c3c(c5ccccc52)CCCCC3)[Se]4)cc1 ; C[Si](C)(C)c1ccc2c(c1)[Se]c1ccc(-n3c4c(c5ccccc53)CCCC4)c3c1B2c1ccccc1[Se]3 ; c1ccc2c(c1)[Se]c1cc(-n3c4c(c5ccccc53)CCCC4)cc3c1B2c1ccccc1[Se]3]

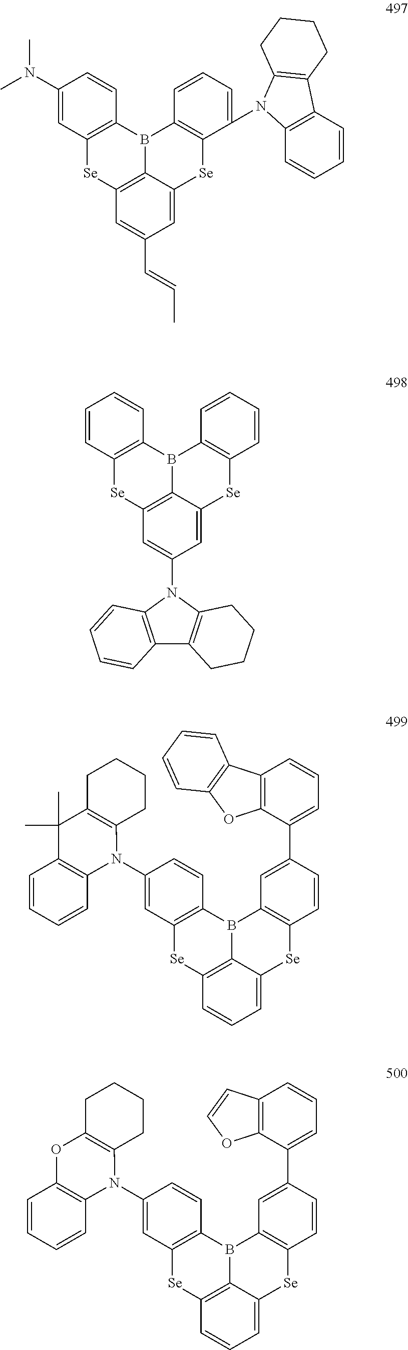 [SMILES: C/C=C/c1cc2c3c(c1)[Se]c1c(cccc1-n1c4c(c5ccccc51)CCCC4)B3c1ccc(N(C)C)cc1[Se]2 ; c1ccc2c(c1)[Se]c1cc(-n3c4c(c5ccccc53)CCCC4)cc3c1B2c1ccccc1[Se]3 ; CC1(C)C2=C(CCCC2)N(c2ccc3c(c2)[Se]c2cccc4c2B3c2cc(-c3cccc5c3oc3ccccc35)ccc2[Se]4)c2ccccc21 ; c1ccc2c(c1)OC1=C(CCCC1)N2c1ccc2c(c1)[Se]c1cccc3c1B2c1cc(-c2cccc4ccoc24)ccc1[Se]3]

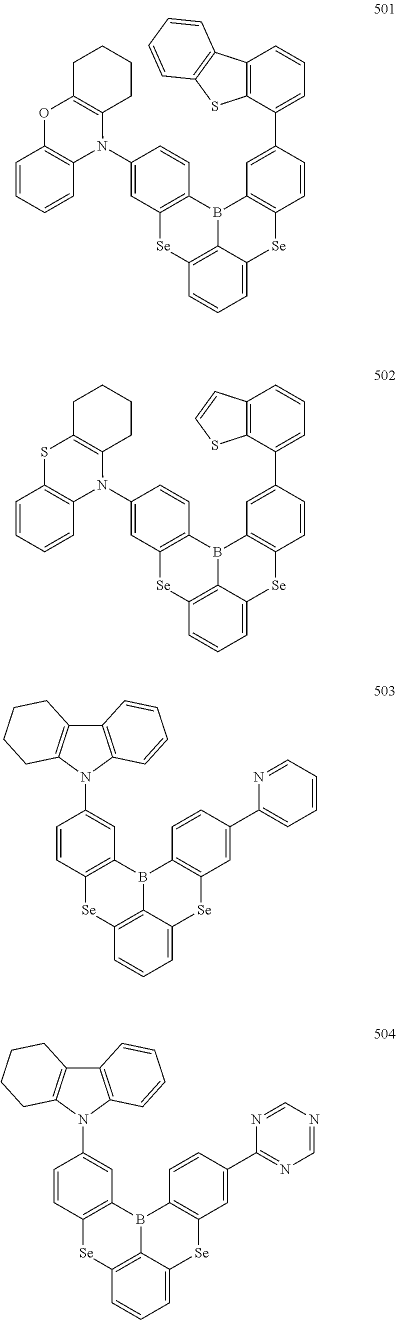 [SMILES: c1ccc2c(c1)OC1=C(CCCC1)N2c1ccc2c(c1)[Se]c1cccc3c1B2c1cc(-c2cccc4c2sc2ccccc24)ccc1[Se]3 ; c1ccc2c(c1)SC1=C(CCCC1)N2c1ccc2c(c1)[Se]c1cccc3c1B2c1cc(-c2cccc4ccsc24)ccc1[Se]3 ; c1ccc(-c2ccc3c(c2)[Se]c2cccc4c2B3c2cc(-n3c5c(c6ccccc63)CCCC5)ccc2[Se]4)nc1 ; c1cc2c3c(c1)[Se]c1ccc(-n4c5c(c6ccccc64)CCCC5)cc1B3c1ccc(-c3ncncn3)cc1[Se]2]

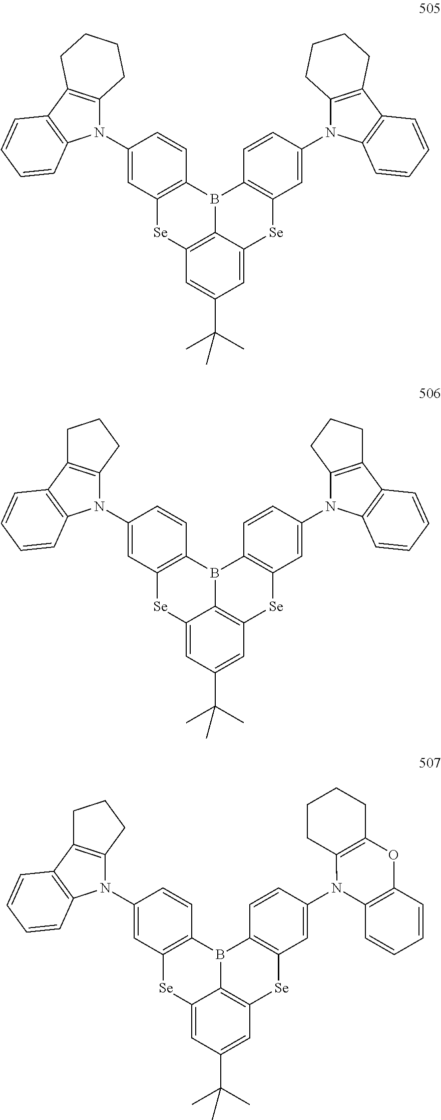 [SMILES: CC(C)(C)c1cc2c3c(c1)[Se]c1cc(-n4c5c(c6ccccc64)CCCC5)ccc1B3c1ccc(-n3c4c(c5ccccc53)CCCC4)cc1[Se]2 ; CC(C)(C)c1cc2c3c(c1)[Se]c1cc(-n4c5c(c6ccccc64)CCC5)ccc1B3c1ccc(-n3c4c(c5ccccc53)CCC4)cc1[Se]2 ; CC(C)(C)c1cc2c3c(c1)[Se]c1cc(-n4c5c(c6ccccc64)CCC5)ccc1B3c1ccc(N3C4=C(CCCC4)Oc4ccccc43)cc1[Se]2]

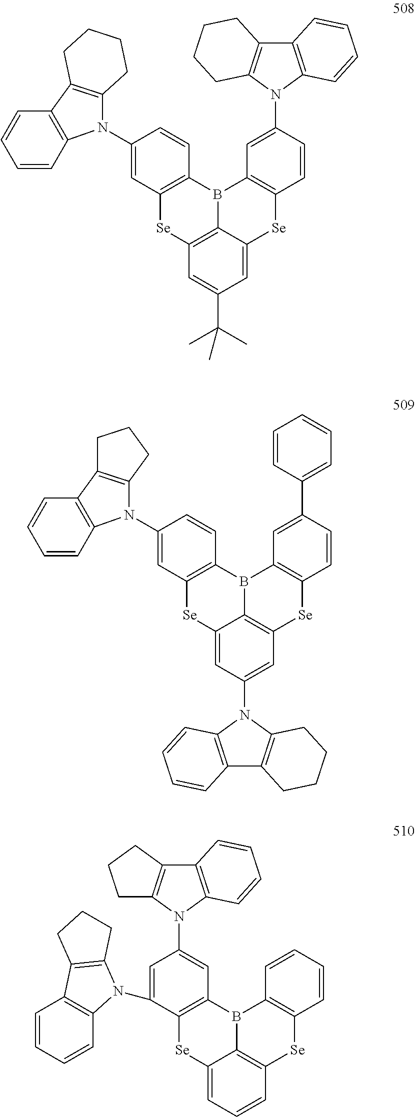 [SMILES: CC(C)(C)c1cc2c3c(c1)[Se]c1ccc(-n4c5c(c6ccccc64)CCCC5)cc1B3c1ccc(-n3c4c(c5ccccc53)CCCC4)cc1[Se]2 ; c1ccc(-c2ccc3c(c2)B2c4ccc(-n5c6c(c7ccccc75)CCC6)cc4[Se]c4cc(-n5c6c(c7ccccc75)CCCC6)cc(c42)[Se]3)cc1 ; c1ccc2c(c1)[Se]c1cccc3c1B2c1cc(-n2c4c(c5ccccc52)CCC4)cc(-n2c4c(c5ccccc52)CCC4)c1[Se]3]

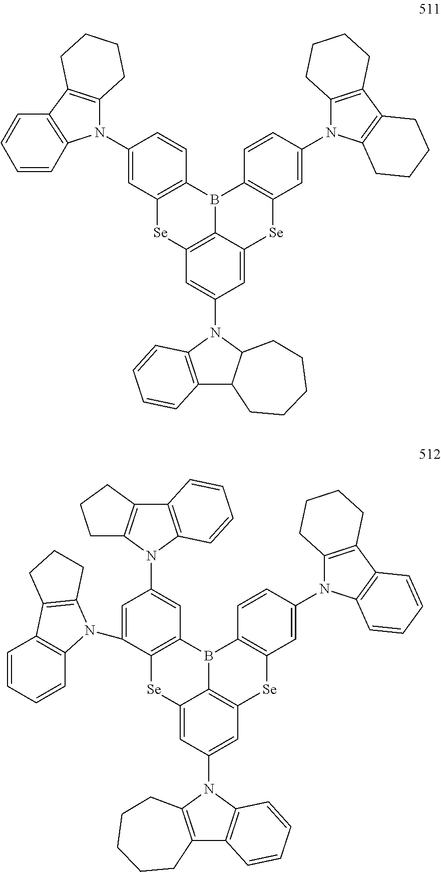 [SMILES: c1ccc2c(c1)C1CCCCCC1N2c1cc2c3c(c1)[Se]c1cc(-n4c5c(c6ccccc64)CCCC5)ccc1B3c1ccc(-n3c4c(c5c3CCCC5)CCCC4)cc1[Se]2 ; c1ccc2c(c1)c1c(n2-c2cc3c4c(c2)[Se]c2c(cc(-n5c6c(c7ccccc75)CCC6)cc2-n2c5c(c6ccccc62)CCC5)B4c2ccc(-n4c5c(c6ccccc64)CCCC5)cc2[Se]3)CCCCC1]

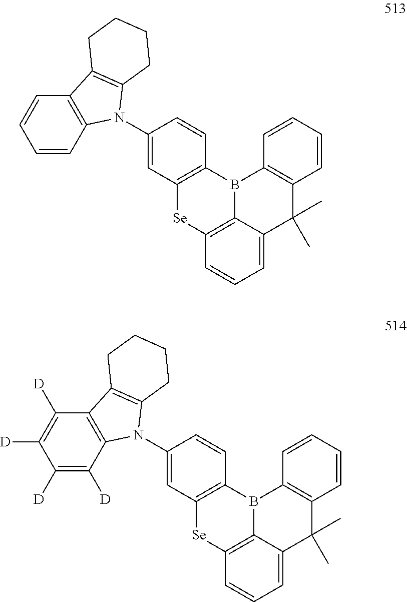 [SMILES: CC1(C)c2ccccc2B2c3ccc(-n4c5c(c6ccccc64)CCCC5)cc3[Se]c3cccc1c32 ; [2H]c1c([2H])c([2H])c2c(c1[2H])c1c(n2-c2ccc3c(c2)[Se]c2cccc4c2B3c2ccccc2C4(C)C)CCCC1]

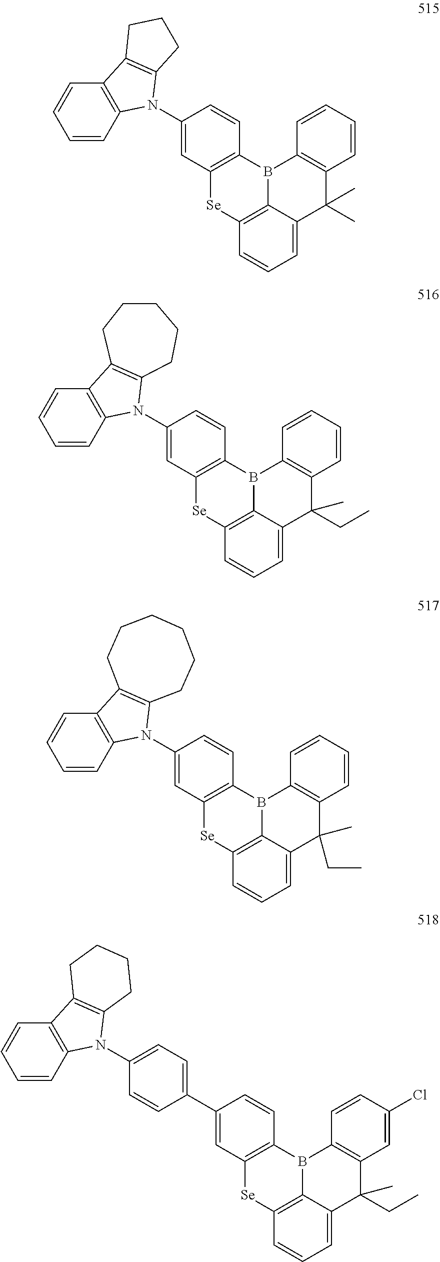 [SMILES: CC1(C)c2ccccc2B2c3ccc(-n4c5c(c6ccccc64)CCC5)cc3[Se]c3cccc1c32 ; CCC1(C)c2ccccc2B2c3ccc(-n4c5c(c6ccccc64)CCCCC5)cc3[Se]c3cccc1c32 ; CCC1(C)c2ccccc2B2c3ccc(-n4c5c(c6ccccc64)CCCCCC5)cc3[Se]c3cccc1c32 ; CCC1(C)c2cc(Cl)ccc2B2c3ccc(-c4ccc(-n5c6c(c7ccccc75)CCCC6)cc4)cc3[Se]c3cccc1c32]

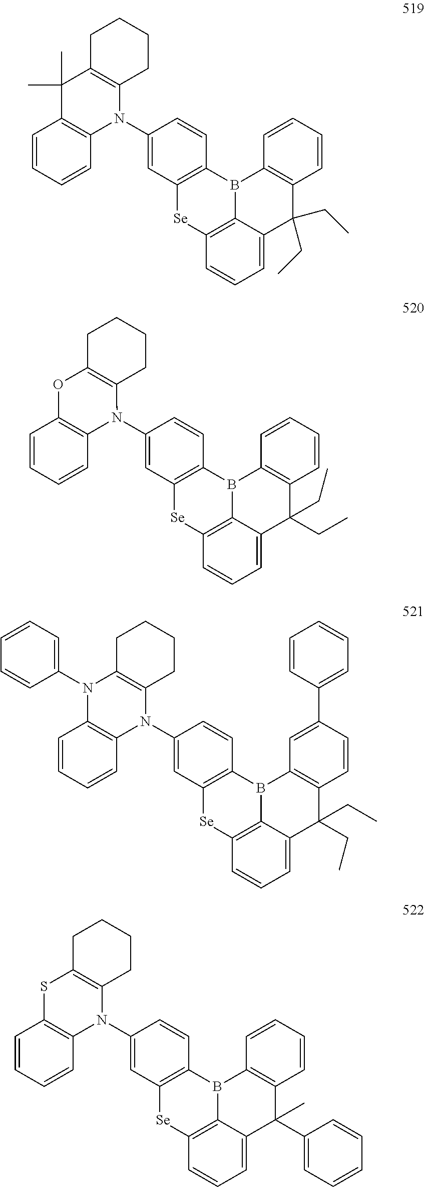 [SMILES: CCC1(CC)c2ccccc2B2c3ccc(N4C5=C(CCCC5)C(C)(C)c5ccccc54)cc3[Se]c3cccc1c32 ; CCC1(CC)c2ccccc2B2c3ccc(N4C5=C(CCCC5)Oc5ccccc54)cc3[Se]c3cccc1c32 ; CCC1(CC)c2ccc(-c3ccccc3)cc2B2c3ccc(N4C5=C(CCCC5)N(c5ccccc5)c5ccccc54)cc3[Se]c3cccc1c32 ; CC1(c2ccccc2)c2ccccc2B2c3ccc(N4C5=C(CCCC5)Sc5ccccc54)cc3[Se]c3cccc1c32]

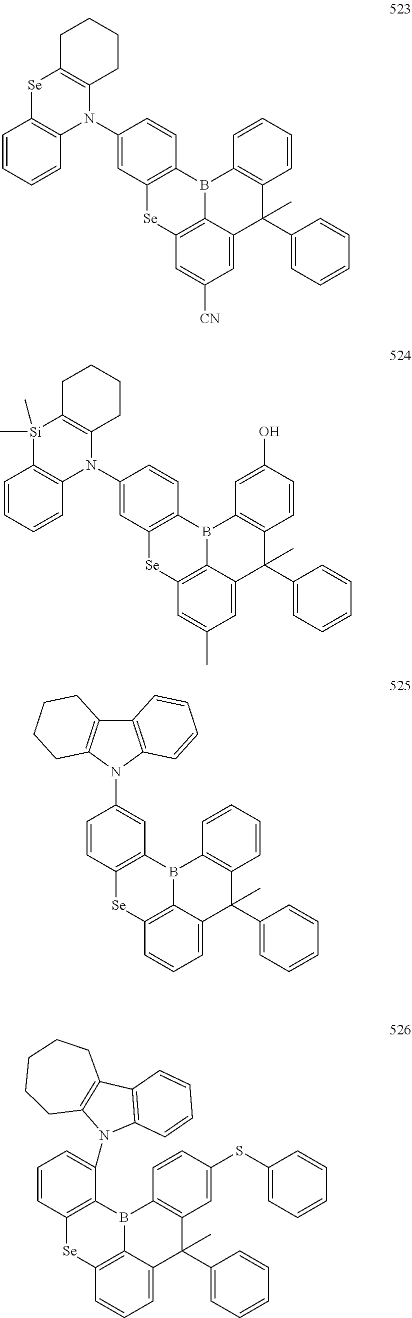

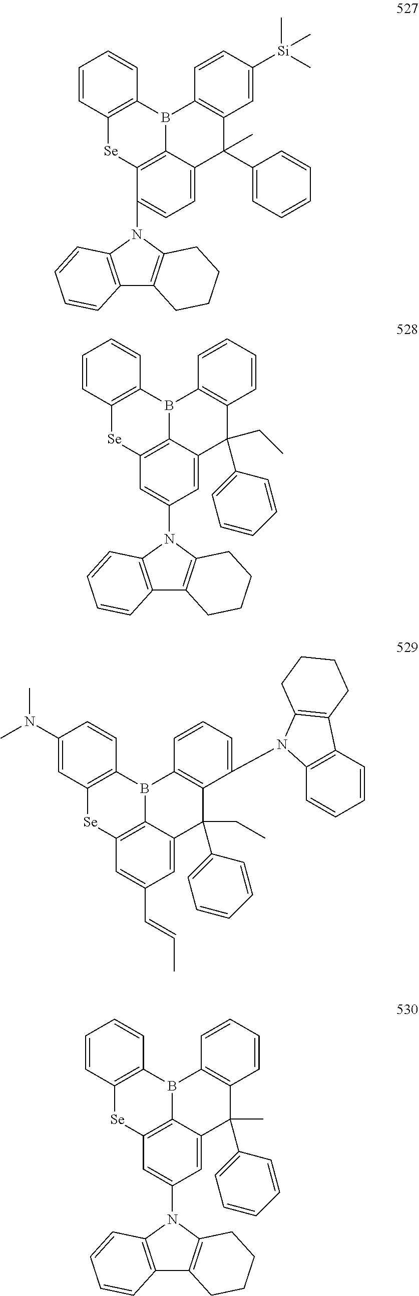

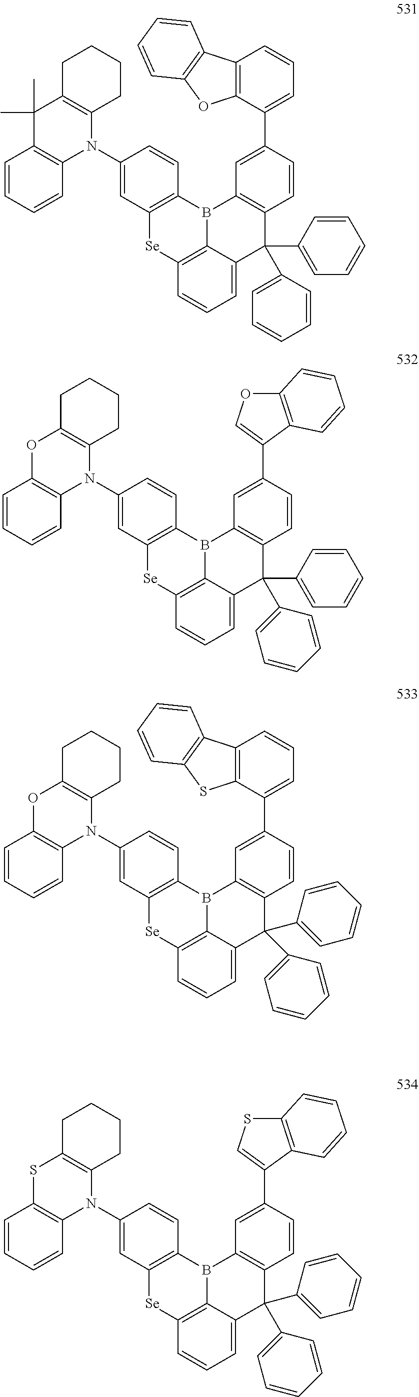

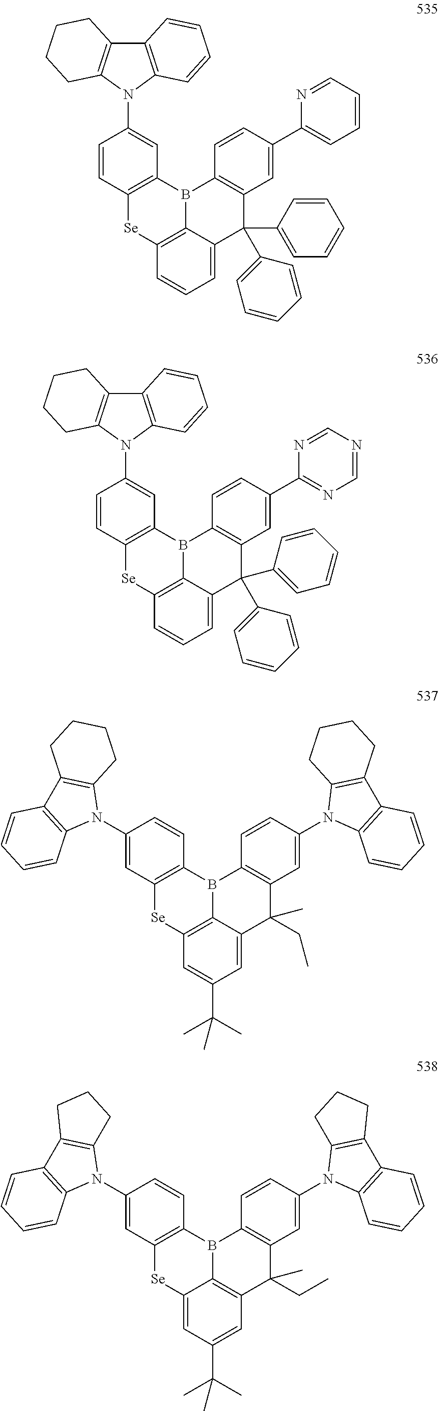 [SMILES: c1ccc(C2(c3ccccc3)c3cc(-c4ccccn4)ccc3B3c4cc(-n5c6c(c7ccccc75)CCCC6)ccc4[Se]c4cccc2c43)cc1 ; c1ccc(C2(c3ccccc3)c3cc(-c4ncncn4)ccc3B3c4cc(-n5c6c(c7ccccc75)CCCC6)ccc4[Se]c4cccc2c43)cc1 ; CCC1(C)c2cc(-n3c4c(c5ccccc53)CCCC4)ccc2B2c3ccc(-n4c5c(c6ccccc64)CCCC5)cc3[Se]c3cc(C(C)(C)C)cc1c32 ; CCC1(C)c2cc(-n3c4c(c5ccccc53)CCC4)ccc2B2c3ccc(-n4c5c(c6ccccc64)CCC5)cc3[Se]c3cc(C(C)(C)C)cc1c32]

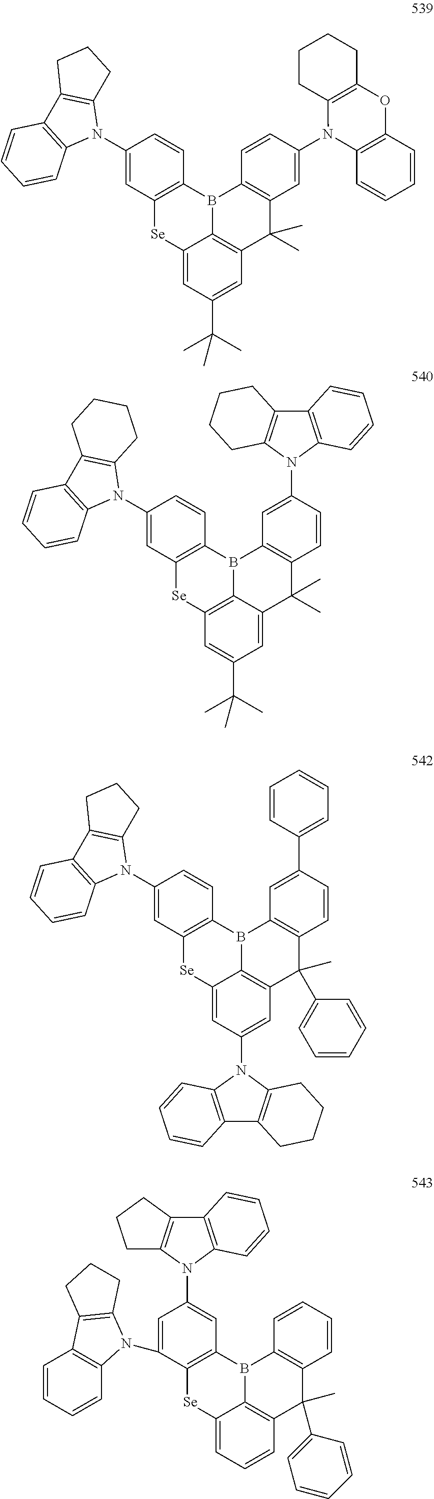

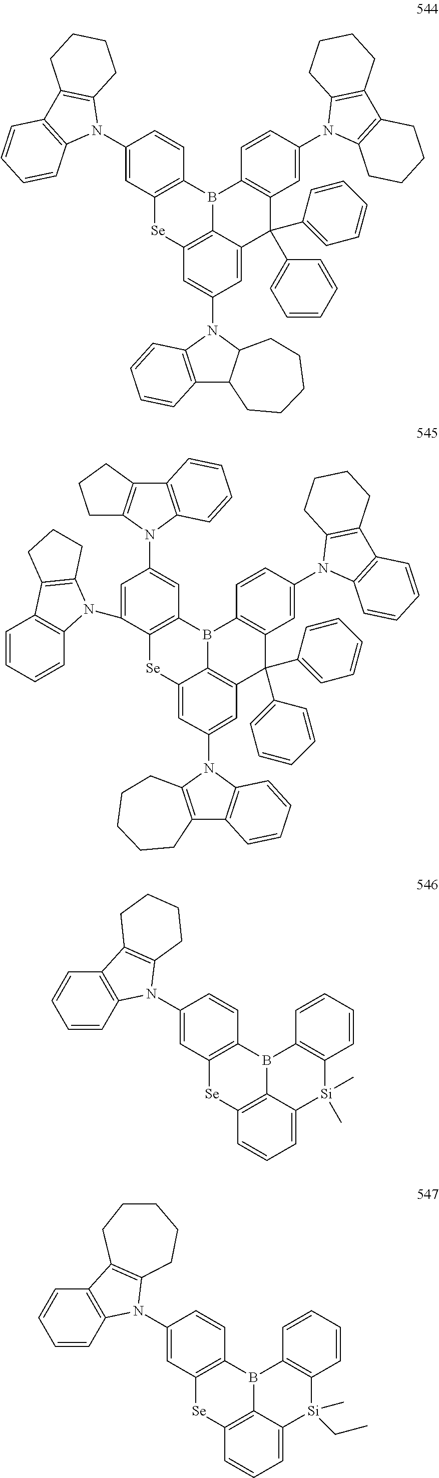

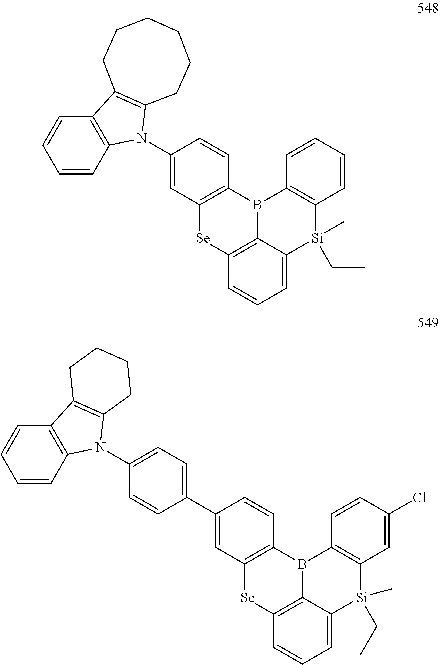 [SMILES: CC[Si]1(C)c2ccccc2B2c3ccc(-n4c5c(c6ccccc64)CCCCCC5)cc3[Se]c3cccc1c32 ; CC[Si]1(C)c2cc(Cl)ccc2B2c3ccc(-c4ccc(-n5c6c(c7ccccc75)CCCC6)cc4)cc3[Se]c3cccc1c32]

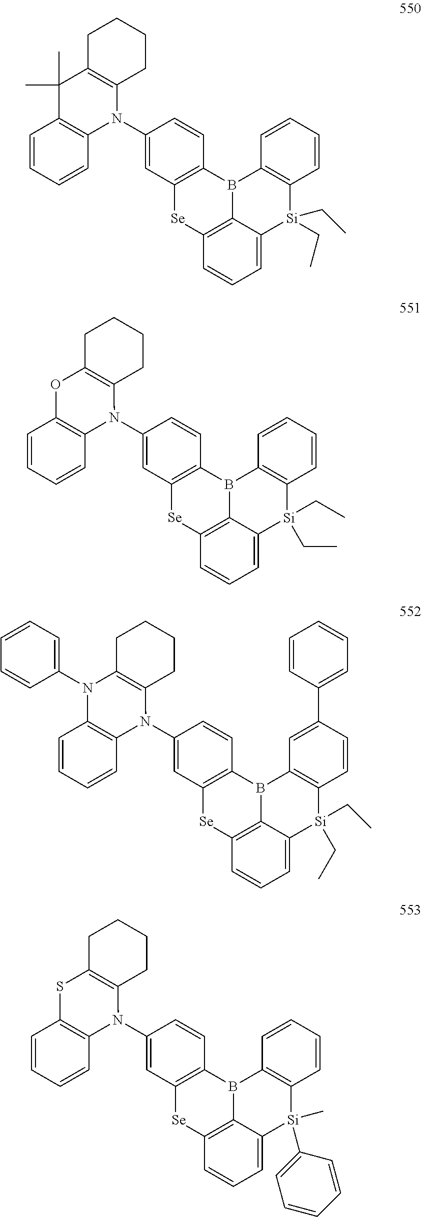 [SMILES: CC[Si]1(CC)c2ccccc2B2c3ccc(N4C5=C(CCCC5)C(C)(C)c5ccccc54)cc3[Se]c3cccc1c32 ; CC[Si]1(CC)c2ccccc2B2c3ccc(N4C5=C(CCCC5)Oc5ccccc54)cc3[Se]c3cccc1c32 ; CC[Si]1(CC)c2ccc(-c3ccccc3)cc2B2c3ccc(N4C5=C(CCCC5)N(c5ccccc5)c5ccccc54)cc3[Se]c3cccc1c32 ; C[Si]1(c2ccccc2)c2ccccc2B2c3ccc(N4C5=C(CCCC5)Sc5ccccc54)cc3[Se]c3cccc1c32]

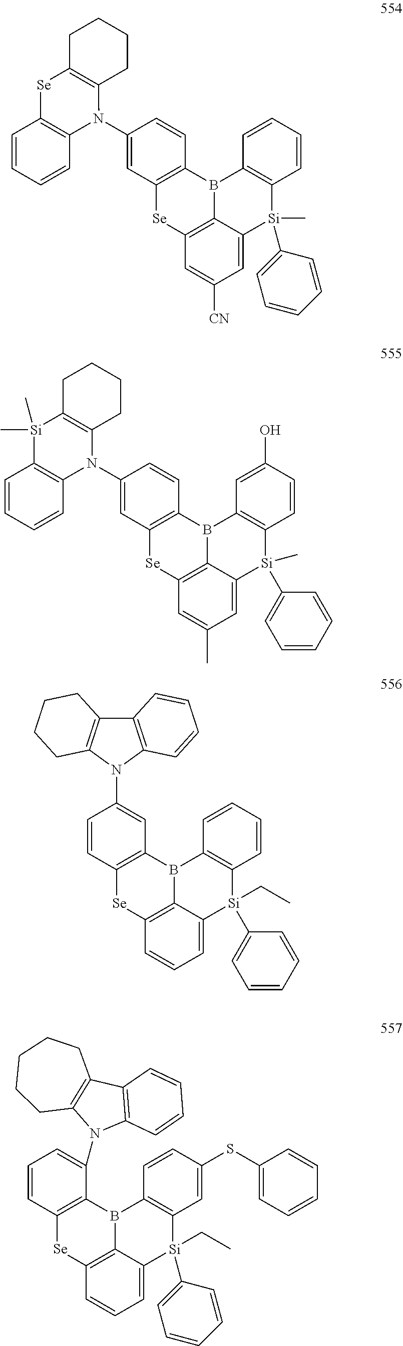

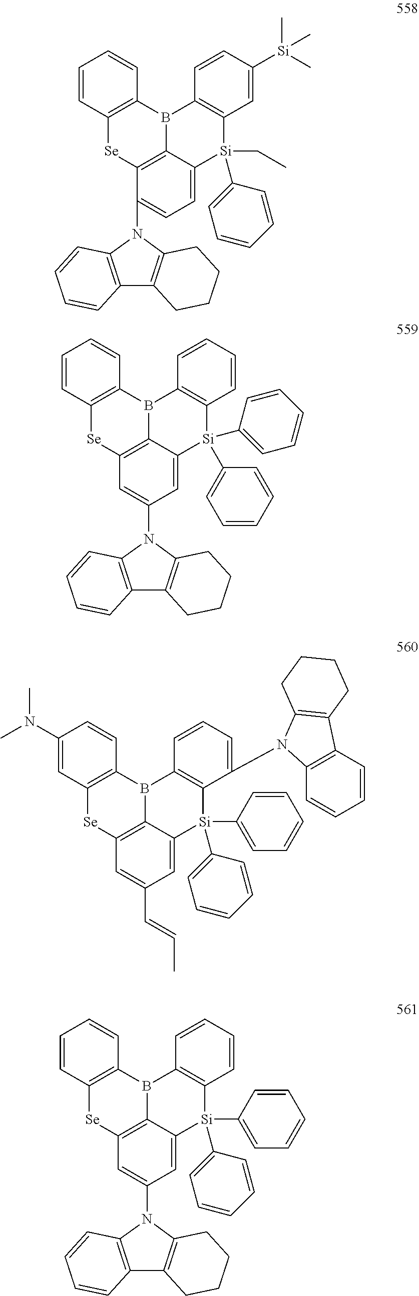

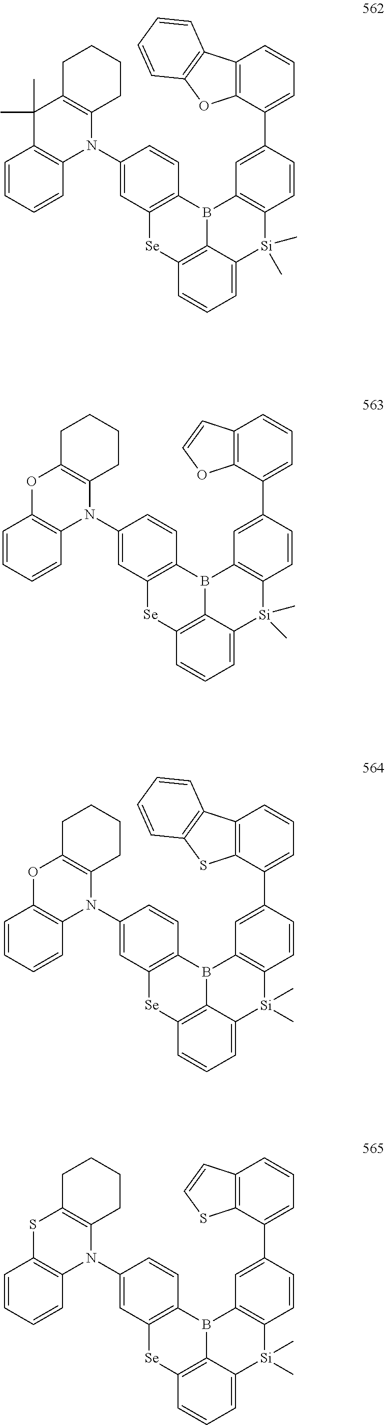

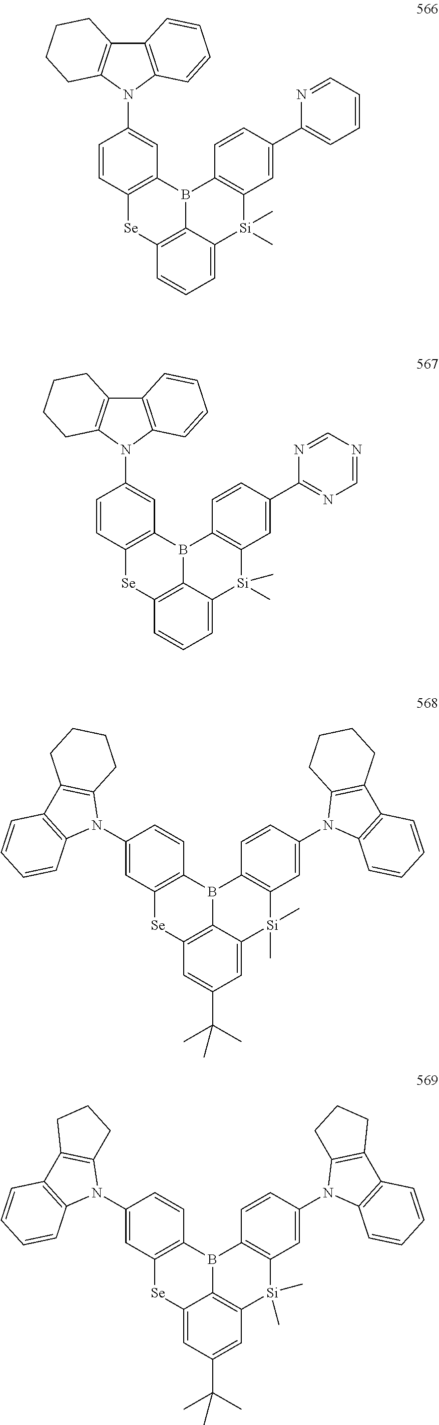 [SMILES: C[Si]1(C)c2cc(-c3ccccn3)ccc2B2c3cc(-n4c5c(c6ccccc64)CCCC5)ccc3[Se]c3cccc1c32 ; C[Si]1(C)c2cc(-c3ncncn3)ccc2B2c3cc(-n4c5c(c6ccccc64)CCCC5)ccc3[Se]c3cccc1c32 ; CC(C)(C)c1cc2c3c(c1)[Si](C)(C)c1cc(-n4c5c(c6ccccc64)CCCC5)ccc1B3c1ccc(-n3c4c(c5ccccc53)CCCC4)cc1[Se]2 ; CC(C)(C)c1cc2c3c(c1)[Si](C)(C)c1cc(-n4c5c(c6ccccc64)CCC5)ccc1B3c1ccc(-n3c4c(c5ccccc53)CCC4)cc1[Se]2]

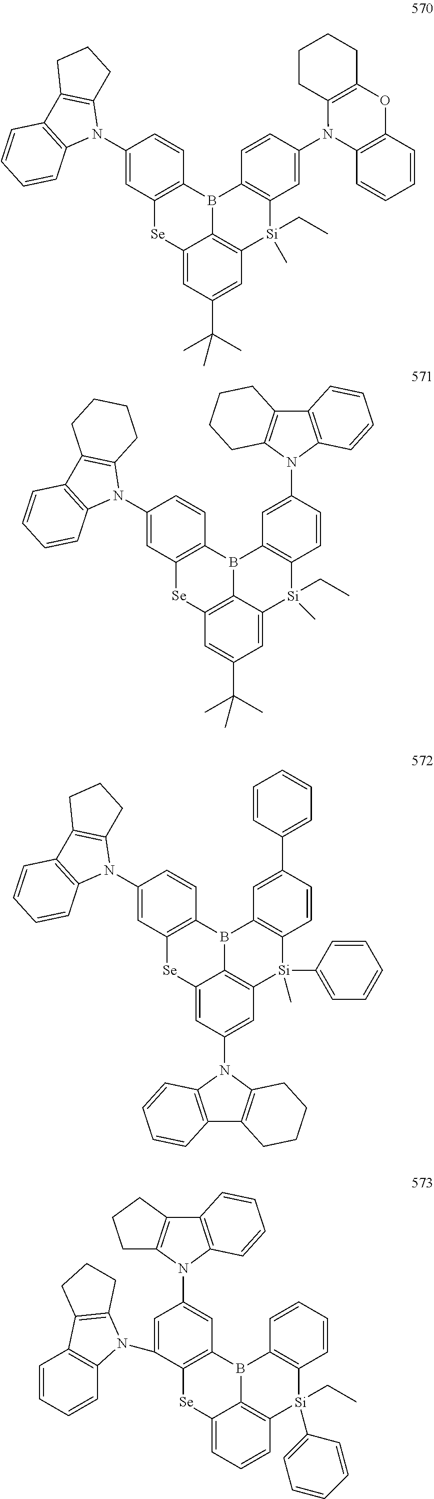

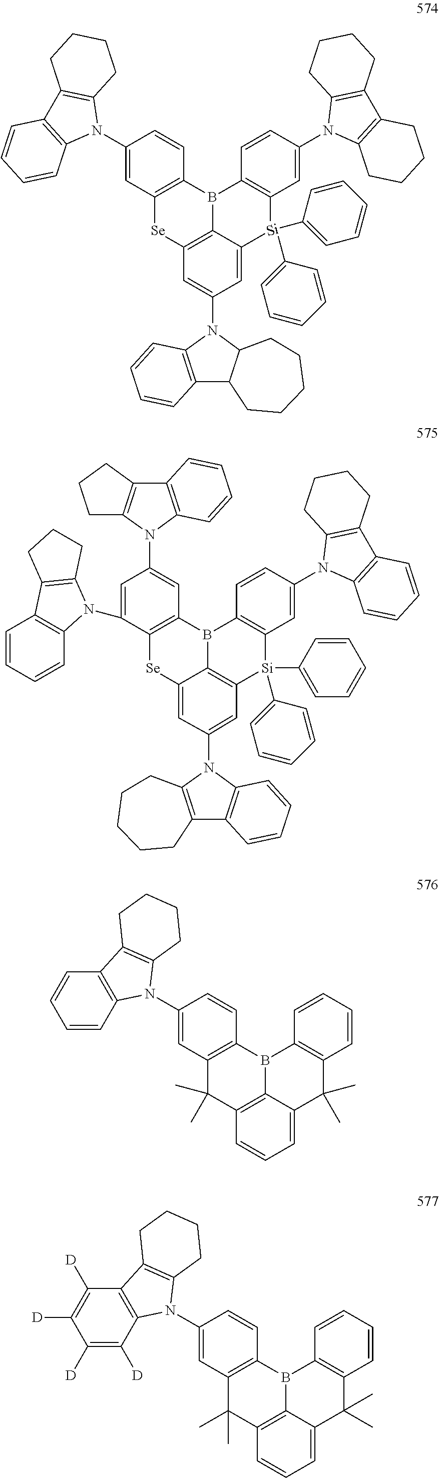

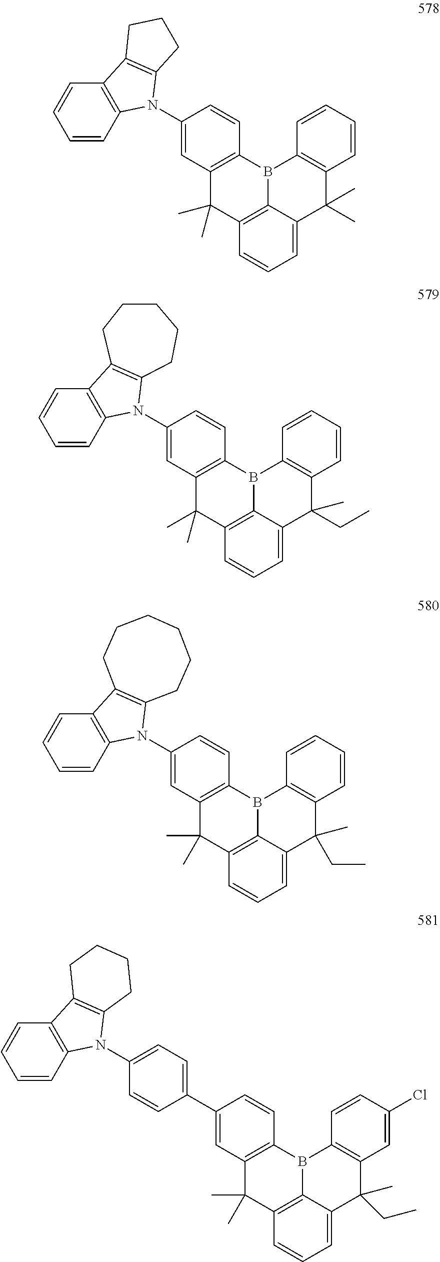 [SMILES: CC1(C)c2ccccc2B2c3ccc(-n4c5c(c6ccccc64)CCC5)cc3C(C)(C)c3cccc1c32 ; CCC1(C)c2ccccc2B2c3ccc(-n4c5c(c6ccccc64)CCCCC5)cc3C(C)(C)c3cccc1c32 ; CCC1(C)c2ccccc2B2c3ccc(-n4c5c(c6ccccc64)CCCCCC5)cc3C(C)(C)c3cccc1c32 ; CCC1(C)c2cc(Cl)ccc2B2c3ccc(-c4ccc(-n5c6c(c7ccccc75)CCCC6)cc4)cc3C(C)(C)c3cccc1c32]

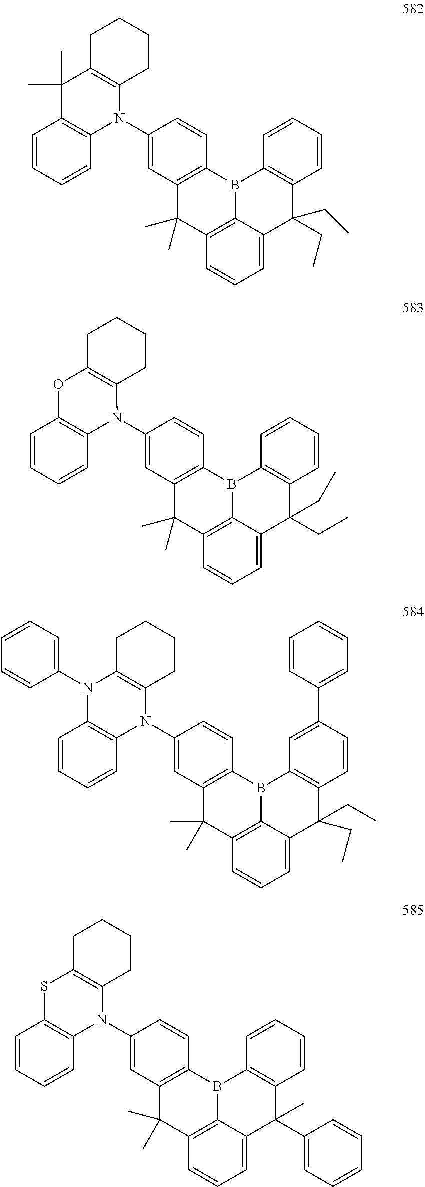 [SMILES: CCC1(CC)c2ccccc2B2c3ccc(N4C5=C(CCCC5)C(C)(C)c5ccccc54)cc3C(C)(C)c3cccc1c32 ; CCC1(CC)c2ccccc2B2c3ccc(N4C5=C(CCCC5)Oc5ccccc54)cc3C(C)(C)c3cccc1c32 ; CCC1(CC)c2ccc(-c3ccccc3)cc2B2c3ccc(N4C5=C(CCCC5)N(c5ccccc5)c5ccccc54)cc3C(C)(C)c3cccc1c32 ; CC1(C)c2cc(N3C4=C(CCCC4)Sc4ccccc43)ccc2B2c3ccccc3C(C)(c3ccccc3)c3cccc1c32]

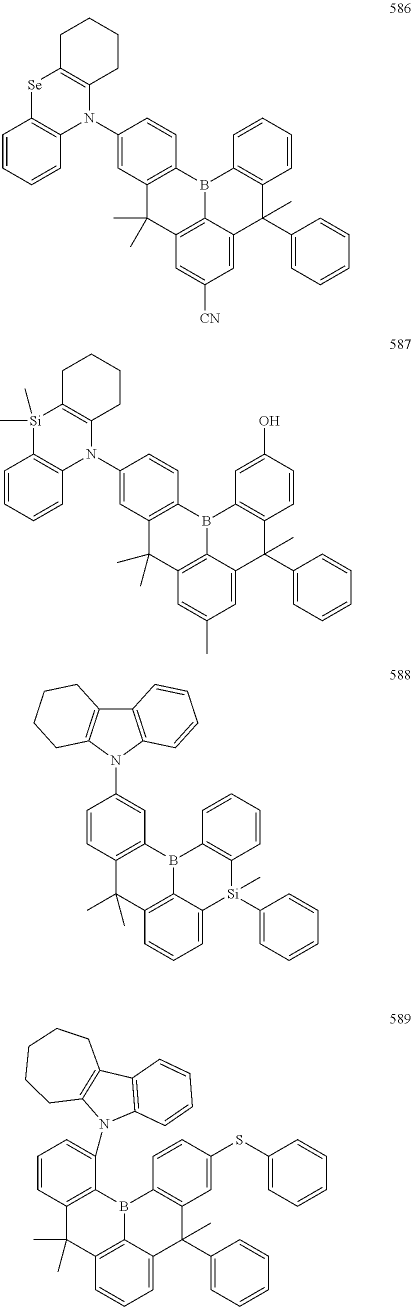

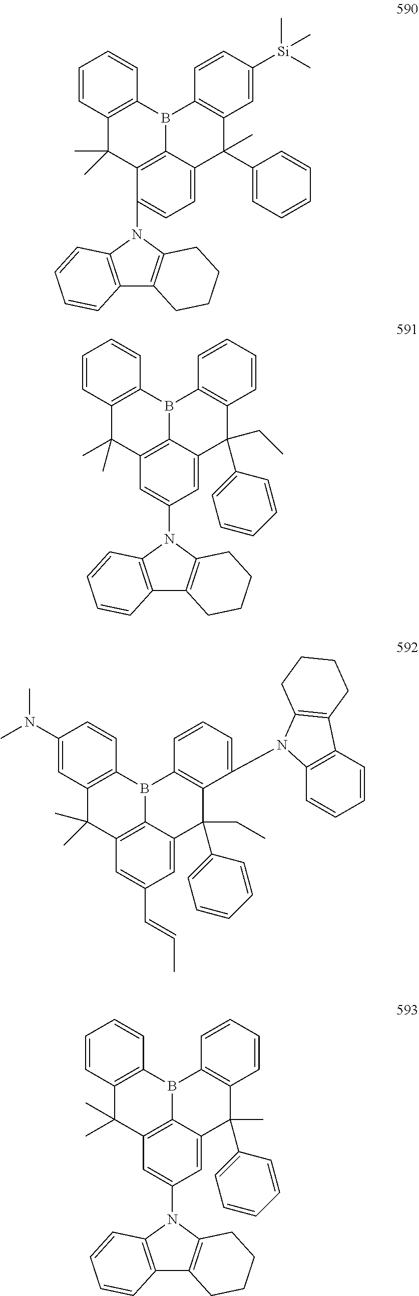

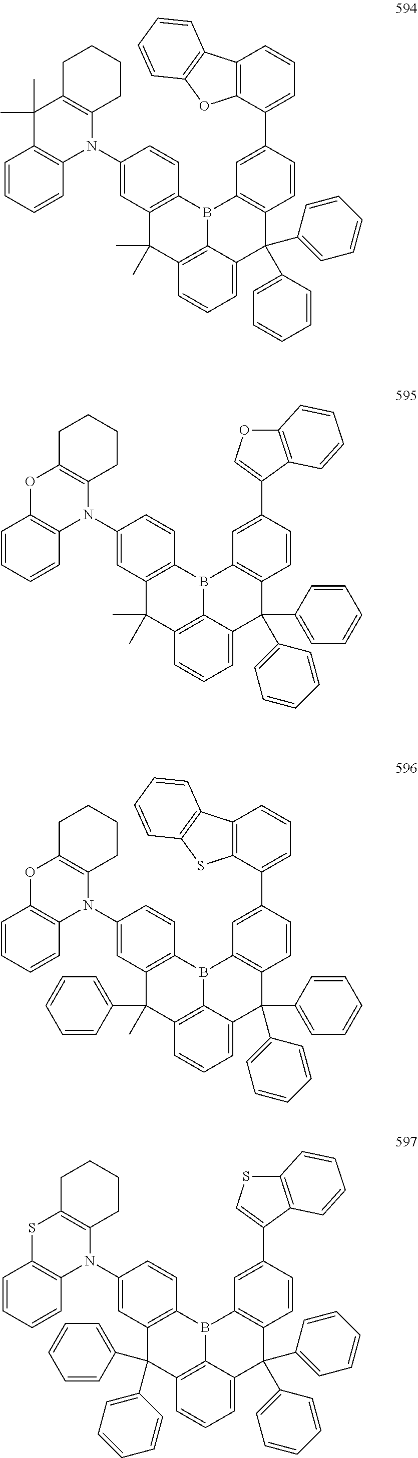 [SMILES: CC1(C)C2=C(CCCC2)N(c2ccc3c(c2)C(C)(C)c2cccc4c2B3c2cc(-c3cccc5c3oc3ccccc35)ccc2C4(c2ccccc2)c2ccccc2)c2ccccc21 ; CC1(C)c2cc(N3C4=C(CCCC4)Oc4ccccc43)ccc2B2c3cc(-c4coc5ccccc45)ccc3C(c3ccccc3)(c3ccccc3)c3cccc1c32 ; CC1(c2ccccc2)c2cc(N3C4=C(CCCC4)Oc4ccccc43)ccc2B2c3cc(-c4cccc5c4sc4ccccc45)ccc3C(c3ccccc3)(c3ccccc3)c3cccc1c32 ; c1ccc(C2(c3ccccc3)c3ccc(-c4csc5ccccc45)cc3B3c4ccc(N5C6=C(CCCC6)Sc6ccccc65)cc4C(c4ccccc4)(c4ccccc4)c4cccc2c43)cc1]

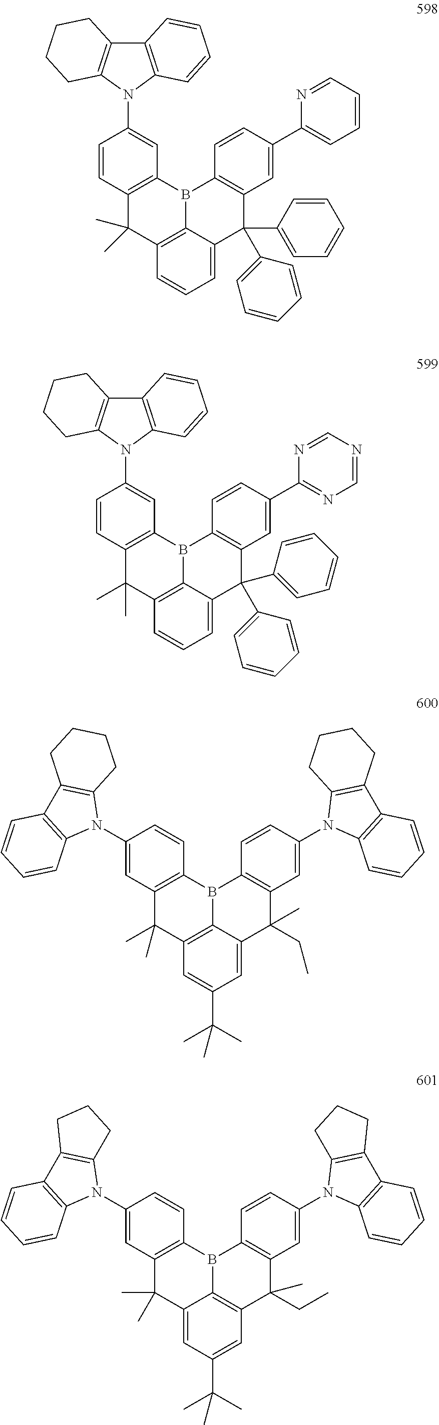 [SMILES: CC1(C)c2ccc(-n3c4c(c5ccccc53)CCCC4)cc2B2c3ccc(-c4ccccn4)cc3C(c3ccccc3)(c3ccccc3)c3cccc1c32 ; CC1(C)c2ccc(-n3c4c(c5ccccc53)CCCC4)cc2B2c3ccc(-c4ncncn4)cc3C(c3ccccc3)(c3ccccc3)c3cccc1c32 ; CCC1(C)c2cc(-n3c4c(c5ccccc53)CCCC4)ccc2B2c3ccc(-n4c5c(c6ccccc64)CCCC5)cc3C(C)(C)c3cc(C(C)(C)C)cc1c32 ; CCC1(C)c2cc(-n3c4c(c5ccccc53)CCC4)ccc2B2c3ccc(-n4c5c(c6ccccc64)CCC5)cc3C(C)(C)c3cc(C(C)(C)C)cc1c32]

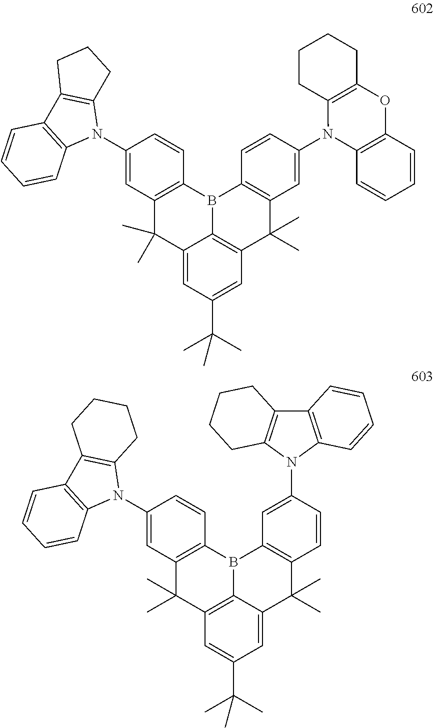

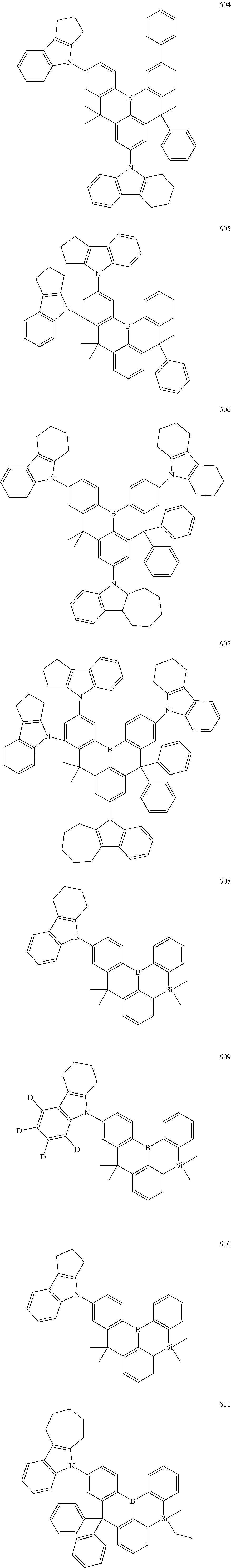

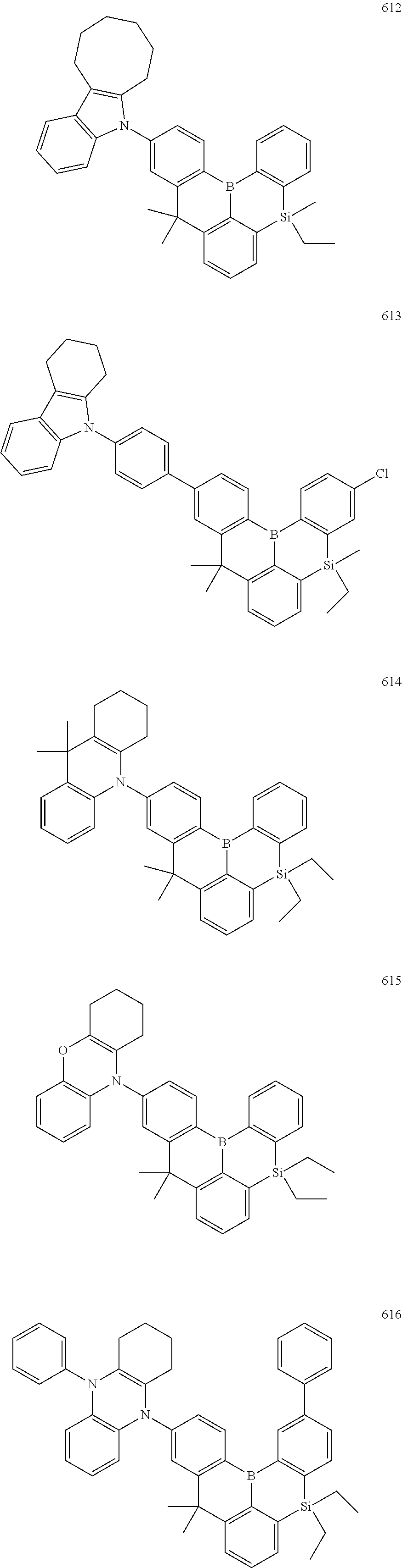

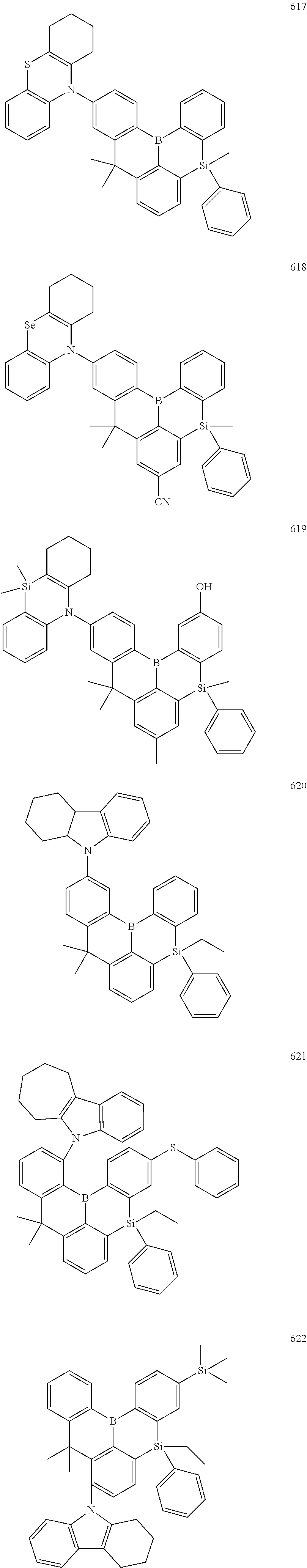

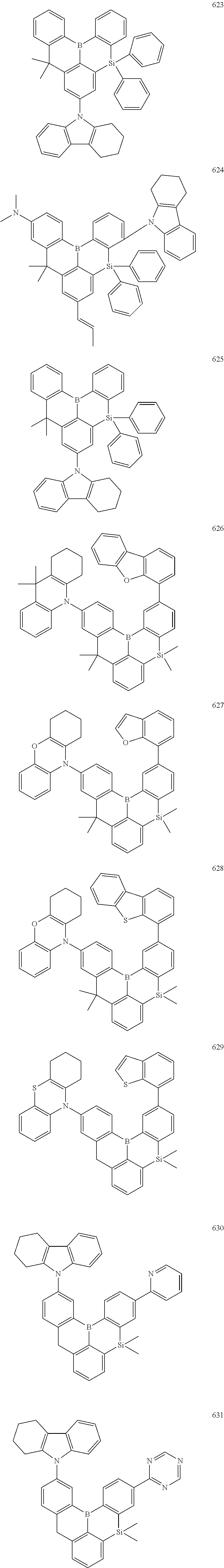

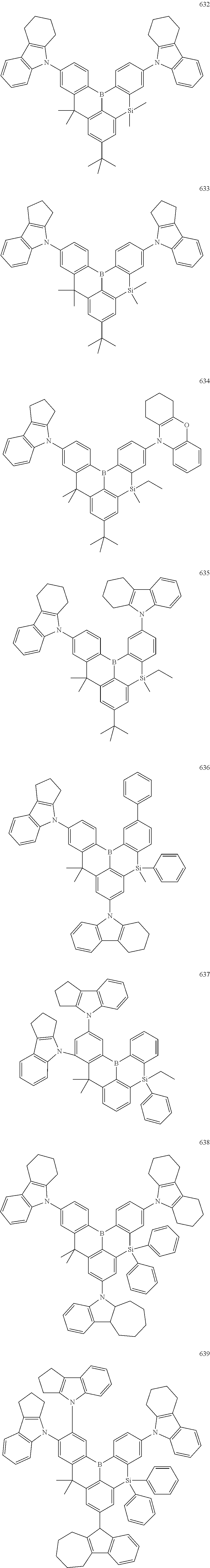

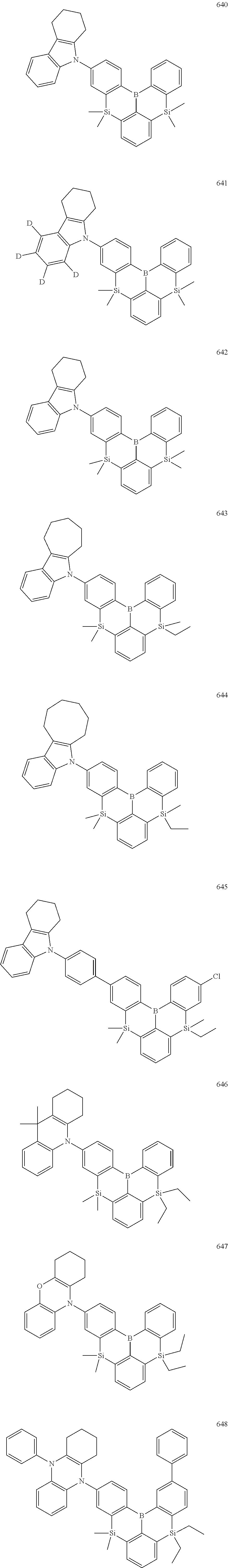

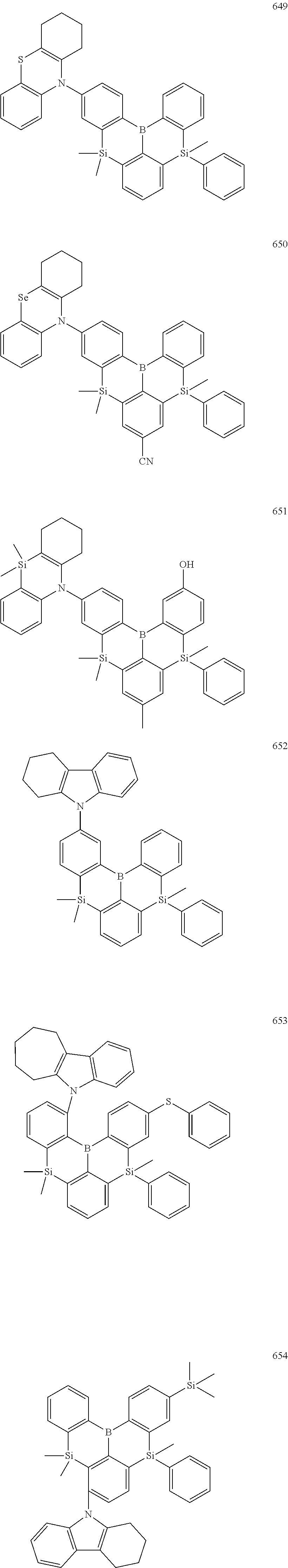

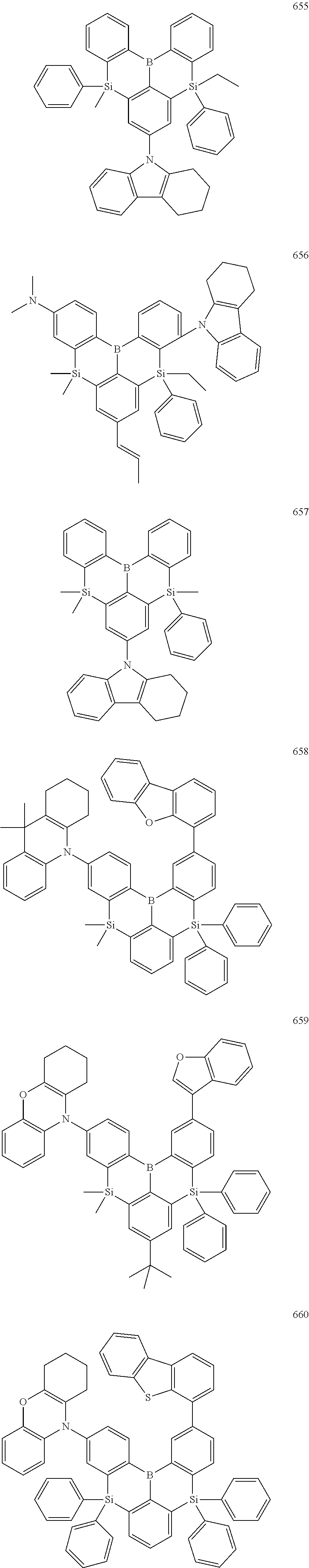

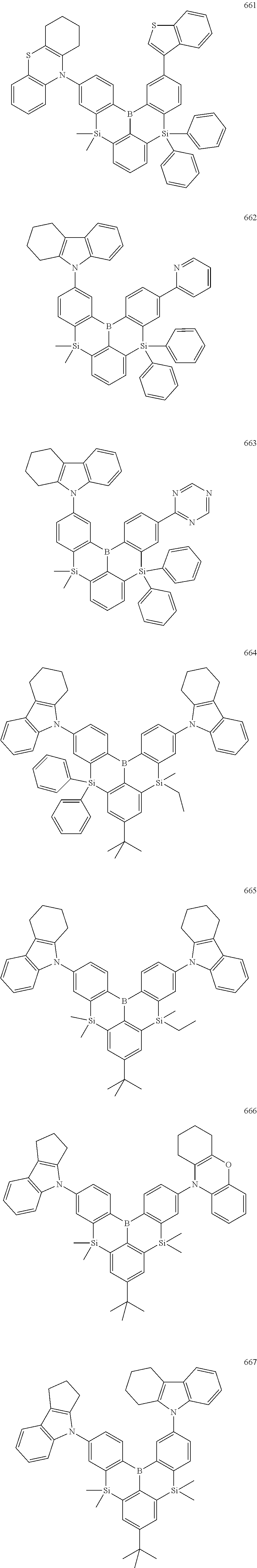

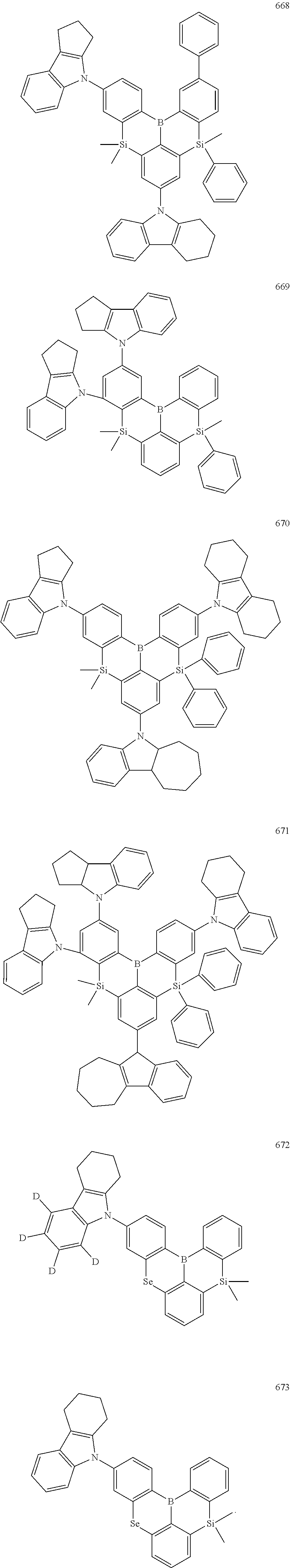

14. A fused polycyclic compound represented by Formula 1: 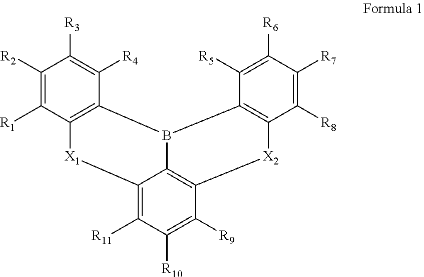
in Formula 1,
X₁ and X₂ are each independently O, S, Se, NR₁₂, CR₁₃R₁₄, or SiR₁₅R₁₆,
R₁ to R₁₆ are each independently a hydrogen atom, a deuterium atom, a halogen atom, a cyano group, a hydroxyl group, a substituted or unsubstituted oxy group, a substituted or unsubstituted thio group, a substituted or unsubstituted silyl group, a substituted or unsubstituted amine group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, a substituted or unsubstituted heteroaryl group of 2 to 30 ring-forming carbon atoms, or a substituent represented by Formula 2, and/or combined with an adjacent group to form a ring,
when each of R₁ to R₁₆ is combined with the adjacent group to form the ring, the ring excludes:
a heterocycle comprising Si in the ring as a ring-forming atom; or
a substituted or unsubstituted benzothiophene moiety, and
at least one selected from among R₁ to R₁₁ is represented by Formula 2: 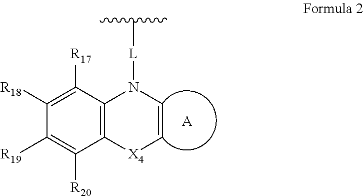
in Formula 2,
L is a direct linkage, or a substituted or unsubstituted arylene group of 6 to 30 ring-forming carbon atoms,
X₃ is a direct linkage, O, S, Se, NR₂₁, CR₂₂R₂₃, or SiR₂₄R₂₅,
R₁₇ to R₂₅ are each independently a hydrogen atom, a deuterium atom, a halogen atom, a cyano group, a hydroxyl group, a substituted or unsubstituted oxy group, a substituted or unsubstituted thio group, a substituted or unsubstituted silyl group, a substituted or unsubstituted amine group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, and/or combined with an adjacent group to form a ring,
“ 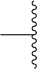
” is a position connected with Formula 1, and
A is represented by Formula 3: 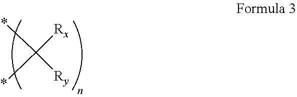
in Formula 3,
Rₓ and R_{y} are each independently a hydrogen atom, a deuterium atom, a halogen atom, a cyano group, a hydroxyl group, a substituted or unsubstituted oxy group, a substituted or unsubstituted thio group, a substituted or unsubstituted silyl group, a substituted or unsubstituted amine group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, and/or combined with an adjacent group to form a ring,
“n” is an integer of 3 to 6, and
“—*” is a position connected with Formula 2.

15. The fused polycyclic compound of claim 14, wherein the substituent represented by Formula 2 is represented by any one selected from among Formula 2-1-1 to Formula 2-1-4: 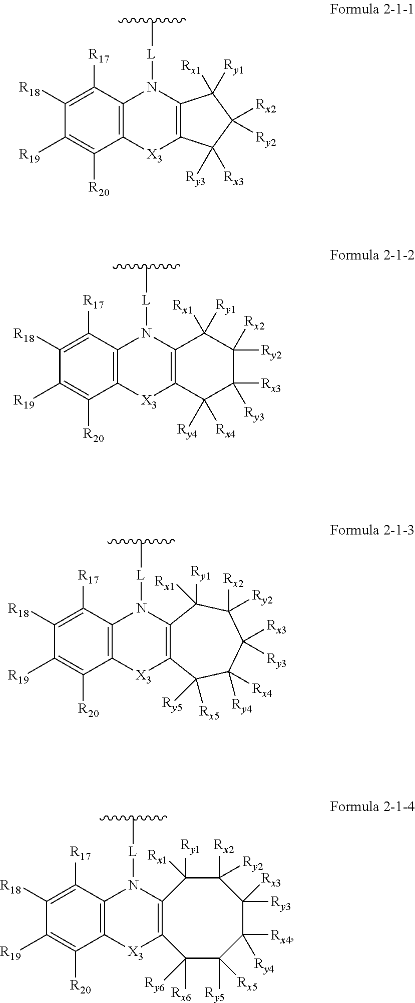
and
in Formula 2-1-1 to Formula 2-1-4,
Rₓ₁ to Rₓ₆, and R_{y1} to R_{y6} are each independently a hydrogen atom, a deuterium atom, a halogen atom, a cyano group, a hydroxyl group, a substituted or unsubstituted oxy group, a substituted or unsubstituted thio group, a substituted or unsubstituted silyl group, a substituted or unsubstituted amine group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, and/or combined with an adjacent group to form a ring, and
L, X₃, and R₁₇ to R₂₀ are as defined in Formula 2.

16. The fused polycyclic compound of claim 14, wherein the substituent represented by Formula 2 is represented by any one selected from among Formula 2-2-1 to Formula 2-2-7: 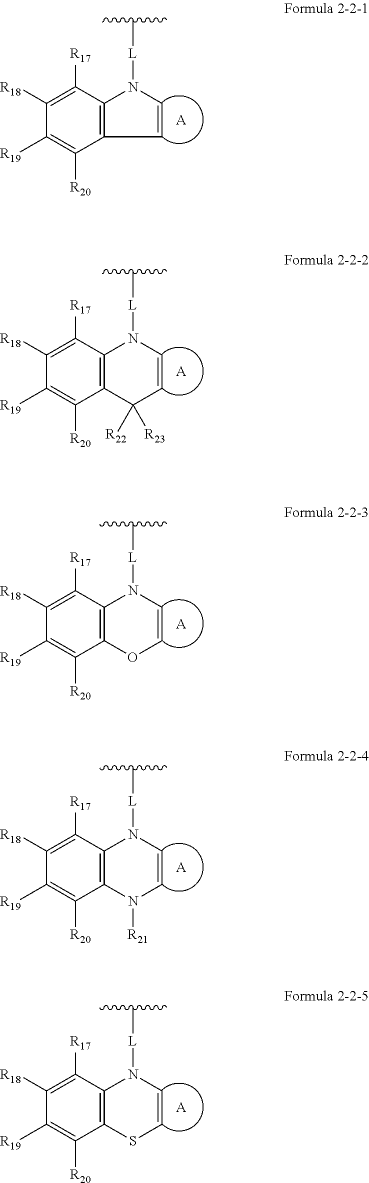 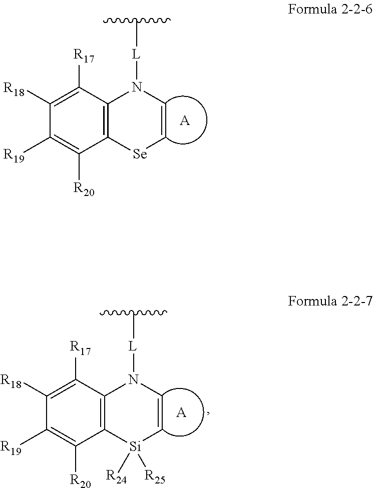
and
in Formula 2-2-1 to Formula 2-2-7,
L, R₁₇ to R₂₅, and A are as defined in Formula 2.

17. The fused polycyclic compound of claim 14, wherein the fused polycyclic compound represented by Formula 1 is represented by any one selected from among Formula 1-1-1 to Formula 1-1-3: 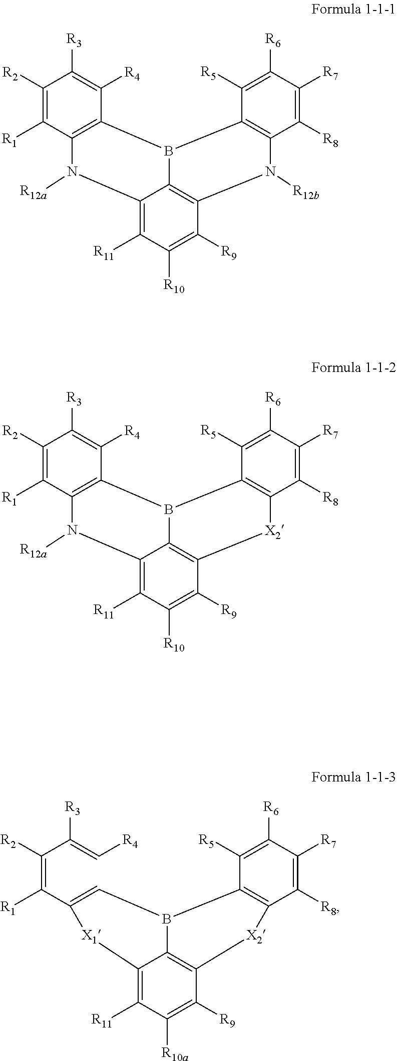
and
in Formula 1-1-1 to Formula 1-1-3,
X₁′ and X₂′ are each independently O, S, Se, CR₂₈R₂₇, or SiR₂₈R₂₉,
R₂₆ to R₂₉ are each independently a hydrogen atom, a deuterium atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, and/or combined with an adjacent group to form a ring,
R₁₂ₐ and R_{12b} are each independently a substituted or unsubstituted aryl group of 6 to 30 ring-forming carbon atoms, or a substituted or unsubstituted heteroaryl group of 2 to 30 ring-forming carbon atoms, and/or combined with an adjacent group to form a ring, and
R₁ to R₁₁ are as defined in Formula 1.

18. The fused polycyclic compound of claim 14, wherein the fused polycyclic compound represented by Formula 1 is represented by Formula 1-2-1 or Formula 1-2-2: 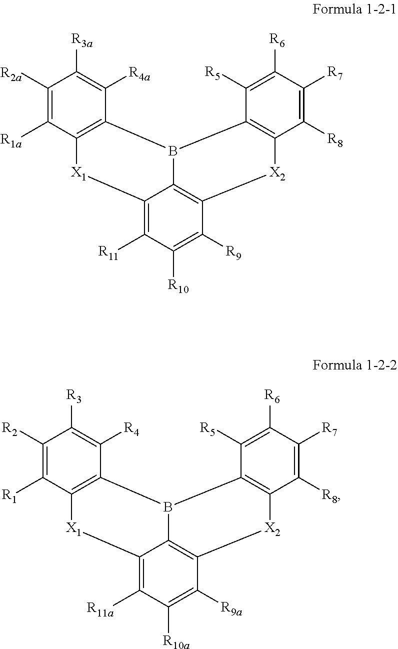
and
in Formula 1-2-1 and Formula 1-2-2,
R₁ₐ to R₄ₐ, and R₉ₐ to R₁₁ₐ are each independently a hydrogen atom, a deuterium atom, a halogen atom, a cyano group, a hydroxyl group, a substituted or unsubstituted oxy group, a substituted or unsubstituted thio group, a substituted or unsubstituted silyl group, a substituted or unsubstituted amine group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, a substituted or unsubstituted heteroaryl group of 2 to 30 ring-forming carbon atoms, or the substituent represented by Formula 2, and/or combined with an adjacent group to form a ring,
in Formula 1-2-1,
at least one selected from among R₁ₐ to R₄ₐ is represented by Formula 2,
in Formula 1-2-2,
at least one selected from among Rea to R₁₁ₐ is represented by Formula 2, and
in Formula 1-2-1 and Formula 1-2-2,
X₁, X₂, and R₁ to R₁₁ are as defined in Formula 1.

19. The fused polycyclic compound of claim 14, wherein the fused polycyclic compound represented by Formula 1 is represented by any one selected from among Formula 1-3-1 to Formula 1-3-3: 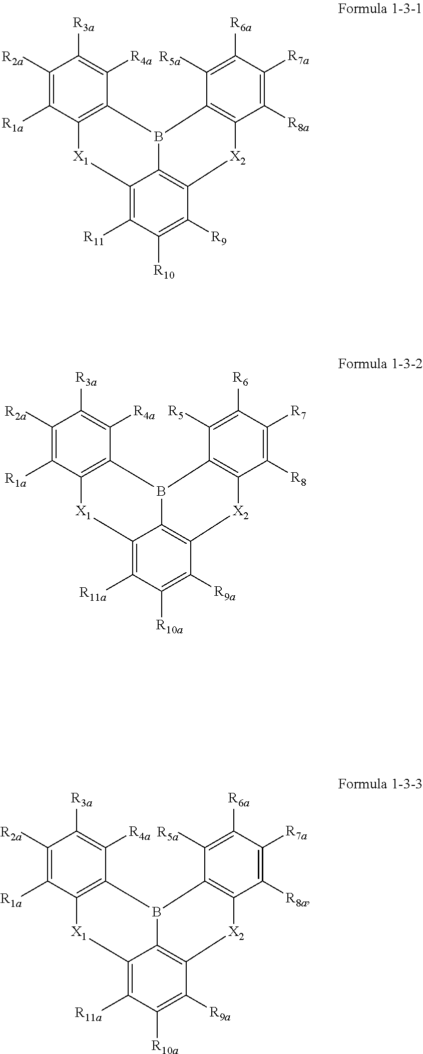
and
in Formula 1-3-1 to Formula 1-3-1,
R₁ₐ to R₁₁ₐ are each independently a hydrogen atom, a deuterium atom, a halogen atom, a cyano group, a hydroxyl group, a substituted or unsubstituted oxy group, a substituted or unsubstituted thio group, a substituted or unsubstituted silyl group, a substituted or unsubstituted amine group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, a substituted or unsubstituted heteroaryl group of 2 to 30 ring-forming carbon atoms, or the substituent represented by Formula 2, and/or combined with an adjacent group to form a ring,
in Formula 1-3-1,
at least one selected from among R₁ₐ to R₄ₐ, and at least one selected from among R₅ₐ to R₈ₐ are represented by Formula 2,
in Formula 1-3-2,
at least one selected from among R₁ₐ to R₄ₐ, and at least one selected from among R₉ₐ to R₁₁ₐ are represented by Formula 2,
in Formula 1-3-3,
at least one selected from among R₁ₐ to R₄ₐ, at least one selected from among R₅ₐ to R₈ₐ, and at least one selected from among R₉ₐ to R₁₁ₐ are represented by Formula 2, and
in Formula 1-3-1 to Formula 1-3-3,
X₁, X₂, and R₅ to R₁₁ are as defined in Formula 1.

20. The fused polycyclic compound of claim 14, wherein the fused polycyclic compound represented by Formula 1 is represented by Formula 1-4-1 or Formula 1-4-2: 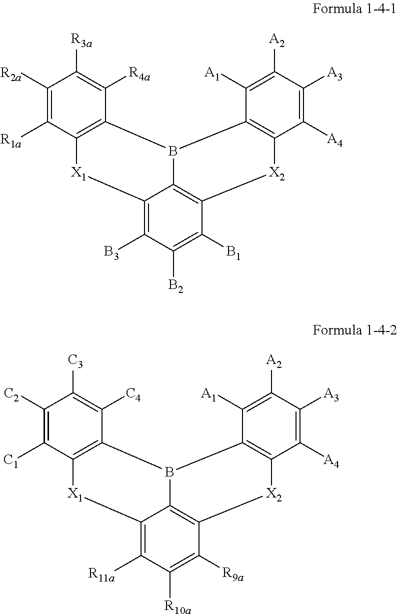
in Formula 1-4-1 and Formula 1-4-2,
A₁ to A₄, B₁ to B₃, and C₁ to C₄ are each independently a hydrogen atom, a deuterium atom, a substituted or unsubstituted alkyl group of 1 to 10 carbon atoms, or the substituent represented by Formula 2, or a substituent represented by Formula C1,
R₁ₐ to R₄ₐ, and Rea to R₁₁ₐ are each independently a hydrogen atom, a deuterium atom, a halogen atom, a cyano group, a hydroxyl group, a substituted or unsubstituted oxy group, a substituted or unsubstituted thio group, a substituted or unsubstituted silyl group, a substituted or unsubstituted amine group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, a substituted or unsubstituted heteroaryl group of 2 to 30 ring-forming carbon atoms, or the substituent represented by Formula 2, and/or combined with an adjacent group to form a ring,
in Formula 1-4-1,
at least one selected from among R₁ₐ to R₄ₐ is represented by Formula 2,
in Formula 1-4-2,
at least one selected from among R₉ₐ to R₁₁ₐ is represented by Formula 2, 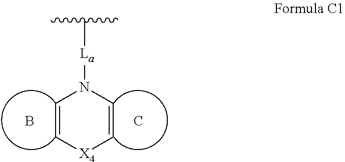
in Formula C1,
Lₐ is a direct linkage, or a substituted or unsubstituted arylene group of 6 to 30 ring-forming carbon atoms,
X₄ is a direct linkage, O, S, Se, NR₃₁, CR₃₂R₃₃, or SiR₃₄R₃₅,
R₃₁ to R₃₅ are each independently a hydrogen atom, a deuterium atom, a halogen atom, a cyano group, a hydroxyl group, a substituted or unsubstituted oxy group, a substituted or unsubstituted thio group, a substituted or unsubstituted silyl group, a substituted or unsubstituted amine group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, and/or combined with an adjacent group to form a ring, and
B and C are each independently represented by Formula C2: 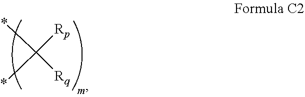
and
in Formula C2,
Rₚ and R_{q} are each independently a hydrogen atom, a deuterium atom, a halogen atom, a cyano group, a hydroxyl group, a substituted or unsubstituted oxy group, a substituted or unsubstituted thio group, a substituted or unsubstituted silyl group, a substituted or unsubstituted amine group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, and/or combined with an adjacent group to form a ring, and
“m” is an integer of 3 to 6, and
in Formula 1-4-1 and Formula 1-4-2,
X₁ and X₂ are as defined in Formula 1.

21. The fused polycyclic compound of claim 14, wherein the fused polycyclic compound comprises at least one selected from among compounds in Compound Group 1:
Compound Group 1 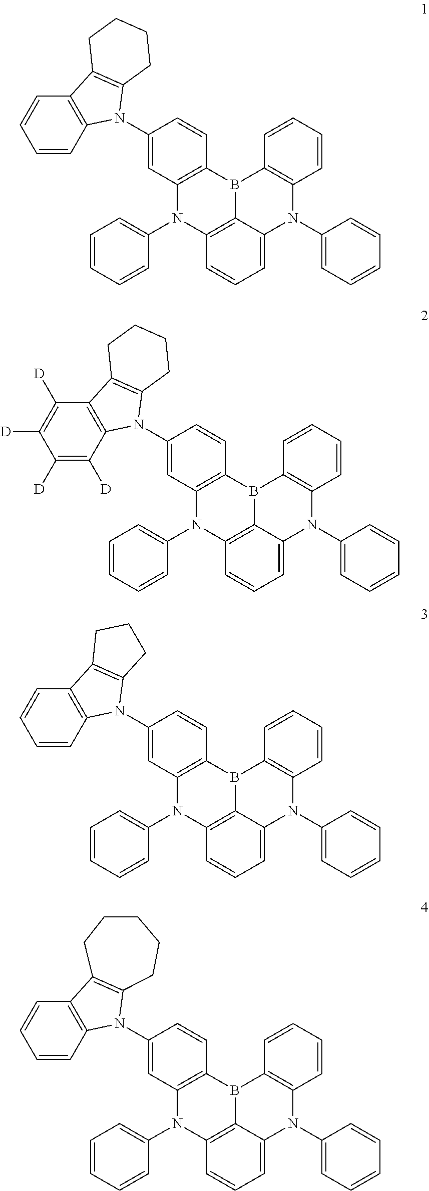 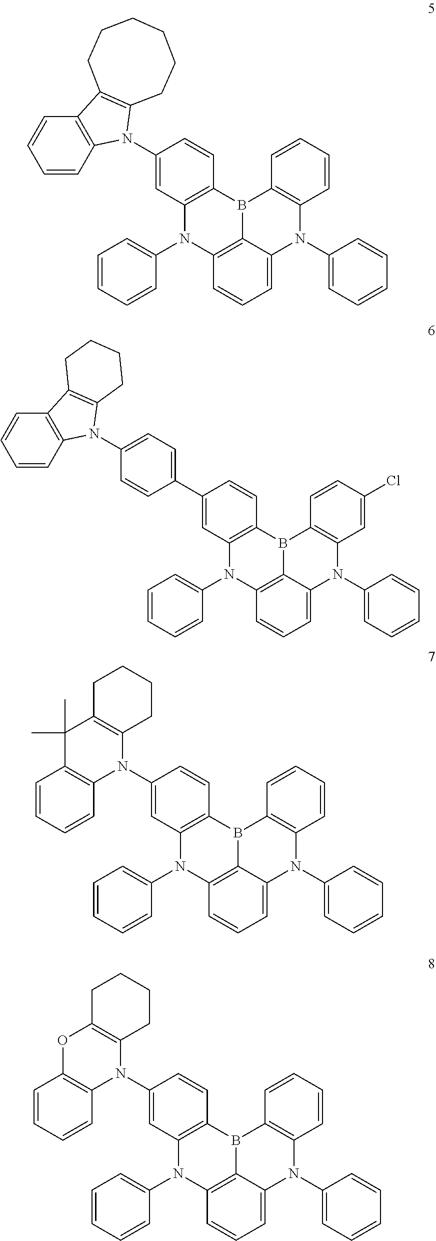 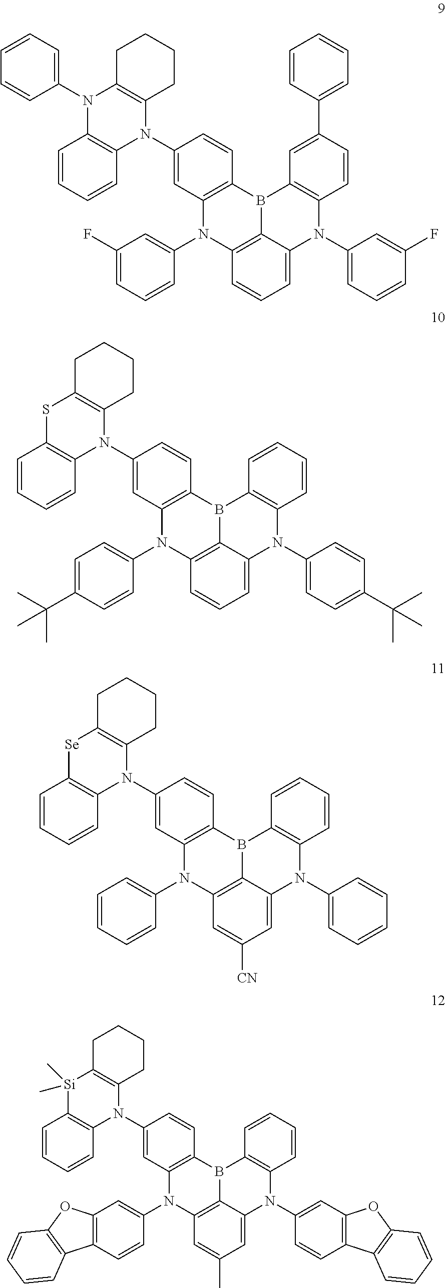 [SMILES: Fc1cccc(N2c3ccc(-c4ccccc4)cc3B3c4ccc(N5C6=C(CCCC6)N(c6ccccc6)c6ccccc65)cc4N(c4cccc(F)c4)c4cccc2c43)c1 ; CC(C)(C)c1ccc(N2c3ccccc3B3c4ccc(N5C6=C(CCCC6)Sc6ccccc65)cc4N(c4ccc(C(C)(C)C)cc4)c4cccc2c43)cc1 ; N#Cc1cc2c3c(c1)N(c1ccccc1)c1cc(N4C5=C(CCCC5)[Se]c5ccccc54)ccc1B3c1ccccc1N2c1ccccc1 ; Cc1cc2c3c(c1)N(c1ccc4c(c1)oc1ccccc14)c1cc(N4C5=C(CCCC5)[Si](C)(C)c5ccccc54)ccc1B3c1ccccc1N2c1ccc2c(c1)oc1ccccc12] 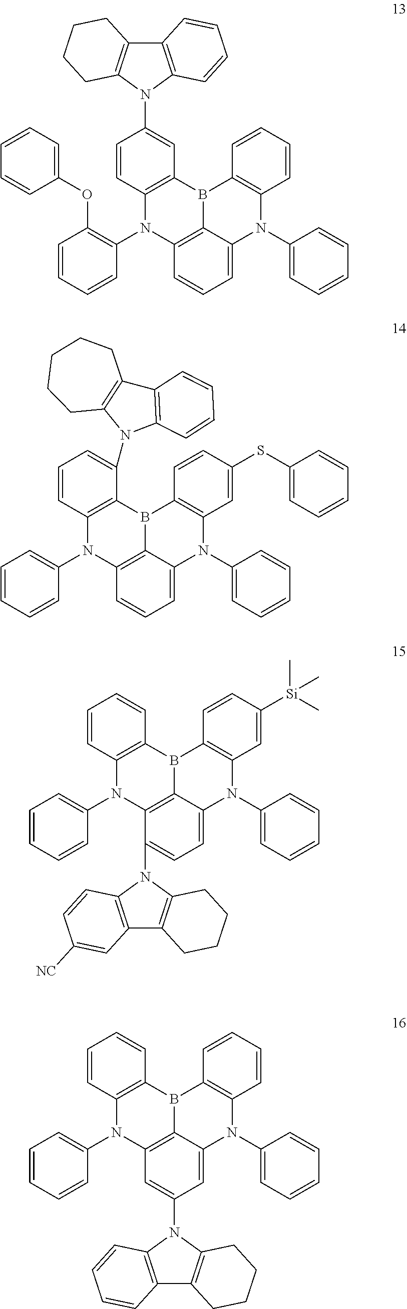 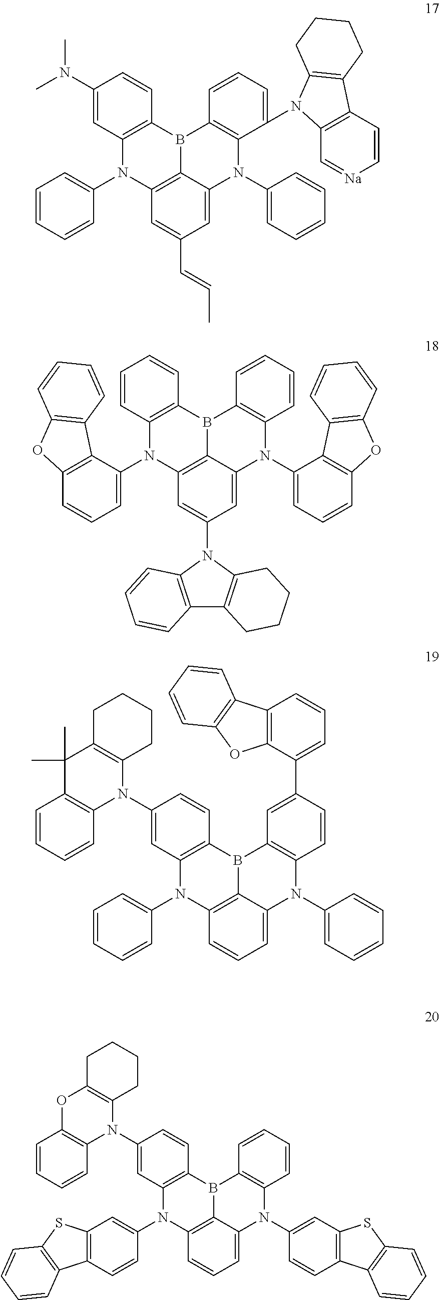 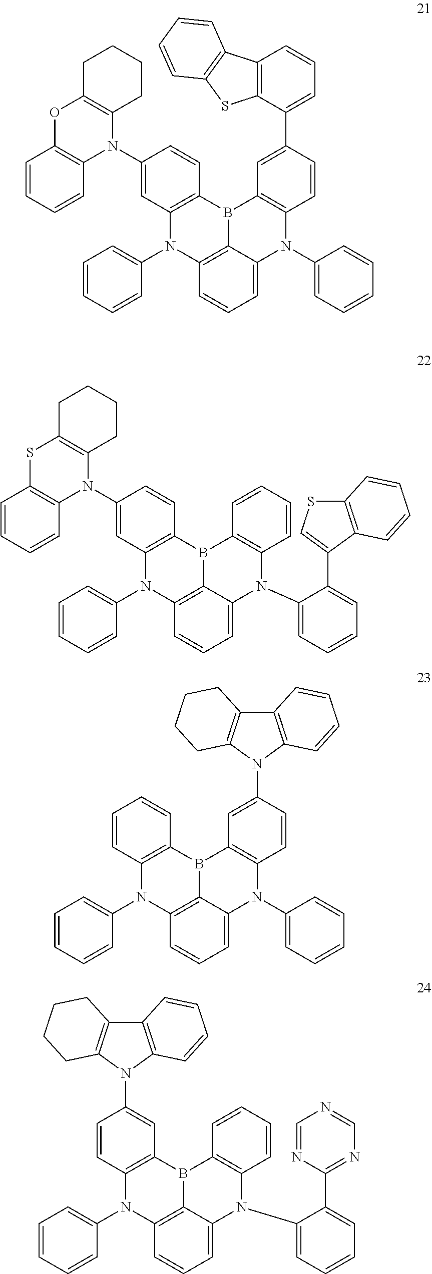 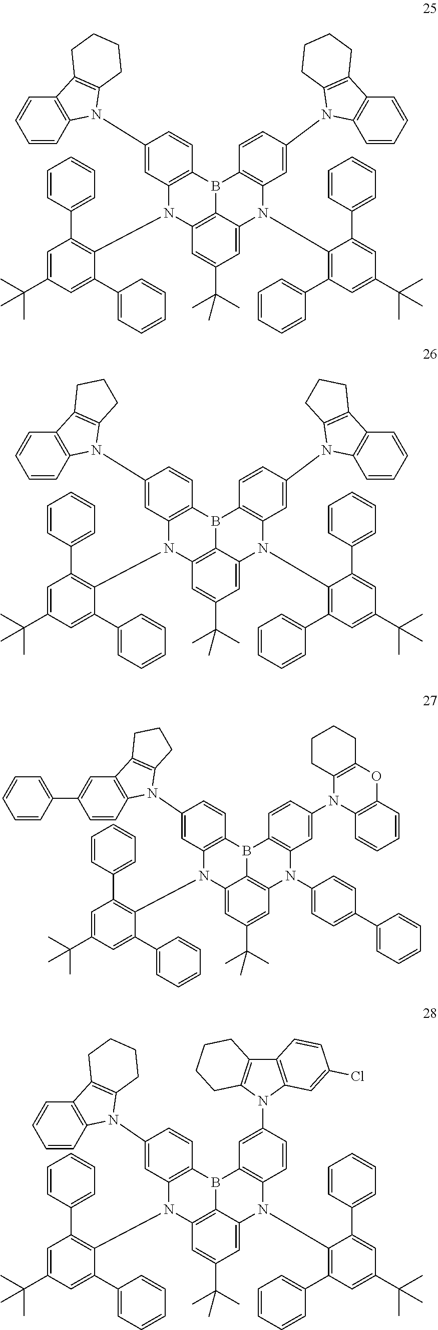 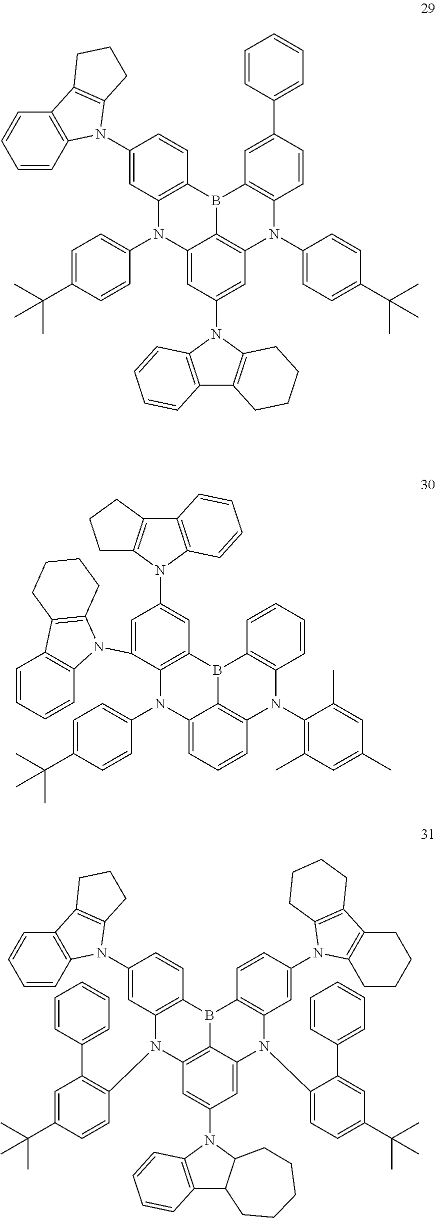 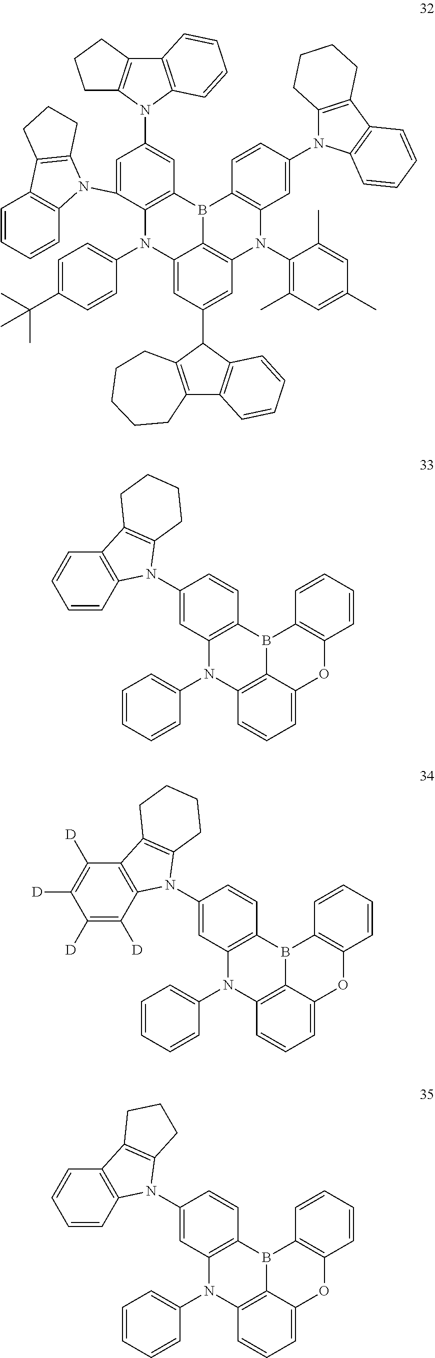 [SMILES: Cc1cc(C)c(N2c3cc(-n4c5c(c6ccccc64)CCCC5)ccc3B3c4cc(-n5c6c(c7ccccc75)CCC6)cc(-n5c6c(c7ccccc75)CCC6)c4N(c4ccc(C(C)(C)C)cc4)c4cc(C5C6=C(CCCCC6)c6ccccc65)cc2c43)c(C)c1 ; c1ccc(N2c3cc(-n4c5c(c6ccccc64)CCCC5)ccc3B3c4ccccc4Oc4cccc2c43)cc1 ; [2H]c1c([2H])c([2H])c2c(c1[2H])c1c(n2-c2ccc3c(c2)N(c2ccccc2)c2cccc4c2B3c2ccccc2O4)CCCC1 ; c1ccc(N2c3cc(-n4c5c(c6ccccc64)CCC5)ccc3B3c4ccccc4Oc4cccc2c43)cc1] 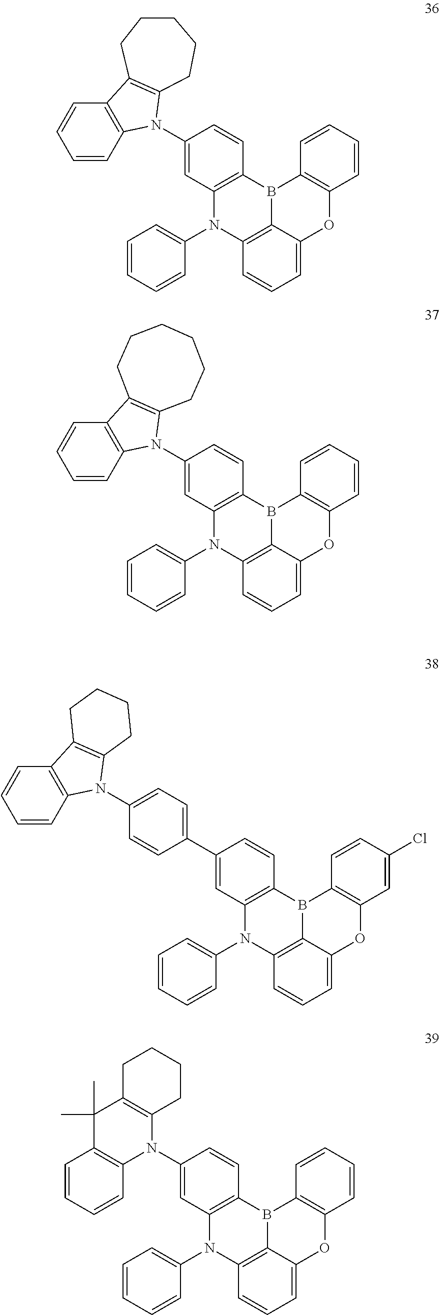 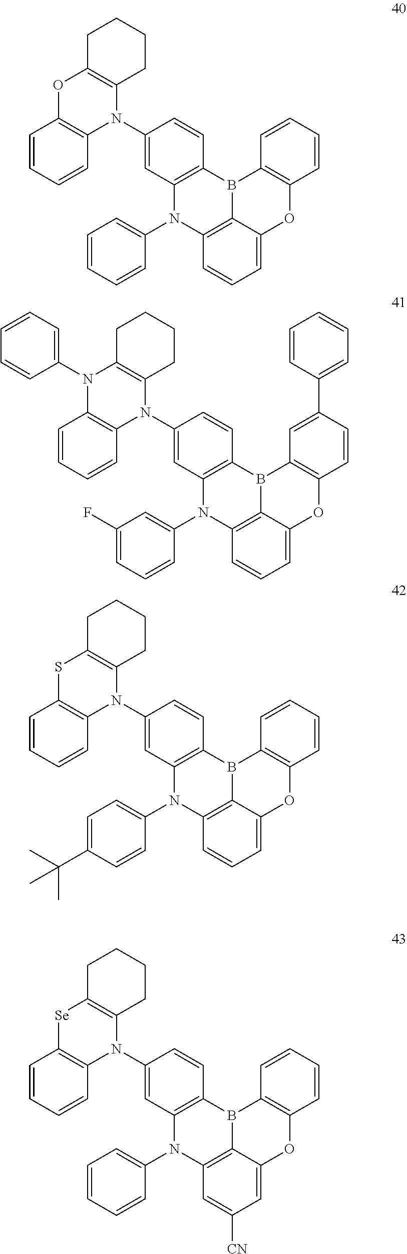 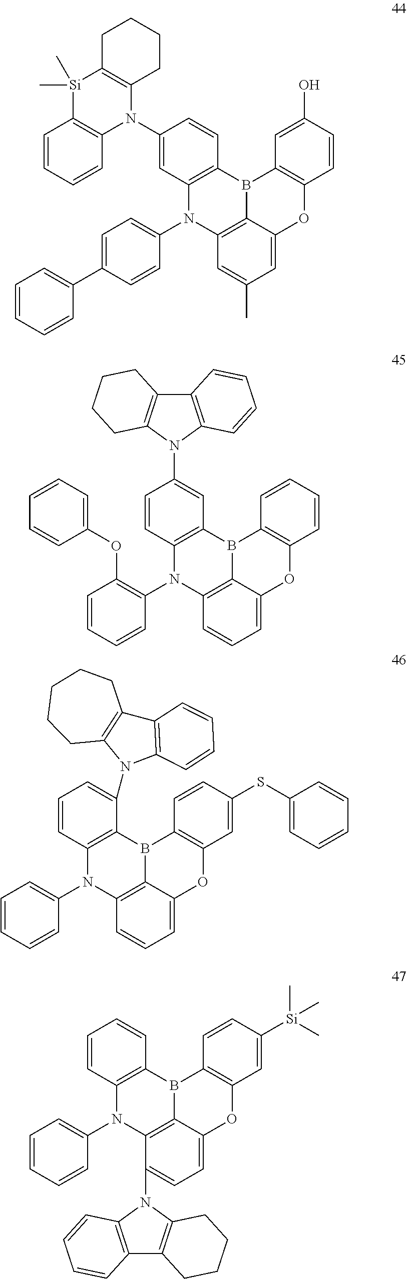 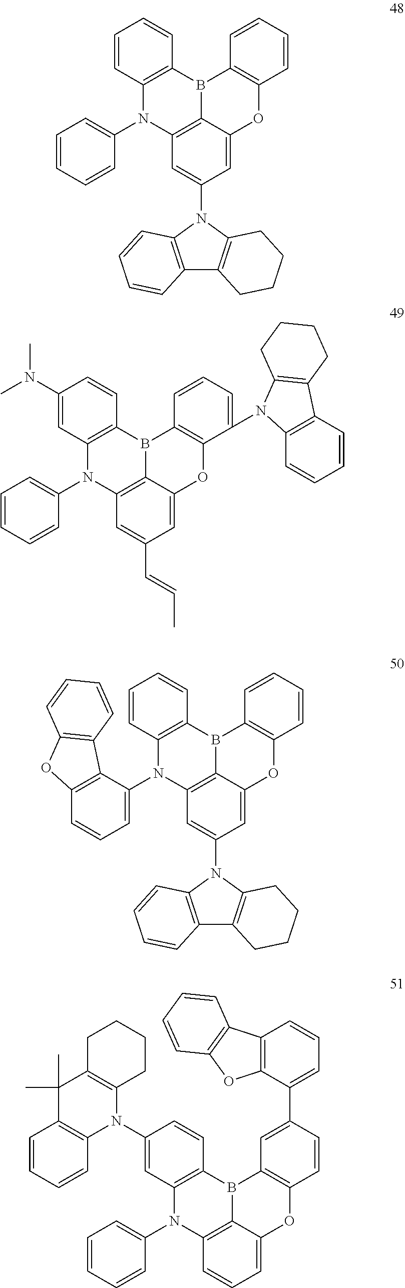 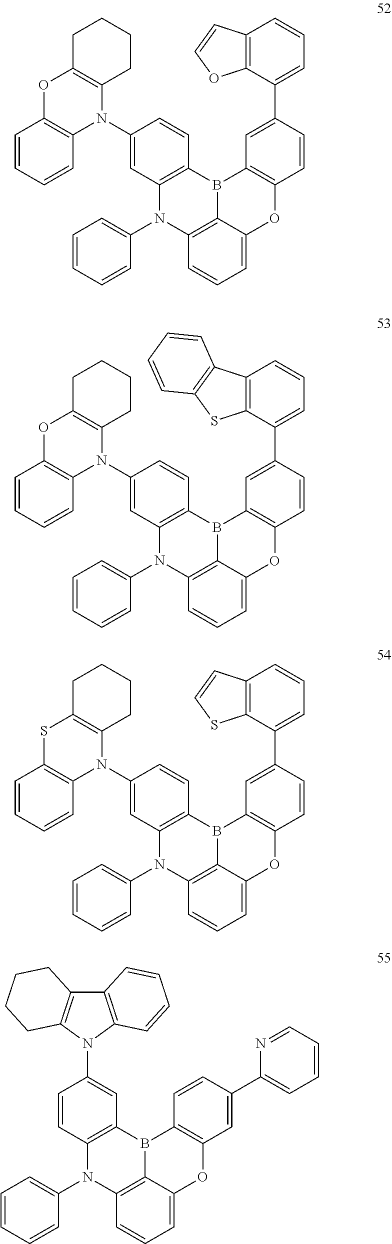 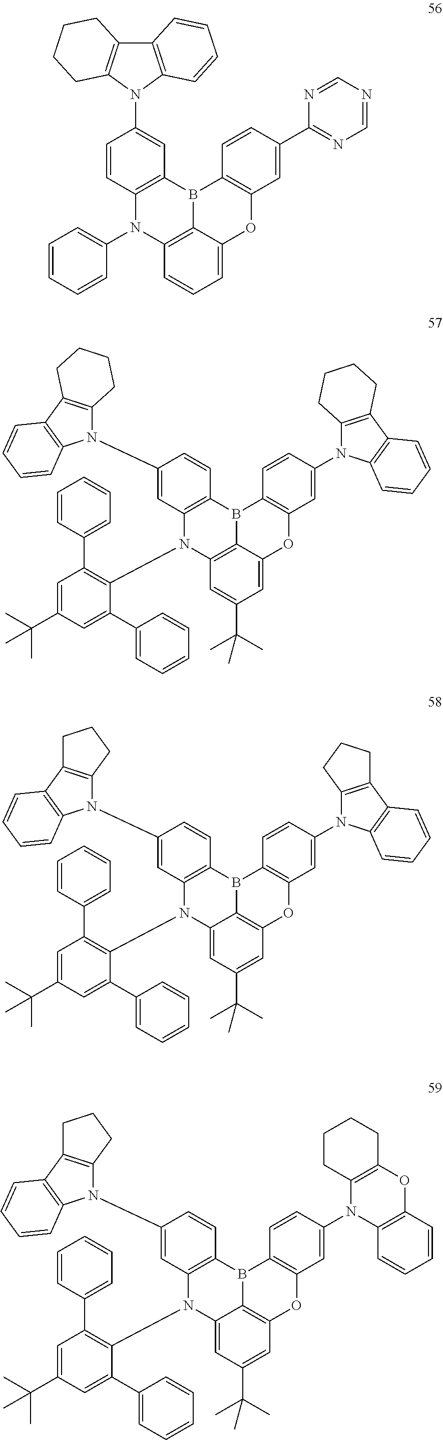 [SMILES: c1ccc(N2c3ccc(-n4c5c(c6ccccc64)CCCC5)cc3B3c4ccc(-c5ncncn5)cc4Oc4cccc2c43)cc1 ; CC(C)(C)c1cc(-c2ccccc2)c(N2c3cc(-n4c5c(c6ccccc64)CCCC5)ccc3B3c4ccc(-n5c6c(c7ccccc75)CCCC6)cc4Oc4cc(C(C)(C)C)cc2c43)c(-c2ccccc2)c1 ; CC(C)(C)c1cc(-c2ccccc2)c(N2c3cc(-n4c5c(c6ccccc64)CCC5)ccc3B3c4ccc(-n5c6c(c7ccccc75)CCC6)cc4Oc4cc(C(C)(C)C)cc2c43)c(-c2ccccc2)c1 ; CC(C)(C)c1cc(-c2ccccc2)c(N2c3cc(-n4c5c(c6ccccc64)CCC5)ccc3B3c4ccc(N5C6=C(CCCC6)Oc6ccccc65)cc4Oc4cc(C(C)(C)C)cc2c43)c(-c2ccccc2)c1] 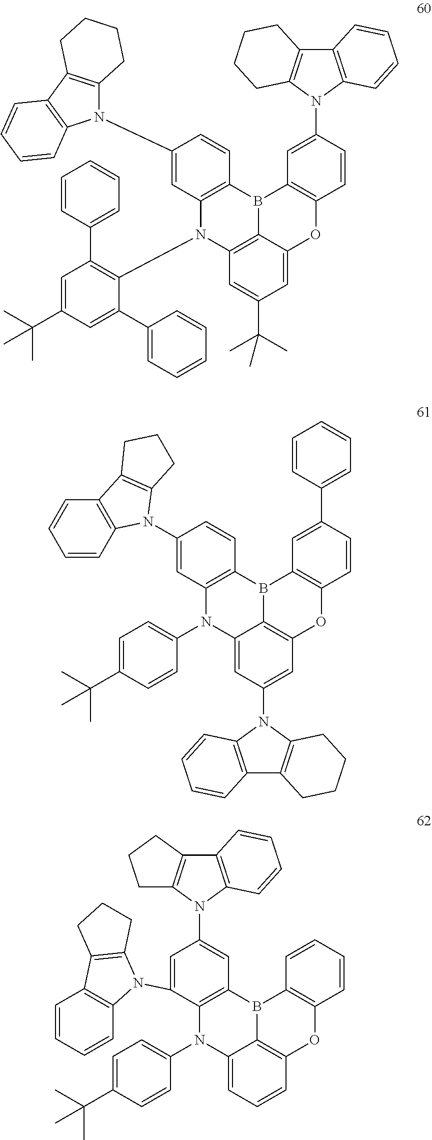 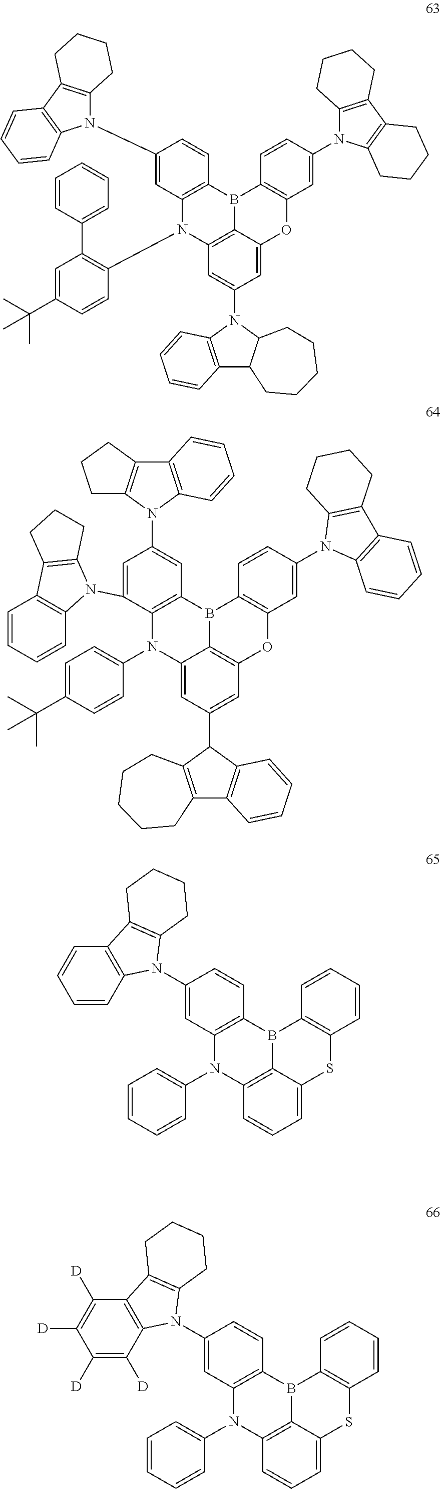 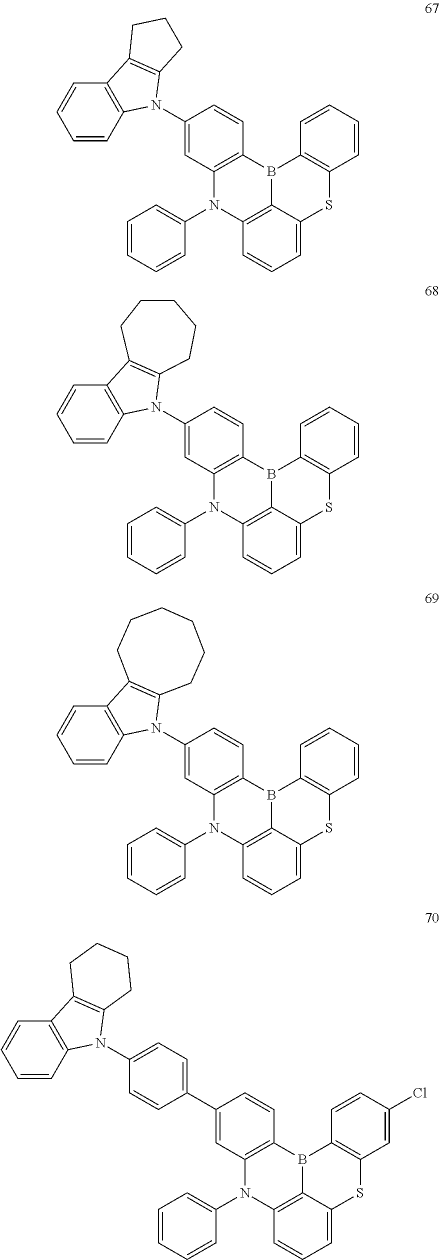 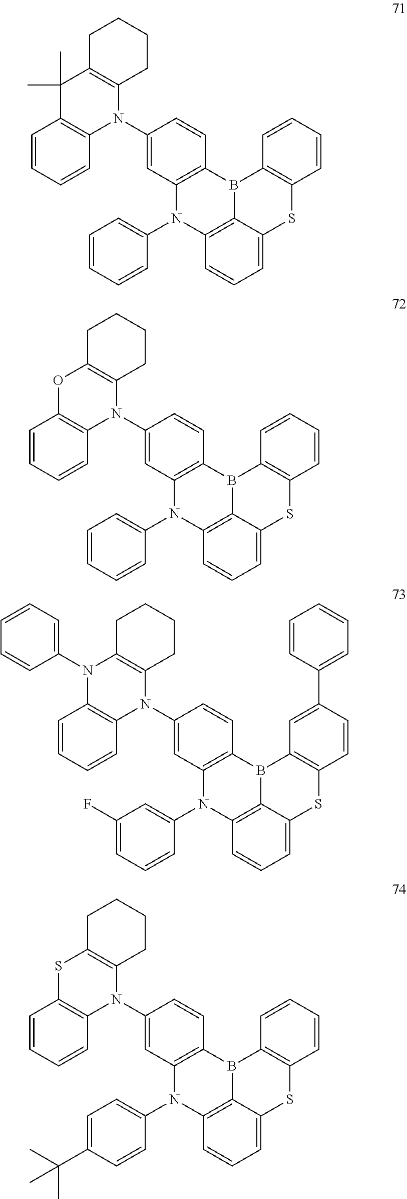 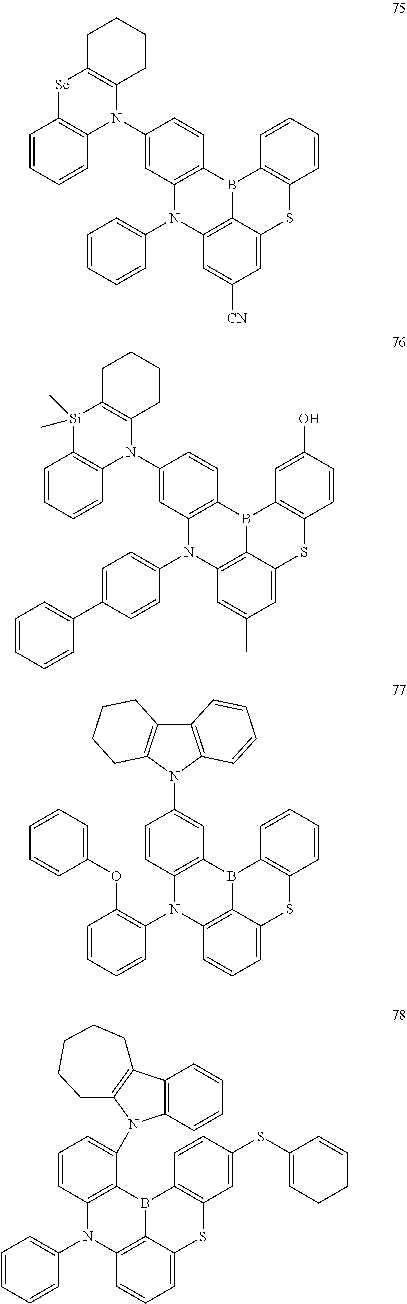 [SMILES: N#Cc1cc2c3c(c1)N(c1ccccc1)c1cc(N4C5=C(CCCC5)[Se]c5ccccc54)ccc1B3c1ccccc1S2 ; Cc1cc2c3c(c1)N(c1ccc(-c4ccccc4)cc1)c1cc(N4C5=C(CCCC5)[Si](C)(C)c5ccccc54)ccc1B3c1cc(O)ccc1S2 ; c1ccc(Oc2ccccc2N2c3ccc(-n4c5c(c6ccccc64)CCCC5)cc3B3c4ccccc4Sc4cccc2c43)cc1 ; C1=CC(Sc2ccc3c(c2)Sc2cccc4c2B3c2c(cccc2-n2c3c(c5ccccc52)CCCCC3)N4c2ccccc2)=CCC1] 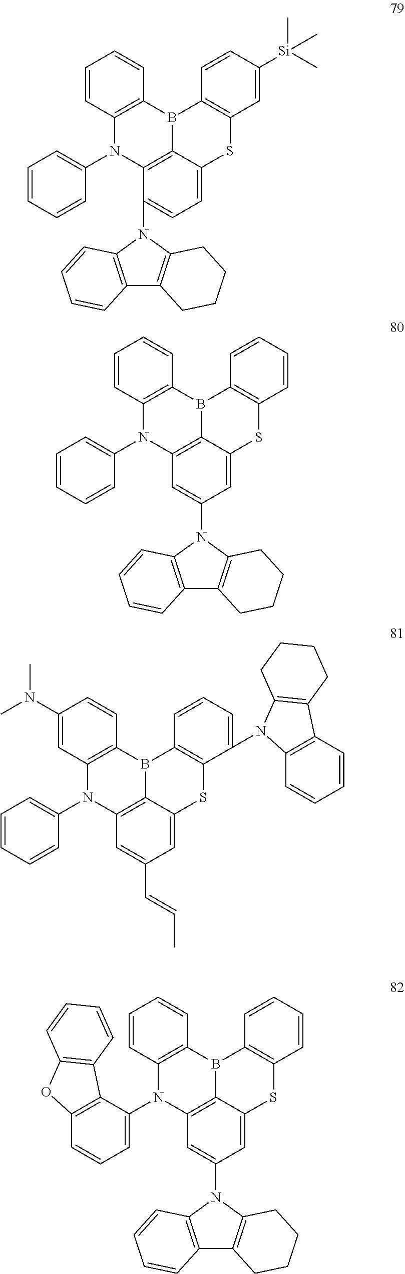 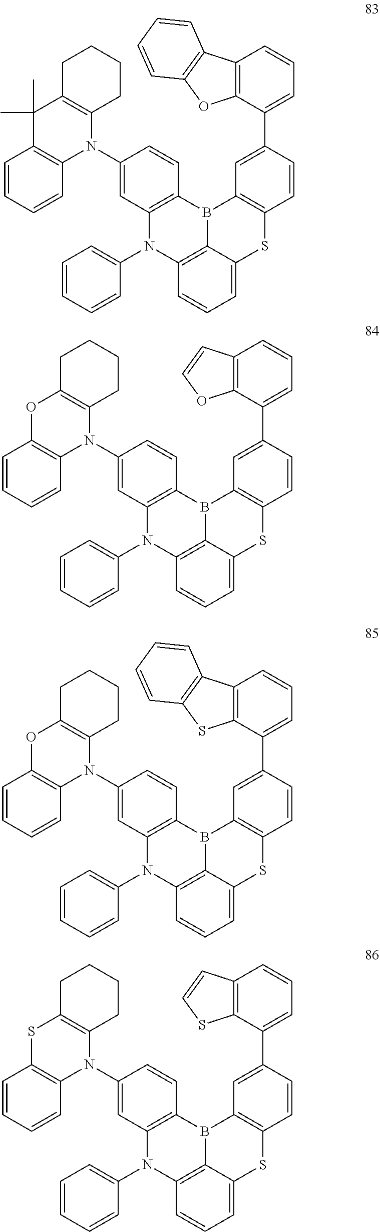 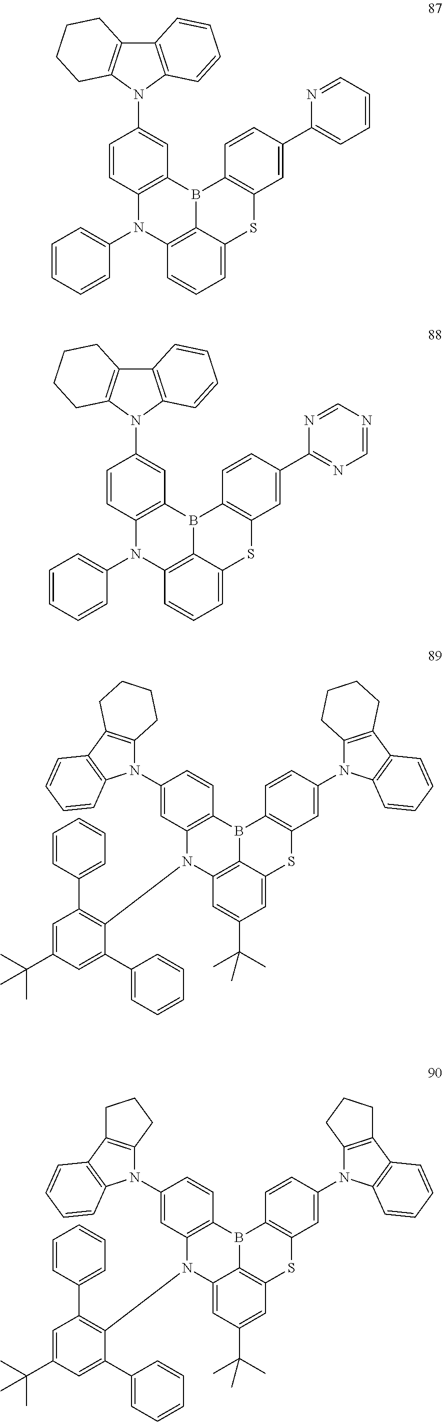 [SMILES: c1ccc(N2c3ccc(-n4c5c(c6ccccc64)CCCC5)cc3B3c4ccc(-c5ccccn5)cc4Sc4cccc2c43)cc1 ; c1ccc(N2c3ccc(-n4c5c(c6ccccc64)CCCC5)cc3B3c4ccc(-c5ncncn5)cc4Sc4cccc2c43)cc1 ; CC(C)(C)c1cc(-c2ccccc2)c(N2c3cc(-n4c5c(c6ccccc64)CCCC5)ccc3B3c4ccc(-n5c6c(c7ccccc75)CCCC6)cc4Sc4cc(C(C)(C)C)cc2c43)c(-c2ccccc2)c1 ; CC(C)(C)c1cc(-c2ccccc2)c(N2c3cc(-n4c5c(c6ccccc64)CCC5)ccc3B3c4ccc(-n5c6c(c7ccccc75)CCC6)cc4Sc4cc(C(C)(C)C)cc2c43)c(-c2ccccc2)c1] 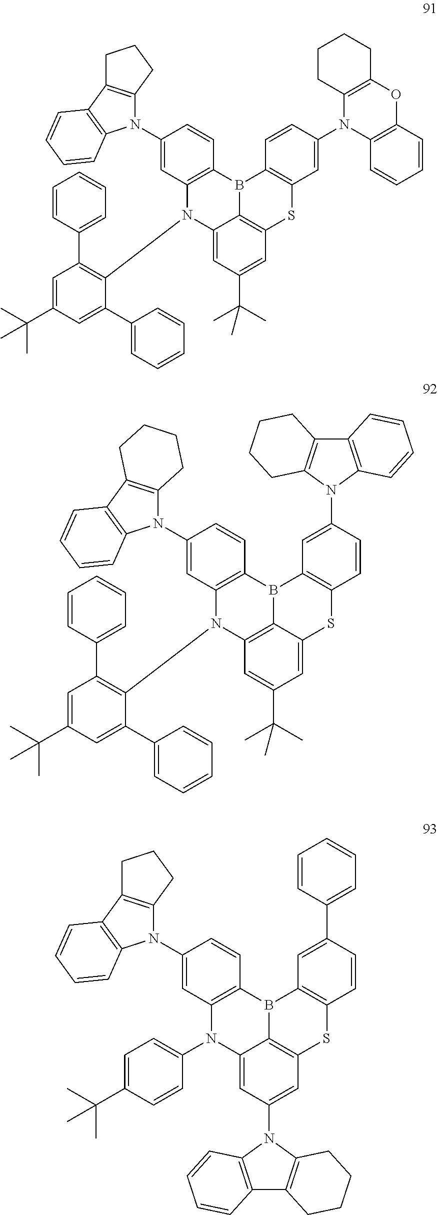 [SMILES: CC(C)(C)c1cc(-c2ccccc2)c(N2c3cc(-n4c5c(c6ccccc64)CCC5)ccc3B3c4ccc(N5C6=C(CCCC6)Oc6ccccc65)cc4Sc4cc(C(C)(C)C)cc2c43)c(-c2ccccc2)c1 ; CC(C)(C)c1cc(-c2ccccc2)c(N2c3cc(-n4c5c(c6ccccc64)CCCC5)ccc3B3c4cc(-n5c6c(c7ccccc75)CCCC6)ccc4Sc4cc(C(C)(C)C)cc2c43)c(-c2ccccc2)c1 ; CC(C)(C)c1ccc(N2c3cc(-n4c5c(c6ccccc64)CCC5)ccc3B3c4cc(-c5ccccc5)ccc4Sc4cc(-n5c6c(c7ccccc75)CCCC6)cc2c43)cc1] 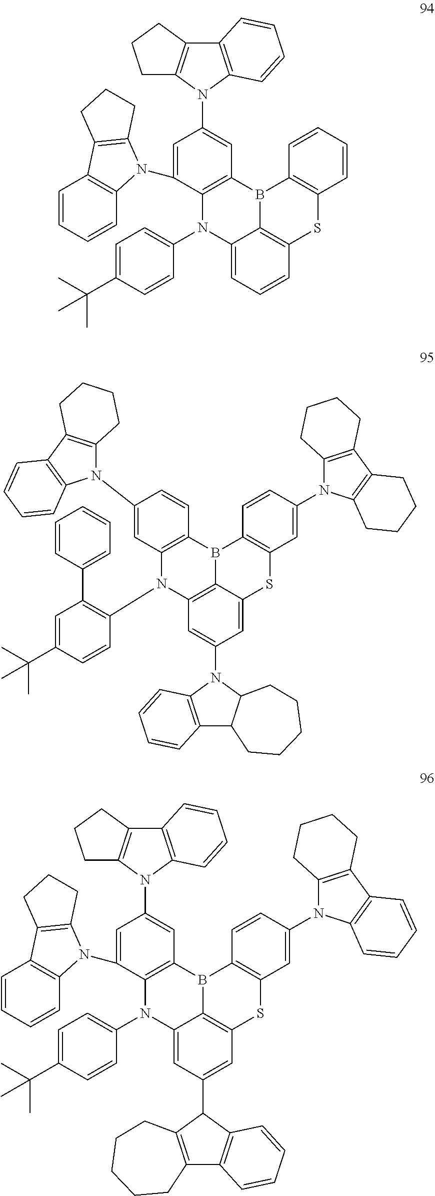 [SMILES: CC(C)(C)c1ccc(N2c3cccc4c3B(c3ccccc3S4)c3cc(-n4c5c(c6ccccc64)CCC5)cc(-n4c5c(c6ccccc64)CCC5)c32)cc1 ; CC(C)(C)c1ccc(N2c3cc(-n4c5c(c6ccccc64)CCCC5)ccc3B3c4ccc(-n5c6c(c7c5CCCC7)CCCC6)cc4Sc4cc(N5c6ccccc6C6CCCCCC65)cc2c43)c(-c2ccccc2)c1 ; CC(C)(C)c1ccc(N2c3cc(C4C5=C(CCCCC5)c5ccccc54)cc4c3B(c3ccc(-n5c6c(c7ccccc75)CCCC6)cc3S4)c3cc(-n4c5c(c6ccccc64)CCC5)cc(-n4c5c(c6ccccc64)CCC5)c32)cc1] 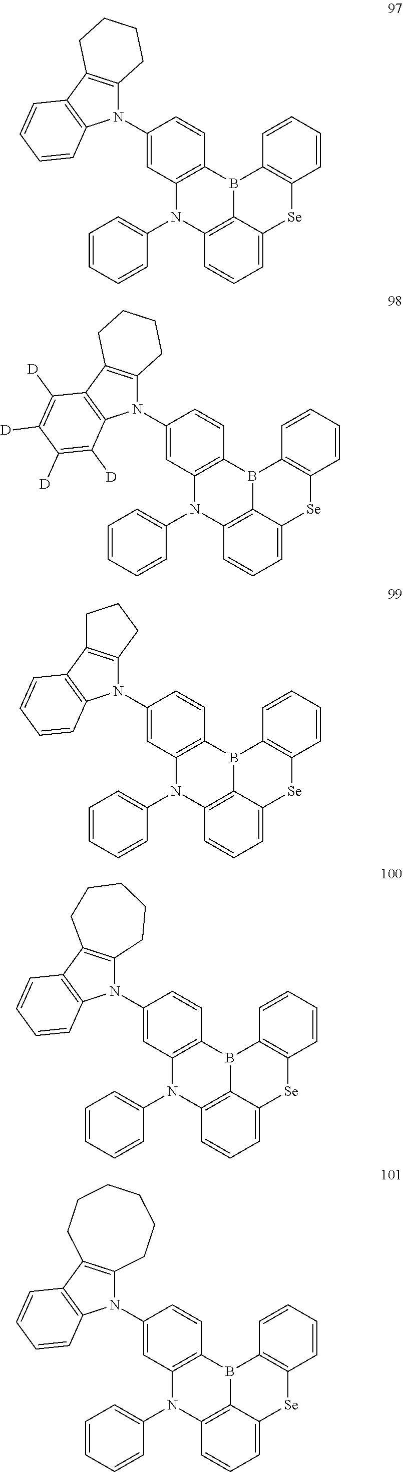 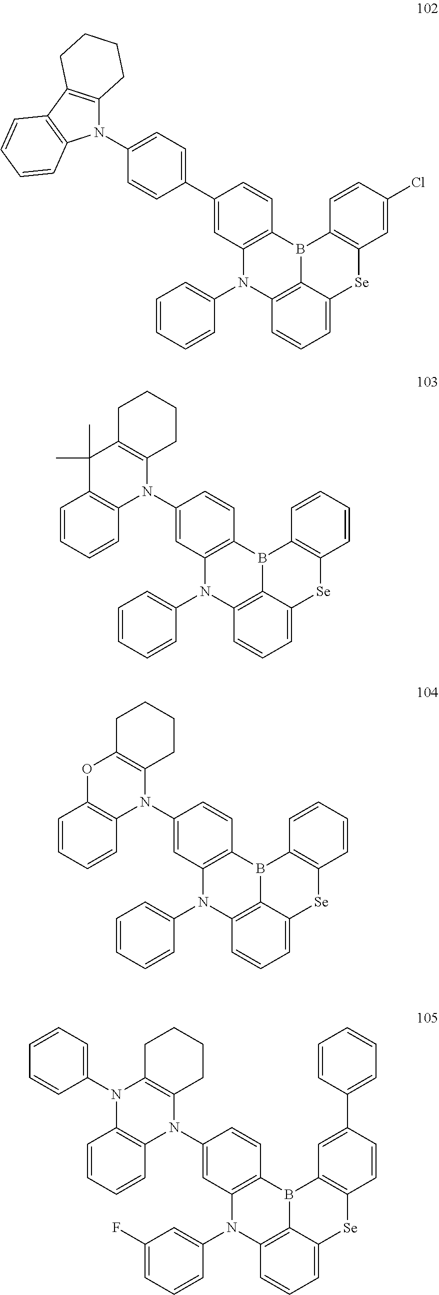 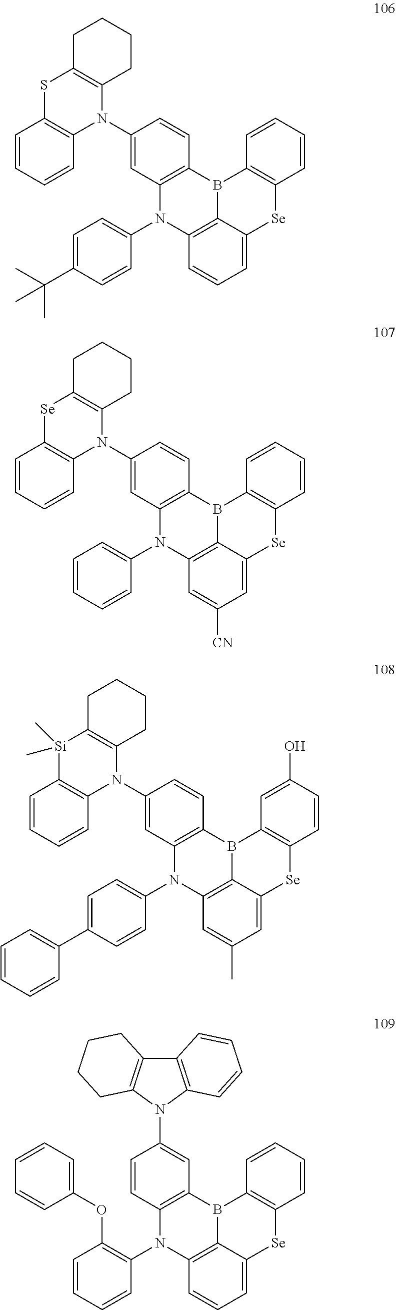 [SMILES: CC(C)(C)c1ccc(N2c3cc(N4C5=C(CCCC5)Sc5ccccc54)ccc3B3c4ccccc4[Se]c4cccc2c43)cc1 ; N#Cc1cc2c3c(c1)N(c1ccccc1)c1cc(N4C5=C(CCCC5)[Se]c5ccccc54)ccc1B3c1ccccc1[Se]2 ; Cc1cc2c3c(c1)N(c1ccc(-c4ccccc4)cc1)c1cc(N4C5=C(CCCC5)[Si](C)(C)c5ccccc54)ccc1B3c1cc(O)ccc1[Se]2 ; c1ccc(Oc2ccccc2N2c3ccc(-n4c5c(c6ccccc64)CCCC5)cc3B3c4ccccc4[Se]c4cccc2c43)cc1] 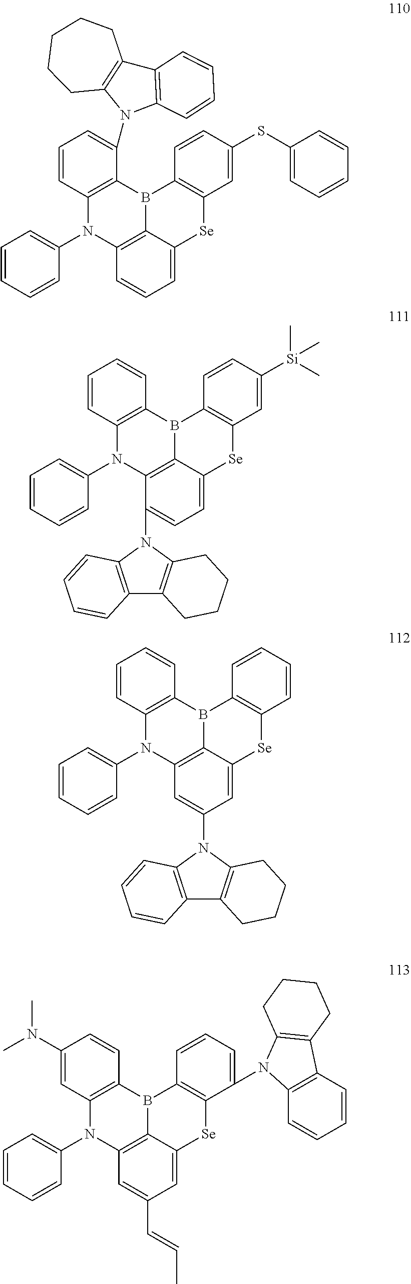 [SMILES: c1ccc(Sc2ccc3c(c2)[Se]c2cccc4c2B3c2c(cccc2-n2c3c(c5ccccc52)CCCCC3)N4c2ccccc2)cc1 ; C[Si](C)(C)c1ccc2c(c1)[Se]c1ccc(-n3c4c(c5ccccc53)CCCC4)c3c1B2c1ccccc1N3c1ccccc1 ; c1ccc(N2c3ccccc3B3c4ccccc4[Se]c4cc(-n5c6c(c7ccccc75)CCCC6)cc2c43)cc1 ; C/C=C/c1cc2c3c(c1)N(c1ccccc1)c1cc(N(C)C)ccc1B3c1cccc(-n3c4c(c5ccccc53)CCCC4)c1[Se]2] 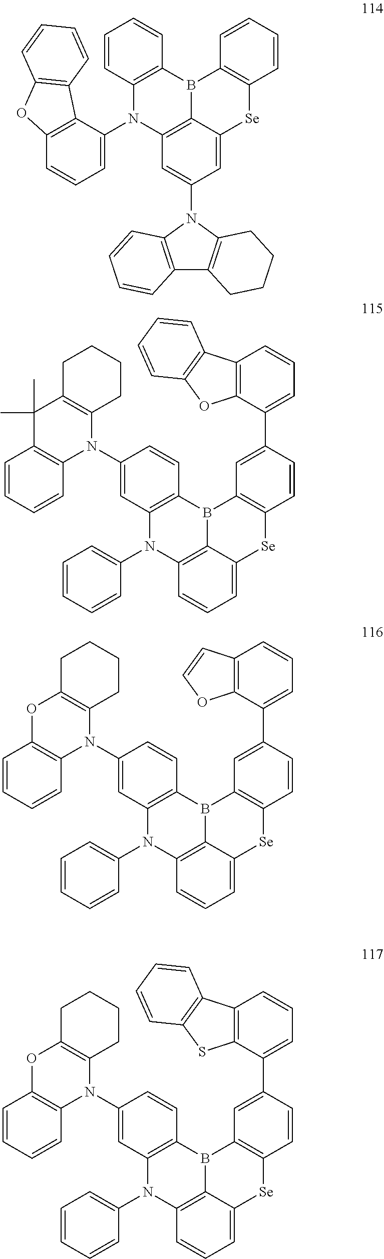 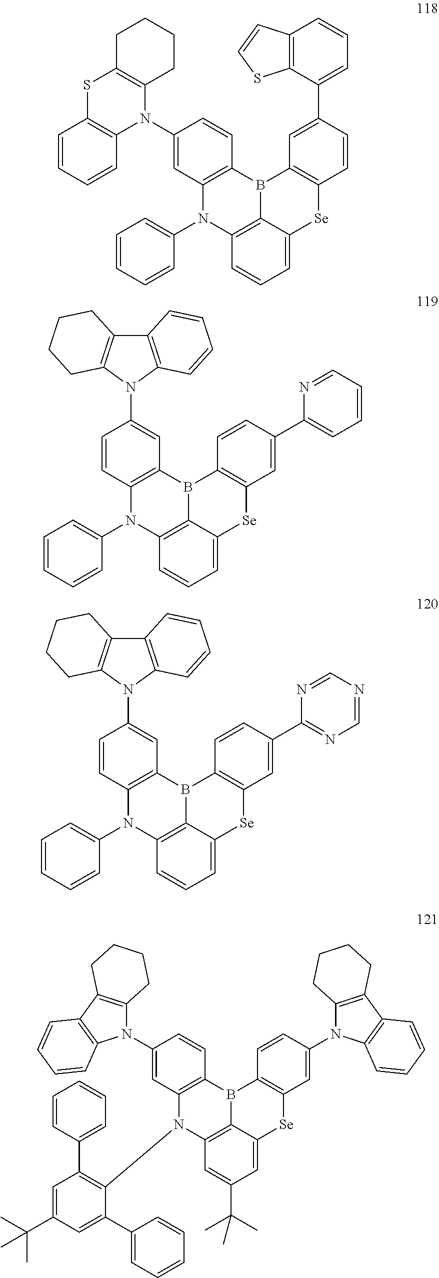 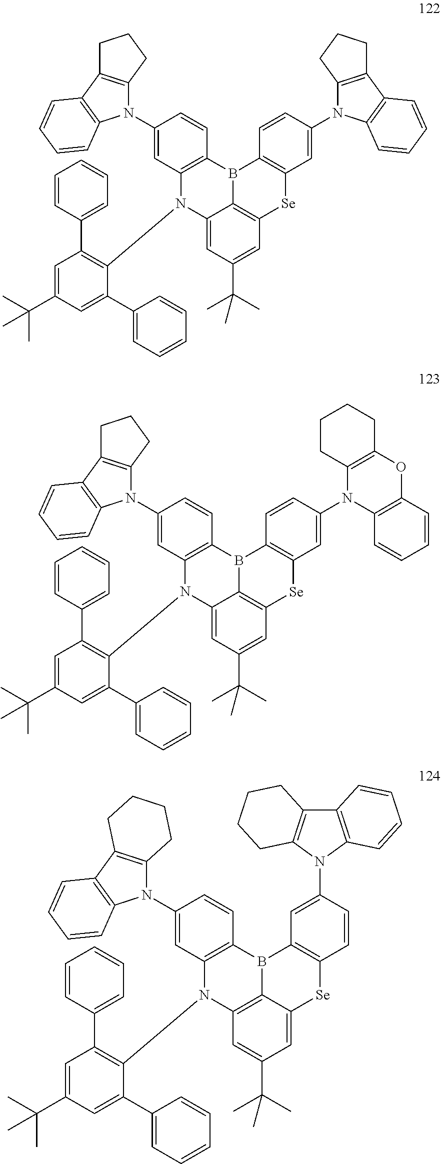 [SMILES: CC(C)(C)c1cc(-c2ccccc2)c(N2c3cc(-n4c5c(c6ccccc64)CCC5)ccc3B3c4ccc(-n5c6c(c7ccccc75)CCC6)cc4[Se]c4cc(C(C)(C)C)cc2c43)c(-c2ccccc2)c1 ; CC(C)(C)c1cc(-c2ccccc2)c(N2c3cc(-n4c5c(c6ccccc64)CCC5)ccc3B3c4ccc(N5C6=C(CCCC6)Oc6ccccc65)cc4[Se]c4cc(C(C)(C)C)cc2c43)c(-c2ccccc2)c1 ; CC(C)(C)c1cc(-c2ccccc2)c(N2c3cc(-n4c5c(c6ccccc64)CCCC5)ccc3B3c4cc(-n5c6c(c7ccccc75)CCCC6)ccc4[Se]c4cc(C(C)(C)C)cc2c43)c(-c2ccccc2)c1] 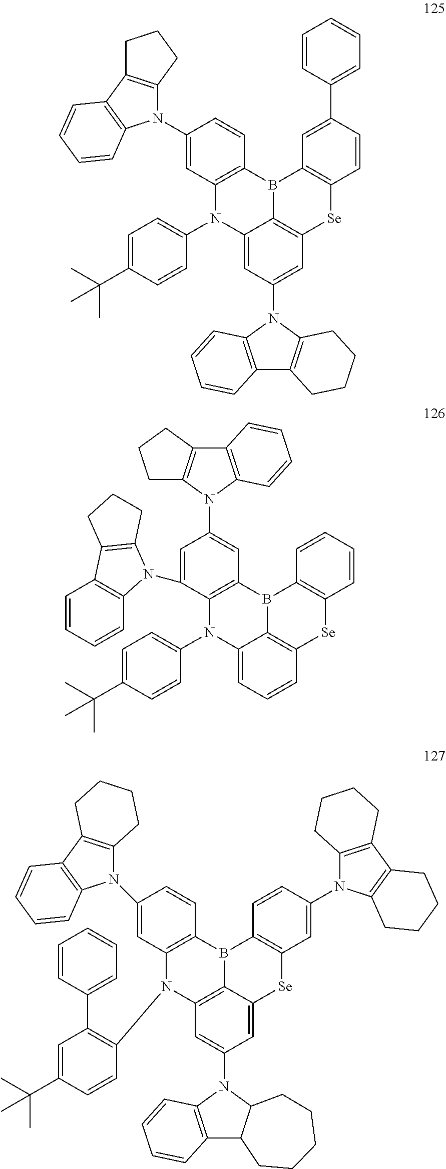 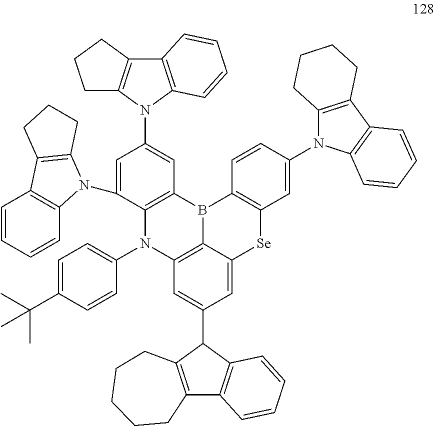 [SMILES: CC(C)(C)c1ccc(N2c3cc(C4C5=C(CCCCC5)c5ccccc54)cc4c3B(c3ccc(-n5c6c(c7ccccc75)CCCC6)cc3[Se]4)c3cc(-n4c5c(c6ccccc64)CCC5)cc(-n4c5c(c6ccccc64)CCC5)c32)cc1] 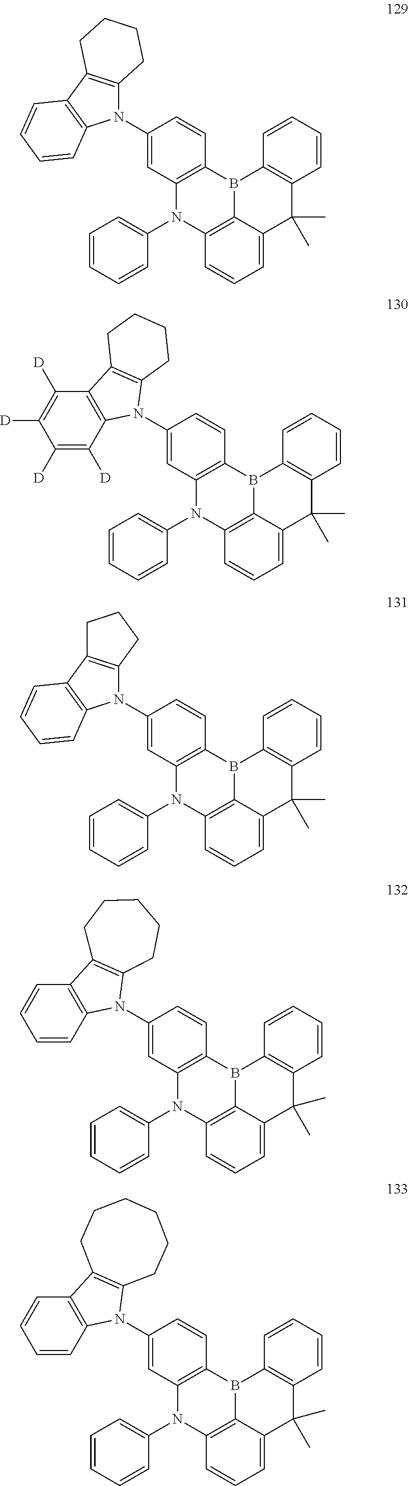 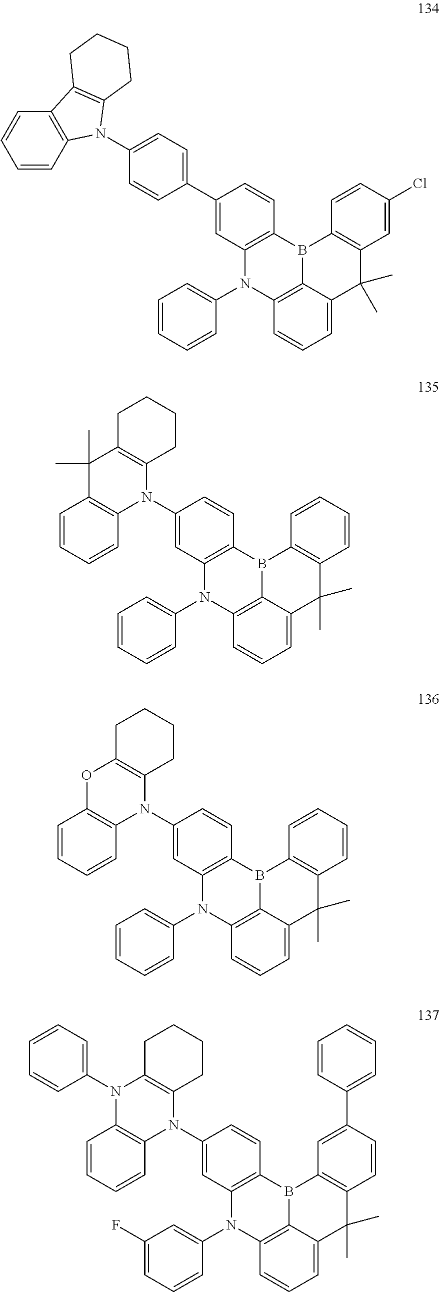 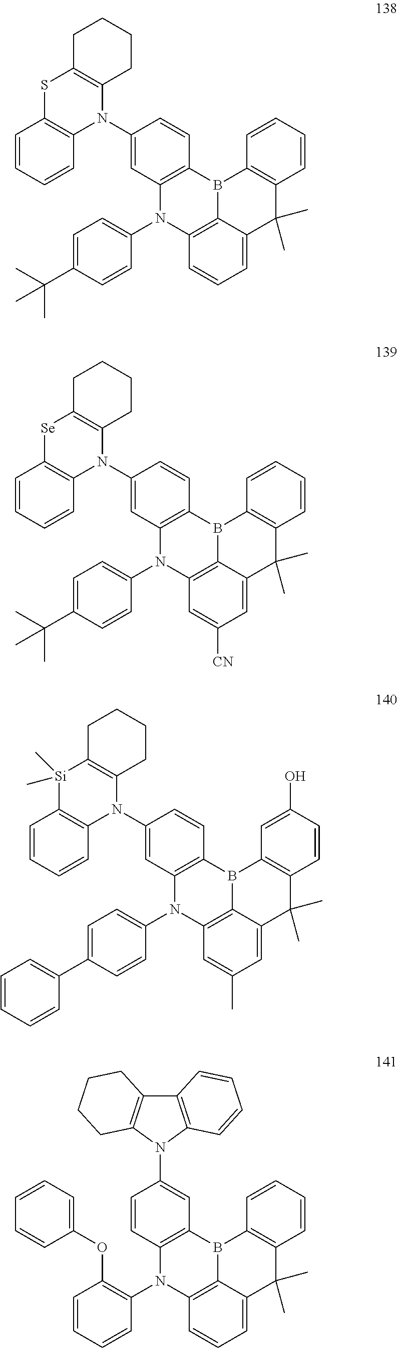 [SMILES: CC(C)(C)c1ccc(N2c3cc(N4C5=C(CCCC5)Sc5ccccc54)ccc3B3c4ccccc4C(C)(C)c4cccc2c43)cc1 ; CC(C)(C)c1ccc(N2c3cc(N4C5=C(CCCC5)[Se]c5ccccc54)ccc3B3c4ccccc4C(C)(C)c4cc(C#N)cc2c43)cc1 ; Cc1cc2c3c(c1)C(C)(C)c1ccc(O)cc1B3c1ccc(N3C4=C(CCCC4)[Si](C)(C)c4ccccc43)cc1N2c1ccc(-c2ccccc2)cc1 ; CC1(C)c2ccccc2B2c3cc(-n4c5c(c6ccccc64)CCCC5)ccc3N(c3ccccc3Oc3ccccc3)c3cccc1c32] 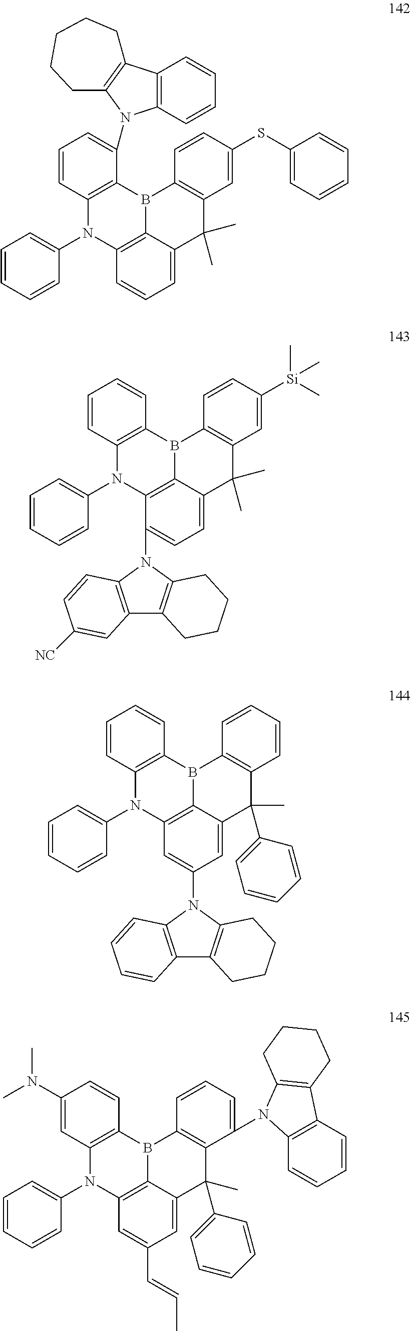 [SMILES: CC1(C)c2cc(Sc3ccccc3)ccc2B2c3c(cccc3-n3c4c(c5ccccc53)CCCCC4)N(c3ccccc3)c3cccc1c32 ; CC1(C)c2cc([Si](C)(C)C)ccc2B2c3ccccc3N(c3ccccc3)c3c(-n4c5c(c6cc(C#N)ccc64)CCCC5)ccc1c32 ; CC1(c2ccccc2)c2ccccc2B2c3ccccc3N(c3ccccc3)c3cc(-n4c5c(c6ccccc64)CCCC5)cc1c32 ; C/C=C/c1cc2c3c(c1)C(C)(c1ccccc1)c1c(cccc1-n1c4c(c5ccccc51)CCCC4)B3c1ccc(N(C)C)cc1N2c1ccccc1] 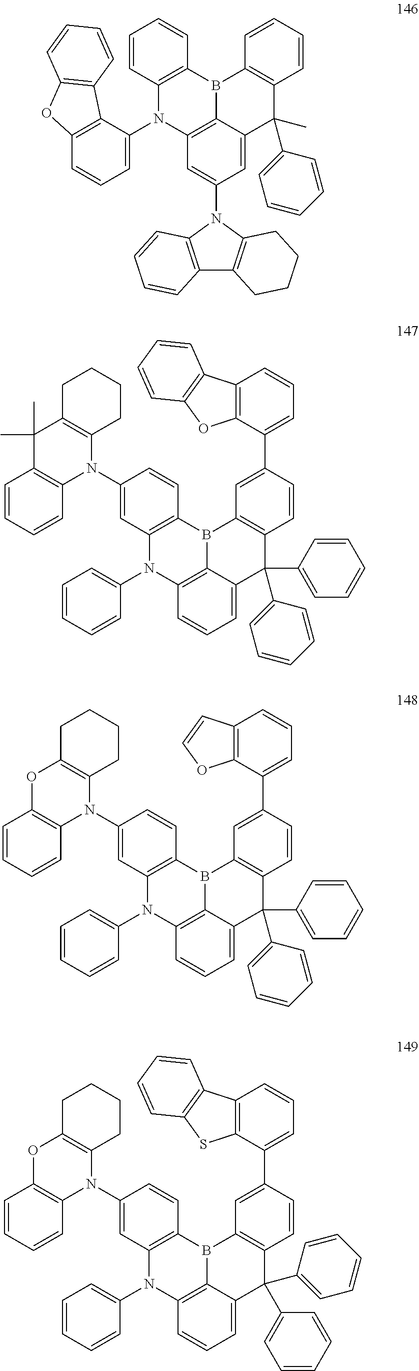 [SMILES: CC1(c2ccccc2)c2ccccc2B2c3ccccc3N(c3cccc4oc5ccccc5c34)c3cc(-n4c5c(c6ccccc64)CCCC5)cc1c32 ; CC1(C)C2=C(CCCC2)N(c2ccc3c(c2)N(c2ccccc2)c2cccc4c2B3c2cc(-c3cccc5c3oc3ccccc35)ccc2C4(c2ccccc2)c2ccccc2)c2ccccc21 ; c1ccc(N2c3cc(N4C5=C(CCCC5)Oc5ccccc54)ccc3B3c4cc(-c5cccc6ccoc56)ccc4C(c4ccccc4)(c4ccccc4)c4cccc2c43)cc1 ; c1ccc(N2c3cc(N4C5=C(CCCC5)Oc5ccccc54)ccc3B3c4cc(-c5cccc6c5sc5ccccc56)ccc4C(c4ccccc4)(c4ccccc4)c4cccc2c43)cc1] 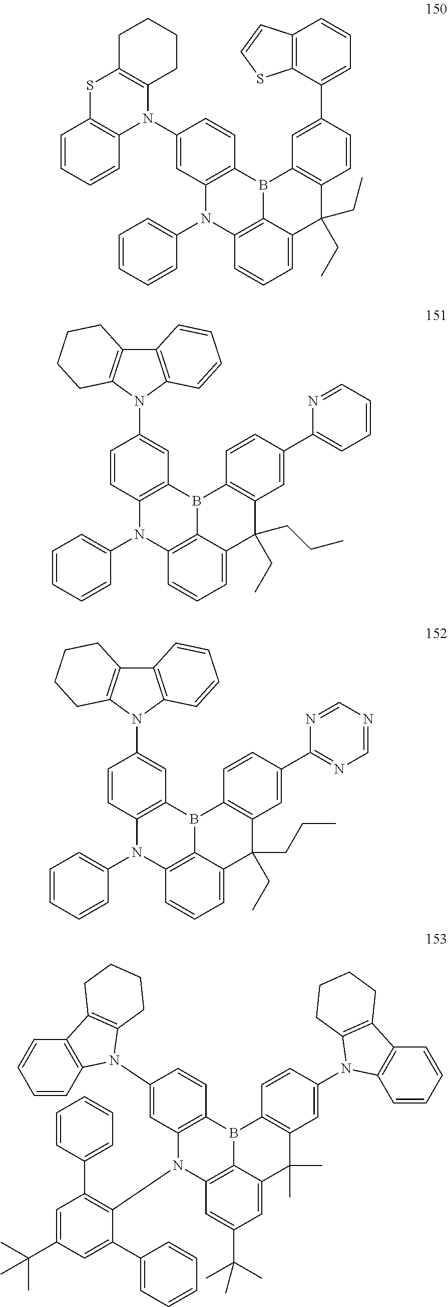 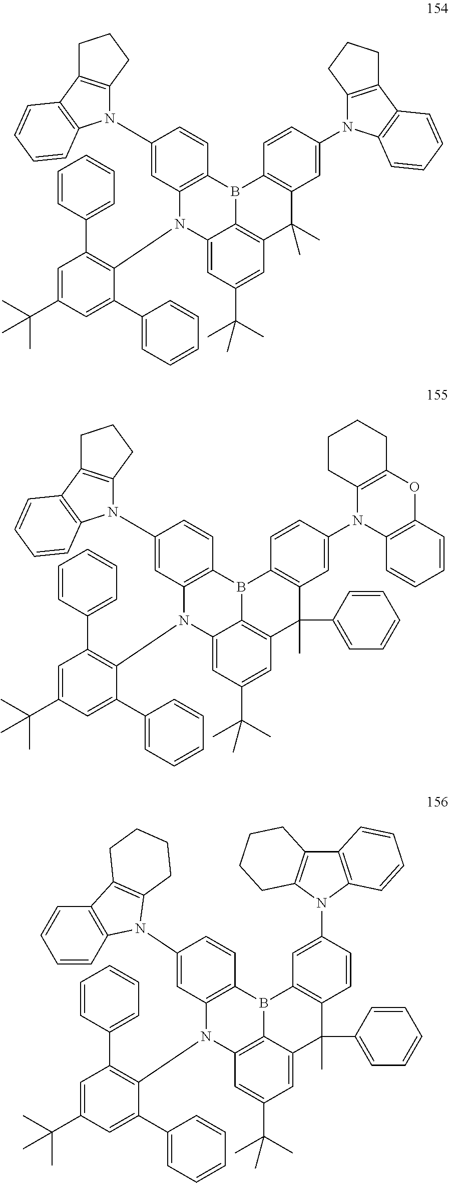 [SMILES: CC(C)(C)c1cc(-c2ccccc2)c(N2c3cc(-n4c5c(c6ccccc64)CCC5)ccc3B3c4ccc(-n5c6c(c7ccccc75)CCC6)cc4C(C)(C)c4cc(C(C)(C)C)cc2c43)c(-c2ccccc2)c1 ; CC(C)(C)c1cc(-c2ccccc2)c(N2c3cc(-n4c5c(c6ccccc64)CCC5)ccc3B3c4ccc(N5C6=C(CCCC6)Oc6ccccc65)cc4C(C)(c4ccccc4)c4cc(C(C)(C)C)cc2c43)c(-c2ccccc2)c1 ; CC(C)(C)c1cc(-c2ccccc2)c(N2c3cc(-n4c5c(c6ccccc64)CCCC5)ccc3B3c4cc(-n5c6c(c7ccccc75)CCCC6)ccc4C(C)(c4ccccc4)c4cc(C(C)(C)C)cc2c43)c(-c2ccccc2)c1] 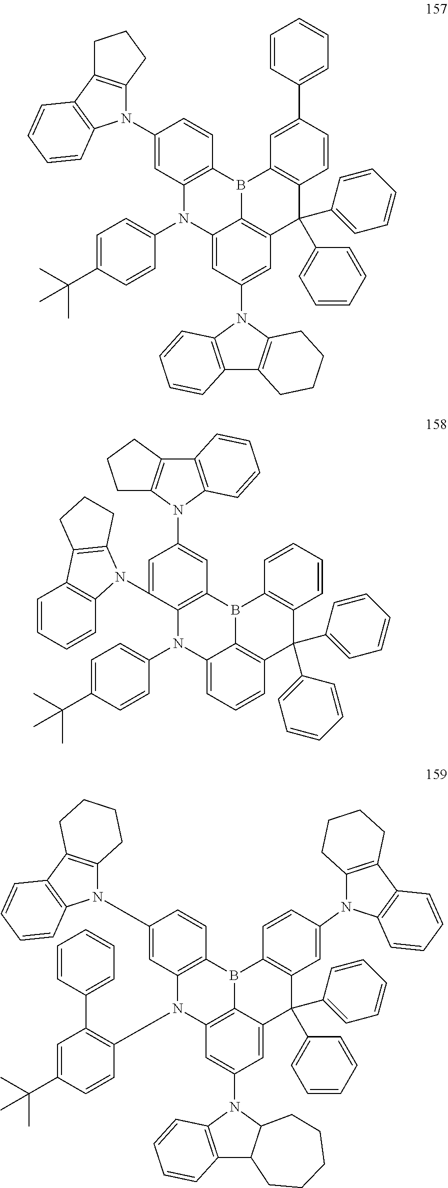 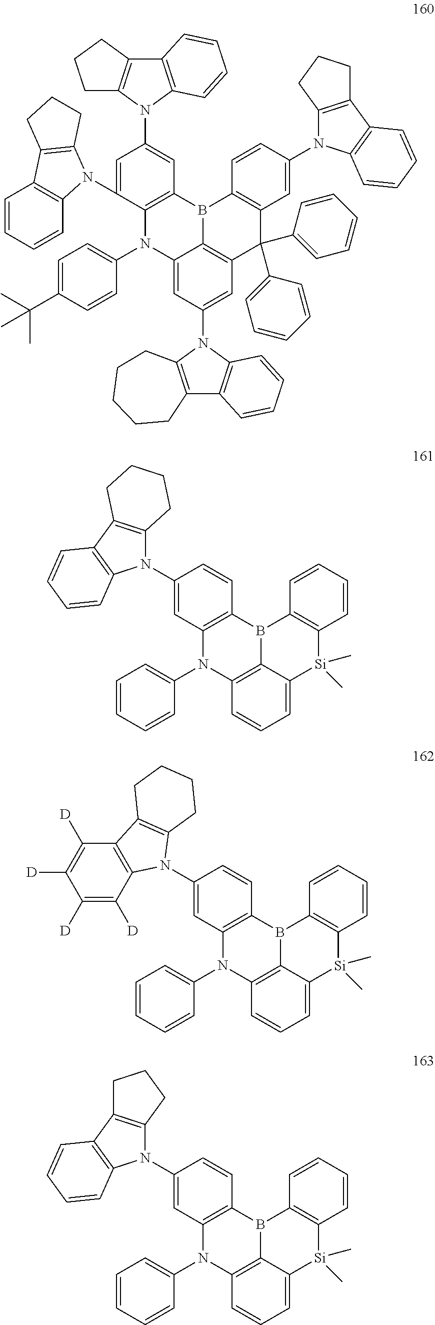 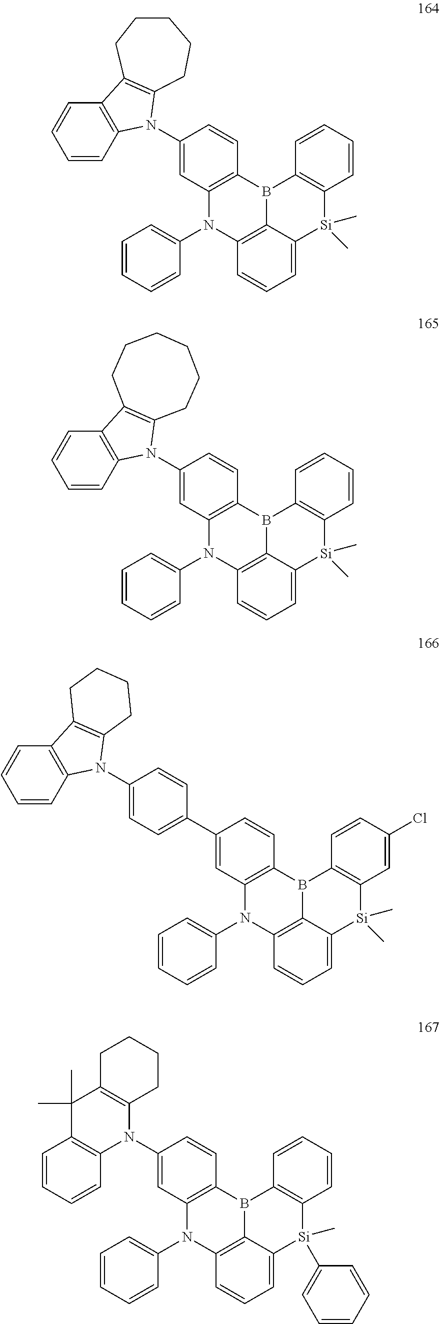 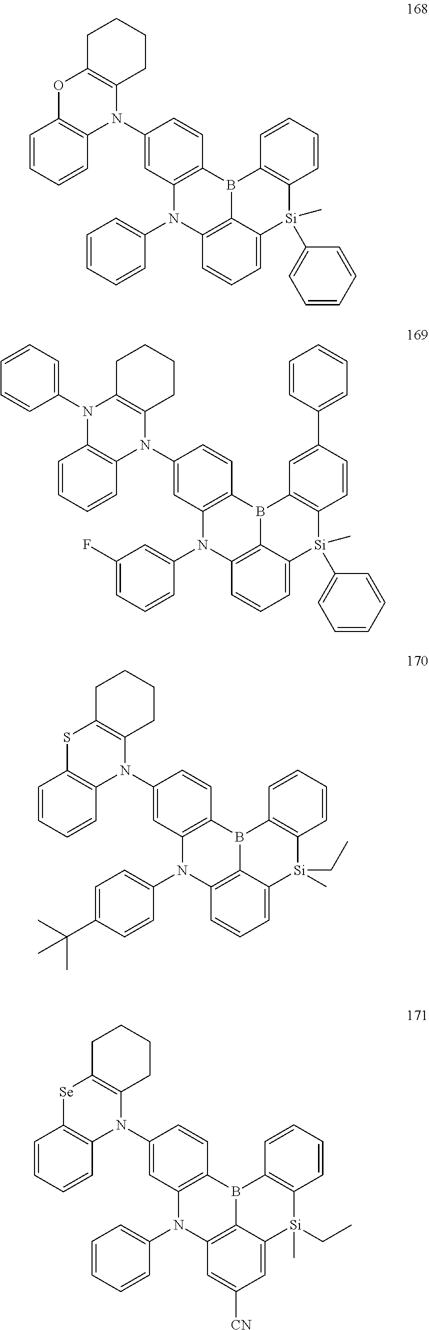 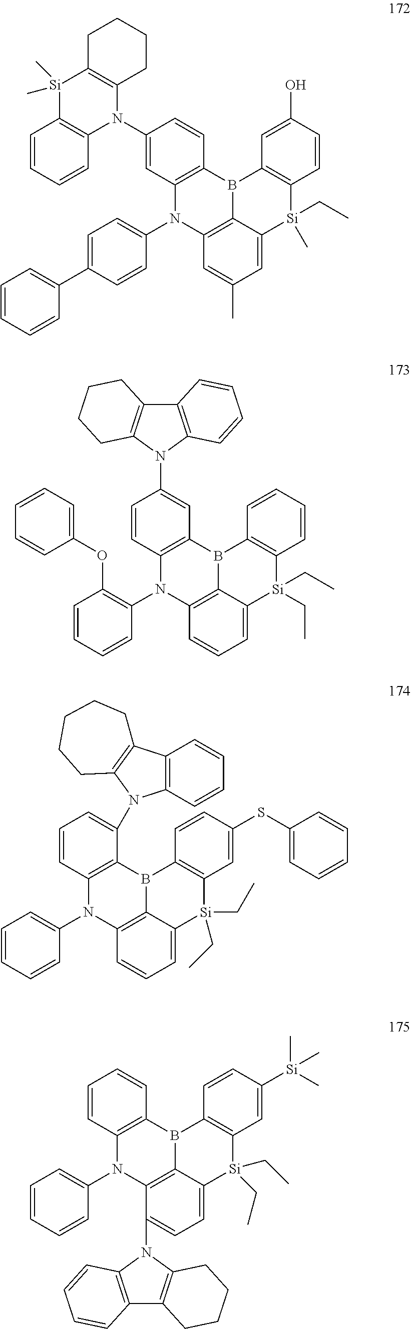 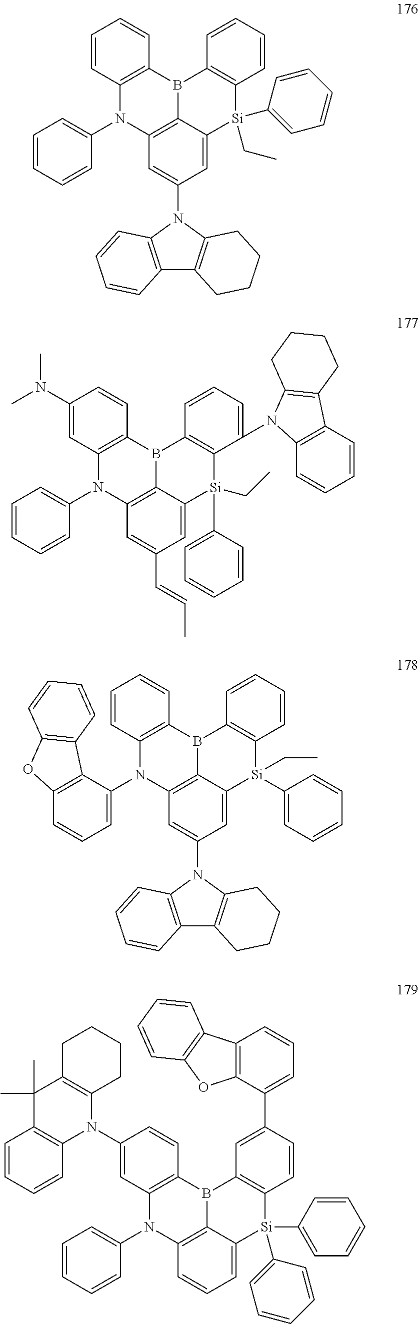 [SMILES: CC[Si]1(c2ccccc2)c2ccccc2B2c3ccccc3N(c3ccccc3)c3cc(-n4c5c(c6ccccc64)CCCC5)cc1c32 ; C/C=C/c1cc2c3c(c1)[Si](CC)(c1ccccc1)c1c(cccc1-n1c4c(c5ccccc51)CCCC4)B3c1ccc(N(C)C)cc1N2c1ccccc1 ; CC[Si]1(c2ccccc2)c2ccccc2B2c3ccccc3N(c3cccc4oc5ccccc5c34)c3cc(-n4c5c(c6ccccc64)CCCC5)cc1c32 ; CC1(C)C2=C(CCCC2)N(c2ccc3c(c2)N(c2ccccc2)c2cccc4c2B3c2cc(-c3cccc5c3oc3ccccc35)ccc2[Si]4(c2ccccc2)c2ccccc2)c2ccccc21] 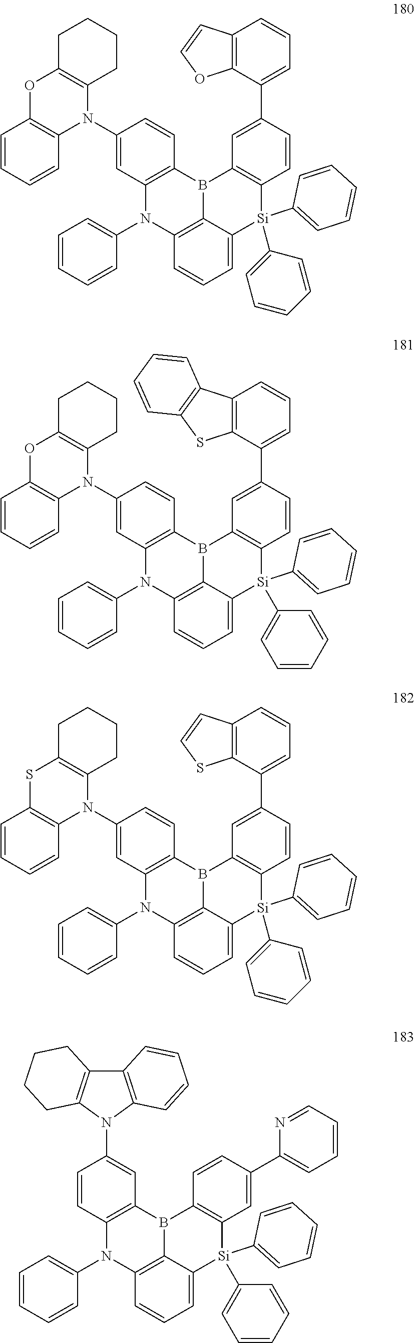 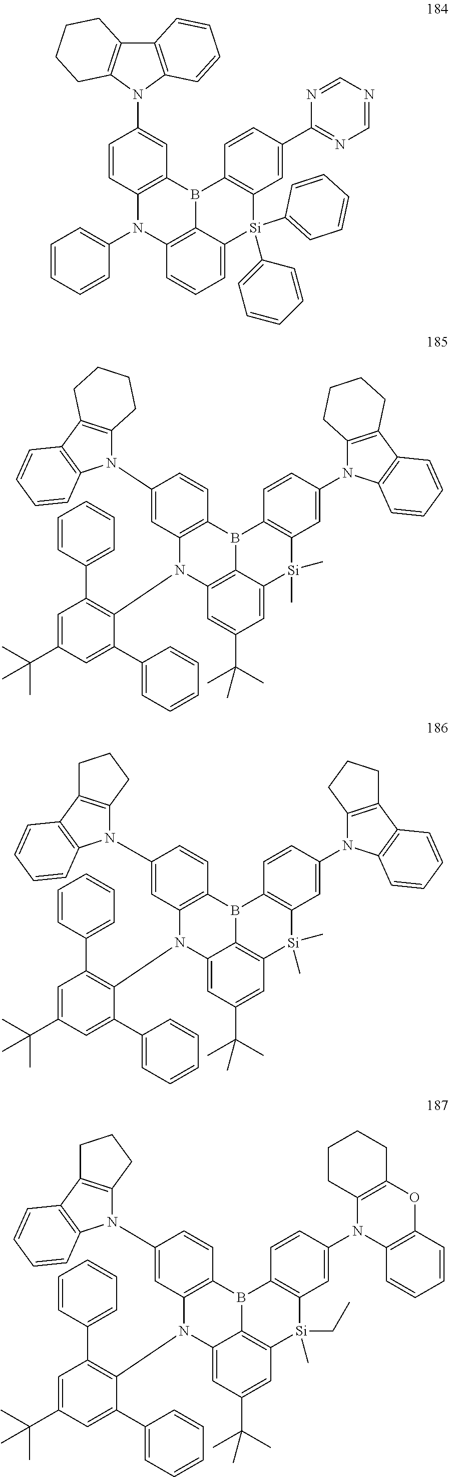 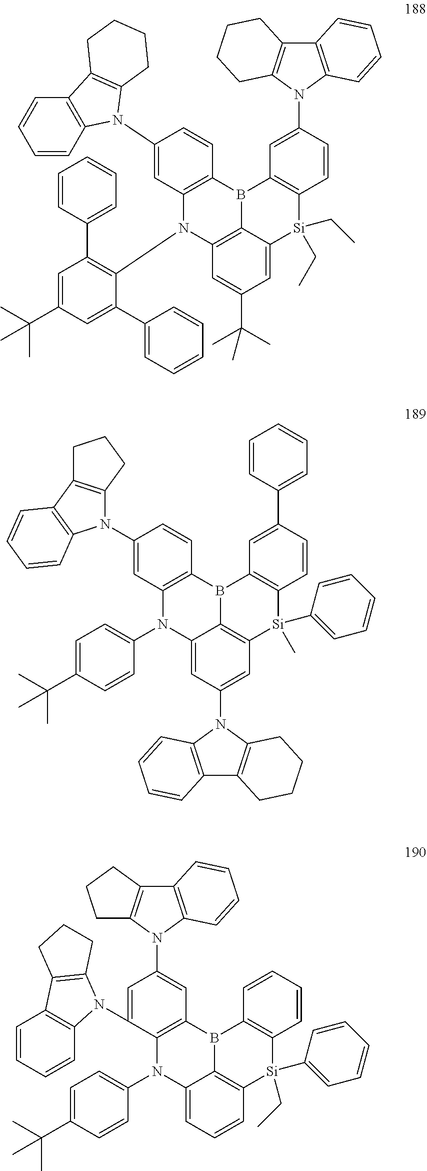 [SMILES: CC[Si]1(CC)c2ccc(-n3c4c(c5ccccc53)CCCC4)cc2B2c3ccc(-n4c5c(c6ccccc64)CCCC5)cc3N(c3c(-c4ccccc4)cc(C(C)(C)C)cc3-c3ccccc3)c3cc(C(C)(C)C)cc1c32 ; CC(C)(C)c1ccc(N2c3cc(-n4c5c(c6ccccc64)CCC5)ccc3B3c4cc(-c5ccccc5)ccc4[Si](C)(c4ccccc4)c4cc(-n5c6c(c7ccccc75)CCCC6)cc2c43)cc1 ; CC[Si]1(c2ccccc2)c2ccccc2B2c3cc(-n4c5c(c6ccccc64)CCC5)cc(-n4c5c(c6ccccc64)CCC5)c3N(c3ccc(C(C)(C)C)cc3)c3cccc1c32] 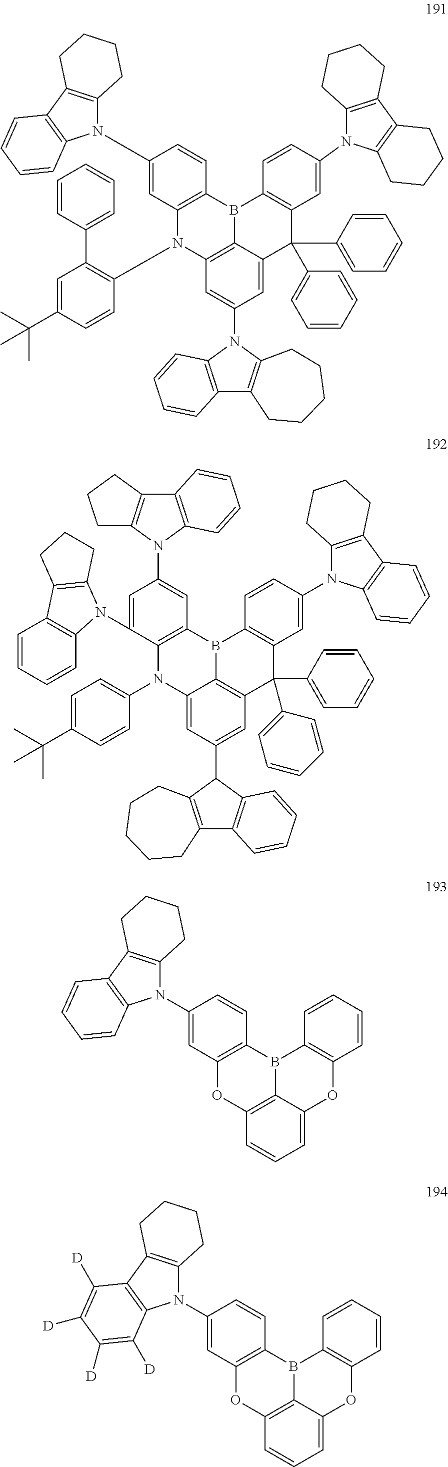 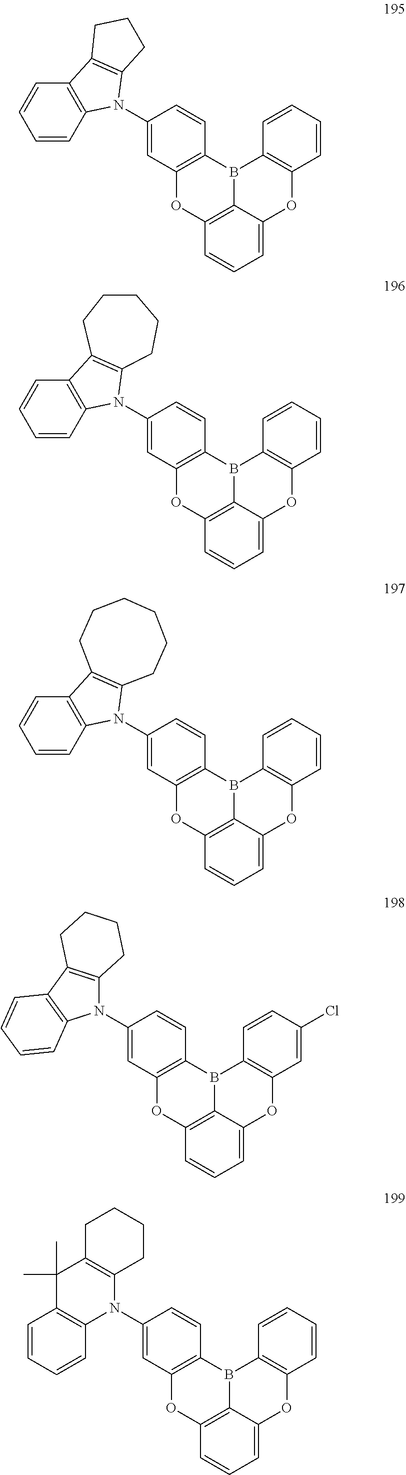 [SMILES: c1ccc2c(c1)Oc1cccc3c1B2c1ccc(-n2c4c(c5ccccc52)CCC4)cc1O3 ; c1ccc2c(c1)Oc1cccc3c1B2c1ccc(-n2c4c(c5ccccc52)CCCCC4)cc1O3 ; c1ccc2c(c1)Oc1cccc3c1B2c1ccc(-n2c4c(c5ccccc52)CCCCCC4)cc1O3 ; Clc1ccc2c(c1)Oc1cccc3c1B2c1ccc(-n2c4c(c5ccccc52)CCCC4)cc1O3 ; CC1(C)C2=C(CCCC2)N(c2ccc3c(c2)Oc2cccc4c2B3c2ccccc2O4)c2ccccc21] 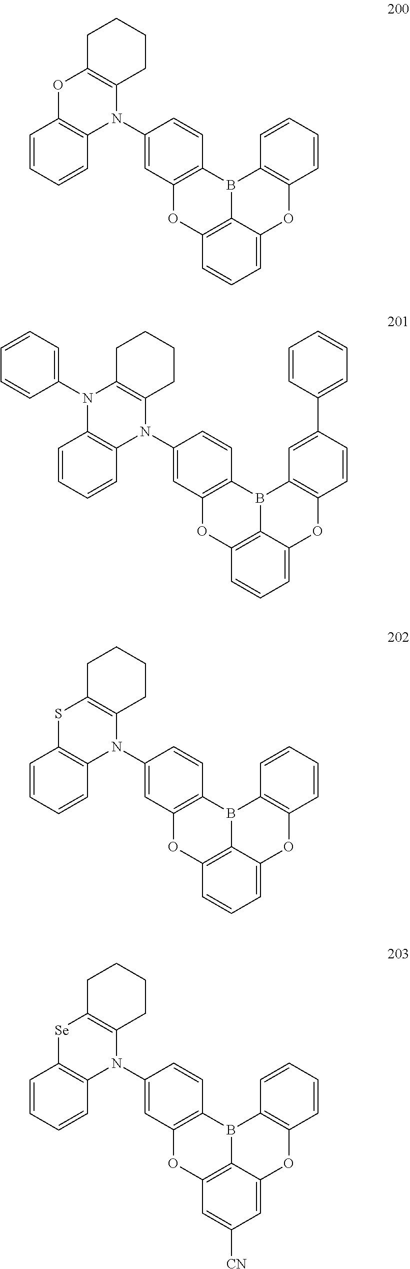 [SMILES: c1ccc2c(c1)Oc1cccc3c1B2c1ccc(N2C4=C(CCCC4)Oc4ccccc42)cc1O3 ; c1ccc(-c2ccc3c(c2)B2c4ccc(N5C6=C(CCCC6)N(c6ccccc6)c6ccccc65)cc4Oc4cccc(c42)O3)cc1 ; c1ccc2c(c1)Oc1cccc3c1B2c1ccc(N2C4=C(CCCC4)Sc4ccccc42)cc1O3 ; N#Cc1cc2c3c(c1)Oc1cc(N4C5=C(CCCC5)[Se]c5ccccc54)ccc1B3c1ccccc1O2] 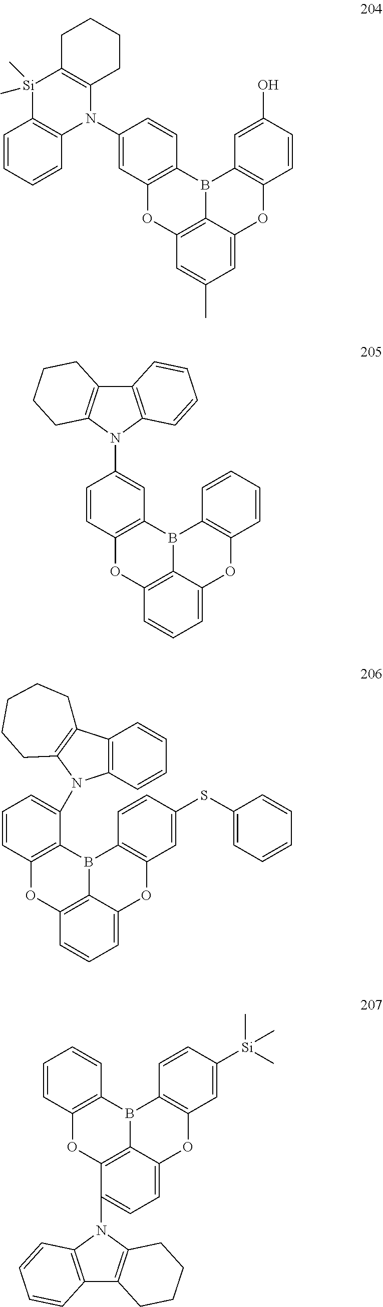 [SMILES: Cc1cc2c3c(c1)Oc1ccc(O)cc1B3c1ccc(N3C4=C(CCCC4)[Si](C)(C)c4ccccc43)cc1O2 ; c1ccc2c(c1)Oc1cccc3c1B2c1cc(-n2c4c(c5ccccc52)CCCC4)ccc1O3 ; c1ccc(Sc2ccc3c(c2)Oc2cccc4c2B3c2c(cccc2-n2c3c(c5ccccc52)CCCCC3)O4)cc1 ; C[Si](C)(C)c1ccc2c(c1)Oc1ccc(-n3c4c(c5ccccc53)CCCC4)c3c1B2c1ccccc1O3] 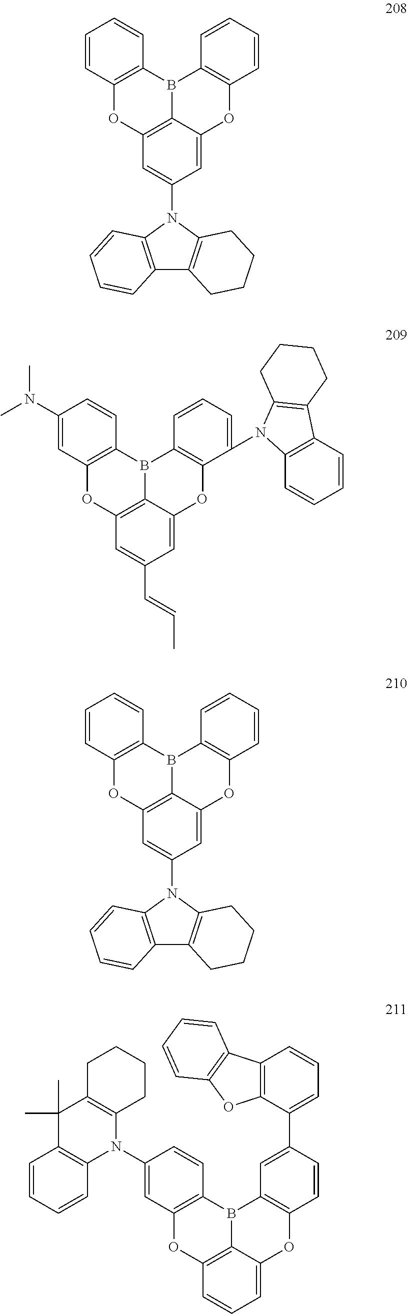 [SMILES: c1ccc2c(c1)Oc1cc(-n3c4c(c5ccccc53)CCCC4)cc3c1B2c1ccccc1O3 ; C/C=C/c1cc2c3c(c1)Oc1c(cccc1-n1c4c(c5ccccc51)CCCC4)B3c1ccc(N(C)C)cc1O2 ; c1ccc2c(c1)Oc1cc(-n3c4c(c5ccccc53)CCCC4)cc3c1B2c1ccccc1O3 ; CC1(C)C2=C(CCCC2)N(c2ccc3c(c2)Oc2cccc4c2B3c2cc(-c3cccc5c3oc3ccccc35)ccc2O4)c2ccccc21] 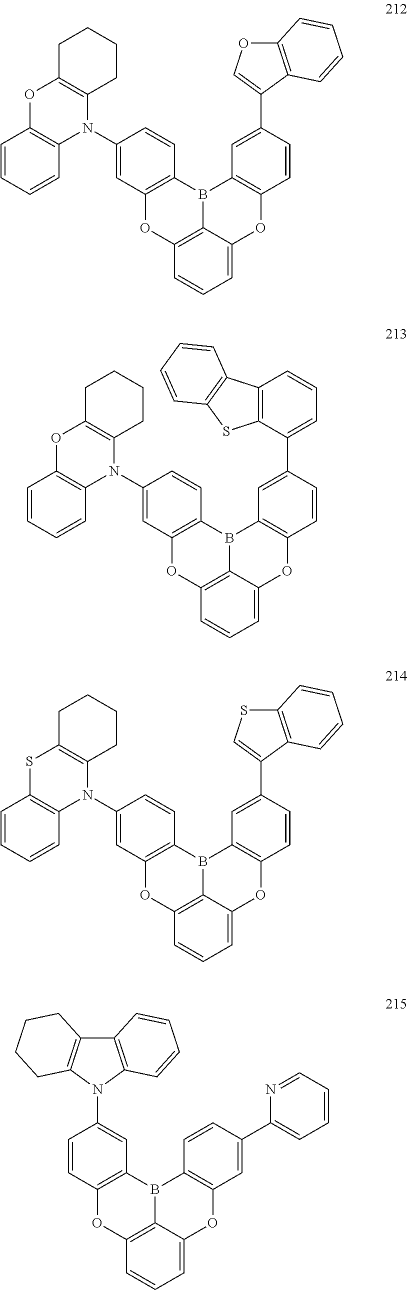 [SMILES: c1ccc2c(c1)OC1=C(CCCC1)N2c1ccc2c(c1)Oc1cccc3c1B2c1cc(-c2coc4ccccc24)ccc1O3 ; c1ccc2c(c1)OC1=C(CCCC1)N2c1ccc2c(c1)Oc1cccc3c1B2c1cc(-c2cccc4c2sc2ccccc24)ccc1O3 ; c1cc2c3c(c1)Oc1ccc(-c4csc5ccccc45)cc1B3c1ccc(N3C4=C(CCCC4)Sc4ccccc43)cc1O2 ; c1ccc(-c2ccc3c(c2)Oc2cccc4c2B3c2cc(-n3c5c(c6ccccc63)CCCC5)ccc2O4)nc1] 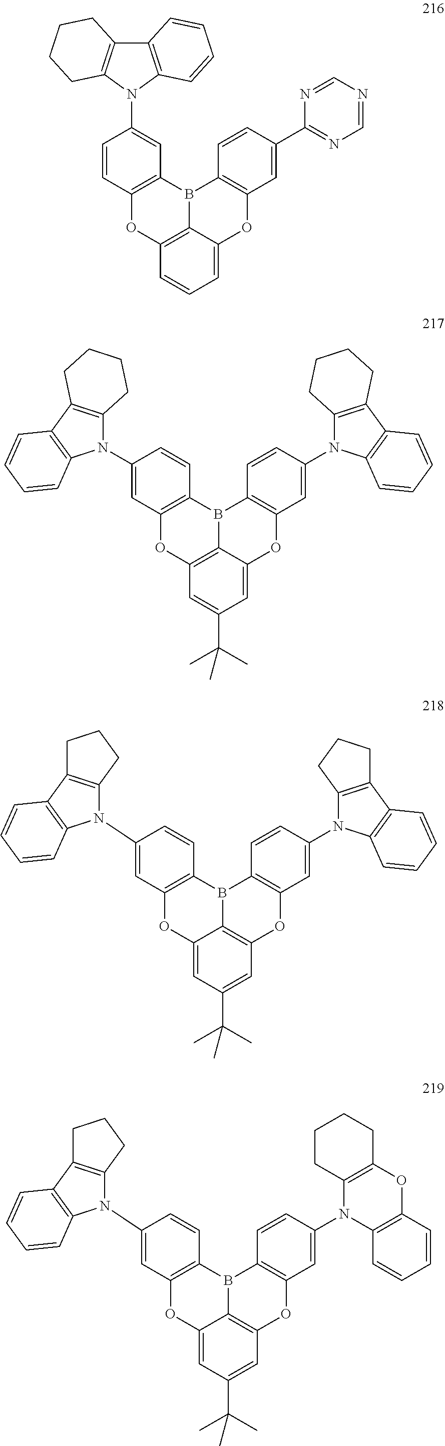 [SMILES: c1cc2c3c(c1)Oc1ccc(-n4c5c(c6ccccc64)CCCC5)cc1B3c1ccc(-c3ncncn3)cc1O2 ; CC(C)(C)c1cc2c3c(c1)Oc1cc(-n4c5c(c6ccccc64)CCCC5)ccc1B3c1ccc(-n3c4c(c5ccccc53)CCCC4)cc1O2 ; CC(C)(C)c1cc2c3c(c1)Oc1cc(-n4c5c(c6ccccc64)CCC5)ccc1B3c1ccc(-n3c4c(c5ccccc53)CCC4)cc1O2 ; CC(C)(C)c1cc2c3c(c1)Oc1cc(-n4c5c(c6ccccc64)CCC5)ccc1B3c1ccc(N3C4=C(CCCC4)Oc4ccccc43)cc1O2] 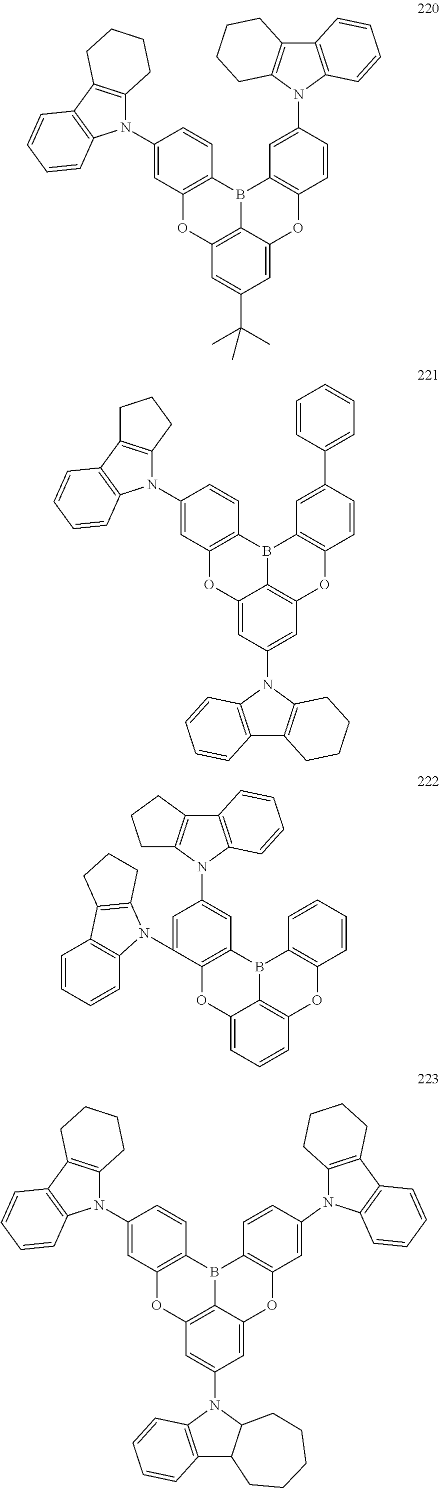 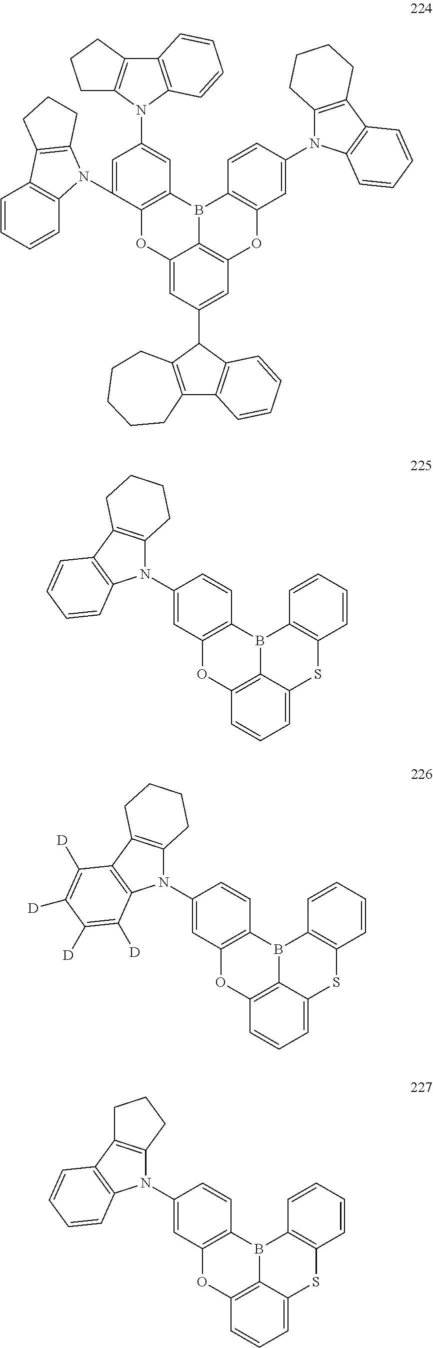 [SMILES: c1ccc2c(c1)C1=C(CCCCC1)C2c1cc2c3c(c1)Oc1c(cc(-n4c5c(c6ccccc64)CCC5)cc1-n1c4c(c5ccccc51)CCC4)B3c1ccc(-n3c4c(c5ccccc53)CCCC4)cc1O2 ; c1ccc2c(c1)Sc1cccc3c1B2c1ccc(-n2c4c(c5ccccc52)CCCC4)cc1O3 ; [2H]c1c([2H])c([2H])c2c(c1[2H])c1c(n2-c2ccc3c(c2)Oc2cccc4c2B3c2ccccc2S4)CCCC1 ; c1ccc2c(c1)Sc1cccc3c1B2c1ccc(-n2c4c(c5ccccc52)CCC4)cc1O3] 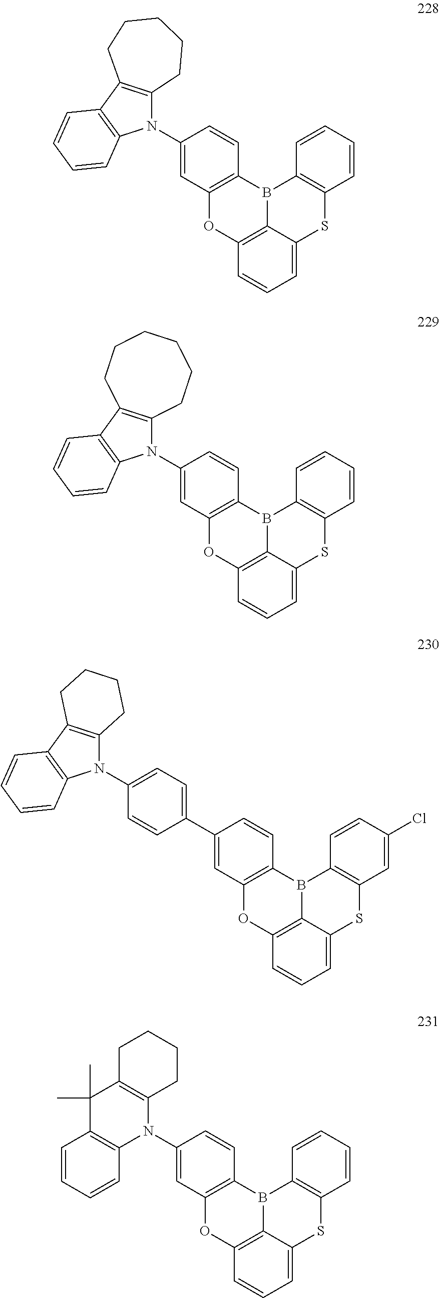 [SMILES: c1ccc2c(c1)Sc1cccc3c1B2c1ccc(-n2c4c(c5ccccc52)CCCCC4)cc1O3 ; c1ccc2c(c1)Sc1cccc3c1B2c1ccc(-n2c4c(c5ccccc52)CCCCCC4)cc1O3 ; Clc1ccc2c(c1)Sc1cccc3c1B2c1ccc(-c2ccc(-n4c5c(c6ccccc64)CCCC5)cc2)cc1O3 ; CC1(C)C2=C(CCCC2)N(c2ccc3c(c2)Oc2cccc4c2B3c2ccccc2S4)c2ccccc21] 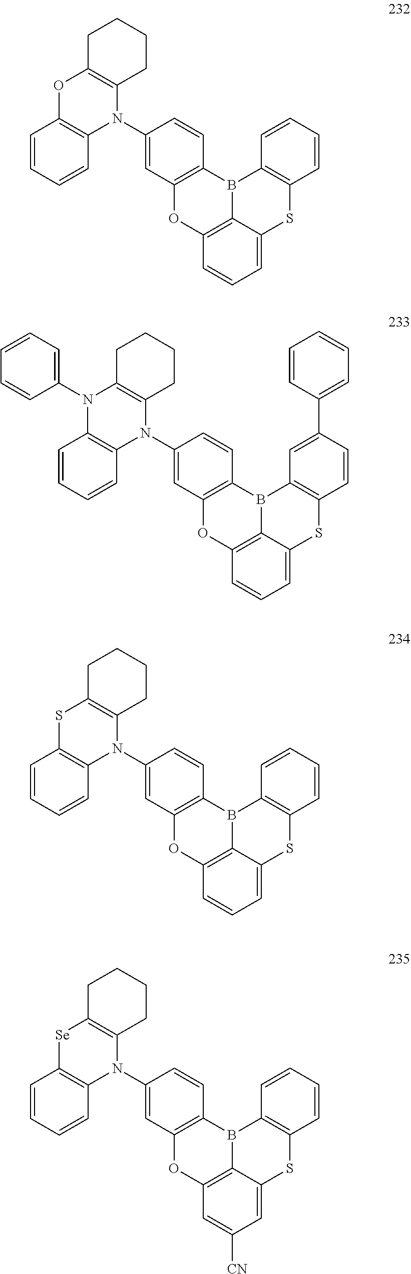 [SMILES: c1ccc2c(c1)OC1=C(CCCC1)N2c1ccc2c(c1)Oc1cccc3c1B2c1ccccc1S3 ; c1ccc(-c2ccc3c(c2)B2c4ccc(N5C6=C(CCCC6)N(c6ccccc6)c6ccccc65)cc4Oc4cccc(c42)S3)cc1 ; c1ccc2c(c1)Sc1cccc3c1B2c1ccc(N2C4=C(CCCC4)Sc4ccccc42)cc1O3 ; N#Cc1cc2c3c(c1)Sc1ccccc1B3c1ccc(N3C4=C(CCCC4)[Se]c4ccccc43)cc1O2] 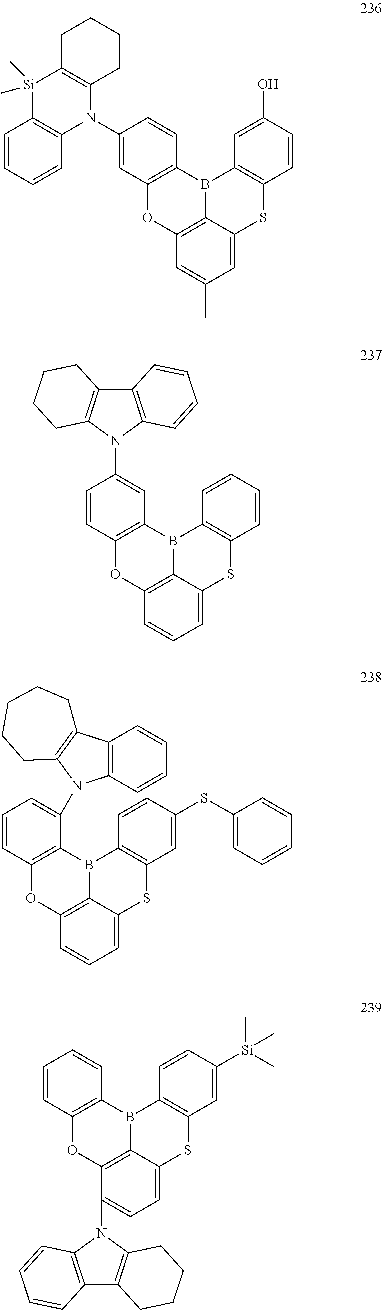 [SMILES: Cc1cc2c3c(c1)Sc1ccc(O)cc1B3c1ccc(N3C4=C(CCCC4)[Si](C)(C)c4ccccc43)cc1O2 ; c1ccc2c(c1)Sc1cccc3c1B2c1cc(-n2c4c(c5ccccc52)CCCC4)ccc1O3 ; c1ccc(Sc2ccc3c(c2)Sc2cccc4c2B3c2c(cccc2-n2c3c(c5ccccc52)CCCCC3)O4)cc1 ; C[Si](C)(C)c1ccc2c(c1)Sc1ccc(-n3c4c(c5ccccc53)CCCC4)c3c1B2c1ccccc1O3] 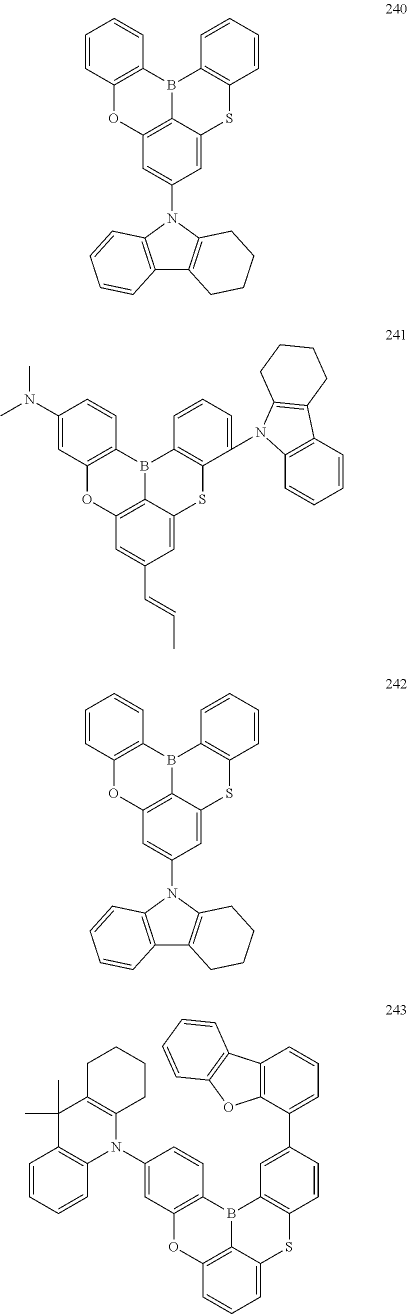 [SMILES: c1ccc2c(c1)Oc1cc(-n3c4c(c5ccccc53)CCCC4)cc3c1B2c1ccccc1S3 ; C/C=C/c1cc2c3c(c1)Sc1c(cccc1-n1c4c(c5ccccc51)CCCC4)B3c1ccc(N(C)C)cc1O2 ; c1ccc2c(c1)Oc1cc(-n3c4c(c5ccccc53)CCCC4)cc3c1B2c1ccccc1S3 ; CC1(C)C2=C(CCCC2)N(c2ccc3c(c2)Oc2cccc4c2B3c2cc(-c3cccc5c3oc3ccccc35)ccc2S4)c2ccccc21] 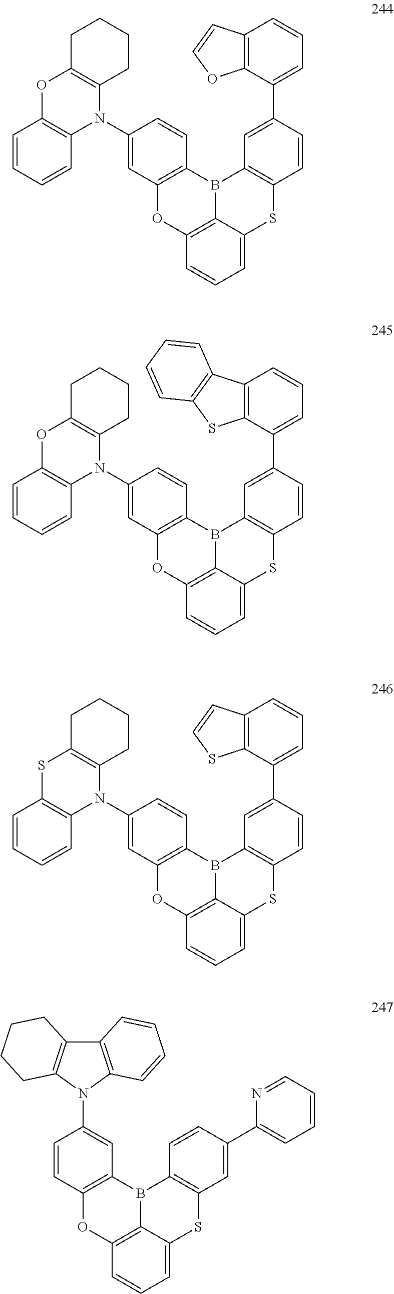 [SMILES: c1ccc2c(c1)OC1=C(CCCC1)N2c1ccc2c(c1)Oc1cccc3c1B2c1cc(-c2cccc4ccoc24)ccc1S3 ; c1ccc2c(c1)OC1=C(CCCC1)N2c1ccc2c(c1)Oc1cccc3c1B2c1cc(-c2cccc4c2sc2ccccc24)ccc1S3 ; c1ccc2c(c1)SC1=C(CCCC1)N2c1ccc2c(c1)Oc1cccc3c1B2c1cc(-c2cccc4ccsc24)ccc1S3 ; c1ccc(-c2ccc3c(c2)Sc2cccc4c2B3c2cc(-n3c5c(c6ccccc63)CCCC5)ccc2O4)nc1] 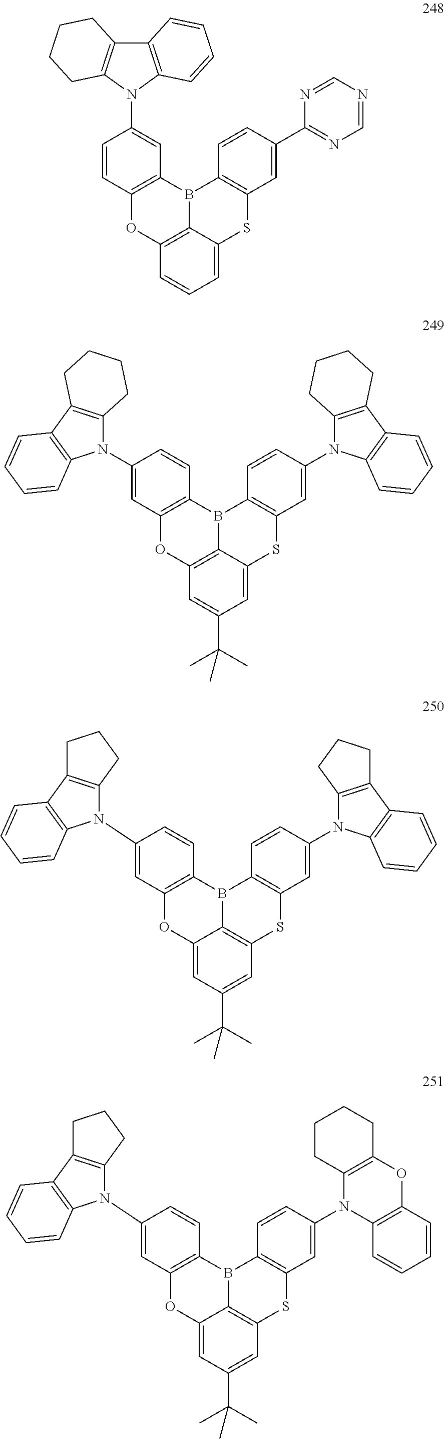 [SMILES: c1cc2c3c(c1)Sc1cc(-c4ncncn4)ccc1B3c1cc(-n3c4c(c5ccccc53)CCCC4)ccc1O2 ; CC(C)(C)c1cc2c3c(c1)Sc1cc(-n4c5c(c6ccccc64)CCCC5)ccc1B3c1ccc(-n3c4c(c5ccccc53)CCCC4)cc1O2 ; CC(C)(C)c1cc2c3c(c1)Sc1cc(-n4c5c(c6ccccc64)CCC5)ccc1B3c1ccc(-n3c4c(c5ccccc53)CCC4)cc1O2 ; CC(C)(C)c1cc2c3c(c1)Sc1cc(N4C5=C(CCCC5)Oc5ccccc54)ccc1B3c1ccc(-n3c4c(c5ccccc53)CCC4)cc1O2] 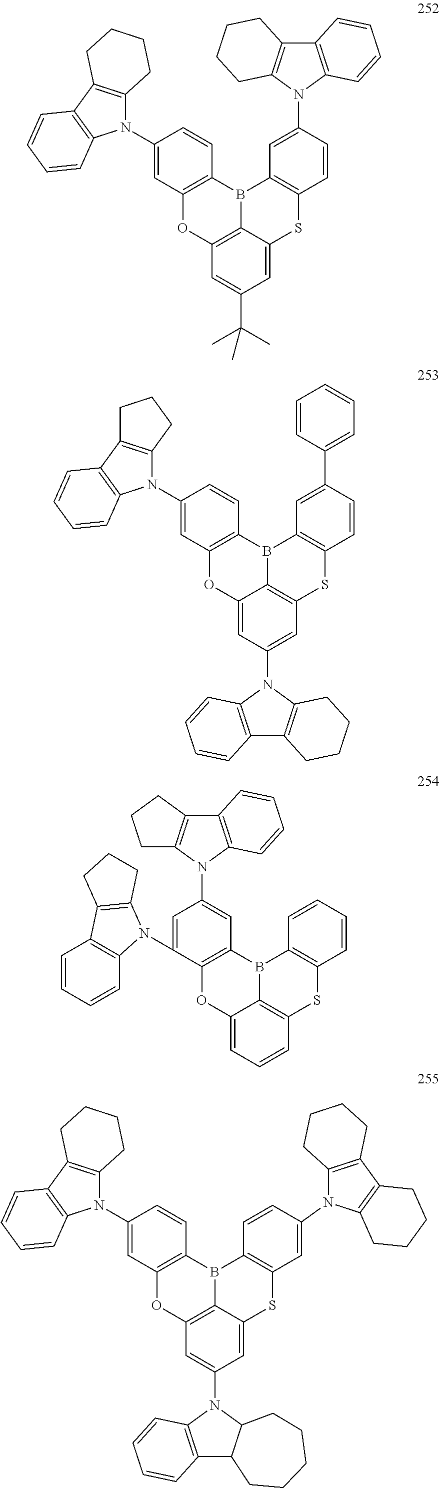 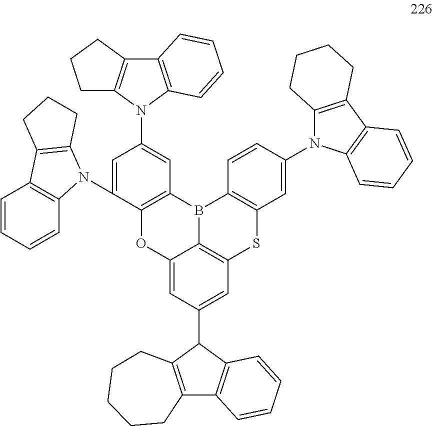 [SMILES: c1ccc2c(c1)C1=C(CCCCC1)C2c1cc2c3c(c1)Sc1cc(-n4c5c(c6ccccc64)CCCC5)ccc1B3c1cc(-n3c4c(c5ccccc53)CCC4)cc(-n3c4c(c5ccccc53)CCC4)c1O2] 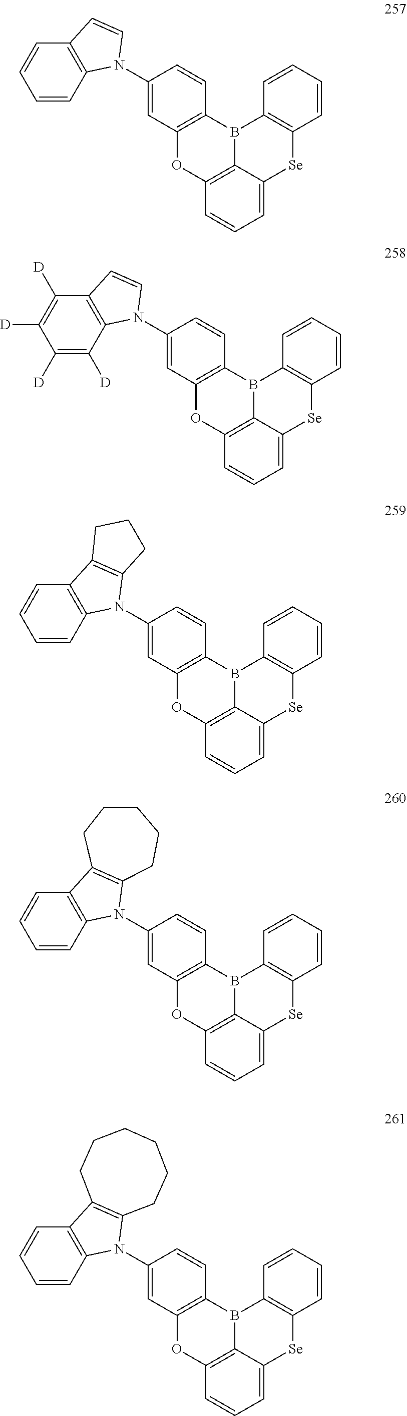 [SMILES: c1ccc2c(c1)[Se]c1cccc3c1B2c1ccc(-n2ccc4ccccc42)cc1O3 ; [2H]c1c([2H])c([2H])c2c(ccn2-c2ccc3c(c2)Oc2cccc4c2B3c2ccccc2[Se]4)c1[2H] ; c1ccc2c(c1)[Se]c1cccc3c1B2c1ccc(-n2c4c(c5ccccc52)CCC4)cc1O3 ; c1ccc2c(c1)[Se]c1cccc3c1B2c1ccc(-n2c4c(c5ccccc52)CCCCC4)cc1O3 ; c1ccc2c(c1)[Se]c1cccc3c1B2c1ccc(-n2c4c(c5ccccc52)CCCCCC4)cc1O3] 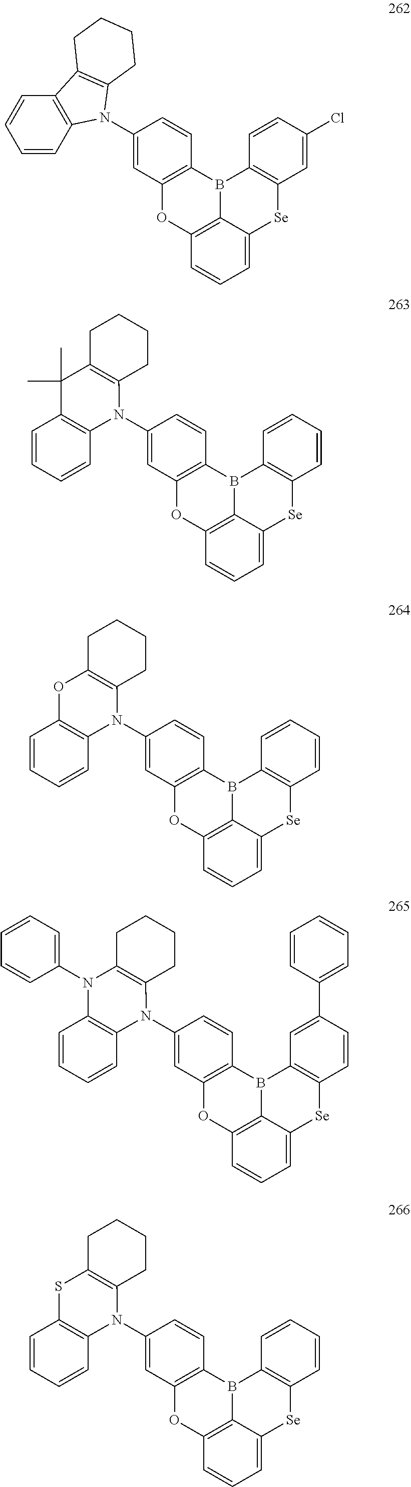 [SMILES: Clc1ccc2c(c1)[Se]c1cccc3c1B2c1ccc(-n2c4c(c5ccccc52)CCCC4)cc1O3 ; CC1(C)C2=C(CCCC2)N(c2ccc3c(c2)Oc2cccc4c2B3c2ccccc2[Se]4)c2ccccc21 ; c1ccc2c(c1)OC1=C(CCCC1)N2c1ccc2c(c1)Oc1cccc3c1B2c1ccccc1[Se]3 ; c1ccc(-c2ccc3c(c2)B2c4ccc(N5C6=C(CCCC6)N(c6ccccc6)c6ccccc65)cc4Oc4cccc(c42)[Se]3)cc1 ; c1ccc2c(c1)SC1=C(CCCC1)N2c1ccc2c(c1)Oc1cccc3c1B2c1ccccc1[Se]3] 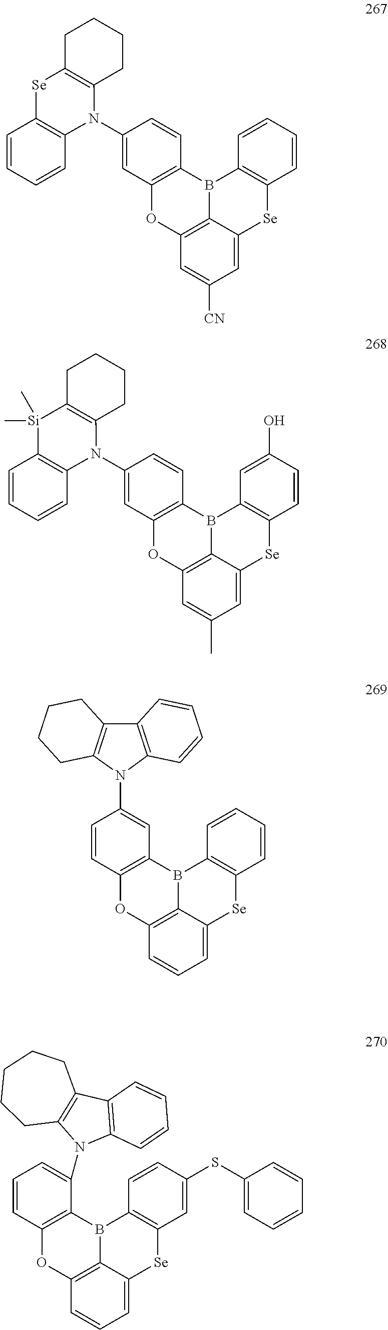 [SMILES: N#Cc1cc2c3c(c1)[Se]c1ccccc1B3c1ccc(N3C4=C(CCCC4)[Se]c4ccccc43)cc1O2 ; Cc1cc2c3c(c1)[Se]c1ccc(O)cc1B3c1ccc(N3C4=C(CCCC4)[Si](C)(C)c4ccccc43)cc1O2 ; c1ccc2c(c1)[Se]c1cccc3c1B2c1cc(-n2c4c(c5ccccc52)CCCC4)ccc1O3 ; c1ccc(Sc2ccc3c(c2)[Se]c2cccc4c2B3c2c(cccc2-n2c3c(c5ccccc52)CCCCC3)O4)cc1] 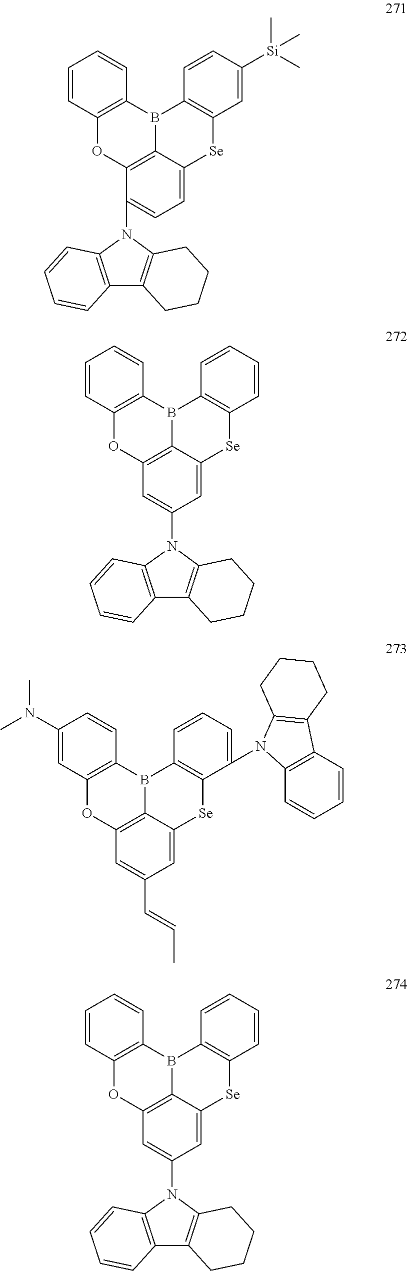 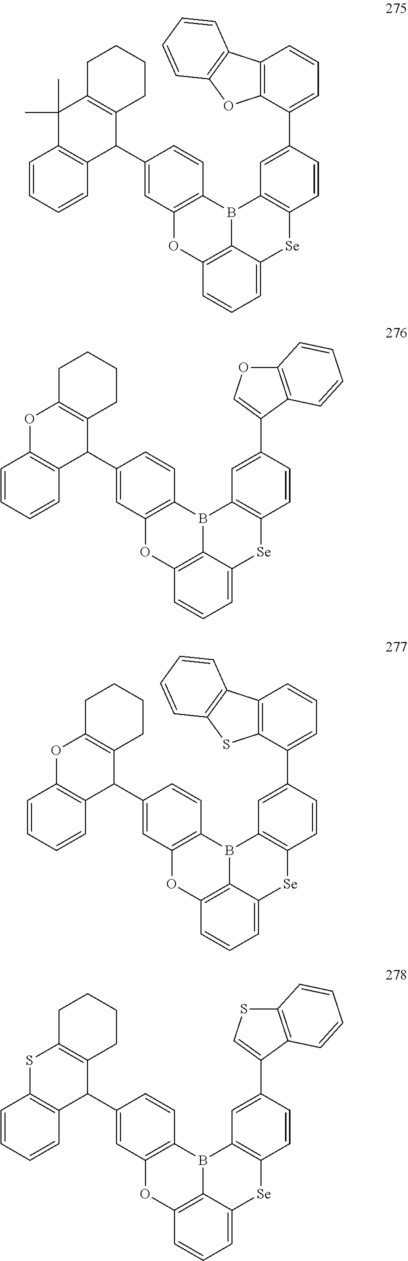 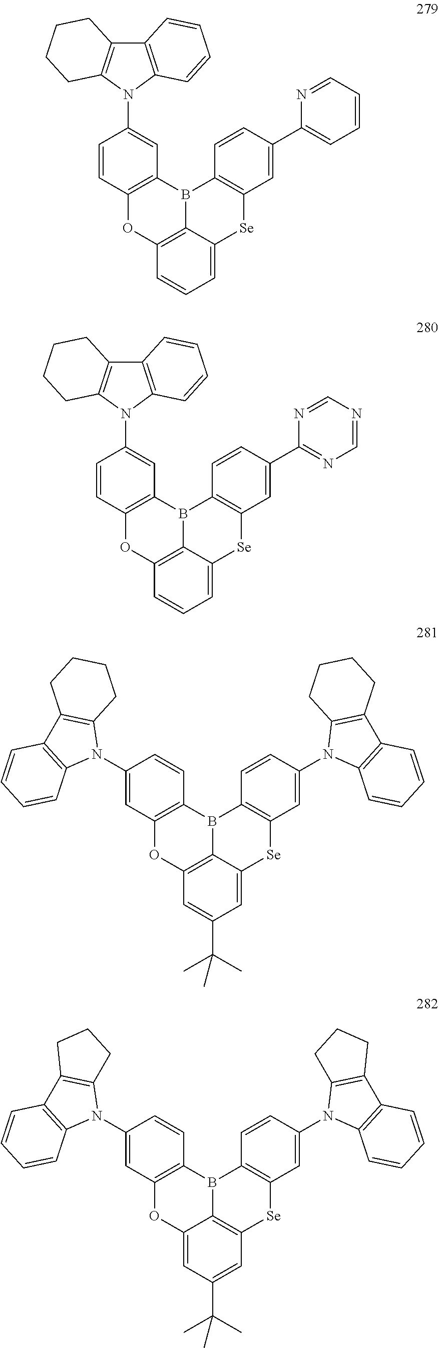 [SMILES: c1ccc(-c2ccc3c(c2)[Se]c2cccc4c2B3c2cc(-n3c5c(c6ccccc63)CCCC5)ccc2O4)nc1 ; c1cc2c3c(c1)[Se]c1cc(-c4ncncn4)ccc1B3c1cc(-n3c4c(c5ccccc53)CCCC4)ccc1O2 ; CC(C)(C)c1cc2c3c(c1)[Se]c1cc(-n4c5c(c6ccccc64)CCCC5)ccc1B3c1ccc(-n3c4c(c5ccccc53)CCCC4)cc1O2 ; CC(C)(C)c1cc2c3c(c1)[Se]c1cc(-n4c5c(c6ccccc64)CCC5)ccc1B3c1ccc(-n3c4c(c5ccccc53)CCC4)cc1O2] 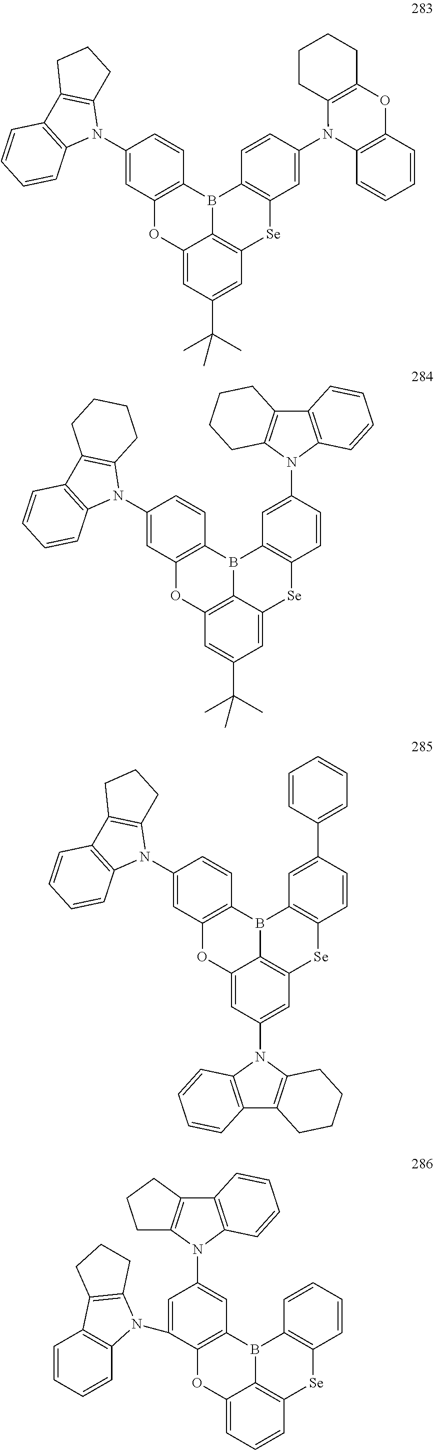 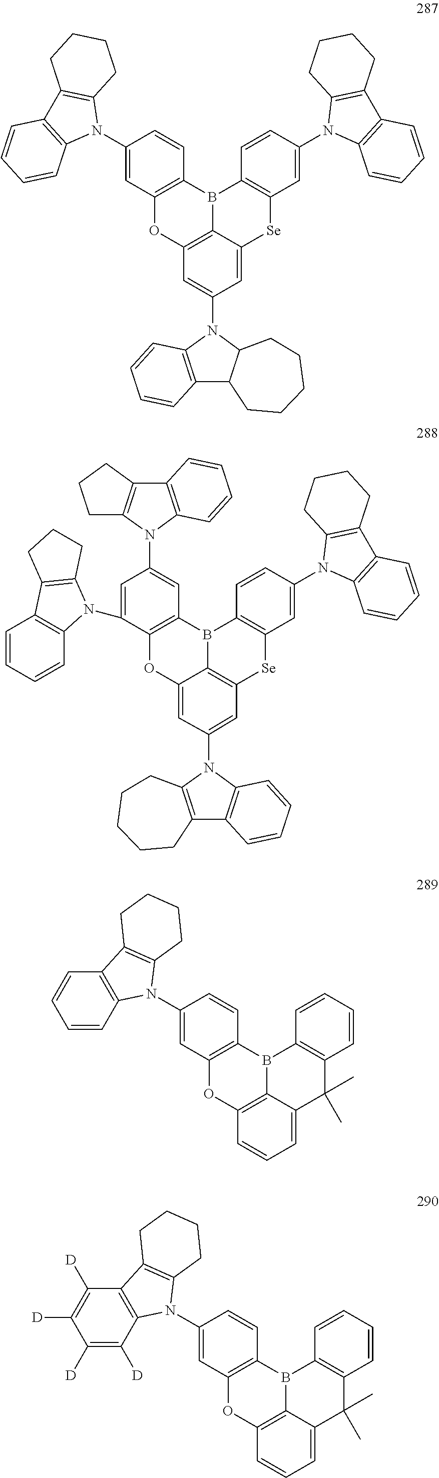 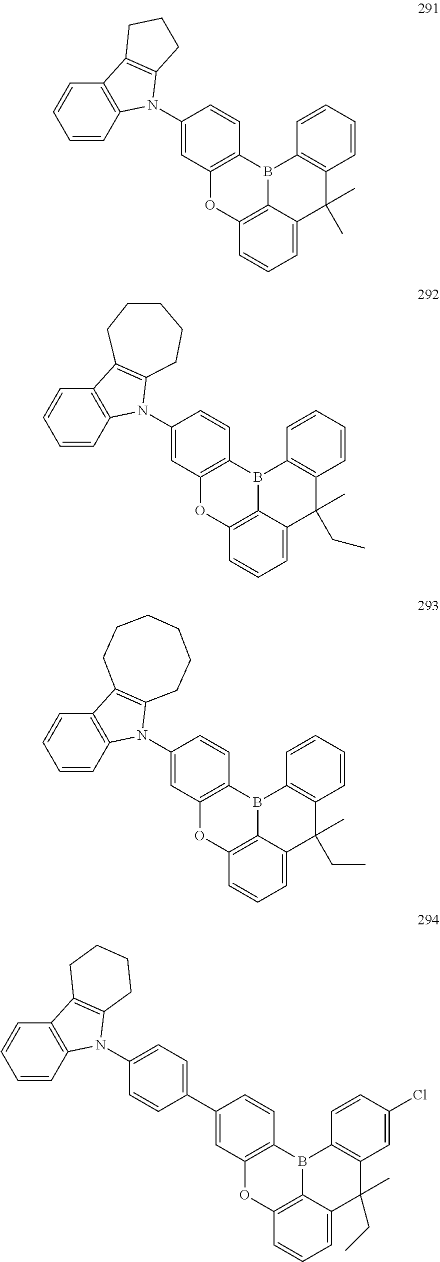 [SMILES: CC1(C)c2ccccc2B2c3ccc(-n4c5c(c6ccccc64)CCC5)cc3Oc3cccc1c32 ; CCC1(C)c2ccccc2B2c3ccc(-n4c5c(c6ccccc64)CCCCC5)cc3Oc3cccc1c32 ; CCC1(C)c2ccccc2B2c3ccc(-n4c5c(c6ccccc64)CCCCCC5)cc3Oc3cccc1c32 ; CCC1(C)c2cc(Cl)ccc2B2c3ccc(-c4ccc(-n5c6c(c7ccccc75)CCCC6)cc4)cc3Oc3cccc1c32] 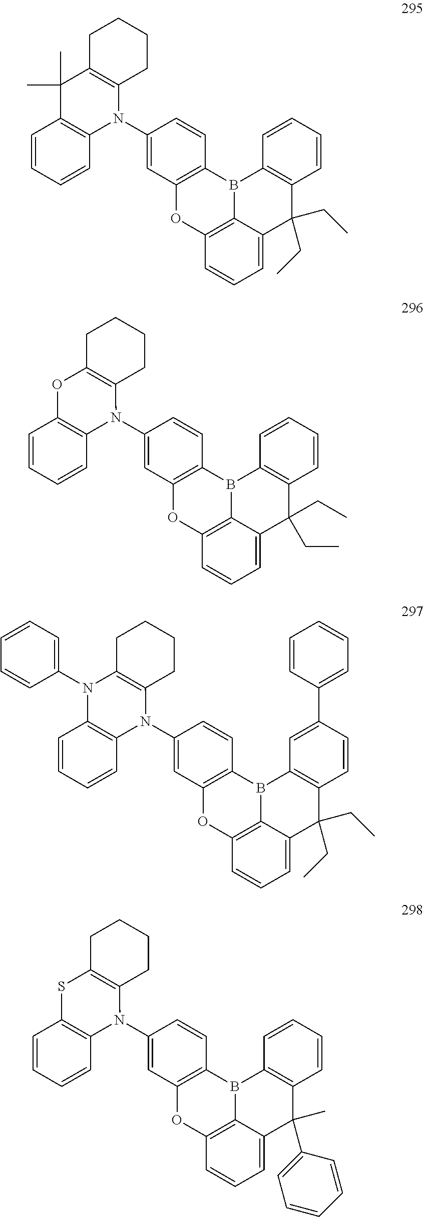 [SMILES: CCC1(CC)c2ccccc2B2c3ccc(N4C5=C(CCCC5)C(C)(C)c5ccccc54)cc3Oc3cccc1c32 ; CCC1(CC)c2ccccc2B2c3ccc(N4C5=C(CCCC5)Oc5ccccc54)cc3Oc3cccc1c32 ; CCC1(CC)c2ccc(-c3ccccc3)cc2B2c3ccc(N4C5=C(CCCC5)N(c5ccccc5)c5ccccc54)cc3Oc3cccc1c32 ; CC1(c2ccccc2)c2ccccc2B2c3ccc(N4C5=C(CCCC5)Sc5ccccc54)cc3Oc3cccc1c32] 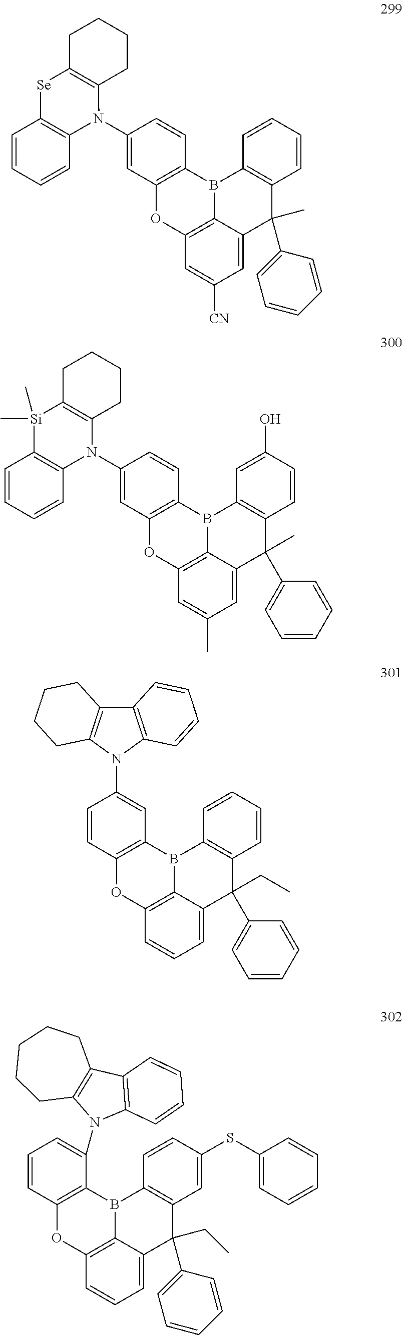 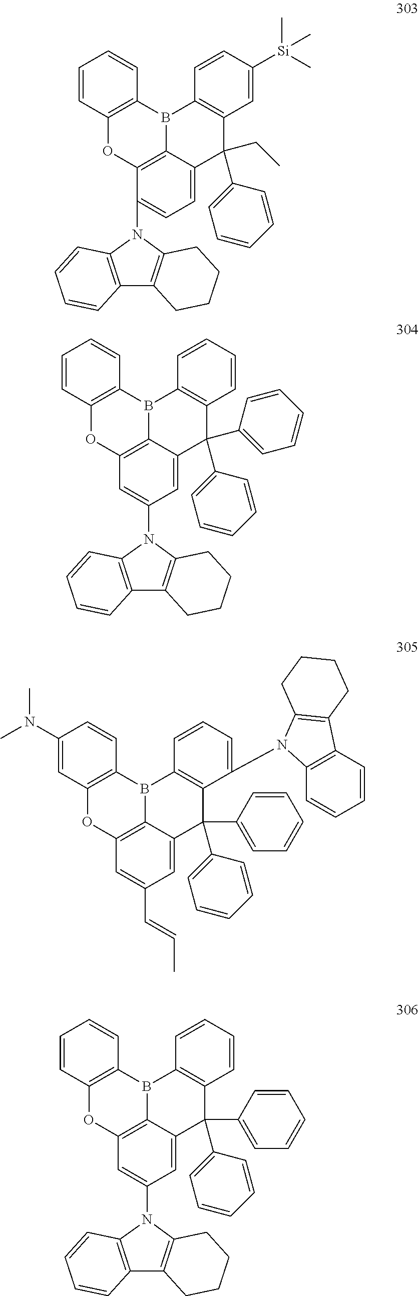 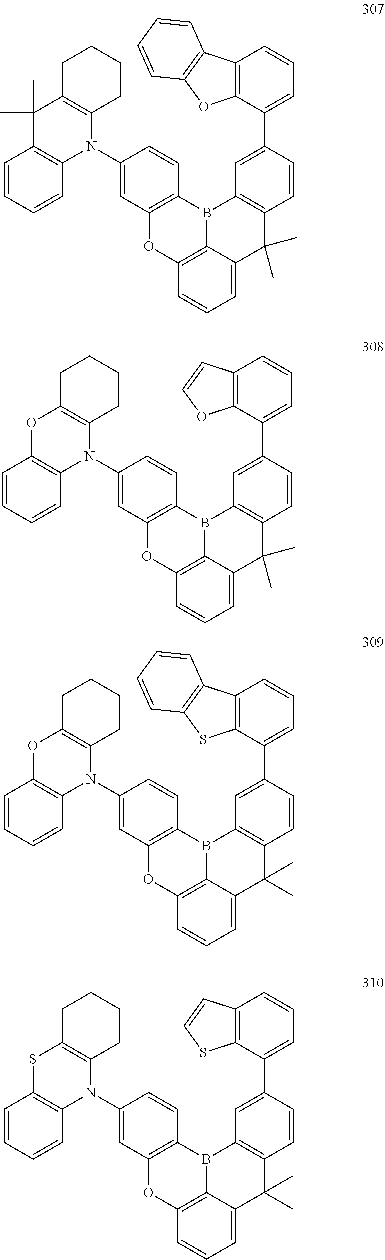 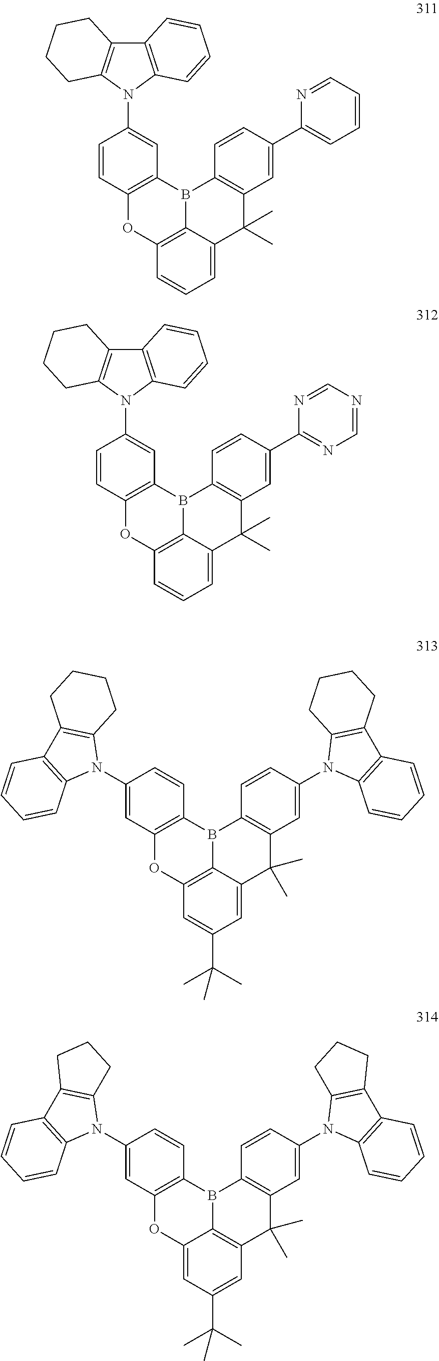 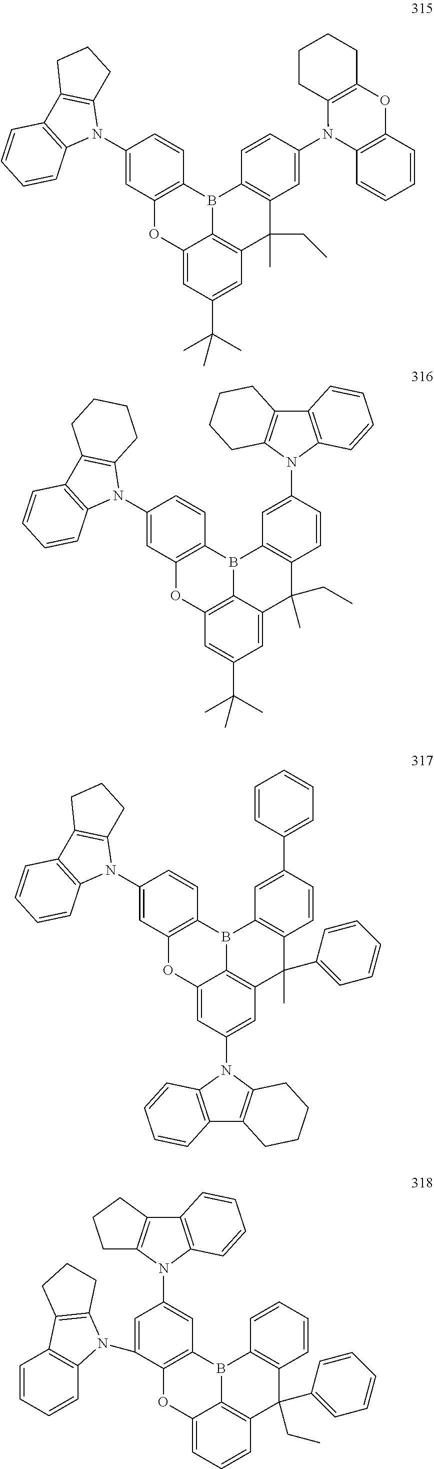 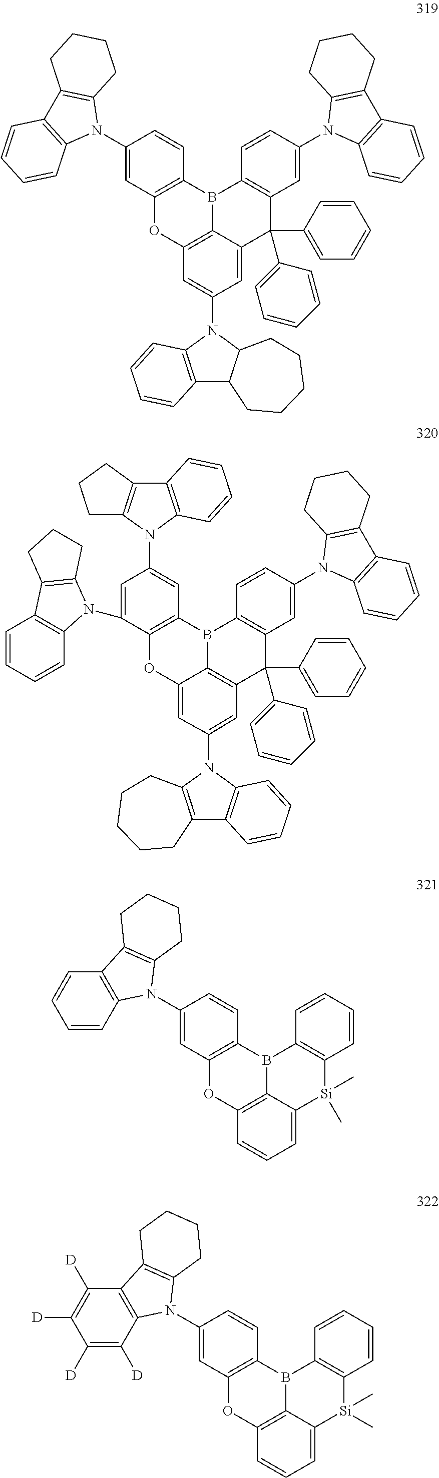 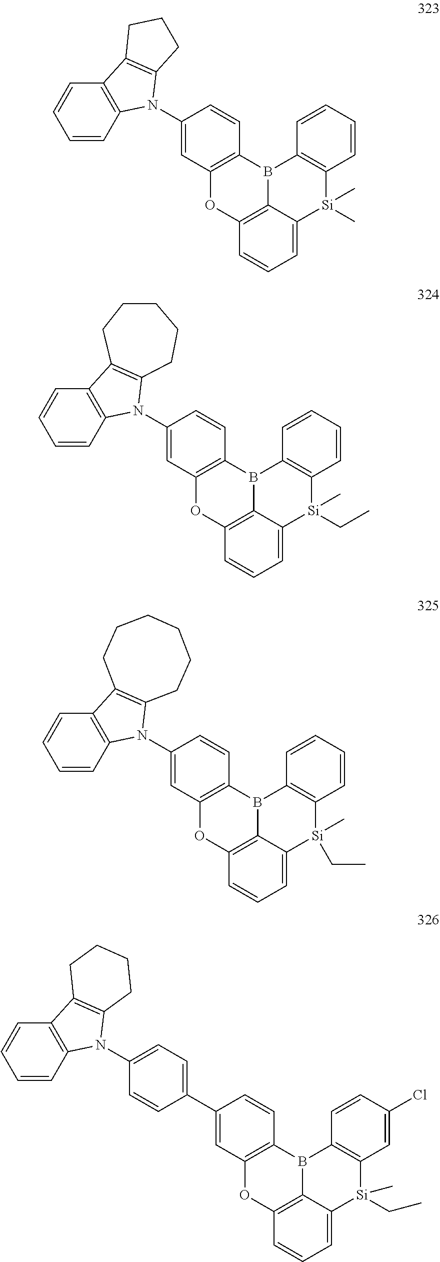 [SMILES: C[Si]1(C)c2ccccc2B2c3ccc(-n4c5c(c6ccccc64)CCC5)cc3Oc3cccc1c32 ; CC[Si]1(C)c2ccccc2B2c3ccc(-n4c5c(c6ccccc64)CCCCC5)cc3Oc3cccc1c32 ; CC[Si]1(C)c2ccccc2B2c3ccc(-n4c5c(c6ccccc64)CCCCCC5)cc3Oc3cccc1c32 ; CC[Si]1(C)c2cc(Cl)ccc2B2c3ccc(-c4ccc(-n5c6c(c7ccccc75)CCCC6)cc4)cc3Oc3cccc1c32] 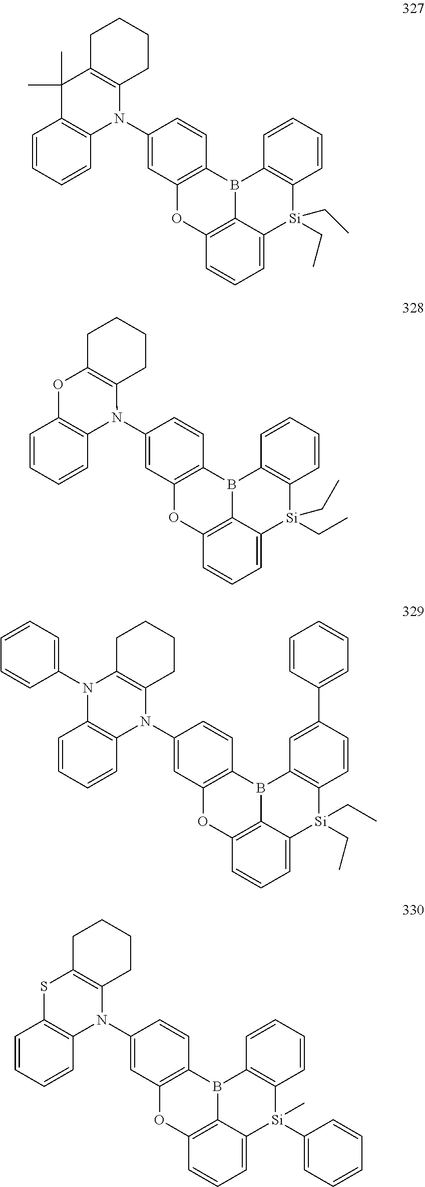 [SMILES: CC[Si]1(CC)c2ccccc2B2c3ccc(N4C5=C(CCCC5)C(C)(C)c5ccccc54)cc3Oc3cccc1c32 ; CC[Si]1(CC)c2ccccc2B2c3ccc(N4C5=C(CCCC5)Oc5ccccc54)cc3Oc3cccc1c32 ; CC[Si]1(CC)c2ccc(-c3ccccc3)cc2B2c3ccc(N4C5=C(CCCC5)N(c5ccccc5)c5ccccc54)cc3Oc3cccc1c32 ; C[Si]1(c2ccccc2)c2ccccc2B2c3ccc(N4C5=C(CCCC5)Sc5ccccc54)cc3Oc3cccc1c32] 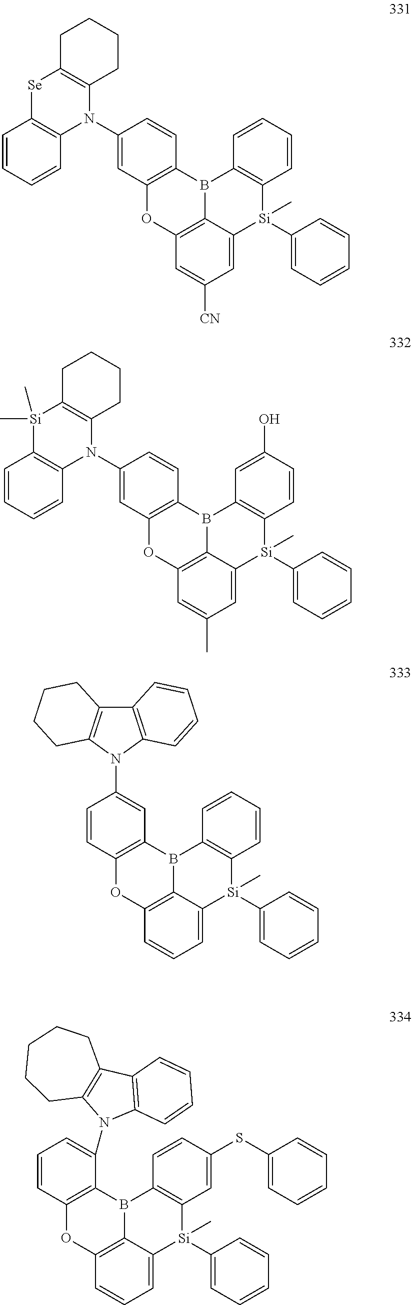 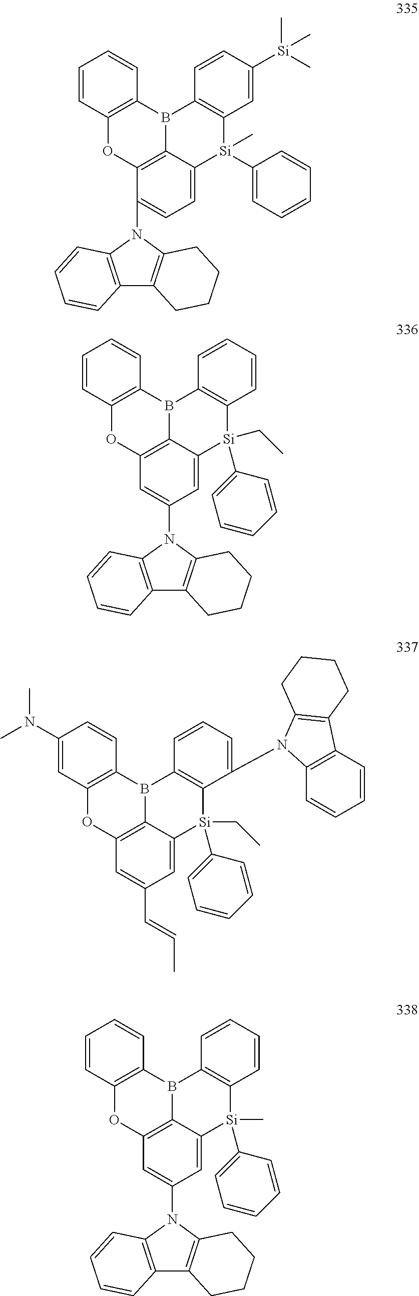 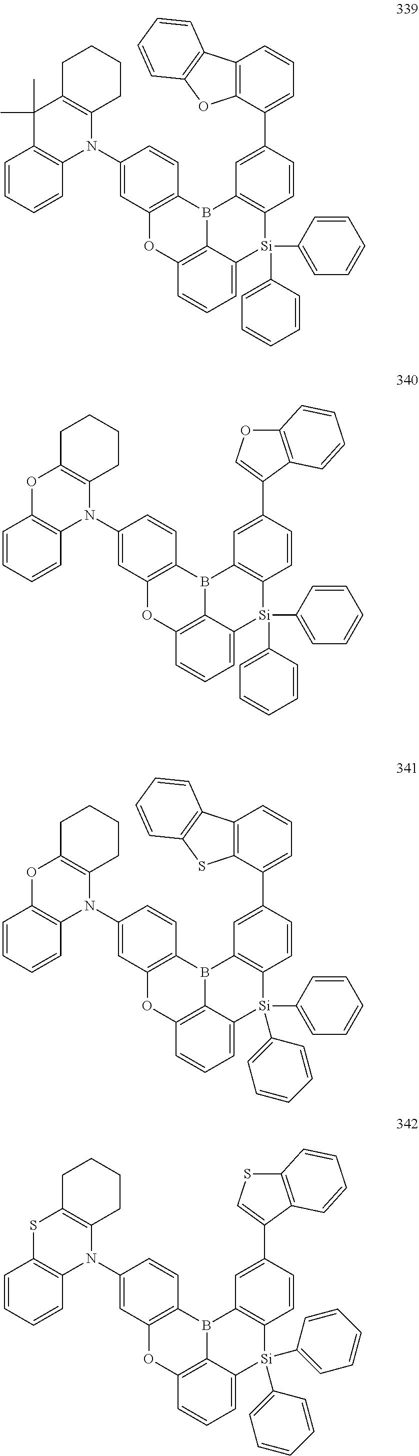 [SMILES: CC1(C)C2=C(CCCC2)N(c2ccc3c(c2)Oc2cccc4c2B3c2cc(-c3cccc5c3oc3ccccc35)ccc2[Si]4(c2ccccc2)c2ccccc2)c2ccccc21 ; c1ccc([Si]2(c3ccccc3)c3ccc(-c4coc5ccccc45)cc3B3c4ccc(N5C6=C(CCCC6)Oc6ccccc65)cc4Oc4cccc2c43)cc1 ; c1ccc([Si]2(c3ccccc3)c3ccc(-c4cccc5c4sc4ccccc45)cc3B3c4ccc(N5C6=C(CCCC6)Oc6ccccc65)cc4Oc4cccc2c43)cc1 ; c1ccc([Si]2(c3ccccc3)c3ccc(-c4csc5ccccc45)cc3B3c4ccc(N5C6=C(CCCC6)Sc6ccccc65)cc4Oc4cccc2c43)cc1] 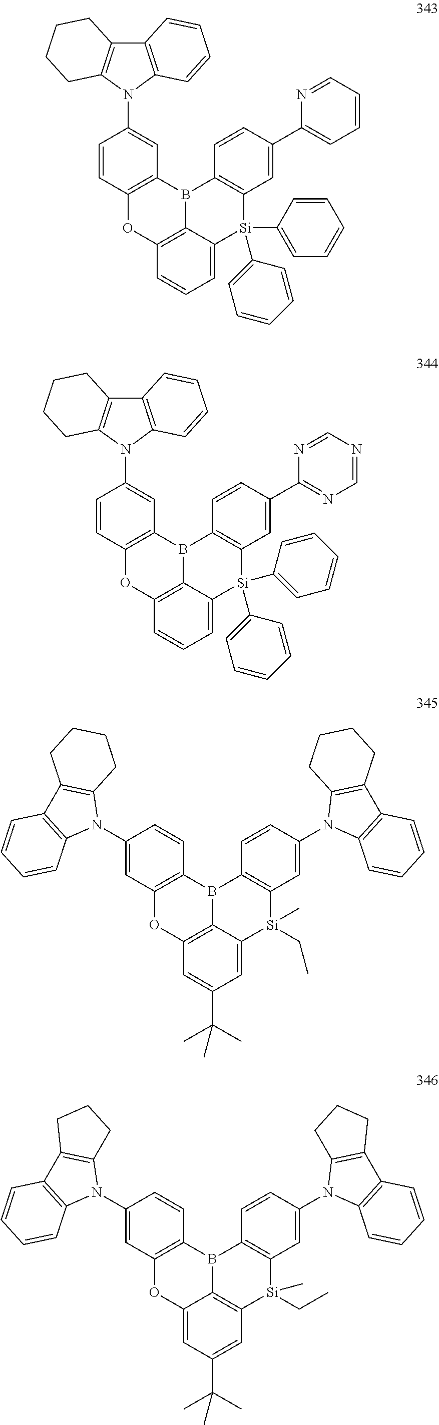 [SMILES: c1ccc([Si]2(c3ccccc3)c3cc(-c4ccccn4)ccc3B3c4cc(-n5c6c(c7ccccc75)CCCC6)ccc4Oc4cccc2c43)cc1 ; c1ccc([Si]2(c3ccccc3)c3cc(-c4ncncn4)ccc3B3c4cc(-n5c6c(c7ccccc75)CCCC6)ccc4Oc4cccc2c43)cc1 ; CC[Si]1(C)c2cc(-n3c4c(c5ccccc53)CCCC4)ccc2B2c3ccc(-n4c5c(c6ccccc64)CCCC5)cc3Oc3cc(C(C)(C)C)cc1c32 ; CC[Si]1(C)c2cc(-n3c4c(c5ccccc53)CCC4)ccc2B2c3ccc(-n4c5c(c6ccccc64)CCC5)cc3Oc3cc(C(C)(C)C)cc1c32] 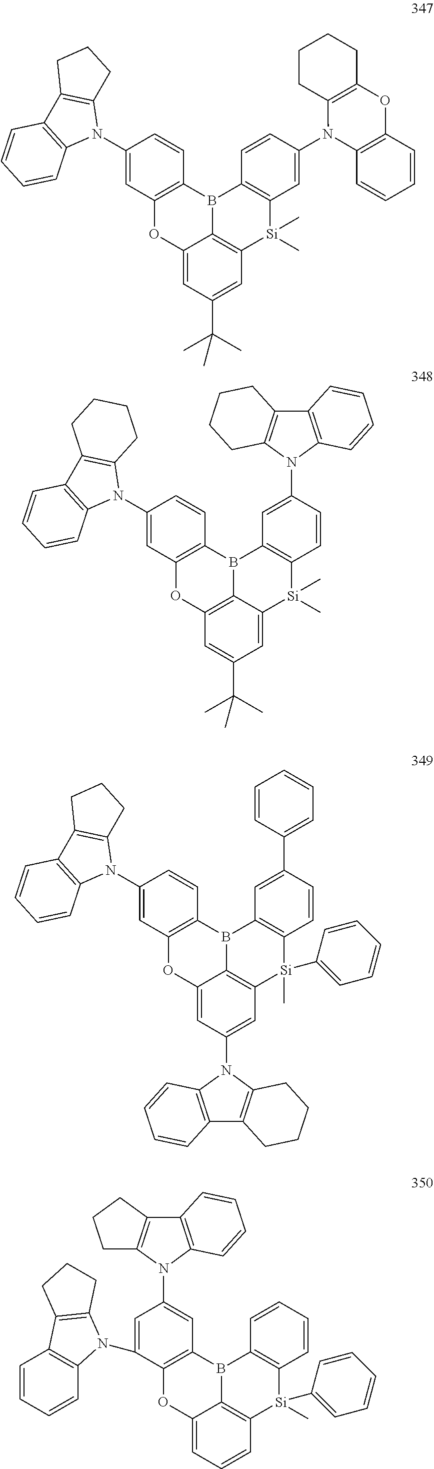 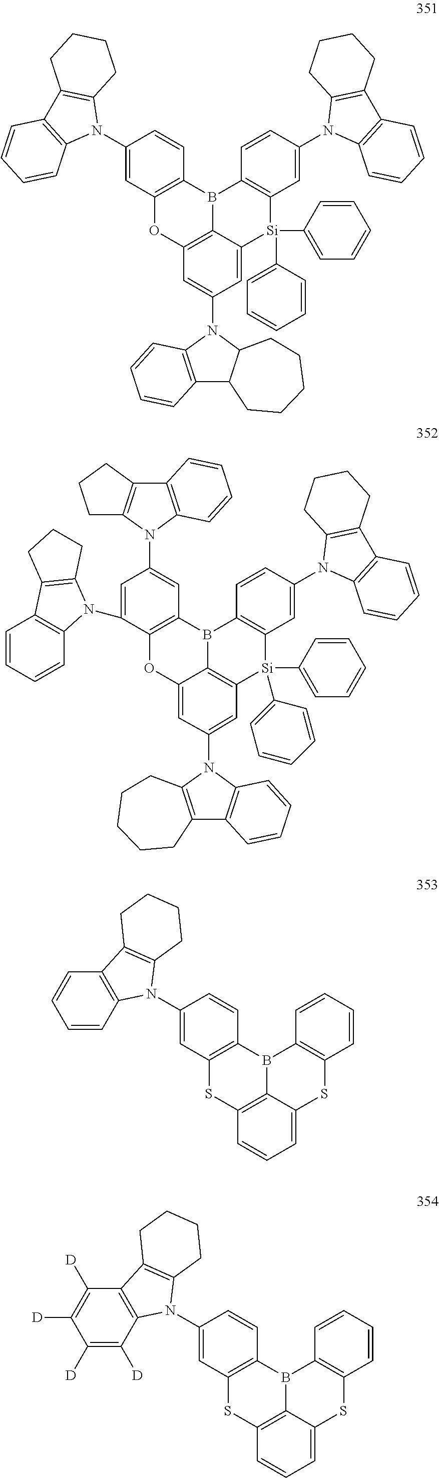 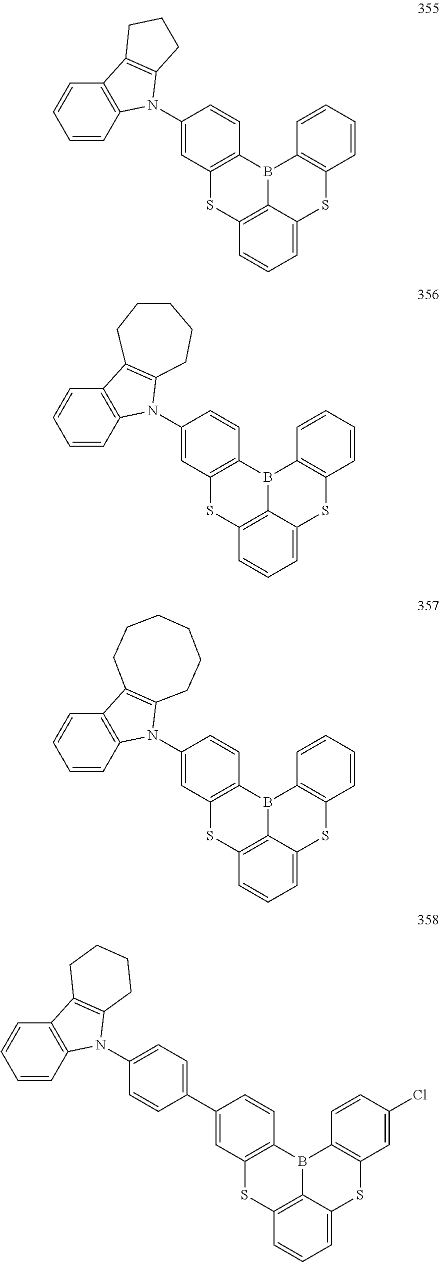 [SMILES: c1ccc2c(c1)Sc1cccc3c1B2c1ccc(-n2c4c(c5ccccc52)CCC4)cc1S3 ; c1ccc2c(c1)Sc1cccc3c1B2c1ccc(-n2c4c(c5ccccc52)CCCCC4)cc1S3 ; c1ccc2c(c1)Sc1cccc3c1B2c1ccc(-n2c4c(c5ccccc52)CCCCCC4)cc1S3 ; Clc1ccc2c(c1)Sc1cccc3c1B2c1ccc(-c2ccc(-n4c5c(c6ccccc64)CCCC5)cc2)cc1S3] 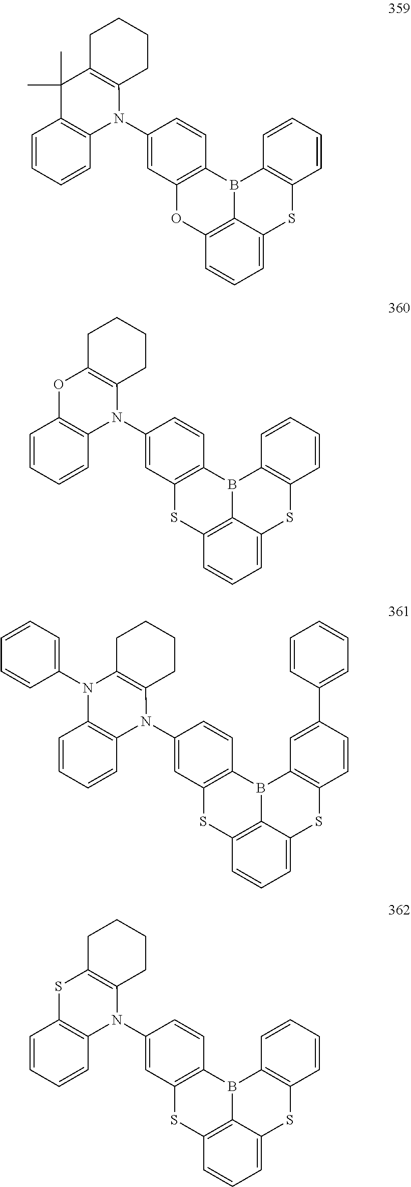 [SMILES: CC1(C)C2=C(CCCC2)N(c2ccc3c(c2)Oc2cccc4c2B3c2ccccc2S4)c2ccccc21 ; c1ccc2c(c1)OC1=C(CCCC1)N2c1ccc2c(c1)Sc1cccc3c1B2c1ccccc1S3 ; c1ccc(-c2ccc3c(c2)B2c4ccc(N5C6=C(CCCC6)N(c6ccccc6)c6ccccc65)cc4Sc4cccc(c42)S3)cc1 ; c1ccc2c(c1)Sc1cccc3c1B2c1ccc(N2C4=C(CCCC4)Sc4ccccc42)cc1S3] 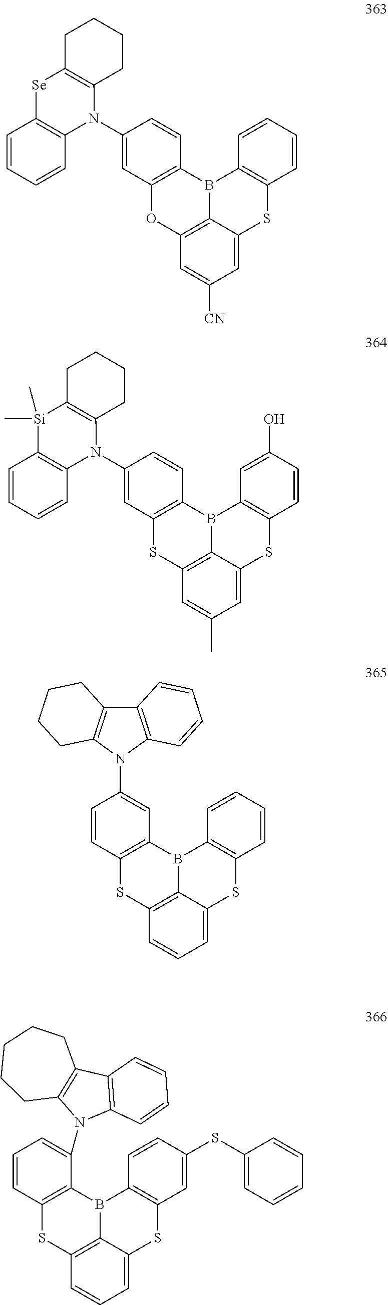 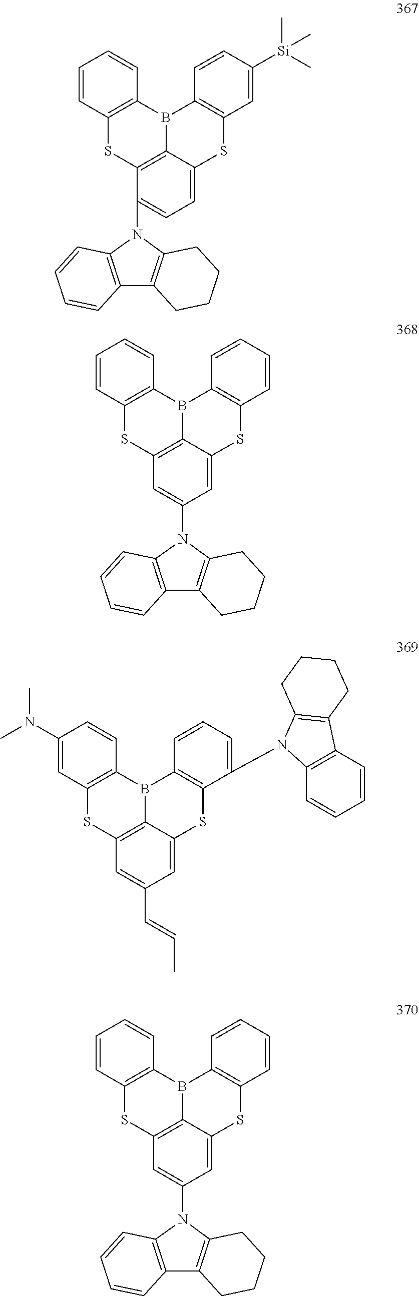 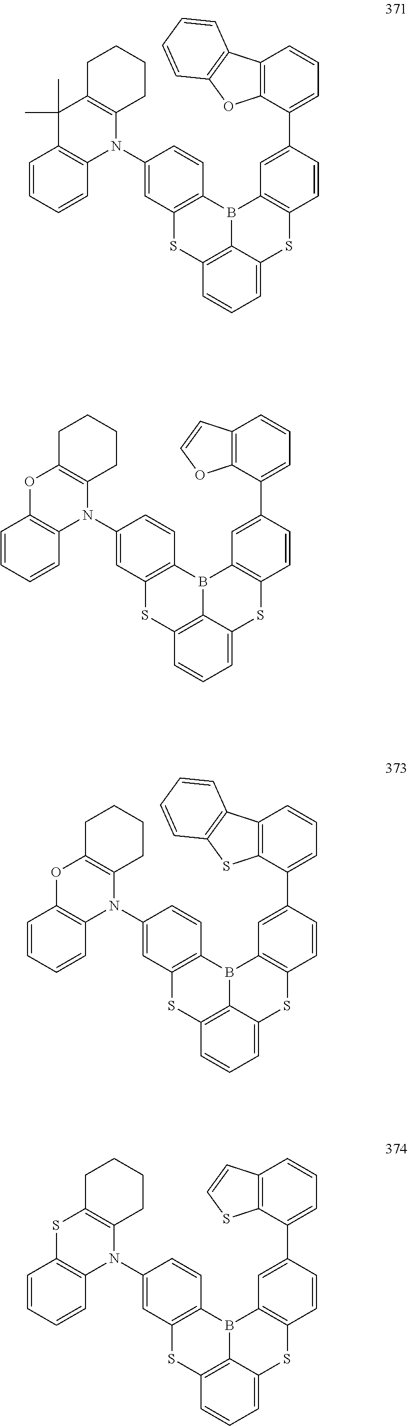 [SMILES: CC1(C)C2=C(CCCC2)N(c2ccc3c(c2)Sc2cccc4c2B3c2cc(-c3cccc5c3oc3ccccc35)ccc2S4)c2ccccc21 ; c1ccc2c(c1)OC1=C(CCCC1)N2c1ccc2c(c1)Sc1cccc3c1B2c1cc(-c2cccc4ccoc24)ccc1S3 ; c1ccc2c(c1)OC1=C(CCCC1)N2c1ccc2c(c1)Sc1cccc3c1B2c1cc(-c2cccc4c2sc2ccccc24)ccc1S3 ; c1ccc2c(c1)SC1=C(CCCC1)N2c1ccc2c(c1)Sc1cccc3c1B2c1cc(-c2cccc4ccsc24)ccc1S3] 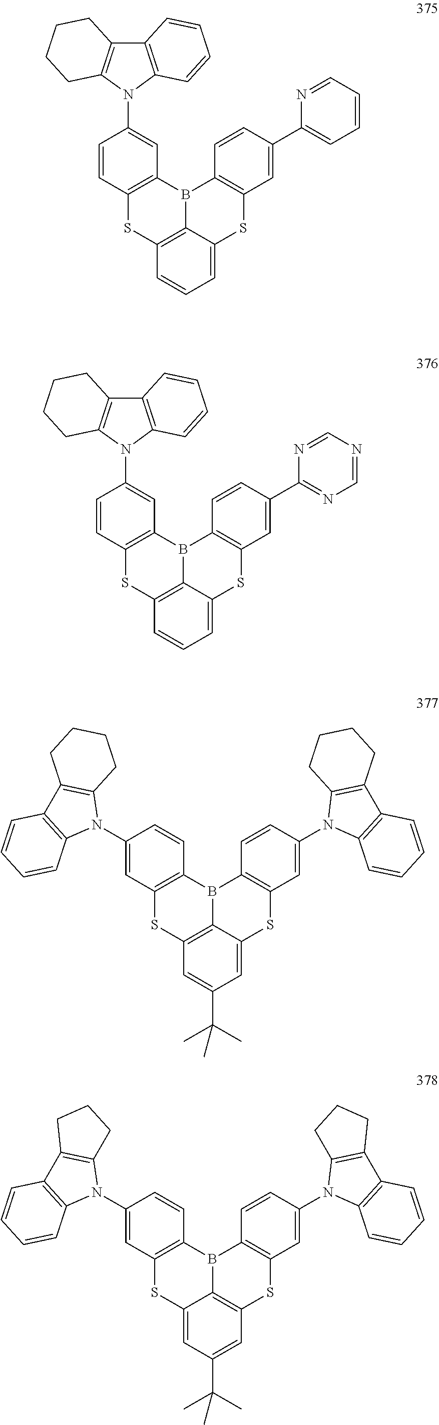 [SMILES: c1ccc(-c2ccc3c(c2)Sc2cccc4c2B3c2cc(-n3c5c(c6ccccc63)CCCC5)ccc2S4)nc1 ; c1cc2c3c(c1)Sc1ccc(-n4c5c(c6ccccc64)CCCC5)cc1B3c1ccc(-c3ncncn3)cc1S2 ; CC(C)(C)c1cc2c3c(c1)Sc1cc(-n4c5c(c6ccccc64)CCCC5)ccc1B3c1ccc(-n3c4c(c5ccccc53)CCCC4)cc1S2 ; CC(C)(C)c1cc2c3c(c1)Sc1cc(-n4c5c(c6ccccc64)CCC5)ccc1B3c1ccc(-n3c4c(c5ccccc53)CCC4)cc1S2] 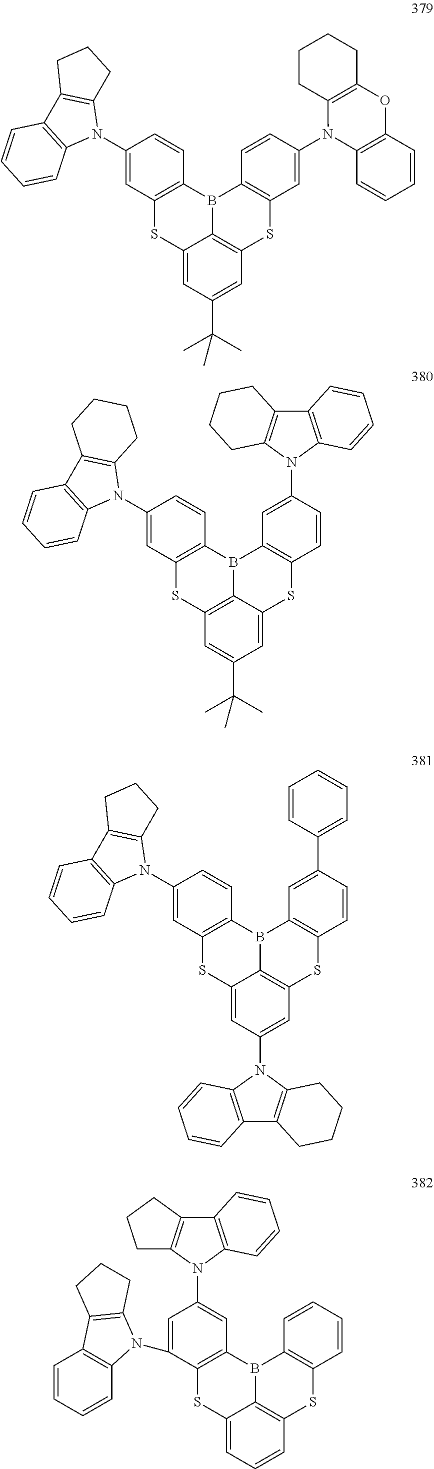 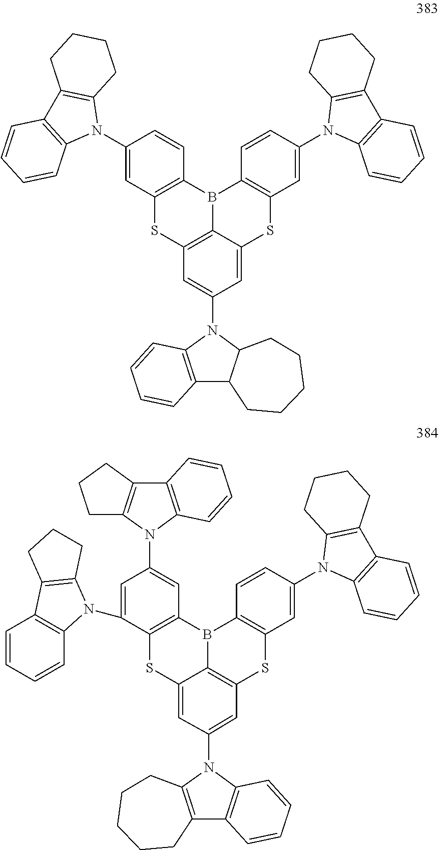 [SMILES: c1ccc2c(c1)C1CCCCCC1N2c1cc2c3c(c1)Sc1cc(-n4c5c(c6ccccc64)CCCC5)ccc1B3c1ccc(-n3c4c(c5ccccc53)CCCC4)cc1S2 ; c1ccc2c(c1)c1c(n2-c2cc3c4c(c2)Sc2c(cc(-n5c6c(c7ccccc75)CCC6)cc2-n2c5c(c6ccccc62)CCC5)B4c2ccc(-n4c5c(c6ccccc64)CCCC5)cc2S3)CCCCC1] 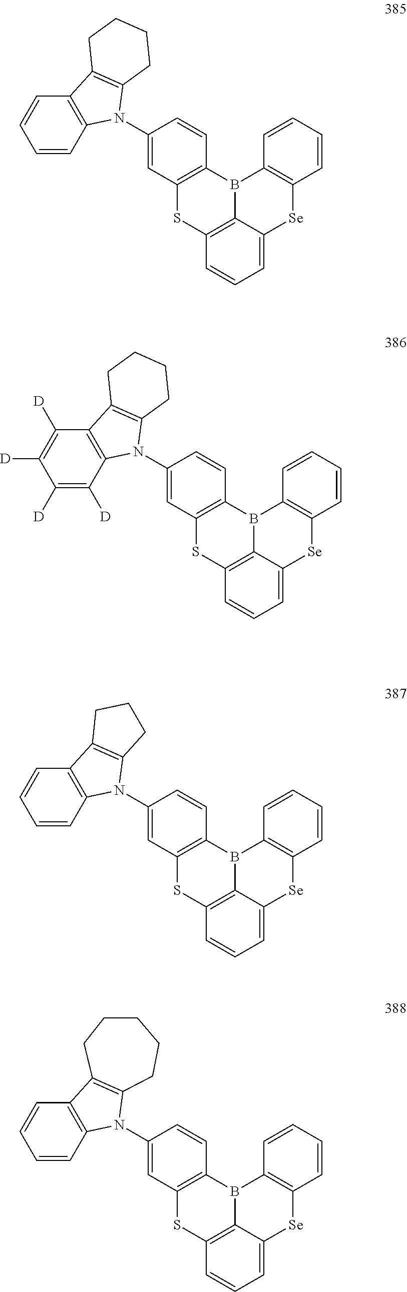 [SMILES: c1ccc2c(c1)[Se]c1cccc3c1B2c1ccc(-n2c4c(c5ccccc52)CCCC4)cc1S3 ; [2H]c1c([2H])c([2H])c2c(c1[2H])c1c(n2-c2ccc3c(c2)Sc2cccc4c2B3c2ccccc2[Se]4)CCCC1 ; c1ccc2c(c1)[Se]c1cccc3c1B2c1ccc(-n2c4c(c5ccccc52)CCC4)cc1S3 ; c1ccc2c(c1)[Se]c1cccc3c1B2c1ccc(-n2c4c(c5ccccc52)CCCCC4)cc1S3] 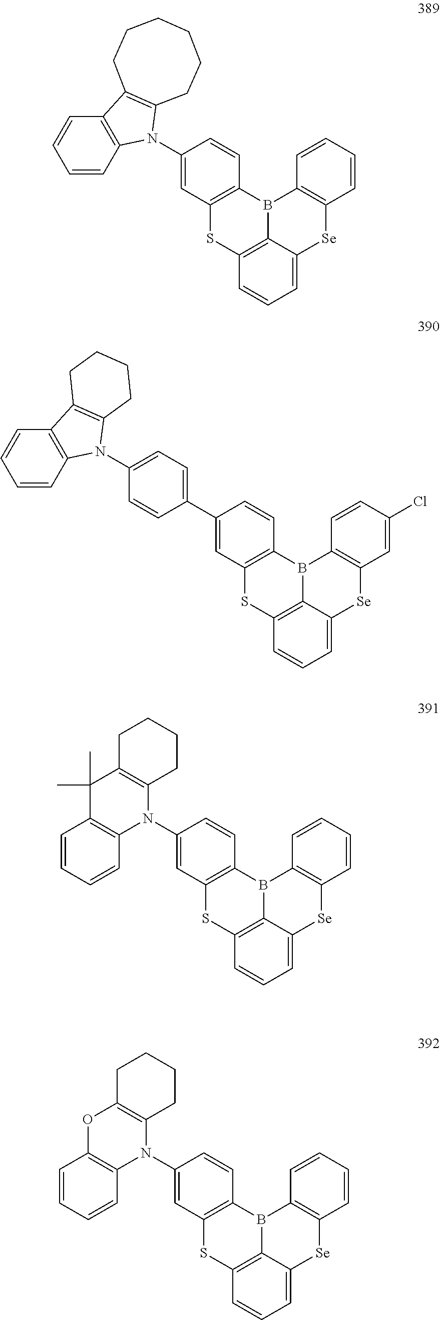 [SMILES: c1ccc2c(c1)[Se]c1cccc3c1B2c1ccc(-n2c4c(c5ccccc52)CCCCCC4)cc1S3 ; Clc1ccc2c(c1)[Se]c1cccc3c1B2c1ccc(-c2ccc(-n4c5c(c6ccccc64)CCCC5)cc2)cc1S3 ; CC1(C)C2=C(CCCC2)N(c2ccc3c(c2)Sc2cccc4c2B3c2ccccc2[Se]4)c2ccccc21 ; c1ccc2c(c1)OC1=C(CCCC1)N2c1ccc2c(c1)Sc1cccc3c1B2c1ccccc1[Se]3] 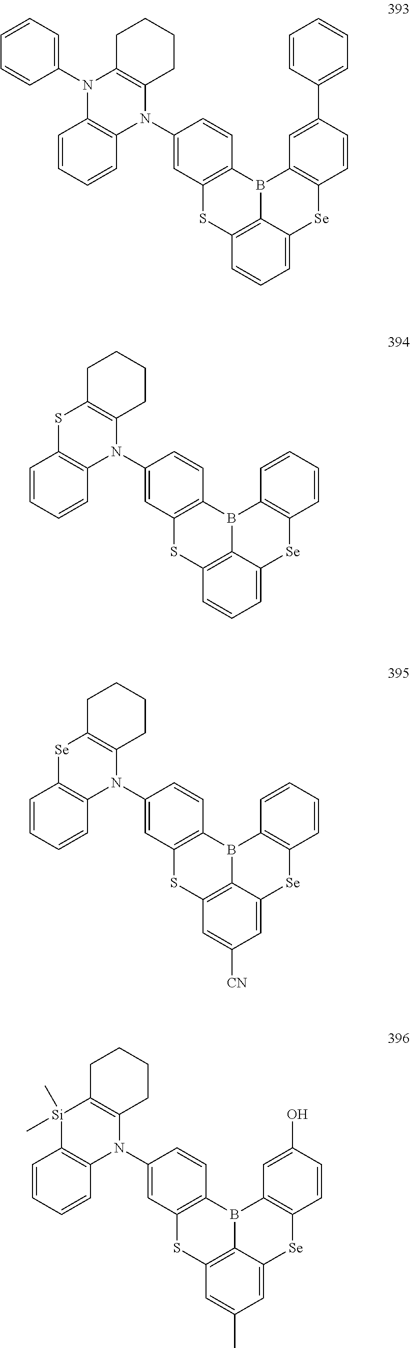 [SMILES: c1ccc(-c2ccc3c(c2)B2c4ccc(N5C6=C(CCCC6)N(c6ccccc6)c6ccccc65)cc4Sc4cccc(c42)[Se]3)cc1 ; c1ccc2c(c1)SC1=C(CCCC1)N2c1ccc2c(c1)Sc1cccc3c1B2c1ccccc1[Se]3 ; N#Cc1cc2c3c(c1)[Se]c1ccccc1B3c1ccc(N3C4=C(CCCC4)[Se]c4ccccc43)cc1S2 ; Cc1cc2c3c(c1)[Se]c1ccc(O)cc1B3c1ccc(N3C4=C(CCCC4)[Si](C)(C)c4ccccc43)cc1S2] 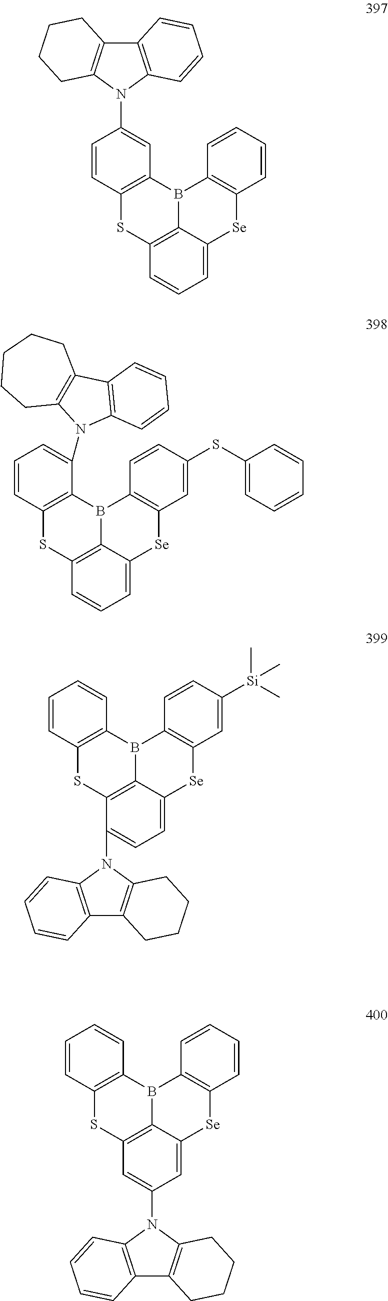 [SMILES: c1ccc2c(c1)[Se]c1cccc3c1B2c1cc(-n2c4c(c5ccccc52)CCCC4)ccc1S3 ; c1ccc(Sc2ccc3c(c2)[Se]c2cccc4c2B3c2c(cccc2-n2c3c(c5ccccc52)CCCCC3)S4)cc1 ; C[Si](C)(C)c1ccc2c(c1)[Se]c1ccc(-n3c4c(c5ccccc53)CCCC4)c3c1B2c1ccccc1S3 ; c1ccc2c(c1)Sc1cc(-n3c4c(c5ccccc53)CCCC4)cc3c1B2c1ccccc1[Se]3] 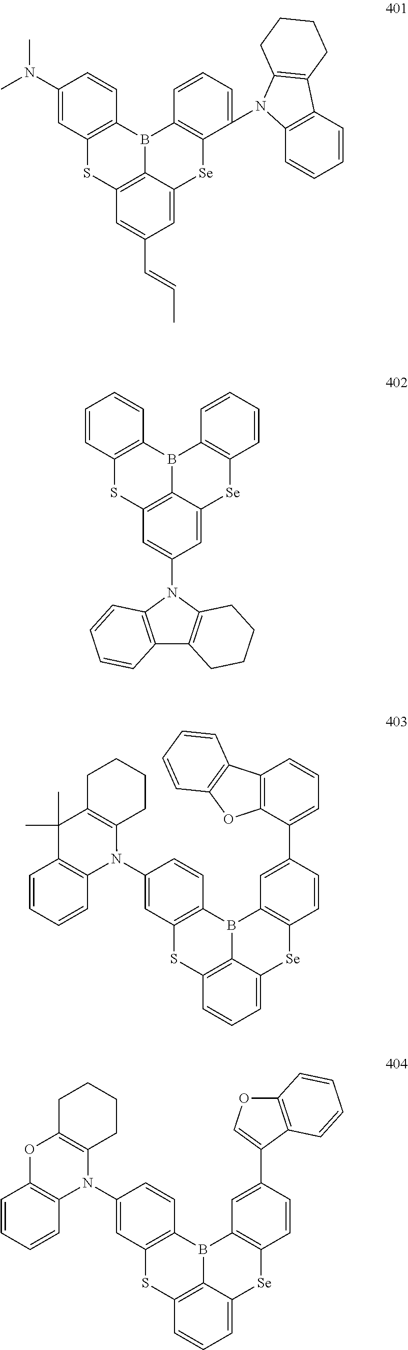 [SMILES: C/C=C/c1cc2c3c(c1)[Se]c1c(cccc1-n1c4c(c5ccccc51)CCCC4)B3c1ccc(N(C)C)cc1S2 ; c1ccc2c(c1)Sc1cc(-n3c4c(c5ccccc53)CCCC4)cc3c1B2c1ccccc1[Se]3 ; CC1(C)C2=C(CCCC2)N(c2ccc3c(c2)Sc2cccc4c2B3c2cc(-c3cccc5c3oc3ccccc35)ccc2[Se]4)c2ccccc21 ; c1ccc2c(c1)OC1=C(CCCC1)N2c1ccc2c(c1)Sc1cccc3c1B2c1cc(-c2coc4ccccc24)ccc1[Se]3] 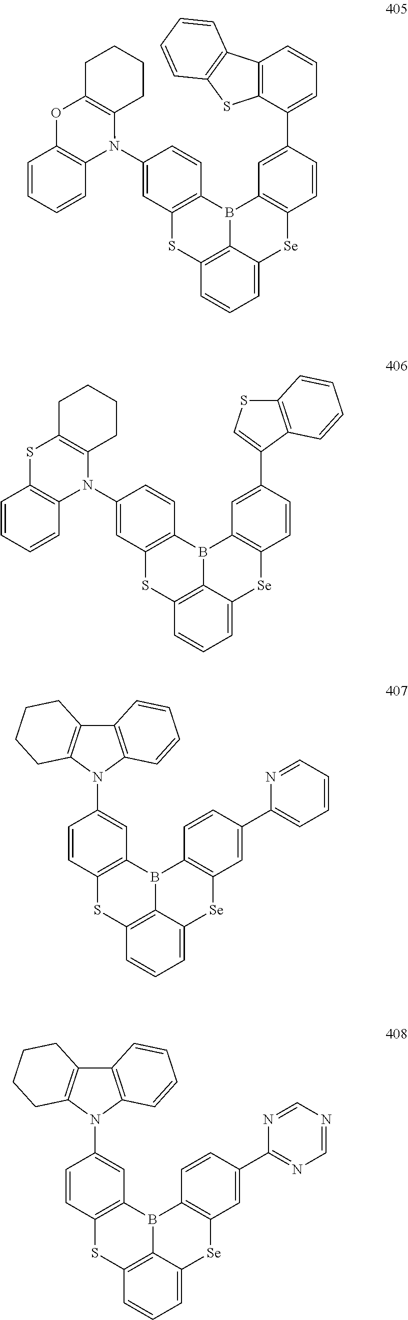 [SMILES: c1ccc2c(c1)OC1=C(CCCC1)N2c1ccc2c(c1)Sc1cccc3c1B2c1cc(-c2cccc4c2sc2ccccc24)ccc1[Se]3 ; c1ccc2c(c1)SC1=C(CCCC1)N2c1ccc2c(c1)Sc1cccc3c1B2c1cc(-c2csc4ccccc24)ccc1[Se]3 ; c1ccc(-c2ccc3c(c2)[Se]c2cccc4c2B3c2cc(-n3c5c(c6ccccc63)CCCC5)ccc2S4)nc1 ; c1cc2c3c(c1)[Se]c1cc(-c4ncncn4)ccc1B3c1cc(-n3c4c(c5ccccc53)CCCC4)ccc1S2] 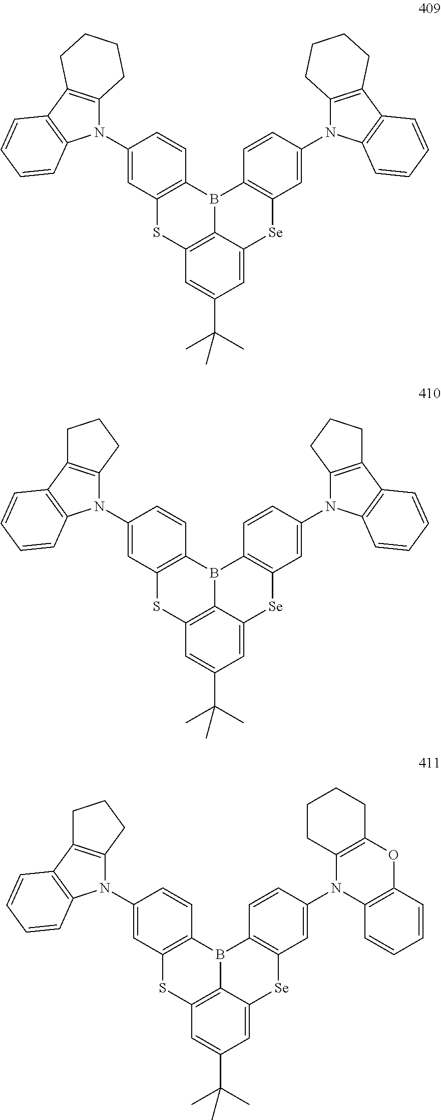 [SMILES: CC(C)(C)c1cc2c3c(c1)[Se]c1cc(-n4c5c(c6ccccc64)CCCC5)ccc1B3c1ccc(-n3c4c(c5ccccc53)CCCC4)cc1S2 ; CC(C)(C)c1cc2c3c(c1)[Se]c1cc(-n4c5c(c6ccccc64)CCC5)ccc1B3c1ccc(-n3c4c(c5ccccc53)CCC4)cc1S2 ; CC(C)(C)c1cc2c3c(c1)[Se]c1cc(N4C5=C(CCCC5)Oc5ccccc54)ccc1B3c1ccc(-n3c4c(c5ccccc53)CCC4)cc1S2] 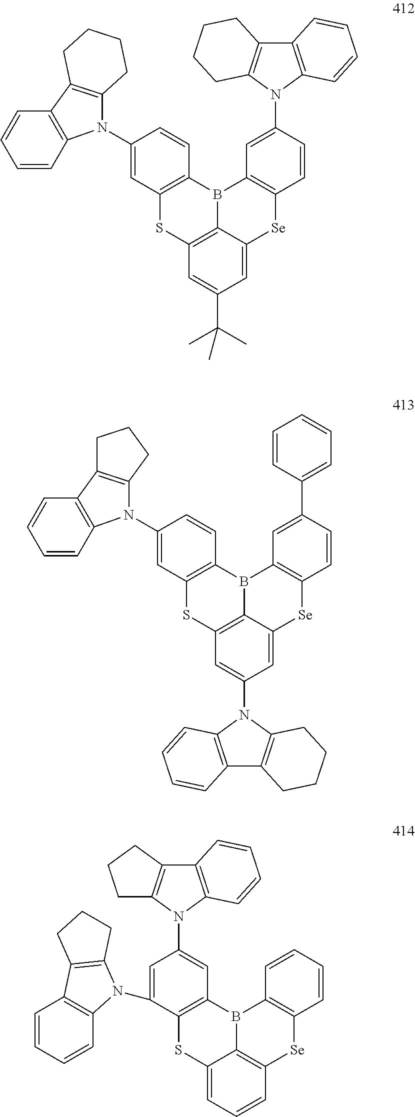 [SMILES: CC(C)(C)c1cc2c3c(c1)[Se]c1ccc(-n4c5c(c6ccccc64)CCCC5)cc1B3c1ccc(-n3c4c(c5ccccc53)CCCC4)cc1S2 ; c1ccc(-c2ccc3c(c2)B2c4ccc(-n5c6c(c7ccccc75)CCC6)cc4Sc4cc(-n5c6c(c7ccccc75)CCCC6)cc(c42)[Se]3)cc1 ; c1ccc2c(c1)[Se]c1cccc3c1B2c1cc(-n2c4c(c5ccccc52)CCC4)cc(-n2c4c(c5ccccc52)CCC4)c1S3] 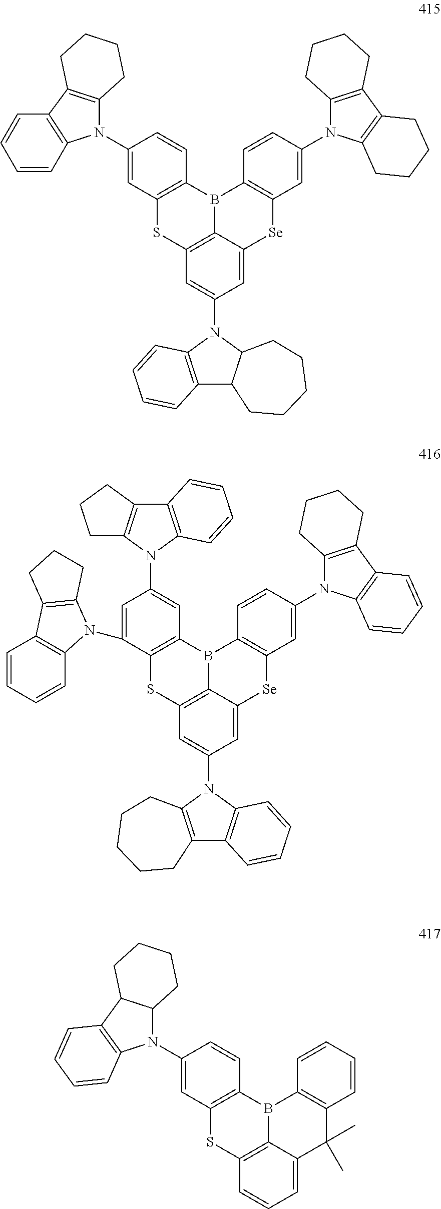 [SMILES: c1ccc2c(c1)C1CCCCCC1N2c1cc2c3c(c1)[Se]c1cc(-n4c5c(c6c4CCCC6)CCCC5)ccc1B3c1ccc(-n3c4c(c5ccccc53)CCCC4)cc1S2 ; c1ccc2c(c1)c1c(n2-c2cc3c4c(c2)[Se]c2cc(-n5c6c(c7ccccc75)CCCC6)ccc2B4c2cc(-n4c5c(c6ccccc64)CCC5)cc(-n4c5c(c6ccccc64)CCC5)c2S3)CCCCC1 ; CC1(C)c2ccccc2B2c3ccc(N4c5ccccc5C5CCCCC54)cc3Sc3cccc1c32] 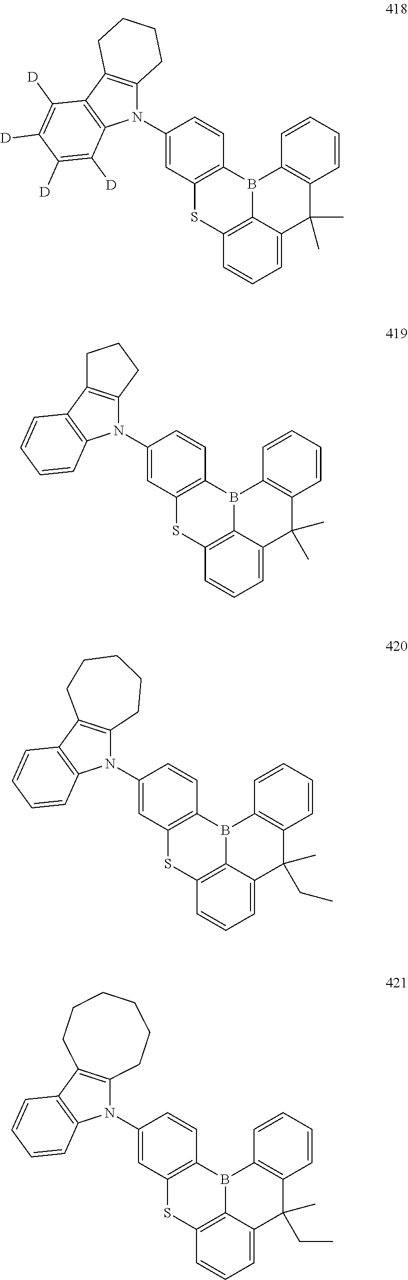 [SMILES: [2H]c1c([2H])c([2H])c2c(c1[2H])c1c(n2-c2ccc3c(c2)Sc2cccc4c2B3c2ccccc2C4(C)C)CCCC1 ; CC1(C)c2ccccc2B2c3ccc(-n4c5c(c6ccccc64)CCC5)cc3Sc3cccc1c32 ; CCC1(C)c2ccccc2B2c3ccc(-n4c5c(c6ccccc64)CCCCC5)cc3Sc3cccc1c32 ; CCC1(C)c2ccccc2B2c3ccc(-n4c5c(c6ccccc64)CCCCCC5)cc3Sc3cccc1c32] 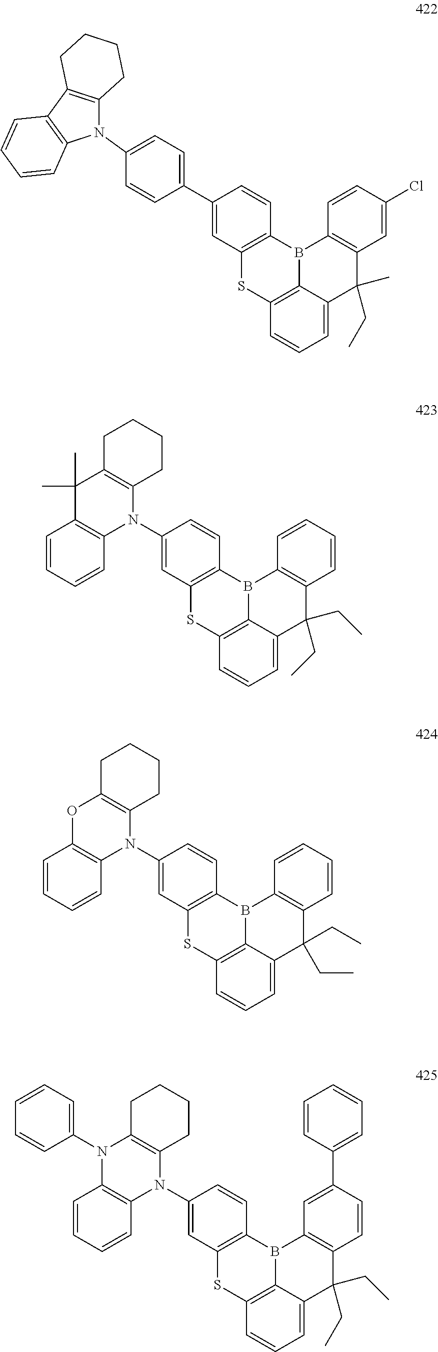 [SMILES: CCC1(C)c2cc(Cl)ccc2B2c3ccc(-c4ccc(-n5c6c(c7ccccc75)CCCC6)cc4)cc3Sc3cccc1c32 ; CCC1(CC)c2ccccc2B2c3ccc(N4C5=C(CCCC5)C(C)(C)c5ccccc54)cc3Sc3cccc1c32 ; CCC1(CC)c2ccccc2B2c3ccc(N4C5=C(CCCC5)Oc5ccccc54)cc3Sc3cccc1c32 ; CCC1(CC)c2ccc(-c3ccccc3)cc2B2c3ccc(N4C5=C(CCCC5)N(c5ccccc5)c5ccccc54)cc3Sc3cccc1c32] 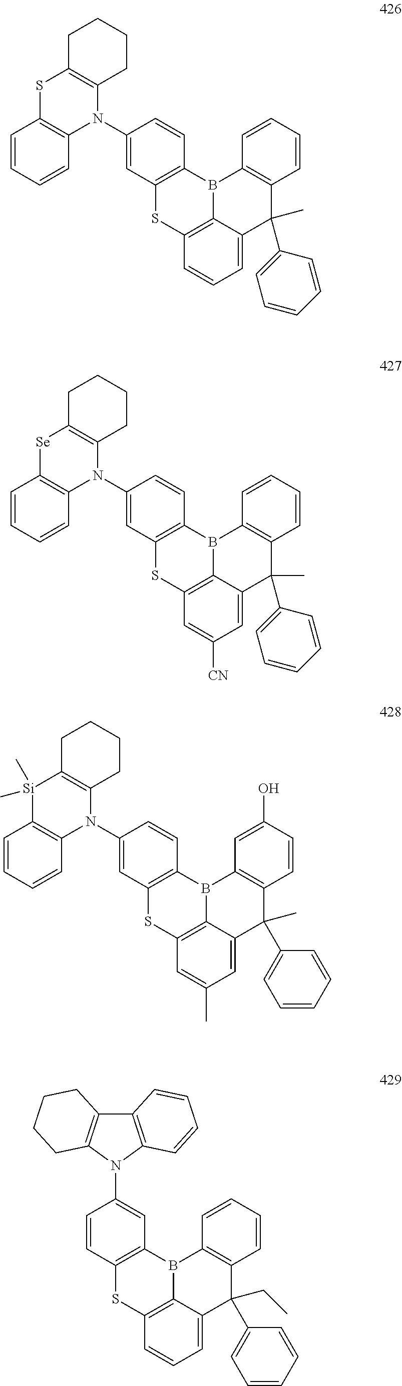 [SMILES: CC1(c2ccccc2)c2ccccc2B2c3ccc(N4C5=C(CCCC5)Sc5ccccc54)cc3Sc3cccc1c32 ; CC1(c2ccccc2)c2ccccc2B2c3ccc(N4C5=C(CCCC5)[Se]c5ccccc54)cc3Sc3cc(C#N)cc1c32 ; Cc1cc2c3c(c1)C(C)(c1ccccc1)c1ccc(O)cc1B3c1ccc(N3C4=C(CCCC4)[Si](C)(C)c4ccccc43)cc1S2 ; CCC1(c2ccccc2)c2ccccc2B2c3cc(-n4c5c(c6ccccc64)CCCC5)ccc3Sc3cccc1c32] 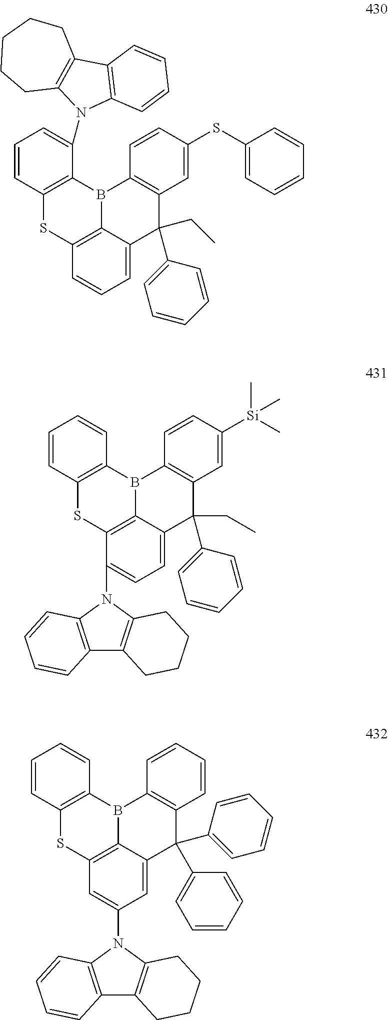 [SMILES: CCC1(c2ccccc2)c2cc(Sc3ccccc3)ccc2B2c3c(cccc3-n3c4c(c5ccccc53)CCCCC4)Sc3cccc1c32 ; CCC1(c2ccccc2)c2cc([Si](C)(C)C)ccc2B2c3ccccc3Sc3c(-n4c5c(c6ccccc64)CCCC5)ccc1c32 ; c1ccc(C2(c3ccccc3)c3ccccc3B3c4ccccc4Sc4cc(-n5c6c(c7ccccc75)CCCC6)cc2c43)cc1] 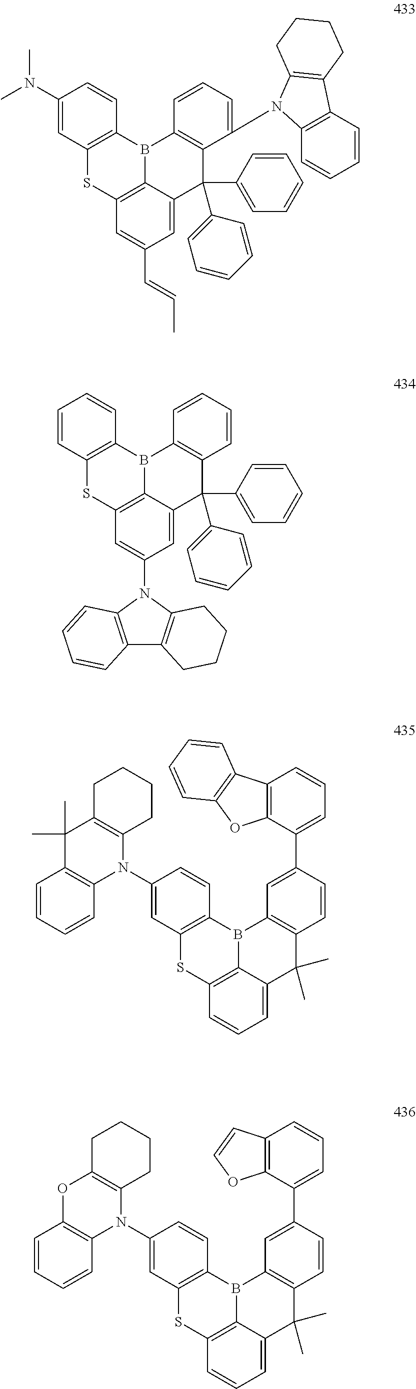 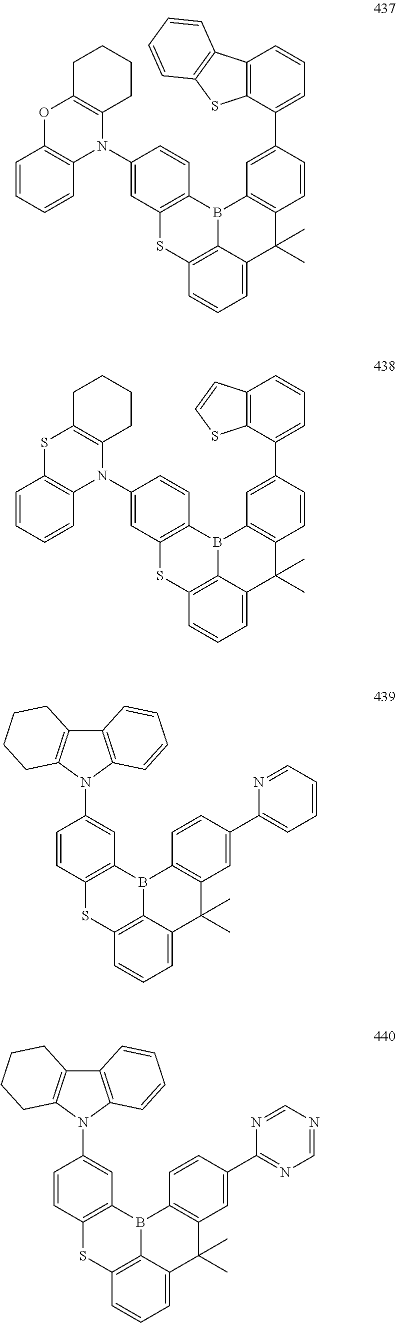 [SMILES: CC1(C)c2ccc(-c3cccc4c3sc3ccccc34)cc2B2c3ccc(N4C5=C(CCCC5)Oc5ccccc54)cc3Sc3cccc1c32 ; CC1(C)c2ccc(-c3cccc4ccsc34)cc2B2c3ccc(N4C5=C(CCCC5)Sc5ccccc54)cc3Sc3cccc1c32 ; CC1(C)c2cc(-c3ccccn3)ccc2B2c3cc(-n4c5c(c6ccccc64)CCCC5)ccc3Sc3cccc1c32 ; CC1(C)c2cc(-c3ncncn3)ccc2B2c3cc(-n4c5c(c6ccccc64)CCCC5)ccc3Sc3cccc1c32] 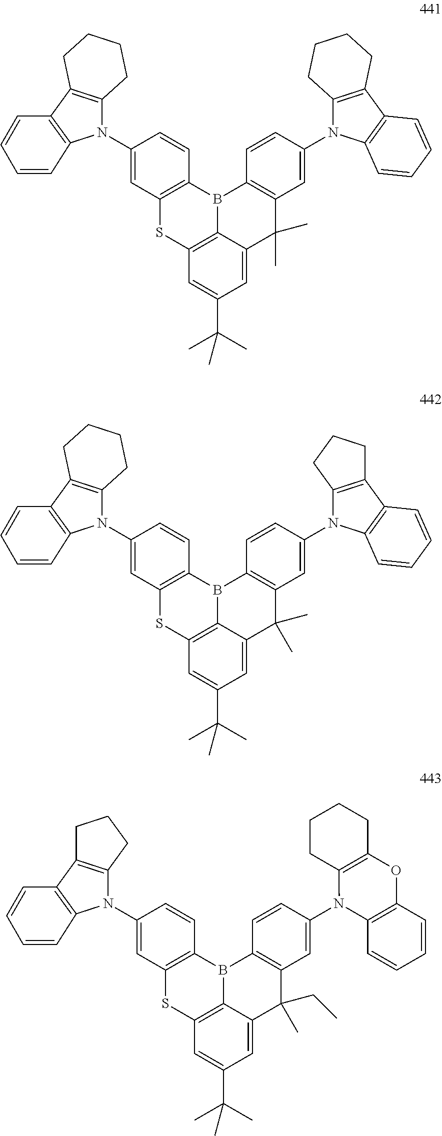 [SMILES: CC(C)(C)c1cc2c3c(c1)C(C)(C)c1cc(-n4c5c(c6ccccc64)CCCC5)ccc1B3c1ccc(-n3c4c(c5ccccc53)CCCC4)cc1S2 ; CC(C)(C)c1cc2c3c(c1)C(C)(C)c1cc(-n4c5c(c6ccccc64)CCC5)ccc1B3c1ccc(-n3c4c(c5ccccc53)CCCC4)cc1S2 ; CCC1(C)c2cc(N3C4=C(CCCC4)Oc4ccccc43)ccc2B2c3ccc(-n4c5c(c6ccccc64)CCC5)cc3Sc3cc(C(C)(C)C)cc1c32] 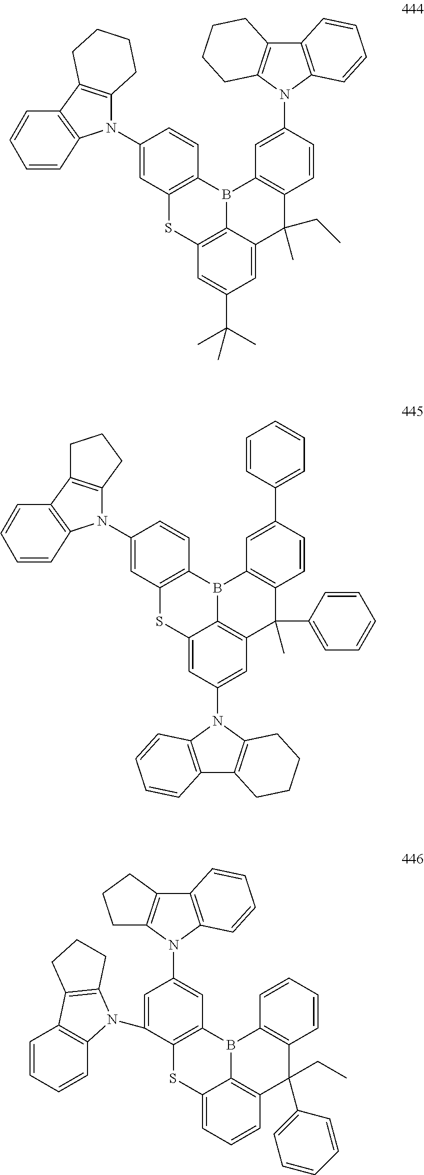 [SMILES: CCC1(C)c2ccc(-n3c4c(c5ccccc53)CCCC4)cc2B2c3ccc(-n4c5c(c6ccccc64)CCCC5)cc3Sc3cc(C(C)(C)C)cc1c32 ; CC1(c2ccccc2)c2ccc(-c3ccccc3)cc2B2c3ccc(-n4c5c(c6ccccc64)CCC5)cc3Sc3cc(-n4c5c(c6ccccc64)CCCC5)cc1c32 ; CCC1(c2ccccc2)c2ccccc2B2c3cc(-n4c5c(c6ccccc64)CCC5)cc(-n4c5c(c6ccccc64)CCC5)c3Sc3cccc1c32] 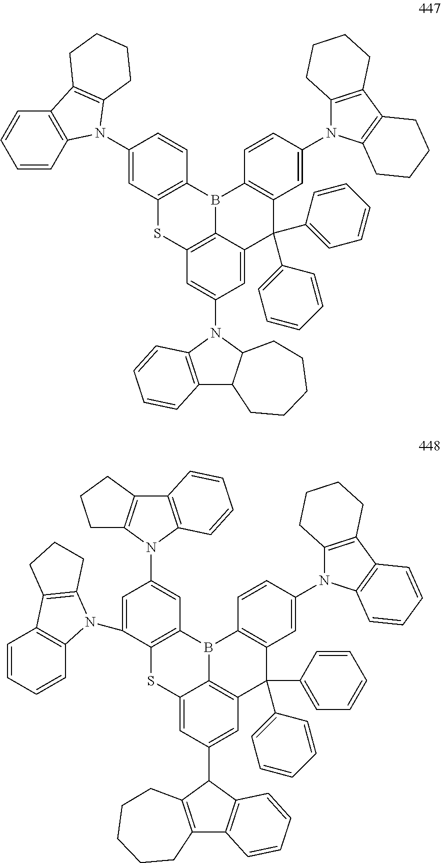 [SMILES: c1ccc(C2(c3ccccc3)c3cc(-n4c5c(c6c4CCCC6)CCCC5)ccc3B3c4ccc(-n5c6c(c7ccccc75)CCCC6)cc4Sc4cc(N5c6ccccc6C6CCCCCC65)cc2c43)cc1 ; c1ccc(C2(c3ccccc3)c3cc(-n4c5c(c6ccccc64)CCCC5)ccc3B3c4cc(-n5c6c(c7ccccc75)CCC6)cc(-n5c6c(c7ccccc75)CCC6)c4Sc4cc(C5C6=C(CCCCC6)c6ccccc65)cc2c43)cc1] 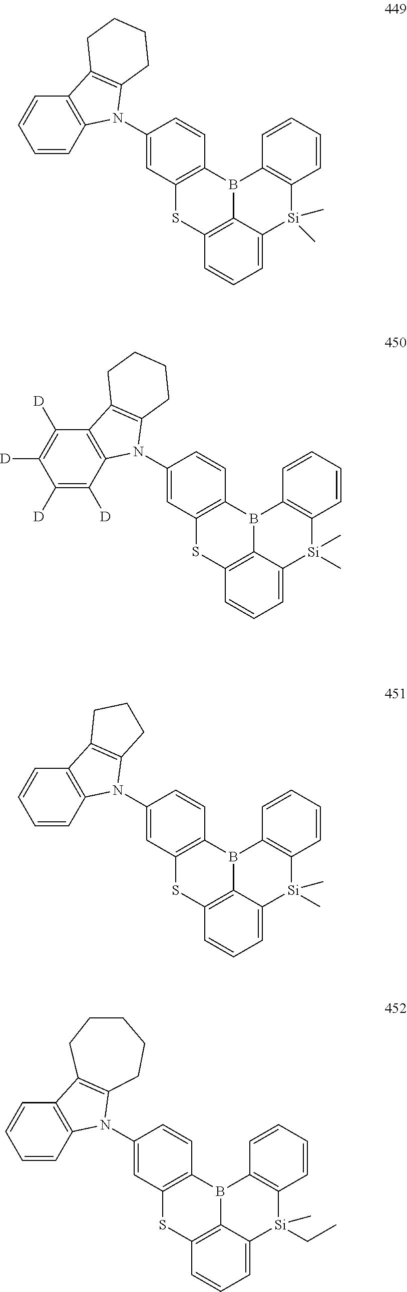 [SMILES: C[Si]1(C)c2ccccc2B2c3ccc(-n4c5c(c6ccccc64)CCCC5)cc3Sc3cccc1c32 ; [2H]c1c([2H])c([2H])c2c(c1[2H])c1c(n2-c2ccc3c(c2)Sc2cccc4c2B3c2ccccc2[Si]4(C)C)CCCC1 ; C[Si]1(C)c2ccccc2B2c3ccc(-n4c5c(c6ccccc64)CCC5)cc3Sc3cccc1c32 ; CC[Si]1(C)c2ccccc2B2c3ccc(-n4c5c(c6ccccc64)CCCCC5)cc3Sc3cccc1c32] 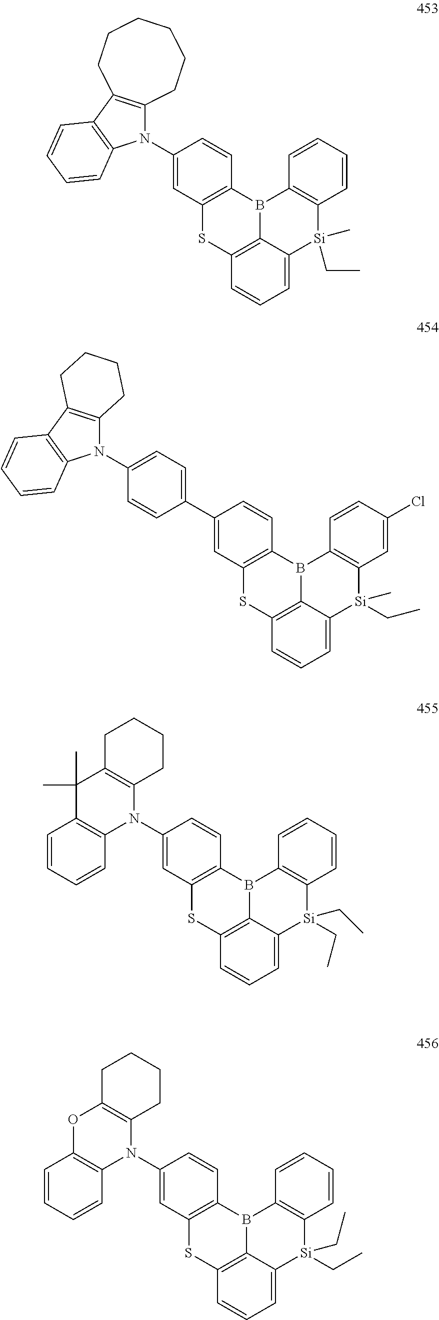 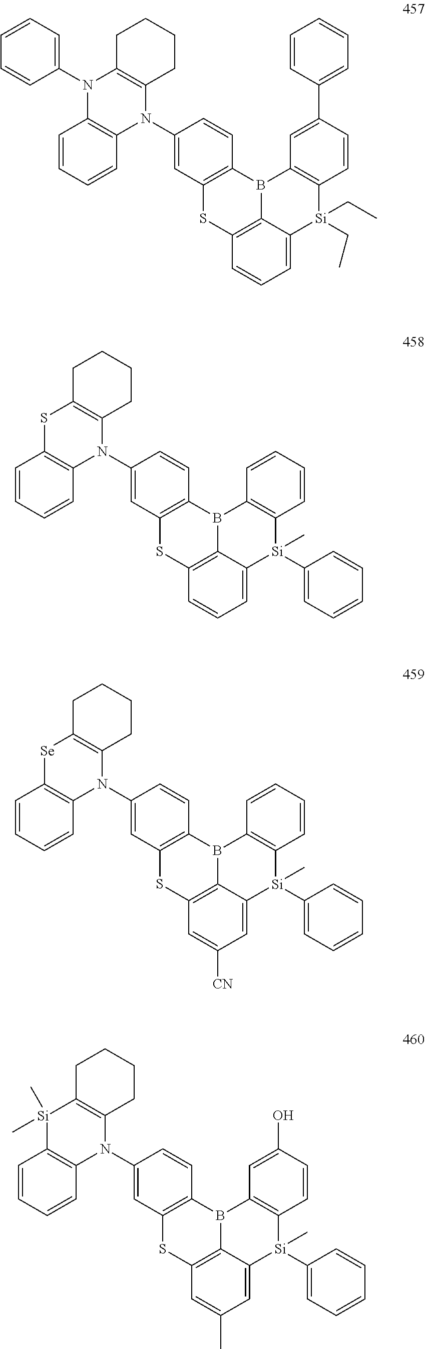 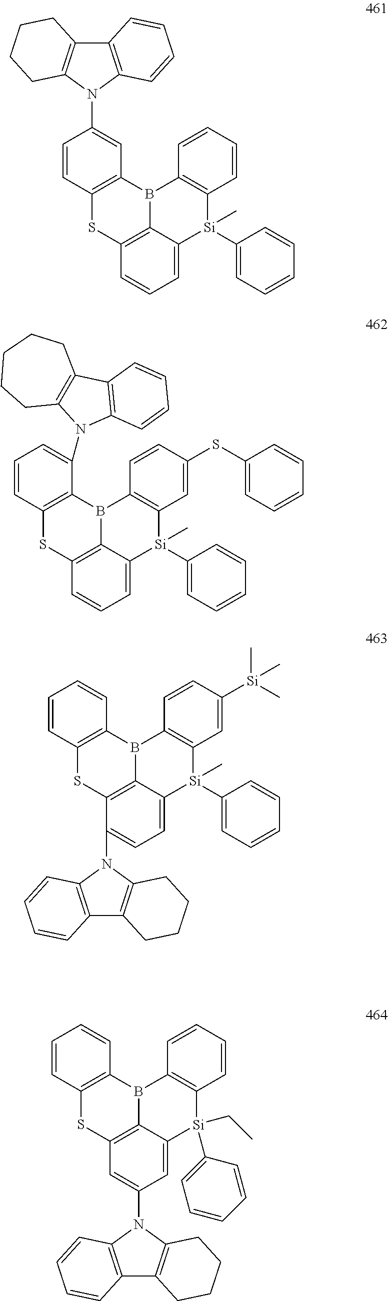 [SMILES: C[Si]1(c2ccccc2)c2ccccc2B2c3cc(-n4c5c(c6ccccc64)CCCC5)ccc3Sc3cccc1c32 ; C[Si]1(c2ccccc2)c2cc(Sc3ccccc3)ccc2B2c3c(cccc3-n3c4c(c5ccccc53)CCCCC4)Sc3cccc1c32 ; C[Si](C)(C)c1ccc2c(c1)[Si](C)(c1ccccc1)c1ccc(-n3c4c(c5ccccc53)CCCC4)c3c1B2c1ccccc1S3 ; CC[Si]1(c2ccccc2)c2ccccc2B2c3ccccc3Sc3cc(-n4c5c(c6ccccc64)CCCC5)cc1c32] 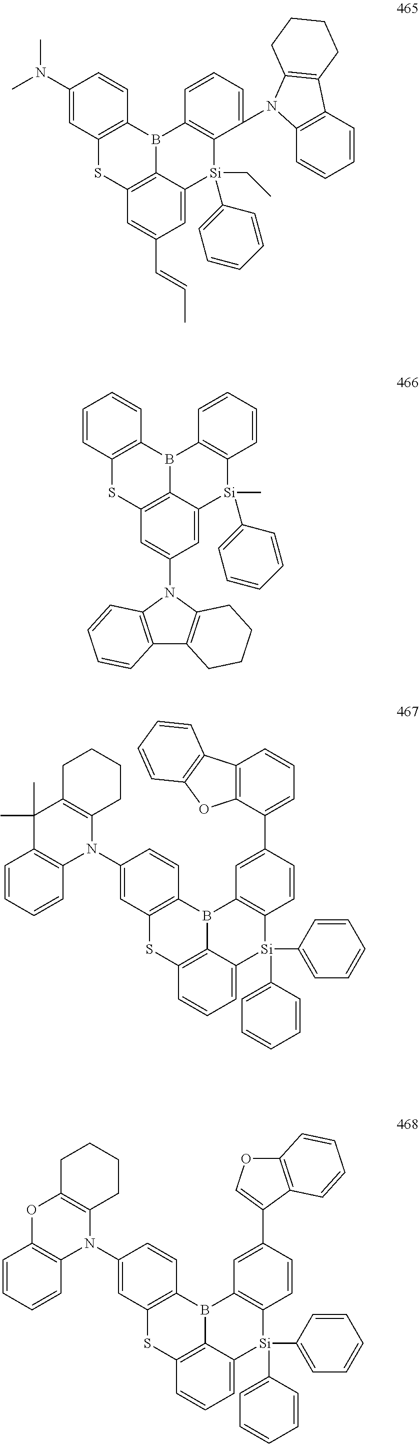 [SMILES: C/C=C/c1cc2c3c(c1)[Si](CC)(c1ccccc1)c1c(cccc1-n1c4c(c5ccccc51)CCCC4)B3c1ccc(N(C)C)cc1S2 ; C[Si]1(c2ccccc2)c2ccccc2B2c3ccccc3Sc3cc(-n4c5c(c6ccccc64)CCCC5)cc1c32 ; CC1(C)C2=C(CCCC2)N(c2ccc3c(c2)Sc2cccc4c2B3c2cc(-c3cccc5c3oc3ccccc35)ccc2[Si]4(c2ccccc2)c2ccccc2)c2ccccc21 ; c1ccc([Si]2(c3ccccc3)c3ccc(-c4coc5ccccc45)cc3B3c4ccc(N5C6=C(CCCC6)Oc6ccccc65)cc4Sc4cccc2c43)cc1] 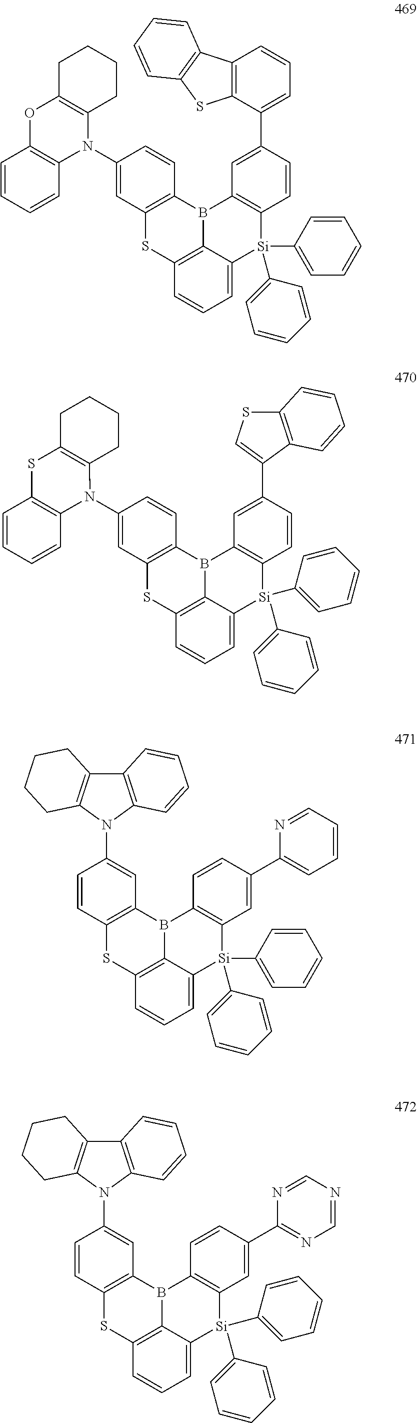 [SMILES: c1ccc([Si]2(c3ccccc3)c3ccc(-c4cccc5c4sc4ccccc45)cc3B3c4ccc(N5C6=C(CCCC6)Oc6ccccc65)cc4Sc4cccc2c43)cc1 ; c1ccc([Si]2(c3ccccc3)c3ccc(-c4csc5ccccc45)cc3B3c4ccc(N5C6=C(CCCC6)Sc6ccccc65)cc4Sc4cccc2c43)cc1 ; c1ccc([Si]2(c3ccccc3)c3cc(-c4ccccn4)ccc3B3c4cc(-n5c6c(c7ccccc75)CCCC6)ccc4Sc4cccc2c43)cc1 ; c1ccc([Si]2(c3ccccc3)c3cc(-c4ncncn4)ccc3B3c4cc(-n5c6c(c7ccccc75)CCCC6)ccc4Sc4cccc2c43)cc1] 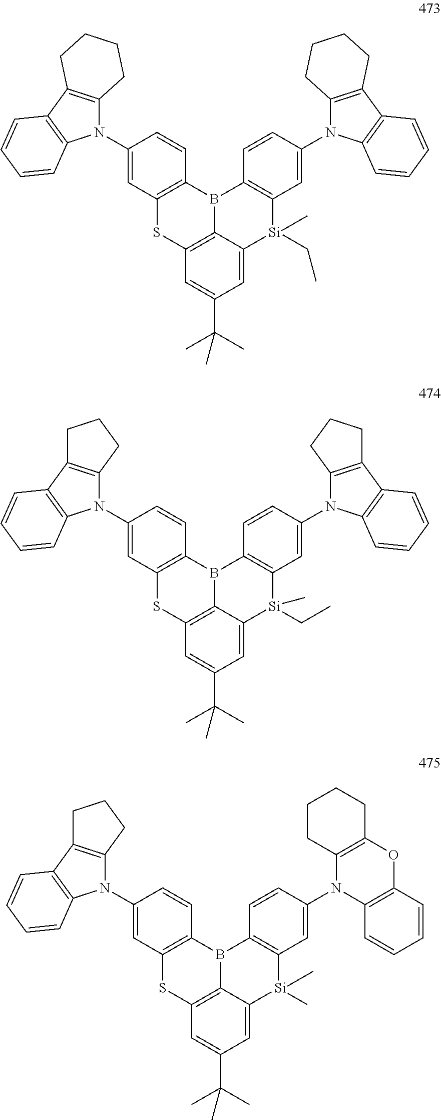 [SMILES: CC[Si]1(C)c2cc(-n3c4c(c5ccccc53)CCCC4)ccc2B2c3ccc(-n4c5c(c6ccccc64)CCCC5)cc3Sc3cc(C(C)(C)C)cc1c32 ; CC[Si]1(C)c2cc(-n3c4c(c5ccccc53)CCC4)ccc2B2c3ccc(-n4c5c(c6ccccc64)CCC5)cc3Sc3cc(C(C)(C)C)cc1c32 ; CC(C)(C)c1cc2c3c(c1)[Si](C)(C)c1cc(N4C5=C(CCCC5)Oc5ccccc54)ccc1B3c1ccc(-n3c4c(c5ccccc53)CCC4)cc1S2] 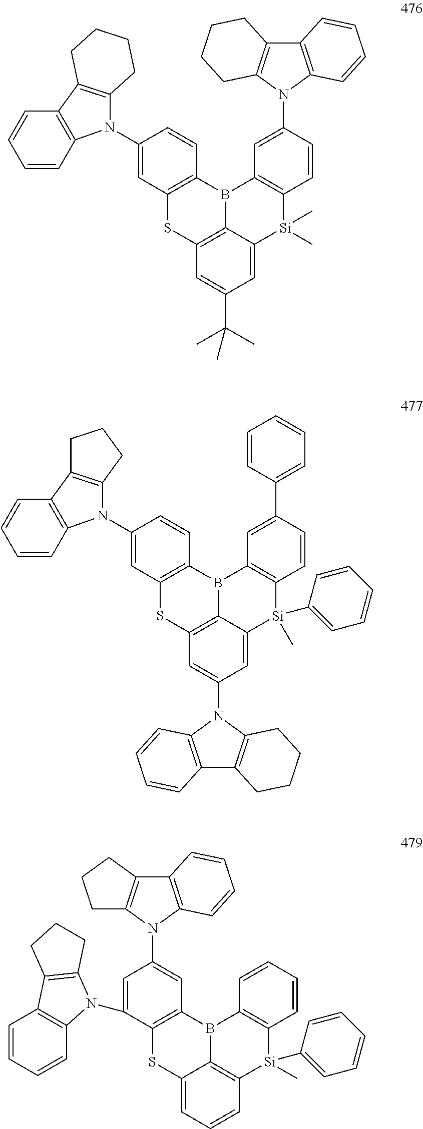 [SMILES: CC(C)(C)c1cc2c3c(c1)[Si](C)(C)c1ccc(-n4c5c(c6ccccc64)CCCC5)cc1B3c1ccc(-n3c4c(c5ccccc53)CCCC4)cc1S2 ; C[Si]1(c2ccccc2)c2ccc(-c3ccccc3)cc2B2c3ccc(-n4c5c(c6ccccc64)CCC5)cc3Sc3cc(-n4c5c(c6ccccc64)CCCC5)cc1c32 ; C[Si]1(c2ccccc2)c2ccccc2B2c3cc(-n4c5c(c6ccccc64)CCC5)cc(-n4c5c(c6ccccc64)CCC5)c3Sc3cccc1c32] 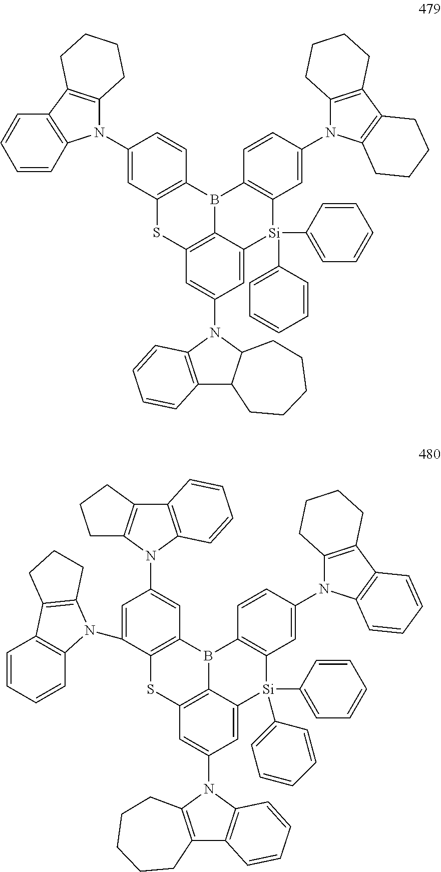 [SMILES: c1ccc([Si]2(c3ccccc3)c3cc(-n4c5c(c6c4CCCC6)CCCC5)ccc3B3c4ccc(-n5c6c(c7ccccc75)CCCC6)cc4Sc4cc(N5c6ccccc6C6CCCCCC65)cc2c43)cc1 ; c1ccc([Si]2(c3ccccc3)c3cc(-n4c5c(c6ccccc64)CCCC5)ccc3B3c4cc(-n5c6c(c7ccccc75)CCC6)cc(-n5c6c(c7ccccc75)CCC6)c4Sc4cc(-n5c6c(c7ccccc75)CCCCC6)cc2c43)cc1] 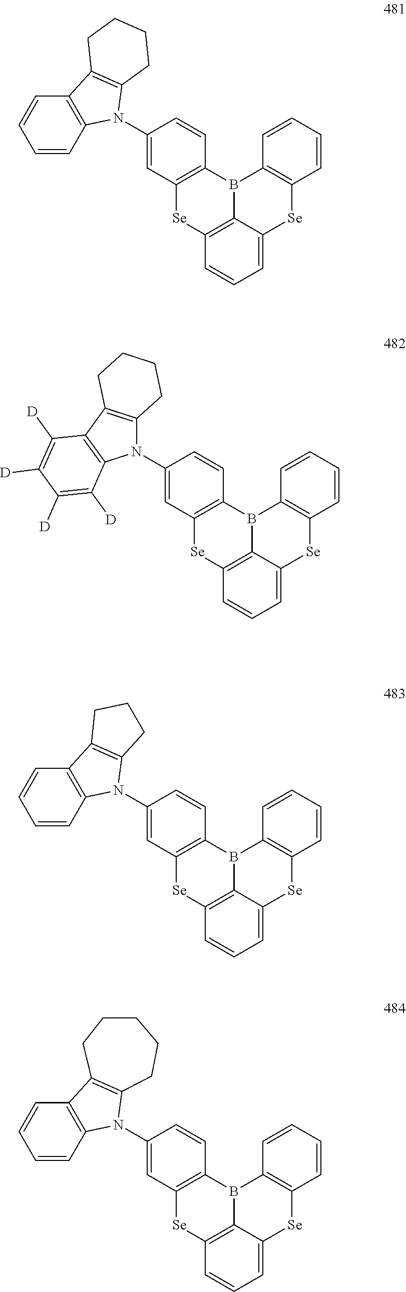 [SMILES: c1ccc2c(c1)[Se]c1cccc3c1B2c1ccc(-n2c4c(c5ccccc52)CCCC4)cc1[Se]3 ; [2H]c1c([2H])c([2H])c2c(c1[2H])c1c(n2-c2ccc3c(c2)[Se]c2cccc4c2B3c2ccccc2[Se]4)CCCC1 ; c1ccc2c(c1)[Se]c1cccc3c1B2c1ccc(-n2c4c(c5ccccc52)CCC4)cc1[Se]3 ; c1ccc2c(c1)[Se]c1cccc3c1B2c1ccc(-n2c4c(c5ccccc52)CCCCC4)cc1[Se]3] 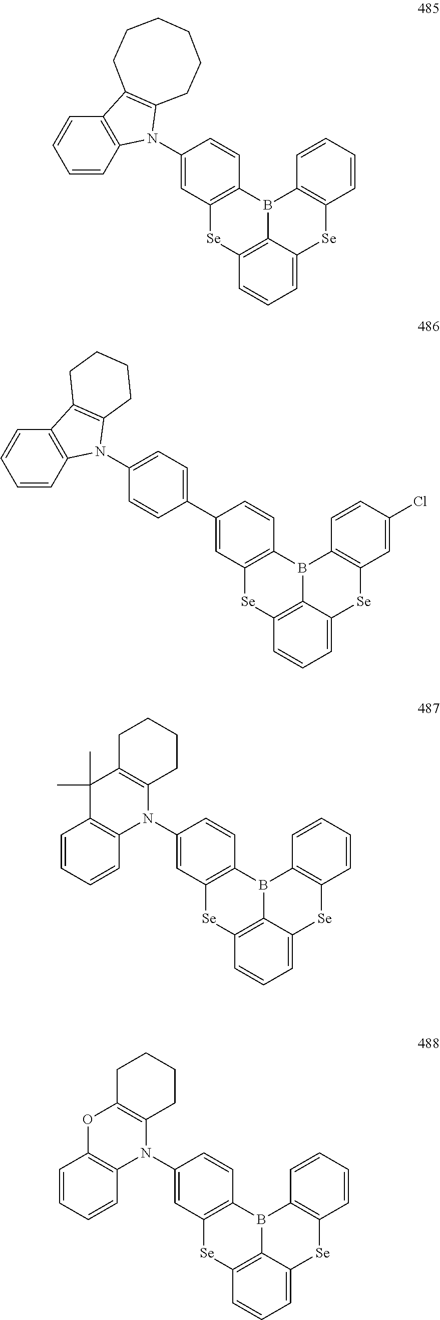 [SMILES: c1ccc2c(c1)[Se]c1cccc3c1B2c1ccc(-n2c4c(c5ccccc52)CCCCCC4)cc1[Se]3 ; Clc1ccc2c(c1)[Se]c1cccc3c1B2c1ccc(-c2ccc(-n4c5c(c6ccccc64)CCCC5)cc2)cc1[Se]3 ; CC1(C)C2=C(CCCC2)N(c2ccc3c(c2)[Se]c2cccc4c2B3c2ccccc2[Se]4)c2ccccc21 ; c1ccc2c(c1)OC1=C(CCCC1)N2c1ccc2c(c1)[Se]c1cccc3c1B2c1ccccc1[Se]3] 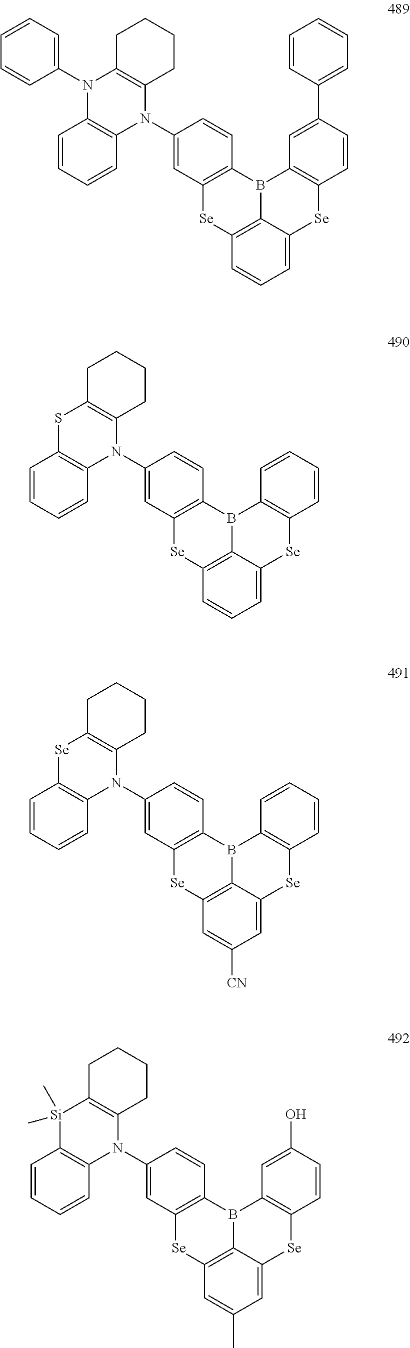 [SMILES: c1ccc(-c2ccc3c(c2)B2c4ccc(N5C6=C(CCCC6)N(c6ccccc6)c6ccccc65)cc4[Se]c4cccc(c42)[Se]3)cc1 ; c1ccc2c(c1)SC1=C(CCCC1)N2c1ccc2c(c1)[Se]c1cccc3c1B2c1ccccc1[Se]3 ; N#Cc1cc2c3c(c1)[Se]c1cc(N4C5=C(CCCC5)[Se]c5ccccc54)ccc1B3c1ccccc1[Se]2 ; Cc1cc2c3c(c1)[Se]c1ccc(O)cc1B3c1ccc(N3C4=C(CCCC4)[Si](C)(C)c4ccccc43)cc1[Se]2] 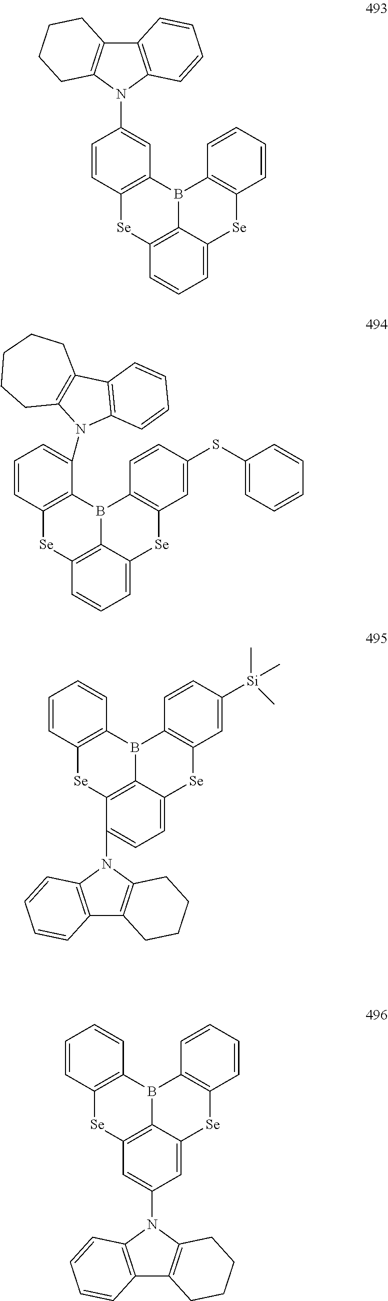 [SMILES: c1ccc2c(c1)[Se]c1cccc3c1B2c1cc(-n2c4c(c5ccccc52)CCCC4)ccc1[Se]3 ; c1ccc(Sc2ccc3c(c2)[Se]c2cccc4c2B3c2c(cccc2-n2c3c(c5ccccc52)CCCCC3)[Se]4)cc1 ; C[Si](C)(C)c1ccc2c(c1)[Se]c1ccc(-n3c4c(c5ccccc53)CCCC4)c3c1B2c1ccccc1[Se]3 ; c1ccc2c(c1)[Se]c1cc(-n3c4c(c5ccccc53)CCCC4)cc3c1B2c1ccccc1[Se]3] 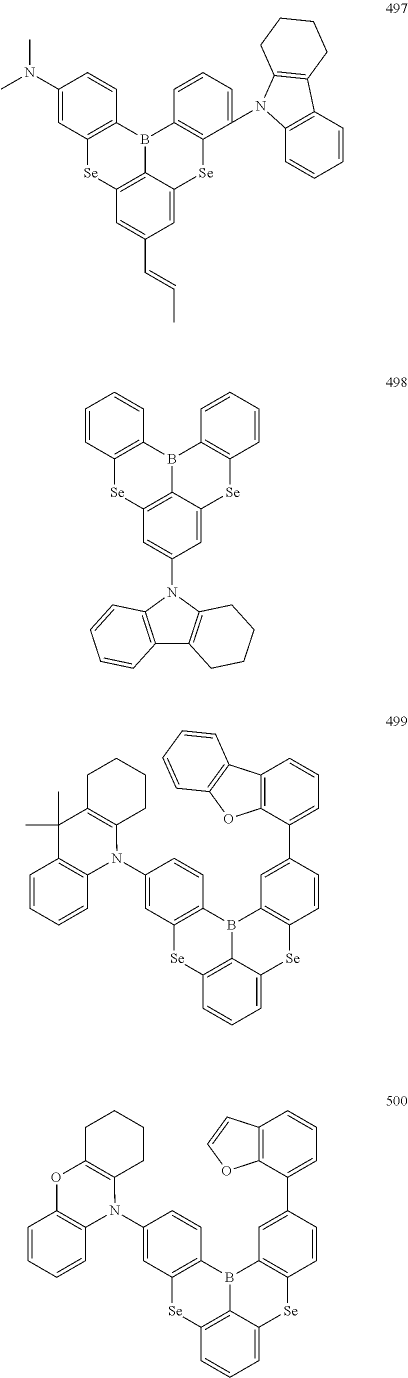 [SMILES: C/C=C/c1cc2c3c(c1)[Se]c1c(cccc1-n1c4c(c5ccccc51)CCCC4)B3c1ccc(N(C)C)cc1[Se]2 ; c1ccc2c(c1)[Se]c1cc(-n3c4c(c5ccccc53)CCCC4)cc3c1B2c1ccccc1[Se]3 ; CC1(C)C2=C(CCCC2)N(c2ccc3c(c2)[Se]c2cccc4c2B3c2cc(-c3cccc5c3oc3ccccc35)ccc2[Se]4)c2ccccc21 ; c1ccc2c(c1)OC1=C(CCCC1)N2c1ccc2c(c1)[Se]c1cccc3c1B2c1cc(-c2cccc4ccoc24)ccc1[Se]3] 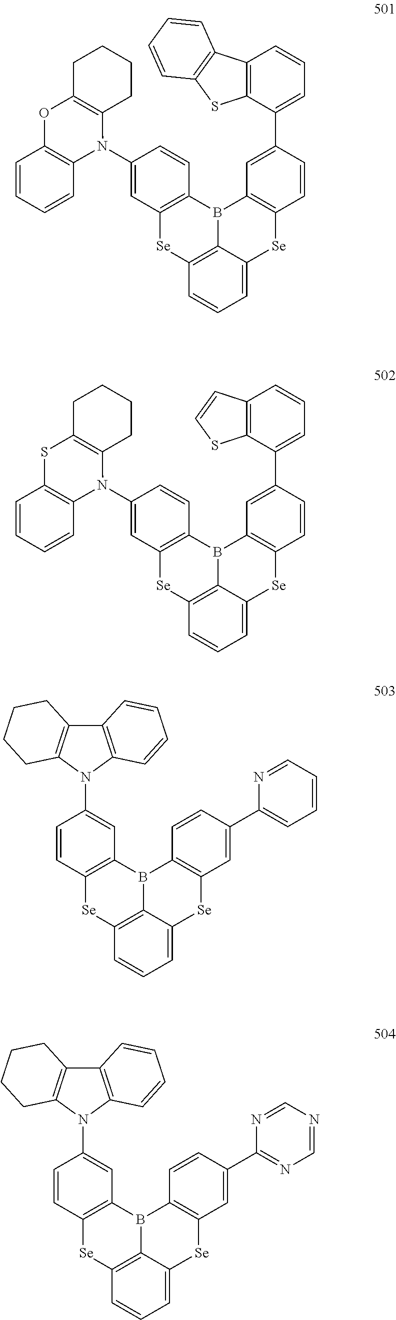 [SMILES: c1ccc2c(c1)OC1=C(CCCC1)N2c1ccc2c(c1)[Se]c1cccc3c1B2c1cc(-c2cccc4c2sc2ccccc24)ccc1[Se]3 ; c1ccc2c(c1)SC1=C(CCCC1)N2c1ccc2c(c1)[Se]c1cccc3c1B2c1cc(-c2cccc4ccsc24)ccc1[Se]3 ; c1ccc(-c2ccc3c(c2)[Se]c2cccc4c2B3c2cc(-n3c5c(c6ccccc63)CCCC5)ccc2[Se]4)nc1 ; c1cc2c3c(c1)[Se]c1ccc(-n4c5c(c6ccccc64)CCCC5)cc1B3c1ccc(-c3ncncn3)cc1[Se]2] 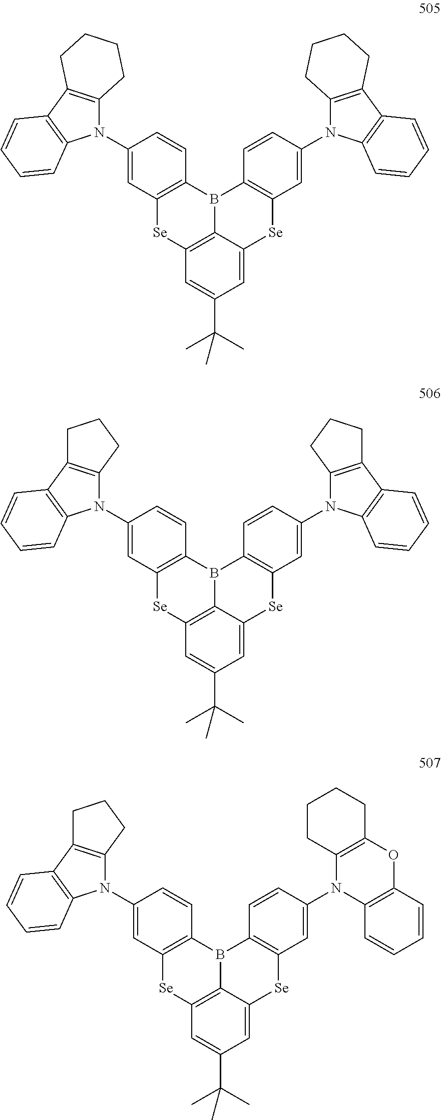 [SMILES: CC(C)(C)c1cc2c3c(c1)[Se]c1cc(-n4c5c(c6ccccc64)CCCC5)ccc1B3c1ccc(-n3c4c(c5ccccc53)CCCC4)cc1[Se]2 ; CC(C)(C)c1cc2c3c(c1)[Se]c1cc(-n4c5c(c6ccccc64)CCC5)ccc1B3c1ccc(-n3c4c(c5ccccc53)CCC4)cc1[Se]2 ; CC(C)(C)c1cc2c3c(c1)[Se]c1cc(-n4c5c(c6ccccc64)CCC5)ccc1B3c1ccc(N3C4=C(CCCC4)Oc4ccccc43)cc1[Se]2] 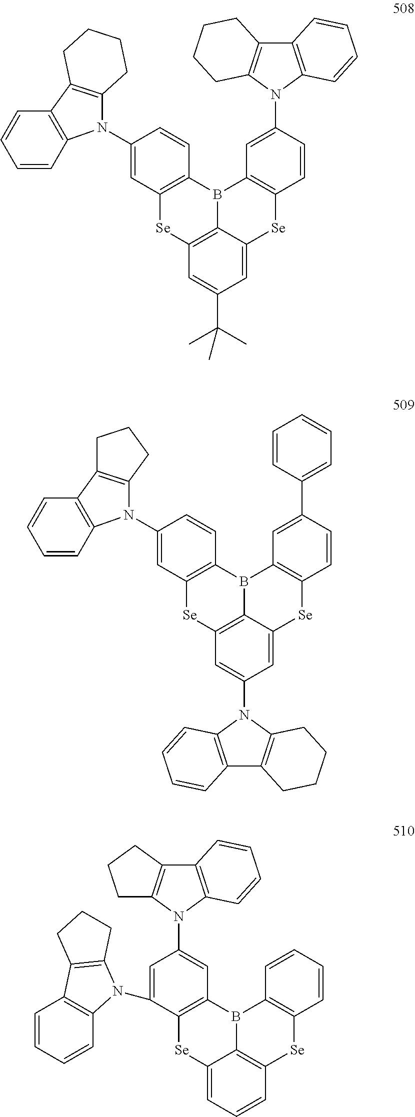 [SMILES: CC(C)(C)c1cc2c3c(c1)[Se]c1ccc(-n4c5c(c6ccccc64)CCCC5)cc1B3c1ccc(-n3c4c(c5ccccc53)CCCC4)cc1[Se]2 ; c1ccc(-c2ccc3c(c2)B2c4ccc(-n5c6c(c7ccccc75)CCC6)cc4[Se]c4cc(-n5c6c(c7ccccc75)CCCC6)cc(c42)[Se]3)cc1 ; c1ccc2c(c1)[Se]c1cccc3c1B2c1cc(-n2c4c(c5ccccc52)CCC4)cc(-n2c4c(c5ccccc52)CCC4)c1[Se]3] 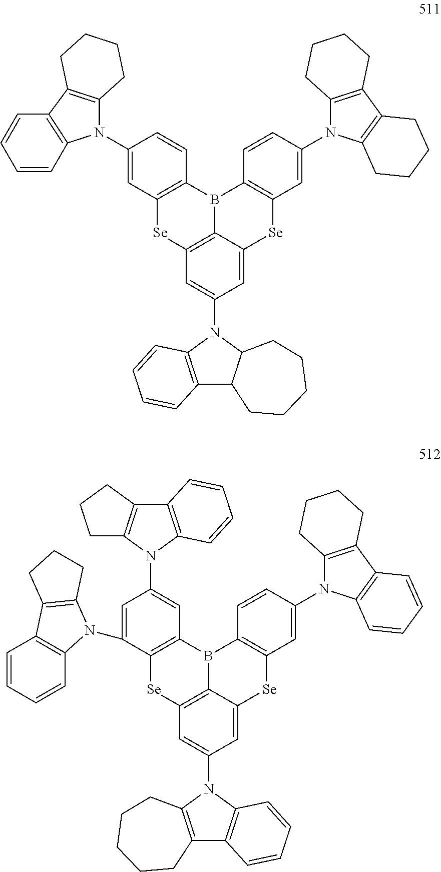 [SMILES: c1ccc2c(c1)C1CCCCCC1N2c1cc2c3c(c1)[Se]c1cc(-n4c5c(c6ccccc64)CCCC5)ccc1B3c1ccc(-n3c4c(c5c3CCCC5)CCCC4)cc1[Se]2 ; c1ccc2c(c1)c1c(n2-c2cc3c4c(c2)[Se]c2c(cc(-n5c6c(c7ccccc75)CCC6)cc2-n2c5c(c6ccccc62)CCC5)B4c2ccc(-n4c5c(c6ccccc64)CCCC5)cc2[Se]3)CCCCC1] 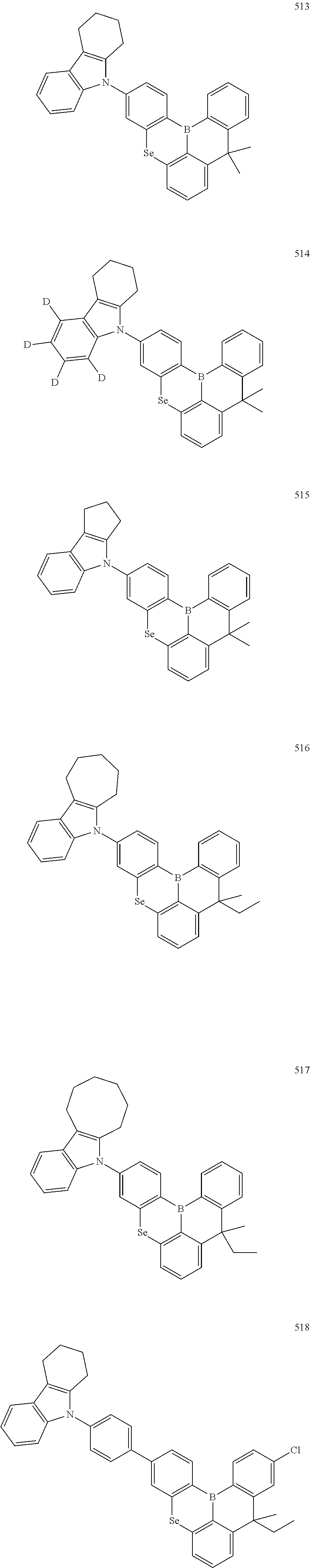 [SMILES: CC1(C)c2ccccc2B2c3ccc(-n4c5c(c6ccccc64)CCCC5)cc3[Se]c3cccc1c32 ; [2H]c1c([2H])c([2H])c2c(c1[2H])c1c(n2-c2ccc3c(c2)[Se]c2cccc4c2B3c2ccccc2C4(C)C)CCCC1 ; CC1(C)c2ccccc2B2c3ccc(-n4c5c(c6ccccc64)CCC5)cc3[Se]c3cccc1c32 ; CCC1(C)c2ccccc2B2c3ccc(-n4c5c(c6ccccc64)CCCCC5)cc3[Se]c3cccc1c32 ; CCC1(C)c2ccccc2B2c3ccc(-n4c5c(c6ccccc64)CCCCCC5)cc3[Se]c3cccc1c32 ; CCC1(C)c2cc(Cl)ccc2B2c3ccc(-c4ccc(-n5c6c(c7ccccc75)CCCC6)cc4)cc3[Se]c3cccc1c32] 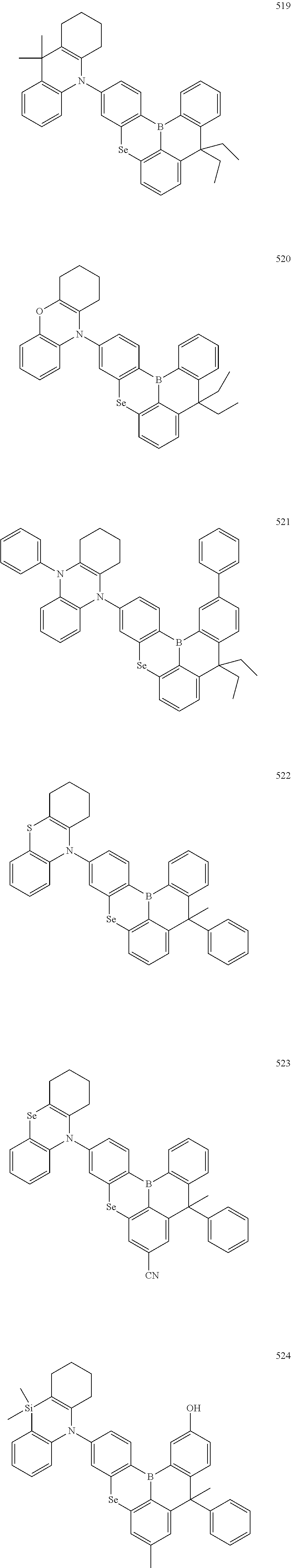 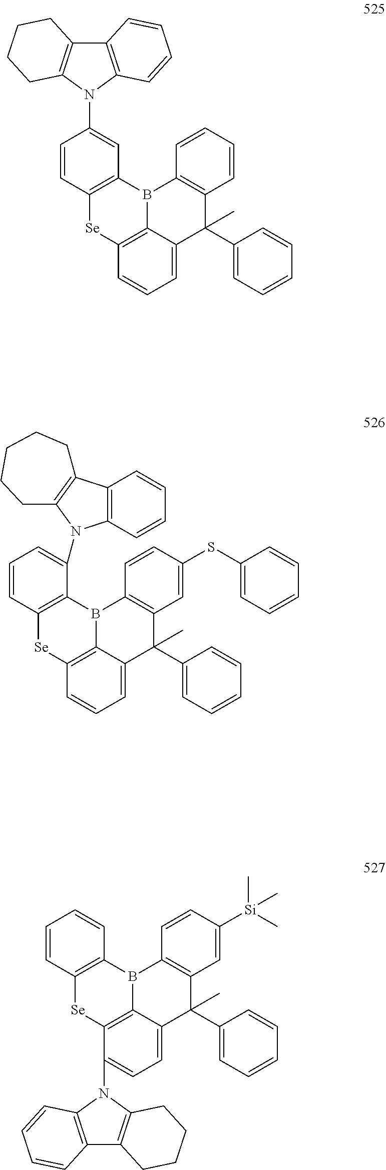 [SMILES: CC1(c2ccccc2)c2ccccc2B2c3cc(-n4c5c(c6ccccc64)CCCC5)ccc3[Se]c3cccc1c32 ; CC1(c2ccccc2)c2cc(Sc3ccccc3)ccc2B2c3c(cccc3-n3c4c(c5ccccc53)CCCCC4)[Se]c3cccc1c32 ; CC1(c2ccccc2)c2cc([Si](C)(C)C)ccc2B2c3ccccc3[Se]c3c(-n4c5c(c6ccccc64)CCCC5)ccc1c32] 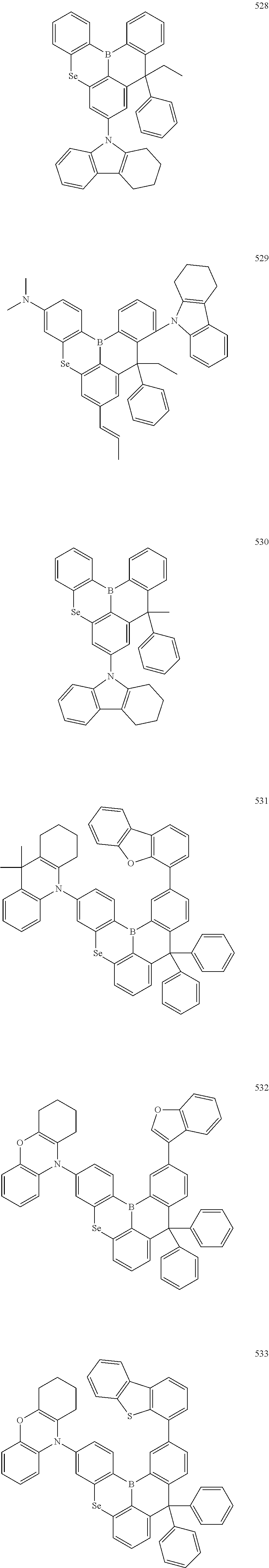 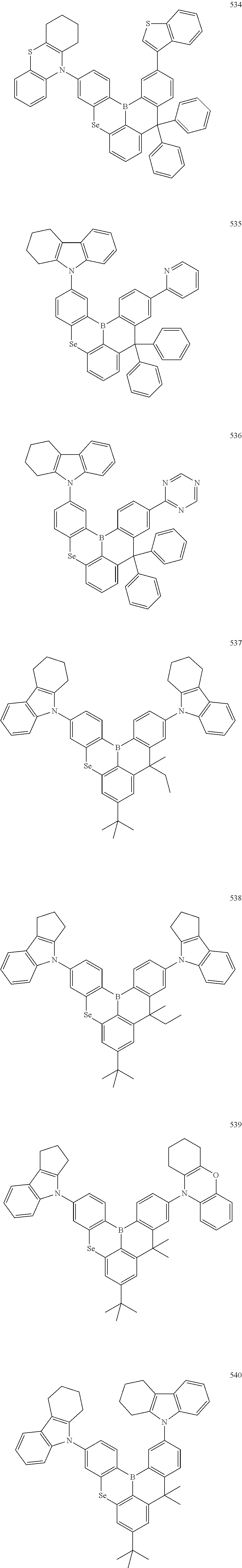 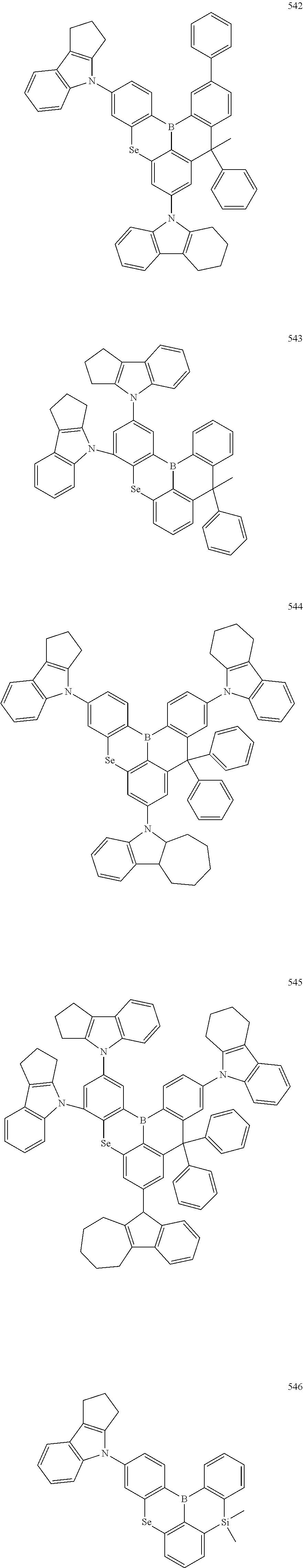 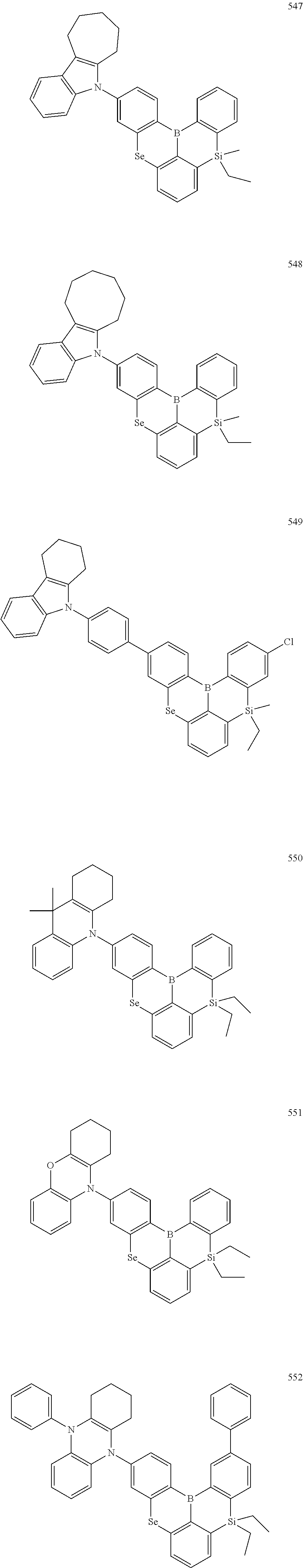 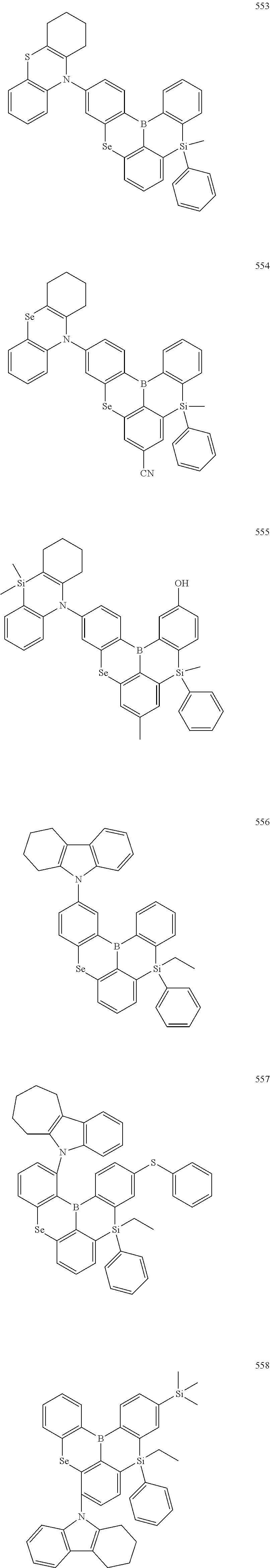 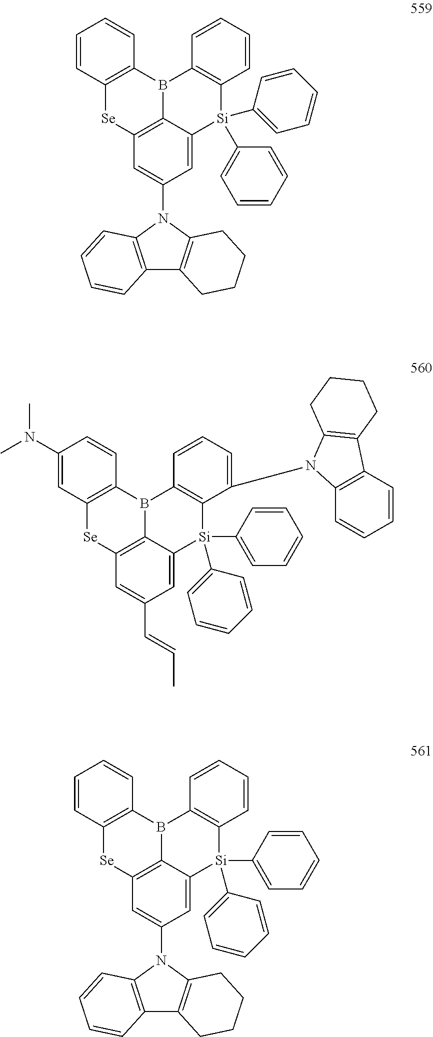 [SMILES: c1ccc([Si]2(c3ccccc3)c3ccccc3B3c4ccccc4[Se]c4cc(-n5c6c(c7ccccc75)CCCC6)cc2c43)cc1 ; C/C=C/c1cc2c3c(c1)[Si](c1ccccc1)(c1ccccc1)c1c(cccc1-n1c4c(c5ccccc51)CCCC4)B3c1ccc(N(C)C)cc1[Se]2 ; c1ccc([Si]2(c3ccccc3)c3ccccc3B3c4ccccc4[Se]c4cc(-n5c6c(c7ccccc75)CCCC6)cc2c43)cc1] 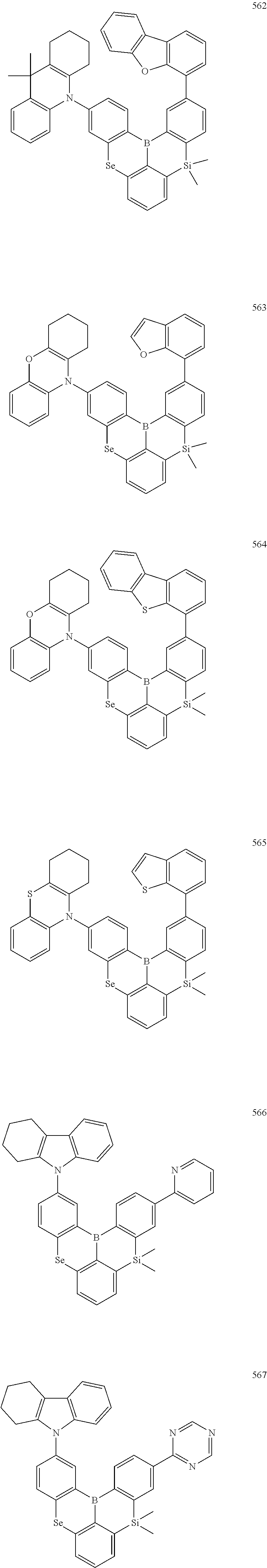 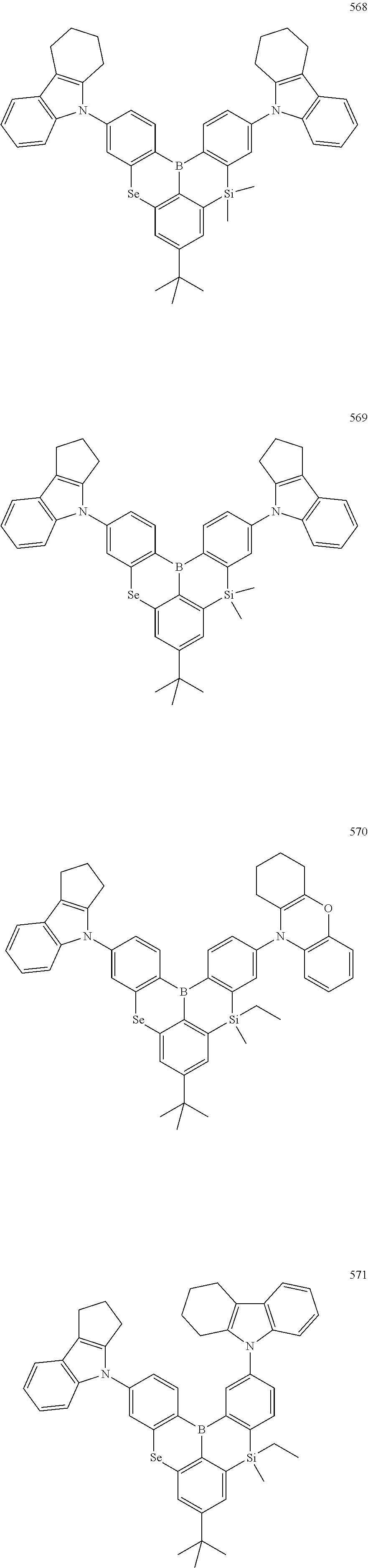 [SMILES: CC(C)(C)c1cc2c3c(c1)[Si](C)(C)c1cc(-n4c5c(c6ccccc64)CCCC5)ccc1B3c1ccc(-n3c4c(c5ccccc53)CCCC4)cc1[Se]2 ; CC(C)(C)c1cc2c3c(c1)[Si](C)(C)c1cc(-n4c5c(c6ccccc64)CCC5)ccc1B3c1ccc(-n3c4c(c5ccccc53)CCC4)cc1[Se]2 ; CC[Si]1(C)c2cc(N3C4=C(CCCC4)Oc4ccccc43)ccc2B2c3ccc(-n4c5c(c6ccccc64)CCC5)cc3[Se]c3cc(C(C)(C)C)cc1c32 ; CC[Si]1(C)c2ccc(-n3c4c(c5ccccc53)CCCC4)cc2B2c3ccc(-n4c5c(c6ccccc64)CCC5)cc3[Se]c3cc(C(C)(C)C)cc1c32] 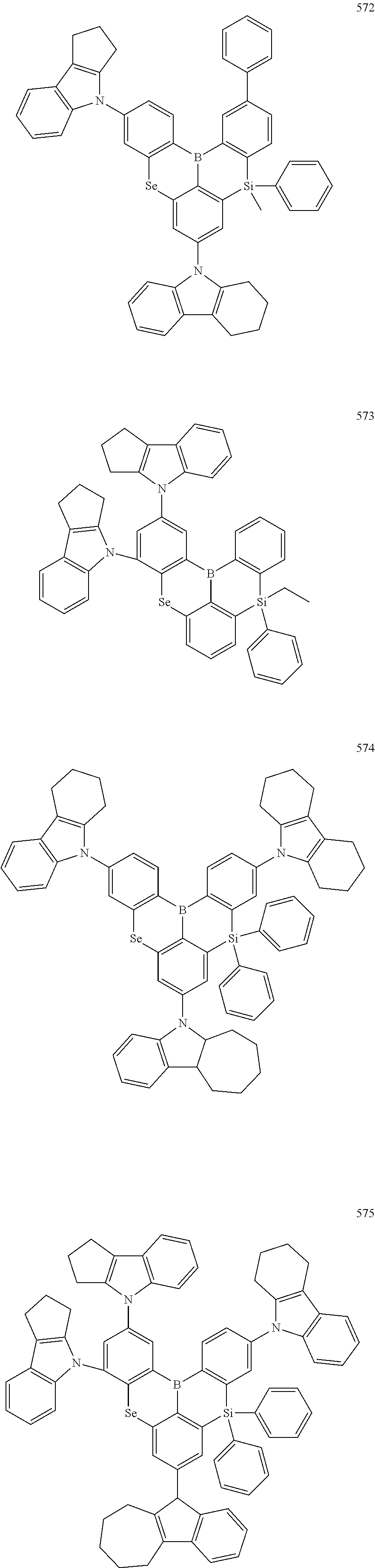 [SMILES: C[Si]1(c2ccccc2)c2ccc(-c3ccccc3)cc2B2c3ccc(-n4c5c(c6ccccc64)CCC5)cc3[Se]c3cc(-n4c5c(c6ccccc64)CCCC5)cc1c32 ; CC[Si]1(c2ccccc2)c2ccccc2B2c3cc(-n4c5c(c6ccccc64)CCC5)cc(-n4c5c(c6ccccc64)CCC5)c3[Se]c3cccc1c32 ; c1ccc([Si]2(c3ccccc3)c3cc(-n4c5c(c6c4CCCC6)CCCC5)ccc3B3c4ccc(-n5c6c(c7ccccc75)CCCC6)cc4[Se]c4cc(N5c6ccccc6C6CCCCCC65)cc2c43)cc1 ; c1ccc([Si]2(c3ccccc3)c3cc(-n4c5c(c6ccccc64)CCCC5)ccc3B3c4cc(-n5c6c(c7ccccc75)CCC6)cc(-n5c6c(c7ccccc75)CCC6)c4[Se]c4cc(C5C6=C(CCCCC6)c6ccccc65)cc2c43)cc1] 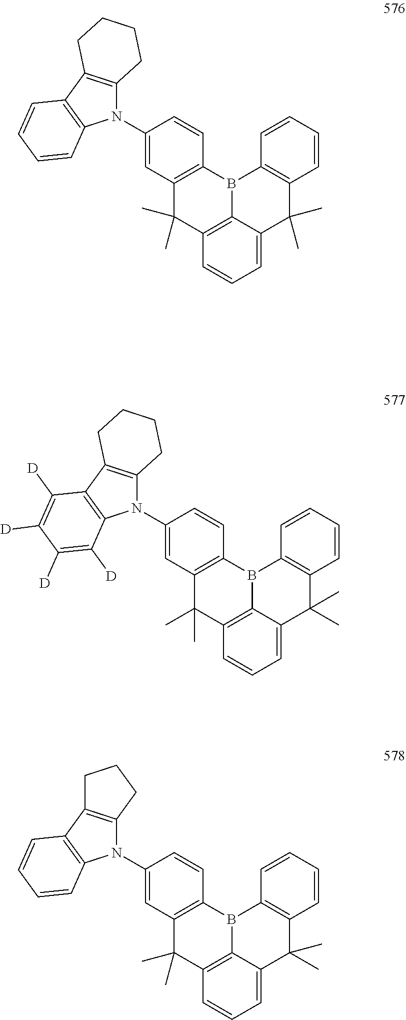 [SMILES: CC1(C)c2ccccc2B2c3ccc(-n4c5c(c6ccccc64)CCCC5)cc3C(C)(C)c3cccc1c32 ; [2H]c1c([2H])c([2H])c2c(c1[2H])c1c(n2-c2ccc3c(c2)C(C)(C)c2cccc4c2B3c2ccccc2C4(C)C)CCCC1 ; CC1(C)c2ccccc2B2c3ccc(-n4c5c(c6ccccc64)CCC5)cc3C(C)(C)c3cccc1c32] 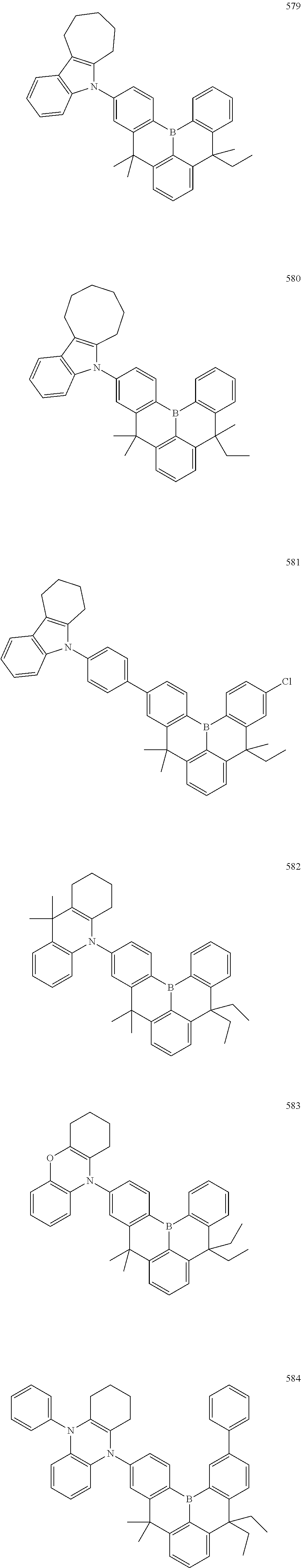 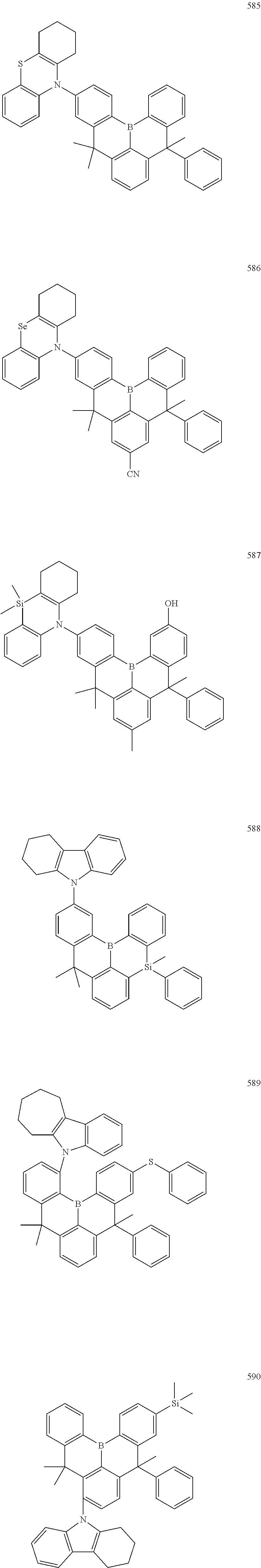 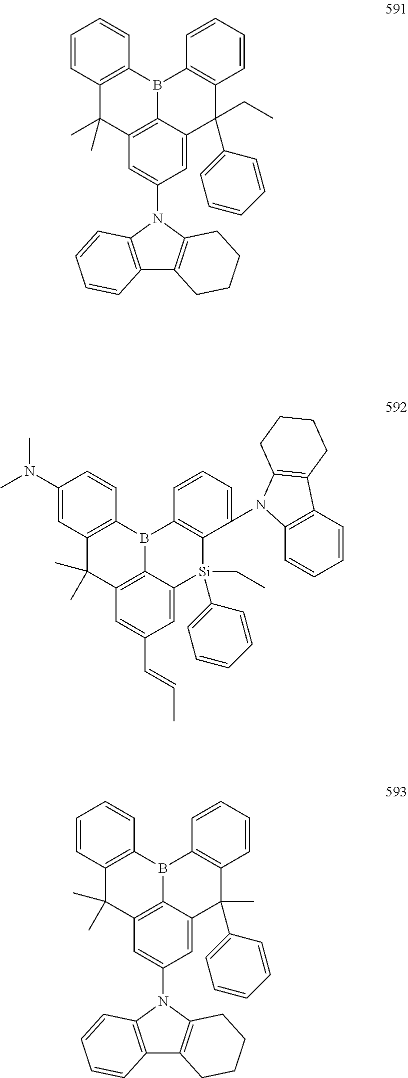 [SMILES: CCC1(c2ccccc2)c2ccccc2B2c3ccccc3C(C)(C)c3cc(-n4c5c(c6ccccc64)CCCC5)cc1c32 ; C/C=C/c1cc2c3c(c1)[Si](CC)(c1ccccc1)c1c(cccc1-n1c4c(c5ccccc51)CCCC4)B3c1ccc(N(C)C)cc1C2(C)C ; CC1(C)c2ccccc2B2c3ccccc3C(C)(c3ccccc3)c3cc(-n4c5c(c6ccccc64)CCCC5)cc1c32] 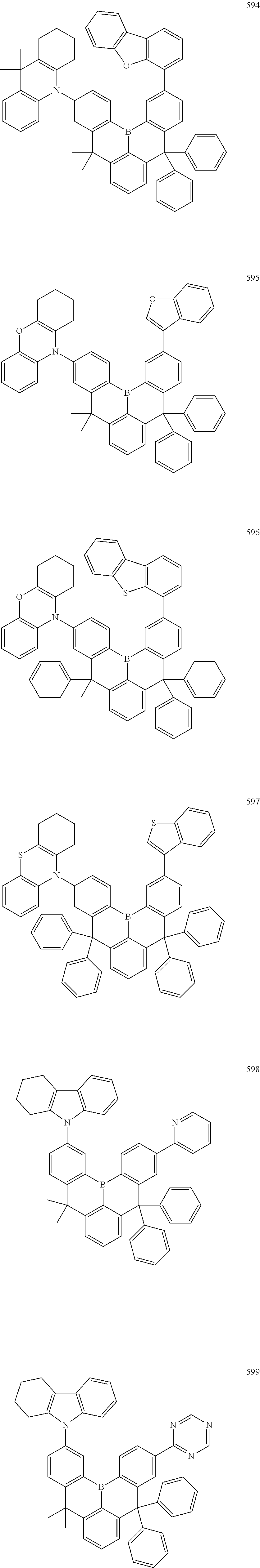 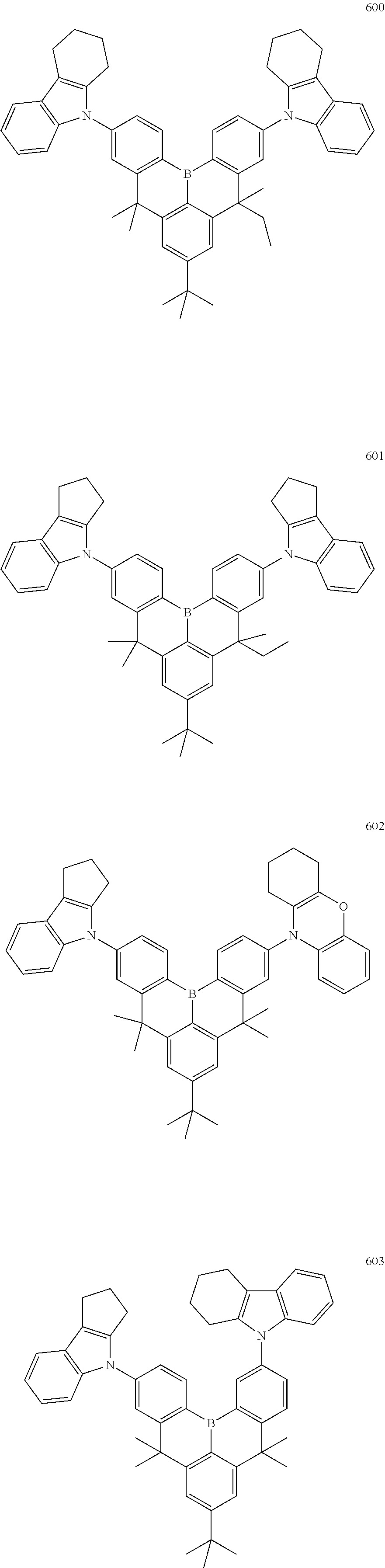 [SMILES: CCC1(C)c2cc(-n3c4c(c5ccccc53)CCCC4)ccc2B2c3ccc(-n4c5c(c6ccccc64)CCCC5)cc3C(C)(C)c3cc(C(C)(C)C)cc1c32 ; CCC1(C)c2cc(-n3c4c(c5ccccc53)CCC4)ccc2B2c3ccc(-n4c5c(c6ccccc64)CCC5)cc3C(C)(C)c3cc(C(C)(C)C)cc1c32 ; CC(C)(C)c1cc2c3c(c1)C(C)(C)c1cc(-n4c5c(c6ccccc64)CCC5)ccc1B3c1ccc(N3C4=C(CCCC4)Oc4ccccc43)cc1C2(C)C ; CC(C)(C)c1cc2c3c(c1)C(C)(C)c1cc(-n4c5c(c6ccccc64)CCC5)ccc1B3c1cc(-n3c4c(c5ccccc53)CCCC4)ccc1C2(C)C] 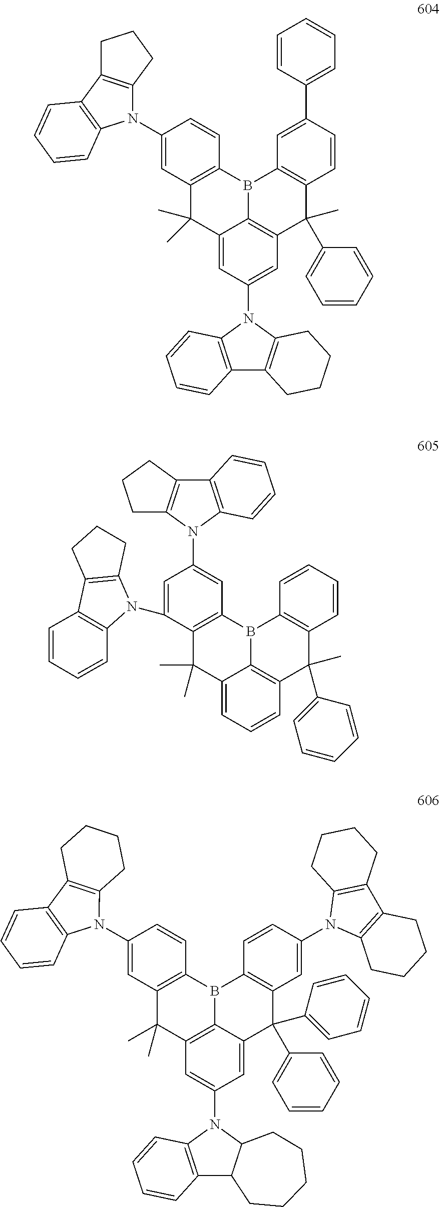 [SMILES: CC1(C)c2cc(-n3c4c(c5ccccc53)CCC4)ccc2B2c3cc(-c4ccccc4)ccc3C(C)(c3ccccc3)c3cc(-n4c5c(c6ccccc64)CCCC5)cc1c32 ; CC1(C)c2cccc3c2B(c2ccccc2C3(C)c2ccccc2)c2cc(-n3c4c(c5ccccc53)CCC4)cc(-n3c4c(c5ccccc53)CCC4)c21 ; CC1(C)c2cc(-n3c4c(c5ccccc53)CCCC4)ccc2B2c3ccc(-n4c5c(c6c4CCCC6)CCCC5)cc3C(c3ccccc3)(c3ccccc3)c3cc(N4c5ccccc5C5CCCCCC54)cc1c32] 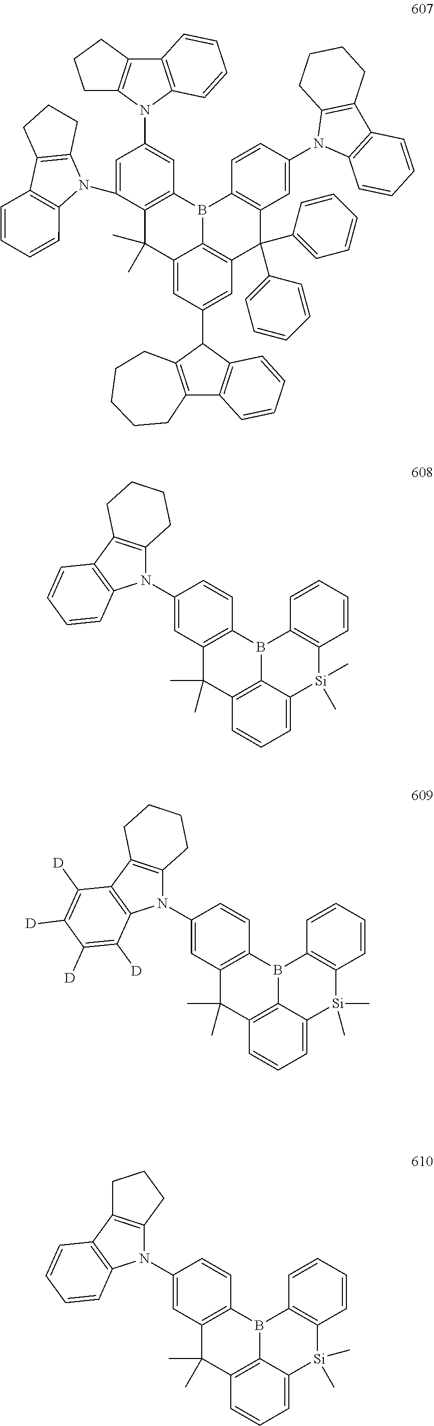 [SMILES: CC1(C)c2cc(C3C4=C(CCCCC4)c4ccccc43)cc3c2B(c2ccc(-n4c5c(c6ccccc64)CCCC5)cc2C3(c2ccccc2)c2ccccc2)c2cc(-n3c4c(c5ccccc53)CCC4)cc(-n3c4c(c5ccccc53)CCC4)c21 ; CC1(C)c2cc(-n3c4c(c5ccccc53)CCCC4)ccc2B2c3ccccc3[Si](C)(C)c3cccc1c32 ; [2H]c1c([2H])c([2H])c2c(c1[2H])c1c(n2-c2ccc3c(c2)C(C)(C)c2cccc4c2B3c2ccccc2[Si]4(C)C)CCCC1 ; CC1(C)c2cc(-n3c4c(c5ccccc53)CCC4)ccc2B2c3ccccc3[Si](C)(C)c3cccc1c32] 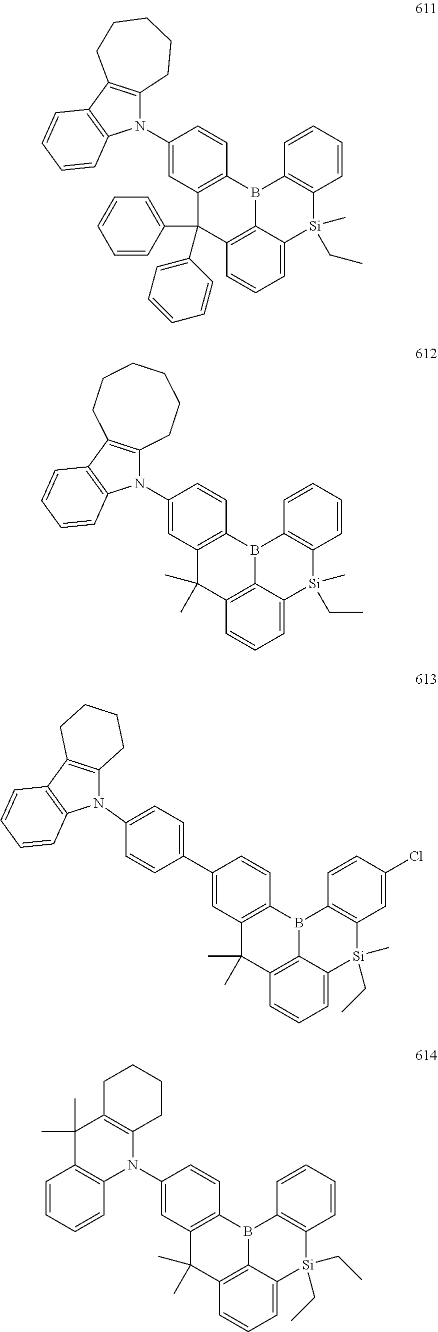 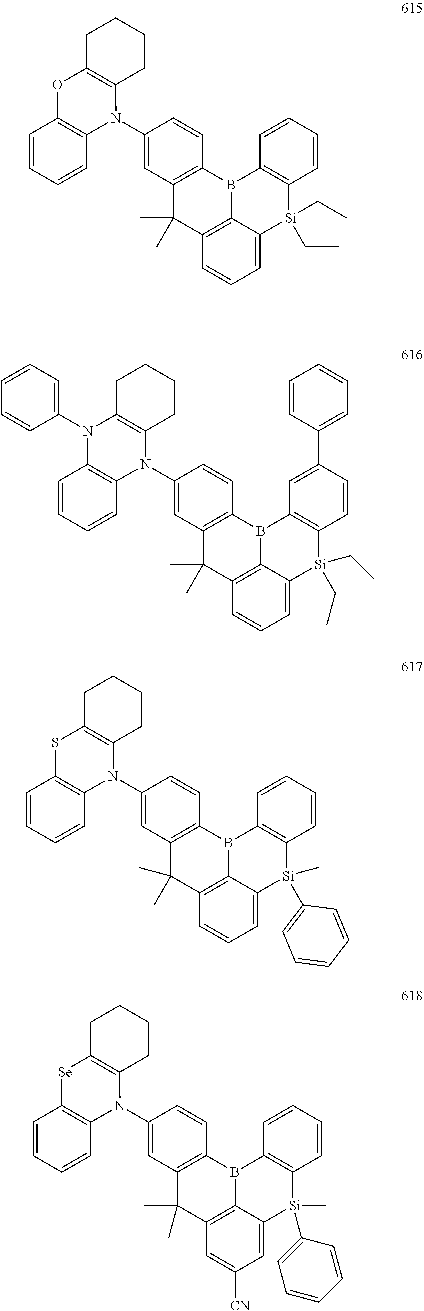 [SMILES: CC[Si]1(CC)c2ccccc2B2c3ccc(N4C5=C(CCCC5)Oc5ccccc54)cc3C(C)(C)c3cccc1c32 ; CC[Si]1(CC)c2ccc(-c3ccccc3)cc2B2c3ccc(N4C5=C(CCCC5)N(c5ccccc5)c5ccccc54)cc3C(C)(C)c3cccc1c32 ; CC1(C)c2cc(N3C4=C(CCCC4)Sc4ccccc43)ccc2B2c3ccccc3[Si](C)(c3ccccc3)c3cccc1c32 ; CC1(C)c2cc(N3C4=C(CCCC4)[Se]c4ccccc43)ccc2B2c3ccccc3[Si](C)(c3ccccc3)c3cc(C#N)cc1c32] 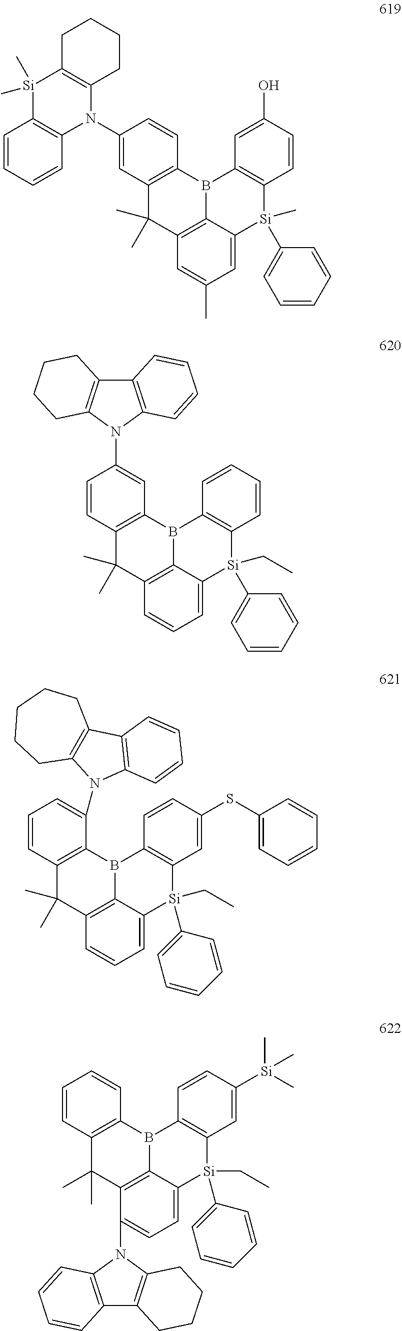 [SMILES: Cc1cc2c3c(c1)[Si](C)(c1ccccc1)c1ccc(O)cc1B3c1ccc(N3C4=C(CCCC4)[Si](C)(C)c4ccccc43)cc1C2(C)C ; CC[Si]1(c2ccccc2)c2ccccc2B2c3cc(-n4c5c(c6ccccc64)CCCC5)ccc3C(C)(C)c3cccc1c32 ; CC[Si]1(c2ccccc2)c2cc(Sc3ccccc3)ccc2B2c3c(-n4c5c(c6ccccc64)CCCCC5)cccc3C(C)(C)c3cccc1c32 ; CC[Si]1(c2ccccc2)c2cc([Si](C)(C)C)ccc2B2c3ccccc3C(C)(C)c3c(-n4c5c(c6ccccc64)CCCC5)ccc1c32] 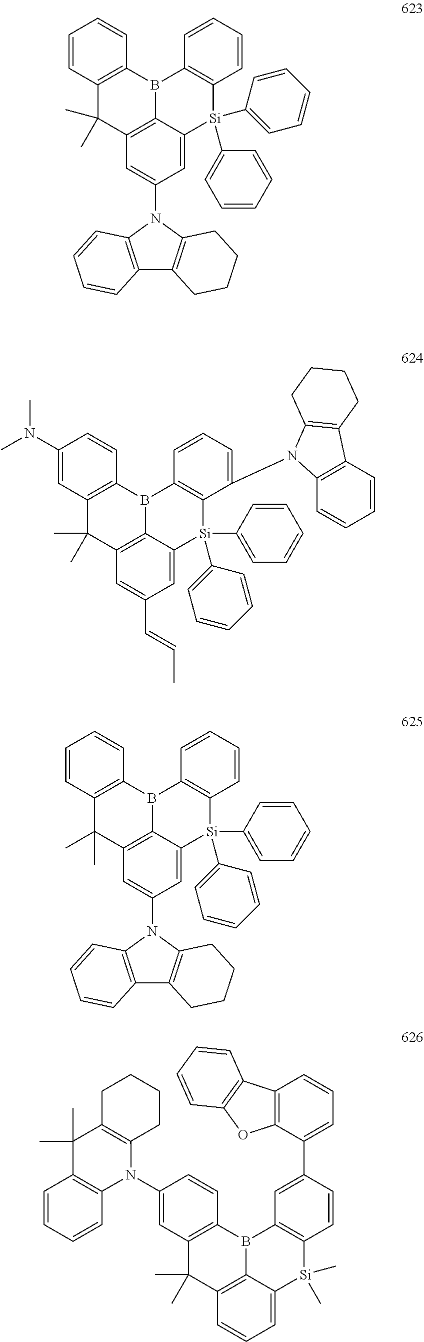 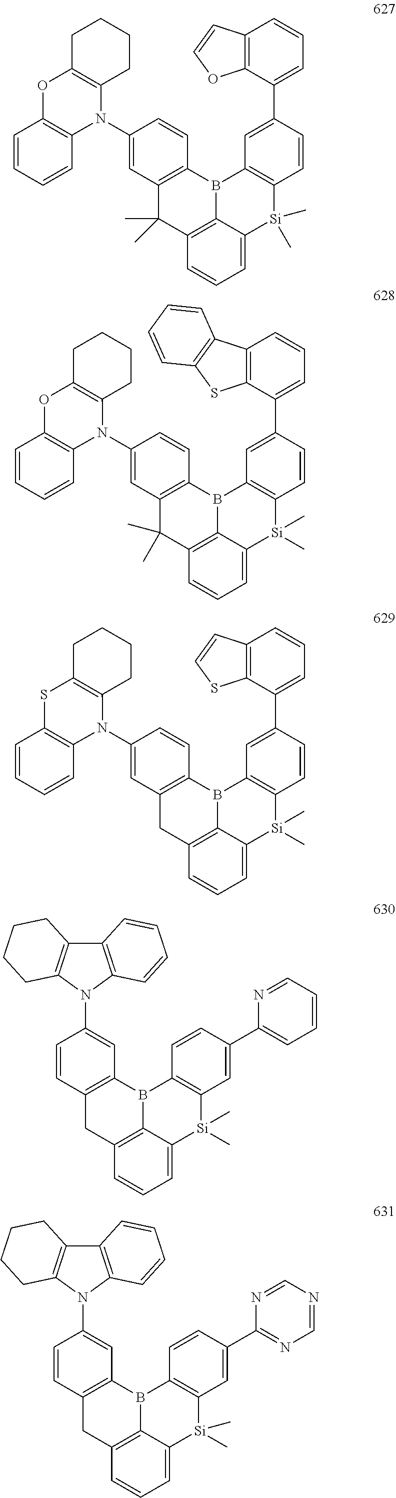 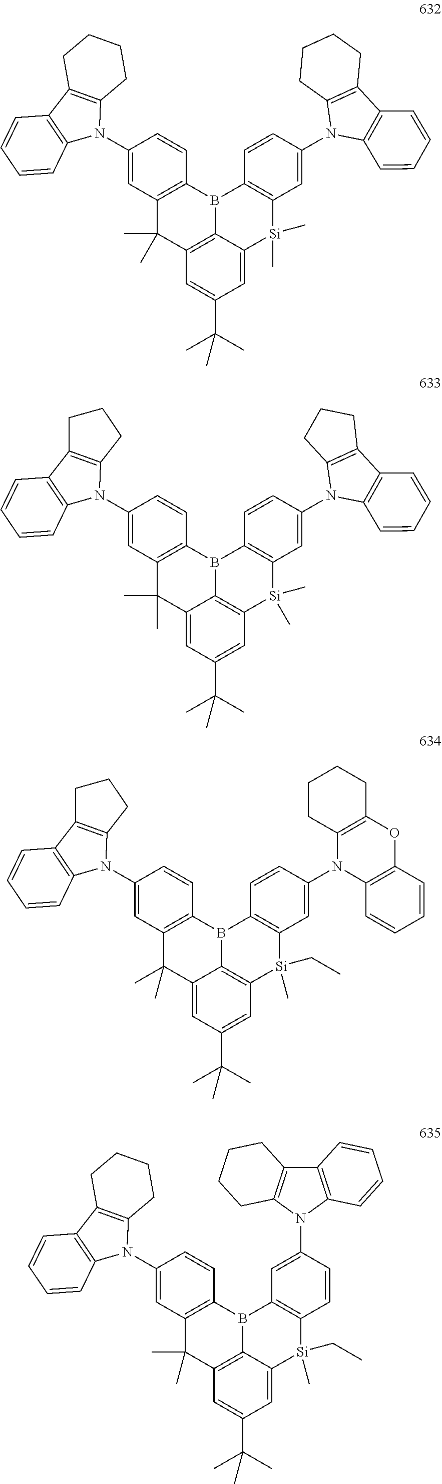 [SMILES: CC(C)(C)c1cc2c3c(c1)[Si](C)(C)c1cc(-n4c5c(c6ccccc64)CCCC5)ccc1B3c1ccc(-n3c4c(c5ccccc53)CCCC4)cc1C2(C)C ; CC(C)(C)c1cc2c3c(c1)[Si](C)(C)c1cc(-n4c5c(c6ccccc64)CCC5)ccc1B3c1ccc(-n3c4c(c5ccccc53)CCC4)cc1C2(C)C ; CC[Si]1(C)c2cc(N3C4=C(CCCC4)Oc4ccccc43)ccc2B2c3ccc(-n4c5c(c6ccccc64)CCC5)cc3C(C)(C)c3cc(C(C)(C)C)cc1c32 ; CC[Si]1(C)c2ccc(-n3c4c(c5ccccc53)CCCC4)cc2B2c3ccc(-n4c5c(c6ccccc64)CCCC5)cc3C(C)(C)c3cc(C(C)(C)C)cc1c32] 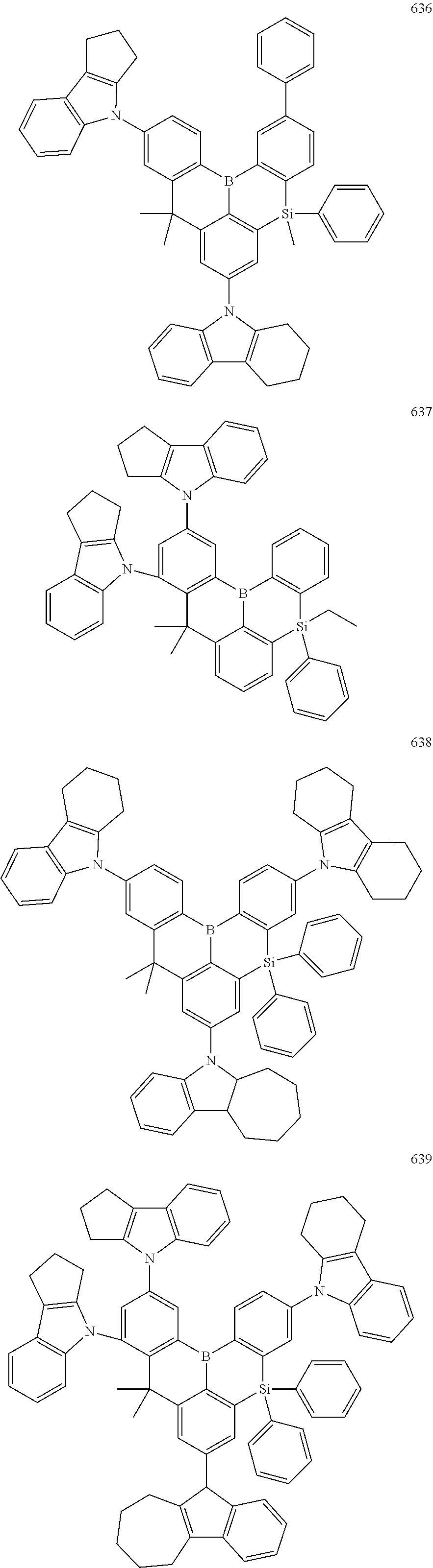 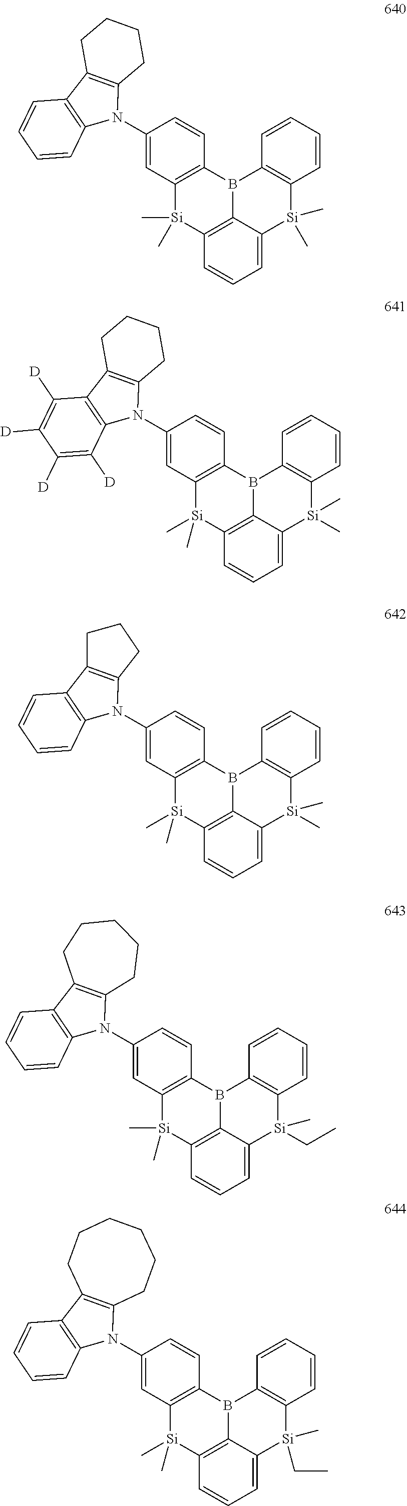 [SMILES: C[Si]1(C)c2ccccc2B2c3ccc(-n4c5c(c6ccccc64)CCCC5)cc3[Si](C)(C)c3cccc1c32 ; [2H]c1c([2H])c([2H])c2c(c1[2H])c1c(n2-c2ccc3c(c2)[Si](C)(C)c2cccc4c2B3c2ccccc2[Si]4(C)C)CCCC1 ; C[Si]1(C)c2ccccc2B2c3ccc(-n4c5c(c6ccccc64)CCC5)cc3[Si](C)(C)c3cccc1c32 ; CC[Si]1(C)c2ccccc2B2c3ccc(-n4c5c(c6ccccc64)CCCCC5)cc3[Si](C)(C)c3cccc1c32 ; CC[Si]1(C)c2ccccc2B2c3ccc(-n4c5c(c6ccccc64)CCCCCC5)cc3[Si](C)(C)c3cccc1c32] 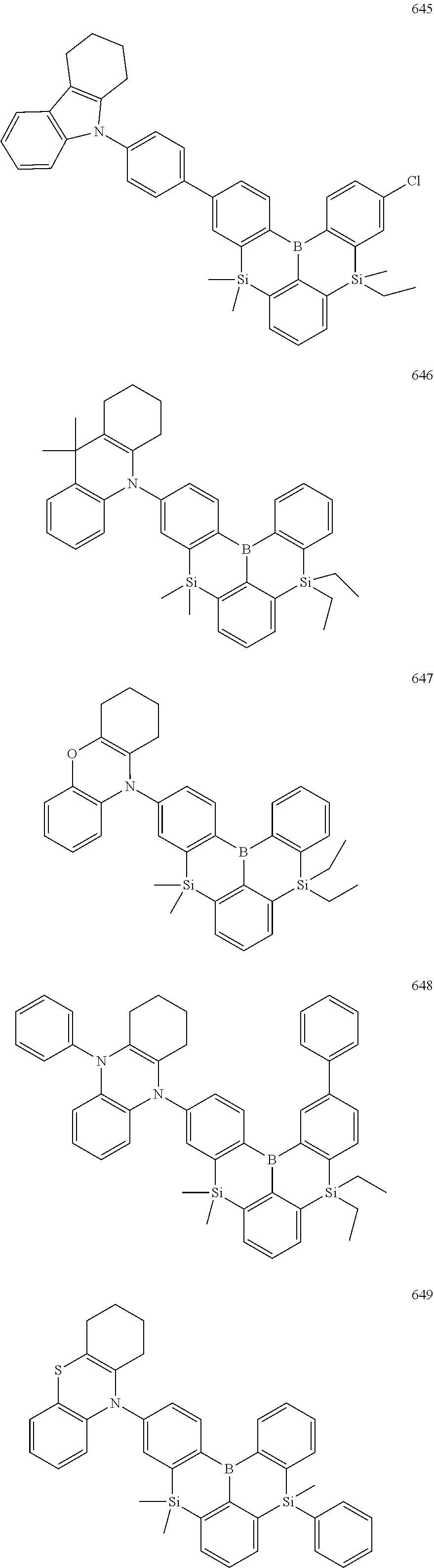 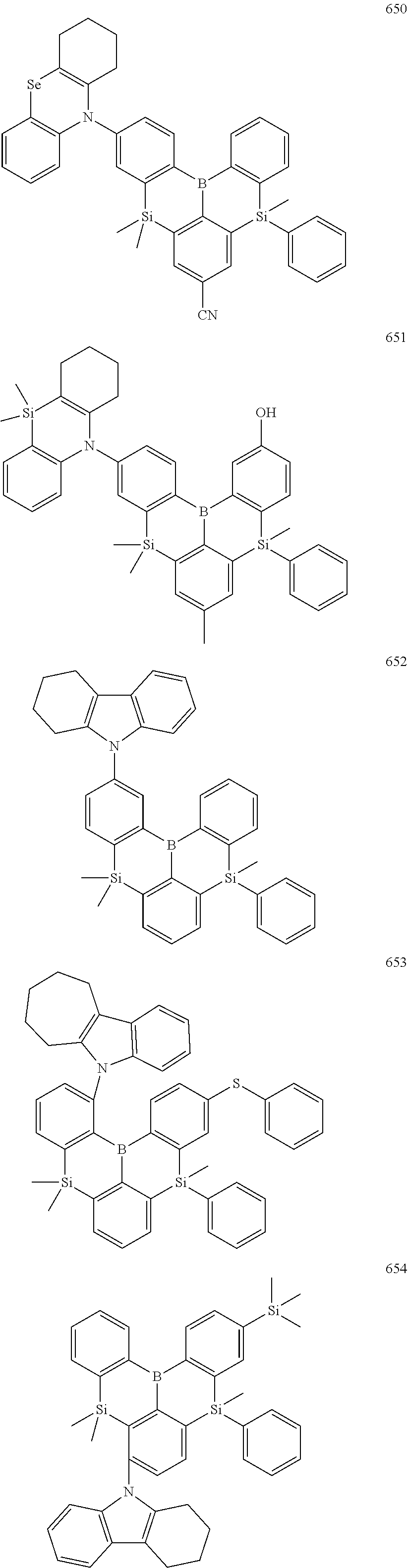 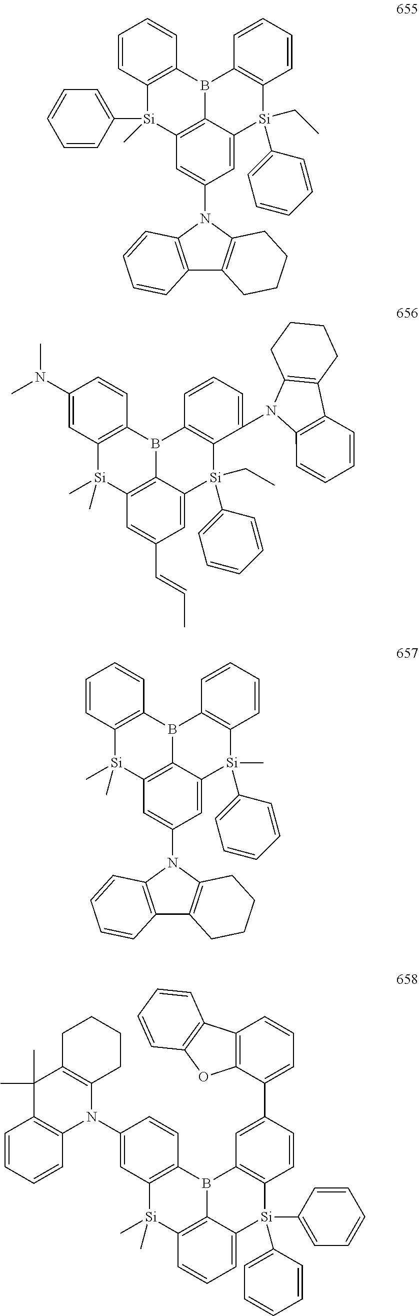 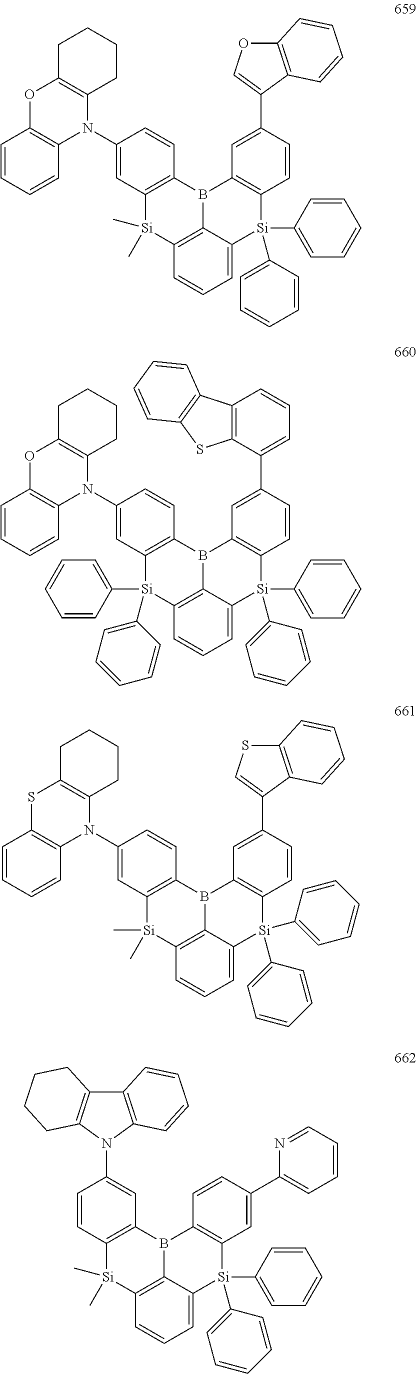 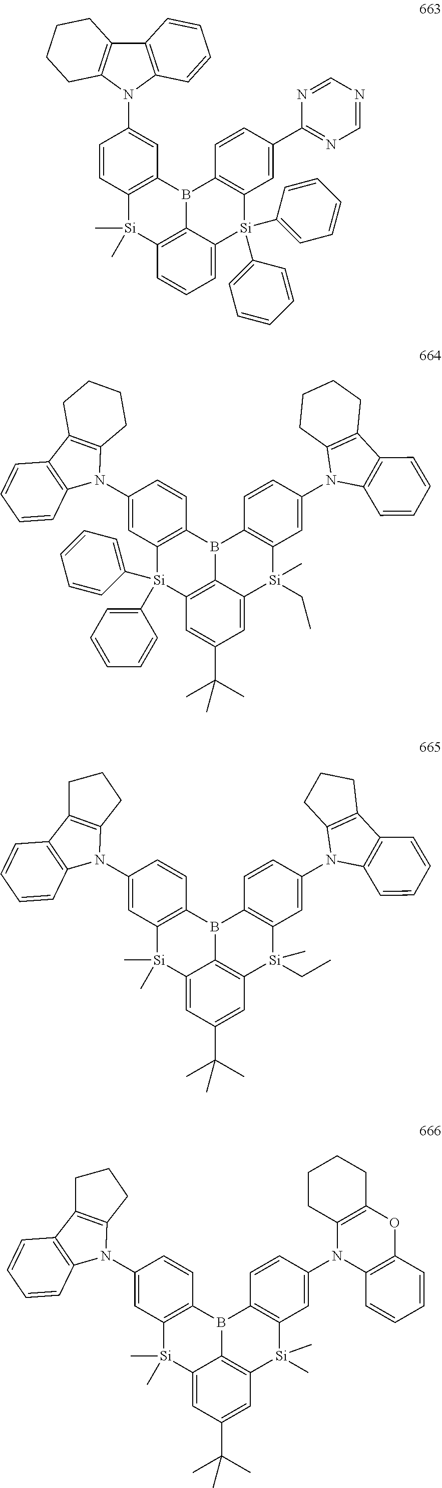 [SMILES: C[Si]1(C)c2ccc(-n3c4c(c5ccccc53)CCCC4)cc2B2c3ccc(-c4ncncn4)cc3[Si](c3ccccc3)(c3ccccc3)c3cccc1c32 ; CC[Si]1(C)c2cc(-n3c4c(c5ccccc53)CCCC4)ccc2B2c3ccc(-n4c5c(c6ccccc64)CCCC5)cc3[Si](c3ccccc3)(c3ccccc3)c3cc(C(C)(C)C)cc1c32 ; CC[Si]1(C)c2cc(-n3c4c(c5ccccc53)CCC4)ccc2B2c3ccc(-n4c5c(c6ccccc64)CCC5)cc3[Si](C)(C)c3cc(C(C)(C)C)cc1c32 ; CC(C)(C)c1cc2c3c(c1)[Si](C)(C)c1cc(-n4c5c(c6ccccc64)CCC5)ccc1B3c1ccc(N3C4=C(CCCC4)Oc4ccccc43)cc1[Si]2(C)C] 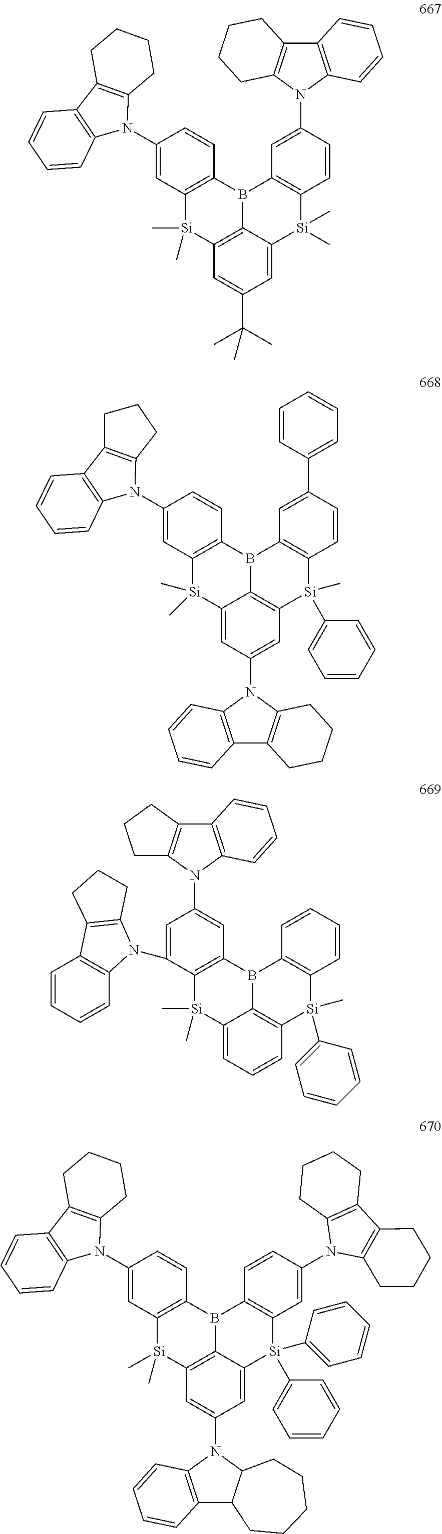 [chemical structure]
